(19) United States
(12) Patent Application Publication
(10) Pub. No.: US 2026/0150575 A1
(43) Pub. Date: May 28, 2026

(54) LIGHT-EMITTING ELEMENT, FUSED POLYCYCLIC COMPOUND FOR LIGHT-EMITTING ELEMENT, AND ELECTRONIC DEVICE INCLUDING THE LIGHT-EMITTING ELEMENT

(71) Applicant: Samsung Display Co., Ltd., Yongin-si (KR)

(72) Inventors: Hirokazu KUWABARA, Yokohama (JP); Keigo HOSHI, Yokohama (JP)

(21) Appl. No.: 19/177,862

(22) Filed: Apr. 14, 2025

(30) Foreign Application Priority Data
May 9, 2024 (KR) 10-2024-0060968

(51) Int. Cl. H10K 85/60; C07F 5/00; C09K 11/02; C09K 11/06; H10K 50/11; H10K 85/30

(52) U.S. Cl. CPC H10K 85/658; C07F 5/00; C09K 11/02; C09K 11/06; H10K 85/346; H10K 85/6572; C09K 2211/1007; C09K 2211/1018; H10K 50/11

(57) ABSTRACT

A light-emitting element including a first electrode, a second electrode disposed on the first electrode is provided. An emission layer is arranged between the first electrode and the second electrode and includes a first compound represented by Formula 1.

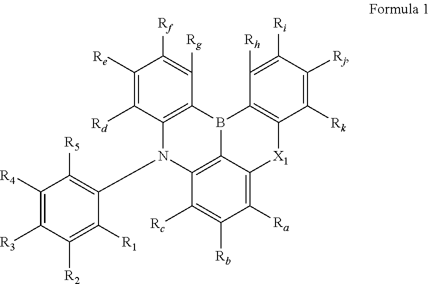

### CROSS-REFERENCE TO RELATED APPLICATION

This application claims priority to and the benefit of Korean Patent Application No. 10-2024-0060968, filed on May 9, 2024, in the Korean Intellectual Property Office, the entire content of which is incorporated herein by reference.

### BACKGROUND

### 1. Field

One or more aspects of embodiments of the present disclosure relate to a light-emitting element, a fused polycyclic compound used for the light-emitting element, and an electronic device including the light-emitting element.

### 2. Background

Recently, there has been significant development in organic electroluminescence display devices as image display devices. Unlike liquid crystal displays, these “self-luminous” display devices recombine holes and electrons in an emission layer injected from a first electrode and a second electrode, respectively. This recombination causes an emission material, such as a light-emitting element containing an organic compound, to emit light and display images.

In the application of organic light-emitting elements to display devices, increases in emission efficiency and lifespan of the organic light-emitting element is desired or required. Therefore ongoing development focuses on materials for organic light-emitting elements that may reliably and stably meet or achieve these requirements.

Recently, to achieve high-efficiency light-emitting elements, technologies such as phosphorescent emission using triplet state energy and fluorescent emission via triplet-triplet annihilation (TTA)—a phenomenon in which a singlet exciton is generated by collision of triplet excitons—have been developed. Additionally, there is the active development of materials for thermally activated delayed fluorescence (TADF), which utilizes a delayed fluorescence phenomenon.

### SUMMARY

One or more aspects of embodiments of the present disclosure is directed toward a light-emitting element with (having) enhanced (e.g., improved) emission efficiency and element lifespan.

One or more aspects of embodiments of the present disclosure is directed toward a fused polycyclic compound capable of improving emission efficiency and element lifespan of a light-emitting element.

One or more aspects of embodiments of the present disclosure is directed toward an electronic device including a light-emitting element having improved emission efficiency and lifespan, thereby having excellent or suitable display quality.

Additional aspects will be set forth in part in the description which follows and, in part, will be apparent from the description, or may be learned by practice of the presented embodiments of the disclosure.

One or more embodiments of the present disclosure provide a light-emitting element including a first electrode, a second electrode opposite to (e.g., facing) the first electrode, and an emission layer arranged between the first electrode and the second electrode and including (e.g., containing) a first compound represented by Formula 1.

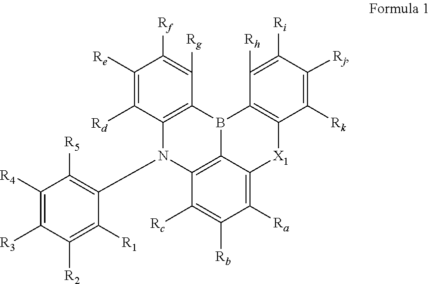

In Formula 1, X₁ may be O, S, or NR₆, R₁ to R₆, and Rₐ to Rₖ may each independently be a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or may be bonded to an adjacent group to form a ring, and at least one selected from among R_{d} to Rₖ may be a substituent represented by Formula 2.

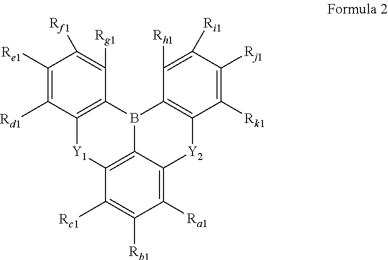

In Formula 2, Y₁ and Y₂ may each independently be O, S, or NR₇, R₇, and Rₐ₁ to Rₖ₁ may each independently be a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or may be bonded to an adjacent group to form a ring, and any one selected from among Rₐ₁ to Rₖ₁ may be a portion to which Formula 1 is connected.

In one or more embodiments, the first compound represented by Formula 1 may be represented by Formula 1-1 or Formula 1-2.

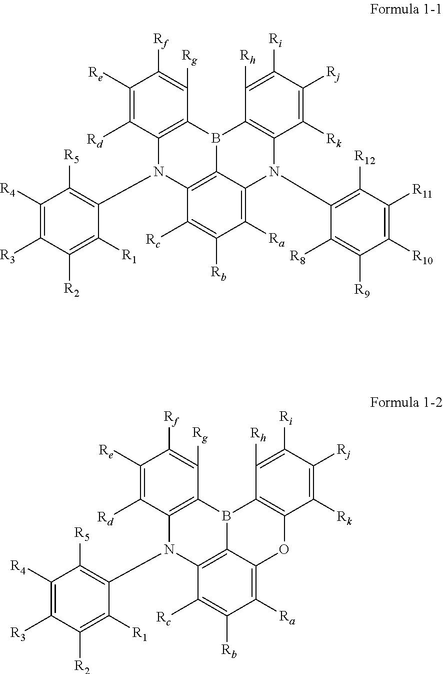

In Formula 1-1 and Formula 1-2, R₈ to R₁₂ may each independently be a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or may be bonded to an adjacent group to form a ring.

In Formula 1-1 and Formula 1-2, R₁ to R₅, and Rₐ to Rₖ may each independently be as defined in Formula 1.

In one or more embodiments, at least one selected from among R_{d} to Rₖ (e.g., the substituent represented by Formula 2) may be represented by any one selected from among Formula 2-1 to Formula 2-3.

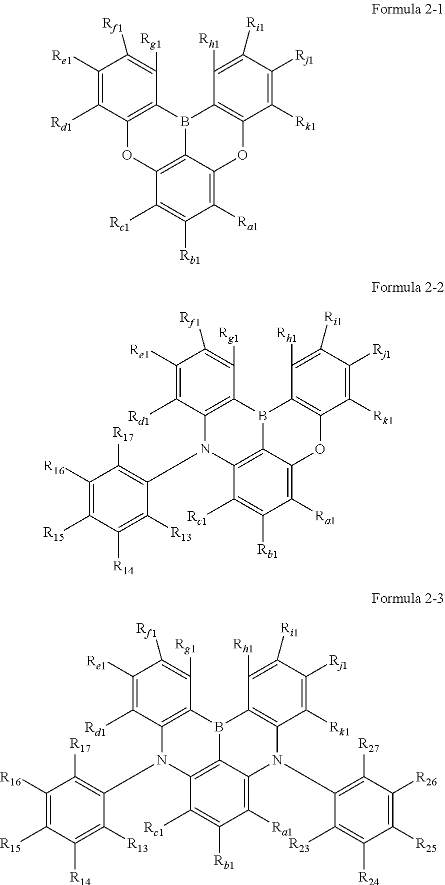

In Formula 2-1 to Formula 2-3, R₁₃ to R₂₇ may each independently be a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or may be bonded to an adjacent group to form a ring.

In Formula 2-1 to Formula 2-3, Rₐ₁ to Rₖ₁ may each independently be as defined in Formula 2.

In one or more embodiments, the first compound represented by Formula 1 may be represented by any one selected from among Formula 3-1 to Formula 3-3.

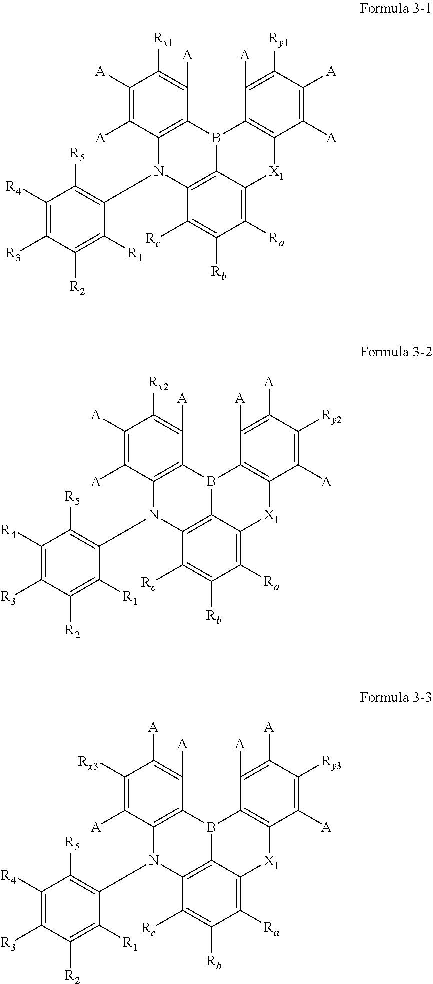

In Formula 3-1 to Formula 3-3, A may be a hydrogen atom or a deuterium atom, and

Rₓ₁, Rₓ₂, Rₓ₃, R_{y1}, R_{y2}, and R_{y3} may each independently be a substituted or unsubstituted amine group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons.

In Formula 3-1, at least one selected from among Rₓ₁ and R_{y1} may be a substituent represented by Formula 2,

In Formula 3-2, at least one selected from among Rₓ₂ and R_{y2} may be a substituent represented by Formula 2,

In Formula 3-3, at least one selected from among Rₓ₃ and R_{y3} may be a substituent represented by Formula 2.

In Formula 3-1 to Formula 3-3, X₁, R₁ to R₅, and Rₐ to Re may each independently be as defined in Formula 1.

In one or more embodiments, the first compound represented by Formula 2 may be represented by any one selected from among Formula 4-1 to Formula 4-3.

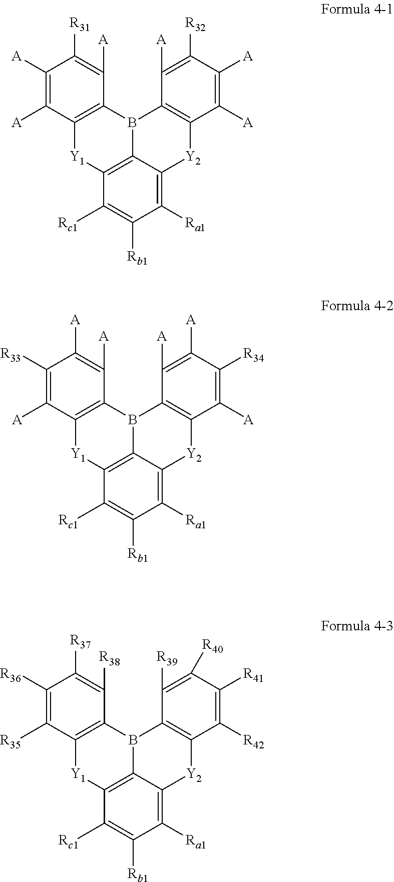

In Formula 4-1 to Formula 4-3, A may be a hydrogen atom or a deuterium atom, R₃₁ to R₄₂ may each independently be a hydrogen atom, a deuterium atom, a halogen atom, a substituted or unsubstituted amine group, a substituted or unsubstituted oxy group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and/or may be bonded to an adjacent group to form a ring, and at least one adjacent pair (e.g., a pair of groups or atoms thereof) selected from among R₃₅ to R₄₂ may be bonded to each other to form a ring.

In Formula 4-1 to Formula 4-3, Y₁, Y₂, and Rₐ₁ to R_{c1} may each independently be as defined in Formula 2.

In one or more embodiments, the first compound represented by Formula 1 is represented by Formula 5.

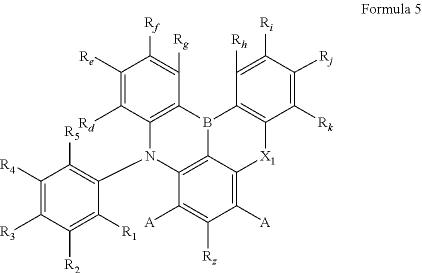

In Formula 5, A is a hydrogen atom, or a deuterium atom, Rz is a substituted or unsubstituted amine group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons.

X₁, R₁ to R₅, and R_{d} to Rₖ may each independently be the same as defined in Formula 1.

In one or more embodiments, at least one selected from among R_{d} to Rₖ (e.g., the substituent represented by Formula 2) may be represented by Formula 6-1 or Formula 6-2.

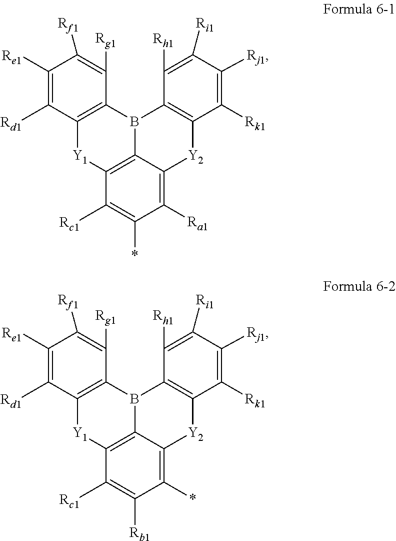

In Formula 6-1 and Formula 6-2,

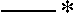 [SMILES: *C]

is a portion to which Formula 1 may be connected.

In Formula 6-1 and Formula 6-2, Y₁, Y₂, and Rₐ₁ to Rₖ₁ may each independently be as defined in Formula 2.

In one or more embodiments, the first compound represented by Formula 1 may be represented by Formula 7.

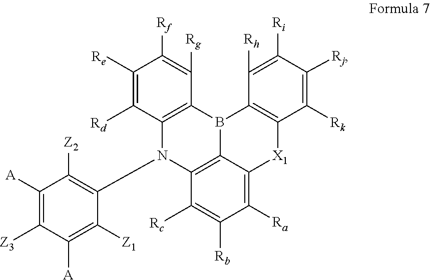

In Formula 7, A may be a hydrogen atom or a deuterium atom, Z₁ to Z₃ may each independently be a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons.

In Formula 7, X₁, and Rₐ to Rₖ may each independently be as defined in Formula 1.

In one or more embodiments, in Formula 1, one or two selected from among R_{d} to Rₖ may each independently be a substituent represented by Formula 2, and the (e.g., any) remaining selected from among R_{d} to Rₖ may each independently be a hydrogen atom, a deuterium atom, a substituted or unsubstituted t-butyl group, a substituted or unsubstituted phenyl group, or a substituted or unsubstituted carbazole group.

In one or more embodiments, in Formula 2, any one selected from among Rₐ₁ to R_{c1} may be a portion to which Formula 1 may be connected, and the rest (e.g., two) selected from among Rₐ₁ to R_{c1} may each independently be a hydrogen atom, or a deuterium atom, and R_{d1} to Rₖ₁ may each independently be a hydrogen atom, a deuterium atom, a substituted or unsubstituted t-butyl group, a substituted or unsubstituted phenyl group, or a substituted or unsubstituted carbazole group, or may be bonded to an adjacent group to form an aromatic hydrocarbon ring or an aromatic hetero ring.

In one or more embodiments, the emission layer may further include at least one selected from among a second compound represented by Formula HT-1, a third compound represented by Formula ET-1 and a fourth compound represented by Formula D-1.

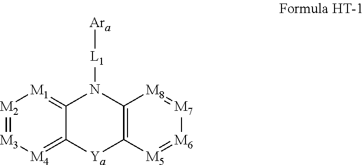

In Formula HT-1, M₁ to M₈ may each independently be N or CR₅₁, L₁ may be a direct linkage, a substituted or unsubstituted arylene group having 6 to 30 ring-forming carbons, or a substituted or unsubstituted heteroarylene group having 2 to 30 ring-forming carbons, Yₐ may be a direct linkage, CR₅₂R₅₃, or SiR₅₄R₅₅, Ara may be a substituted or unsubstituted aryl group having 6 to 30 ring-forming carbons, a substituted or unsubstituted heteroaryl group having 2 to 30 ring-forming carbons, and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, and/or may be bonded to an adjacent group to form a ring.

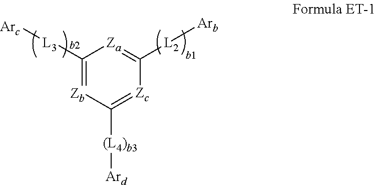

In, Formula ET-1, at least one selected from among Zₐ to Z_{c} may be N, and the (e.g., any) remaining Zₐ to Z_{c} may be CR₅₆, R₅₆ may be a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons, b1 to b3 may each independently be an integer of 0 to 10, Arb to Ard may each independently be a hydrogen atom, a deuterium atom, a substituted or unsubstituted alkyl group having 1 to 20 carbons, or a substituted or unsubstituted aryl group having 6 to 30 carbons, or a substituted or unsubstituted heteroaryl group having 2 to 30 ring-forming carbons, and L₂ to L₄ may each independently be a direct linkage, a substituted or unsubstituted arylene group having 6 to 30 ring-forming carbons, or a substituted or unsubstituted heteroarylene group having 2 to 30 ring-forming carbons.

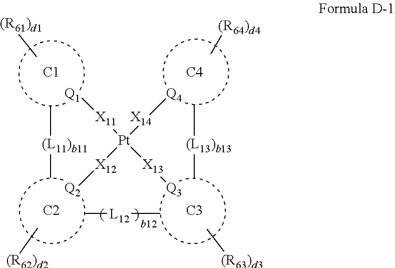

In Formula D-1, Q₁ to Q₄ may each independently be C or N, C1 to C4 may each independently be a substituted or unsubstituted hydro carbon ring having 5 to 30 ring-forming carbons, a substituted or unsubstituted aryl group having 6 to 30 ring-forming carbons, or a substituted or unsubstituted heteroaryl group having 2 to 30 ring-forming carbons, X₁₁ to X₁₄ may each independently be a direct linkage, or

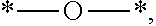

L₁₁ to L₁₃ may each independently be a direct linkage,

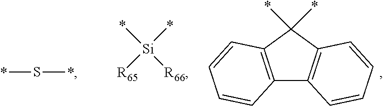

a substituted or unsubstituted alkylene group having 1 to 20 carbons, a substituted or unsubstituted arylene group having 6 to 30 ring-forming carbons, or a substituted or unsubstituted heteroarylene group having 2 to 30 ring-forming carbons, b11 to b13 may each independently be 0 or 1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, and d1 to d4 may each independently be an integer of 0 to 4.

In one or more embodiments of the present disclosure, an electronic device may include a base layer, a circuit layer arranged on the base layer, and a display element layer arranged on the circuit layer and including (e.g., containing) the light-emitting element, wherein the light-emitting element includes a first electrode, a second electrode arranged on the first electrode, and an emission layer arranged between the first electrode and the second electrode and including (e.g., containing) a first compound represented by Formula 1.

In one or more embodiments, the light-emitting element may further include a capping layer arranged on the second electrode. The capping layer may have a refractive index of at least about 1.6 (e.g., or greater) for light in a wavelength range of about 550 nanometer (nm) to about 660 nm.

In one or more embodiments, the electronic device may further include a light control layer arranged on the display element layer and including (e.g., containing) a quantum dot. The light-emitting element may be to emit a first color light, the light control layer may include a first light control part including (e.g., containing) a first quantum dot that converts (e.g., is configured to convert) the first color light into a second color light, which may have a wavelength region that is longer than a wavelength region of the first color light. The light control layer may include a second light control part including (e.g., containing) a second quantum dot that converts (e.g., is configured to convert) the first color light into a third color light, which may have a wavelength region that is longer than wavelength region of the first color light and a wavelength region of the second color light. The light control layer may include a third light control part transmitting (e.g., is configured to transmit) the first color light.

In one or more embodiments, the electronic device may be at least one selected from among: large-sized display devices such as selected from among televisions, monitors, and outdoor billboards; and medium- or small-sized display devices such as selected from among personal computers, laptop computers, personal digital assistants, display devices for vehicles, game consoles, mobile electronic devices, and/or cameras.

In one or more embodiments of the present disclosure, a fused polycyclic compound may be represented by Formula 1.

### BRIEF DESCRIPTION OF THE DRAWINGS

The accompanying drawings are included to provide a further understanding of the preceding and other advantages of the disclosure, and are incorporated in and constitute a part of this specification. The drawings illustrate embodiments of the present disclosure and, together with the description, serve to explain principles of the disclosure. In the drawings:

FIG. 1 is a plan view of a display device according to one or more embodiments of the disclosure;

FIG. 2 is a cross-sectional view of a display device according to one or more embodiments of the disclosure;

FIG. 3 is a cross-sectional view schematically illustrating a light-emitting element according to one or more embodiments of the disclosure;

FIG. 4 is a cross-sectional view schematically illustrating a light-emitting element according to one or more embodiments of the disclosure;

FIG. 5 is a cross-sectional view schematically illustrating a light-emitting element according to one or more embodiments of the disclosure;

FIG. 6 is a cross-sectional view schematically illustrating a light-emitting element according to one or more embodiments of the disclosure;

FIG. 7 and FIG. 8 are each a cross-sectional view of a display device according to one or more embodiments of the disclosure;

FIG. 9 is a cross-sectional view illustrating a display device according to one or more embodiments of the disclosure;

FIG. 10 is a cross-sectional view illustrating a display device according to one or more embodiments of the disclosure;

FIG. 11 is a view illustrating an inside of a vehicle in which a display device according to one or more embodiments is arranged; and

FIG. 12A, FIG. 12B, FIG. 13A, and FIG. 13B are each a view illustrating a three-dimensional molecule model of a compound according to one or more embodiments.

### DETAILED DESCRIPTION

The present disclosure may be modified in one or more suitable manners and have many forms, and thus specific embodiments will be exemplified in the drawings and described in more detail in the detailed description of present disclosure. It should be understood, however, that it is not intended to limit the disclosure to the particular forms disclosed, but rather, is intended to cover all modifications, equivalents, and alternatives falling within the spirit and scope of the disclosure.

When explaining each of drawings, like reference numbers are used for referring to like elements, and duplicative descriptions thereof may not be provided. In the accompanying drawings, the dimensions of each structure are exaggeratingly illustrated for clarity of the present disclosure. It will be understood that, although the terms “first,” “second,” and/or the like, may be used herein to describe one or more suitable components, these components should not be limited by these terms. These terms are only used to distinguish one component from another. For example, a first component could be termed a second component, and, similarly, a second component could be termed a first component, without departing from the scope of example embodiments of the disclosure. As used herein, the singular forms, “a,” “an,” and “the” are intended to include the plural forms as well, unless the context clearly indicates otherwise.

In the present application, it will be understood that the terms “comprises,” “comprising,” “comprise,” “includes,” “including”, “include,” “have” “has,” “having,” and/or the like specify the presence of features, numbers, steps, operations, component, parts, and/or one or more (e.g., any suitable) combinations thereof disclosed in the specification, but do not exclude the possibility of presence or addition of one or more other features, numbers, steps, operations, component, parts, and/or one or more (e.g., any suitable) combinations thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof. In this context, “consisting essentially of” indicates that any additional components will not materially affect the chemical, physical, optical or electrical properties of the semiconductor film.

In the present application, if (e.g., when) a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, if (e.g., when) a layer, a film, a region, or a plate is referred to as being “below”, “in a lower portion of” another layer, film, region, or plate, it can be not only directly under the layer, film, region, or plate, but intervening layers, films, regions, or plates may also be present. In addition, it will be understood that if (e.g., when) a part is referred to as being “on” another part, it can be arranged above the other part, or arranged under the other part as well.

Spatially relative terms, such as “beneath”, “below”, “lower”, “above”, “upper” and/or the like, may be used herein for ease of description to describe one element or feature's relationship to another elements or features as shown in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the term “and/or” may include any and all combinations of one or more of the associated listed items.

Expressions such as “at least one of,” “one of,” “selected from,” and “selected from among,” when preceding a list of elements, modify the entire list of elements and do not modify the individual elements of the list. For example, throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

Unless otherwise defined, all terms including chemical, technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Hereinafter, embodiments of the present disclosure will be described with reference to accompanying drawings in which one or more embodiments of present disclosure are shown. An aspect and a characteristic of the disclosure, and a method of accomplishing these will be apparent referring to one or more embodiments described with reference to the drawings. In this specification, phrases such as “on a plane,” “plan view,” and/or the like indicate viewing a target portion from the top, and the phrase “on a cross-section” indicates viewing a cross-section formed by vertically cutting a target portion from the side.

### Definitions

In the specification, the term “substituted or unsubstituted” may refer to substituted or unsubstituted with at least one substituent selected from among the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified herein may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but one or more embodiments of the disclosure is not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but one or more embodiments of the disclosure is not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but one or more embodiments of the disclosure is not limited thereto.

In the specification, an alkynyl group refers to a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, and/or the like, but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but one or more embodiments of the disclosure is not limited thereto.

In the specification, the fluorenyl group may be substituted, and two substituents may be bonded to each other to form a spiro structure. Examples of the substituted fluorenyl group are as follows. However, one or more embodiments of the disclosure is not limited thereto.

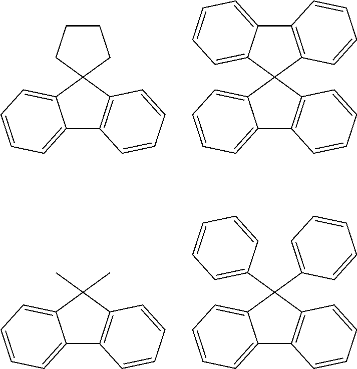

The heterocyclic group herein refers to any functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. If the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but one or more embodiments of the disclosure is not limited thereto.

In the specification, the heteroaryl group may contain at least one of B, O, N, P, Si, or S as a heteroatom. If the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridine group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but one or more embodiments of the disclosure is not limited thereto.

In the specification, the description of the aryl group may be applied to an arylene group except that the arylene group is a divalent group. The preceding description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but one or more embodiments of the disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but one or more embodiments of the disclosure is not limited thereto.

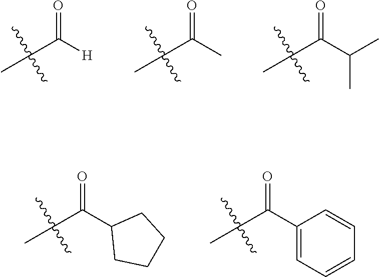

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but one or more embodiments of the disclosure is not limited thereto.

In the specification, an oxy group may refer to that an oxygen atom is bonded to the alkyl group or the aryl group as defined. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but one or more embodiments of the disclosure is not limited thereto.

The boron group herein may refer to that a boron atom is bonded to the alkyl group or the aryl group as defined. The boron group includes an alkyl boron group and an aryl boron group. Examples of the boron group may include a dimethylboron group, a trimethylboron group, a t-butyldimethylboron group, a diphenylboron group, a phenylboron group, and/or the like, but one or more embodiments of the disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, and/or the like, but one or more embodiments of the disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described herein.

In the specification, the aryl group among an aryloxy group, an arylthio group, an arylsulfoxy group, an arylamino group, an arylboron group, an arylsilyl group, an arylamine group is the same as the examples of the aryl group described.

In the specification, a direct linkage may refer to a single bond.

In one or more embodiments, in the specification,

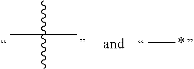

refer to a position to be connected.

Hereinafter, embodiments of the disclosure will be described with reference to the accompanying drawings.

### Display Apparatus

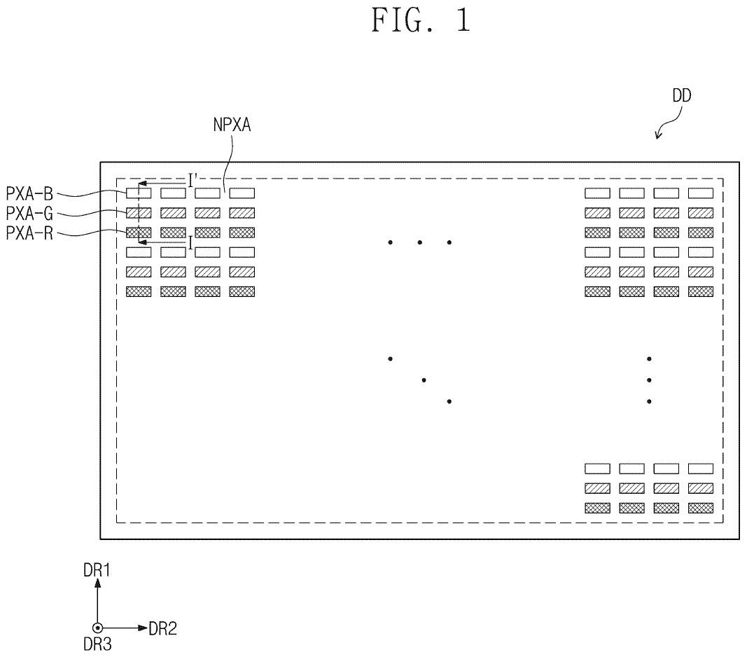

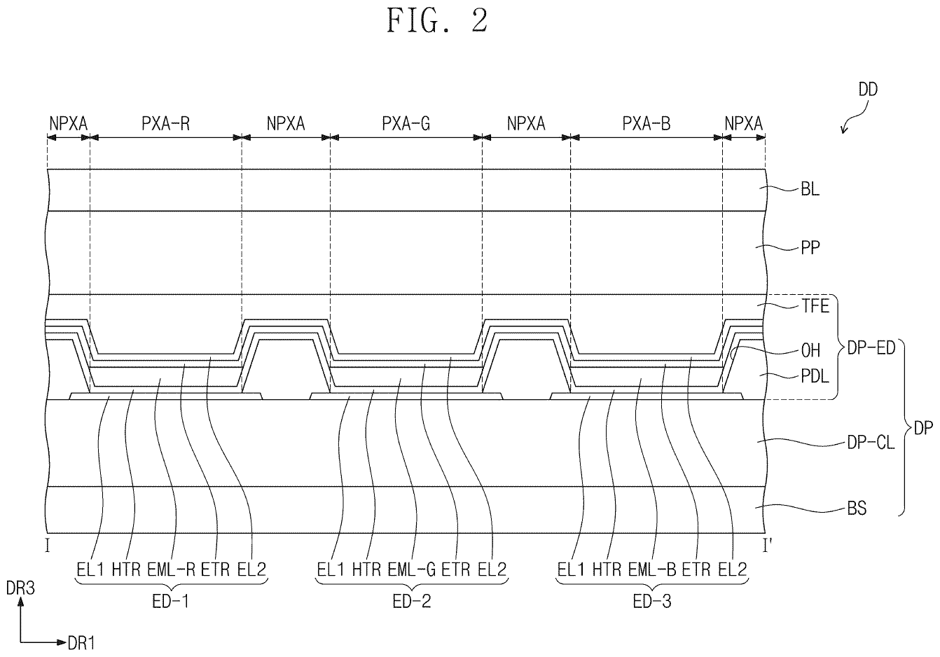

FIG. 1 is a plan view illustrating one or more embodiments of a display apparatus DD. FIG. 2 is a cross-sectional view of the display apparatus DD of the embodiment. FIG. 2 is a cross-sectional view illustrating a part taken along the line I-I′ of FIG. 1.

The display apparatus DD may include a display panel DP and an optical layer PP arranged on the display panel DP. The display panel DP includes light emitting devices ED-1, ED-2, and ED-3. The display apparatus DD may include a plurality of light emitting devices ED-1, ED-2, and ED-3. The optical layer PP may be arranged on the display panel DP to control reflected light in the display panel DP due to external light. The optical layer PP may include, for example, a polarization layer or a color filter layer. In one or more embodiments, the optical layer PP may not be provided from the display apparatus DD of one or more embodiments.

A base substrate BL may be arranged on the optical layer PP. The base substrate BL may be a member which provides a base surface on which the optical layer PP arranged. The base substrate BL may be a glass substrate, a metal substrate, a plastic substrate, and/or the like. However, one or more embodiments of the disclosure are not limited thereto, and the base substrate BL may be an inorganic layer, an organic layer, or a composite material layer. In one or more embodiments, the base substrate BL may not be provided.

The display apparatus DD according to one or more embodiments may further include a filling layer. The filling layer may be arranged between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting devices ED-1, ED-2, and ED-3 arranged between portions of the pixel defining film PDL, and an encapsulation layer TFE arranged on the light emitting devices ED-1, ED-2, and ED-3.

The base layer BS may be a member which provides a base surface on which the display device layer DP-ED is arranged. The base layer BS may be a glass substrate, a metal substrate, a plastic substrate, and/or the like. However, one or more embodiments is not limited thereto, and the base layer BS may be an inorganic layer, an organic layer, or a composite material layer.

In one or more embodiments, the circuit layer DP-CL is arranged on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting devices ED-1, ED-2, and ED-3 of the display device layer DP-ED.

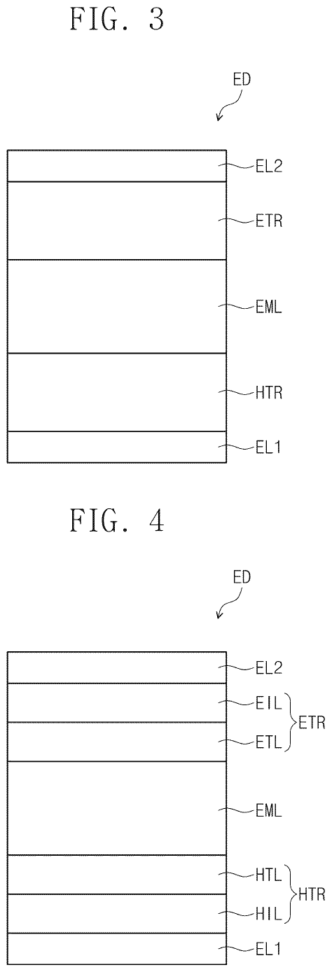

Each of the light emitting devices ED-1, ED-2, and ED-3 may have a structure of each light emitting device ED of embodiments according to FIGS. 3 to 6, which will be described in more detail later. Each of the light emitting devices ED-1, ED-2, and ED-3 may include a first electrode EL1, a hole transport region HTR, emission layers EML-R, EML-G, and EML-B, an electron transport region ETR, and a second electrode EL2.

FIG. 2 illustrates one or more embodiments in which the emission layers EML-R, EML-G, and EML-B of the light emitting devices ED-1, ED-2, and ED-3 are arranged in openings OH defined in the pixel defining film PDL, and the hole transport region HTR, the electron transport region ETR, and the second electrode EL2 are provided as a common layer in the entire light emitting devices ED-1, ED-2, and ED-3. However, one or more embodiments of the disclosure is not limited thereto, and unlike the configuration illustrated in FIG. 2, the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 in one or more embodiments may be provided by being patterned in an inkjet printing method.

The encapsulation layer TFE may cover the light emitting devices ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but one or more embodiments of the disclosure is not particularly limited thereto. The encapsulation-organic film may include an acrylic-based compound, an epoxy-based compound, and/or the like. The encapsulation-organic film may include a photopolymerizable organic material, but one or more embodiments of the disclosure is not particularly limited thereto.

The encapsulation layer TFE may be arranged on the second electrode EL2 and may be arranged filling the opening OH.

Referring to FIGS. 1 and 2, the display apparatus DD may include one or more non-light emitting region(s) NPXA and also include light emitting regions PXA-R, PXA-G, and PXA-B. The light emitting regions PXA-R, PXA-G, and PXA-B may be regions in which light generated by the respective light emitting devices ED-1, ED-2, and ED-3 is emitted. The light emitting regions PXA-R, PXA-G, and PXA-B may be spaced and/or apart (e.g., spaced apart or separated) from each other on a plane.

Each of the light emitting regions PXA-R, PXA-G, and PXA-B may be a region divided (i.e., defined) by the pixel defining film PDL. The non-light emitting areas NPXA may be areas between the adjacent light emitting areas PXA-R, PXA-G, and PXA-B, which correspond to the pixel defining film PDL. In one or more embodiments, in the specification, the light emitting regions PXA-R, PXA-G, and PXA-B may respectively correspond to pixels. The pixel defining film PDL may divide the light emitting devices ED-1, ED-2, and ED-3. The emission layers EML-R, EML-G, and EML-B of the light emitting devices ED-1, ED-2, and ED-3 may be arranged in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display apparatus DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display apparatus DD according to one or more embodiments, the plurality of light emitting devices ED-1, ED-2 and ED-3 may be to emit light beams having wavelengths different from each other. For example, in one or more embodiments, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, one or more embodiments of the disclosure is not limited thereto, and the first to third light emitting devices ED-1, ED-2, and ED-3 may be to emit light beams in substantially the same wavelength range or at least one light emitting device may be to emit a light beam in a wavelength range different from the others. For example, the first to third light emitting devices ED-1, ED-2, and ED-3 may all emit blue light.

The light emitting regions PXA-R, PXA-G, and PXA-B in the display apparatus DD according to one or more embodiments may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B each may be arranged along the second directional axis DR2. In some embodiments, the red light emitting region PXA-R, the green light emitting region PXA-G, and the blue light emitting region PXA-B may be alternately arranged with each other in this order along a first directional axis DR1.

FIGS. 1 and 2 illustrate that all the light emitting regions PXA-R, PXA-G, and PXA-B have similar area, but one or more embodiments of the disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas if (e.g., when) viewed on a plane defined by the first directional axis DR1 and the second directional axis DR2 (e.g., in a plan view).

In one or more embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality desired or required in the display apparatus DD. For example, the arrangement form of the light emitting regions PXA-R, PXA-G, and PXA-B may be a pentile (PENTILE™) arrangement form or a diamond (Diamond Pixel™) arrangement form, (PENTILE™ and Diamond Pixel™ are registered trademarks owned by Samsung Display Co., Ltd.).

In some embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but one or more embodiments of the disclosure is not limited thereto.

Hereinafter, FIG. 3 to FIG. 6 are cross-sectional views schematically showing light emitting devices according to one or more embodiments. The light emitting device ED of one or more embodiments may include a first electrode EL1, a hole transport region HTR, an emission layer EML, an electron transport region ETR, and a second electrode EL2 stacked in order (e.g., stacked sequentially).

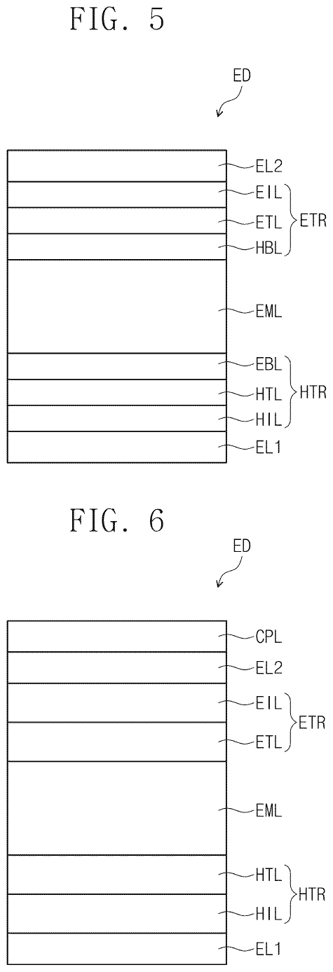

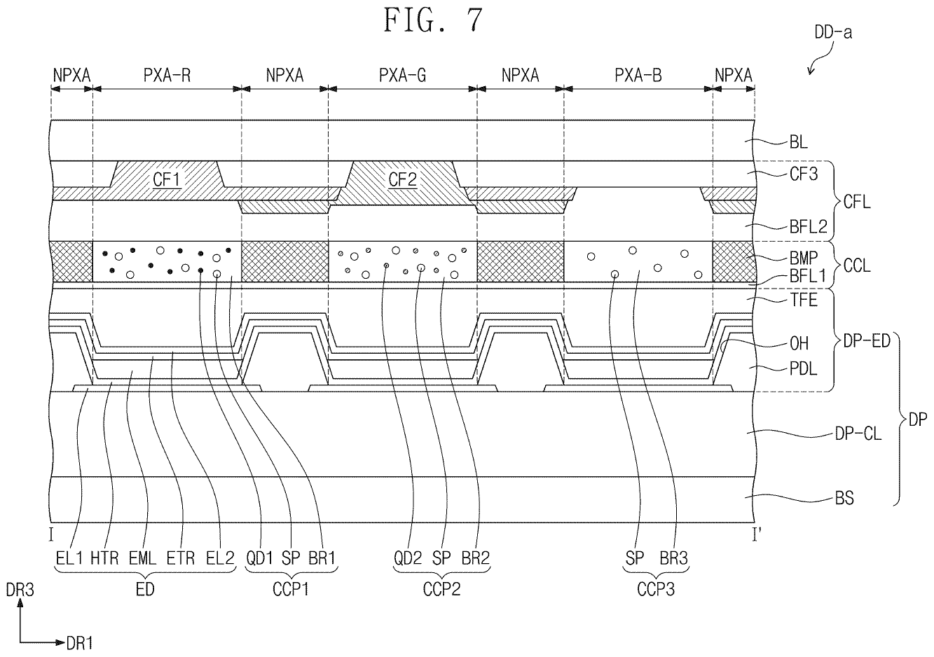

Compared with FIG. 3, FIG. 4 illustrates a cross-sectional view of a light emitting device ED of one or more embodiments, in which a hole transport region HTR includes a hole injection layer HIL and a hole transport layer HTL, and an electron transport region ETR includes an electron injection layer EIL and an electron transport layer ETL. In some embodiments, compared with FIG. 3, FIG. 5 illustrates a cross-sectional view of a light emitting device ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting device ED of one or more embodiments including a capping layer CPL arranged on a second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, one or more embodiments of the disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, L₁, Ca, LiF, Mo, Ti, W, In, Sn, and Zn, a compound of two or more selected from among these, a mixture of two or more selected from among these, and/or an oxide thereof.

If the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, L₁, Ca, LiF/Ca (a stacked structure of LiF and Ca), LiF/Al (a stacked structure of LiF and Al), Mo, Ti, W, a compound or mixture thereof (e.g., a mixture of Ag and Mg). In one or more embodiments, the first electrode EL1 may have a multilayer structure including a reflective film or a transflective film formed of the herein-described materials, and a transparent conductive film formed of ITO, IZO, ZnO, ITZO, and/or the like. For example, the first electrode EL1 may have a three-layer structure of ITO/Ag/ITO, but one or more embodiments of the disclosure is not limited thereto. One or more embodiments of the disclosure is not limited thereto, and the first electrode EL1 may include the herein-described metal materials, combinations of at least two metal materials of the herein-described metal materials, oxides of the herein-described metal materials, and/or the like. The thickness of the first electrode EL1 may be from about 700 angstrom (Å) to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but one or more embodiments of the disclosure is not limited thereto.

The hole transport region HTR may be formed using one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

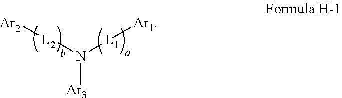

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In one or more embodiments, if (e.g., when) a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. In one or more embodiments, the compound represented by Formula H-1 may be a diamine compound in which at least one among Ar₁ to Ar₃ includes the amine group as a substituent. In some embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one among (e.g., selected from among) the compounds in Compound Group H. However, the compounds listed in Compound Group H are examples, and the compounds represented by Formula H-1 are not limited to those represented by Compound Group H:

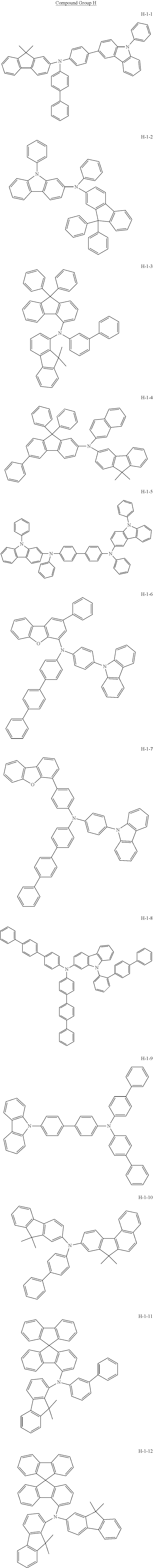

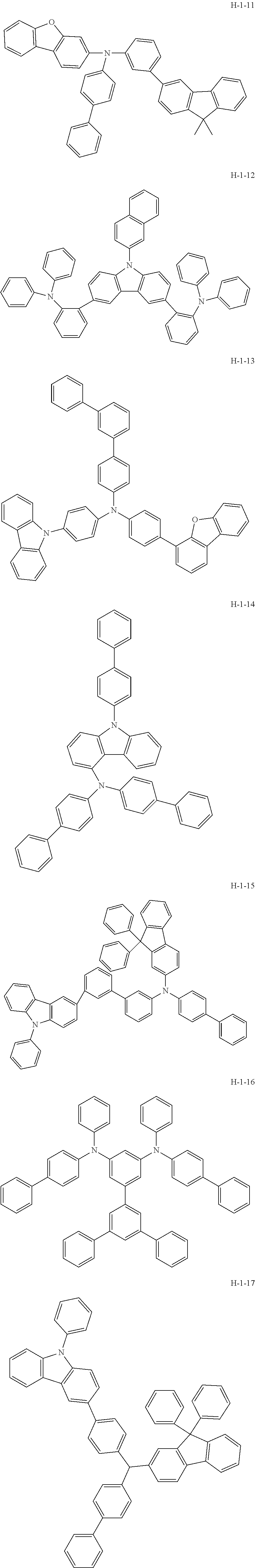

The hole transport region HTR may include at least one selected from among a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

The hole transport region HTR may include at least one selected from among a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), and/or the like.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the herein-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, if (e.g., when) the hole transport region HTR includes the electron blocking layer EBL, the electron blocking layer EBL may have a thickness of about 10 Å to about 1,000 Å. If the thicknesses of the hole transport region HTR, the hole injection layer HIL, the hole transport layer HTL and the electron blocking layer EBL satisfy the herein-described ranges, satisfactory hole transport properties may be achieved without a substantial increase in driving voltage.

The hole transport region HTR may further include a charge generating material to increase conductivity in addition to the herein-described materials. The charge generating material may be dispersed uniformly (e.g., substantially uniformly) or non-uniformly (e.g., substantially non-uniformly) in the hole transport region HTR. The charge generating material may be, for example, a p-dopant. The p-dopant may include at least one of a halogenated metal compound, a quinone derivative, a metal oxide, or a cyano group-containing compound, but one or more embodiments of the disclosure is not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but one or more embodiments of the disclosure is not limited thereto.

As described herein, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be used as a material to be included in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1000 Å, or about 100 Å to about 300 Å. The emission layer EML may have a single layer formed of a single material, a single layer formed of a plurality of different materials, or a multi-layered structure having a plurality of layers formed of a plurality of different materials.

The light-emitting element ED according to one or more embodiments may contain a fused polycyclic compound represented by Formula 1 in at least one functional layer arranged between the first electrode EL1 and the second electrode EL2. In the light-emitting element ED according to one or more embodiments, the emission layer EML may contain the fused polycyclic compound according to one or more embodiments. In one or more embodiments, the emission layer EML may contain the fused polycyclic compound according to one or more embodiments as a dopant. The fused polycyclic compound according to one or more embodiments may be a dopant material of the emission layer EML. In one or more embodiments, in this specification, the fused polycyclic compound according to one or more embodiments may be referred to as a first compound.

### Fused Polycyclic Compound

The fused polycyclic compound according to one or more embodiments includes at least two fused structures in which first to third aromatic rings are fused via a first boron atom, a first heteroatom, and a second heteroatom. In the at least two fused ring structures included in the fused polycyclic compound according to one or more embodiments, at least one among a plurality of heteroatoms are nitrogen atoms.

The fused polycyclic compound according to one or more embodiments corresponds to the at least two of fused ring structures, described previously, including one first fused ring and at least one second fused ring. The first fused ring is a fused ring in which a (1-1)-th to (3-1)-th aromatic rings are fused via a (1-1)-th boron atom, a (1-1)-th heteroatom, and a (2-1)-th heteroatom. The second fused ring is a fused ring in which the (1-2)-th to (3-2)-th aromatic rings are fused via a (1-2)-th boron atom, a (1-2)-th heteroatom, and a (2-2)-th heteroatom. In the first fused ring, the (1-1)-th to (3-1)-th aromatic rings are each connected to the (1-1)-th boron atom, the (1-1)-th and (3-1)-th aromatic rings are each connected with each other via the (1-1)-th heteroatom, the (2-1)-th aromatic ring and the (3-1)-th aromatic rings are each connected with each other via the (2-1)-th heteroatom. In the first fused ring, at least one among the (1-1)-th heteroatom and the (2-1)-th heteroatom may be a nitrogen atom.

In the second fused ring, the (1-2)-th to (3-2)-th aromatic rings are each connected to the (1-2)-th boron atom, the (1-2)-th and (3-2)-th aromatic rings are each connected to each other via the (1-2)-th heteroatom, and the (2-2)-th aromatic ring and (3-2)-th aromatic ring are each connected to each other via the (2-2)-th heteroatom. In one or more embodiments, in each of the first fused ring and the second fused ring, the boron atom and two heteroatoms, and a fused structure in which the first to third aromatic rings are fused via the boron atom and the two heteroatoms may be referred to as a “fused core”.

In one or more embodiments, the (1-1)-th to (3-1)-th aromatic rings and the (1-2)-th to (3-2)-th aromatic rings may each independently be a substituted or unsubstituted monocyclic aromatic hydrocarbon ring having 6 to 30 ring-forming carbons. The (1-1)-th to (3-1)-th aromatic rings and the (1-2)-th to (3-2)-th aromatic rings may each independently be 6-membered aromatic hydrocarbon ring. For example, the (1-1)-th to (3-1)-th aromatic rings and the (1-2)-th to (3-2)-th aromatic rings may each independently be a benzene ring.

In the fused polycyclic compound according to one or more embodiments, the second fused ring is connected to the first fused ring. The second fused ring is connected to the (1-1)-th aromatic ring or the (2-1)-th aromatic ring. In the fused polycyclic compound according to one or more embodiments, if (e.g., when) two second fused rings are provided, one among the two of the second fused rings may be connected to the (1-1)-th aromatic ring, and the other may be connected to the (2-1)-th aromatic ring. The second fused ring is connected to the first fused ring via one of carbons contained in the (1-2)-th to (3-2)-th aromatic rings. The second fused ring is directly connected to the first fused ring without an additional linker.

The fused polycyclic compound according to one or more embodiments may be represented by Formula 1.

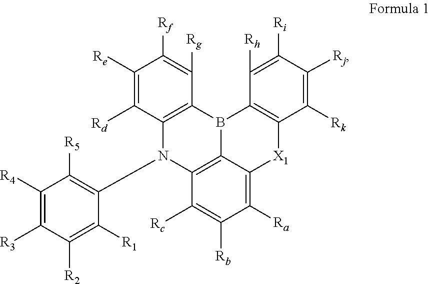

The fused polycyclic compound according to one or more embodiments represented by Formula 1 may include a fused structure of three aromatic rings via one boron atom, a first nitrogen atom, and a second additional atom. In one or more embodiments, a skeleton structure represented by Formula 1 may correspond to the herein-described first fused ring. In Formula 1, a benzene ring substituted with a substituent represented by R_{d} to R_{g} may correspond to the herein-described the (1-1)-th aromatic ring, a benzene ring substituted with a substituent represented by Rₕ to Rₖ may correspond to the herein-described the (2-1)-th aromatic ring, and a benzene ring substituted with a substituent represented by Rₐ to R_{c} may correspond to the herein-described the (3-1)-th aromatic ring. In Formula 1, the nitrogen atom may correspond to the herein-described (1-1)-th heteroatom, and X₁ may correspond to the herein-described (2-1)-th heteroatom. In Formula 1, at least one among substituents represented by R_{d} to Rₖ may be the herein-described second fused ring.

In Formula 1, X₁ may be O, S, or NR₆. For example, X₁ may be O, or NR₆.

In Formula 1, R₁ to R₆, and Rₐ to Rₖ may each independently be a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons. In one or more embodiments, R₁ to R₆, and Rₐ to Rₖ may be each bonded to an adjacent group to form a ring. For example, R₁ to R₆ may each independently be a hydrogen atom, a deuterium atom, a substituted or unsubstituted methyl group, a substituted or unsubstituted t-butyl group, a substituted or unsubstituted phenyl group, a substituted or unsubstituted terphenyl group. Rₐ to Rₖ may each independently be a hydrogen atom, a deuterium atom, a substituted or unsubstituted methyl group, a substituted or unsubstituted t-butyl group, a substituted or unsubstituted phenyl group, a substituted or unsubstituted carbazole group, a substituted or unsubstituted dibenzofuran group, or a substituted or unsubstituted dibenzothiophene group.

In Formula 1, at least one selected from among R_{d} to Rₖ may be a substituent represented by Formula 2. In Formula 1, one selected from among R_{d} to Rₖ may be the substituent represented by Formula 2. In one or more embodiments, in Formula 1, two selected from among R_{d} to Rₖ may be each the substituents represented by Formula 2. In one or more embodiments, if (e.g., when) two or more selected from among R_{d} to Rₖ are substituents represented by Formula 2, the two or more substituents may be the same as or different from each other.

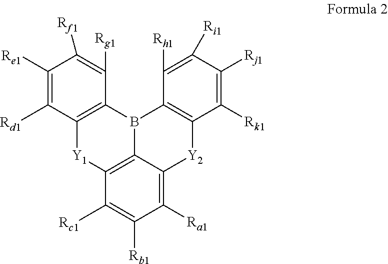

The substituent represented by Formula 2 may include a fused structure of three aromatic rings via one boron atom, a first nitrogen atom and a second additional atom. In one or more embodiments, a skeleton structure represented by Formula 2 may correspond to the herein-described second fused ring. In Formula 2, a benzene group substituted with substituents represented by R_{d1} to R_{g1} may correspond to the (1-2)-th aromatic ring, a benzene group substituted with substituents represented by Rₕ₁ to Rₖ₁ may correspond to the (2-2)-th aromatic ring, and a benzene group substituted with substituents represented by Rₐ₁ to R_{c1} may correspond to the (3-2)-th aromatic ring. In Formula 1, Y₁ may correspond to the herein-described (1-2)-th heteroatom, and Y₂ may correspond to the herein-described (2-2)-th heteroatom. In Formula 2, one among the substituents represented by Rₐ₁ to Rₖ₁ is a portion to which the herein-described first fused ring is connected.

In Formula 2, Y₁ and Y₂ may each independently be O, S, or NR₇. Y₁ and Y₂ may be the same as or different from each other. In one or more embodiments, all (e.g., each) Y₁ and Y₂ may be O, or NR₇. In one or more embodiments, any one selected from among Y₁ and Y₂ may be O and the other may be NR₇.

In one or more embodiments, in Formula 1, previously described, if X₁ is NR₆, at least one selected from among Y₁ and Y₂ is O or S. For example, in the fused polycyclic compound according to one or more embodiments, a case where X₁ in Formula 1 is NR₆ and both (e.g., simultaneously) Y₁ and Y₂ in Formula 2 are NR₇ is excluded. A case where, in the fused polycyclic compound according to one or more embodiments, all (e.g., each of) the at least two fused rings within a molecule contain only nitrogen atom as a skeleton-forming heteroatom.

In Formula 2, R₇, and Rₐ₁ to Rₖ₁ may each independently be a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons. In one or more embodiments, each of R₇, and Rₐ₁ to Rₖ₁ may be bonded to an adjacent group to form a ring. For example, R₇ may be a substituted or unsubstituted phenyl group, or a substituted or unsubstituted terphenyl group. Rₐ₁ to Rₖ₁ may each independently be a hydrogen atom, a deuterium atom, a substituted or unsubstituted methyl group, a substituted or unsubstituted t-butyl group, a substituted or unsubstituted phenyl group, a substituted or unsubstituted carbazole group, a substituted or unsubstituted dibenzofuran group, or a substituted or unsubstituted dibenzothiophene group. In one or more embodiments, each of Rₐ₁ to Rₖ₁ may independently be a substituted or unsubstituted oxy group, a substituted or unsubstituted thio group, a substituted or unsubstituted vinyl group, or a substituted or unsubstituted phenyl group, or may be bonded to an adjacent group to form an aromatic hydrocarbon ring, or aromatic hetero ring. For example, each of Rₐ₁ to Rₖ₁ may independently be bonded to an adjacent group to form a benzene ring, a benzofuran ring, or a benzothiophene ring.

In Formula 2, any one selected from among Rₐ₁ to Rₖ₁ may be a portion to which Formula 1 is connected. The substituent represented by Formula 2 may be connected to a skeleton structure represented by Formula 1 at any one portion among Rₐ₁ to Rₖ₁. The substituent represented by Formula 2 may be connected to any one portion selected from among R_{d} to Rₖ in Formula 1, described previously, at any one portion selected from among Rₐ₁ to Rₖ₁. In one or more embodiments, the substituent represented by Formula 2 may be directly linked to the skeleton structure of Formula 1 without an additional linker.

In one or more embodiments, the first compound represented by Formula 1 may be represented by Formula 1-1 or Formula 1-2.

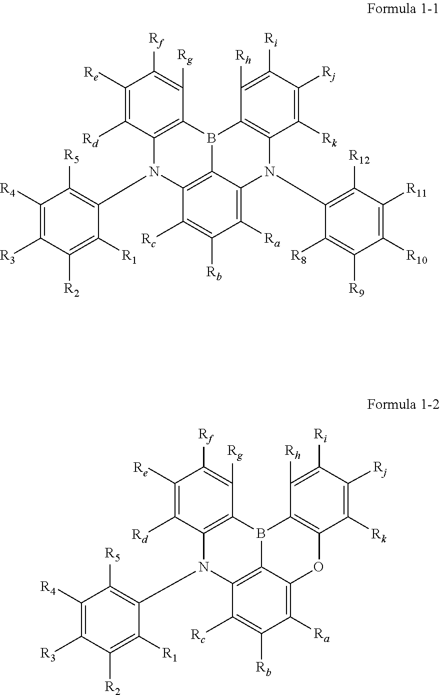

Each of Formula 1-1 and Formula 1-2 shows a case where X₁ in Formula 1 is specified.

In Formula 1-1 and Formula 1-2, R₈ to R₁₂ may each independently be a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons. In one or more embodiments, R₈ to R₁₂ may each independently be bonded to an adjacent group to form a ring. For example, R₁ to R₆ may each independently be a hydrogen atom, a deuterium atom, a substituted or unsubstituted methyl group, a substituted or unsubstituted t-butyl group, a substituted or unsubstituted phenyl group, or a substituted or unsubstituted terphenyl group.

In Formula 1-1 and Formula 1-2, the same descriptions of R₁ to R₅, and Rₐ to Rₖ in Formula 1 may be similarly applied.

In one or more embodiments, the substituent represented by Formula 2 may be represented by any one selected from among Formula 2-1 to Formula 2-3.

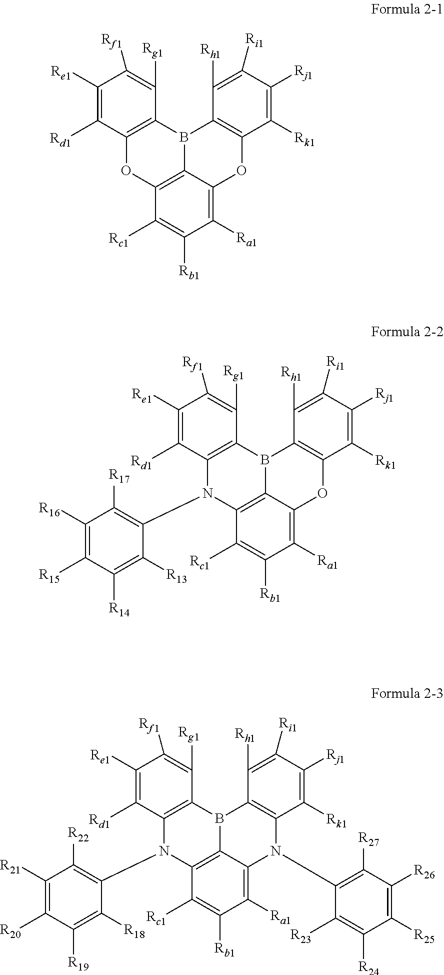

Each of Formula 2-1 to Formula 2-3 shows a case where Y₁ and Y₂ in Formula 1 are specified.

In Formula 2-1 to Formula 2-3, R₁₃ to R₂₇ may each independently be a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons. In one or more embodiments, each of R₁₃ to R₂₇ may be bonded to an adjacent group to form a ring. For example, R₁₃ to R₂₇ may each independently be a hydrogen atom, a deuterium atom, a substituted or unsubstituted methyl group, a substituted or unsubstituted t-butyl group, a substituted or unsubstituted phenyl group, or a substituted or unsubstituted terphenyl group.

In Formula 2-1 to Formula 2-3, the same descriptions of Rₐ₁ to Rₖ₁ in Formula 2 may be similarly applied.

In one or more embodiments, the first compound represented by Formula 1 may be represented by any one selected from among Formula 3-1 to Formula 3-3.

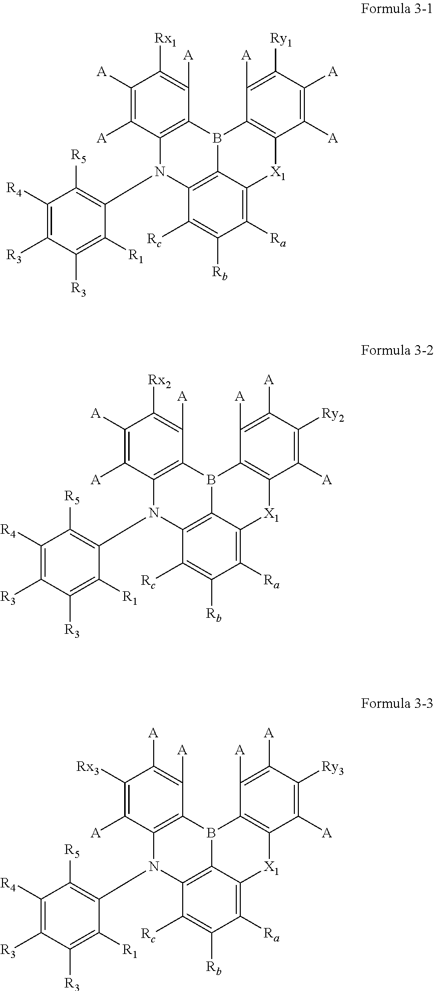

Each of Formula 3-1 to Formula 3-3 shows a case where each of R_{d} to Rₖ in Formula 1 is specified.

In Formula 3-1 to Formula 3-3, A may be a hydrogen atom or a deuterium atom. A plurality of A may be the same as or different from each other. For example, the plurality of A may be all (e.g., each) hydrogen atoms. In one or more embodiments, the plurality of A may be all (e.g., each) deuterium atoms.

In Formula 3-1, Rₓ₁ and R_{y1} may each independently be a substituted or unsubstituted amine group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. For example, Rₓ₁ and R_{y1} may each independently be a substituted or unsubstituted diphenylamine group, a substituted or unsubstituted t-butyl group, a substituted or unsubstituted phenyl group, or a substituted or unsubstituted carbazole group.

In Formula 3-1, at least one selected from among Rₓ₁ and R_{y1} may be the substituent represented by Formula 2. For example, any one selected from among Rₓ₁ and R_{y1} may be the substituent represented by Formula 2, and the others selected from among Rₓ₁ and R_{y1} may be a substituted or unsubstituted phenyl group, or a substituted or unsubstituted carbazole group. In one or more embodiments, both (e.g., simultaneously) Rₓ₁ and R_{y1} may be the substituents represented by Formula 2.

In Formula 3-2, Rₓ₂ and R_{y2} may each independently be a substituted or unsubstituted amine group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. For example, Rₓ₂ and R_{y2} may each independently be a substituted or unsubstituted diphenylamine group, a substituted or unsubstituted t-butyl group, a substituted or unsubstituted phenyl group, or a substituted or unsubstituted carbazole group.

In Formula 3-2, at least one selected from among Rₓ₂ and R_{y2} may be the substituent represented by Formula 2. For example, any one selected from among Rₓ₂ and R_{y2} may be a substituent represented by Formula 2, and the others selected from among Rₓ₂ and R_{y2} may be an unsubstituted phenyl group, or a substituted or unsubstituted carbazole group. In one or more embodiments, both (e.g., simultaneously) Rₓ₂ and R_{y2} may be substituents represented by Formula 2.

In Formula 3-3, Rₓ₃ and R_{y3} may each independently be a substituted or unsubstituted amine group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. For example, Rₓ₃ and R_{y3} may each independently be a substituted or unsubstituted diphenylamine group, a substituted or unsubstituted t-butyl group, a substituted or unsubstituted phenyl group, or a substituted or unsubstituted carbazole group.

In Formula 3-3, at least one selected from among Rₓ₃ and R_{y3} may be the substituent represented by Formula 2. For example, any one selected from among Rₓs and R_{y3} may be a substituent represented by Formula 2, and the others selected from among Rₓ₃ and R_{y3} may be an unsubstituted phenyl group, or a substituted or unsubstituted carbazole group. In one or more embodiments, both (e.g., simultaneously) Rₓ₃ and R_{y3} may be substituents represented by Formula 2.

In Formula 3-1 to Formula 3-3, the same descriptions of X₁, R₁ to R₅, and Rₐ to R_{c} in Formula 1 may be similarly applied.

In one or more embodiments, the substituent represented by Formula 2 may be represented by any one among Formula 4-1 to Formula 4-3.

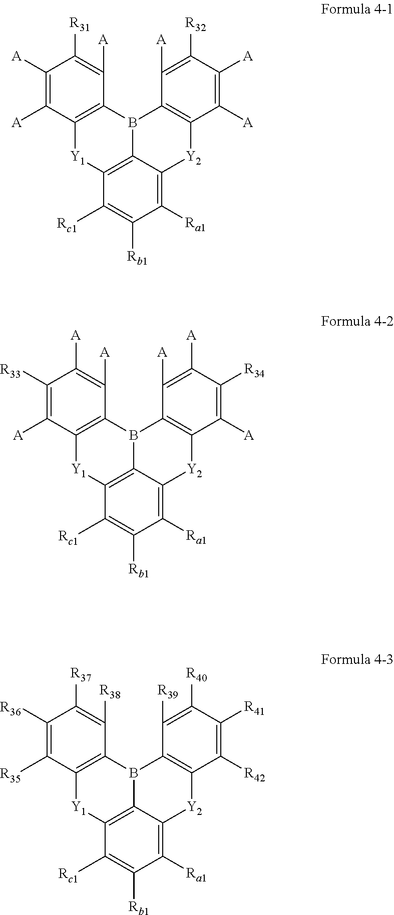

Each of Formula 4-1 to Formula 4-3 shows a case where each of R_{d1} to Rₖ₁ in Formula 2 is specified.

In Formula 4-1 to Formula 4-3, A may be a hydrogen atom or a deuterium atom. A plurality of A may be the same as or different from each other. For example, the plurality of A may be all (e.g., each) hydrogen atoms. In one or more embodiments, the plurality of A may be all (e.g., each) deuterium atoms.

In Formula 4-1 to Formula 4-3, R₃₁ to R₄₂ may each independently be a hydrogen atom, a deuterium atom, a halogen atom, a substituted or unsubstituted amine group, a substituted or unsubstituted oxy group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. In one or more embodiments, each of R₃₁ to R₄₂ may be bonded to an adjacent group to form a ring. For example, R₃₁ to R₄₂ may each independently be a hydrogen atom, a deuterium atom, a substituted or unsubstituted methyl group, a substituted or unsubstituted t-butyl group, a substituted or unsubstituted phenyl group, or a substituted or unsubstituted carbazole group, or a substituted or unsubstituted dibenzofuran group, or a substituted or unsubstituted dibenzothiophene group.

In Formula 4-3, at least one adjacent pair (e.g., a pair of groups or atoms thereof) selected from among R₃₅ to R₄₂ may be bonded to each other to form a ring. Each of R₃₅ to R₄₂ may be a substituted or unsubstituted oxy group, a substituted or unsubstituted thio group, a substituted or unsubstituted vinyl group, or a substituted or unsubstituted phenyl group, or may be bonded to each other to an adjacent group to form an aromatic hydrocarbon ring or an aromatic hetero ring. For example, each of R₃₅ to R₄₂ may be bonded to an adjacent group to form a benzene ring, a benzofuran ring, or a benzothiophene ring. In one or more embodiments, (e.g., pairs of) adjacent R₃₅ and R₃₆, R₃₇ and R₃₈, R₃₉ and R₄₀, and R₄₁ and R₄₂, may each be bonded with each other to form an aromatic hydrocarbon ring or an aromatic hetero ring.

In Formula 4-1 to Formula 4-3, the same descriptions of Y₁, Y₂, and Rₐ₁ to R_{c1} in Formula 2 may be similarly applied.

In one or more embodiments, the first compound represented by Formula 1 may be represented by Formula 5.

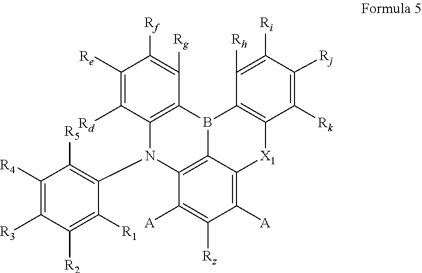

Formula 5 show a case where each of Rₐ to R_{c} in Formula 1 is specified.

In Formula 5, A may be a hydrogen atom or a deuterium atom. A plurality of A may be the same as or different from each other. For example, the plurality of A may be all (e.g., each) hydrogen atoms. In one or more embodiments, the plurality of A may be all (e.g., each) deuterium atoms.

In Formula 5, R_{z} may be a substituted or unsubstituted amine group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. For example, R_{z} may be a substituted or unsubstituted diphenylamine group, a substituted or unsubstituted methyl group, a substituted or unsubstituted t-butyl group, a substituted or unsubstituted phenyl group, or a substituted or unsubstituted carbazole group. R_{z} may be an unsubstituted t-butyl group.

In Formula 5, the same descriptions of X₁, R₁ to R₅, and R_{d} to Rₖ as those described in Formula 1 may be similarly applied.

In one or more embodiments, the substituent represented by Formula 2 may be represented by Formula 6-1, or Formula 6-2.

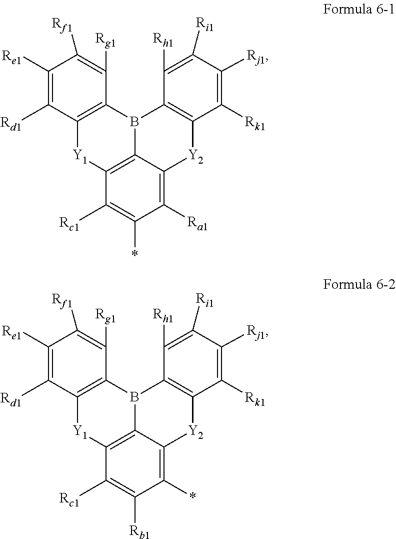

Formula 6-1 and Formula 6-2 show cases where in Formula 2, a portion, to which the skeleton structure of Formula 1 is connected, is specified.

In Formula 6-1 and Formula 6-2,

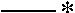 [SMILES: *C]

may be a portion to which the skeleton structure represented by Formula 1 is connected. The substituent structure represented by Formula 6-1 and Formula 6-2 may be bonded to at least one portion selected from among R_{d} to Rₖ in Formula 1, described previously, at a position represented by

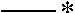 [SMILES: *C]

In one or more embodiments, the substituent represented by Formula 6-1 and Formula 6-2 may be directly linked to the skeleton structure of Formula 1 without an additional linker. Each of substituents represented by Formula 6-1 and Formula 6-2 may be directly linked to the herein-described skeleton structure of Formula 1 at the position represented by

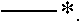

In Formula 6-1 and Formula 6-2, the same descriptions of Y₁, Y₂, and Rₐ₁ to Rₖ₁ as those described in Formula 2 may be similarly applied.

In one or more embodiments, the first compound represented by Formula 1 may be represented by Formula 7.

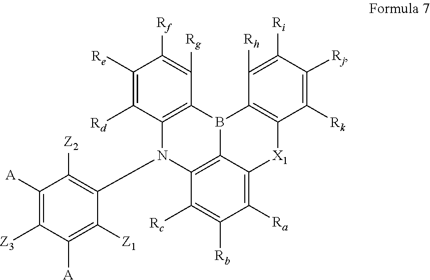

Formula 7 shows a case where each of R₁ to R₅ in Formula 1 is specified.

In Formula 7, A may be a hydrogen atom or a deuterium atom. A plurality of A may be the same as or different from each other. For example, the plurality of A may be all (e.g., each) hydrogen atoms. In one or more embodiments, the plurality of A may be all (e.g., each) deuterium atoms.

In Formula 7, Z₁ to Z₃ may each independently be a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. For example, Z₁ to Z₃ may each independently be a substituted or unsubstituted methyl group, a substituted or unsubstituted t-butyl group, or a substituted or unsubstituted phenyl group. Z₁ and Z₂ may be substituted or unsubstituted phenyl groups, and Z₃ may be a substituted or unsubstituted t-butyl group. In one or more embodiments, Z₁ and Z₂ may be substituted or unsubstituted phenyl groups, and Z₃ may be a hydrogen atom.

In one or more embodiments, in each of Formula 1 and Formula 7, a substituent that is connected to a nitrogen atom may be represented by Formula S. The benzene ring substituted with R₁ to R₅ in Formula 1, and each of the benzene ring substituted with A, and Z₁ to Z₃ in Formula 7 may be substituents represented by Formula S.

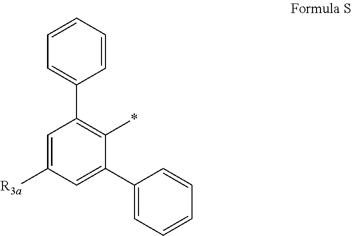

In Formula S, R₃ₐ may be a hydrogen atom, a substituted or unsubstituted t-butyl group, or a substituted or unsubstituted phenyl group.

In Formula S,

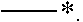

is a portion to which the skeleton structure represented by Formula 1 is connected.

In one or more embodiments, the polycyclic compounds represented by each of Formula 1, Formula 1-1, Formula 1-2, Formula 3-1 to Formula 3-3, Formula 5, and Formula 7 may contain at least one deuterium atom as a substituent. The polycyclic compound represented by each of Formula 1, Formula 1-1, Formula 1-2, Formula 3-1 to Formula 3-3, Formula 5, and Formula 7 may include a structure in which at least one hydrogen atom is substituted with a deuterium atom. The substituent represented by each of Formula 2, Formula 2-1 to Formula 2-3, Formula 4-1 to Formula 4-3, Formula 6-1, and Formula 6-2 may include a structure in which at least one hydrogen atom is substituted with a deuterium atom.

The fused polycyclic compound according to one or more embodiments may be any one among (e.g., selected from among) Compounds present in Compound Group 1. At least one functional layer included in the light-emitting element ED according to one or more embodiments may contain at least one fused polycyclic compound among (e.g., selected from among) the compounds present in Compound Group 1. The light-emitting element ED according to one or more embodiments may contain at least one fused polycyclic compound among e.g., selected from among) the compounds present in Compound Group 1 in the emission layer EML.

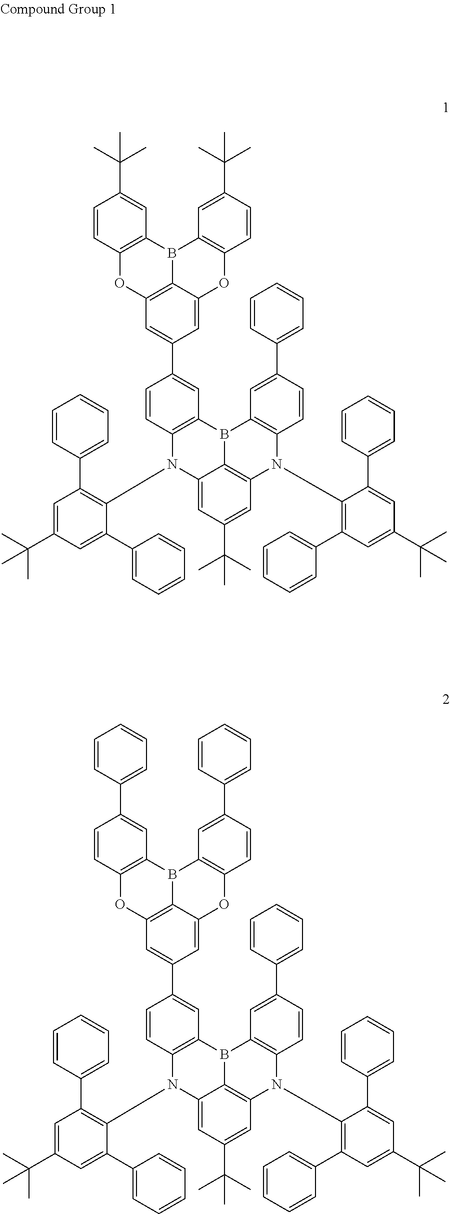

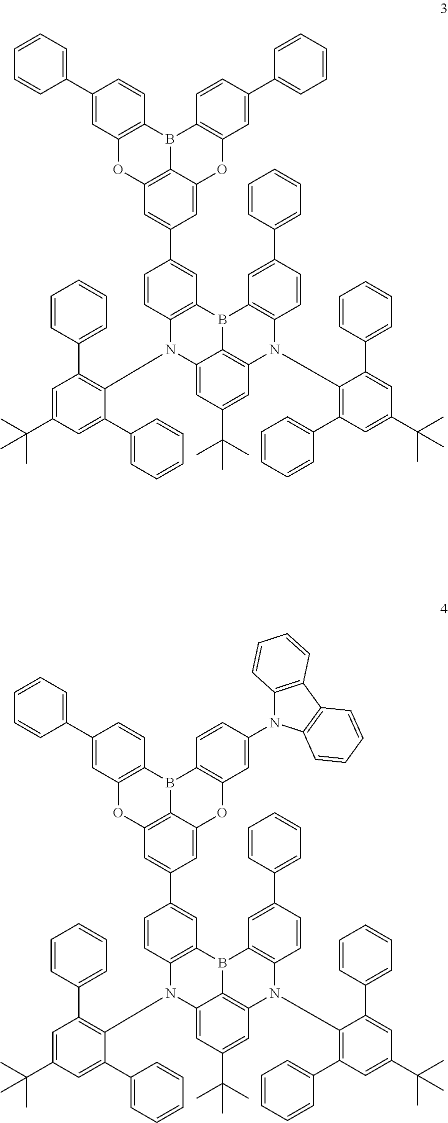

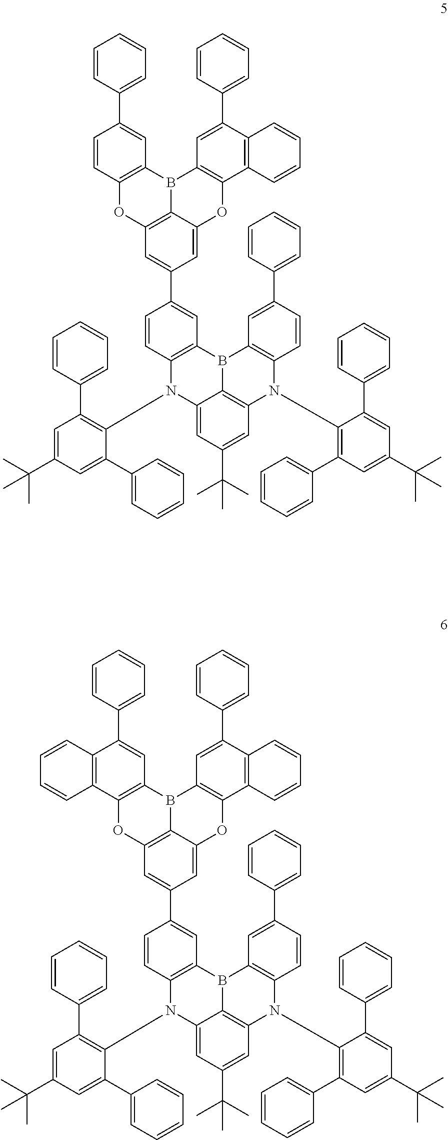

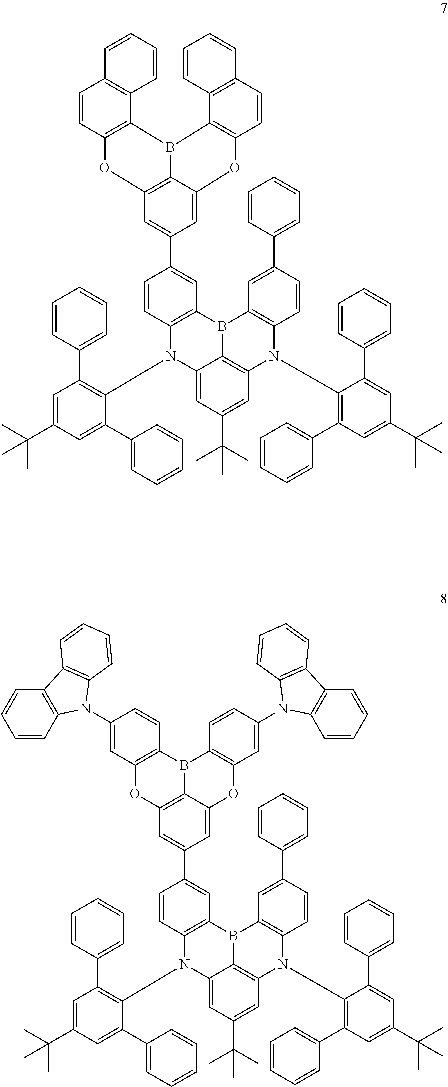 [SMILES: CC(C)(C)c1cc(-c2ccccc2)c(N2c3ccc(-c4ccccc4)cc3B3c4cc(-c5cc6c7c(c5)Oc5ccc8ccccc8c5B7c5c(ccc7ccccc57)O6)ccc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4ccccc4)cc3B3c4cc(-c5cc6c7c(c5)Oc5cc(-n8c9ccccc9c9ccccc98)ccc5B7c5ccc(-n7c8ccccc8c8ccccc87)cc5O6)ccc4N(c4c(-c5ccccc5)cc(C(C)(C)C)cc4-c4ccccc4)c4cc(C(C)(C)C)cc2c43)c(-c2ccccc2)c1]

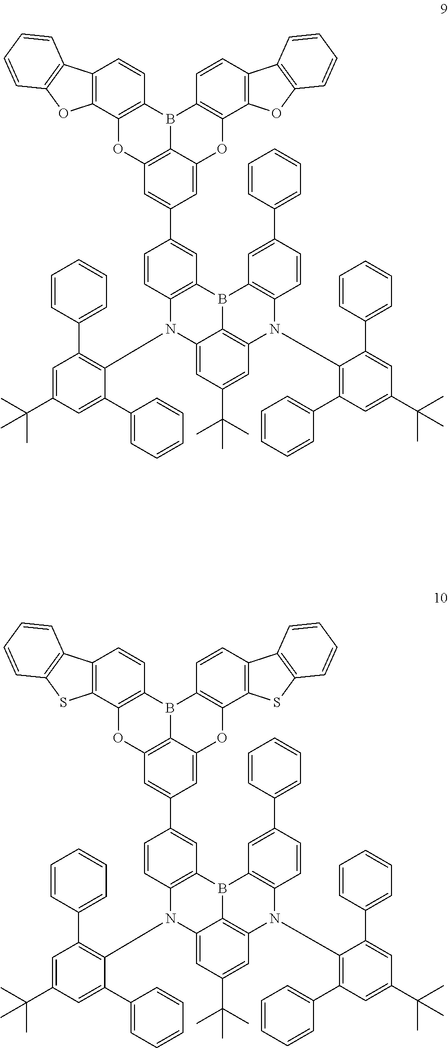

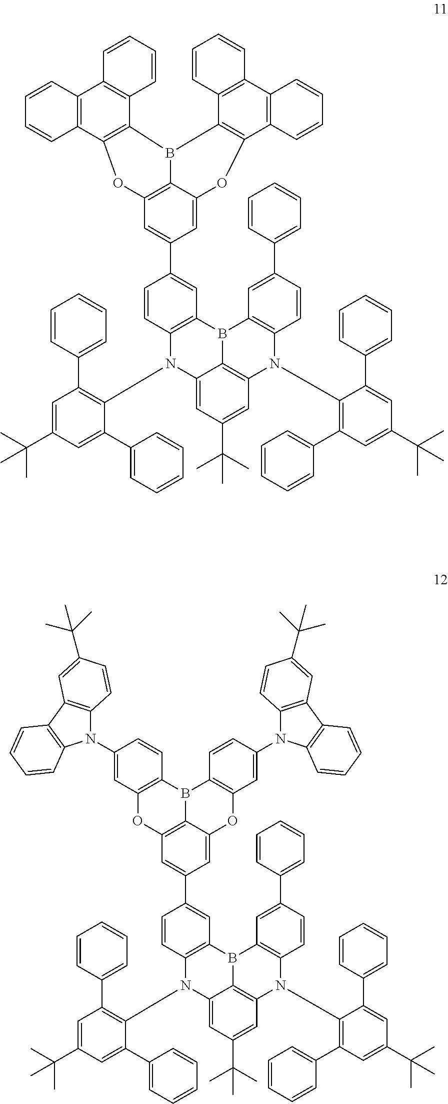 [SMILES: CC(C)(C)c1cc(-c2ccccc2)c(N2c3ccc(-c4ccccc4)cc3B3c4cc(-c5cc6c7c(c5)Oc5c(c8ccccc8c8ccccc58)B7c5c(c7ccccc7c7ccccc57)O6)ccc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4ccccc4)cc3B3c4cc(-c5cc6c7c(c5)Oc5cc(-n8c9ccccc9c9cc(C(C)(C)C)ccc98)ccc5B7c5ccc(-n7c8ccccc8c8cc(C(C)(C)C)ccc87)cc5O6)ccc4N(c4c(-c5ccccc5)cc(C(C)(C)C)cc4-c4ccccc4)c4cc(C(C)(C)C)cc2c43)c(-c2ccccc2)c1]

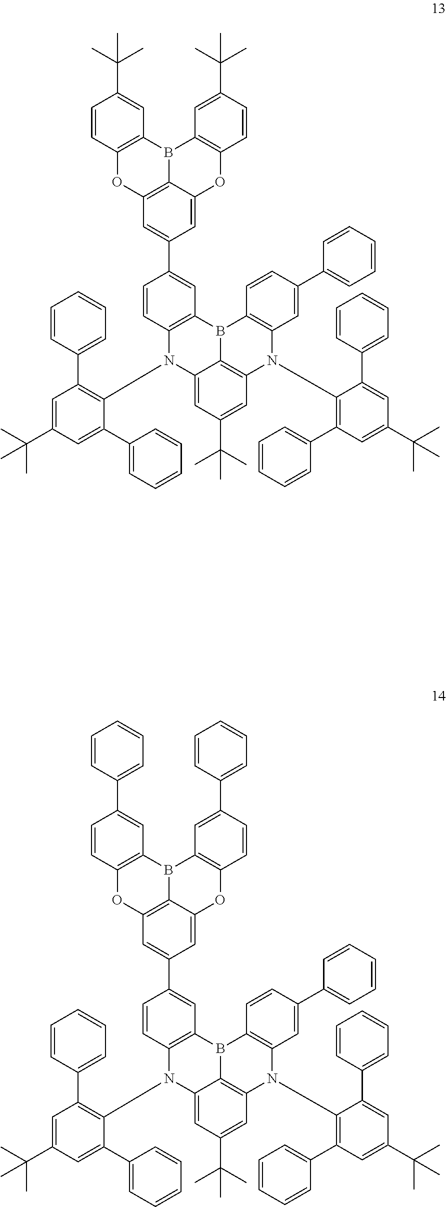

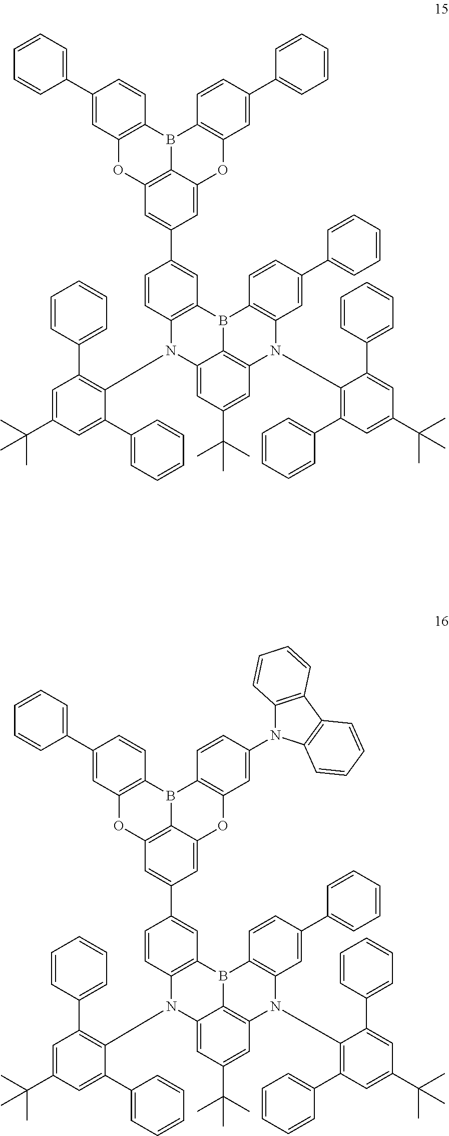

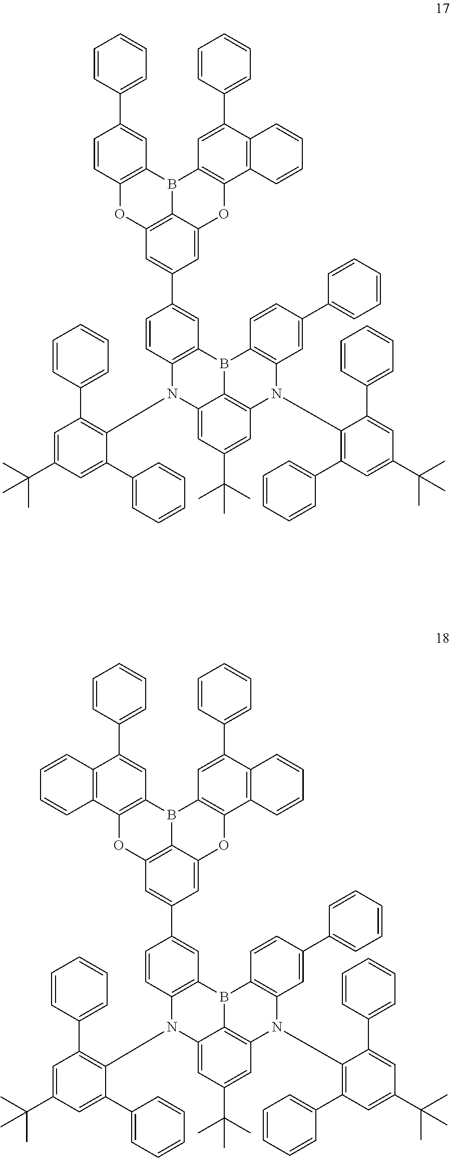

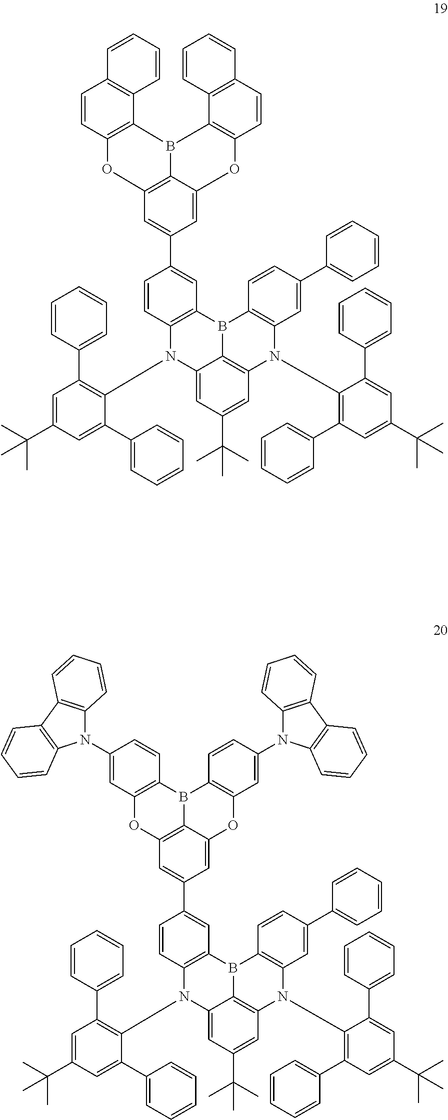 [SMILES: CC(C)(C)c1cc(-c2ccccc2)c(N2c3ccc(-c4cc5c6c(c4)Oc4ccc7ccccc7c4B6c4c(ccc6ccccc46)O5)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-n6c7ccccc7c7ccccc76)cc4O5)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1]

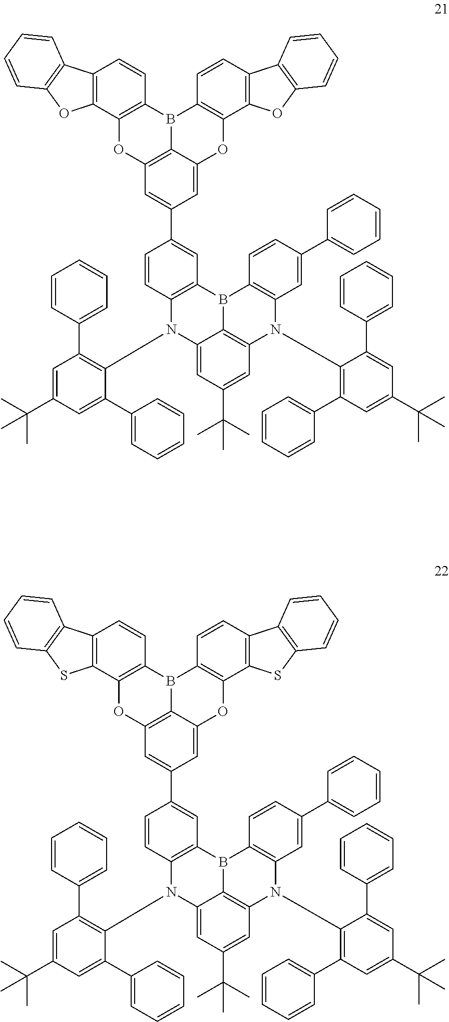

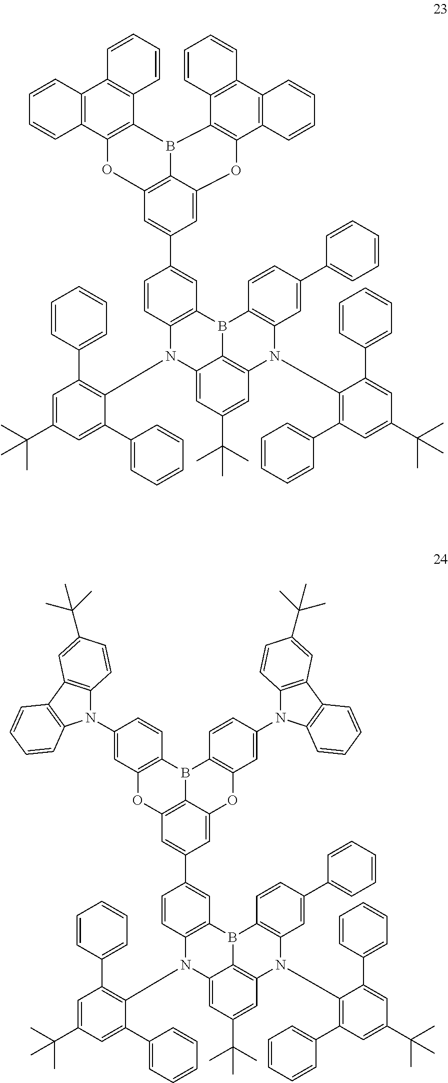 [SMILES: CC(C)(C)c1cc(-c2ccccc2)c(N2c3ccc(-c4cc5c6c(c4)Oc4c(c7ccccc7c7ccccc47)B6c4c(c6ccccc6c6ccccc46)O5)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8cc(C(C)(C)C)ccc87)ccc4B6c4ccc(-n6c7ccccc7c7cc(C(C)(C)C)ccc76)cc4O5)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1]

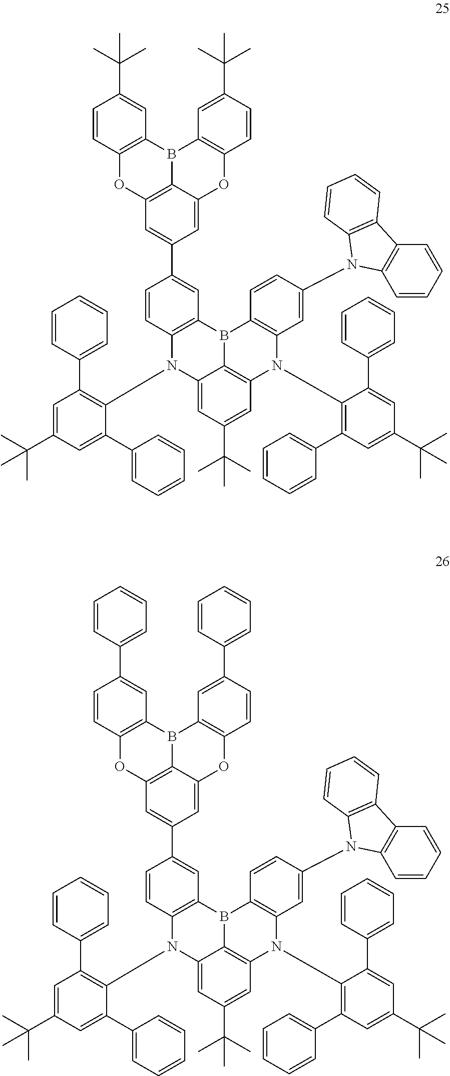

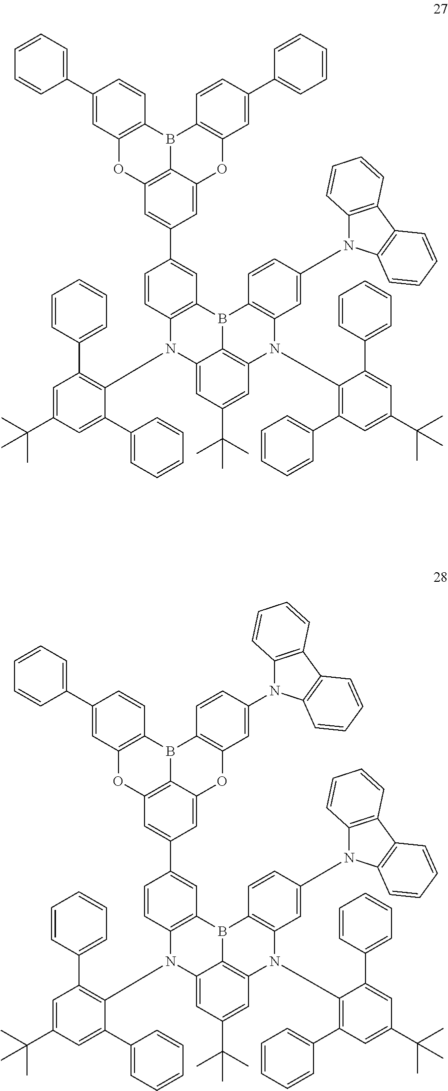

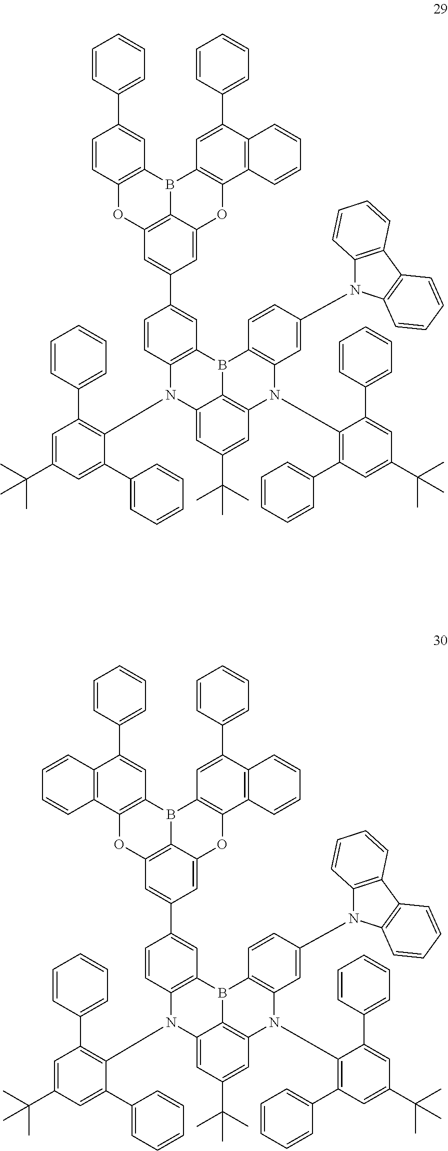

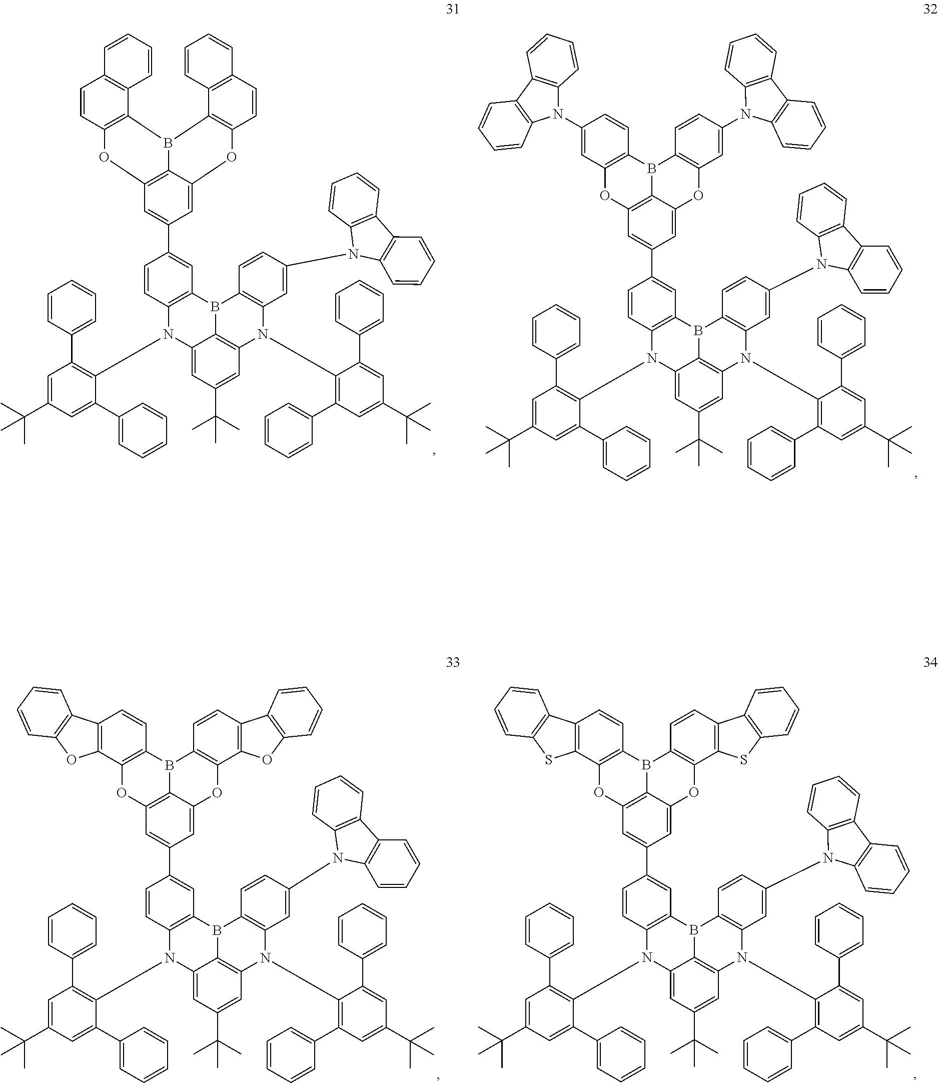

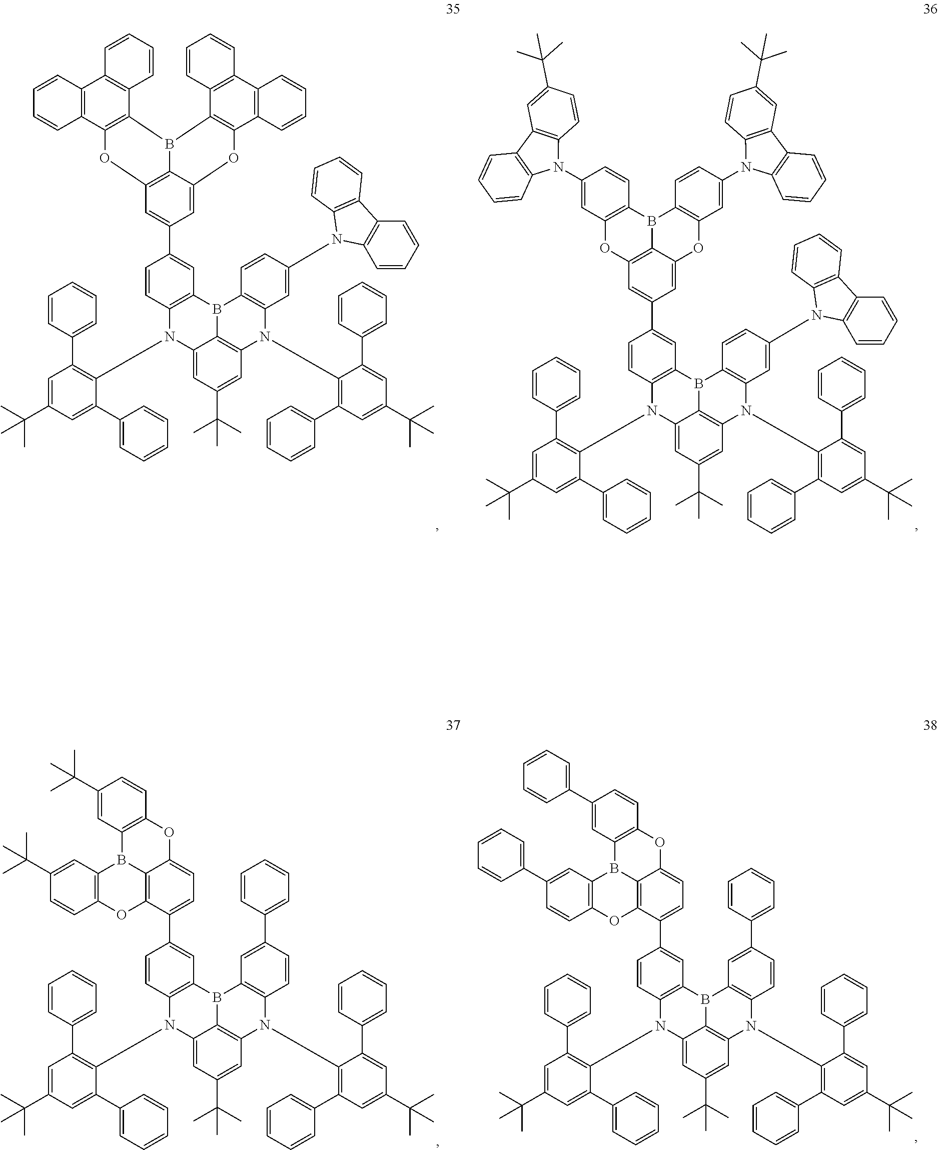

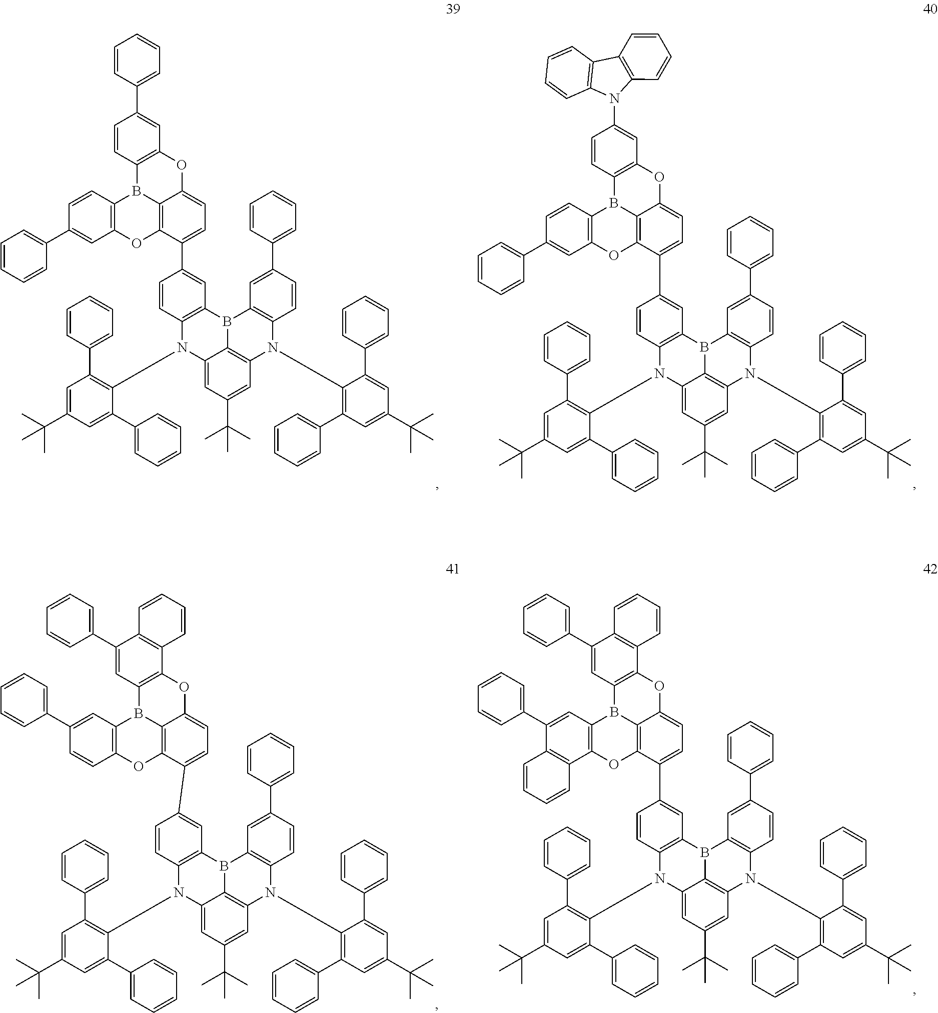

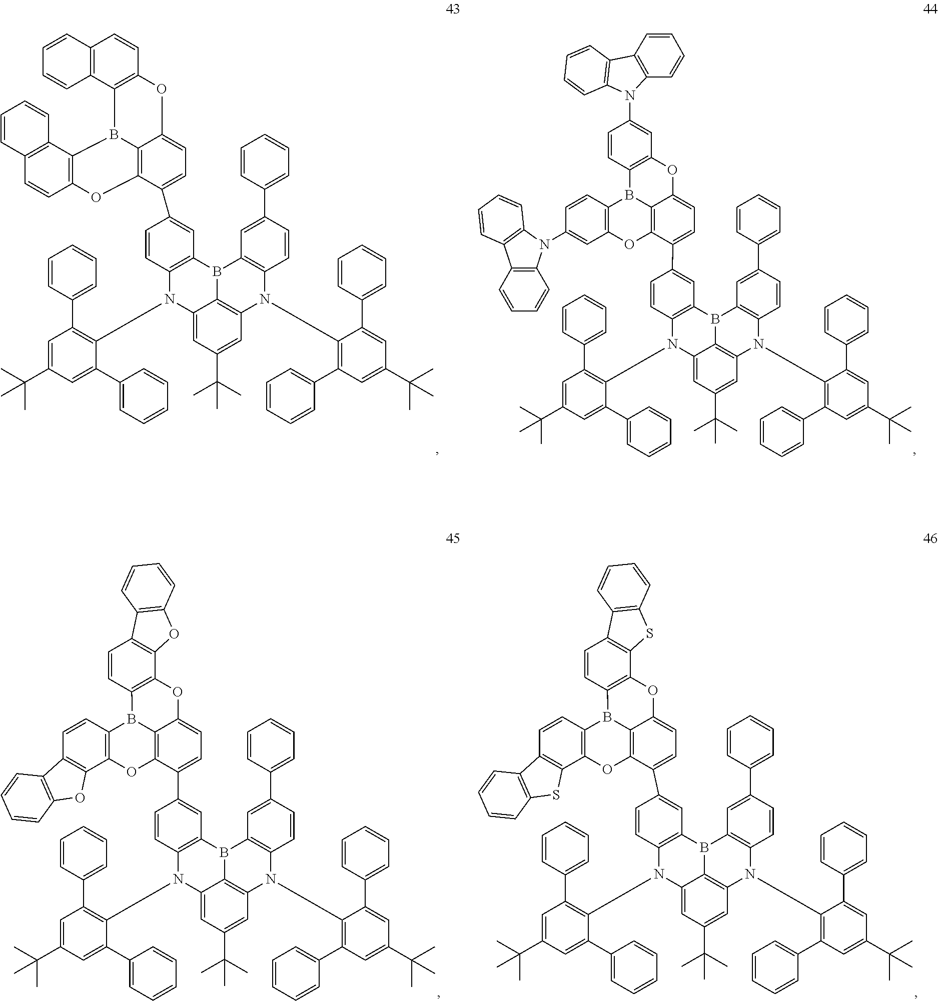

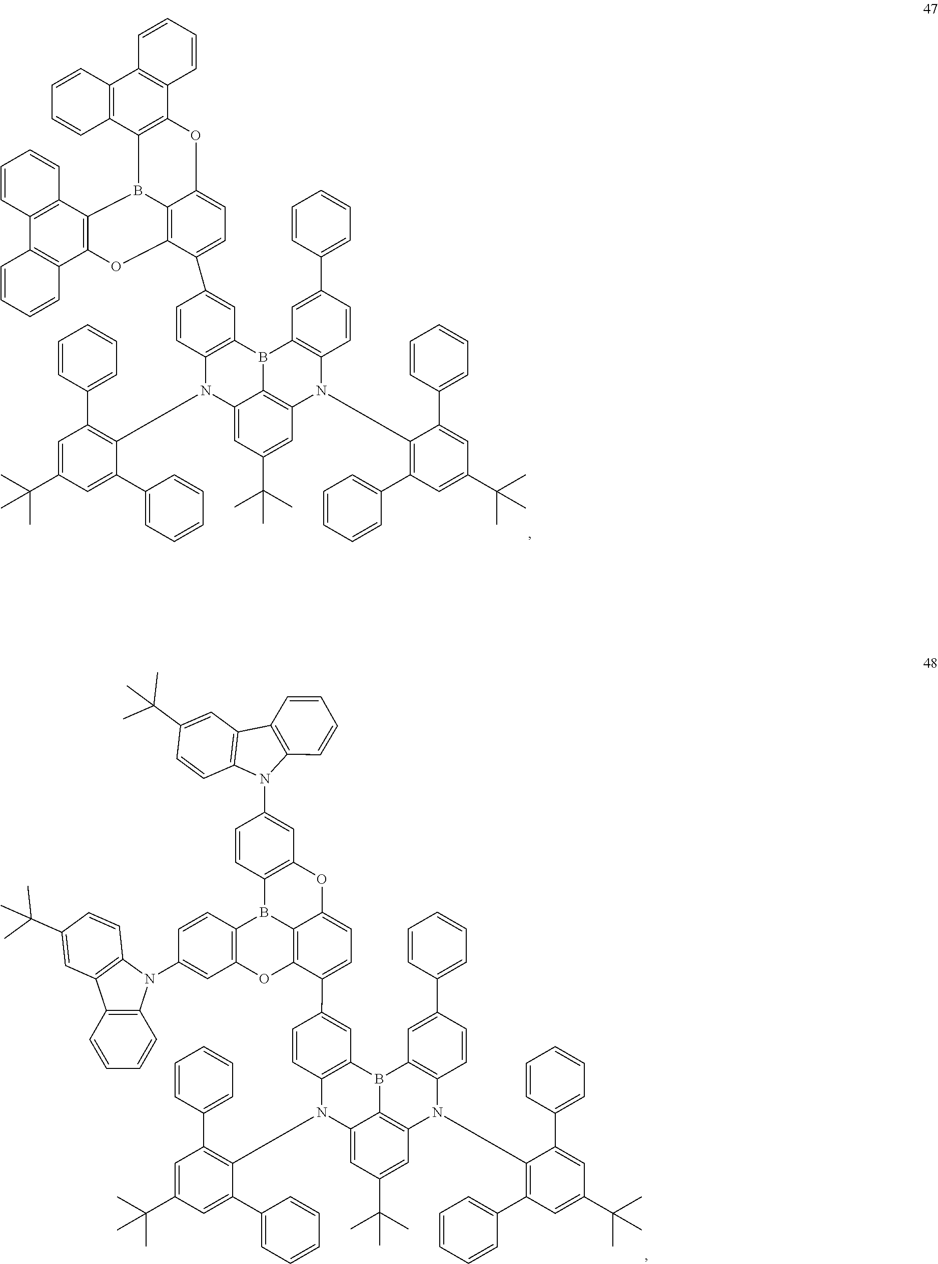

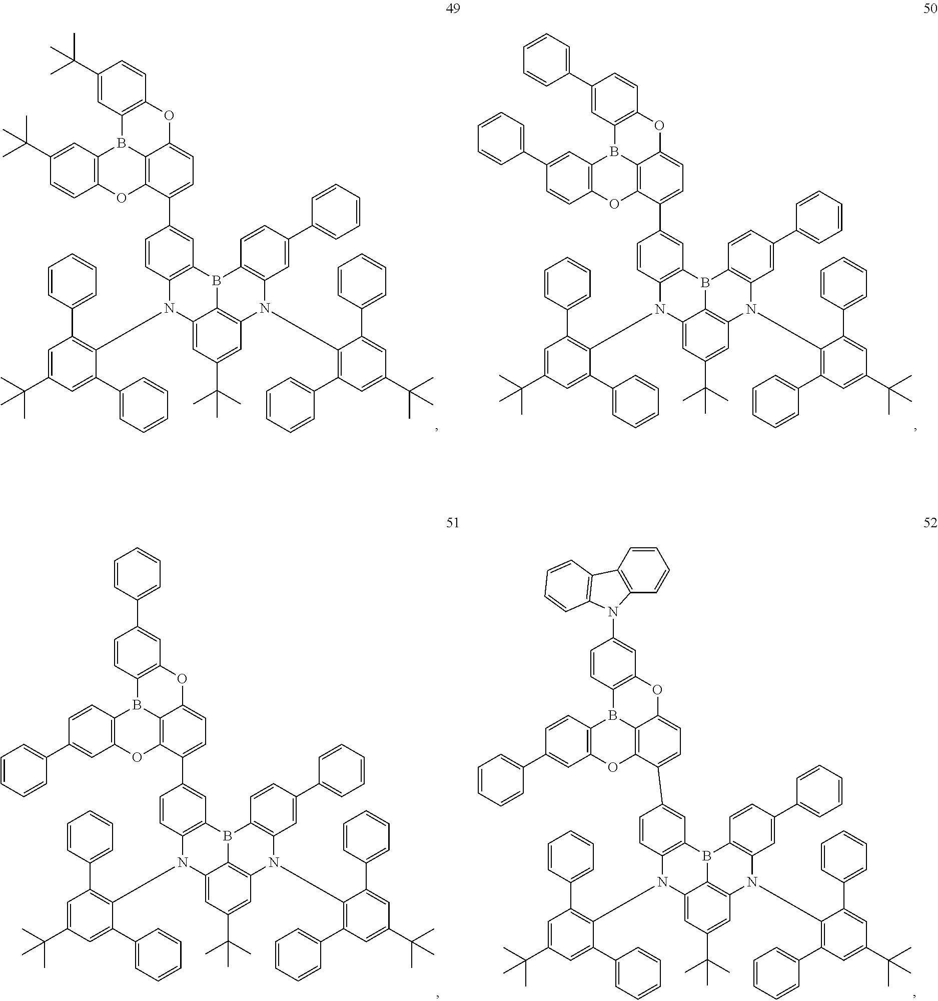

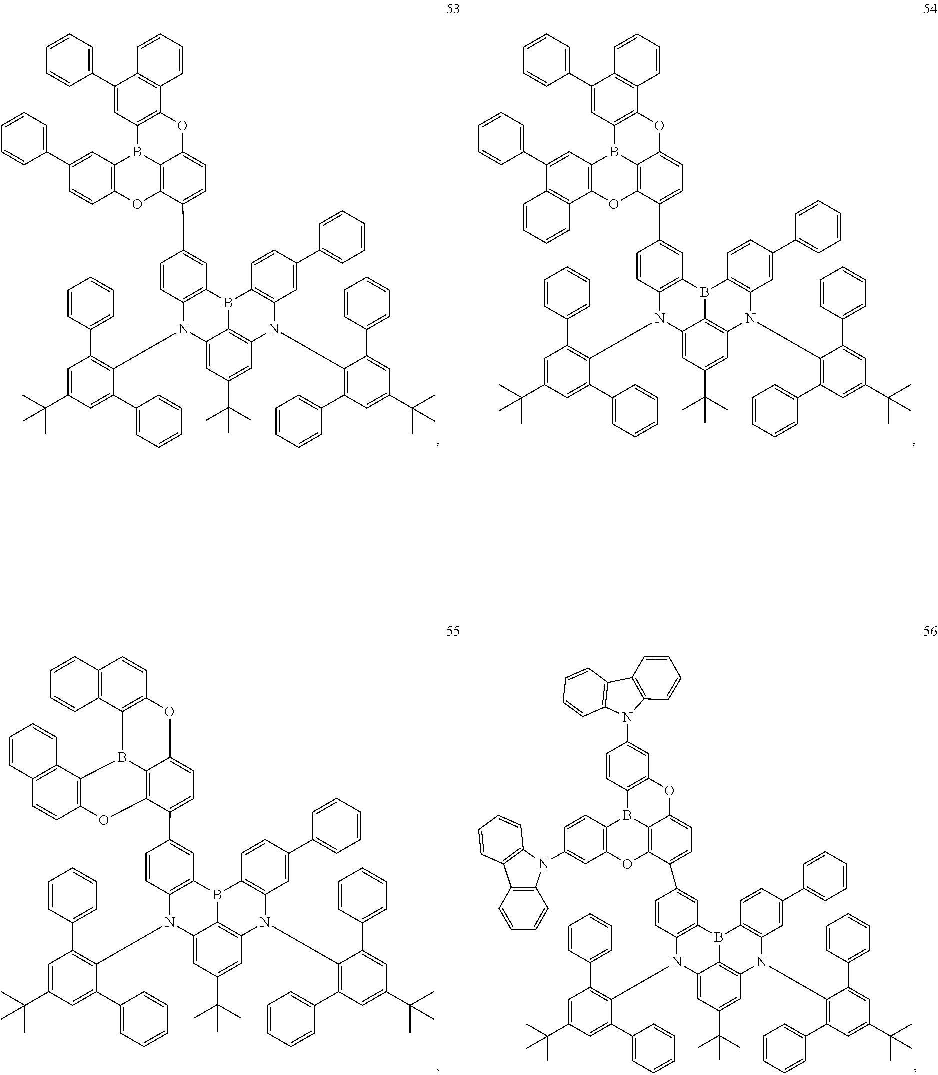

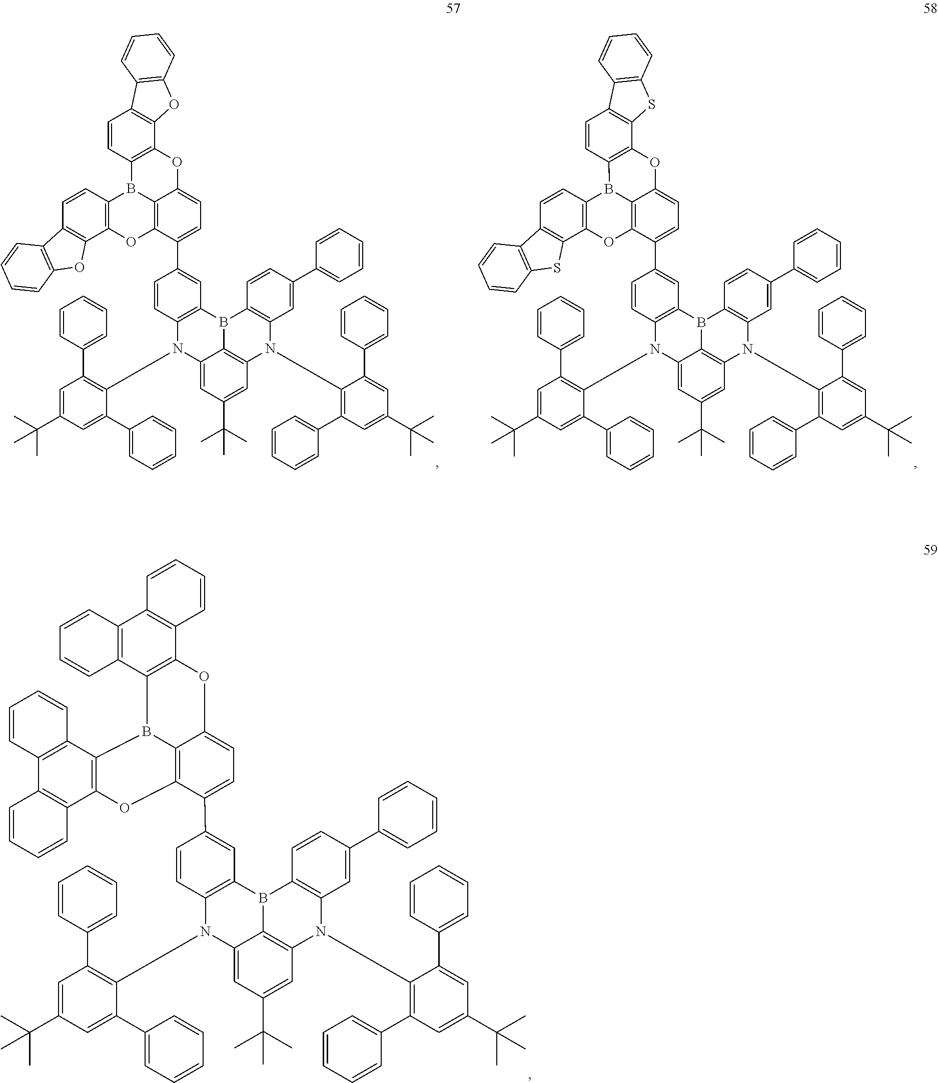

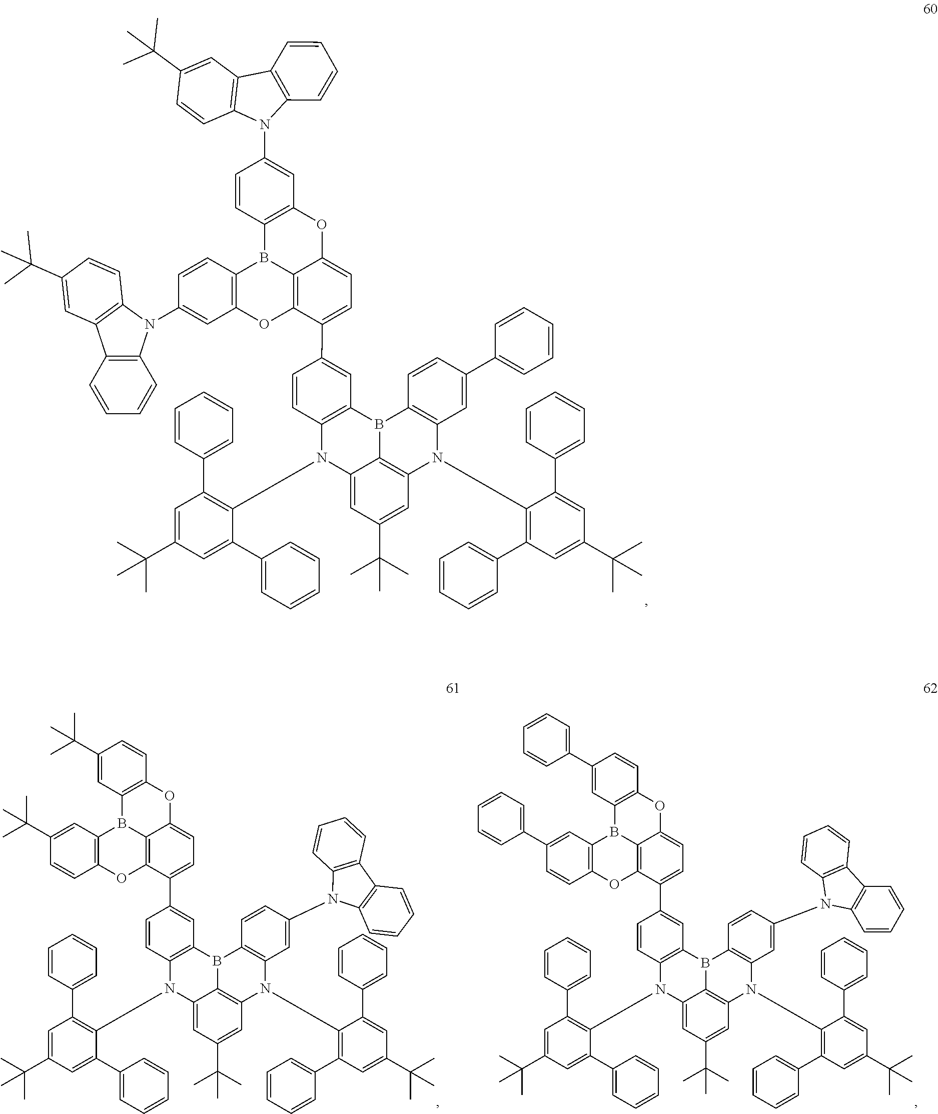

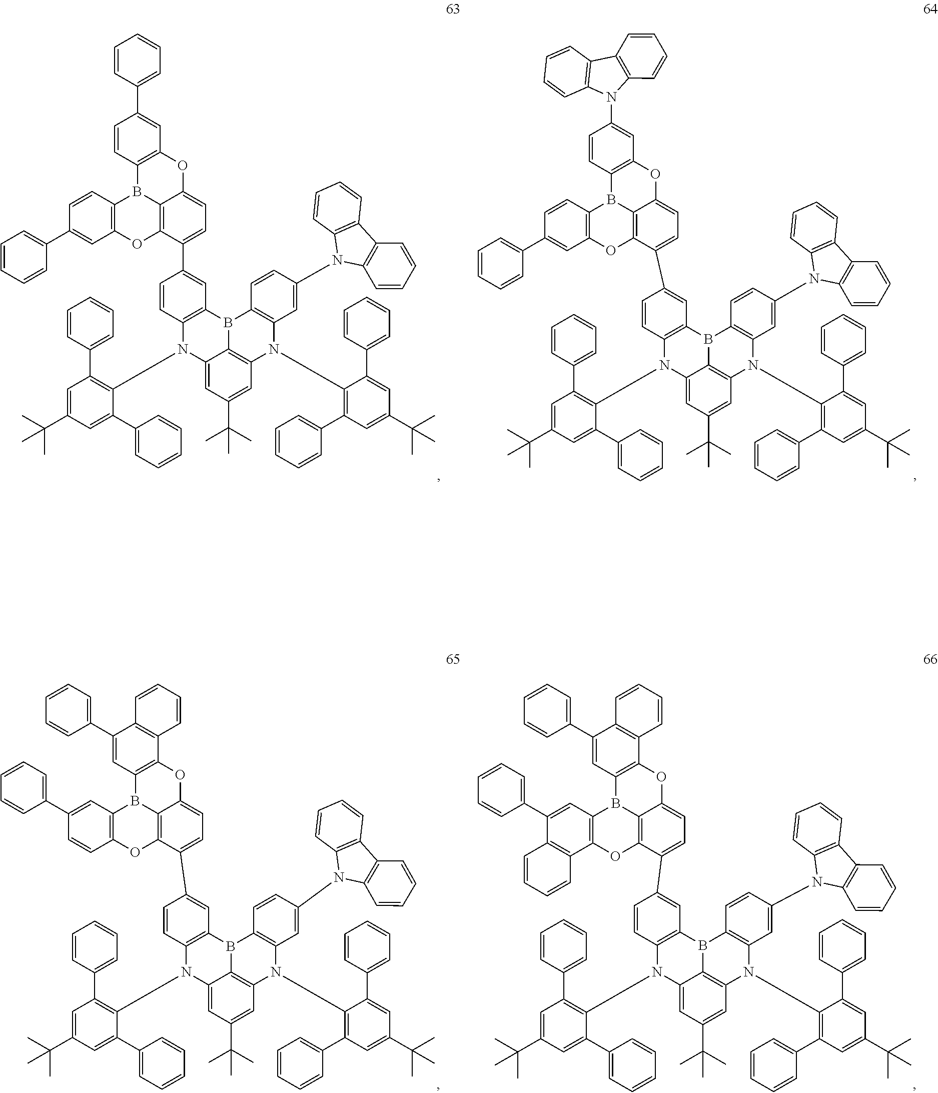

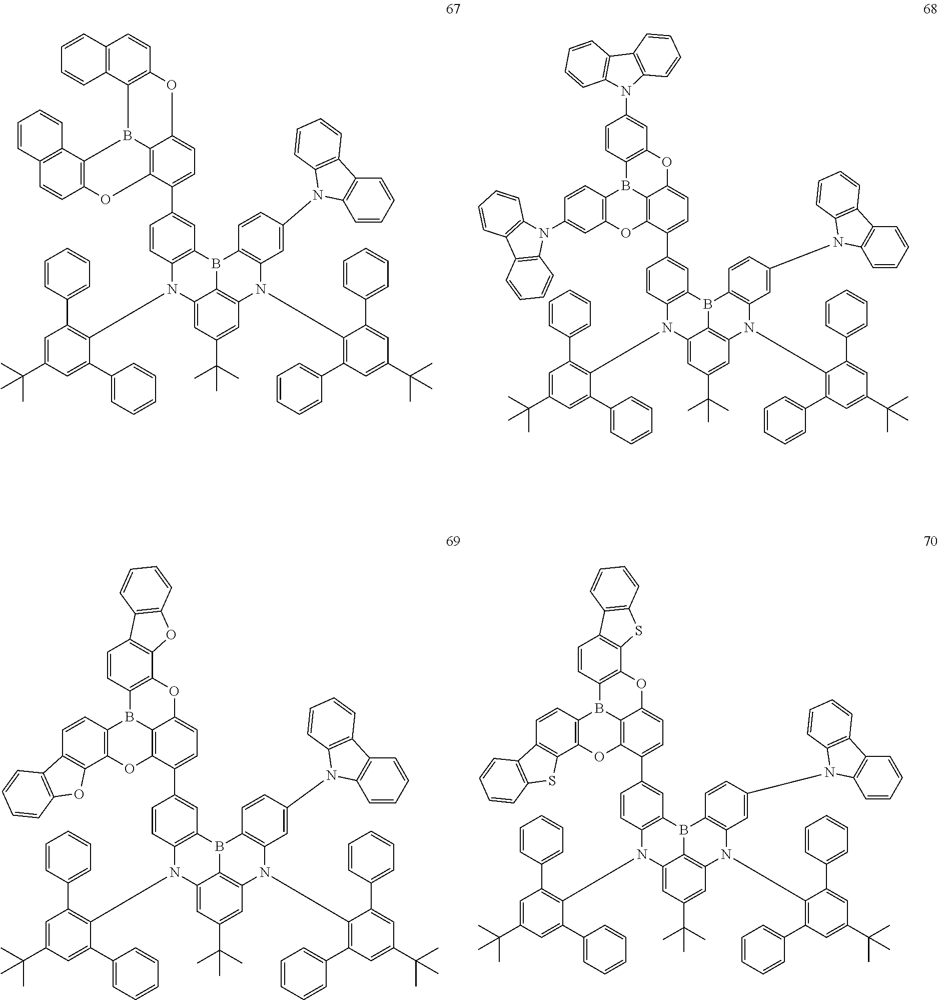

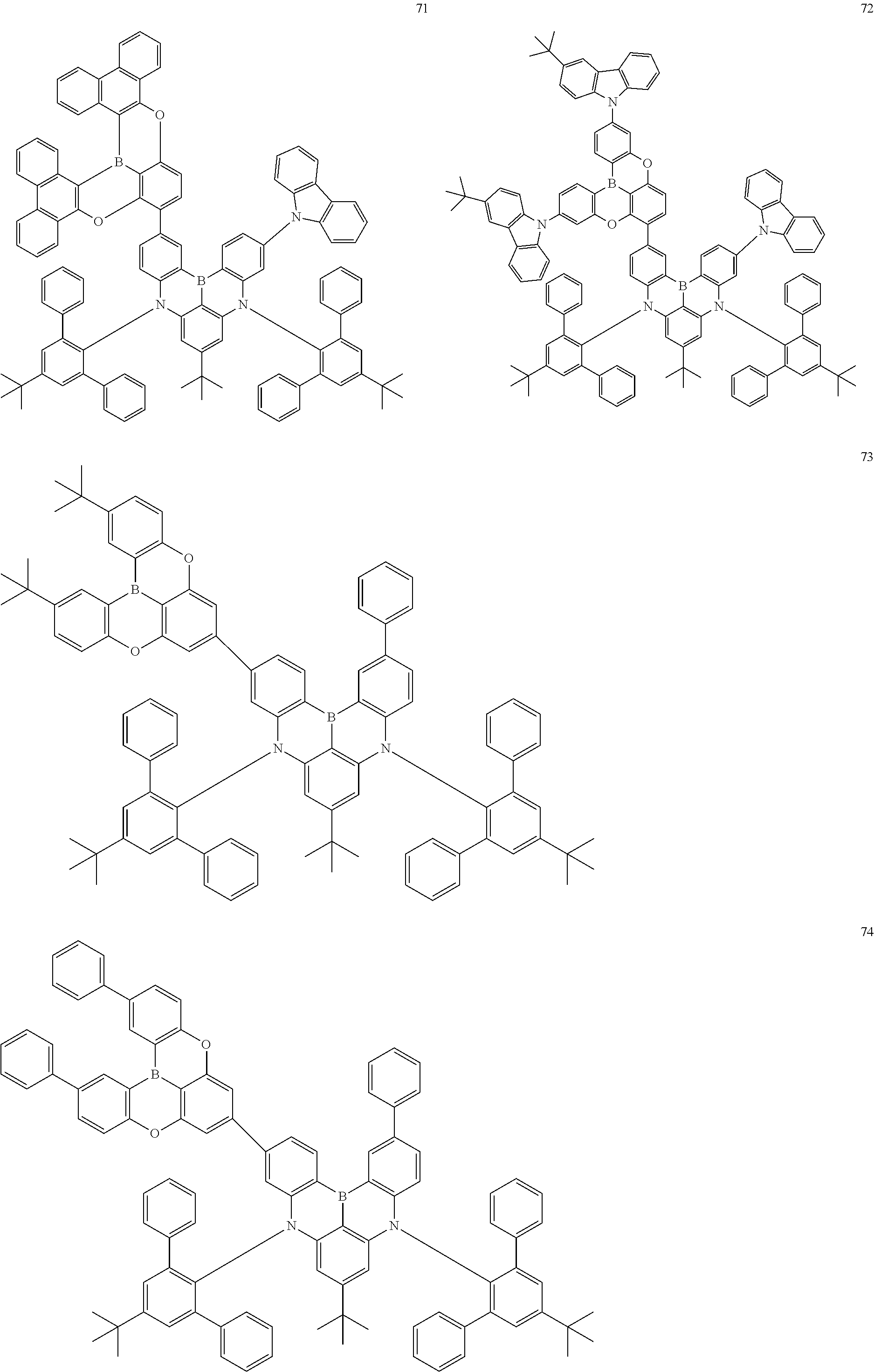

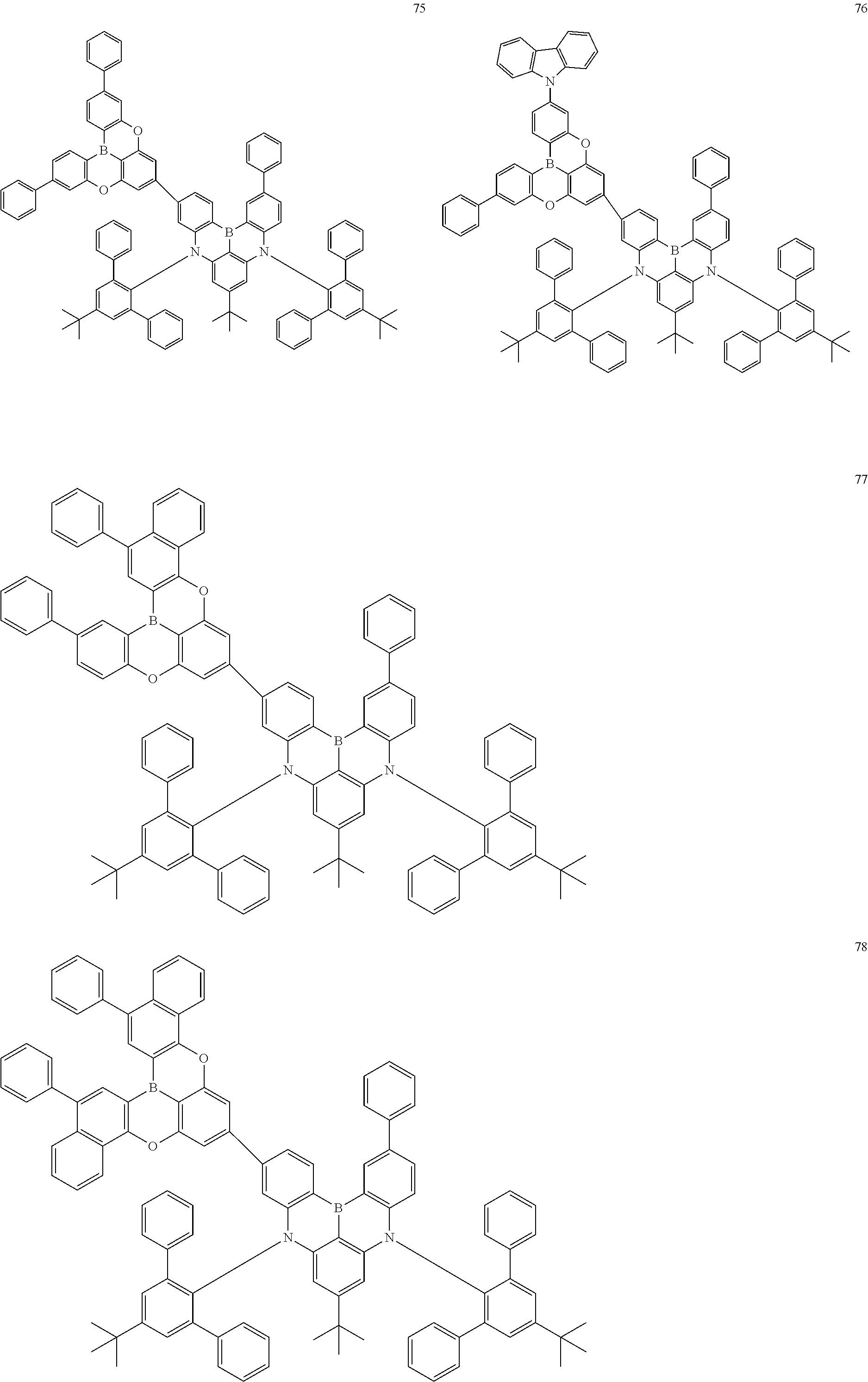

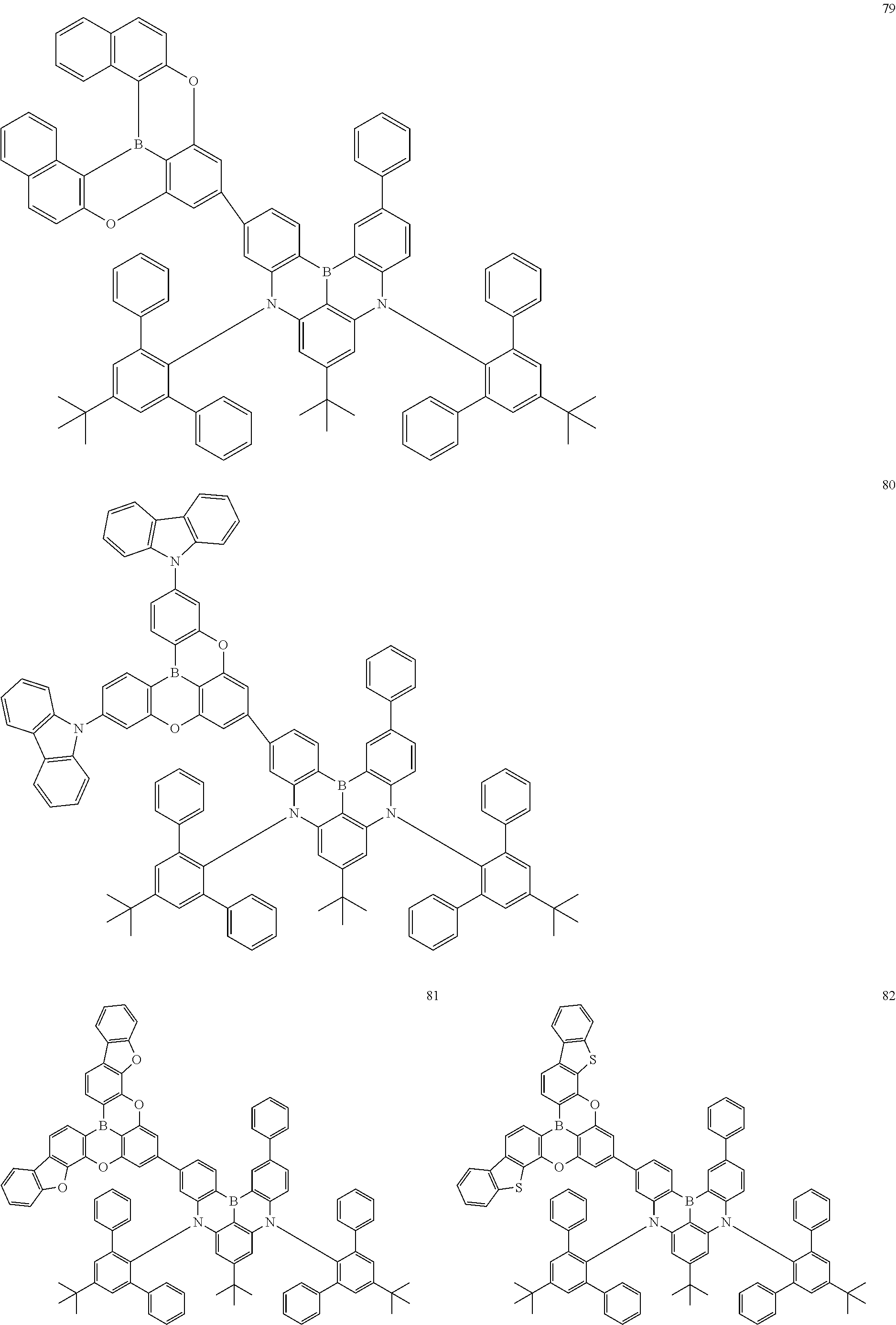

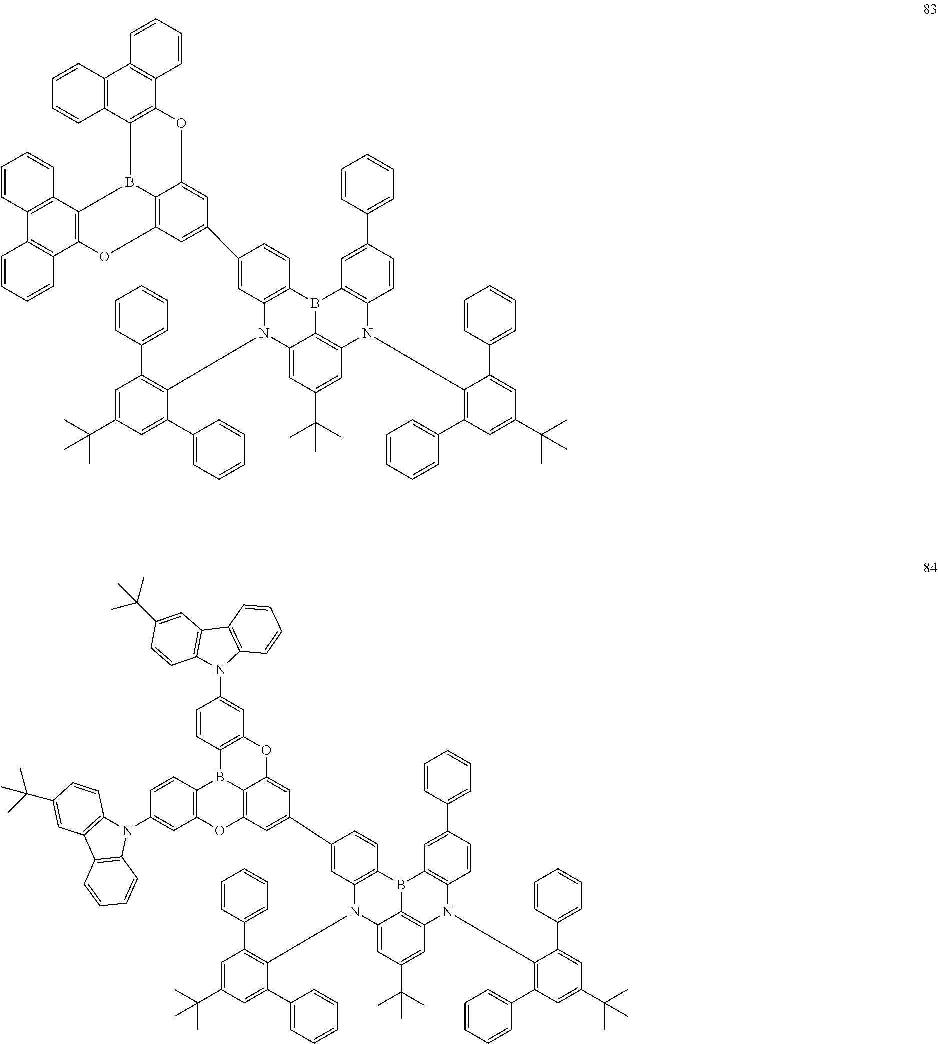

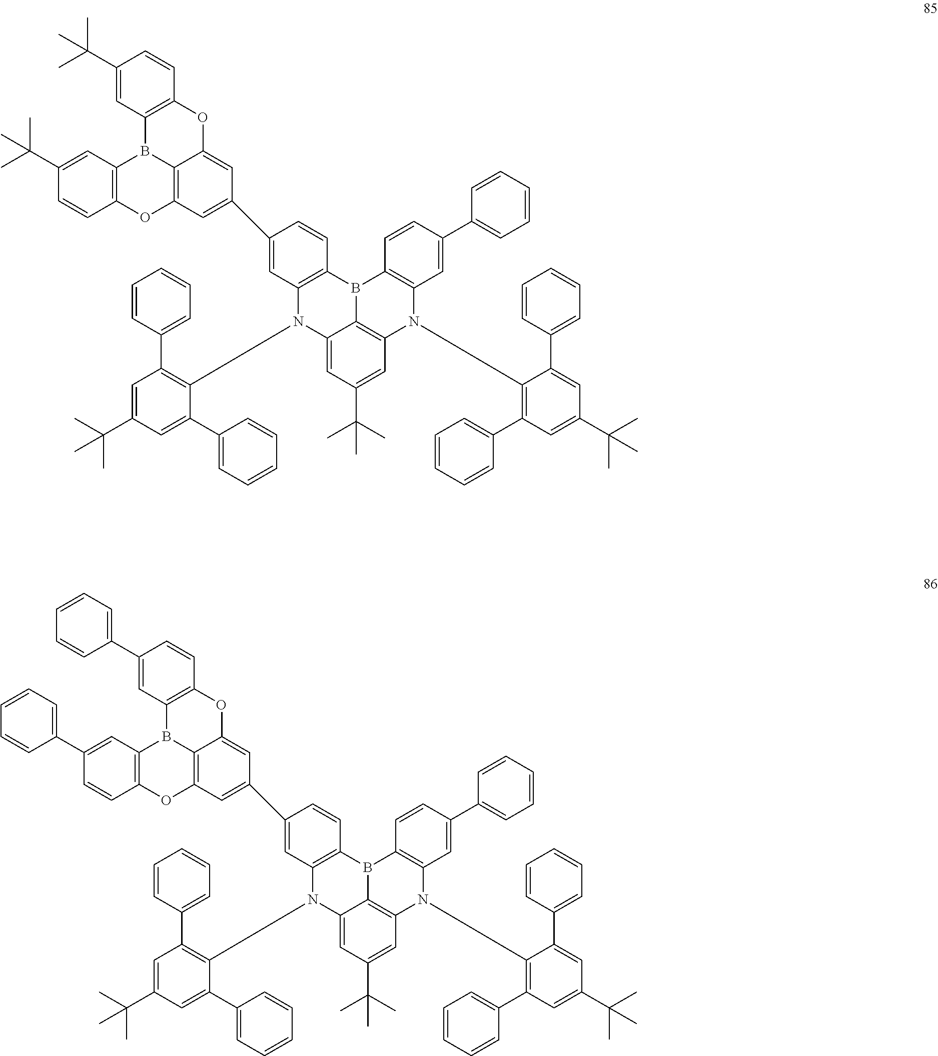 [SMILES: CC(C)(C)c1ccc2c(c1)B1c3cc(C(C)(C)C)ccc3Oc3cc(-c4ccc5c(c4)N(c4c(-c6ccccc6)cc(C(C)(C)C)cc4-c4ccccc4)c4cc(C(C)(C)C)cc6c4B5c4ccc(-c5ccccc5)cc4N6c4c(-c5ccccc5)cc(C(C)(C)C)cc4-c4ccccc4)cc(c31)O2 ; CC(C)(C)c1cc(-c2ccccc2)c(N2c3cc(-c4ccccc4)ccc3B3c4ccc(-c5cc6c7c(c5)Oc5ccc(-c8ccccc8)cc5B7c5cc(-c7ccccc7)ccc5O6)cc4N(c4c(-c5ccccc5)cc(C(C)(C)C)cc4-c4ccccc4)c4cc(C(C)(C)C)cc2c43)c(-c2ccccc2)c1]

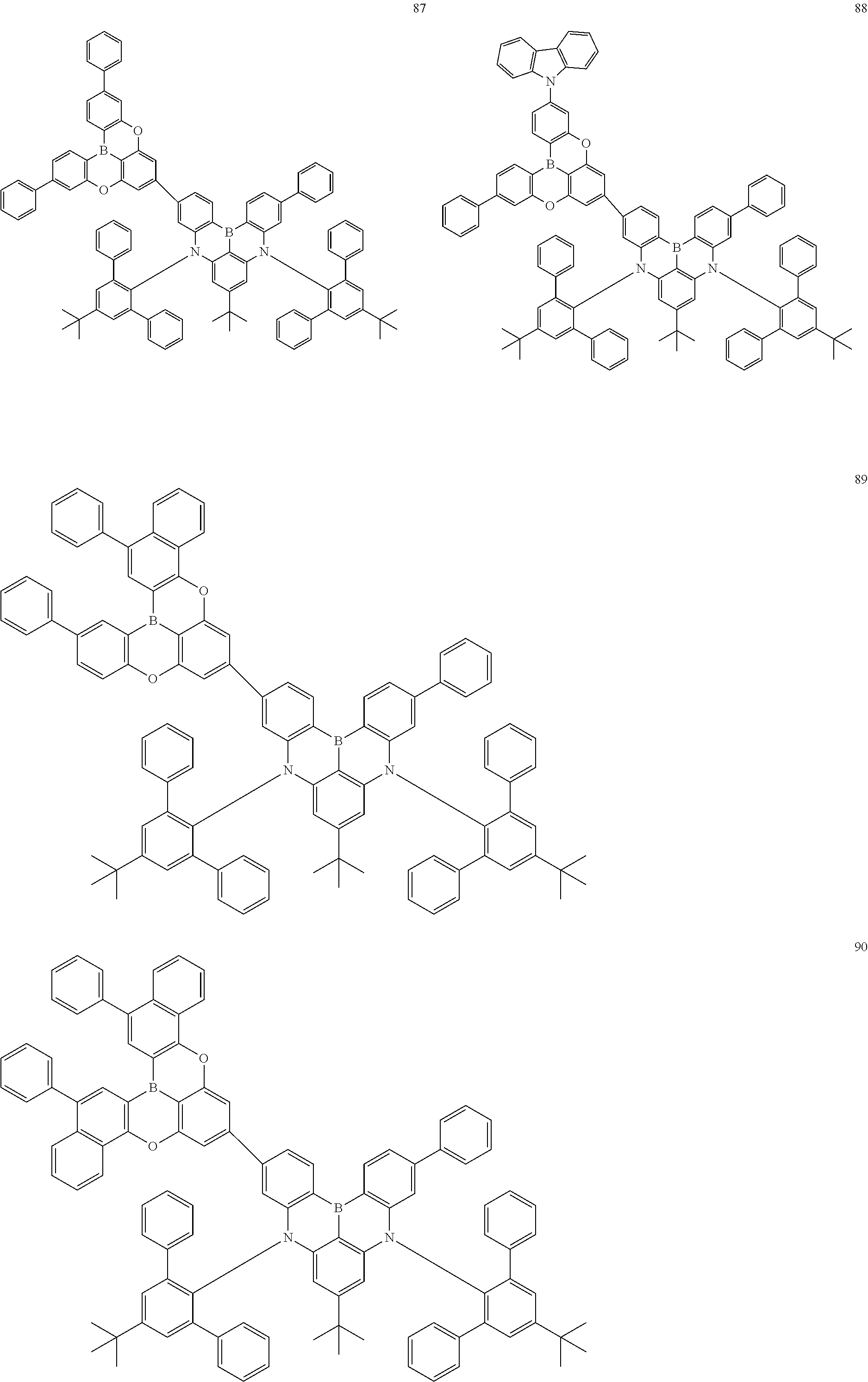

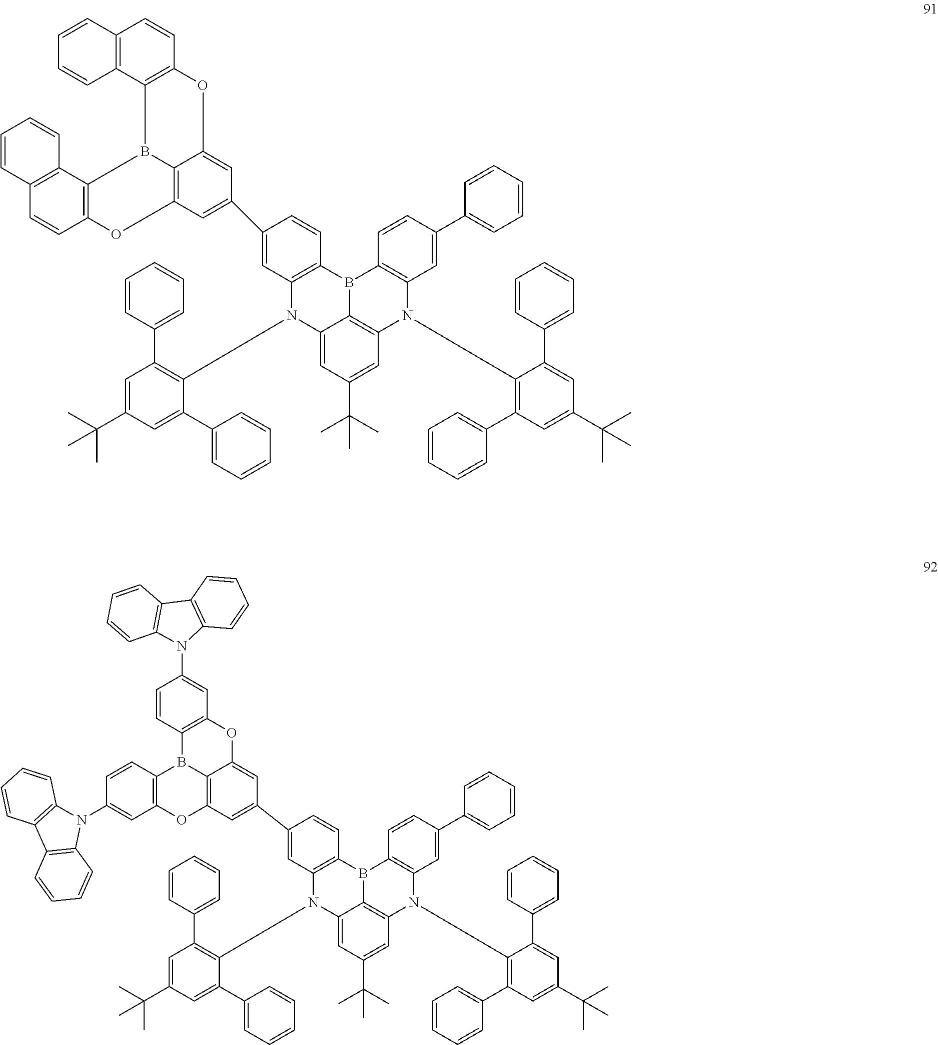 [SMILES: CC(C)(C)c1cc(-c2ccccc2)c(N2c3cc(-c4ccccc4)ccc3B3c4ccc(-c5cc6c7c(c5)Oc5ccc8ccccc8c5B7c5c(ccc7ccccc57)O6)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4ccccc4)ccc3B3c4ccc(-c5cc6c7c(c5)Oc5cc(-n8c9ccccc9c9ccccc98)ccc5B7c5ccc(-n7c8ccccc8c8ccccc87)cc5O6)cc4N(c4c(-c5ccccc5)cc(C(C)(C)C)cc4-c4ccccc4)c4cc(C(C)(C)C)cc2c43)c(-c2ccccc2)c1]

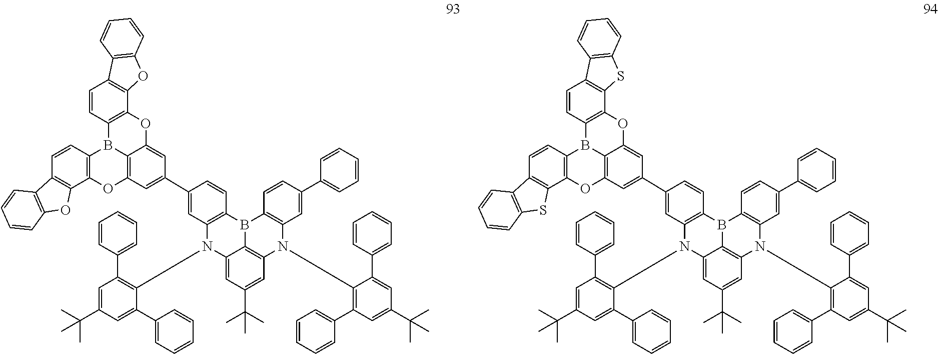 [SMILES: CC(C)(C)c1cc(-c2ccccc2)c(N2c3cc(-c4ccccc4)ccc3B3c4ccc(-c5cc6c7c(c5)Oc5c(ccc8c5oc5ccccc58)B7c5ccc7c(oc8ccccc87)c5O6)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4ccccc4)ccc3B3c4ccc(-c5cc6c7c(c5)Oc5c(ccc8c5sc5ccccc58)B7c5ccc7c(sc8ccccc87)c5O6)cc4N(c4c(-c5ccccc5)cc(C(C)(C)C)cc4-c4ccccc4)c4cc(C(C)(C)C)cc2c43)c(-c2ccccc2)c1]

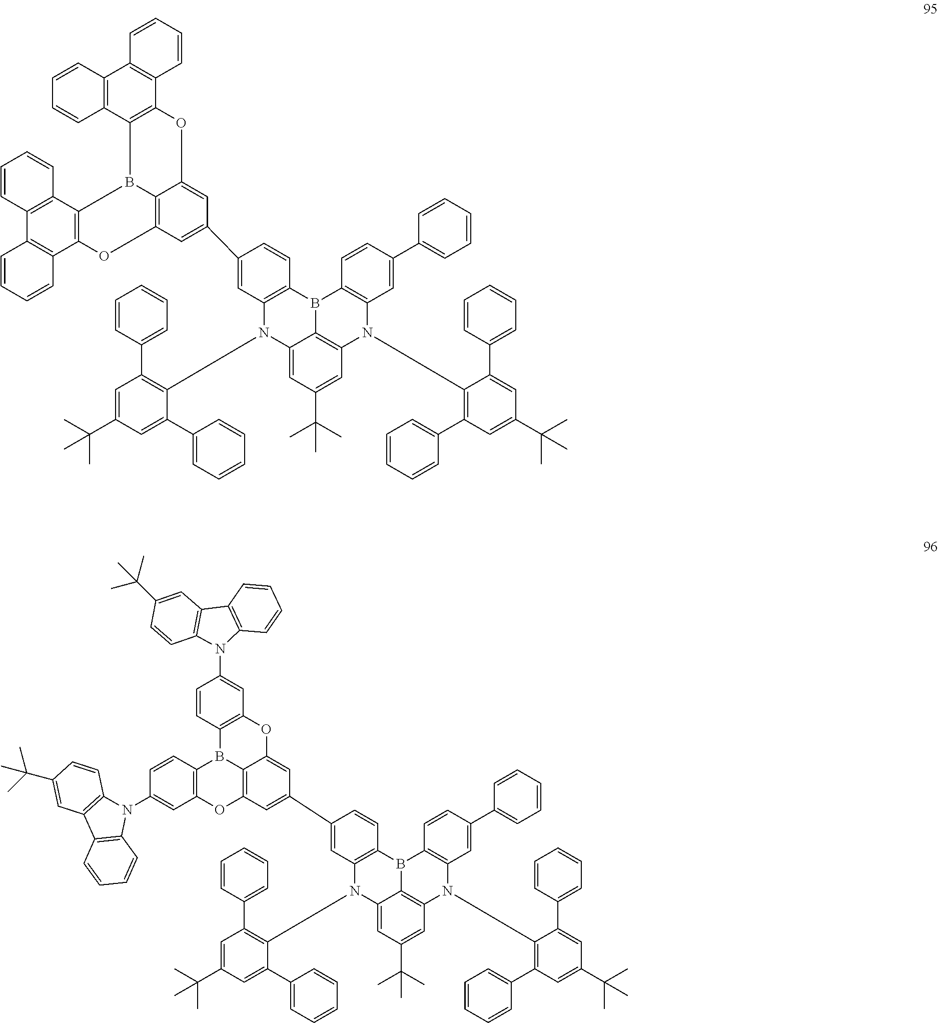

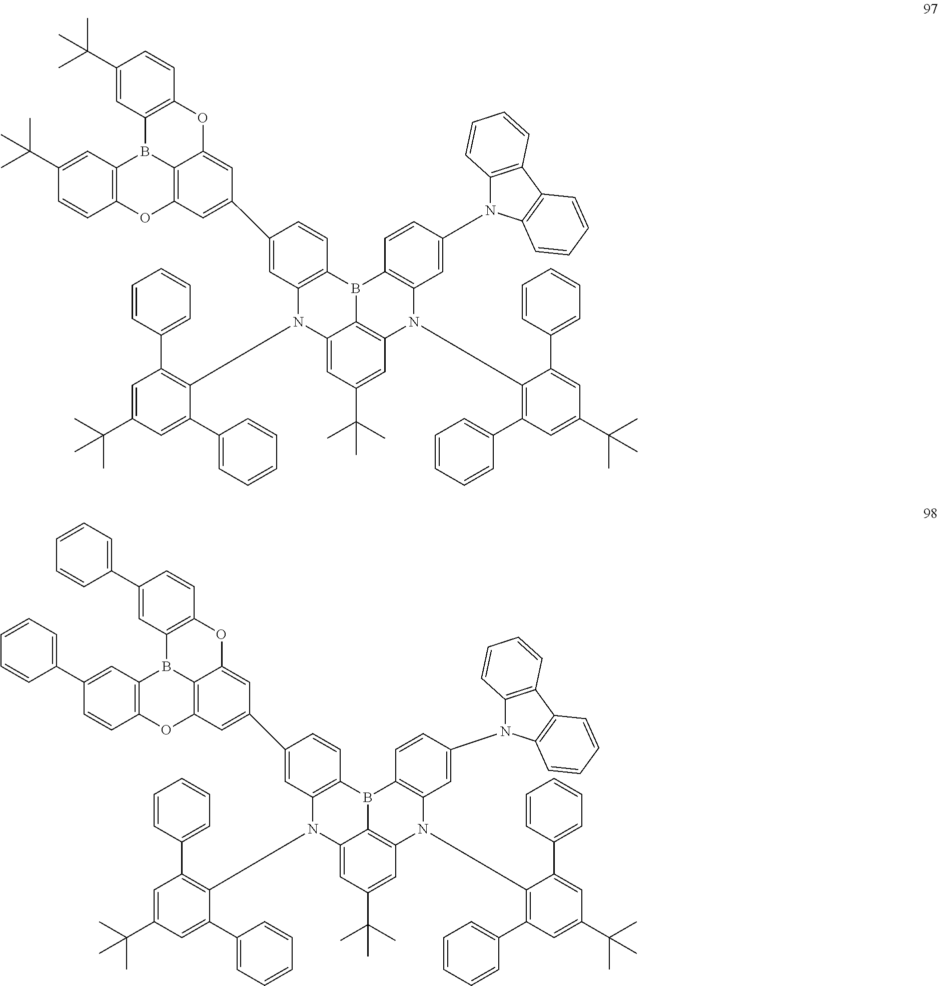 [SMILES: CC(C)(C)c1ccc2c(c1)B1c3cc(C(C)(C)C)ccc3Oc3cc(-c4ccc5c(c4)N(c4c(-c6ccccc6)cc(C(C)(C)C)cc4-c4ccccc4)c4cc(C(C)(C)C)cc6c4B5c4ccc(-n5c7ccccc7c7ccccc75)cc4N6c4c(-c5ccccc5)cc(C(C)(C)C)cc4-c4ccccc4)cc(c31)O2 ; CC(C)(C)c1cc(-c2ccccc2)c(N2c3cc(-c4cc5c6c(c4)Oc4ccc(-c7ccccc7)cc4B6c4cc(-c6ccccc6)ccc4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1]

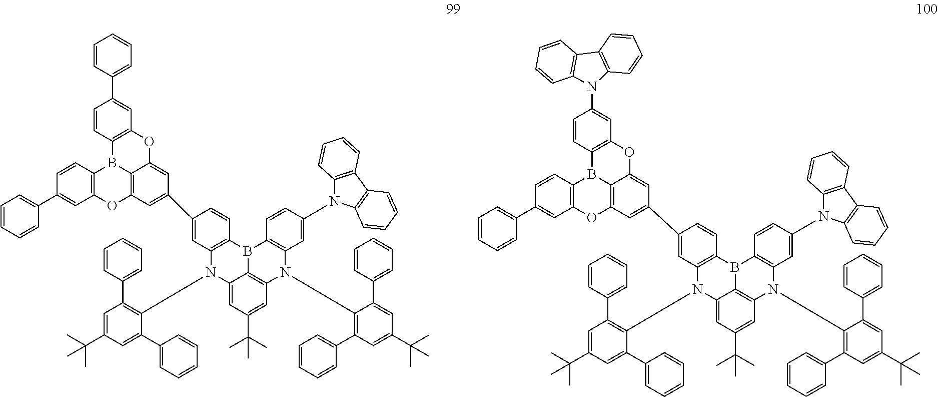 [SMILES: CC(C)(C)c1cc(-c2ccccc2)c(N2c3cc(-c4cc5c6c(c4)Oc4cc(-c7ccccc7)ccc4B6c4ccc(-c6ccccc6)cc4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8ccccc87)ccc4B6c4ccc(-c6ccccc6)cc4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1]

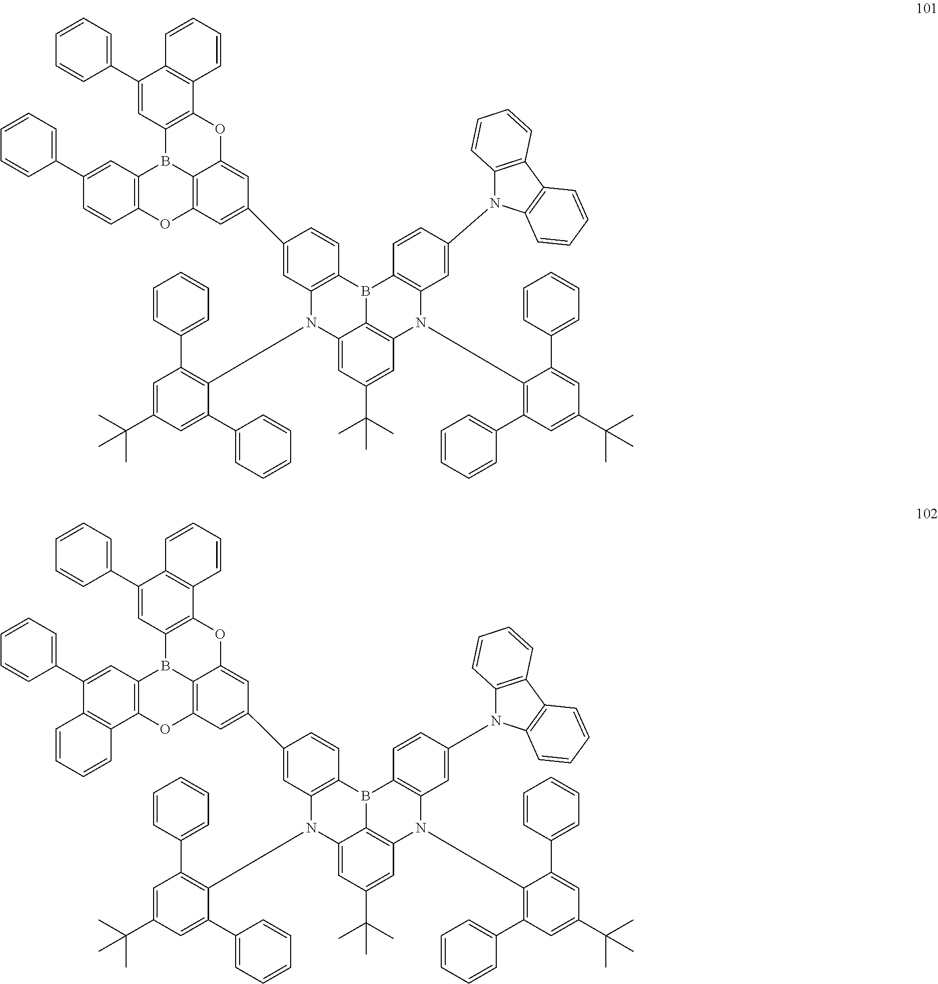 [SMILES: CC(C)(C)c1cc(-c2ccccc2)c(N2c3cc(-c4cc5c6c(c4)Oc4c(cc(-c7ccccc7)c7ccccc47)B6c4cc(-c6ccccc6)ccc4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4cc5c6c(c4)Oc4c(cc(-c7ccccc7)c7ccccc47)B6c4cc(-c6ccccc6)c6ccccc6c4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1]

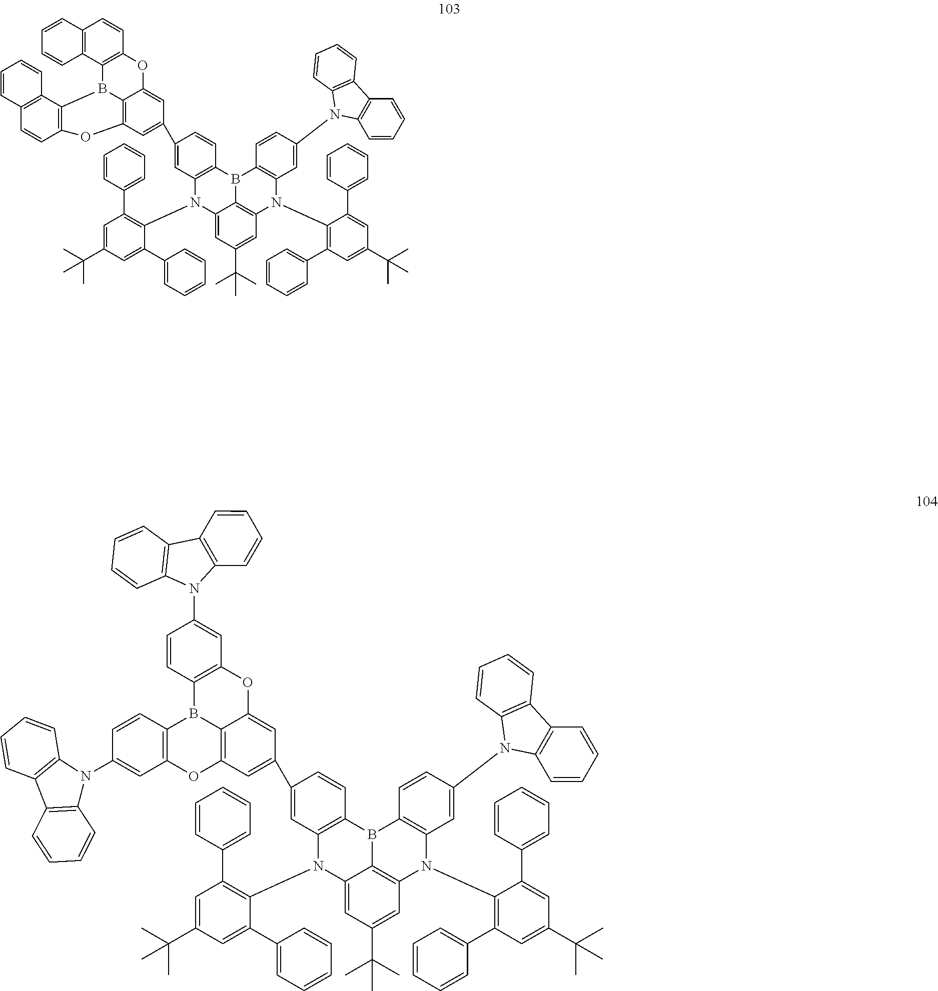 [SMILES: CC(C)(C)c1cc(-c2ccccc2)c(N2c3cc(-c4cc5c6c(c4)Oc4ccc7ccccc7c4B6c4c(ccc6ccccc46)O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8ccccc87)ccc4B6c4ccc(-n6c7ccccc7c7ccccc76)cc4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1]

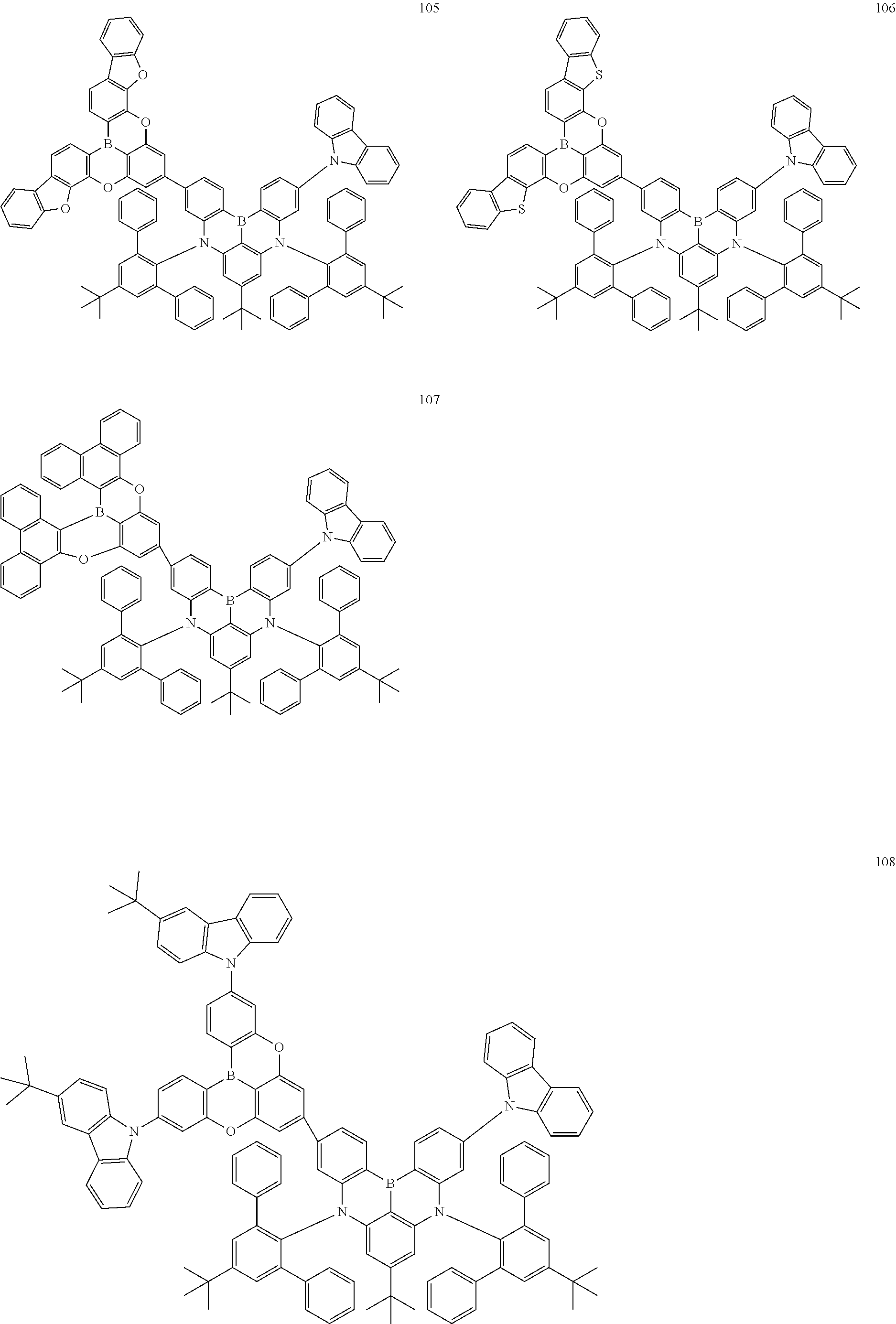

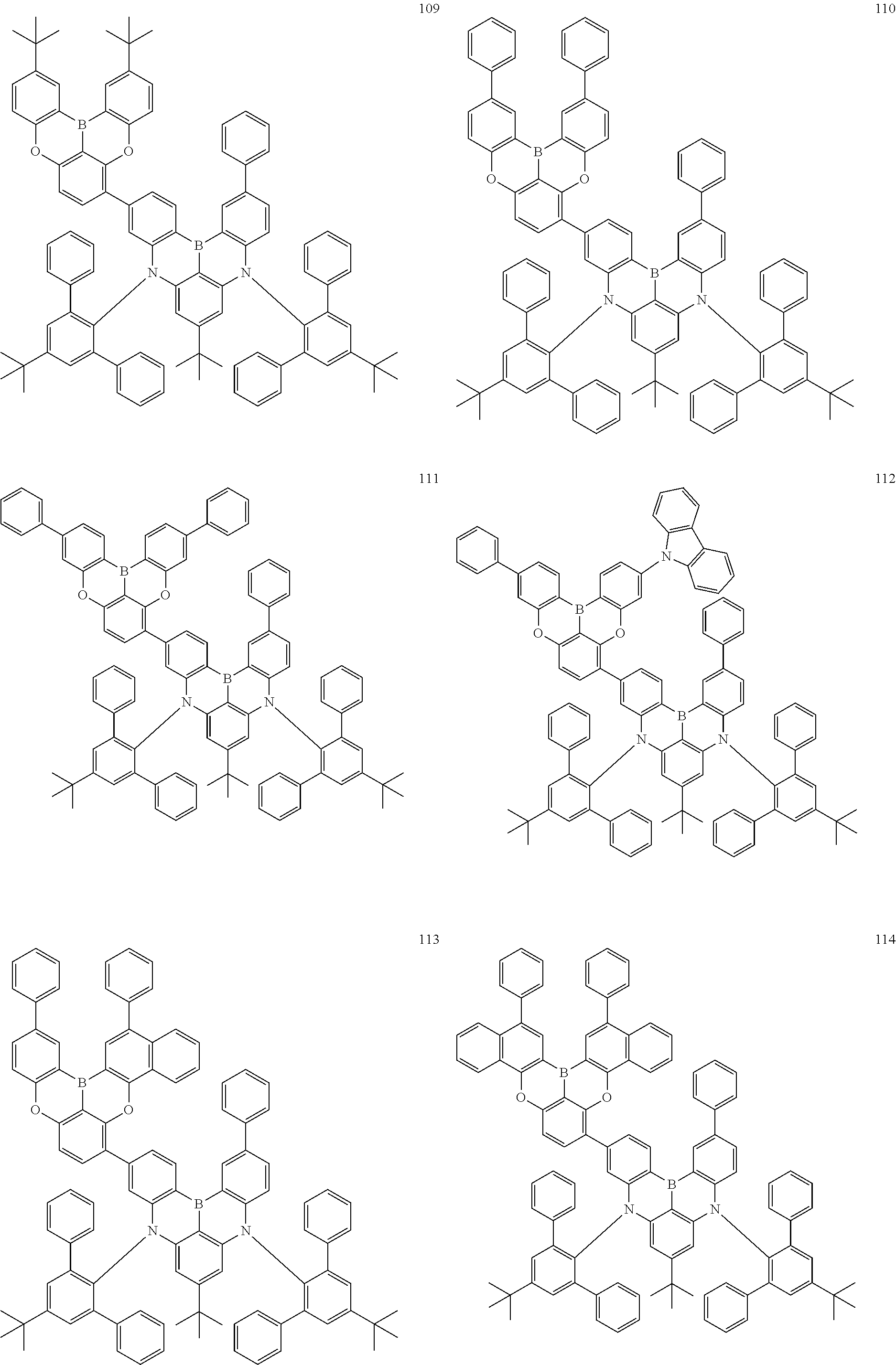

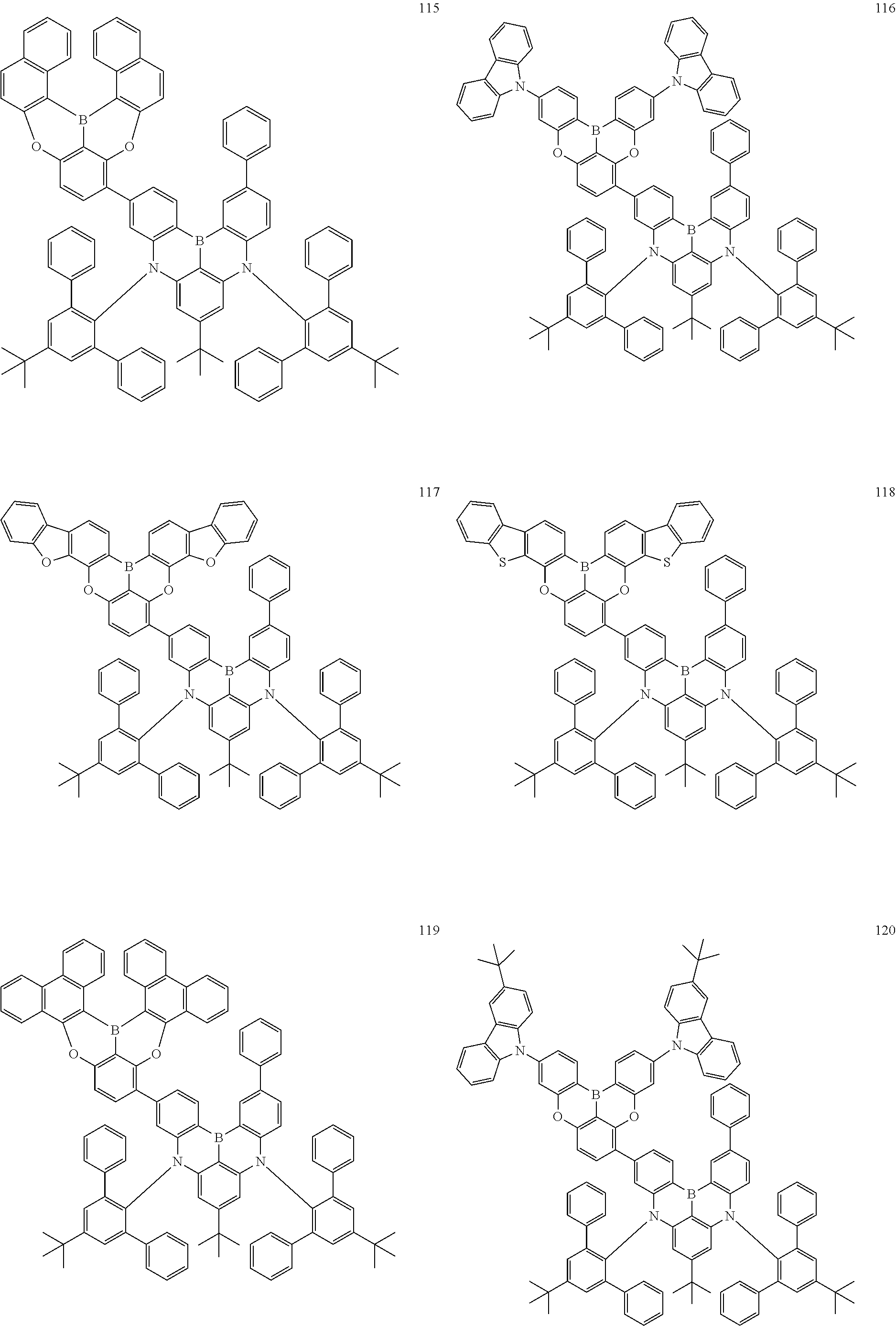

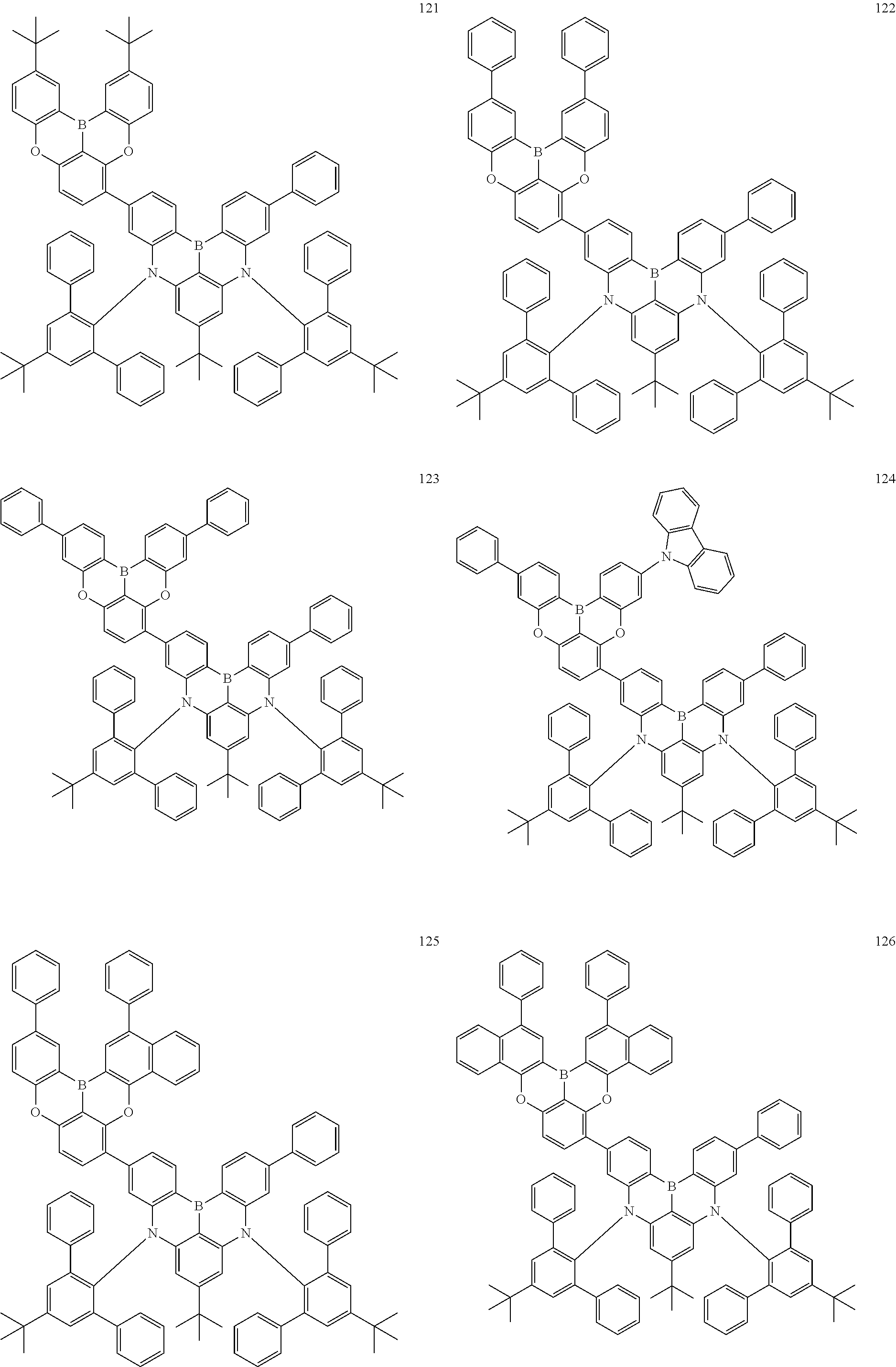

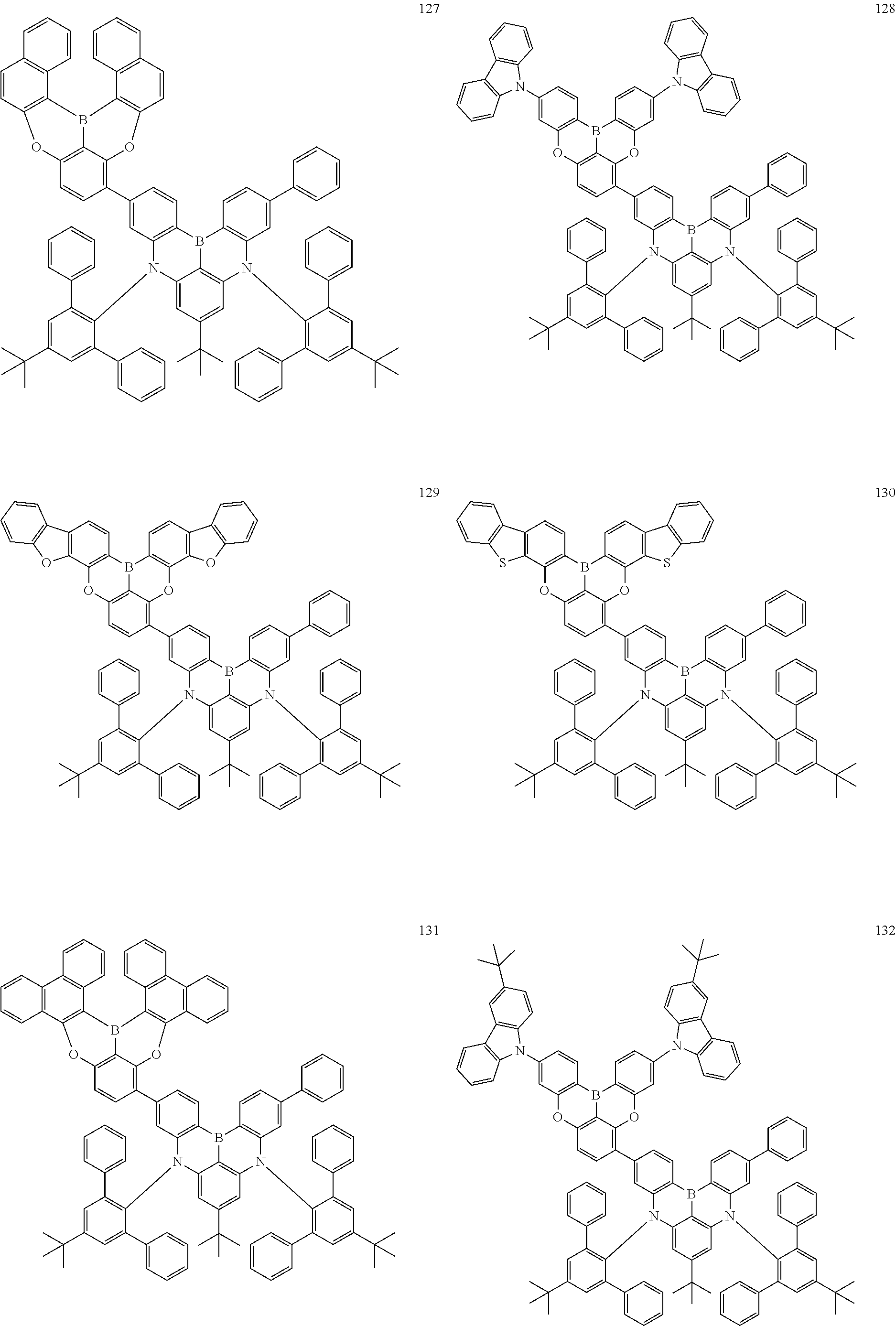

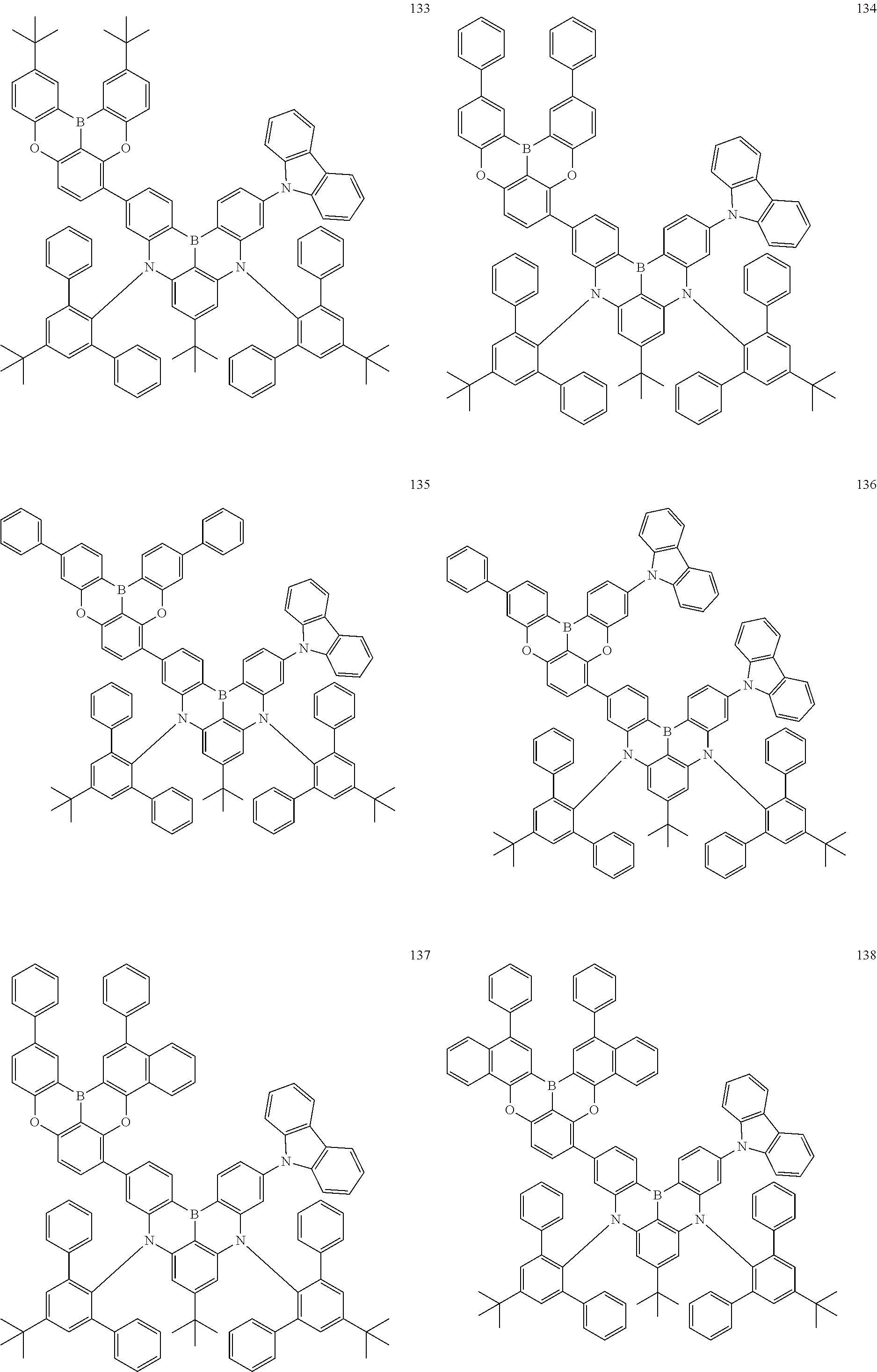

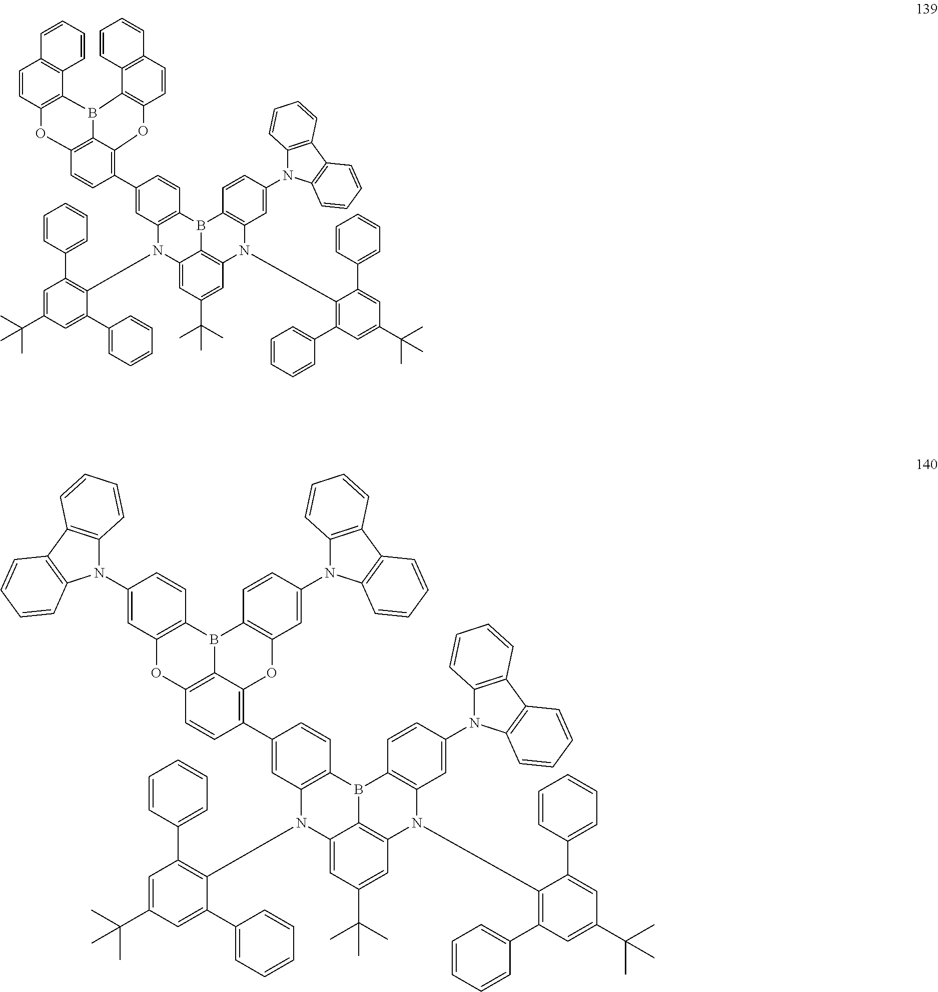 [SMILES: CC(C)(C)c1cc(-c2ccccc2)c(N2c3cc(-c4ccc5c6c4Oc4ccc7ccccc7c4B6c4c(ccc6ccccc46)O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4ccc5c6c4Oc4cc(-n7c8ccccc8c8ccccc87)ccc4B6c4ccc(-n6c7ccccc7c7ccccc76)cc4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1]

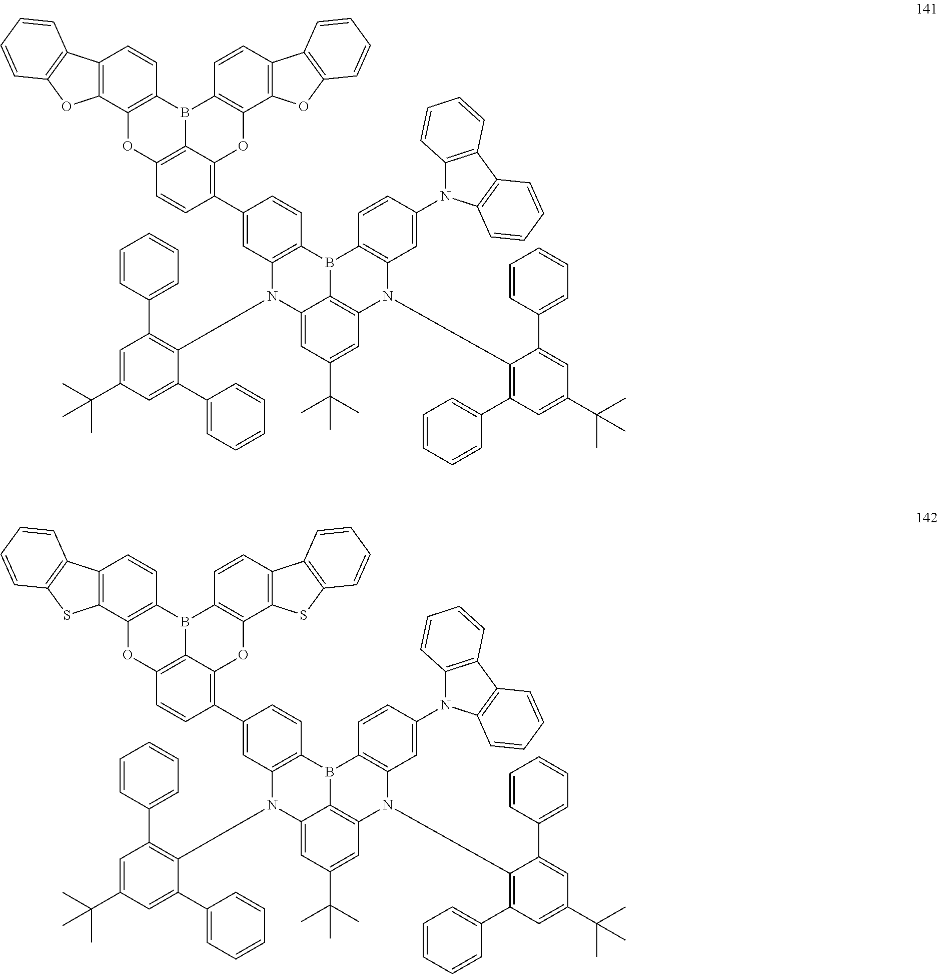 [SMILES: CC(C)(C)c1cc(-c2ccccc2)c(N2c3cc(-c4ccc5c6c4Oc4c(ccc7c4oc4ccccc47)B6c4ccc6c(oc7ccccc76)c4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4ccc5c6c4Oc4c(ccc7c4sc4ccccc47)B6c4ccc6c(sc7ccccc76)c4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1]

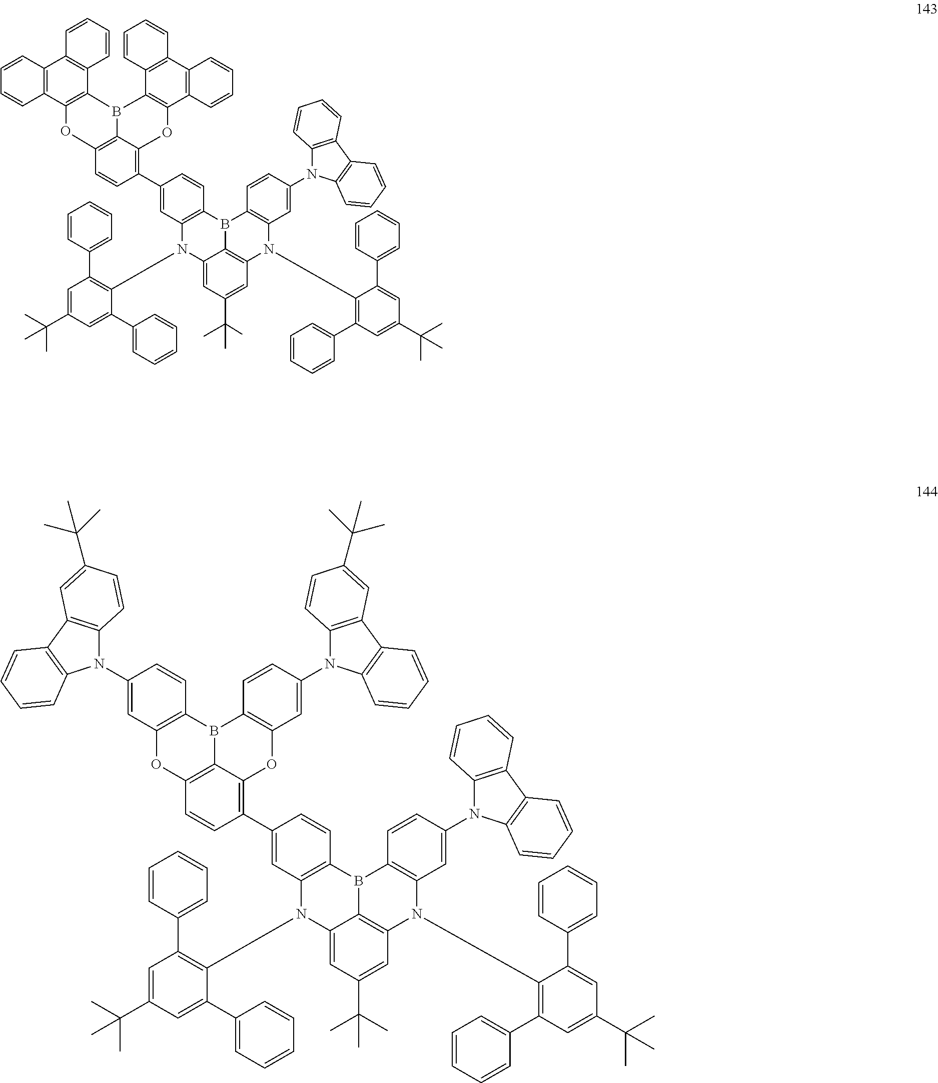 [SMILES: CC(C)(C)c1cc(-c2ccccc2)c(N2c3cc(-c4ccc5c6c4Oc4c(c7ccccc7c7ccccc47)B6c4c(c6ccccc6c6ccccc46)O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4ccc5c6c4Oc4cc(-n7c8ccccc8c8cc(C(C)(C)C)ccc87)ccc4B6c4ccc(-n6c7ccccc7c7cc(C(C)(C)C)ccc76)cc4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1]

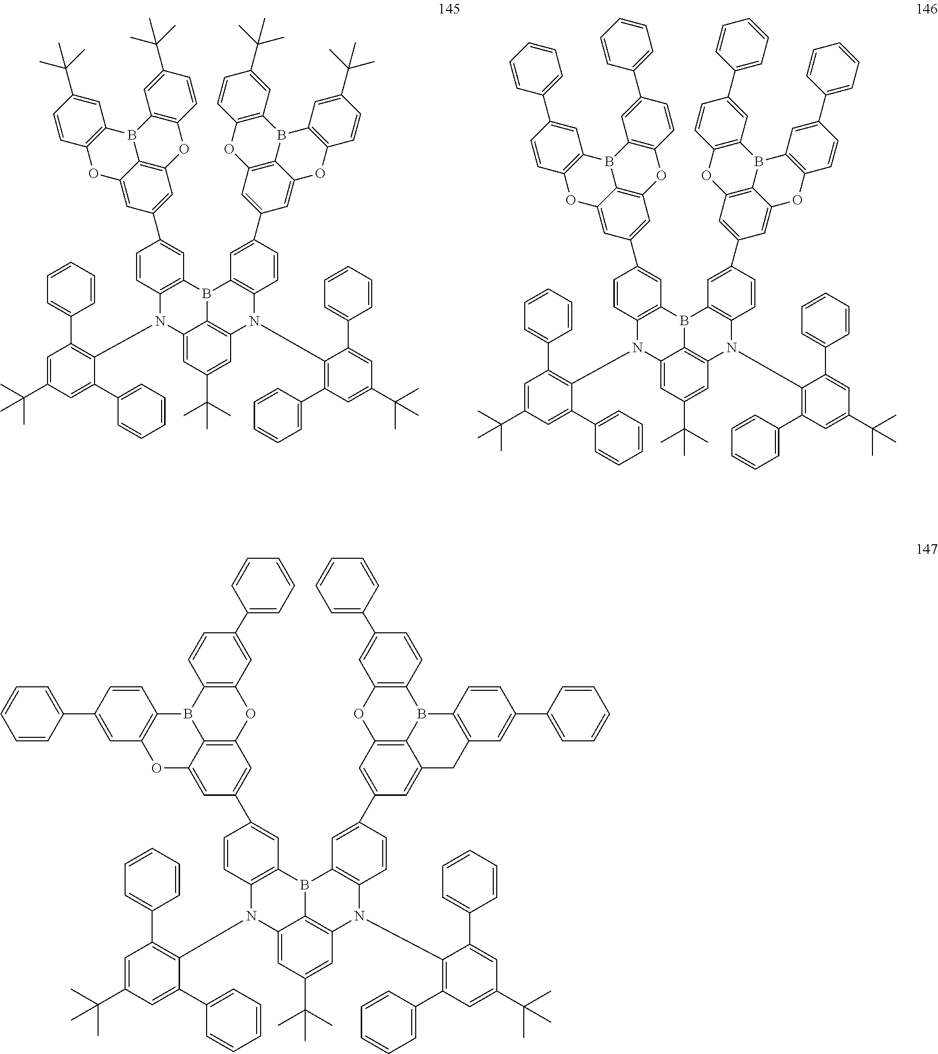

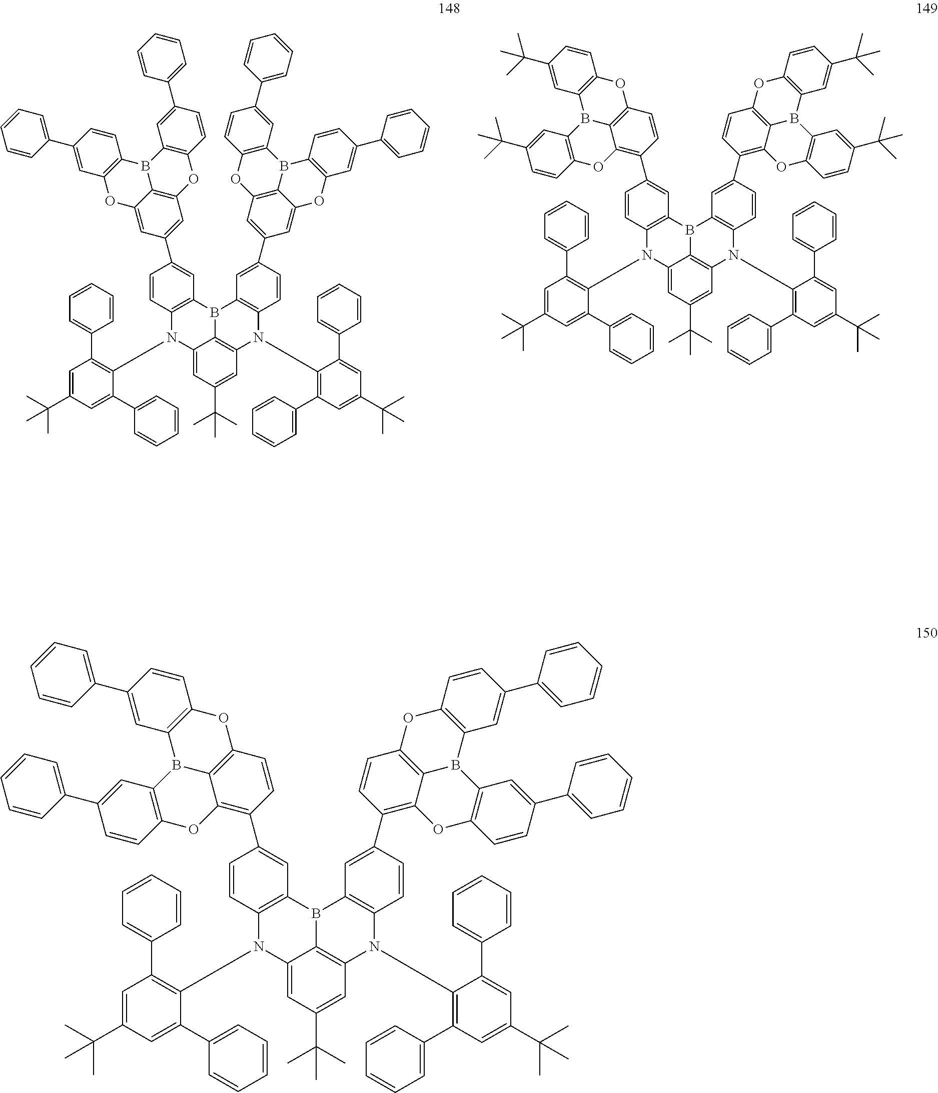

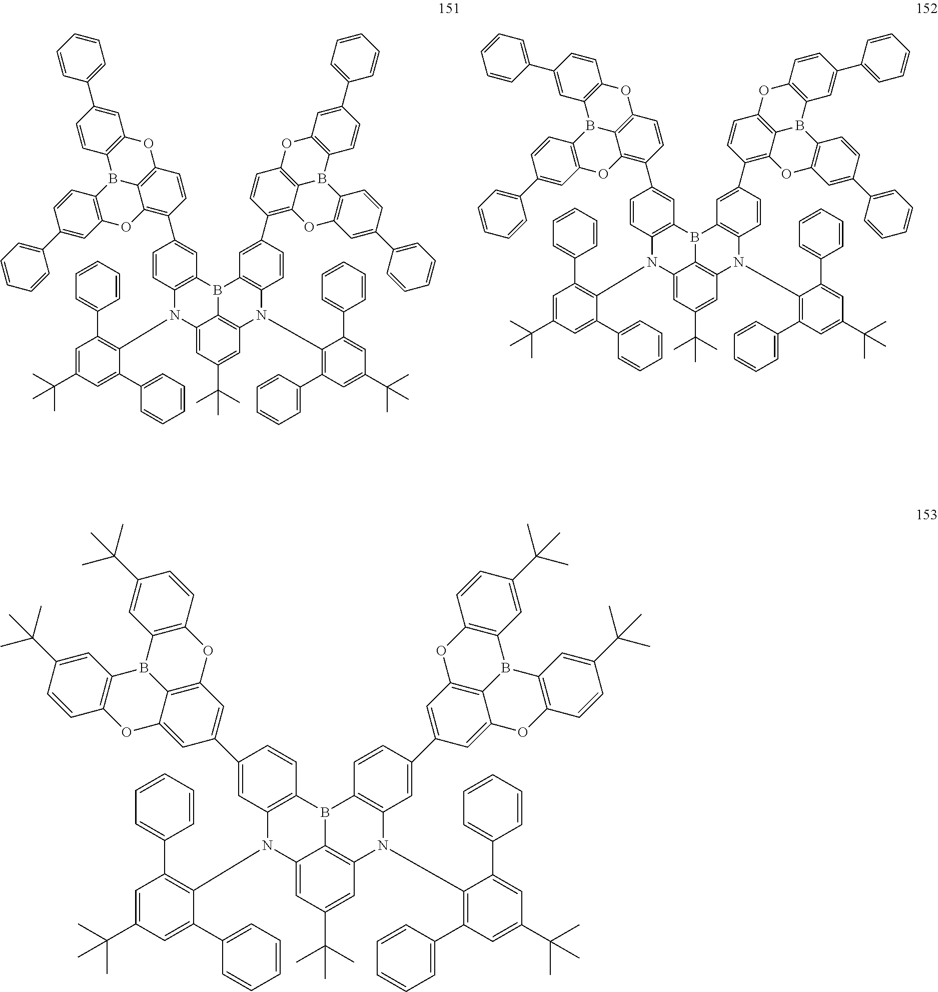

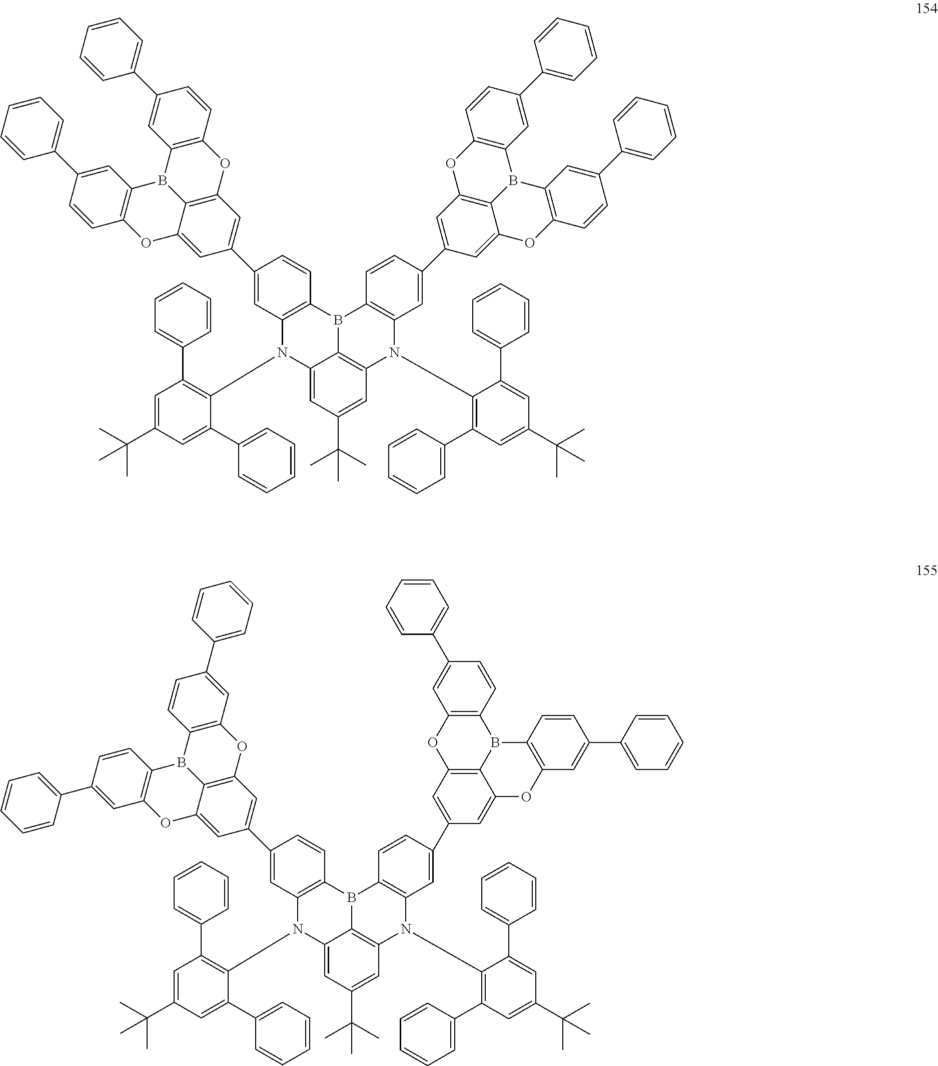 [SMILES: CC(C)(C)c1cc(-c2ccccc2)c(N2c3cc(-c4cc5c6c(c4)Oc4ccc(-c7ccccc7)cc4B6c4cc(-c6ccccc6)ccc4O5)ccc3B3c4ccc(-c5cc6c7c(c5)Oc5ccc(-c8ccccc8)cc5B7c5cc(-c7ccccc7)ccc5O6)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4cc5c6c(c4)Oc4cc(-c7ccccc7)ccc4B6c4ccc(-c6ccccc6)cc4O5)ccc3B3c4ccc(-c5cc6c7c(c5)Oc5cc(-c8ccccc8)ccc5B7c5ccc(-c7ccccc7)cc5O6)cc4N(c4c(-c5ccccc5)cc(C(C)(C)C)cc4-c4ccccc4)c4cc(C(C)(C)C)cc2c43)c(-c2ccccc2)c1]

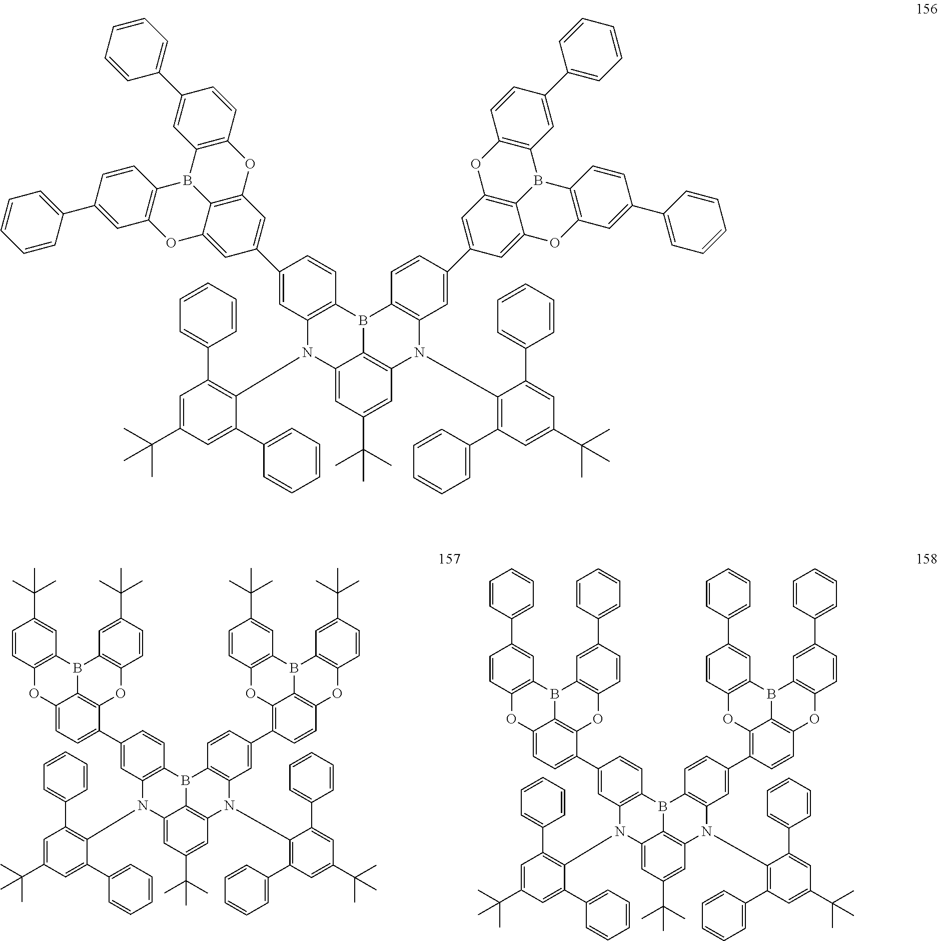

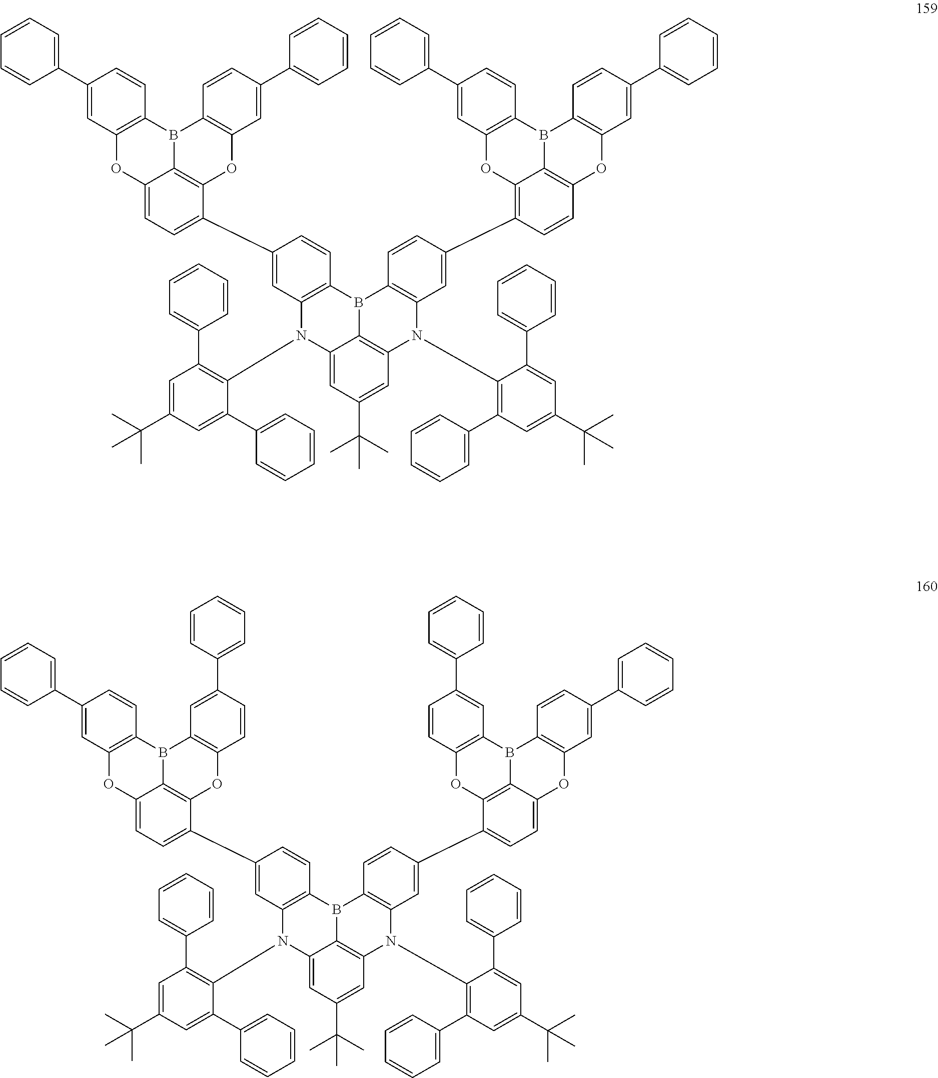 [SMILES: CC(C)(C)c1cc(-c2ccccc2)c(N2c3cc(-c4ccc5c6c4Oc4cc(-c7ccccc7)ccc4B6c4ccc(-c6ccccc6)cc4O5)ccc3B3c4ccc(-c5ccc6c7c5Oc5cc(-c8ccccc8)ccc5B7c5ccc(-c7ccccc7)cc5O6)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4ccc5c6c4Oc4ccc(-c7ccccc7)cc4B6c4ccc(-c6ccccc6)cc4O5)ccc3B3c4ccc(-c5ccc6c7c5Oc5ccc(-c8ccccc8)cc5B7c5ccc(-c7ccccc7)cc5O6)cc4N(c4c(-c5ccccc5)cc(C(C)(C)C)cc4-c4ccccc4)c4cc(C(C)(C)C)cc2c43)c(-c2ccccc2)c1]

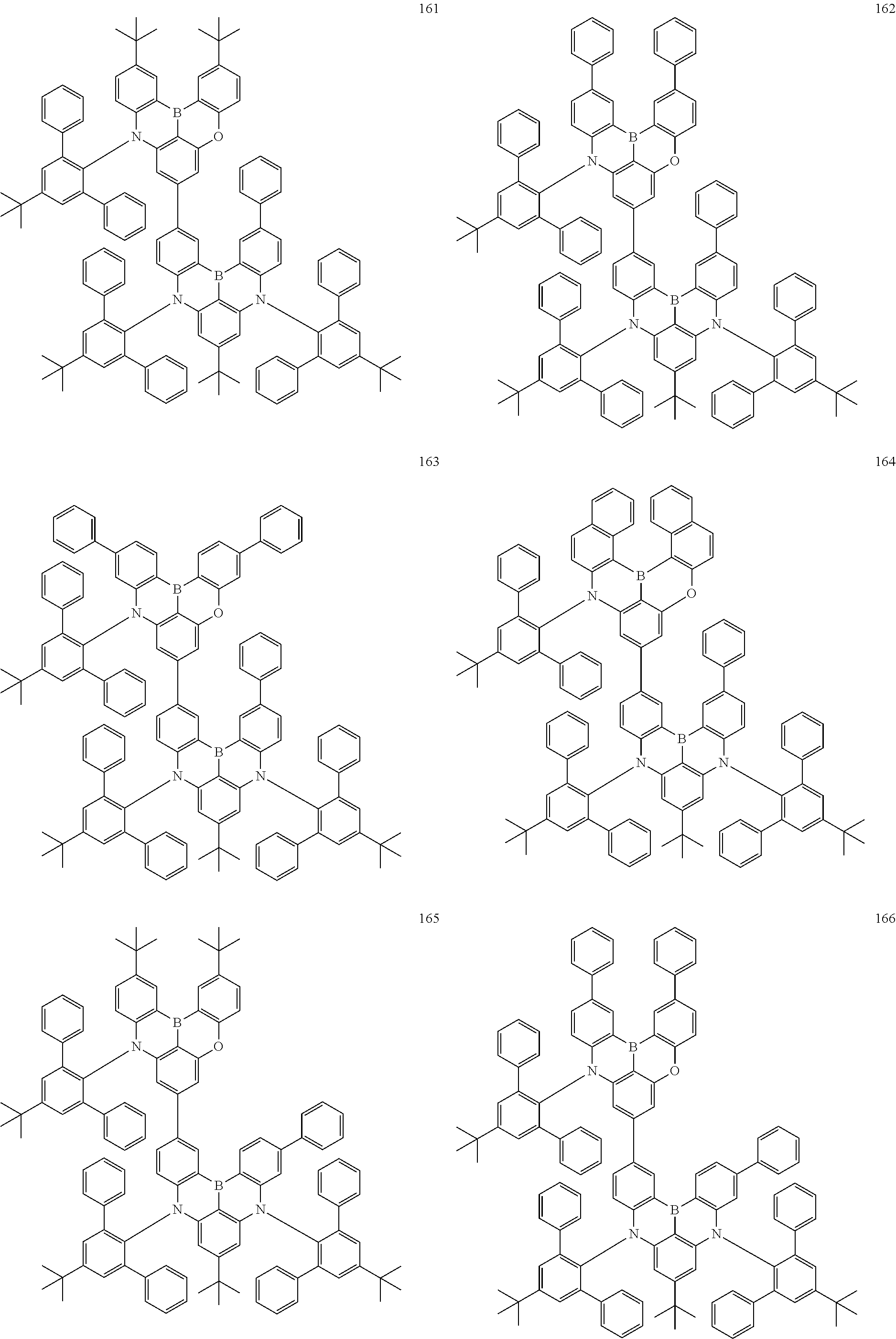

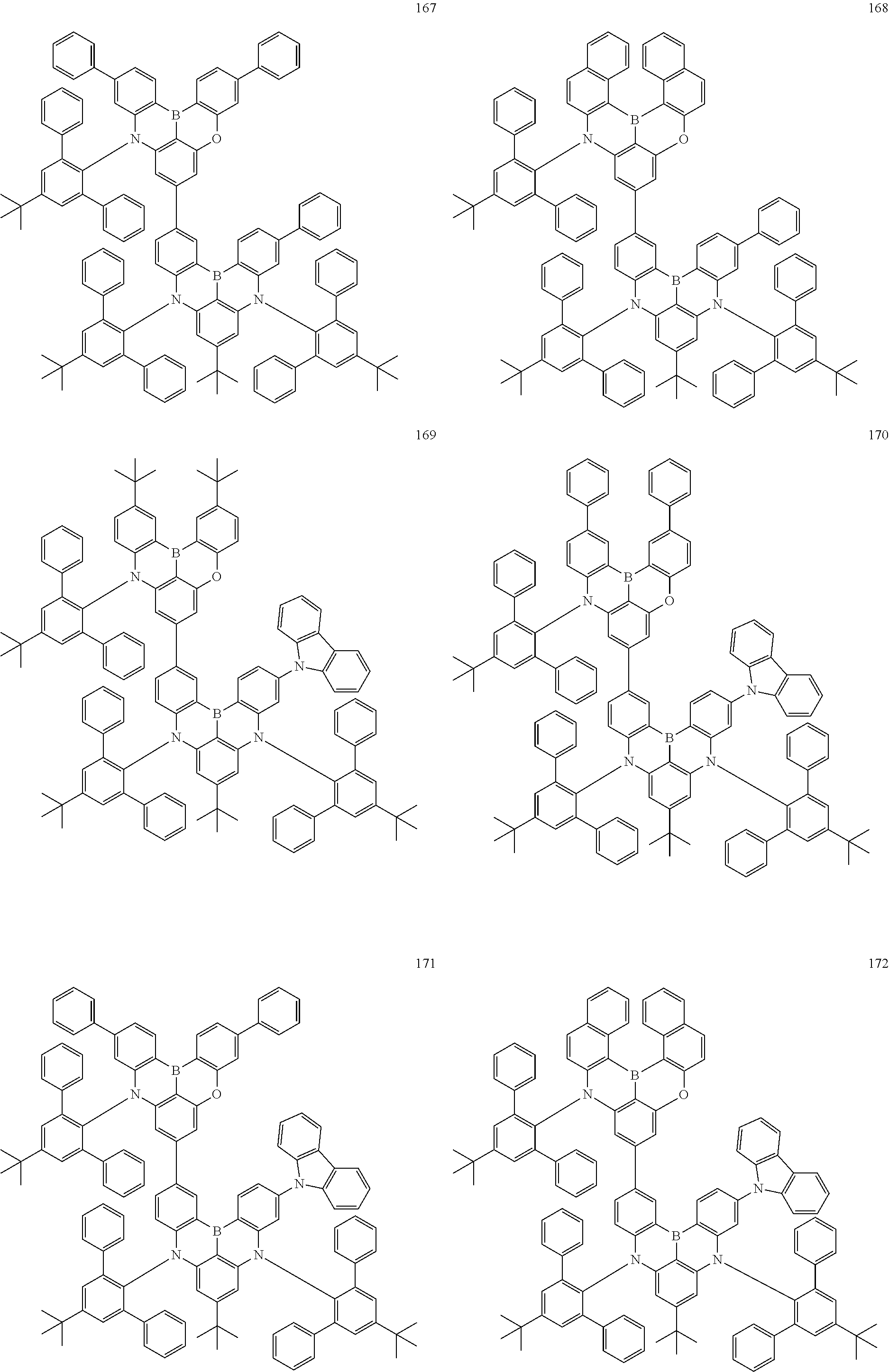

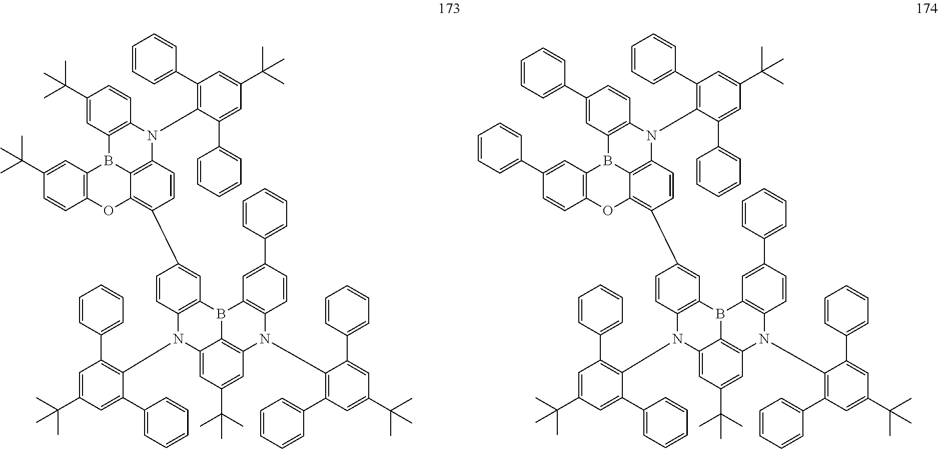 [SMILES: CC(C)(C)c1ccc2c(c1)B1c3cc(C(C)(C)C)ccc3N(c3c(-c4ccccc4)cc(C(C)(C)C)cc3-c3ccccc3)c3ccc(-c4ccc5c(c4)B4c6cc(-c7ccccc7)ccc6N(c6c(-c7ccccc7)cc(C(C)(C)C)cc6-c6ccccc6)c6cc(C(C)(C)C)cc(c64)N5c4c(-c5ccccc5)cc(C(C)(C)C)cc4-c4ccccc4)c(c31)O2 ; CC(C)(C)c1cc(-c2ccccc2)c(N2c3ccc(-c4ccccc4)cc3B3c4cc(-c5ccc6c7c5Oc5ccc(-c8ccccc8)cc5B7c5cc(-c7ccccc7)ccc5N6c5c(-c6ccccc6)cc(C(C)(C)C)cc5-c5ccccc5)ccc4N(c4c(-c5ccccc5)cc(C(C)(C)C)cc4-c4ccccc4)c4cc(C(C)(C)C)cc2c43)c(-c2ccccc2)c1]

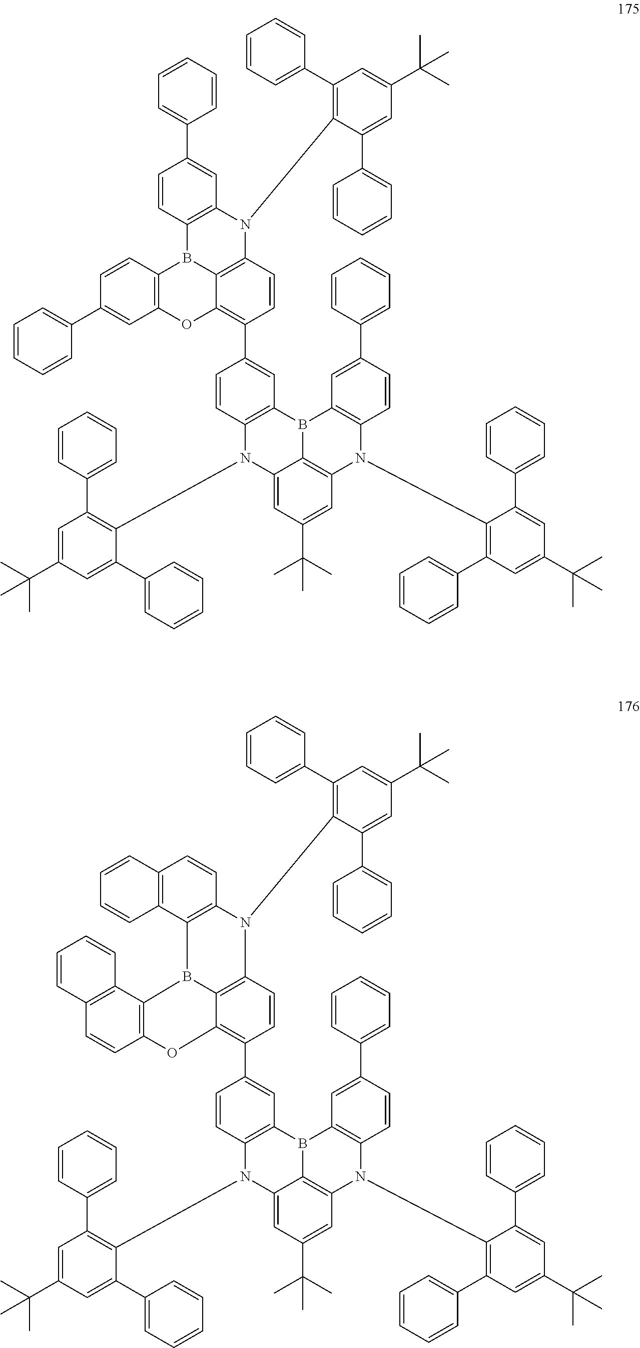

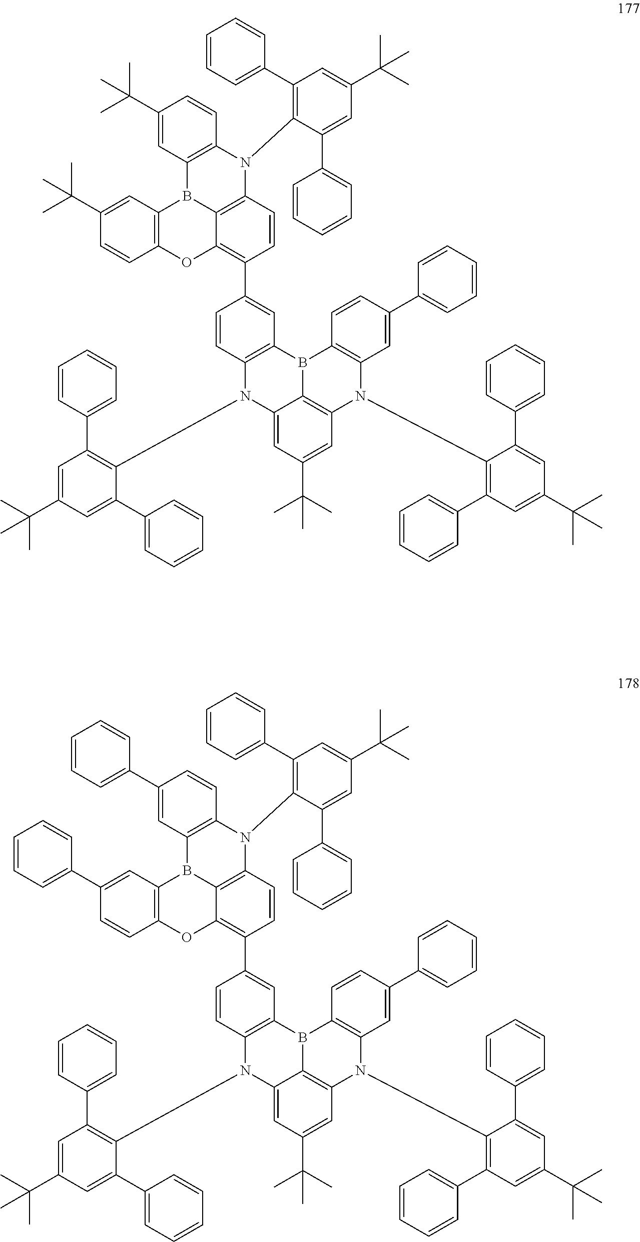

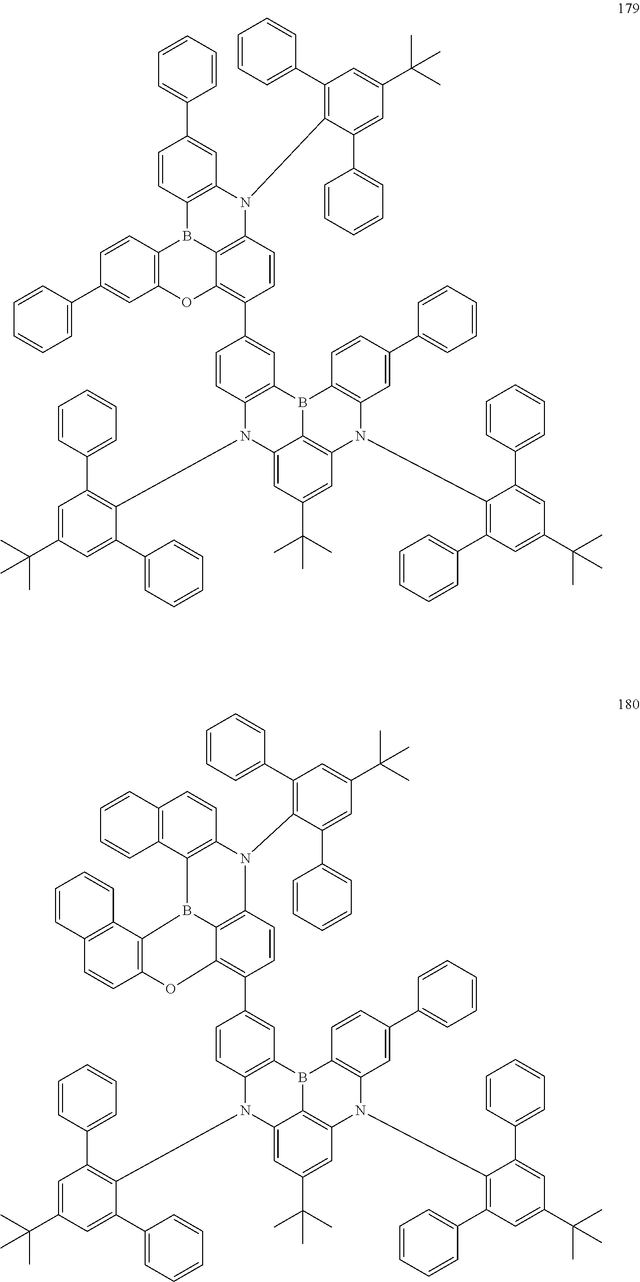

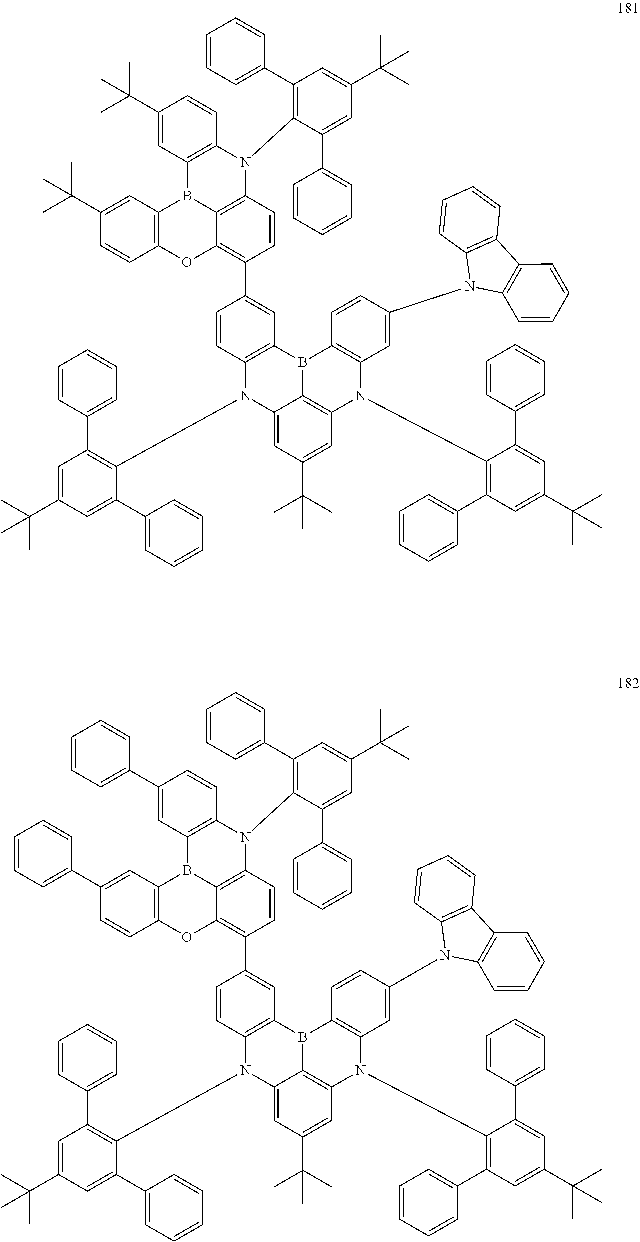

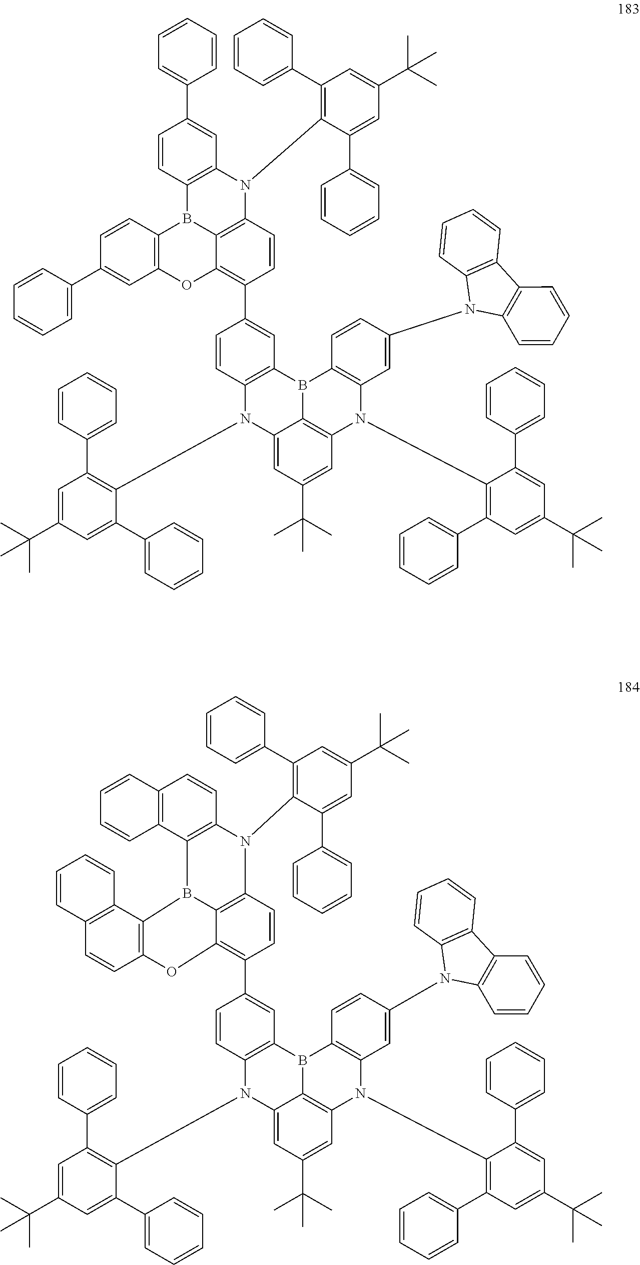

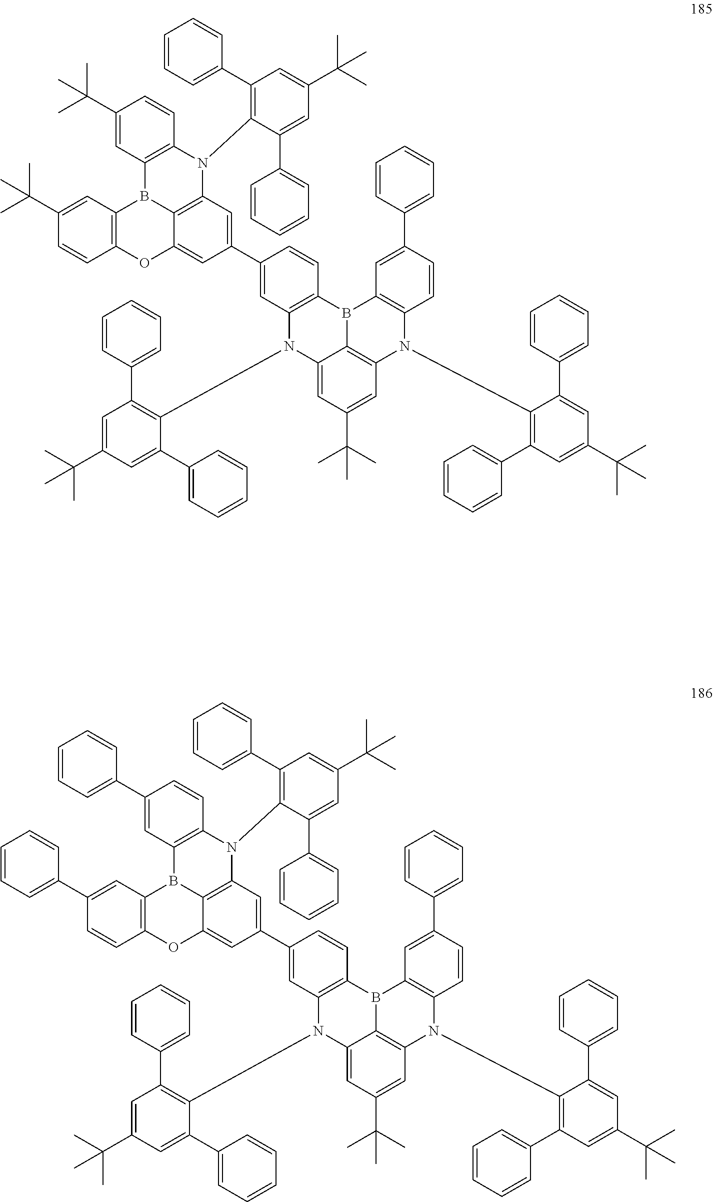 [SMILES: CC(C)(C)c1ccc2c(c1)B1c3cc(C(C)(C)C)ccc3N(c3c(-c4ccccc4)cc(C(C)(C)C)cc3-c3ccccc3)c3cc(-c4ccc5c(c4)N(c4c(-c6ccccc6)cc(C(C)(C)C)cc4-c4ccccc4)c4cc(C(C)(C)C)cc6c4B5c4cc(-c5ccccc5)ccc4N6c4c(-c5ccccc5)cc(C(C)(C)C)cc4-c4ccccc4)cc(c31)O2 ; CC(C)(C)c1cc(-c2ccccc2)c(N2c3ccc(-c4ccccc4)cc3B3c4cc(-c5ccccc5)ccc4Oc4cc(-c5ccc6c(c5)N(c5c(-c7ccccc7)cc(C(C)(C)C)cc5-c5ccccc5)c5cc(C(C)(C)C)cc7c5B6c5cc(-c6ccccc6)ccc5N7c5c(-c6ccccc6)cc(C(C)(C)C)cc5-c5ccccc5)cc2c43)c(-c2ccccc2)c1]

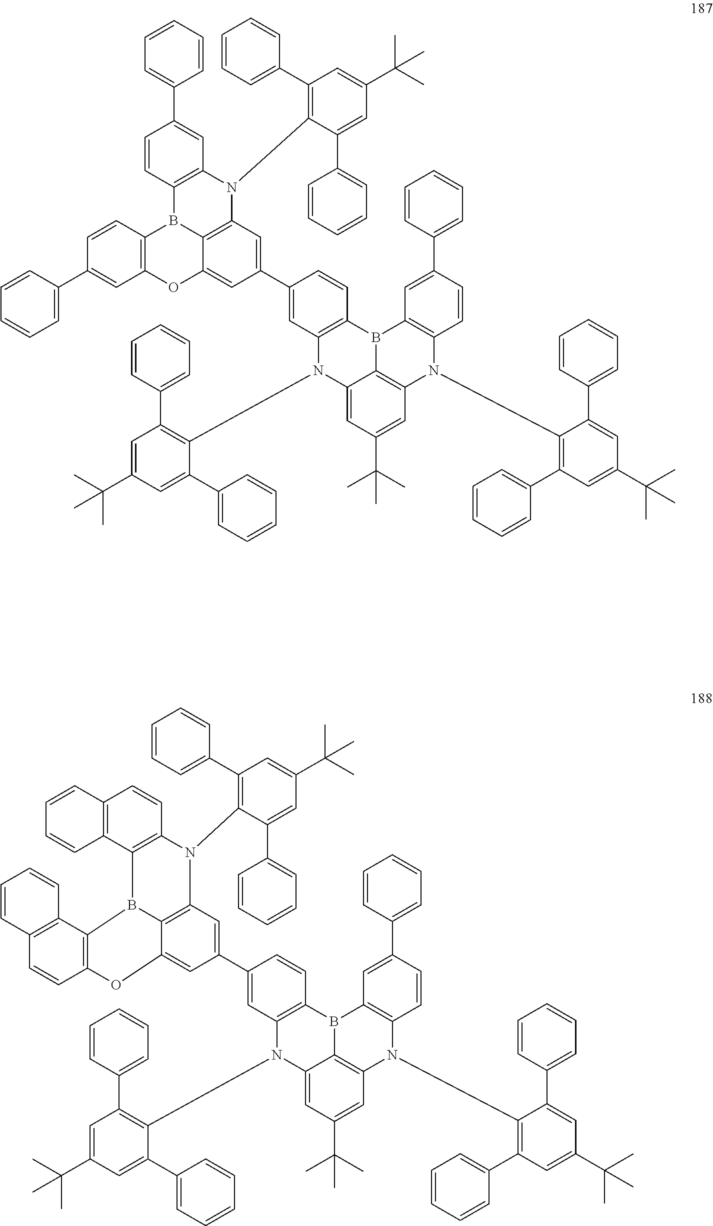 [SMILES: CC(C)(C)c1cc(-c2ccccc2)c(N2c3cc(-c4ccccc4)ccc3B3c4ccc(-c5ccccc5)cc4Oc4cc(-c5ccc6c(c5)N(c5c(-c7ccccc7)cc(C(C)(C)C)cc5-c5ccccc5)c5cc(C(C)(C)C)cc7c5B6c5cc(-c6ccccc6)ccc5N7c5c(-c6ccccc6)cc(C(C)(C)C)cc5-c5ccccc5)cc2c43)c(-c2ccccc2)c1 ; CC(C)(C)c1cc(-c2ccccc2)c(N2c3ccc(-c4ccccc4)cc3B3c4ccc(-c5cc6c7c(c5)N(c5c(-c8ccccc8)cc(C(C)(C)C)cc5-c5ccccc5)c5ccc8ccccc8c5B7c5c(ccc7ccccc57)O6)cc4N(c4c(-c5ccccc5)cc(C(C)(C)C)cc4-c4ccccc4)c4cc(C(C)(C)C)cc2c43)c(-c2ccccc2)c1]

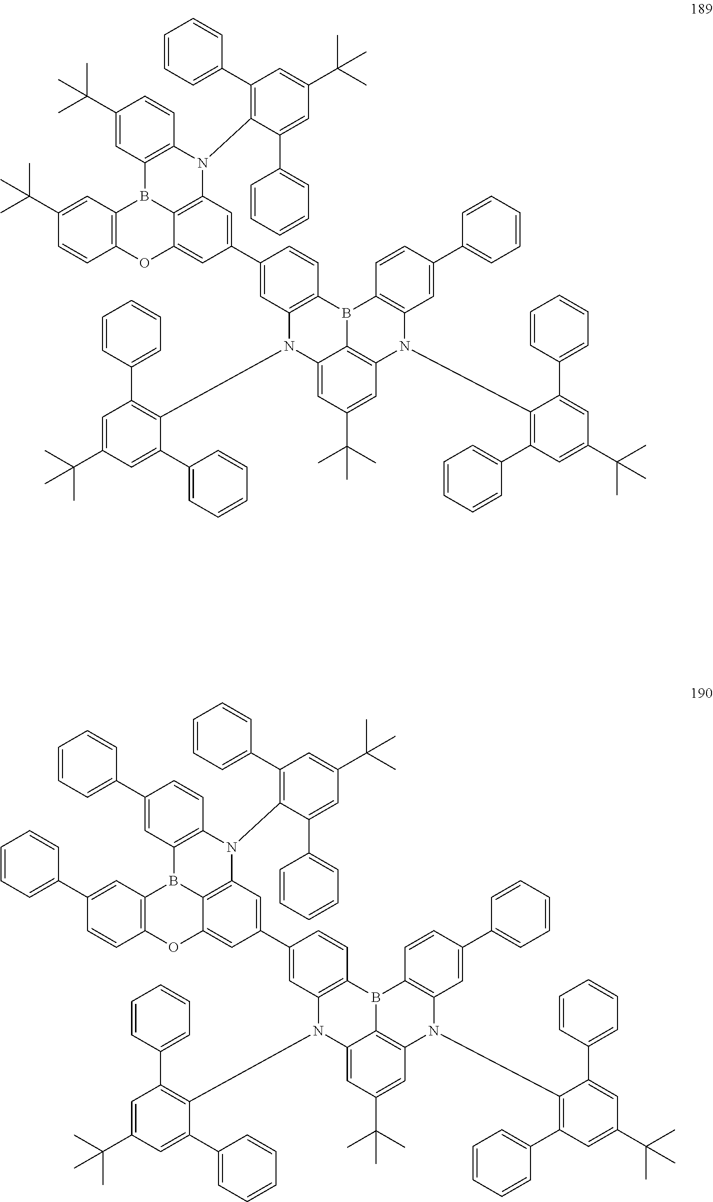 [SMILES: CC(C)(C)c1ccc2c(c1)B1c3cc(C(C)(C)C)ccc3N(c3c(-c4ccccc4)cc(C(C)(C)C)cc3-c3ccccc3)c3cc(-c4ccc5c(c4)N(c4c(-c6ccccc6)cc(C(C)(C)C)cc4-c4ccccc4)c4cc(C(C)(C)C)cc6c4B5c4ccc(-c5ccccc5)cc4N6c4c(-c5ccccc5)cc(C(C)(C)C)cc4-c4ccccc4)cc(c31)O2 ; CC(C)(C)c1cc(-c2ccccc2)c(N2c3ccc(-c4ccccc4)cc3B3c4cc(-c5ccccc5)ccc4Oc4cc(-c5ccc6c(c5)N(c5c(-c7ccccc7)cc(C(C)(C)C)cc5-c5ccccc5)c5cc(C(C)(C)C)cc7c5B6c5ccc(-c6ccccc6)cc5N7c5c(-c6ccccc6)cc(C(C)(C)C)cc5-c5ccccc5)cc2c43)c(-c2ccccc2)c1]

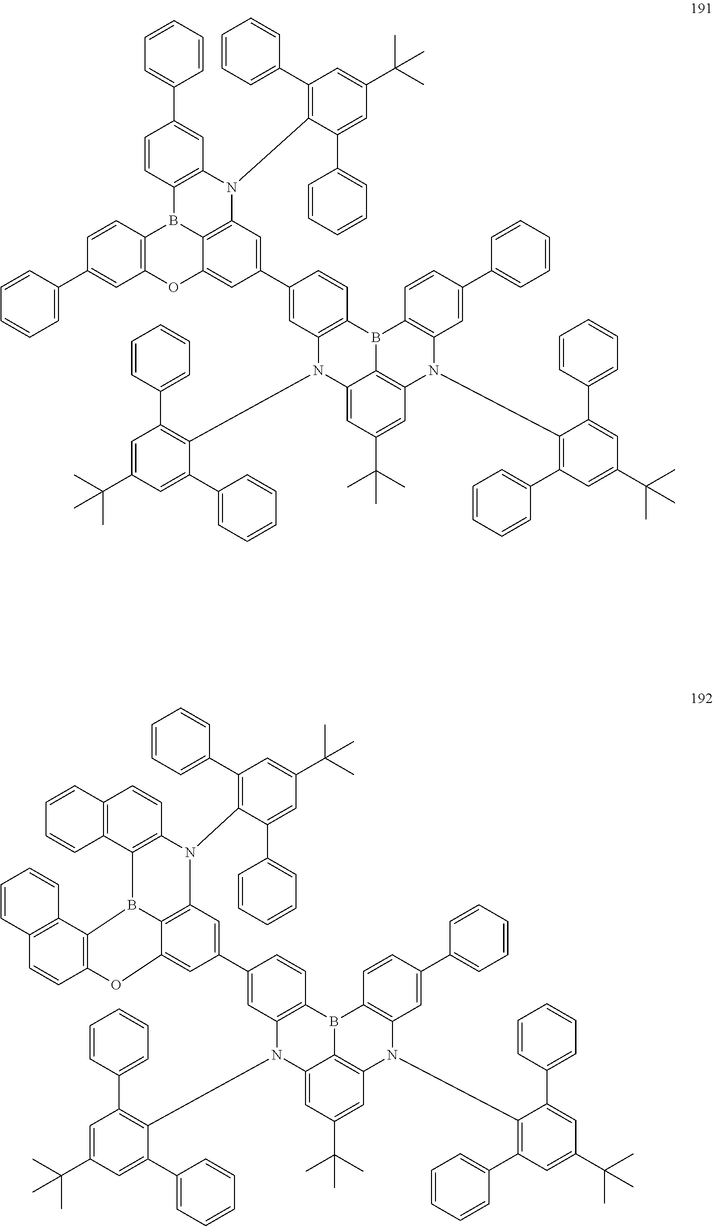 [SMILES: CC(C)(C)c1cc(-c2ccccc2)c(N2c3cc(-c4ccccc4)ccc3B3c4ccc(-c5ccccc5)cc4Oc4cc(-c5ccc6c(c5)N(c5c(-c7ccccc7)cc(C(C)(C)C)cc5-c5ccccc5)c5cc(C(C)(C)C)cc7c5B6c5ccc(-c6ccccc6)cc5N7c5c(-c6ccccc6)cc(C(C)(C)C)cc5-c5ccccc5)cc2c43)c(-c2ccccc2)c1 ; CC(C)(C)c1cc(-c2ccccc2)c(N2c3cc(-c4ccccc4)ccc3B3c4ccc(-c5cc6c7c(c5)N(c5c(-c8ccccc8)cc(C(C)(C)C)cc5-c5ccccc5)c5ccc8ccccc8c5B7c5c(ccc7ccccc57)O6)cc4N(c4c(-c5ccccc5)cc(C(C)(C)C)cc4-c4ccccc4)c4cc(C(C)(C)C)cc2c43)c(-c2ccccc2)c1]

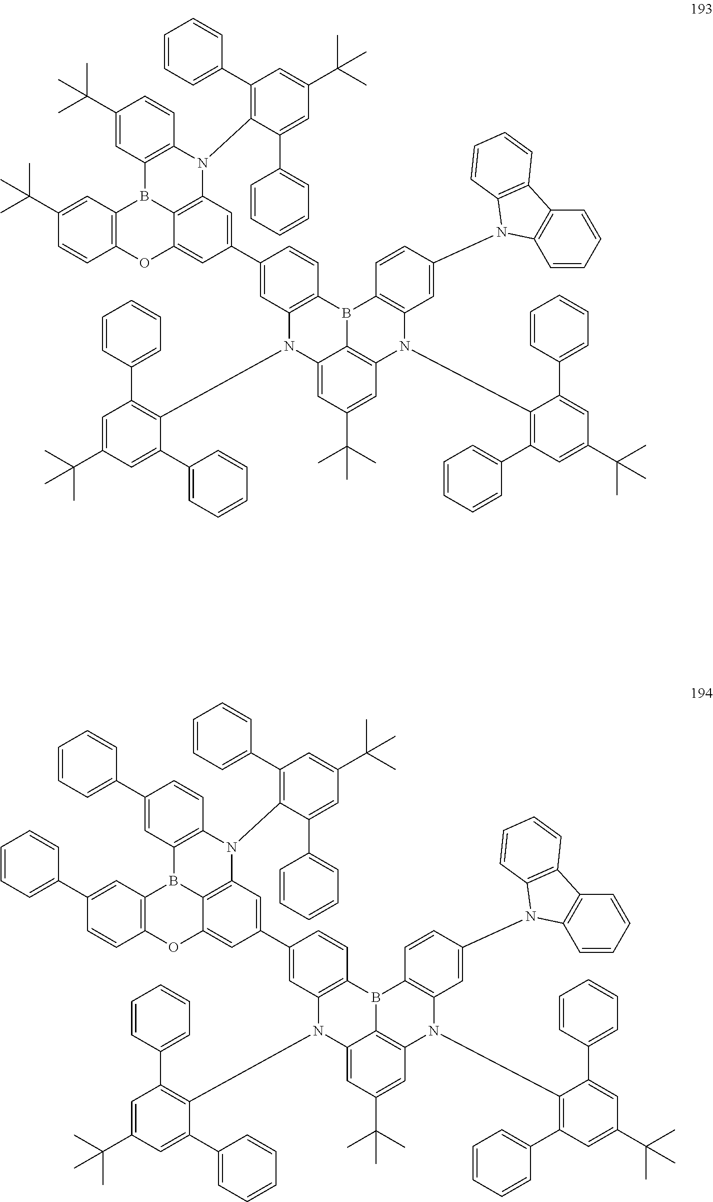 [SMILES: CC(C)(C)c1ccc2c(c1)B1c3cc(C(C)(C)C)ccc3N(c3c(-c4ccccc4)cc(C(C)(C)C)cc3-c3ccccc3)c3cc(-c4ccc5c(c4)N(c4c(-c6ccccc6)cc(C(C)(C)C)cc4-c4ccccc4)c4cc(C(C)(C)C)cc6c4B5c4ccc(-n5c7ccccc7c7ccccc75)cc4N6c4c(-c5ccccc5)cc(C(C)(C)C)cc4-c4ccccc4)cc(c31)O2 ; CC(C)(C)c1cc(-c2ccccc2)c(N2c3ccc(-c4ccccc4)cc3B3c4cc(-c5ccccc5)ccc4Oc4cc(-c5ccc6c(c5)N(c5c(-c7ccccc7)cc(C(C)(C)C)cc5-c5ccccc5)c5cc(C(C)(C)C)cc7c5B6c5ccc(-n6c8ccccc8c8ccccc86)cc5N7c5c(-c6ccccc6)cc(C(C)(C)C)cc5-c5ccccc5)cc2c43)c(-c2ccccc2)c1]

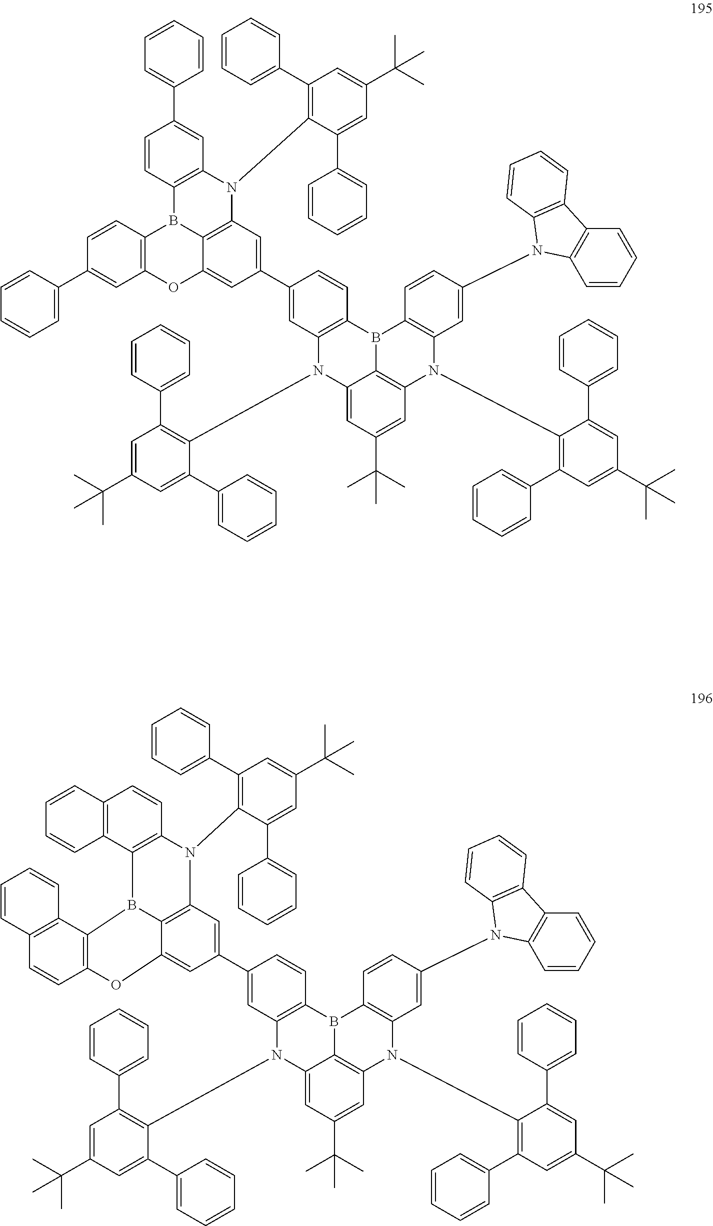 [SMILES: CC(C)(C)c1cc(-c2ccccc2)c(N2c3cc(-c4ccccc4)ccc3B3c4ccc(-c5ccccc5)cc4Oc4cc(-c5ccc6c(c5)N(c5c(-c7ccccc7)cc(C(C)(C)C)cc5-c5ccccc5)c5cc(C(C)(C)C)cc7c5B6c5ccc(-n6c8ccccc8c8ccccc86)cc5N7c5c(-c6ccccc6)cc(C(C)(C)C)cc5-c5ccccc5)cc2c43)c(-c2ccccc2)c1 ; CC(C)(C)c1cc(-c2ccccc2)c(N2c3cc(-c4cc5c6c(c4)N(c4c(-c7ccccc7)cc(C(C)(C)C)cc4-c4ccccc4)c4ccc7ccccc7c4B6c4c(ccc6ccccc46)O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1]

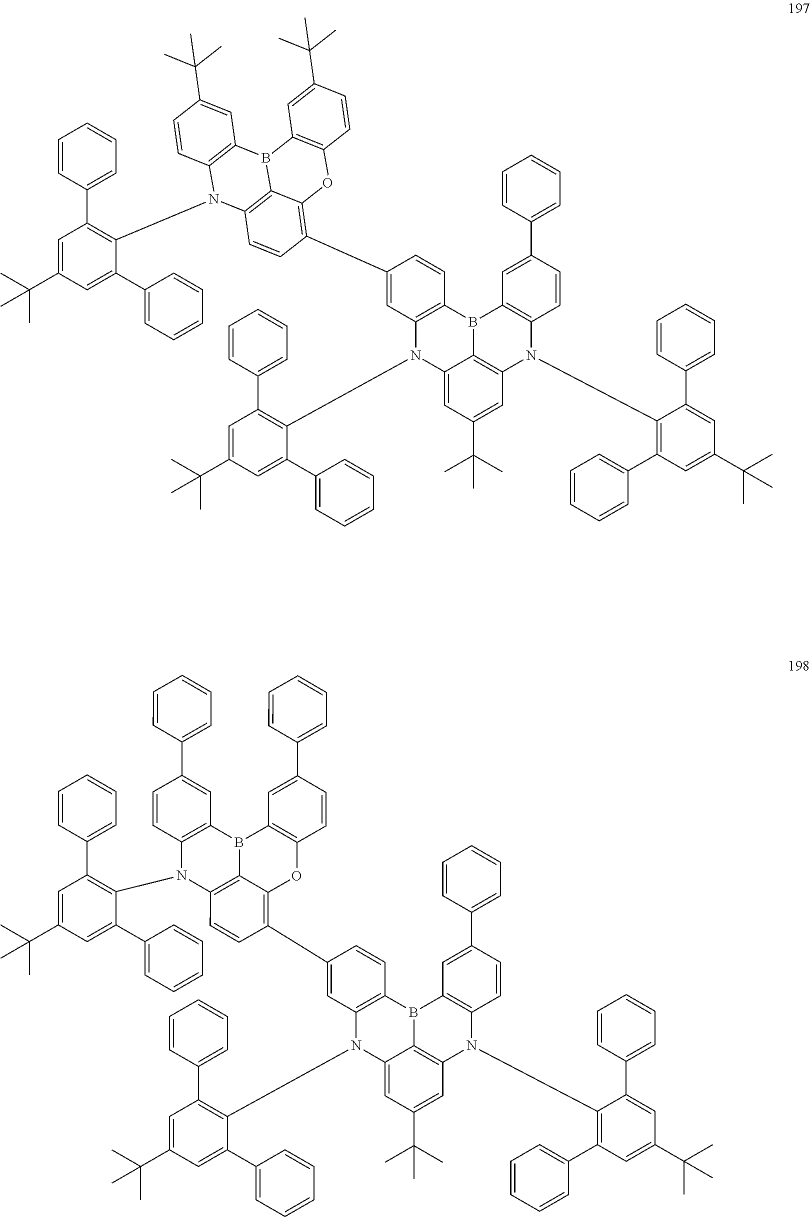

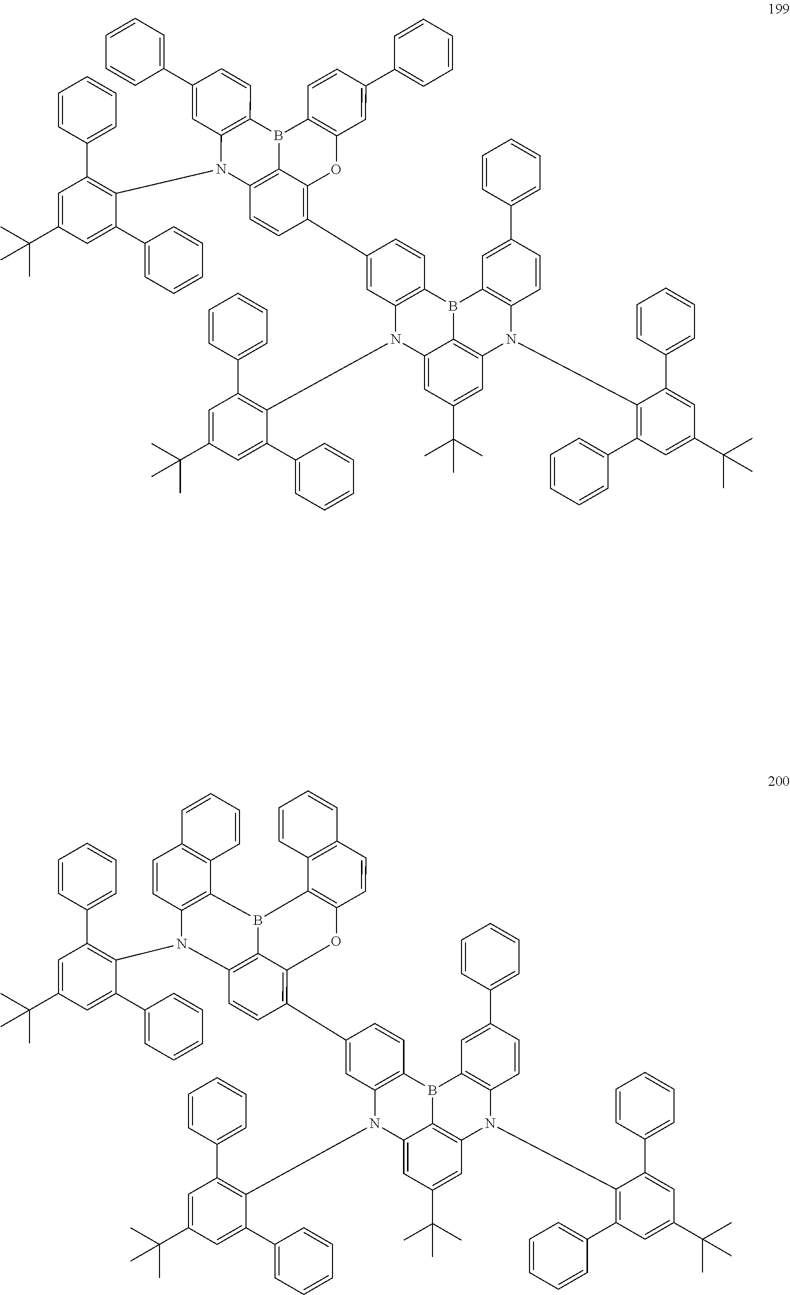

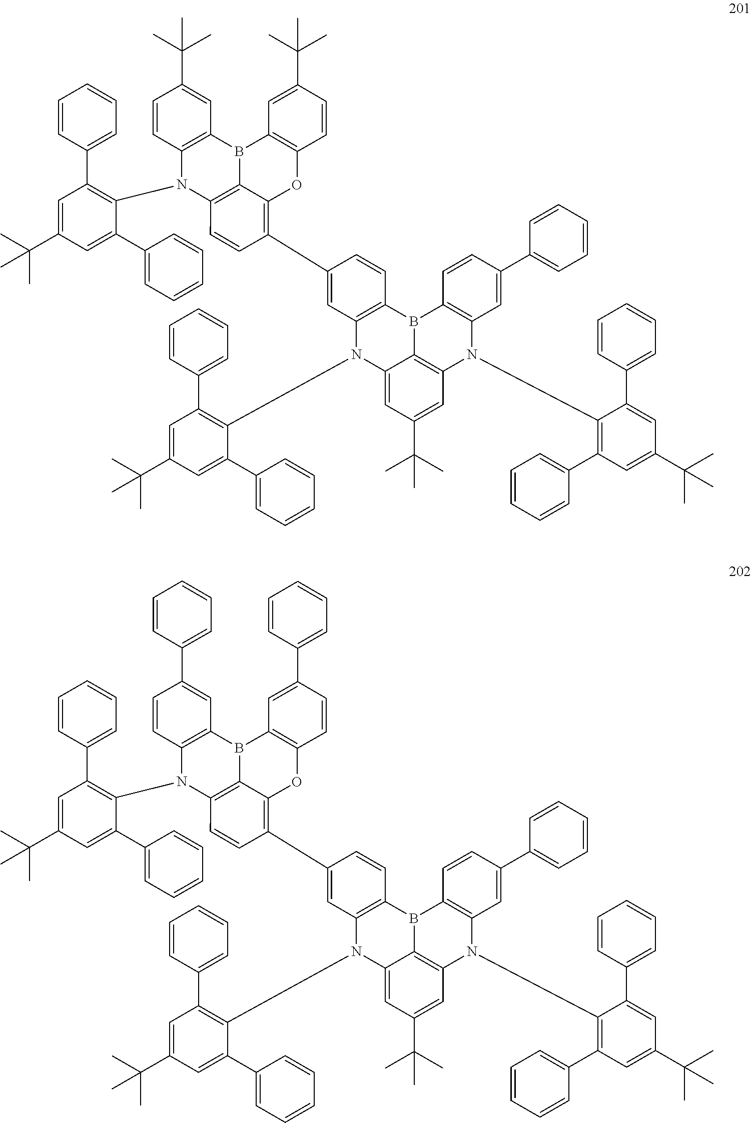

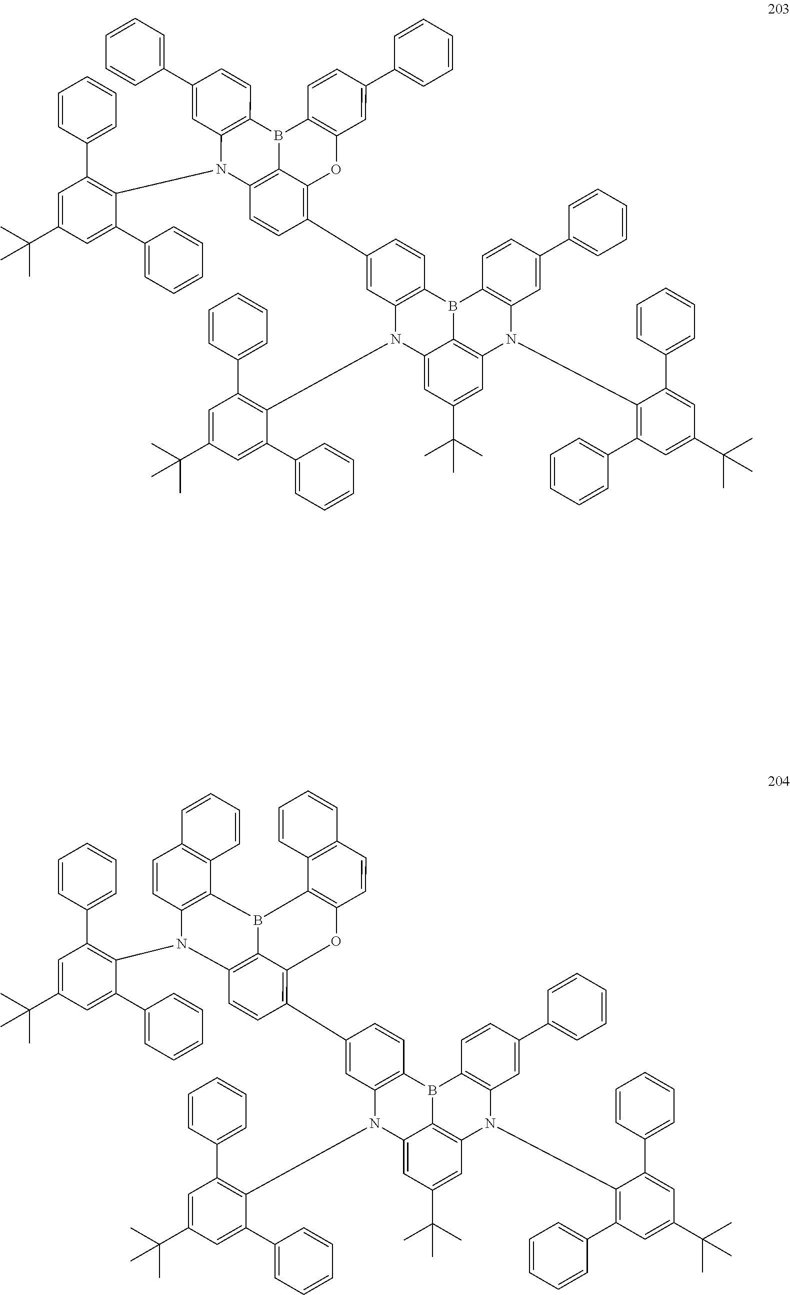

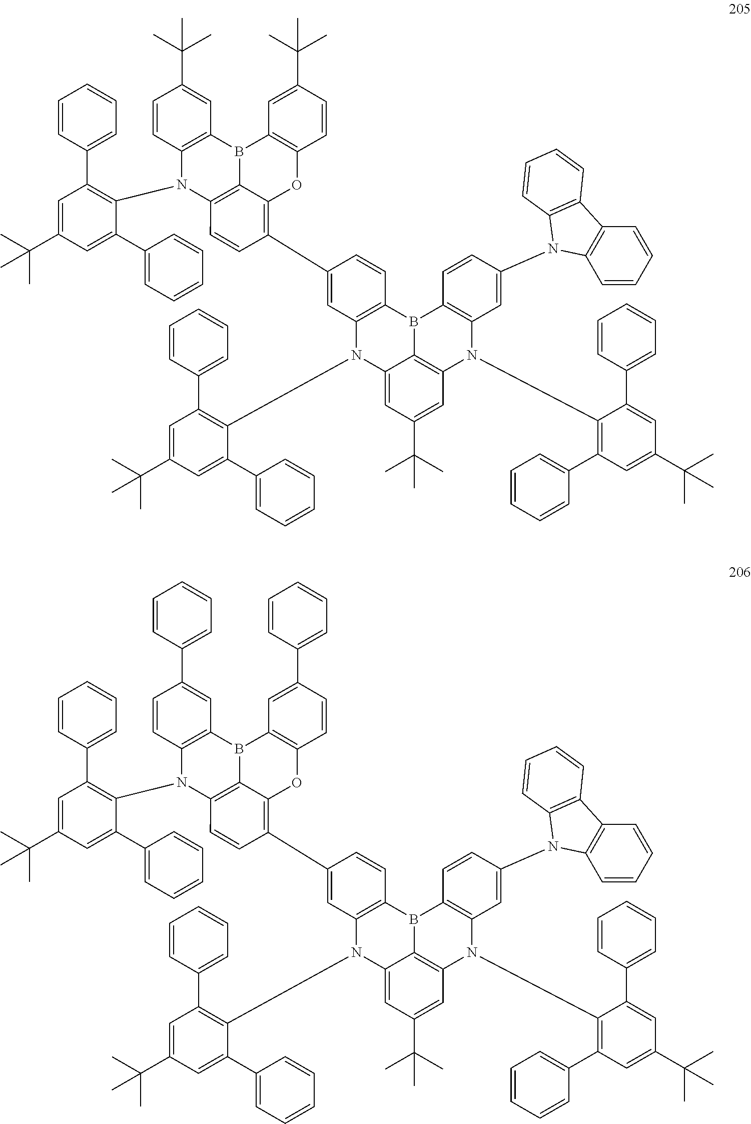

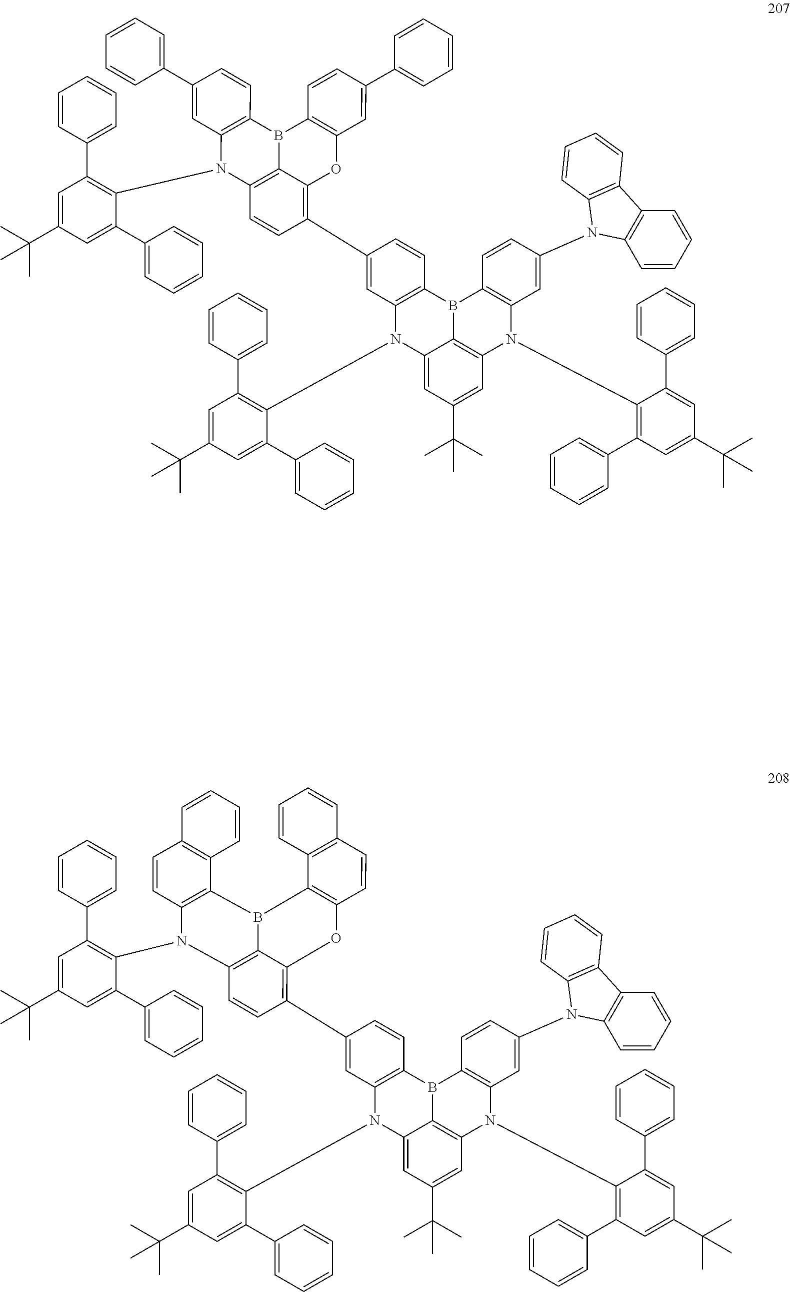

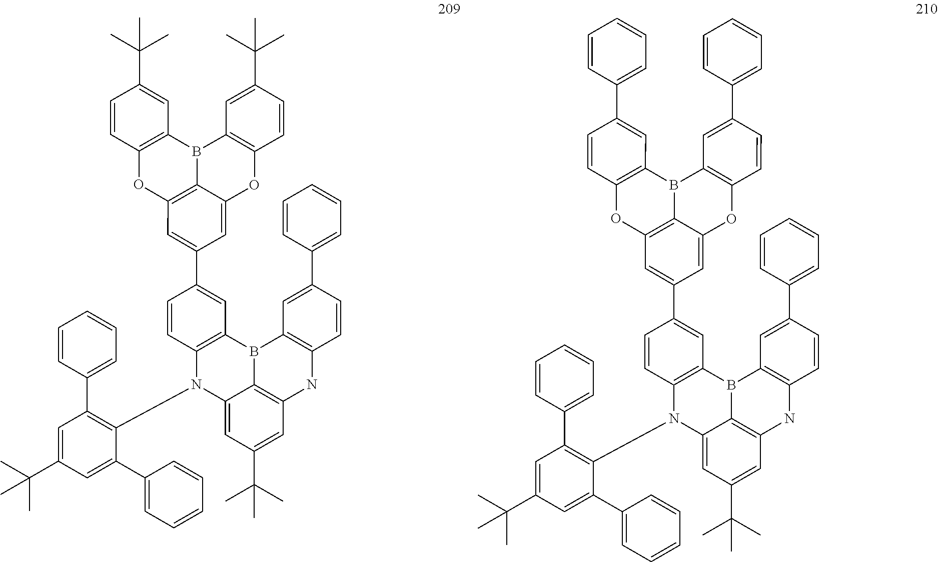 [SMILES: CC(C)(C)c1ccc2c(c1)B1c3cc(C(C)(C)C)ccc3Oc3cc(-c4ccc5c(c4)B4c6cc(-c7ccccc7)ccc6Nc6cc(C(C)(C)C)cc(c64)N5c4c(-c5ccccc5)cc(C(C)(C)C)cc4-c4ccccc4)cc(c31)O2 ; CC(C)(C)c1cc(-c2ccccc2)c(N2c3ccc(-c4cc5c6c(c4)Oc4ccc(-c7ccccc7)cc4B6c4cc(-c6ccccc6)ccc4O5)cc3B3c4cc(-c5ccccc5)ccc4Nc4cc(C(C)(C)C)cc2c43)c(-c2ccccc2)c1]

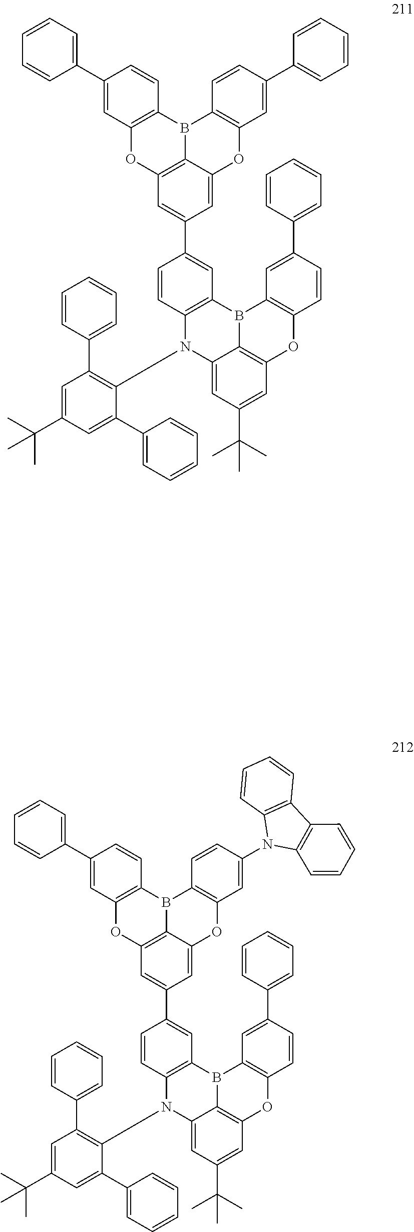 [SMILES: CC(C)(C)c1cc(-c2ccccc2)c(N2c3ccc(-c4cc5c6c(c4)Oc4cc(-c7ccccc7)ccc4B6c4ccc(-c6ccccc6)cc4O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-c6ccccc6)cc4O5)cc3B3c4cc(-c5ccccc5)ccc4Oc4cc(C(C)(C)C)cc2c43)c(-c2ccccc2)c1]

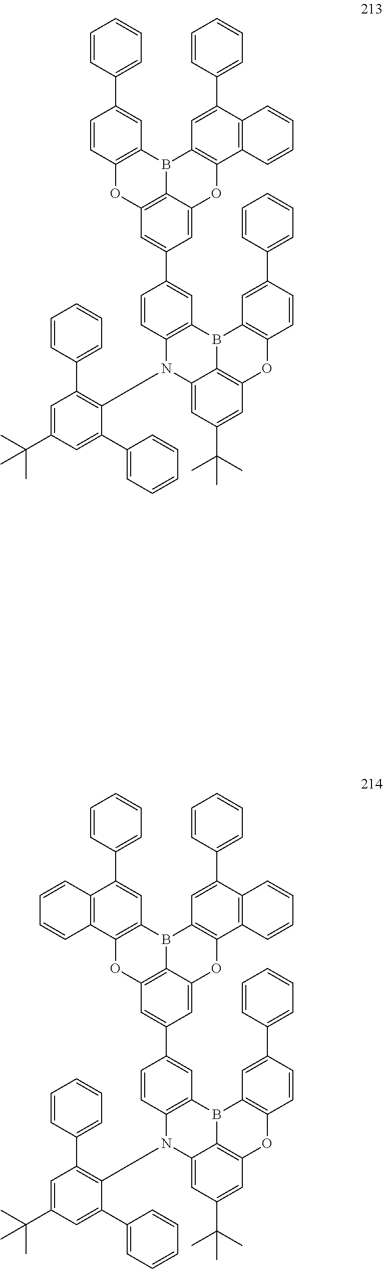 [SMILES: CC(C)(C)c1cc(-c2ccccc2)c(N2c3ccc(-c4cc5c6c(c4)Oc4c(cc(-c7ccccc7)c7ccccc47)B6c4cc(-c6ccccc6)ccc4O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4cc5c6c(c4)Oc4c(cc(-c7ccccc7)c7ccccc47)B6c4cc(-c6ccccc6)c6ccccc6c4O5)cc3B3c4cc(-c5ccccc5)ccc4Oc4cc(C(C)(C)C)cc2c43)c(-c2ccccc2)c1]

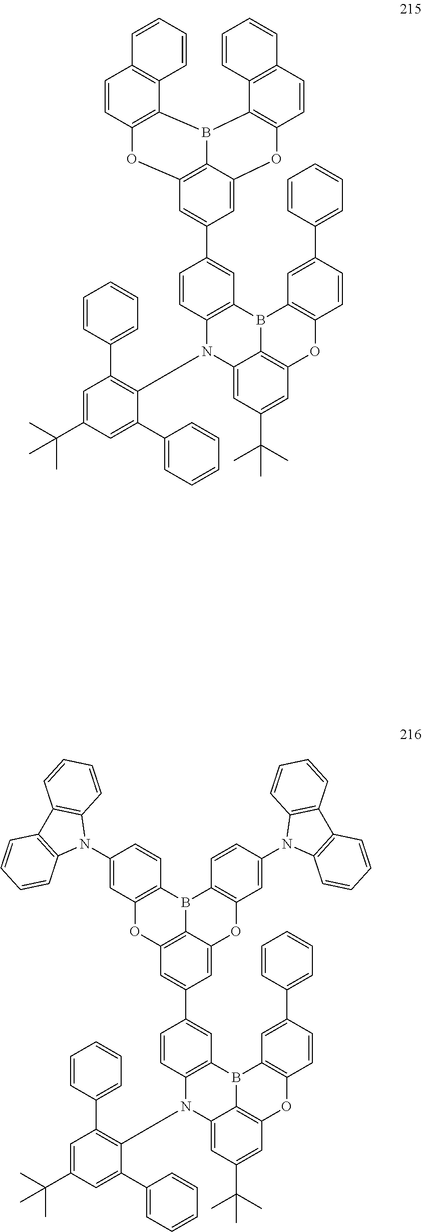 [SMILES: CC(C)(C)c1cc(-c2ccccc2)c(N2c3ccc(-c4cc5c6c(c4)Oc4ccc7ccccc7c4B6c4c(ccc6ccccc46)O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-n6c7ccccc7c7ccccc76)cc4O5)cc3B3c4cc(-c5ccccc5)ccc4Oc4cc(C(C)(C)C)cc2c43)c(-c2ccccc2)c1]

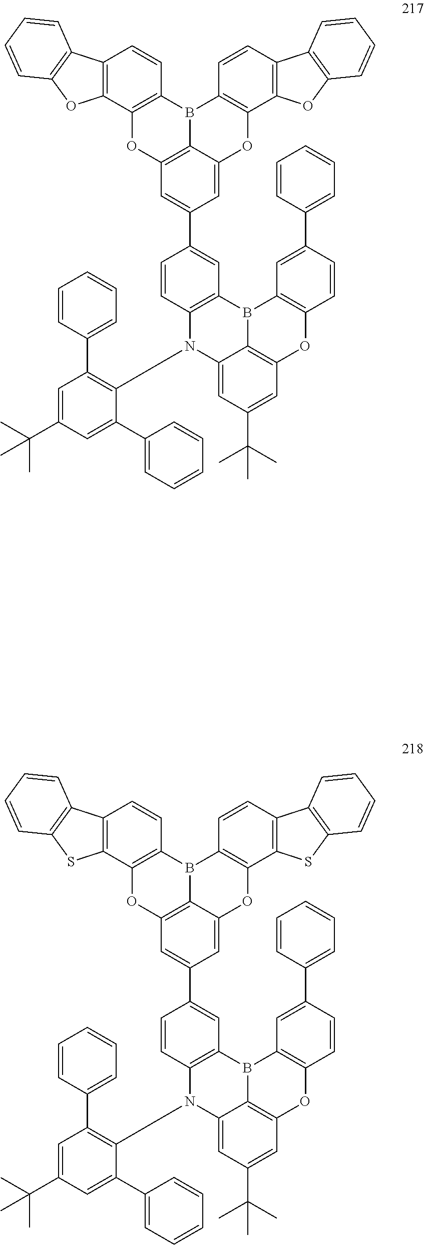 [SMILES: CC(C)(C)c1cc(-c2ccccc2)c(N2c3ccc(-c4cc5c6c(c4)Oc4c(ccc7c4oc4ccccc47)B6c4ccc6c(oc7ccccc76)c4O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4cc5c6c(c4)Oc4c(ccc7c4sc4ccccc47)B6c4ccc6c(sc7ccccc76)c4O5)cc3B3c4cc(-c5ccccc5)ccc4Oc4cc(C(C)(C)C)cc2c43)c(-c2ccccc2)c1]

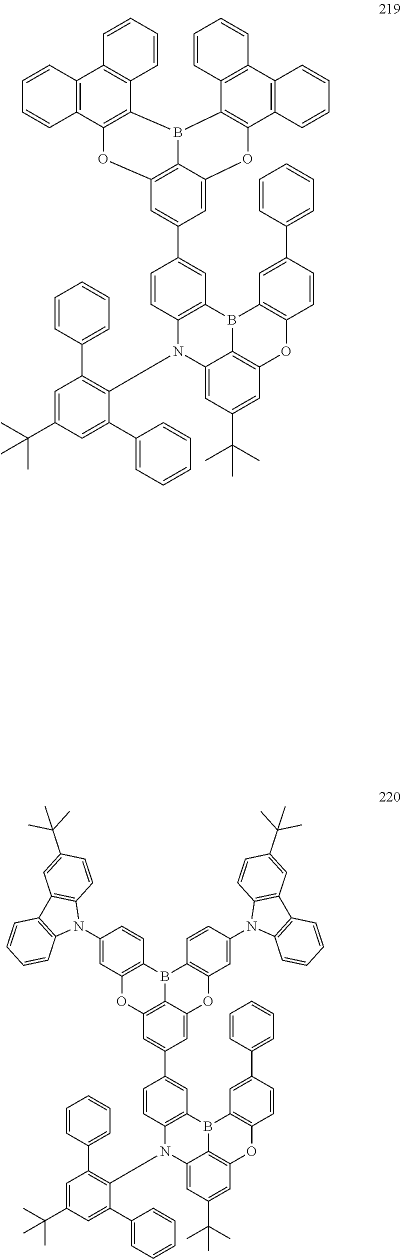 [SMILES: CC(C)(C)c1cc(-c2ccccc2)c(N2c3ccc(-c4cc5c6c(c4)Oc4c(c7ccccc7c7ccccc47)B6c4c(c6ccccc6c6ccccc46)O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8cc(C(C)(C)C)ccc87)ccc4B6c4ccc(-n6c7ccccc7c7cc(C(C)(C)C)ccc76)cc4O5)cc3B3c4cc(-c5ccccc5)ccc4Oc4cc(C(C)(C)C)cc2c43)c(-c2ccccc2)c1]

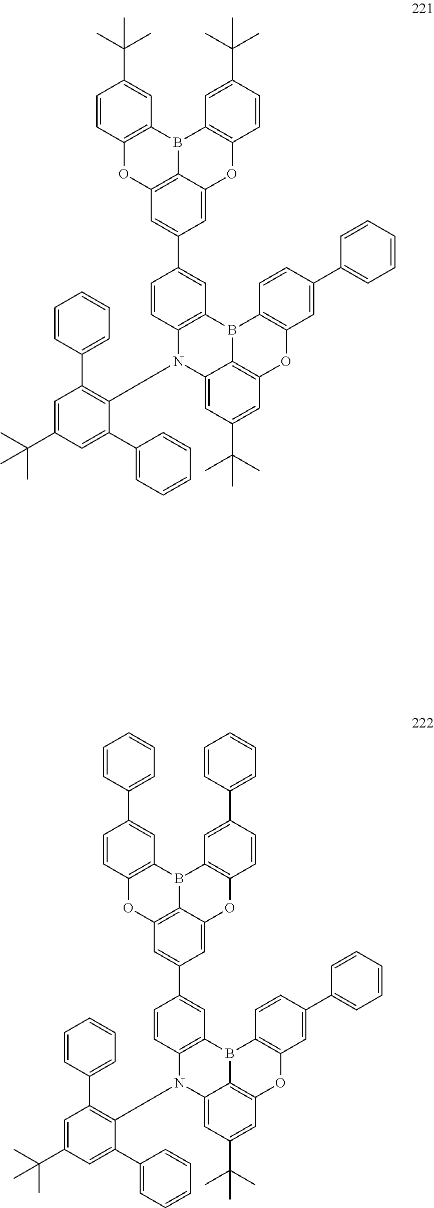 [SMILES: CC(C)(C)c1ccc2c(c1)B1c3cc(C(C)(C)C)ccc3Oc3cc(-c4ccc5c(c4)B4c6ccc(-c7ccccc7)cc6Oc6cc(C(C)(C)C)cc(c64)N5c4c(-c5ccccc5)cc(C(C)(C)C)cc4-c4ccccc4)cc(c31)O2 ; CC(C)(C)c1cc(-c2ccccc2)c(N2c3ccc(-c4cc5c6c(c4)Oc4ccc(-c7ccccc7)cc4B6c4cc(-c6ccccc6)ccc4O5)cc3B3c4ccc(-c5ccccc5)cc4Oc4cc(C(C)(C)C)cc2c43)c(-c2ccccc2)c1]

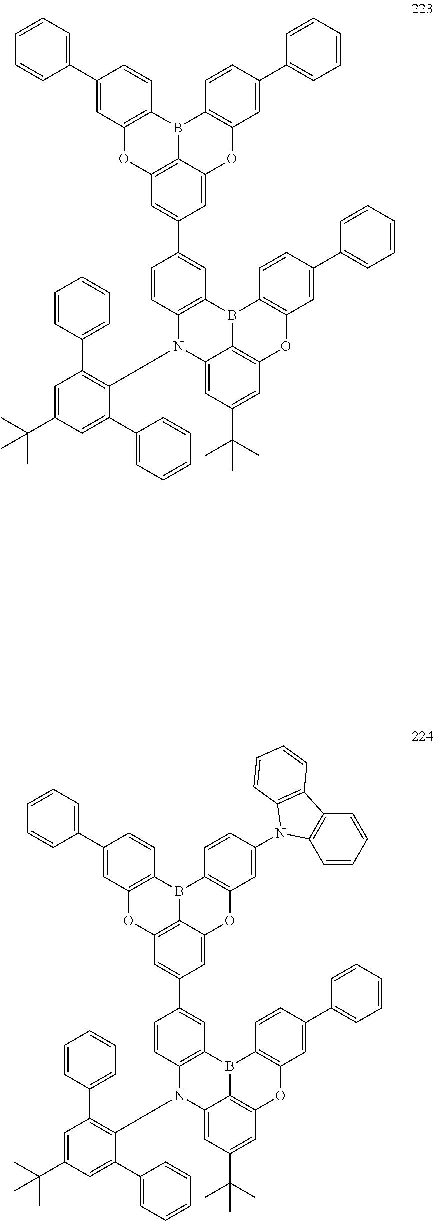 [SMILES: CC(C)(C)c1cc(-c2ccccc2)c(N2c3ccc(-c4cc5c6c(c4)Oc4cc(-c7ccccc7)ccc4B6c4ccc(-c6ccccc6)cc4O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-c6ccccc6)cc4O5)cc3B3c4ccc(-c5ccccc5)cc4Oc4cc(C(C)(C)C)cc2c43)c(-c2ccccc2)c1]

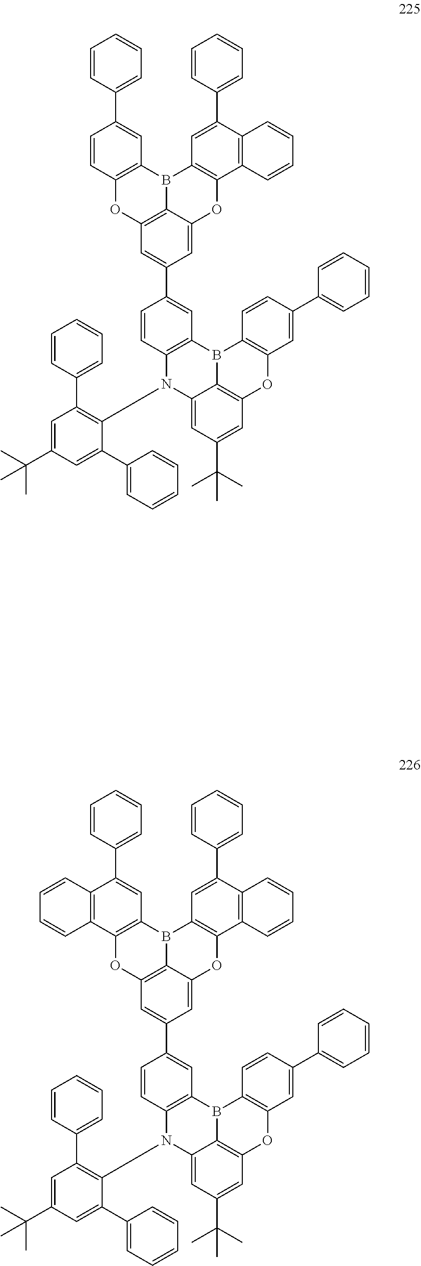 [SMILES: CC(C)(C)c1cc(-c2ccccc2)c(N2c3ccc(-c4cc5c6c(c4)Oc4c(cc(-c7ccccc7)c7ccccc47)B6c4cc(-c6ccccc6)ccc4O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4c(cc(-c7ccccc7)c7ccccc47)B6c4cc(-c6ccccc6)c6ccccc6c4O5)cc3B3c4ccc(-c5ccccc5)cc4Oc4cc(C(C)(C)C)cc2c43)c(-c2ccccc2)c1]

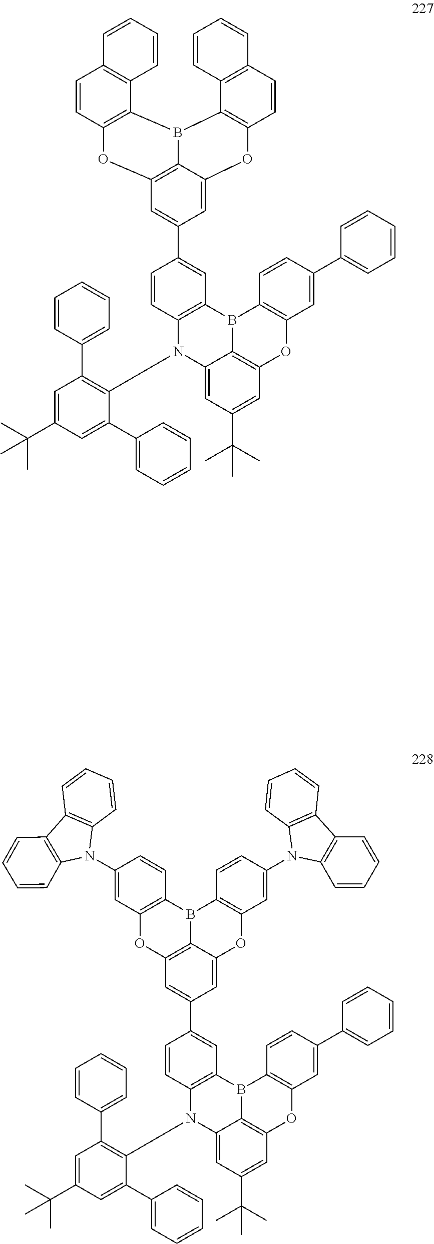 [SMILES: CC(C)(C)c1cc(-c2ccccc2)c(N2c3ccc(-c4cc5c6c(c4)Oc4ccc7ccccc7c4B6c4c(ccc6ccccc46)O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-n6c7ccccc7c7ccccc76)cc4O5)cc3B3c4ccc(-c5ccccc5)cc4Oc4cc(C(C)(C)C)cc2c43)c(-c2ccccc2)c1]

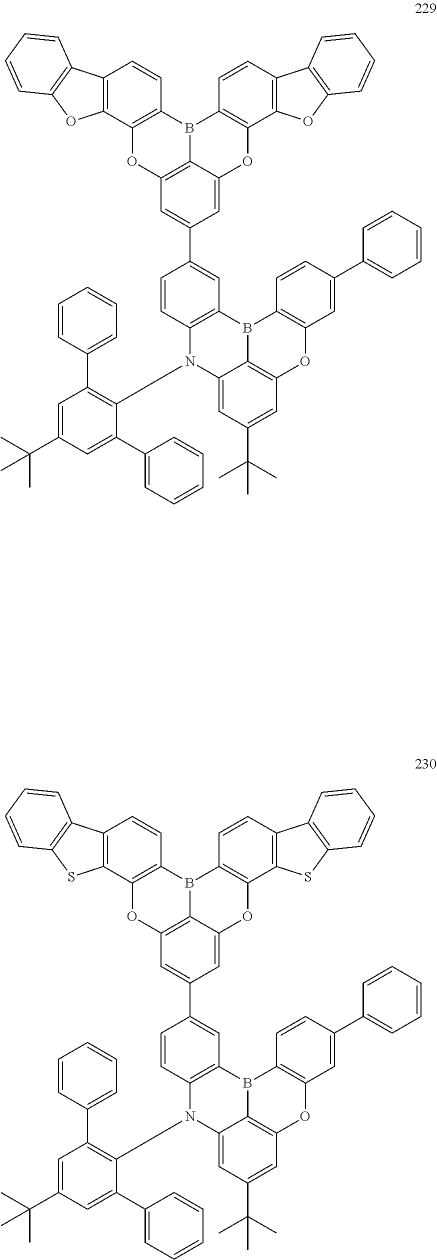 [SMILES: CC(C)(C)c1cc(-c2ccccc2)c(N2c3ccc(-c4cc5c6c(c4)Oc4c(ccc7c4oc4ccccc47)B6c4ccc6c(oc7ccccc76)c4O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4c(ccc7c4sc4ccccc47)B6c4ccc6c(sc7ccccc76)c4O5)cc3B3c4ccc(-c5ccccc5)cc4Oc4cc(C(C)(C)C)cc2c43)c(-c2ccccc2)c1]

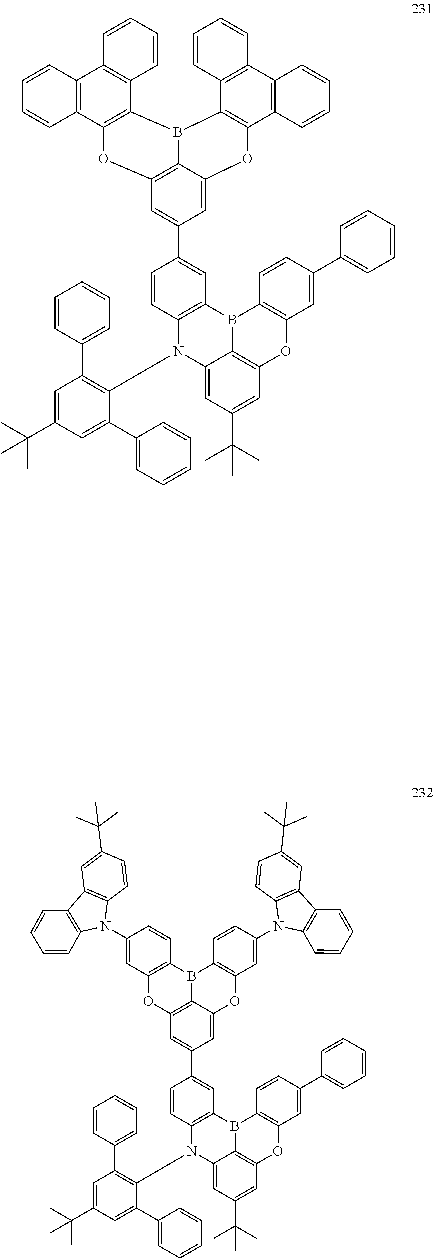 [SMILES: CC(C)(C)c1cc(-c2ccccc2)c(N2c3ccc(-c4cc5c6c(c4)Oc4c(c7ccccc7c7ccccc47)B6c4c(c6ccccc6c6ccccc46)O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8cc(C(C)(C)C)ccc87)ccc4B6c4ccc(-n6c7ccccc7c7cc(C(C)(C)C)ccc76)cc4O5)cc3B3c4ccc(-c5ccccc5)cc4Oc4cc(C(C)(C)C)cc2c43)c(-c2ccccc2)c1]

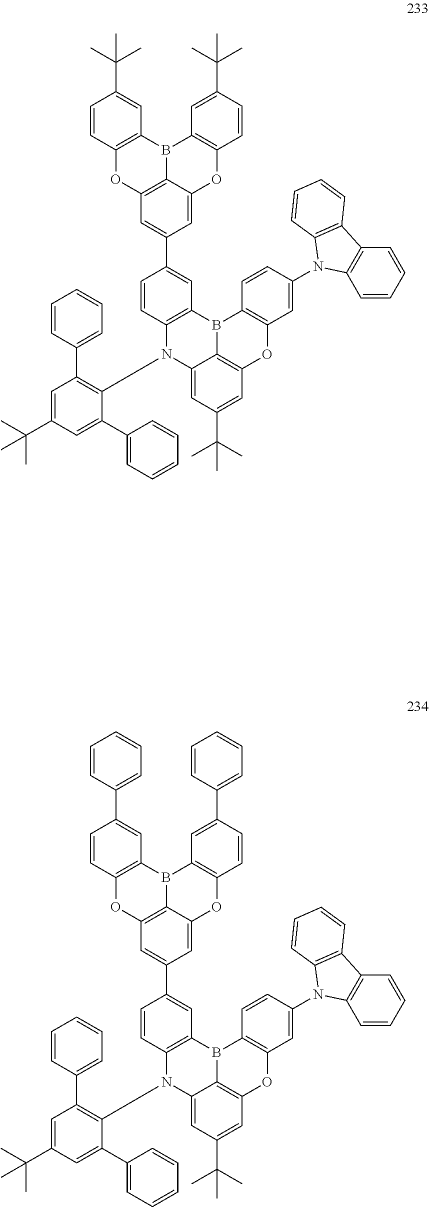 [SMILES: CC(C)(C)c1ccc2c(c1)B1c3cc(C(C)(C)C)ccc3Oc3cc(-c4ccc5c(c4)B4c6ccc(-n7c8ccccc8c8ccccc87)cc6Oc6cc(C(C)(C)C)cc(c64)N5c4c(-c5ccccc5)cc(C(C)(C)C)cc4-c4ccccc4)cc(c31)O2 ; CC(C)(C)c1cc(-c2ccccc2)c(N2c3ccc(-c4cc5c6c(c4)Oc4ccc(-c7ccccc7)cc4B6c4cc(-c6ccccc6)ccc4O5)cc3B3c4ccc(-n5c6ccccc6c6ccccc65)cc4Oc4cc(C(C)(C)C)cc2c43)c(-c2ccccc2)c1]

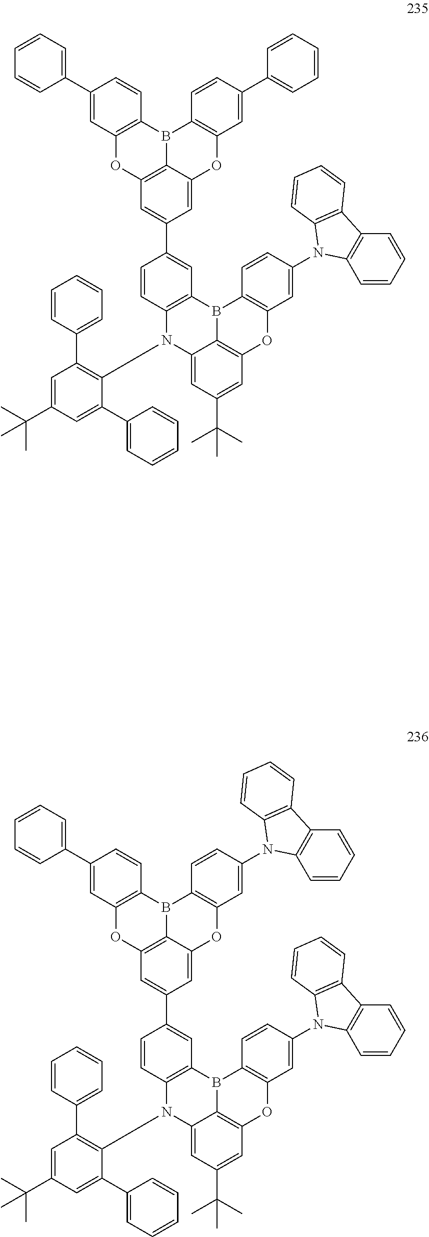 [SMILES: CC(C)(C)c1cc(-c2ccccc2)c(N2c3ccc(-c4cc5c6c(c4)Oc4cc(-c7ccccc7)ccc4B6c4ccc(-c6ccccc6)cc4O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-c6ccccc6)cc4O5)cc3B3c4ccc(-n5c6ccccc6c6ccccc65)cc4Oc4cc(C(C)(C)C)cc2c43)c(-c2ccccc2)c1]

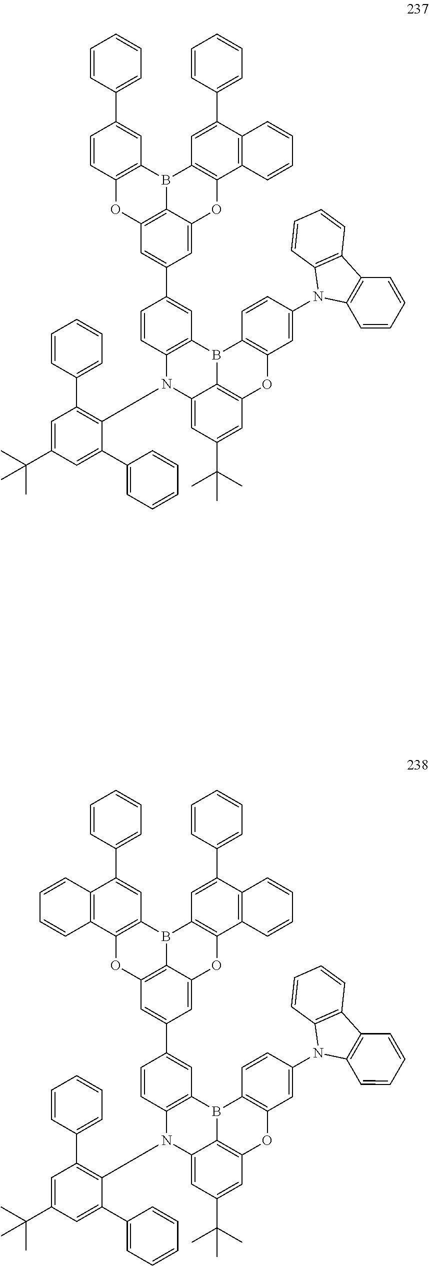 [SMILES: CC(C)(C)c1cc(-c2ccccc2)c(N2c3ccc(-c4cc5c6c(c4)Oc4c(cc(-c7ccccc7)c7ccccc47)B6c4cc(-c6ccccc6)ccc4O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4c(cc(-c7ccccc7)c7ccccc47)B6c4cc(-c6ccccc6)c6ccccc6c4O5)cc3B3c4ccc(-n5c6ccccc6c6ccccc65)cc4Oc4cc(C(C)(C)C)cc2c43)c(-c2ccccc2)c1]

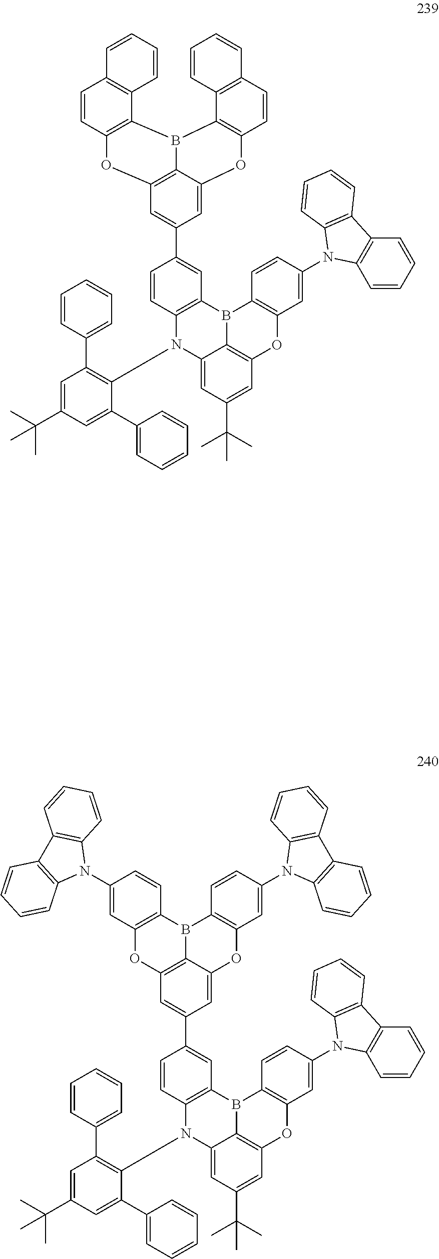 [SMILES: CC(C)(C)c1cc(-c2ccccc2)c(N2c3ccc(-c4cc5c6c(c4)Oc4ccc7ccccc7c4B6c4c(ccc6ccccc46)O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-n6c7ccccc7c7ccccc76)cc4O5)cc3B3c4ccc(-n5c6ccccc6c6ccccc65)cc4Oc4cc(C(C)(C)C)cc2c43)c(-c2ccccc2)c1]

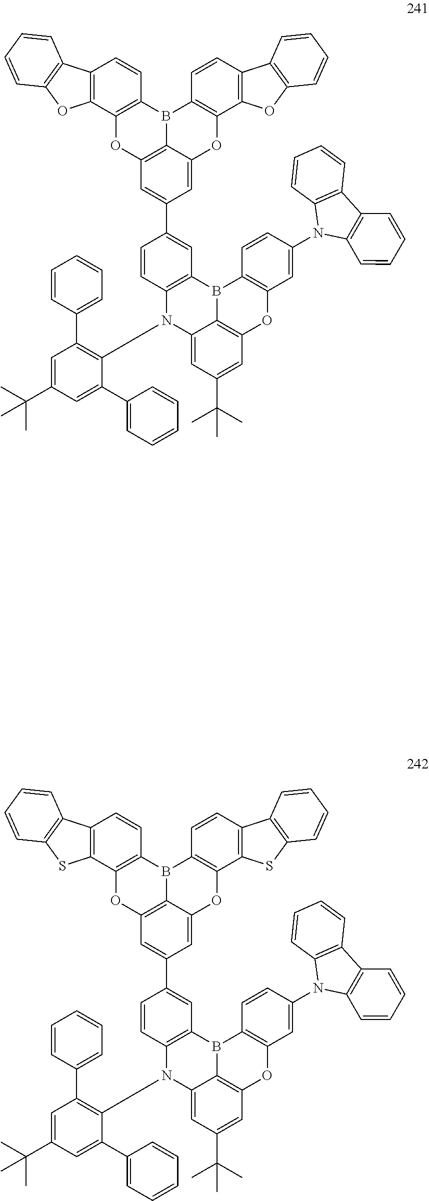 [SMILES: CC(C)(C)c1cc(-c2ccccc2)c(N2c3ccc(-c4cc5c6c(c4)Oc4c(ccc7c4oc4ccccc47)B6c4ccc6c(oc7ccccc76)c4O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4c(ccc7c4sc4ccccc47)B6c4ccc6c(sc7ccccc76)c4O5)cc3B3c4ccc(-n5c6ccccc6c6ccccc65)cc4Oc4cc(C(C)(C)C)cc2c43)c(-c2ccccc2)c1]

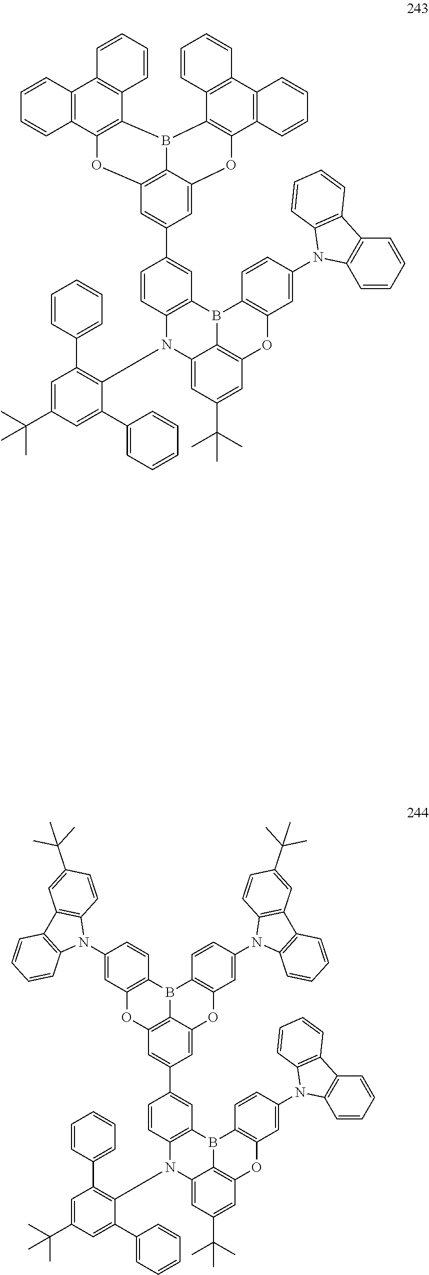 [SMILES: CC(C)(C)c1cc(-c2ccccc2)c(N2c3ccc(-c4cc5c6c(c4)Oc4c(c7ccccc7c7ccccc47)B6c4c(c6ccccc6c6ccccc46)O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8cc(C(C)(C)C)ccc87)ccc4B6c4ccc(-n6c7ccccc7c7cc(C(C)(C)C)ccc76)cc4O5)cc3B3c4ccc(-n5c6ccccc6c6ccccc65)cc4Oc4cc(C(C)(C)C)cc2c43)c(-c2ccccc2)c1]

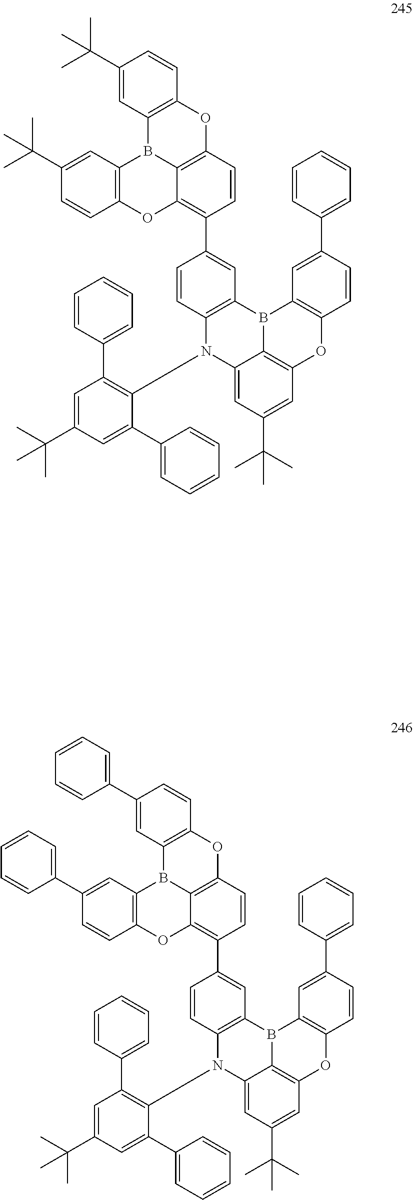 [SMILES: CC(C)(C)c1ccc2c(c1)B1c3cc(C(C)(C)C)ccc3Oc3c(-c4ccc5c(c4)B4c6cc(-c7ccccc7)ccc6Oc6cc(C(C)(C)C)cc(c64)N5c4c(-c5ccccc5)cc(C(C)(C)C)cc4-c4ccccc4)ccc(c31)O2 ; CC(C)(C)c1cc(-c2ccccc2)c(N2c3ccc(-c4ccc5c6c4Oc4ccc(-c7ccccc7)cc4B6c4cc(-c6ccccc6)ccc4O5)cc3B3c4cc(-c5ccccc5)ccc4Oc4cc(C(C)(C)C)cc2c43)c(-c2ccccc2)c1]

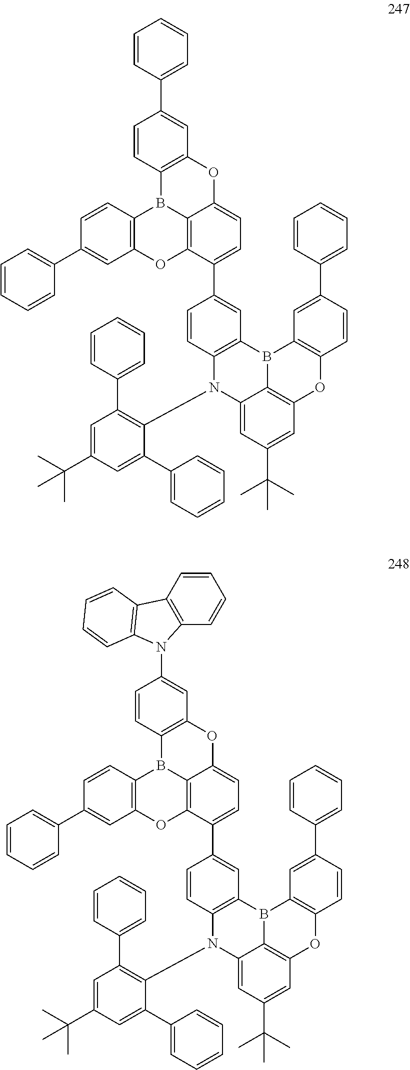 [SMILES: CC(C)(C)c1cc(-c2ccccc2)c(N2c3ccc(-c4ccc5c6c4Oc4cc(-c7ccccc7)ccc4B6c4ccc(-c6ccccc6)cc4O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4ccc5c6c4Oc4cc(-c7ccccc7)ccc4B6c4ccc(-n6c7ccccc7c7ccccc76)cc4O5)cc3B3c4cc(-c5ccccc5)ccc4Oc4cc(C(C)(C)C)cc2c43)c(-c2ccccc2)c1]

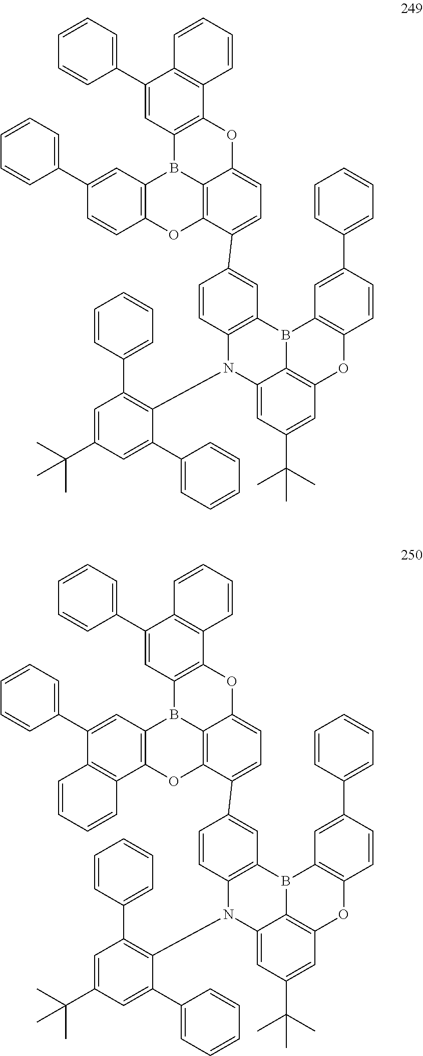 [SMILES: CC(C)(C)c1cc(-c2ccccc2)c(N2c3ccc(-c4ccc5c6c4Oc4ccc(-c7ccccc7)cc4B6c4cc(-c6ccccc6)c6ccccc6c4O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4ccc5c6c4Oc4c(cc(-c7ccccc7)c7ccccc47)B6c4cc(-c6ccccc6)c6ccccc6c4O5)cc3B3c4cc(-c5ccccc5)ccc4Oc4cc(C(C)(C)C)cc2c43)c(-c2ccccc2)c1]

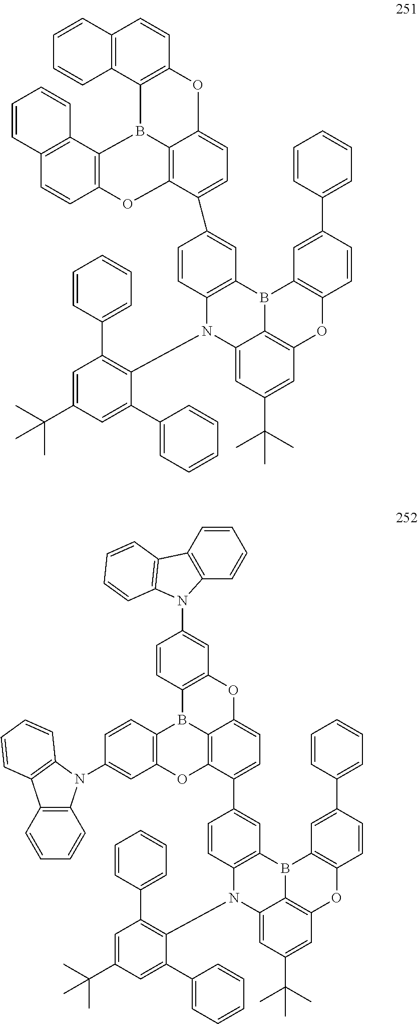 [SMILES: CC(C)(C)c1cc(-c2ccccc2)c(N2c3ccc(-c4ccc5c6c4Oc4ccc7ccccc7c4B6c4c(ccc6ccccc46)O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4ccc5c6c4Oc4cc(-n7c8ccccc8c8ccccc87)ccc4B6c4ccc(-n6c7ccccc7c7ccccc76)cc4O5)cc3B3c4cc(-c5ccccc5)ccc4Oc4cc(C(C)(C)C)cc2c43)c(-c2ccccc2)c1]

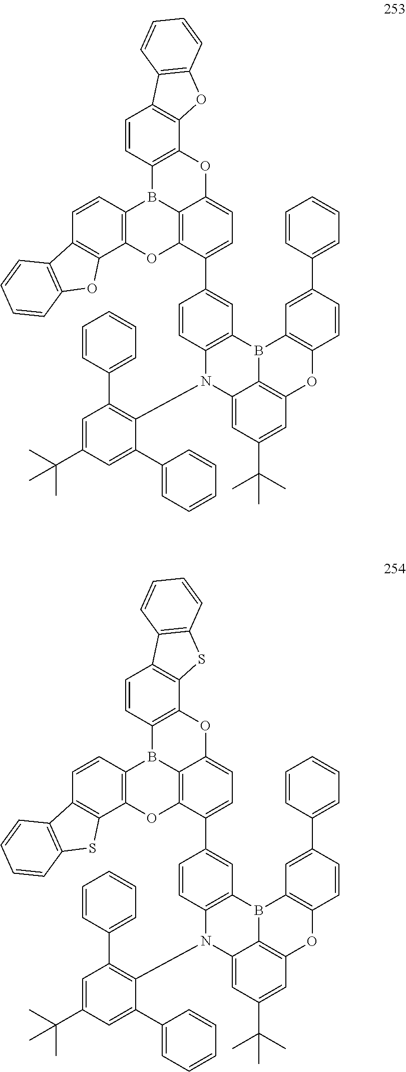 [SMILES: CC(C)(C)c1cc(-c2ccccc2)c(N2c3ccc(-c4ccc5c6c4Oc4c(ccc7c4oc4ccccc47)B6c4ccc6c(oc7ccccc76)c4O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4ccc5c6c4Oc4c(ccc7c4sc4ccccc47)B6c4ccc6c(sc7ccccc76)c4O5)cc3B3c4cc(-c5ccccc5)ccc4Oc4cc(C(C)(C)C)cc2c43)c(-c2ccccc2)c1]

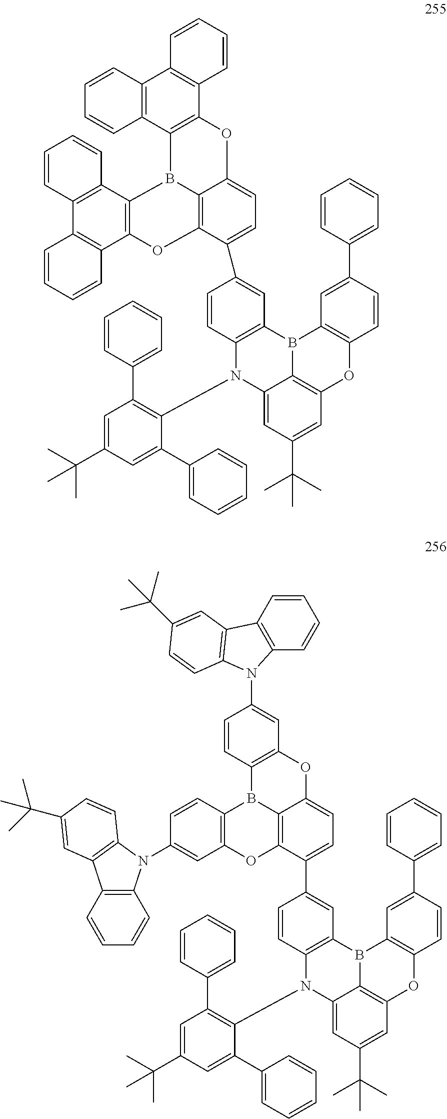 [SMILES: CC(C)(C)c1cc(-c2ccccc2)c(N2c3ccc(-c4ccc5c6c4Oc4c(c7ccccc7c7ccccc47)B6c4c(c6ccccc6c6ccccc46)O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4ccc5c6c4Oc4cc(-n7c8ccccc8c8cc(C(C)(C)C)ccc87)ccc4B6c4ccc(-n6c7ccccc7c7cc(C(C)(C)C)ccc76)cc4O5)cc3B3c4cc(-c5ccccc5)ccc4Oc4cc(C(C)(C)C)cc2c43)c(-c2ccccc2)c1]

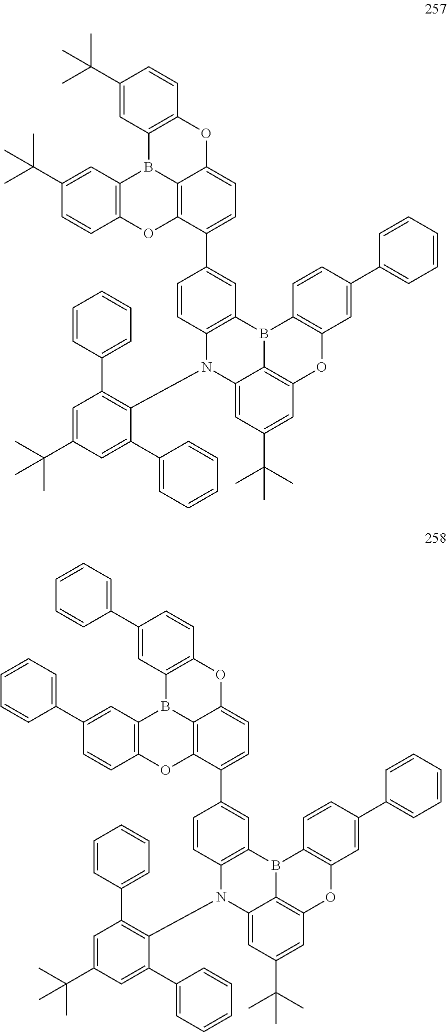 [SMILES: CC(C)(C)c1ccc2c(c1)B1c3cc(C(C)(C)C)ccc3Oc3c(-c4ccc5c(c4)B4c6ccc(-c7ccccc7)cc6Oc6cc(C(C)(C)C)cc(c64)N5c4c(-c5ccccc5)cc(C(C)(C)C)cc4-c4ccccc4)ccc(c31)O2 ; CC(C)(C)c1cc(-c2ccccc2)c(N2c3ccc(-c4ccc5c6c4Oc4ccc(-c7ccccc7)cc4B6c4cc(-c6ccccc6)ccc4O5)cc3B3c4ccc(-c5ccccc5)cc4Oc4cc(C(C)(C)C)cc2c43)c(-c2ccccc2)c1]

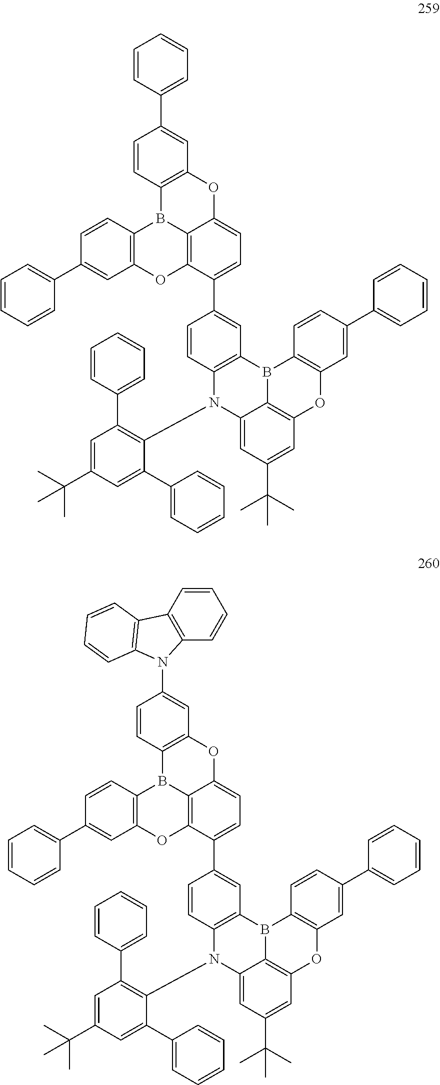 [SMILES: CC(C)(C)c1cc(-c2ccccc2)c(N2c3ccc(-c4ccc5c6c4Oc4cc(-c7ccccc7)ccc4B6c4ccc(-c6ccccc6)cc4O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4ccc5c6c4Oc4cc(-c7ccccc7)ccc4B6c4ccc(-n6c7ccccc7c7ccccc76)cc4O5)cc3B3c4ccc(-c5ccccc5)cc4Oc4cc(C(C)(C)C)cc2c43)c(-c2ccccc2)c1]

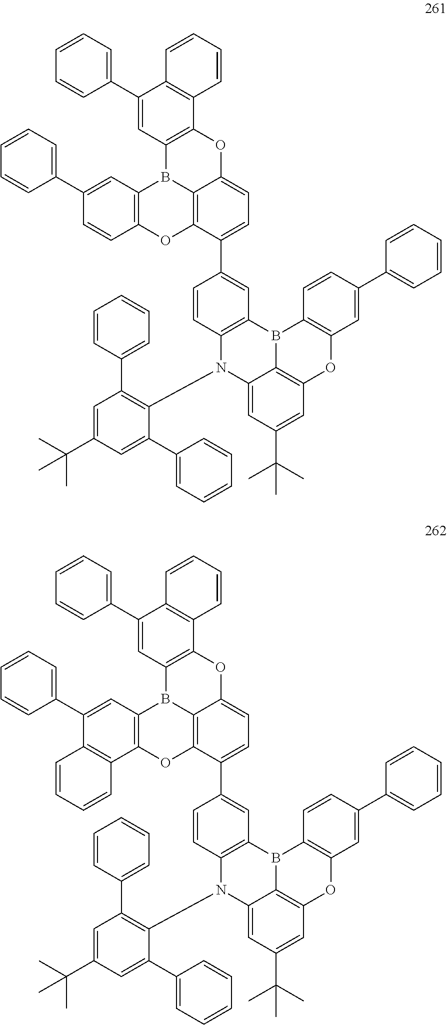 [SMILES: CC(C)(C)c1cc(-c2ccccc2)c(N2c3ccc(-c4ccc5c6c4Oc4ccc(-c7ccccc7)cc4B6c4cc(-c6ccccc6)c6ccccc6c4O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4ccc5c6c4Oc4c(cc(-c7ccccc7)c7ccccc47)B6c4cc(-c6ccccc6)c6ccccc6c4O5)cc3B3c4ccc(-c5ccccc5)cc4Oc4cc(C(C)(C)C)cc2c43)c(-c2ccccc2)c1]

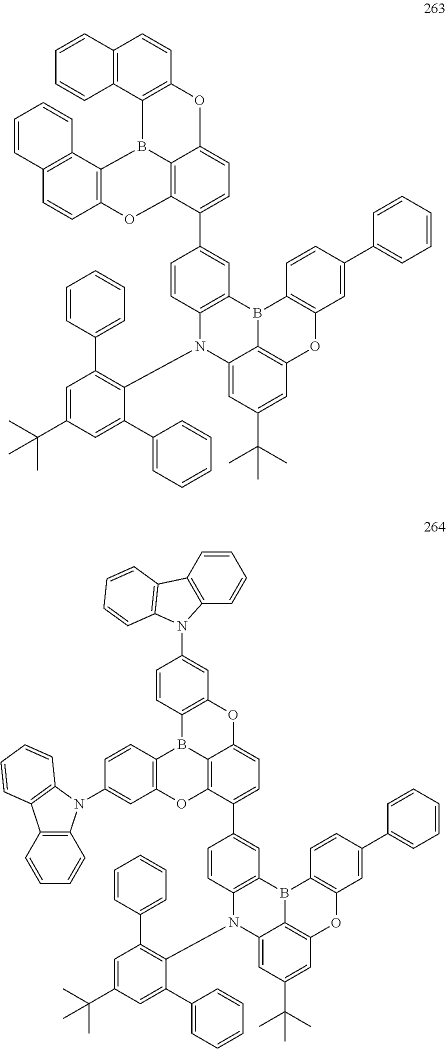 [SMILES: CC(C)(C)c1cc(-c2ccccc2)c(N2c3ccc(-c4ccc5c6c4Oc4ccc7ccccc7c4B6c4c(ccc6ccccc46)O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4ccc5c6c4Oc4cc(-n7c8ccccc8c8ccccc87)ccc4B6c4ccc(-n6c7ccccc7c7ccccc76)cc4O5)cc3B3c4ccc(-c5ccccc5)cc4Oc4cc(C(C)(C)C)cc2c43)c(-c2ccccc2)c1]

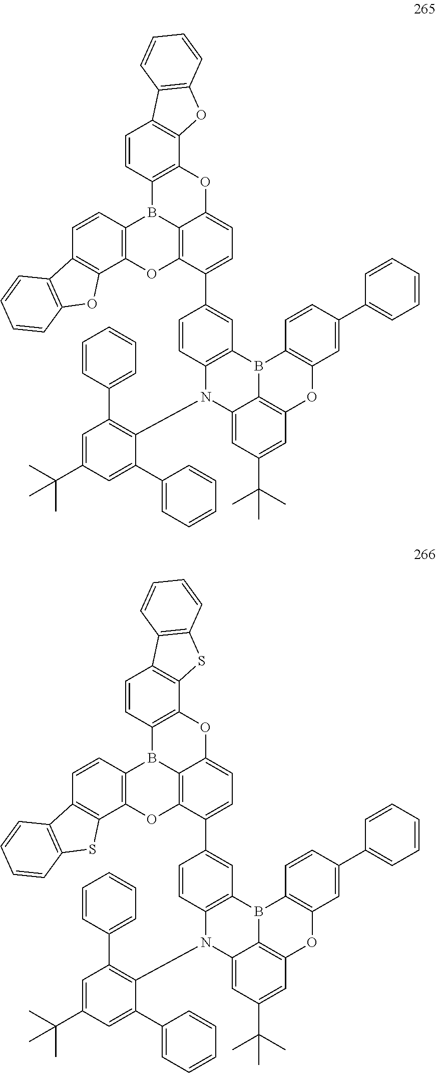 [SMILES: CC(C)(C)c1cc(-c2ccccc2)c(N2c3ccc(-c4ccc5c6c4Oc4c(ccc7c4oc4ccccc47)B6c4ccc6c(oc7ccccc76)c4O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4ccc5c6c4Oc4c(ccc7c4sc4ccccc47)B6c4ccc6c(sc7ccccc76)c4O5)cc3B3c4ccc(-c5ccccc5)cc4Oc4cc(C(C)(C)C)cc2c43)c(-c2ccccc2)c1]

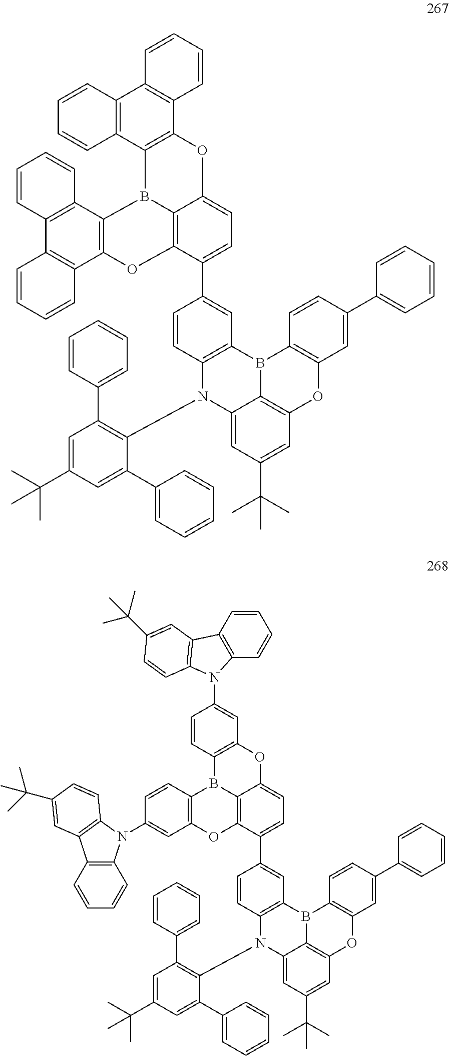 [SMILES: CC(C)(C)c1cc(-c2ccccc2)c(N2c3ccc(-c4ccc5c6c4Oc4c(c7ccccc7c7ccccc47)B6c4c(c6ccccc6c6ccccc46)O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4ccc5c6c4Oc4cc(-n7c8ccccc8c8cc(C(C)(C)C)ccc87)ccc4B6c4ccc(-n6c7ccccc7c7cc(C(C)(C)C)ccc76)cc4O5)cc3B3c4ccc(-c5ccccc5)cc4Oc4cc(C(C)(C)C)cc2c43)c(-c2ccccc2)c1]

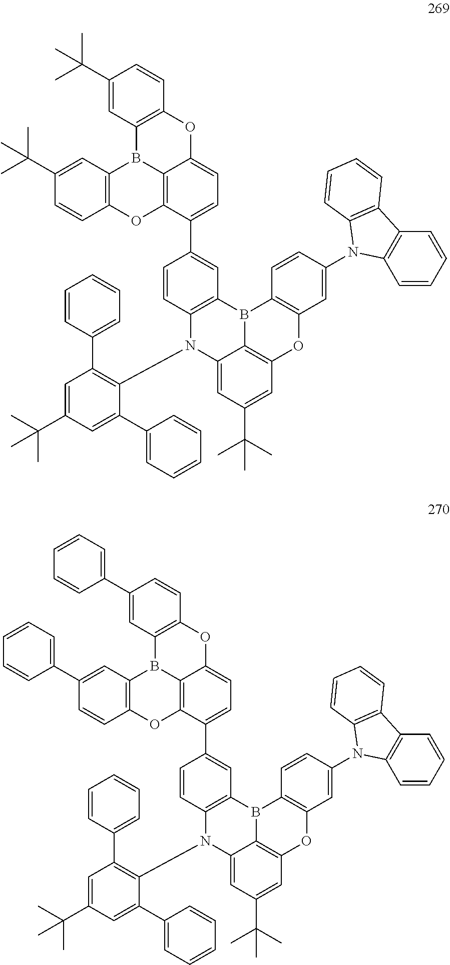 [SMILES: CC(C)(C)c1ccc2c(c1)B1c3cc(C(C)(C)C)ccc3Oc3c(-c4ccc5c(c4)B4c6ccc(-n7c8ccccc8c8ccccc87)cc6Oc6cc(C(C)(C)C)cc(c64)N5c4c(-c5ccccc5)cc(C(C)(C)C)cc4-c4ccccc4)ccc(c31)O2 ; CC(C)(C)c1cc(-c2ccccc2)c(N2c3ccc(-c4ccc5c6c4Oc4ccc(-c7ccccc7)cc4B6c4cc(-c6ccccc6)ccc4O5)cc3B3c4ccc(-n5c6ccccc6c6ccccc65)cc4Oc4cc(C(C)(C)C)cc2c43)c(-c2ccccc2)c1]

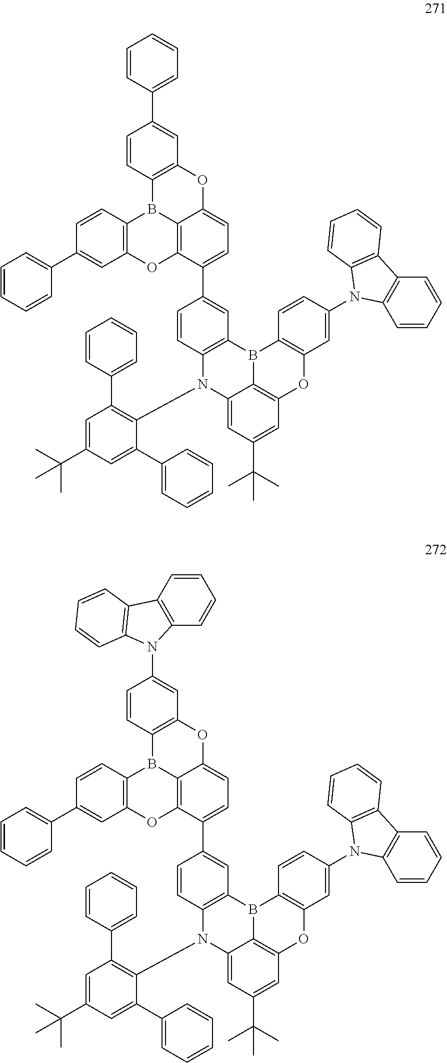 [SMILES: CC(C)(C)c1cc(-c2ccccc2)c(N2c3ccc(-c4ccc5c6c4Oc4cc(-c7ccccc7)ccc4B6c4ccc(-c6ccccc6)cc4O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4ccc5c6c4Oc4cc(-c7ccccc7)ccc4B6c4ccc(-n6c7ccccc7c7ccccc76)cc4O5)cc3B3c4ccc(-n5c6ccccc6c6ccccc65)cc4Oc4cc(C(C)(C)C)cc2c43)c(-c2ccccc2)c1]

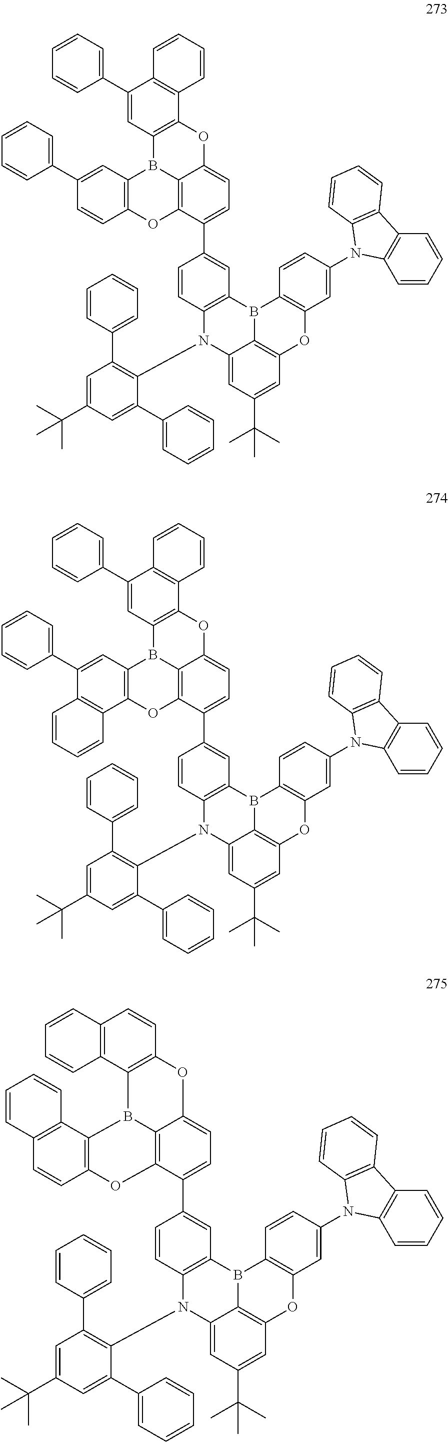 [SMILES: CC(C)(C)c1cc(-c2ccccc2)c(N2c3ccc(-c4ccc5c6c4Oc4ccc(-c7ccccc7)cc4B6c4cc(-c6ccccc6)c6ccccc6c4O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4ccc5c6c4Oc4c(cc(-c7ccccc7)c7ccccc47)B6c4cc(-c6ccccc6)c6ccccc6c4O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4ccc5c6c4Oc4ccc7ccccc7c4B6c4c(ccc6ccccc46)O5)cc3B3c4ccc(-n5c6ccccc6c6ccccc65)cc4Oc4cc(C(C)(C)C)cc2c43)c(-c2ccccc2)c1]

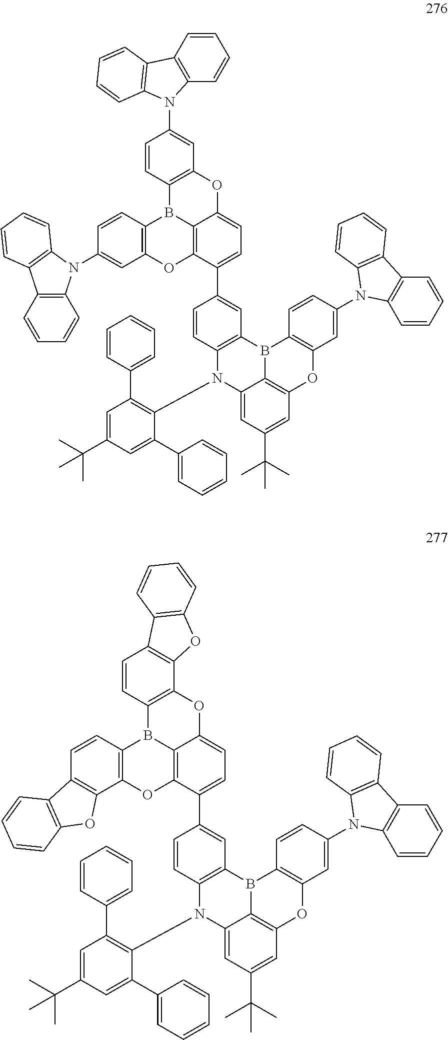 [SMILES: CC(C)(C)c1cc(-c2ccccc2)c(N2c3ccc(-c4ccc5c6c4Oc4cc(-n7c8ccccc8c8ccccc87)ccc4B6c4ccc(-n6c7ccccc7c7ccccc76)cc4O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4ccc5c6c4Oc4c(ccc7c4oc4ccccc47)B6c4ccc6c(oc7ccccc76)c4O5)cc3B3c4ccc(-n5c6ccccc6c6ccccc65)cc4Oc4cc(C(C)(C)C)cc2c43)c(-c2ccccc2)c1]

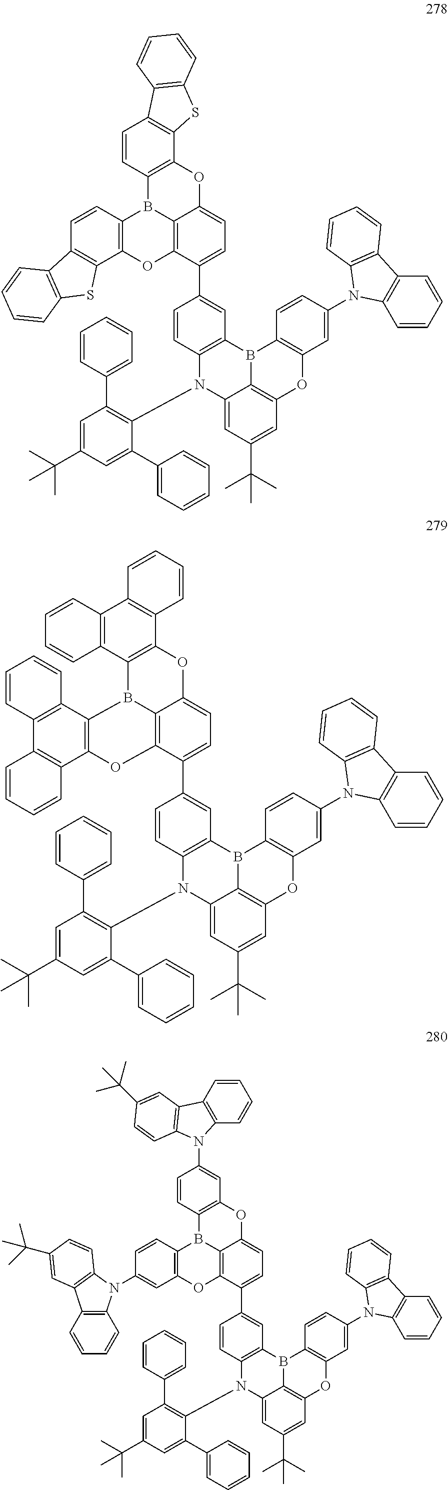

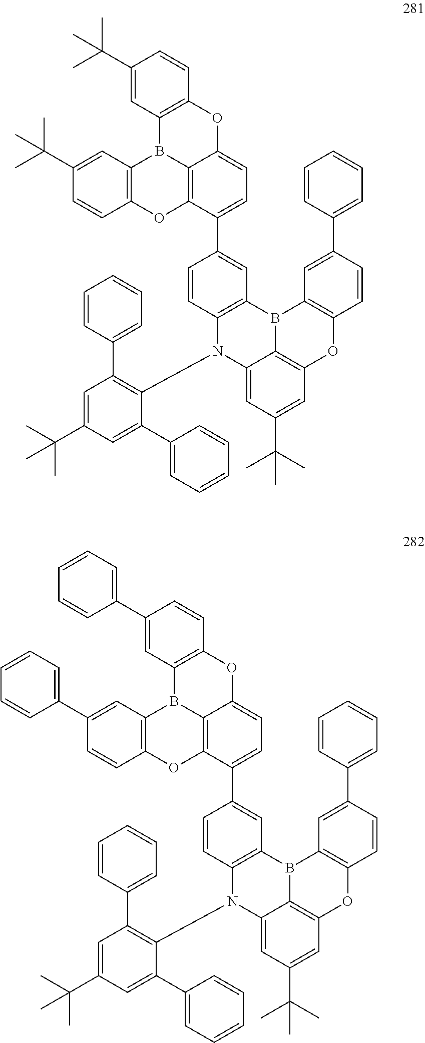 [SMILES: CC(C)(C)c1ccc2c(c1)B1c3cc(C(C)(C)C)ccc3Oc3c(-c4ccc5c(c4)B4c6cc(-c7ccccc7)ccc6Oc6cc(C(C)(C)C)cc(c64)N5c4c(-c5ccccc5)cc(C(C)(C)C)cc4-c4ccccc4)ccc(c31)O2 ; CC(C)(C)c1cc(-c2ccccc2)c(N2c3ccc(-c4ccc5c6c4Oc4ccc(-c7ccccc7)cc4B6c4cc(-c6ccccc6)ccc4O5)cc3B3c4cc(-c5ccccc5)ccc4Oc4cc(C(C)(C)C)cc2c43)c(-c2ccccc2)c1]

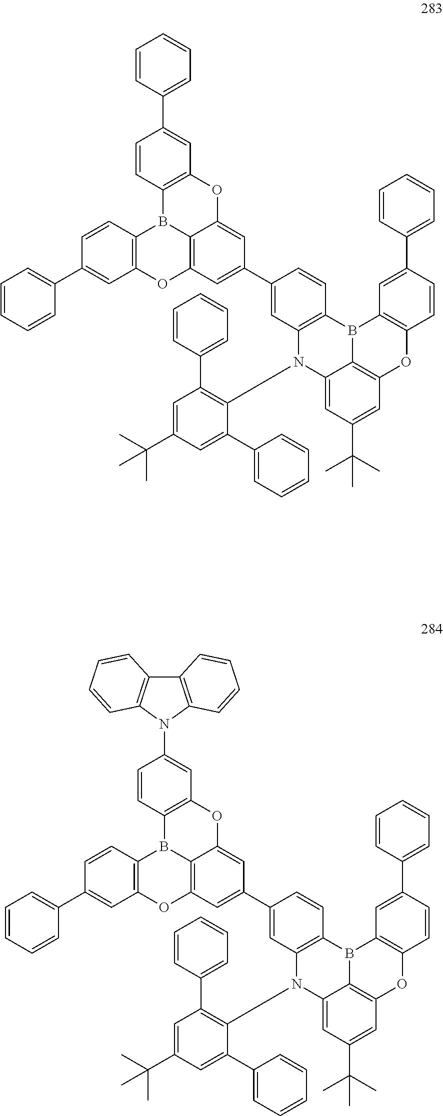 [SMILES: CC(C)(C)c1cc(-c2ccccc2)c(N2c3cc(-c4cc5c6c(c4)Oc4cc(-c7ccccc7)ccc4B6c4ccc(-c6ccccc6)cc4O5)ccc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8ccccc87)ccc4B6c4ccc(-c6ccccc6)cc4O5)ccc3B3c4cc(-c5ccccc5)ccc4Oc4cc(C(C)(C)C)cc2c43)c(-c2ccccc2)c1]

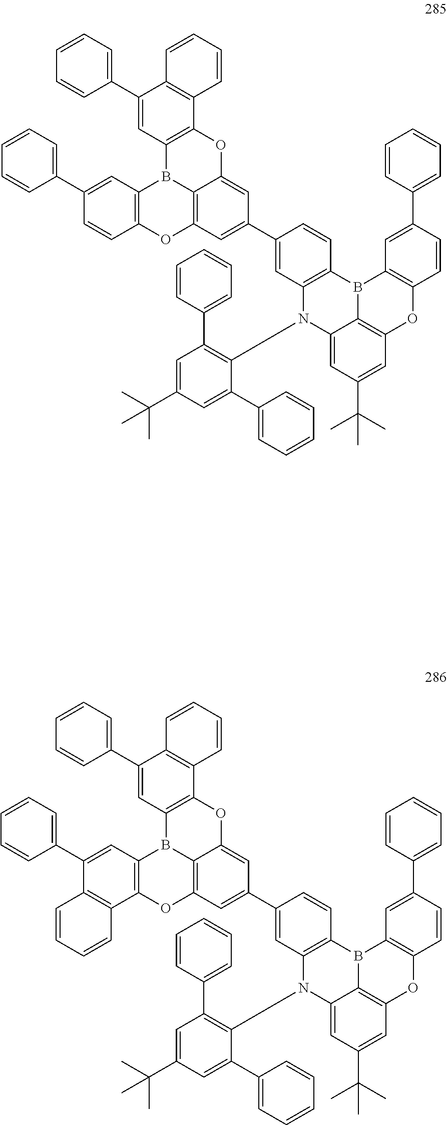 [SMILES: CC(C)(C)c1cc(-c2ccccc2)c(N2c3cc(-c4cc5c6c(c4)Oc4c(cc(-c7ccccc7)c7ccccc47)B6c4cc(-c6ccccc6)ccc4O5)ccc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc(-c4cc5c6c(c4)Oc4c(cc(-c7ccccc7)c7ccccc47)B6c4cc(-c6ccccc6)c6ccccc6c4O5)ccc3B3c4cc(-c5ccccc5)ccc4Oc4cc(C(C)(C)C)cc2c43)c(-c2ccccc2)c1]

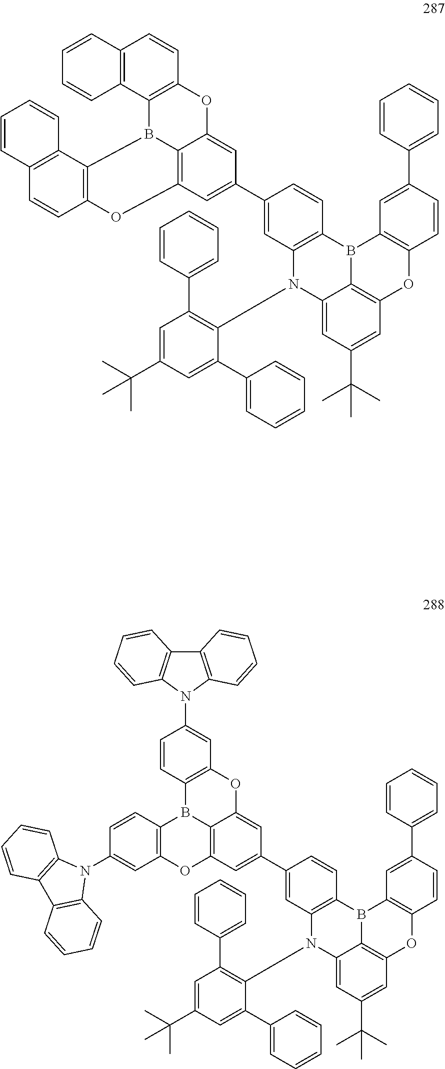 [SMILES: CC(C)(C)c1cc(-c2ccccc2)c(N2c3cc(-c4cc5c6c(c4)Oc4ccc7ccccc7c4B6c4c(ccc6ccccc46)O5)ccc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8ccccc87)ccc4B6c4ccc(-n6c7ccccc7c7ccccc76)cc4O5)ccc3B3c4cc(-c5ccccc5)ccc4Oc4cc(C(C)(C)C)cc2c43)c(-c2ccccc2)c1]

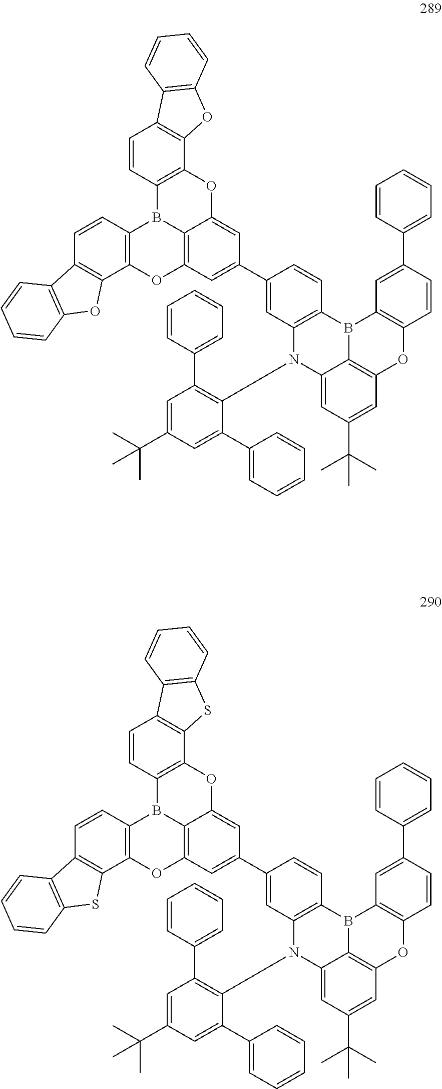 [SMILES: CC(C)(C)c1cc(-c2ccccc2)c(N2c3cc(-c4cc5c6c(c4)Oc4c(ccc7c4oc4ccccc47)B6c4ccc6c(oc7ccccc76)c4O5)ccc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc(-c4cc5c6c(c4)Oc4c(ccc7c4sc4ccccc47)B6c4ccc6c(sc7ccccc76)c4O5)ccc3B3c4cc(-c5ccccc5)ccc4Oc4cc(C(C)(C)C)cc2c43)c(-c2ccccc2)c1]

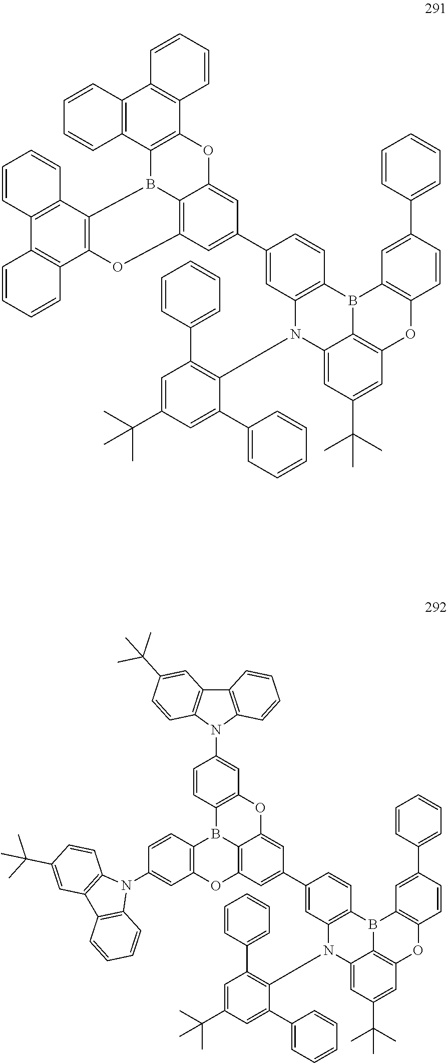 [SMILES: CC(C)(C)c1cc(-c2ccccc2)c(N2c3cc(-c4cc5c6c(c4)Oc4c(c7ccccc7c7ccccc47)B6c4c(c6ccccc6c6ccccc46)O5)ccc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8cc(C(C)(C)C)ccc87)ccc4B6c4ccc(-n6c7ccccc7c7cc(C(C)(C)C)ccc76)cc4O5)ccc3B3c4cc(-c5ccccc5)ccc4Oc4cc(C(C)(C)C)cc2c43)c(-c2ccccc2)c1]

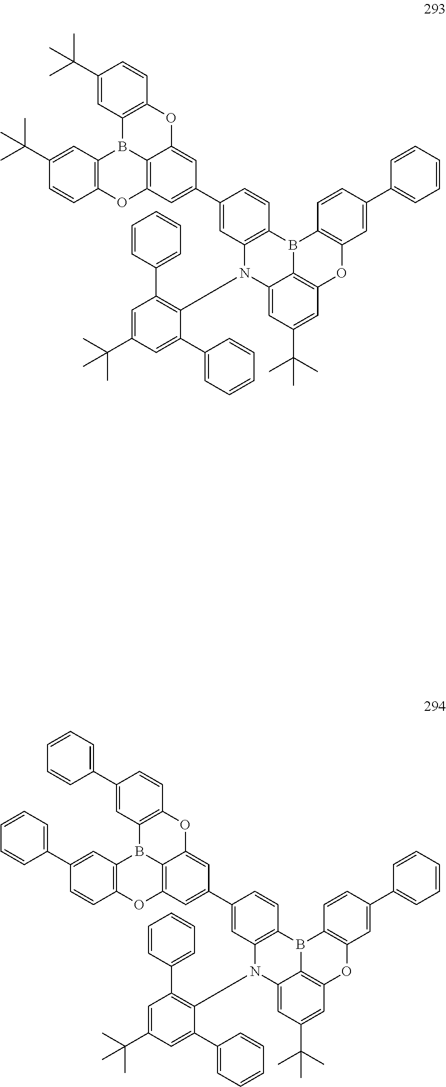 [SMILES: CC(C)(C)c1ccc2c(c1)B1c3cc(C(C)(C)C)ccc3Oc3cc(-c4ccc5c(c4)N(c4c(-c6ccccc6)cc(C(C)(C)C)cc4-c4ccccc4)c4cc(C(C)(C)C)cc6c4B5c4ccc(-c5ccccc5)cc4O6)cc(c31)O2 ; CC(C)(C)c1cc(-c2ccccc2)c(N2c3cc(-c4cc5c6c(c4)Oc4ccc(-c7ccccc7)cc4B6c4cc(-c6ccccc6)ccc4O5)ccc3B3c4ccc(-c5ccccc5)cc4Oc4cc(C(C)(C)C)cc2c43)c(-c2ccccc2)c1]

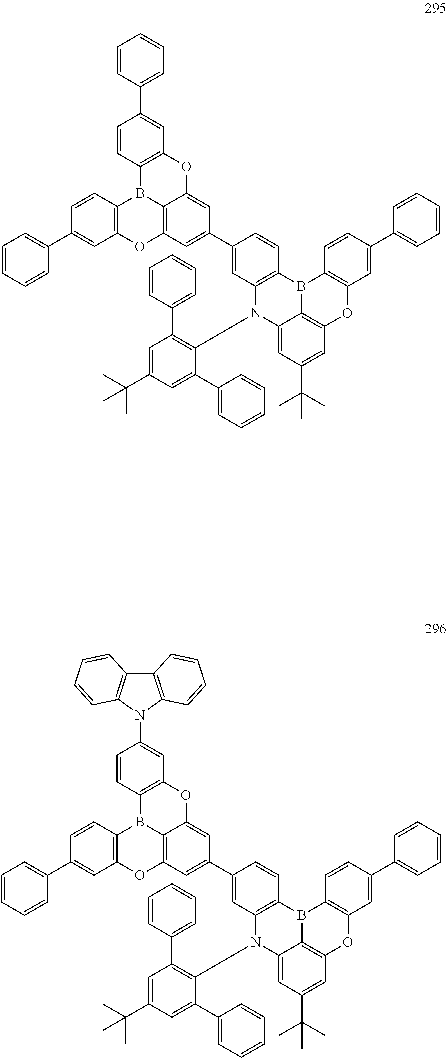 [SMILES: CC(C)(C)c1cc(-c2ccccc2)c(N2c3cc(-c4cc5c6c(c4)Oc4cc(-c7ccccc7)ccc4B6c4ccc(-c6ccccc6)cc4O5)ccc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8ccccc87)ccc4B6c4ccc(-c6ccccc6)cc4O5)ccc3B3c4ccc(-c5ccccc5)cc4Oc4cc(C(C)(C)C)cc2c43)c(-c2ccccc2)c1]

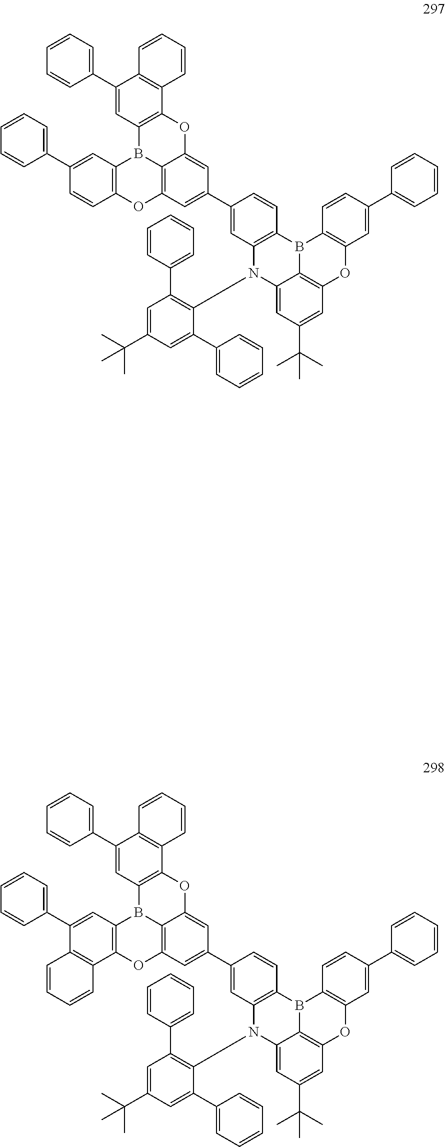 [SMILES: CC(C)(C)c1cc(-c2ccccc2)c(N2c3cc(-c4cc5c6c(c4)Oc4c(cc(-c7ccccc7)c7ccccc47)B6c4cc(-c6ccccc6)ccc4O5)ccc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4c(cc(-c7ccccc7)c7ccccc47)B6c4cc(-c6ccccc6)c6ccccc6c4O5)ccc3B3c4ccc(-c5ccccc5)cc4Oc4cc(C(C)(C)C)cc2c43)c(-c2ccccc2)c1]

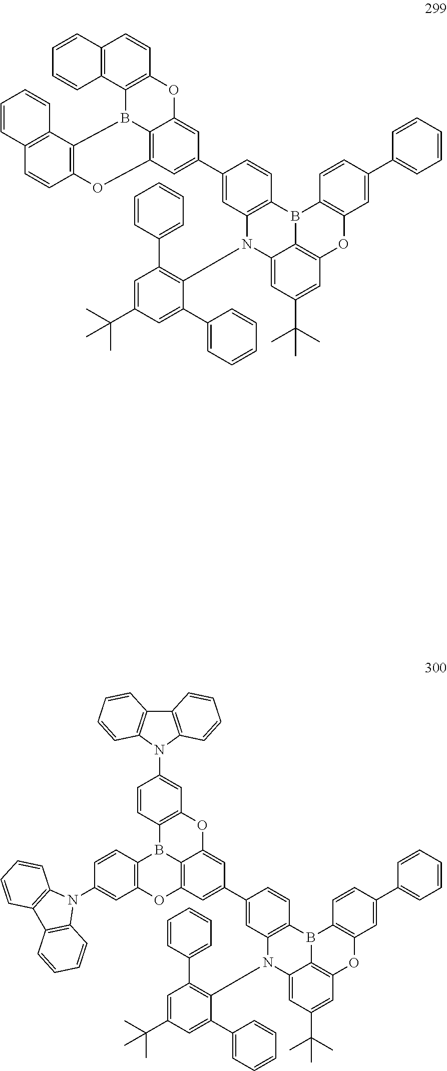 [SMILES: CC(C)(C)c1cc(-c2ccccc2)c(N2c3cc(-c4cc5c6c(c4)Oc4ccc7ccccc7c4B6c4c(ccc6ccccc46)O5)ccc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8ccccc87)ccc4B6c4ccc(-n6c7ccccc7c7ccccc76)cc4O5)ccc3B3c4ccc(-c5ccccc5)cc4Oc4cc(C(C)(C)C)cc2c43)c(-c2ccccc2)c1]

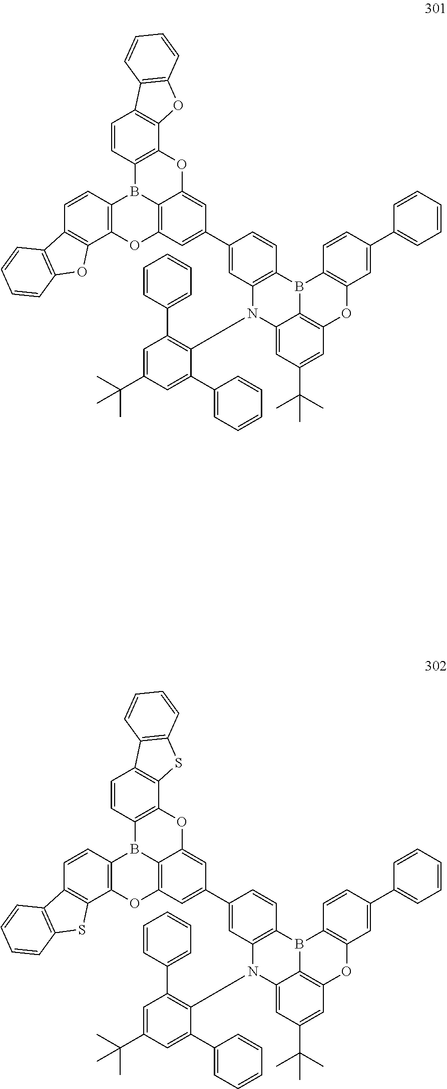 [SMILES: CC(C)(C)c1cc(-c2ccccc2)c(N2c3cc(-c4cc5c6c(c4)Oc4c(ccc7c4oc4ccccc47)B6c4ccc6c(oc7ccccc76)c4O5)ccc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4c(ccc7c4sc4ccccc47)B6c4ccc6c(sc7ccccc76)c4O5)ccc3B3c4ccc(-c5ccccc5)cc4Oc4cc(C(C)(C)C)cc2c43)c(-c2ccccc2)c1]

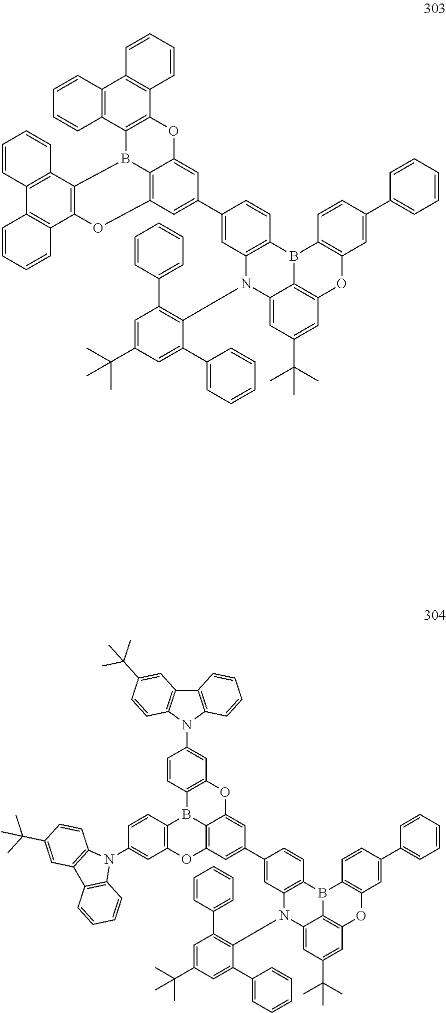 [SMILES: CC(C)(C)c1cc(-c2ccccc2)c(N2c3cc(-c4cc5c6c(c4)Oc4c(c7ccccc7c7ccccc47)B6c4c(c6ccccc6c6ccccc46)O5)ccc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8cc(C(C)(C)C)ccc87)ccc4B6c4ccc(-n6c7ccccc7c7cc(C(C)(C)C)ccc76)cc4O5)ccc3B3c4ccc(-c5ccccc5)cc4Oc4cc(C(C)(C)C)cc2c43)c(-c2ccccc2)c1]

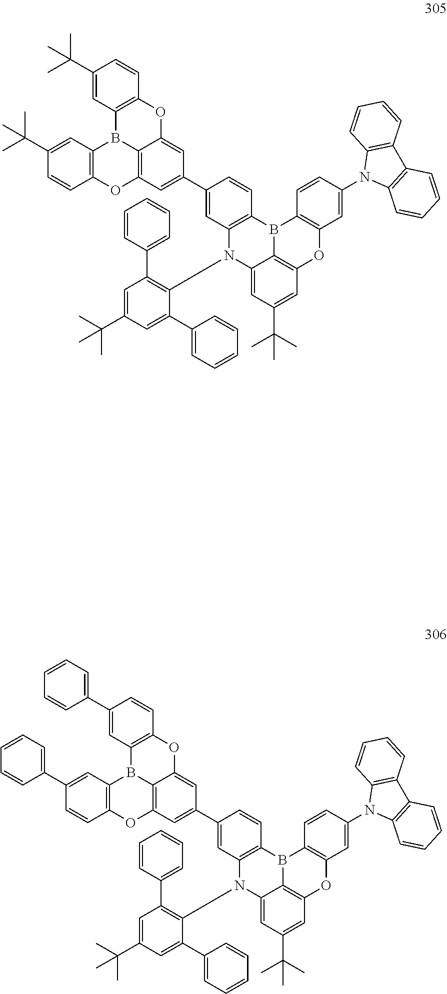 [SMILES: CC(C)(C)c1ccc2c(c1)B1c3cc(C(C)(C)C)ccc3Oc3cc(-c4ccc5c(c4)N(c4c(-c6ccccc6)cc(C(C)(C)C)cc4-c4ccccc4)c4cc(C(C)(C)C)cc6c4B5c4ccc(-n5c7ccccc7c7ccccc75)cc4O6)cc(c31)O2 ; CC(C)(C)c1cc(-c2ccccc2)c(N2c3cc(-c4cc5c6c(c4)Oc4ccc(-c7ccccc7)cc4B6c4cc(-c6ccccc6)ccc4O5)ccc3B3c4ccc(-n5c6ccccc6c6ccccc65)cc4Oc4cc(C(C)(C)C)cc2c43)c(-c2ccccc2)c1]

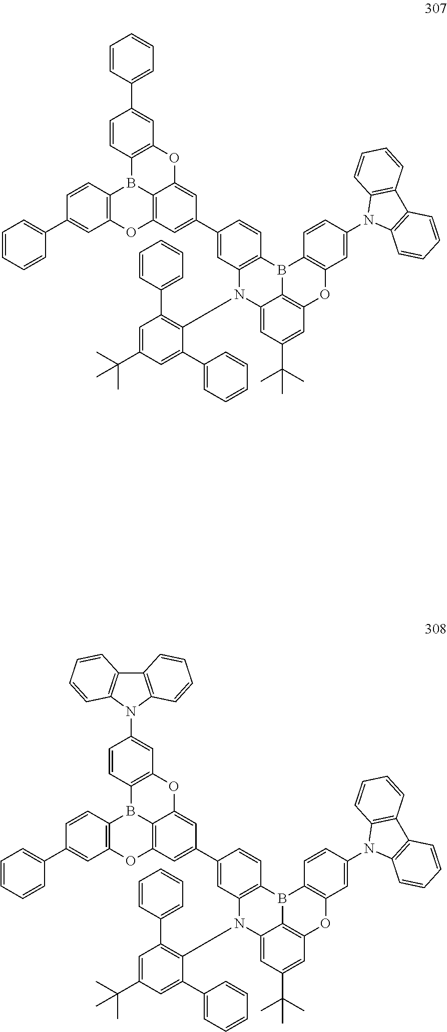 [SMILES: CC(C)(C)c1cc(-c2ccccc2)c(N2c3cc(-c4cc5c6c(c4)Oc4cc(-c7ccccc7)ccc4B6c4ccc(-c6ccccc6)cc4O5)ccc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8ccccc87)ccc4B6c4ccc(-c6ccccc6)cc4O5)ccc3B3c4ccc(-n5c6ccccc6c6ccccc65)cc4Oc4cc(C(C)(C)C)cc2c43)c(-c2ccccc2)c1]

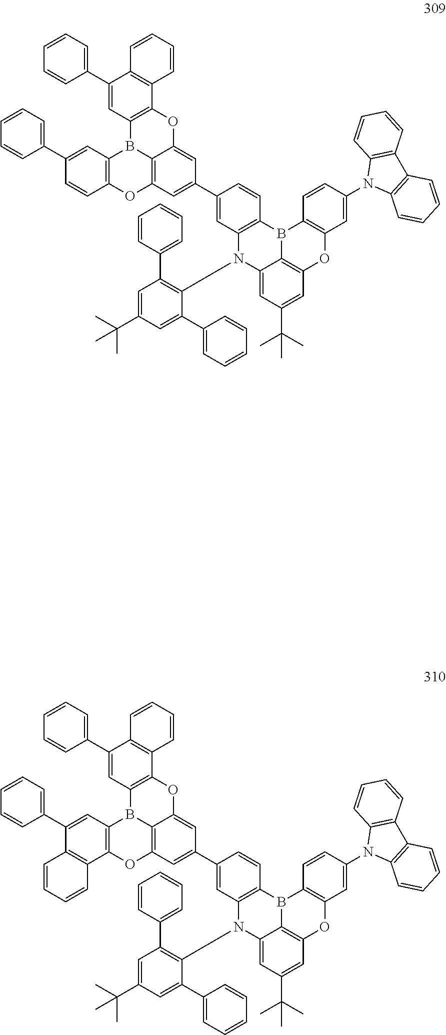 [SMILES: CC(C)(C)c1cc(-c2ccccc2)c(N2c3cc(-c4cc5c6c(c4)Oc4c(cc(-c7ccccc7)c7ccccc47)B6c4cc(-c6ccccc6)ccc4O5)ccc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4c(cc(-c7ccccc7)c7ccccc47)B6c4cc(-c6ccccc6)c6ccccc6c4O5)ccc3B3c4ccc(-n5c6ccccc6c6ccccc65)cc4Oc4cc(C(C)(C)C)cc2c43)c(-c2ccccc2)c1]

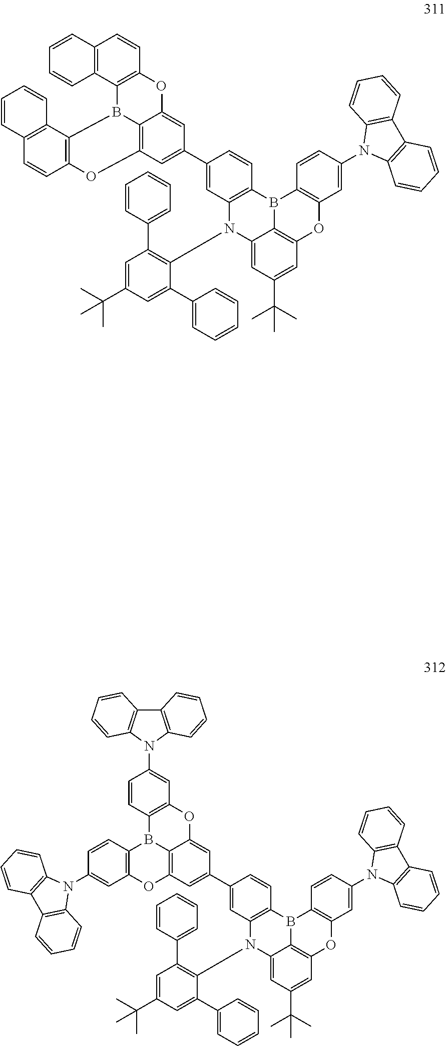 [SMILES: CC(C)(C)c1cc(-c2ccccc2)c(N2c3cc(-c4cc5c6c(c4)Oc4ccc7ccccc7c4B6c4c(ccc6ccccc46)O5)ccc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8ccccc87)ccc4B6c4ccc(-n6c7ccccc7c7ccccc76)cc4O5)ccc3B3c4ccc(-n5c6ccccc6c6ccccc65)cc4Oc4cc(C(C)(C)C)cc2c43)c(-c2ccccc2)c1]

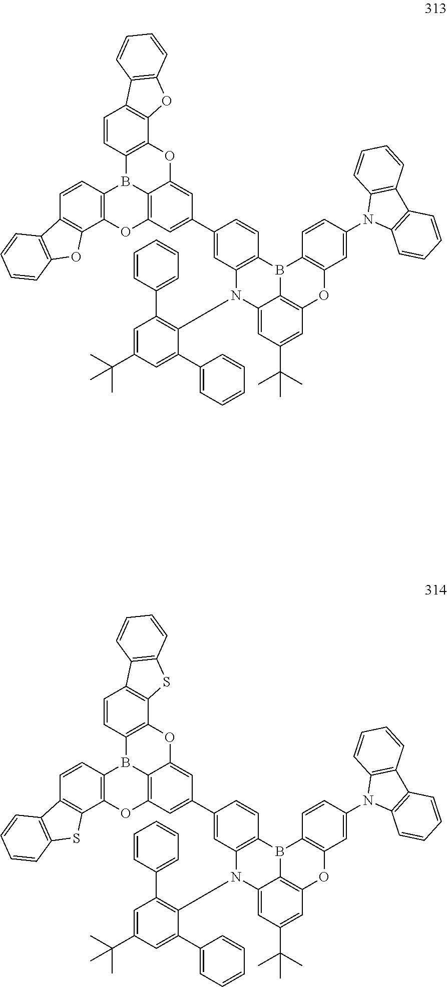 [SMILES: CC(C)(C)c1cc(-c2ccccc2)c(N2c3cc(-c4cc5c6c(c4)Oc4c(ccc7c4oc4ccccc47)B6c4ccc6c(oc7ccccc76)c4O5)ccc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4c(ccc7c4sc4ccccc47)B6c4ccc6c(sc7ccccc76)c4O5)ccc3B3c4ccc(-n5c6ccccc6c6ccccc65)cc4Oc4cc(C(C)(C)C)cc2c43)c(-c2ccccc2)c1]

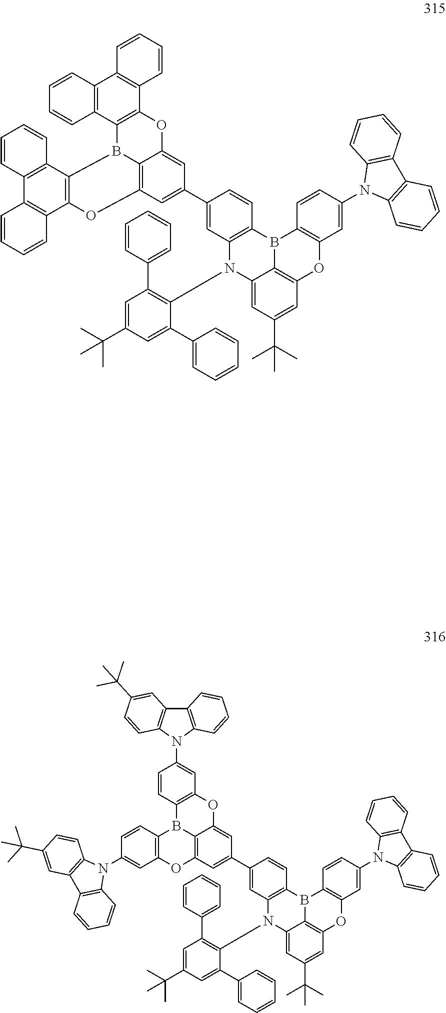 [SMILES: CC(C)(C)c1cc(-c2ccccc2)c(N2c3cc(-c4cc5c6c(c4)Oc4c(c7ccccc7c7ccccc47)B6c4c(c6ccccc6c6ccccc46)O5)ccc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8cc(C(C)(C)C)ccc87)ccc4B6c4ccc(-n6c7ccccc7c7cc(C(C)(C)C)ccc76)cc4O5)ccc3B3c4ccc(-n5c6ccccc6c6ccccc65)cc4Oc4cc(C(C)(C)C)cc2c43)c(-c2ccccc2)c1]

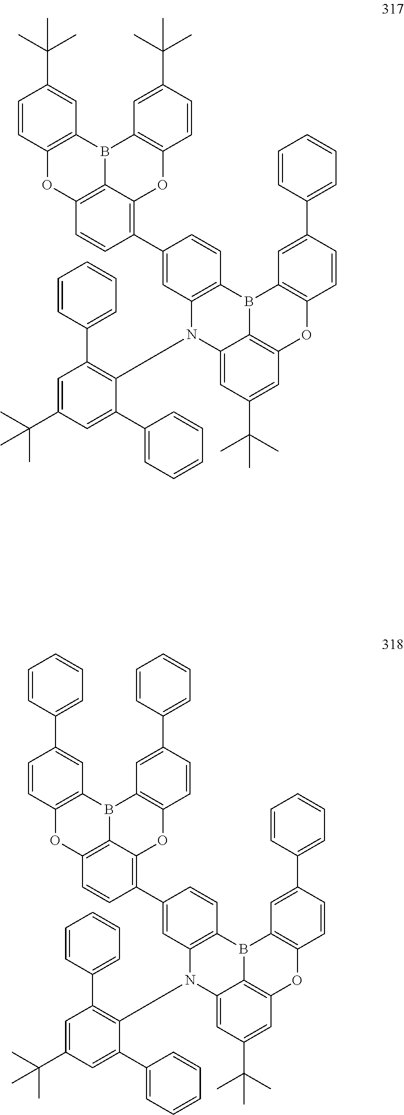 [SMILES: CC(C)(C)c1ccc2c(c1)B1c3cc(C(C)(C)C)ccc3Oc3c(-c4ccc5c(c4)N(c4c(-c6ccccc6)cc(C(C)(C)C)cc4-c4ccccc4)c4cc(C(C)(C)C)cc6c4B5c4cc(-c5ccccc5)ccc4O6)ccc(c31)O2 ; CC(C)(C)c1cc(-c2ccccc2)c(N2c3cc(-c4ccc5c6c4Oc4ccc(-c7ccccc7)cc4B6c4cc(-c6ccccc6)ccc4O5)ccc3B3c4cc(-c5ccccc5)ccc4Oc4cc(C(C)(C)C)cc2c43)c(-c2ccccc2)c1]

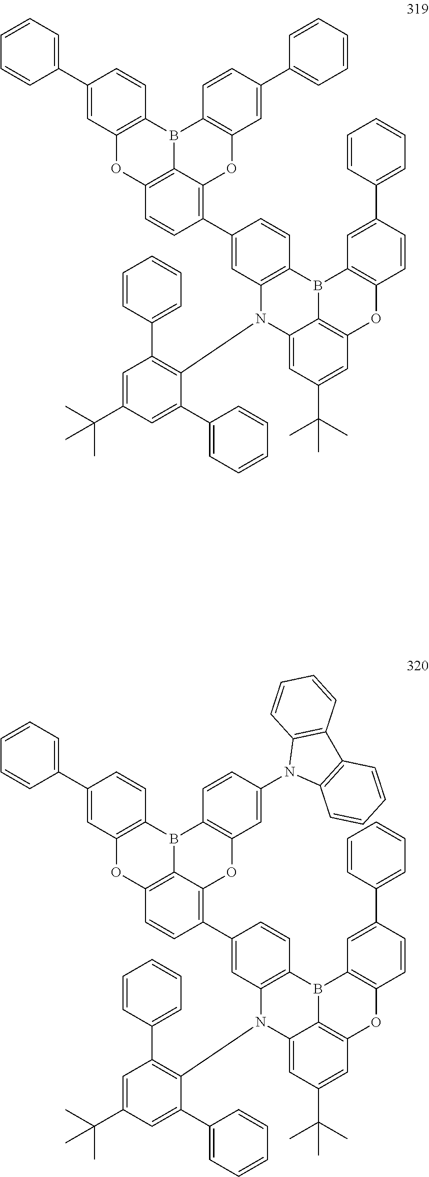 [SMILES: CC(C)(C)c1cc(-c2ccccc2)c(N2c3cc(-c4ccc5c6c4Oc4cc(-c7ccccc7)ccc4B6c4ccc(-c6ccccc6)cc4O5)ccc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc(-c4ccc5c6c4Oc4cc(-n7c8ccccc8c8ccccc87)ccc4B6c4ccc(-c6ccccc6)cc4O5)ccc3B3c4cc(-c5ccccc5)ccc4Oc4cc(C(C)(C)C)cc2c43)c(-c2ccccc2)c1]

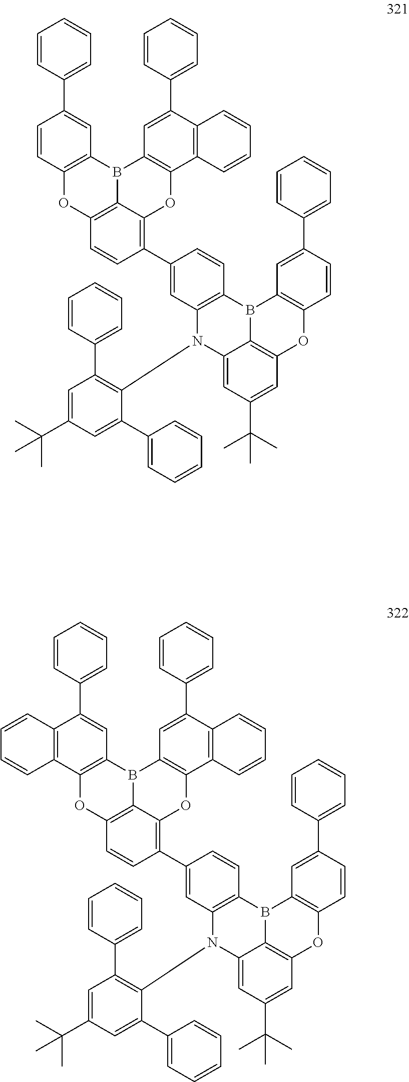 [SMILES: CC(C)(C)c1cc(-c2ccccc2)c(N2c3cc(-c4ccc5c6c4Oc4c(cc(-c7ccccc7)c7ccccc47)B6c4cc(-c6ccccc6)ccc4O5)ccc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc(-c4ccc5c6c4Oc4c(cc(-c7ccccc7)c7ccccc47)B6c4cc(-c6ccccc6)c6ccccc6c4O5)ccc3B3c4cc(-c5ccccc5)ccc4Oc4cc(C(C)(C)C)cc2c43)c(-c2ccccc2)c1]

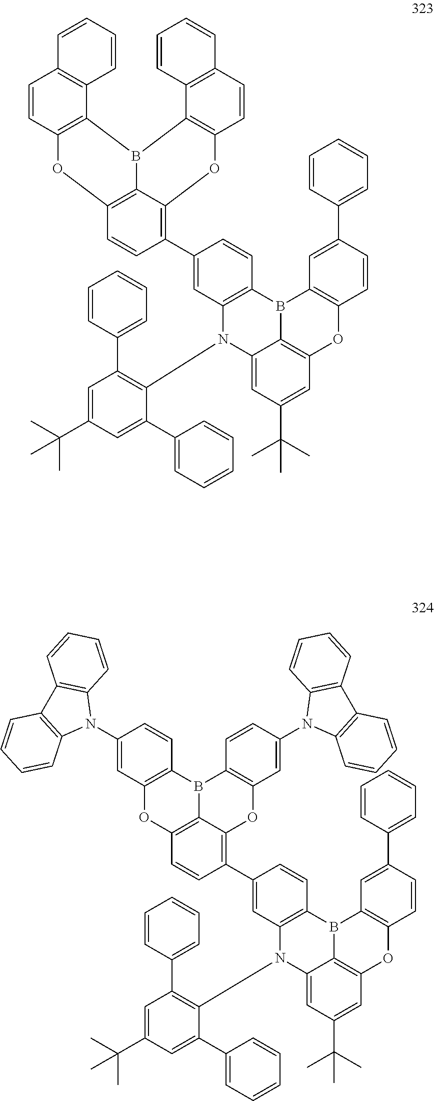 [SMILES: CC(C)(C)c1cc(-c2ccccc2)c(N2c3cc(-c4ccc5c6c4Oc4ccc7ccccc7c4B6c4c(ccc6ccccc46)O5)ccc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc(-c4ccc5c6c4Oc4cc(-n7c8ccccc8c8ccccc87)ccc4B6c4ccc(-n6c7ccccc7c7ccccc76)cc4O5)ccc3B3c4cc(-c5ccccc5)ccc4Oc4cc(C(C)(C)C)cc2c43)c(-c2ccccc2)c1]

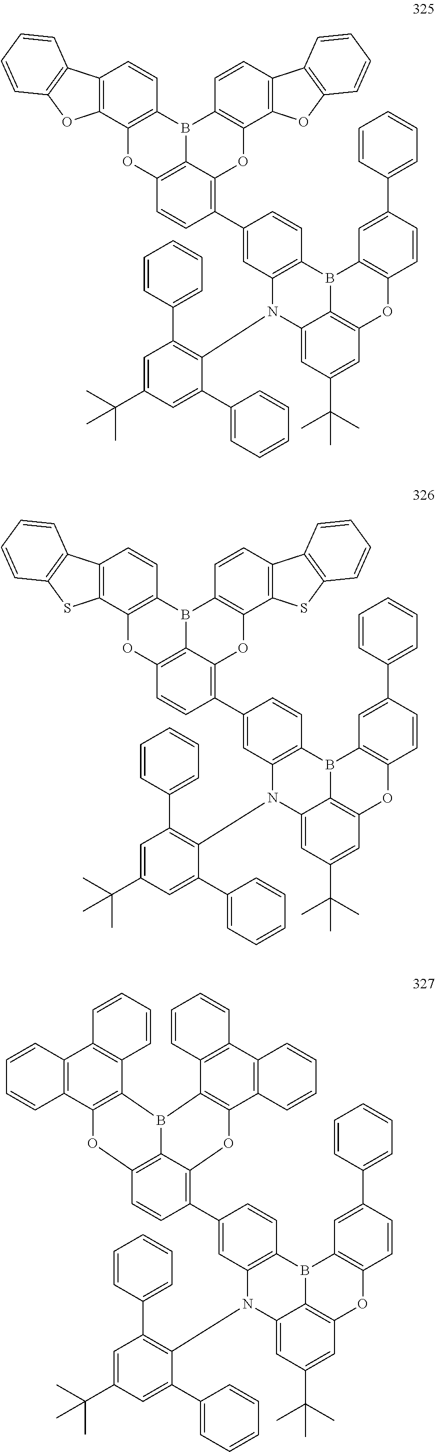 [SMILES: CC(C)(C)c1cc(-c2ccccc2)c(N2c3cc(-c4ccc5c6c4Oc4c(ccc7c4oc4ccccc47)B6c4ccc6c(oc7ccccc76)c4O5)ccc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc(-c4ccc5c6c4Oc4c(ccc7c4sc4ccccc47)B6c4ccc6c(sc7ccccc76)c4O5)ccc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc(-c4ccc5c6c4Oc4c(c7ccccc7c7ccccc47)B6c4c(c6ccccc6c6ccccc46)O5)ccc3B3c4cc(-c5ccccc5)ccc4Oc4cc(C(C)(C)C)cc2c43)c(-c2ccccc2)c1]

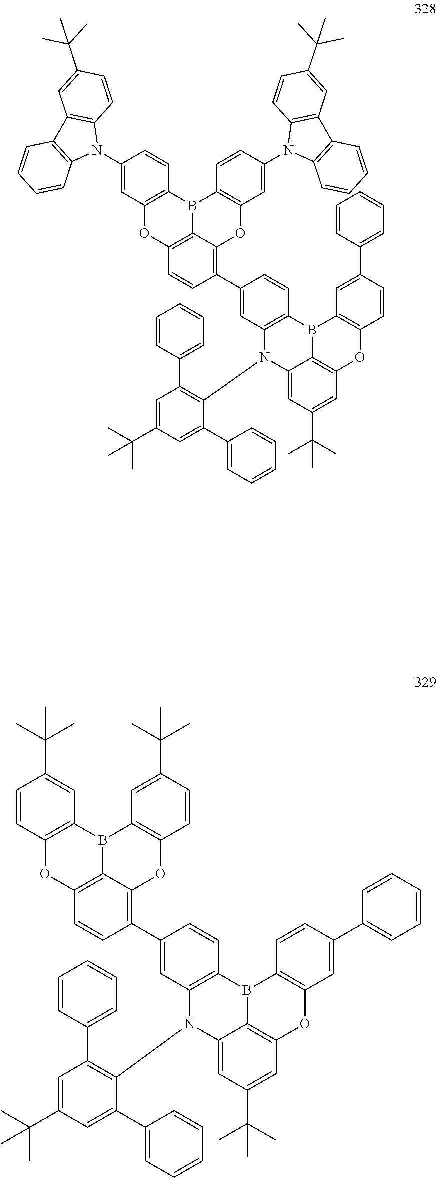 [SMILES: CC(C)(C)c1cc(-c2ccccc2)c(N2c3cc(-c4ccc5c6c4Oc4cc(-n7c8ccccc8c8cc(C(C)(C)C)ccc87)ccc4B6c4ccc(-n6c7ccccc7c7cc(C(C)(C)C)ccc76)cc4O5)ccc3B3c4cc(-c5ccccc5)ccc4Oc4cc(C(C)(C)C)cc2c43)c(-c2ccccc2)c1 ; CC(C)(C)c1ccc2c(c1)B1c3cc(C(C)(C)C)ccc3Oc3c(-c4ccc5c(c4)N(c4c(-c6ccccc6)cc(C(C)(C)C)cc4-c4ccccc4)c4cc(C(C)(C)C)cc6c4B5c4ccc(-c5ccccc5)cc4O6)ccc(c31)O2]

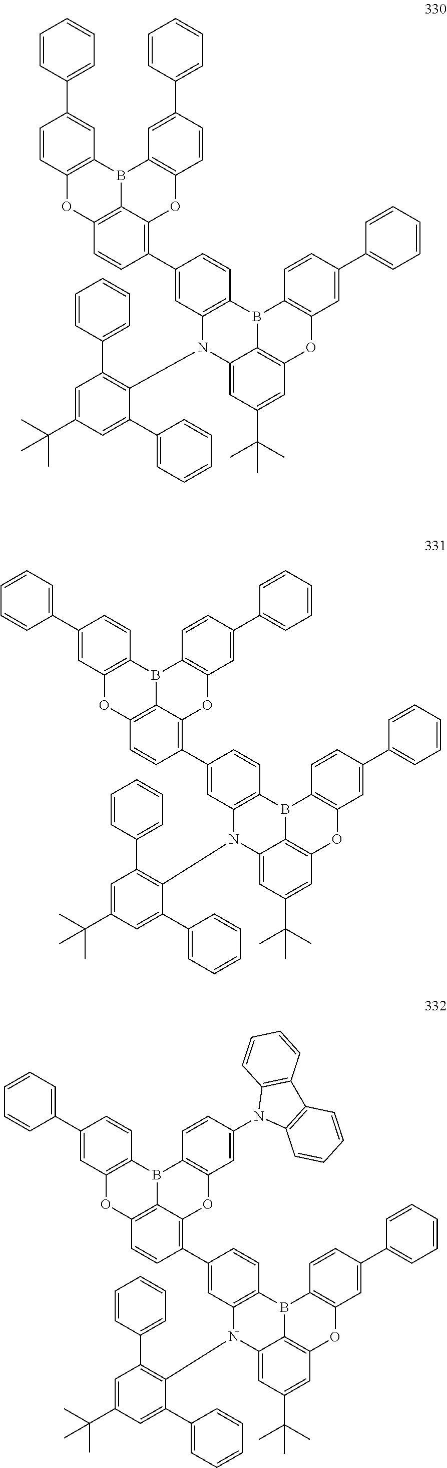 [SMILES: CC(C)(C)c1cc(-c2ccccc2)c(N2c3cc(-c4ccc5c6c4Oc4ccc(-c7ccccc7)cc4B6c4cc(-c6ccccc6)ccc4O5)ccc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc(-c4ccc5c6c4Oc4cc(-c7ccccc7)ccc4B6c4ccc(-c6ccccc6)cc4O5)ccc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc(-c4ccc5c6c4Oc4cc(-n7c8ccccc8c8ccccc87)ccc4B6c4ccc(-c6ccccc6)cc4O5)ccc3B3c4ccc(-c5ccccc5)cc4Oc4cc(C(C)(C)C)cc2c43)c(-c2ccccc2)c1]

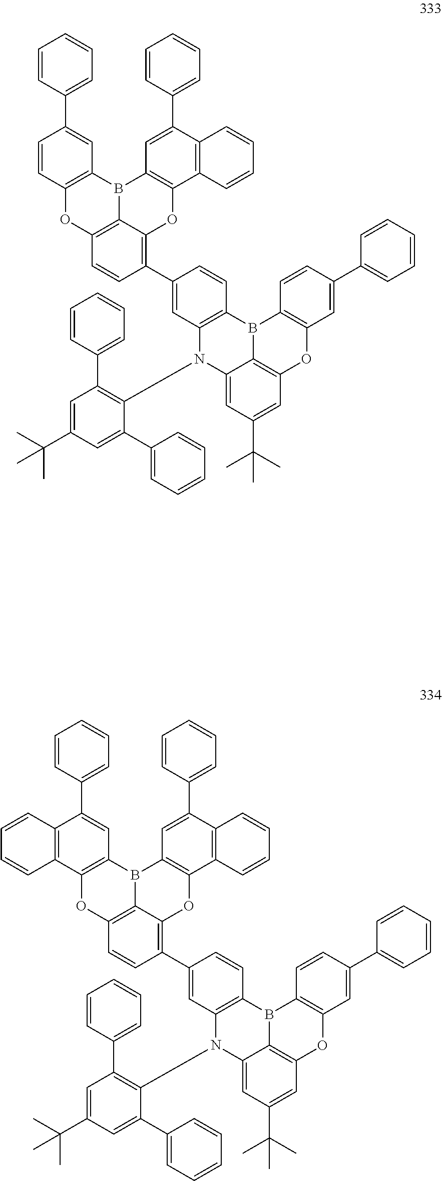 [SMILES: CC(C)(C)c1cc(-c2ccccc2)c(N2c3cc(-c4ccc5c6c4Oc4c(cc(-c7ccccc7)c7ccccc47)B6c4cc(-c6ccccc6)ccc4O5)ccc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc(-c4ccc5c6c4Oc4c(cc(-c7ccccc7)c7ccccc47)B6c4cc(-c6ccccc6)c6ccccc6c4O5)ccc3B3c4ccc(-c5ccccc5)cc4Oc4cc(C(C)(C)C)cc2c43)c(-c2ccccc2)c1]

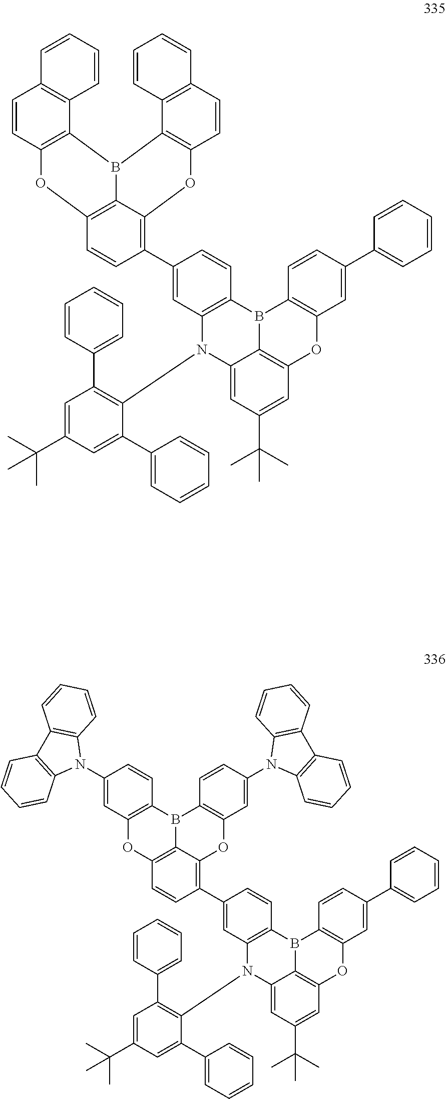 [SMILES: CC(C)(C)c1cc(-c2ccccc2)c(N2c3cc(-c4ccc5c6c4Oc4ccc7ccccc7c4B6c4c(ccc6ccccc46)O5)ccc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc(-c4ccc5c6c4Oc4cc(-n7c8ccccc8c8ccccc87)ccc4B6c4ccc(-n6c7ccccc7c7ccccc76)cc4O5)ccc3B3c4ccc(-c5ccccc5)cc4Oc4cc(C(C)(C)C)cc2c43)c(-c2ccccc2)c1]

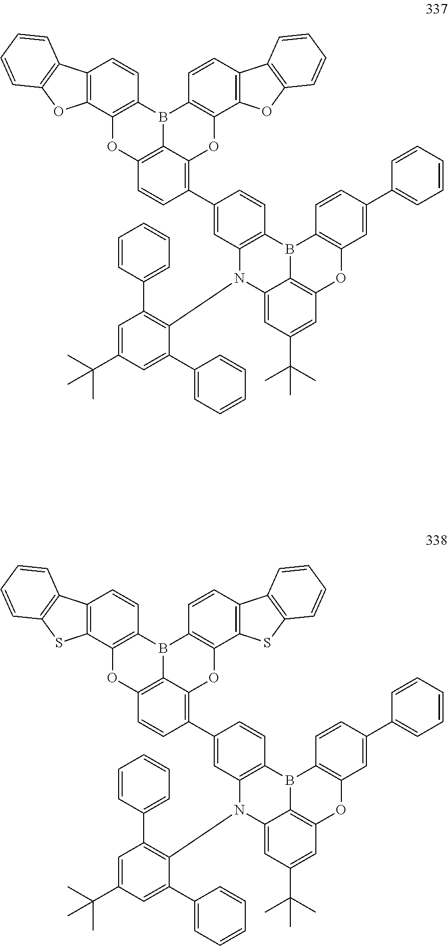 [SMILES: CC(C)(C)c1cc(-c2ccccc2)c(N2c3cc(-c4ccc5c6c4Oc4c(ccc7c4oc4ccccc47)B6c4ccc6c(oc7ccccc76)c4O5)ccc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc(-c4ccc5c6c4Oc4c(ccc7c4sc4ccccc47)B6c4ccc6c(sc7ccccc76)c4O5)ccc3B3c4ccc(-c5ccccc5)cc4Oc4cc(C(C)(C)C)cc2c43)c(-c2ccccc2)c1]

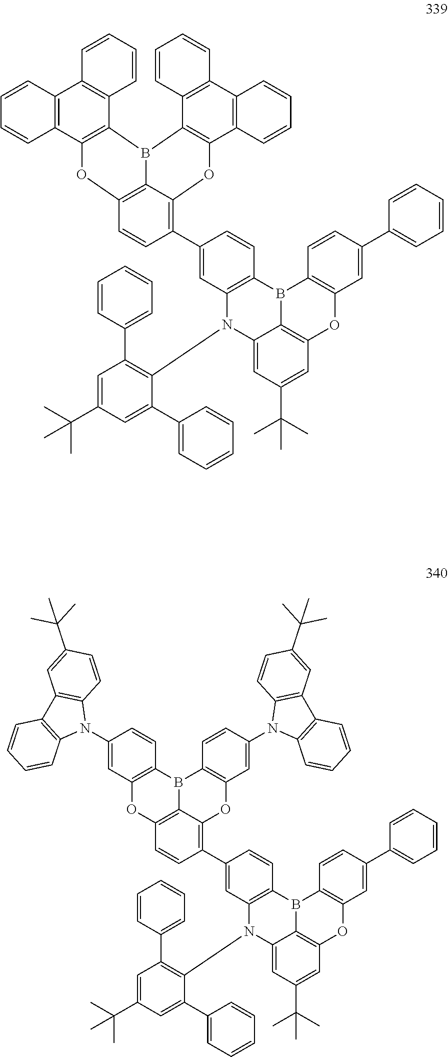 [SMILES: CC(C)(C)c1cc(-c2ccccc2)c(N2c3cc(-c4ccc5c6c4Oc4c(c7ccccc7c7ccccc47)B6c4c(c6ccccc6c6ccccc46)O5)ccc3B3c4ccc(-c5ccccc5)cc4Oc4cc(C(C)(C)C)cc2c43)c(-c2ccccc2)c1 ; CC(C)(C)c1cc(-c2ccccc2)c(N2c3cc(-c4ccc5c6c4Oc4cc(-n7c8ccccc8c8cc(C(C)(C)C)ccc87)ccc4B6c4ccc(-n6c7ccccc7c7cc(C(C)(C)C)ccc76)cc4O5)ccc3B3c4ccc(-c5ccccc5)cc4Oc4cc(C(C)(C)C)cc2c43)c(-c2ccccc2)c1]

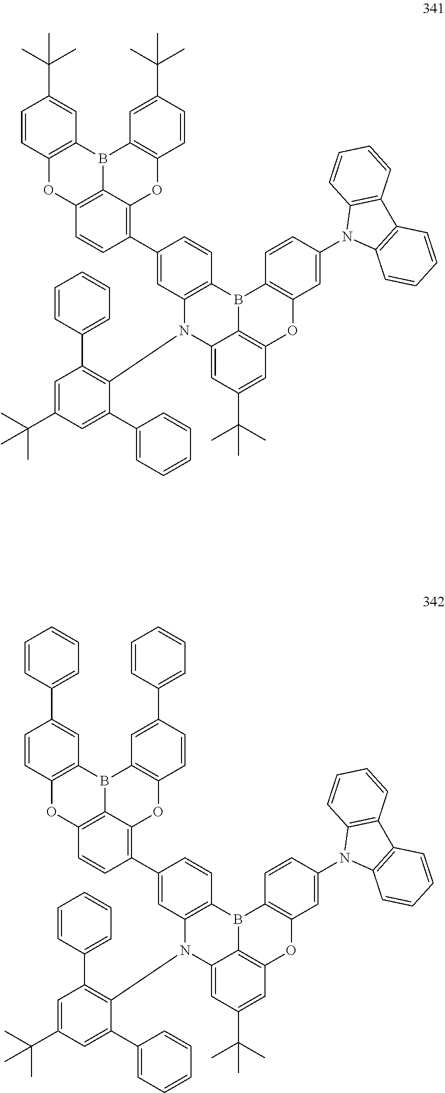 [SMILES: CC(C)(C)c1ccc2c(c1)B1c3cc(C(C)(C)C)ccc3Oc3c(-c4ccc5c(c4)N(c4c(-c6ccccc6)cc(C(C)(C)C)cc4-c4ccccc4)c4cc(C(C)(C)C)cc6c4B5c4ccc(-n5c7ccccc7c7ccccc75)cc4O6)ccc(c31)O2 ; CC(C)(C)c1cc(-c2ccccc2)c(N2c3cc(-c4ccc5c6c4Oc4ccc(-c7ccccc7)cc4B6c4cc(-c6ccccc6)ccc4O5)ccc3B3c4ccc(-n5c6ccccc6c6ccccc65)cc4Oc4cc(C(C)(C)C)cc2c43)c(-c2ccccc2)c1]

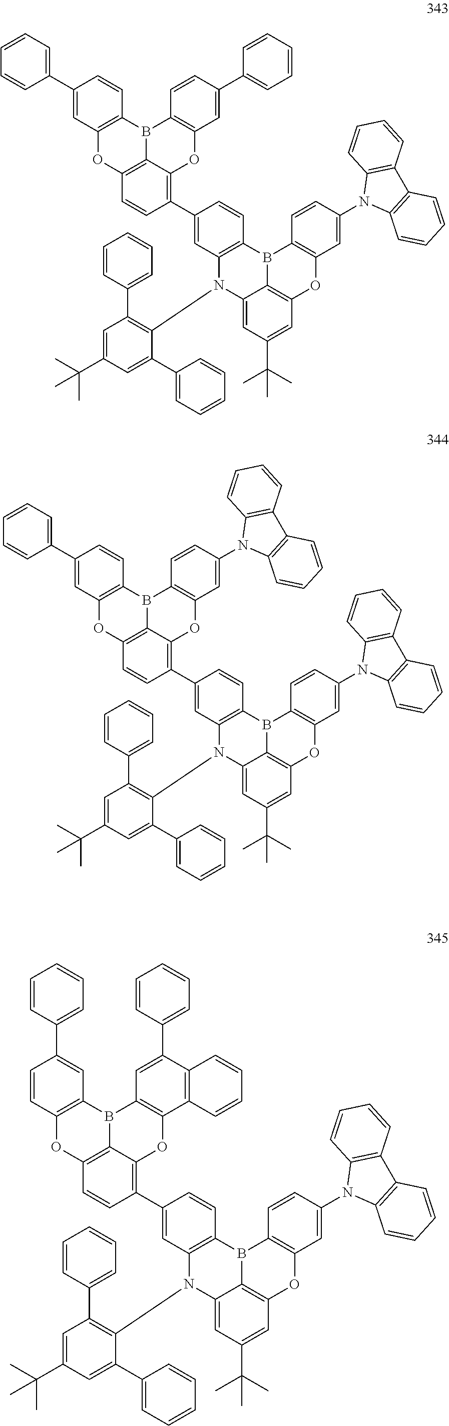

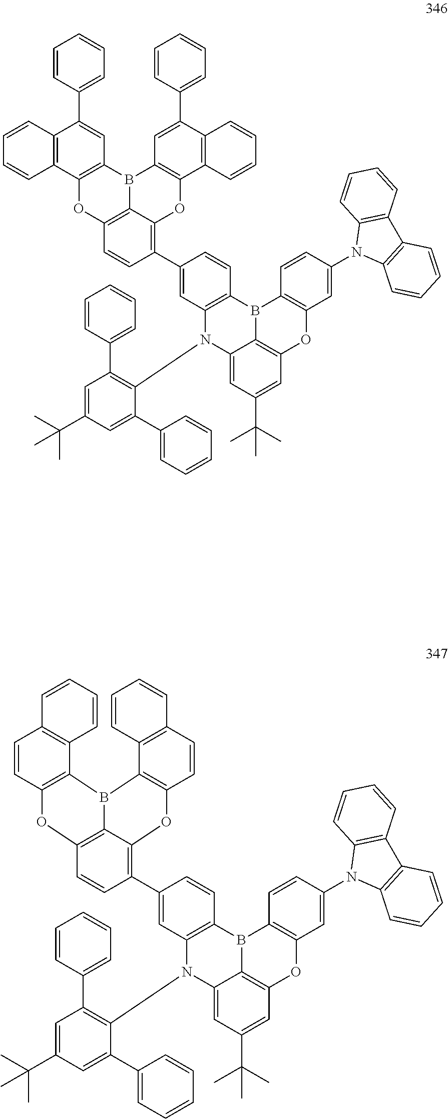 [SMILES: CC(C)(C)c1cc(-c2ccccc2)c(N2c3cc(-c4ccc5c6c4Oc4c(cc(-c7ccccc7)c7ccccc47)B6c4cc(-c6ccccc6)c6ccccc6c4O5)ccc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3cc(-c4ccc5c6c4Oc4ccc7ccccc7c4B6c4c(ccc6ccccc46)O5)ccc3B3c4ccc(-n5c6ccccc6c6ccccc65)cc4Oc4cc(C(C)(C)C)cc2c43)c(-c2ccccc2)c1]

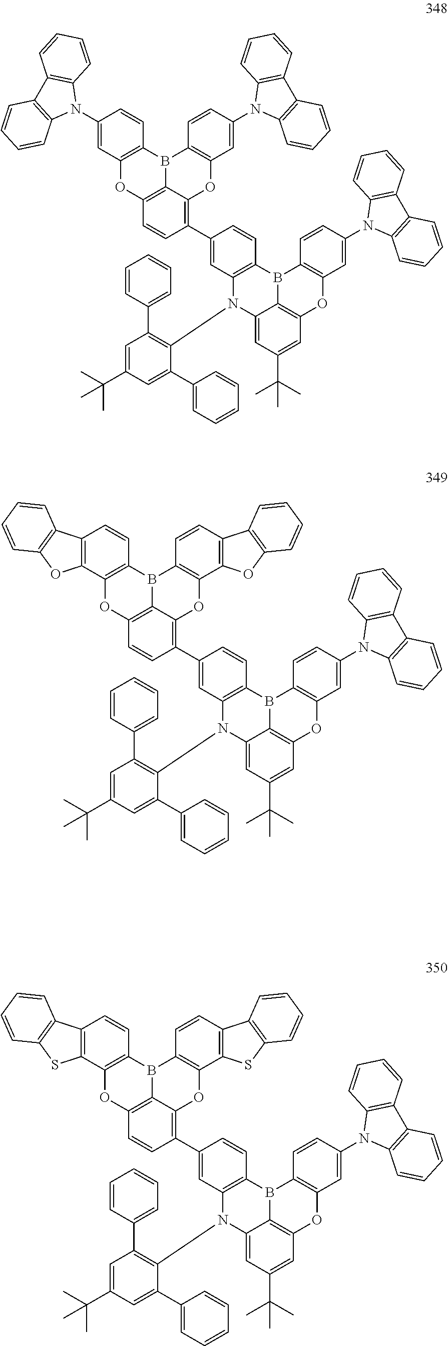

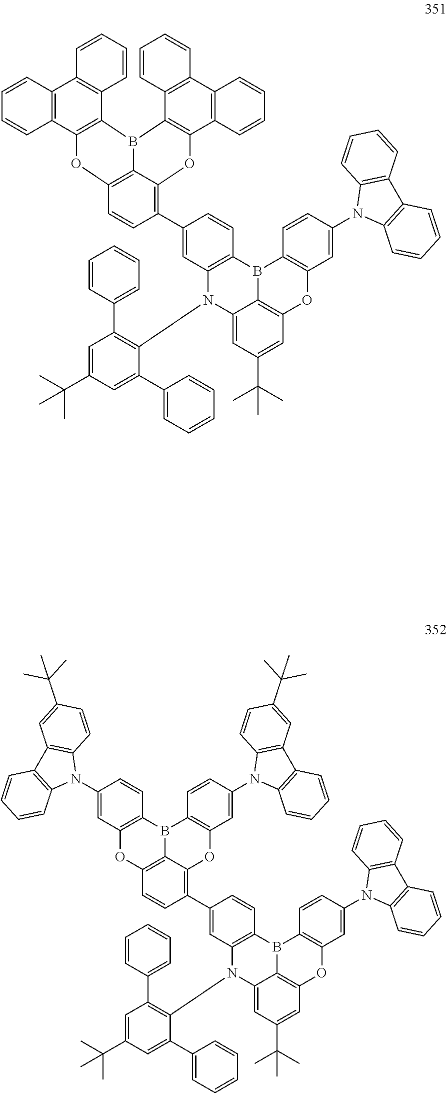 [SMILES: CC(C)(C)c1cc(-c2ccccc2)c(N2c3cc(-c4ccc5c6c4Oc4c(c7ccccc7c7ccccc47)B6c4c(c6ccccc6c6ccccc46)O5)ccc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3cc(-c4ccc5c6c4Oc4cc(-n7c8ccccc8c8cc(C(C)(C)C)ccc87)ccc4B6c4ccc(-n6c7ccccc7c7cc(C(C)(C)C)ccc76)cc4O5)ccc3B3c4ccc(-n5c6ccccc6c6ccccc65)cc4Oc4cc(C(C)(C)C)cc2c43)c(-c2ccccc2)c1]

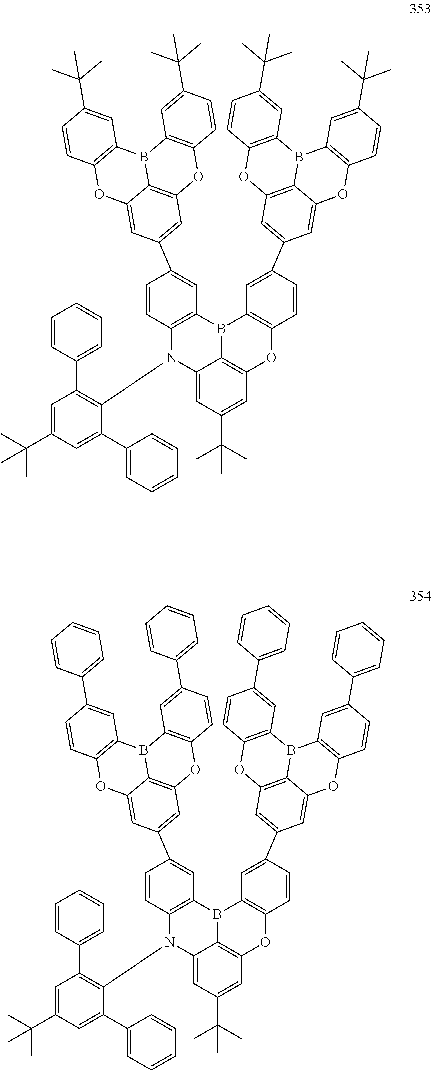

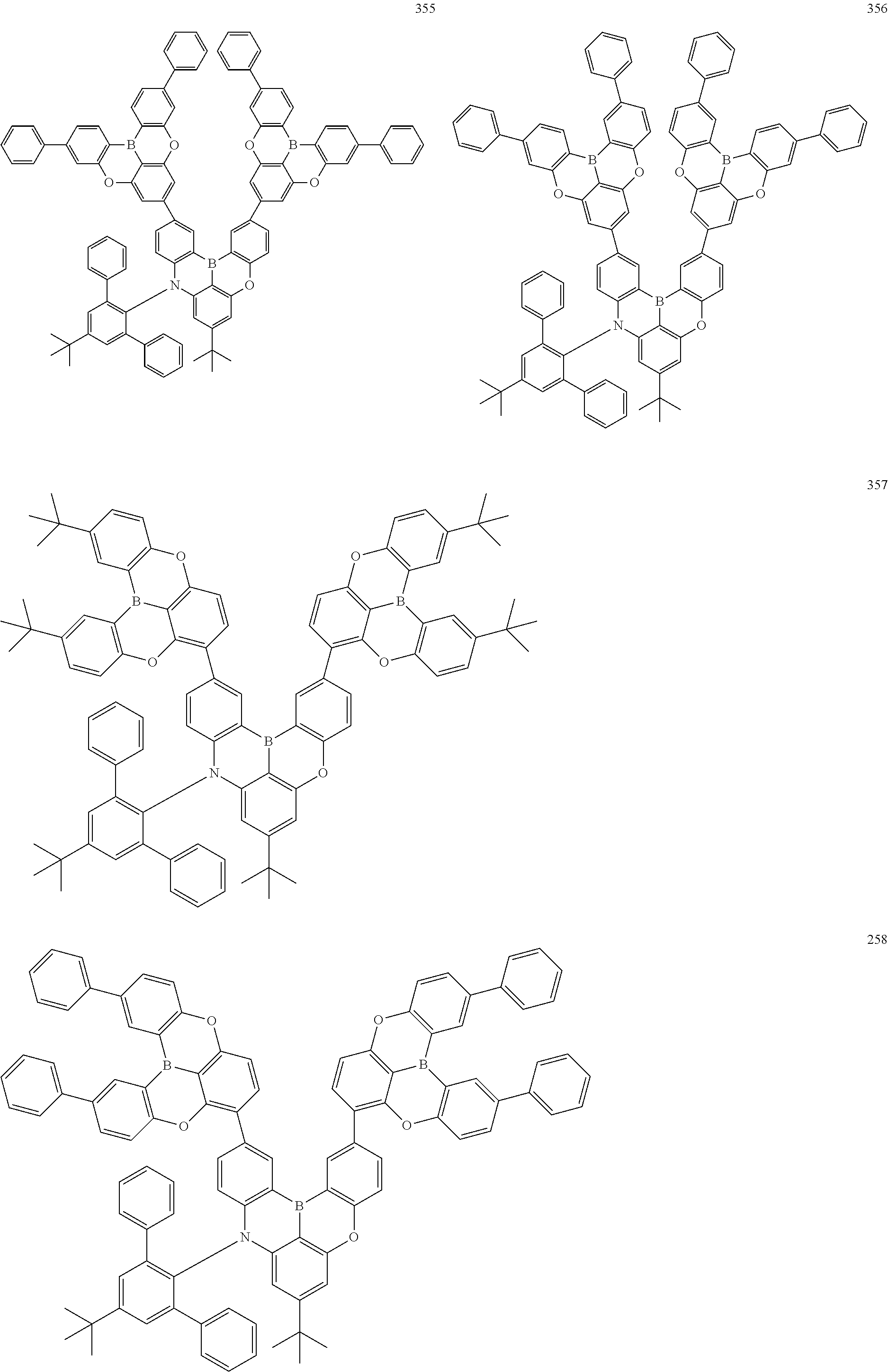

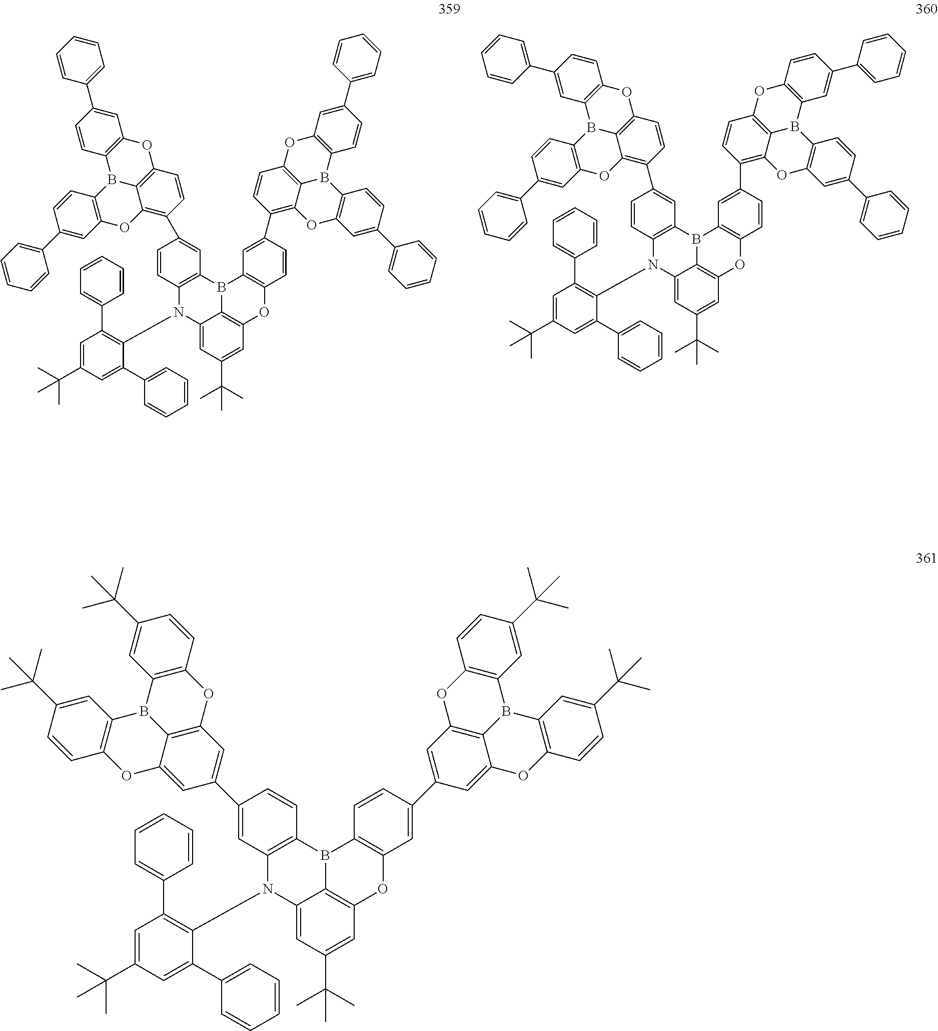

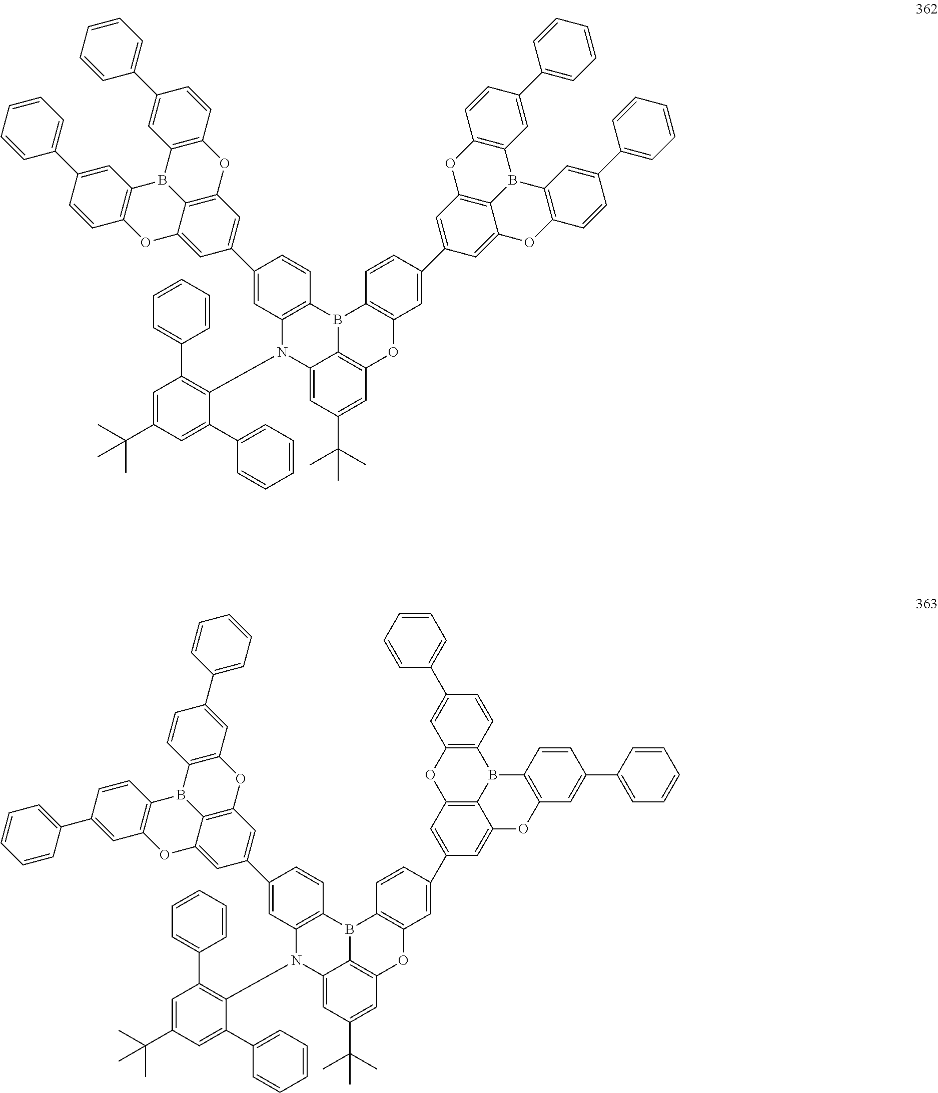 [SMILES: CC(C)(C)c1cc(-c2ccccc2)c(N2c3cc(-c4cc5c6c(c4)Oc4ccc(-c7ccccc7)cc4B6c4cc(-c6ccccc6)ccc4O5)ccc3B3c4ccc(-c5cc6c7c(c5)Oc5ccc(-c8ccccc8)cc5B7c5cc(-c7ccccc7)ccc5O6)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4cc(-c7ccccc7)ccc4B6c4ccc(-c6ccccc6)cc4O5)ccc3B3c4ccc(-c5cc6c7c(c5)Oc5cc(-c8ccccc8)ccc5B7c5ccc(-c7ccccc7)cc5O6)cc4Oc4cc(C(C)(C)C)cc2c43)c(-c2ccccc2)c1]

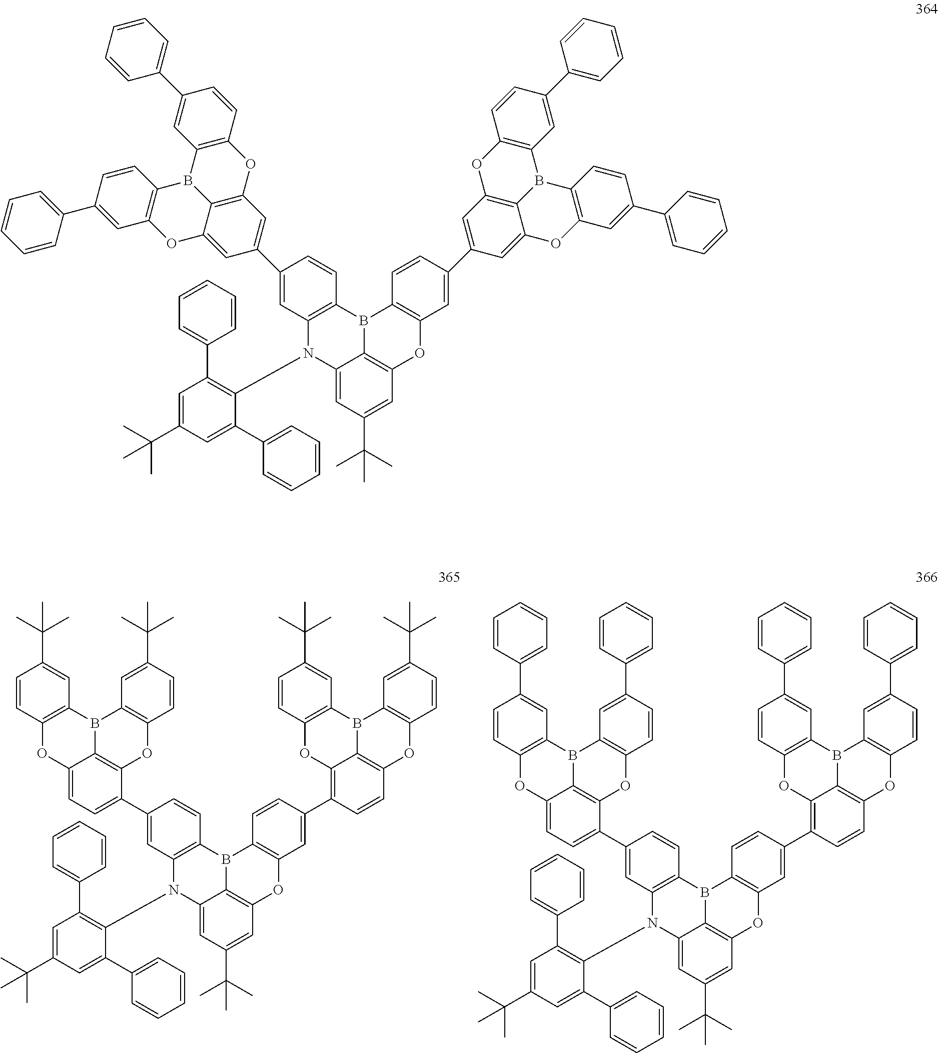

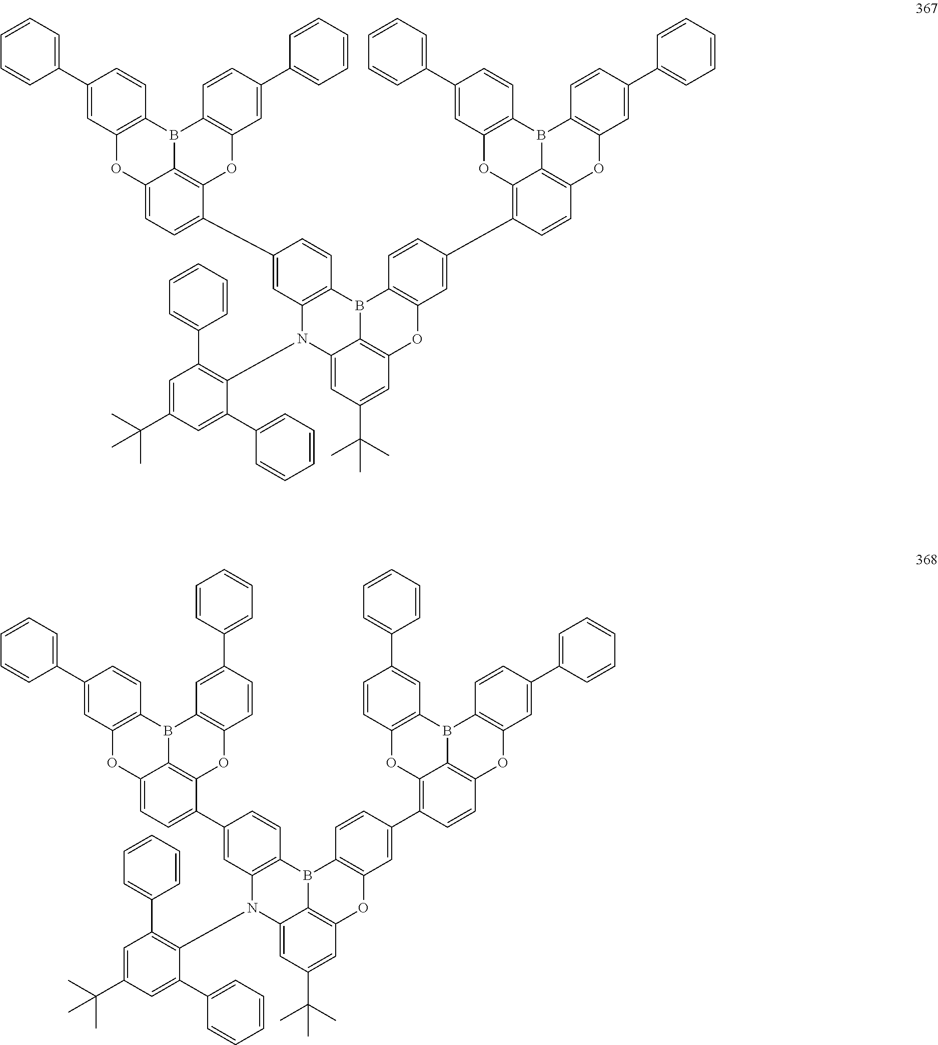 [SMILES: CC(C)(C)c1cc(-c2ccccc2)c(N2c3cc(-c4ccc5c6c4Oc4cc(-c7ccccc7)ccc4B6c4ccc(-c6ccccc6)cc4O5)ccc3B3c4ccc(-c5ccc6c7c5Oc5cc(-c8ccccc8)ccc5B7c5ccc(-c7ccccc7)cc5O6)cc4Oc4cc(C(C)(C)C)cc2c43)c(-c2ccccc2)c1 ; CC(C)(C)c1cc(-c2ccccc2)c(N2c3cc(-c4ccc5c6c4Oc4ccc(-c7ccccc7)cc4B6c4ccc(-c6ccccc6)cc4O5)ccc3B3c4ccc(-c5ccc6c7c5Oc5ccc(-c8ccccc8)cc5B7c5ccc(-c7ccccc7)cc5O6)cc4Oc4cc(C(C)(C)C)cc2c43)c(-c2ccccc2)c1]

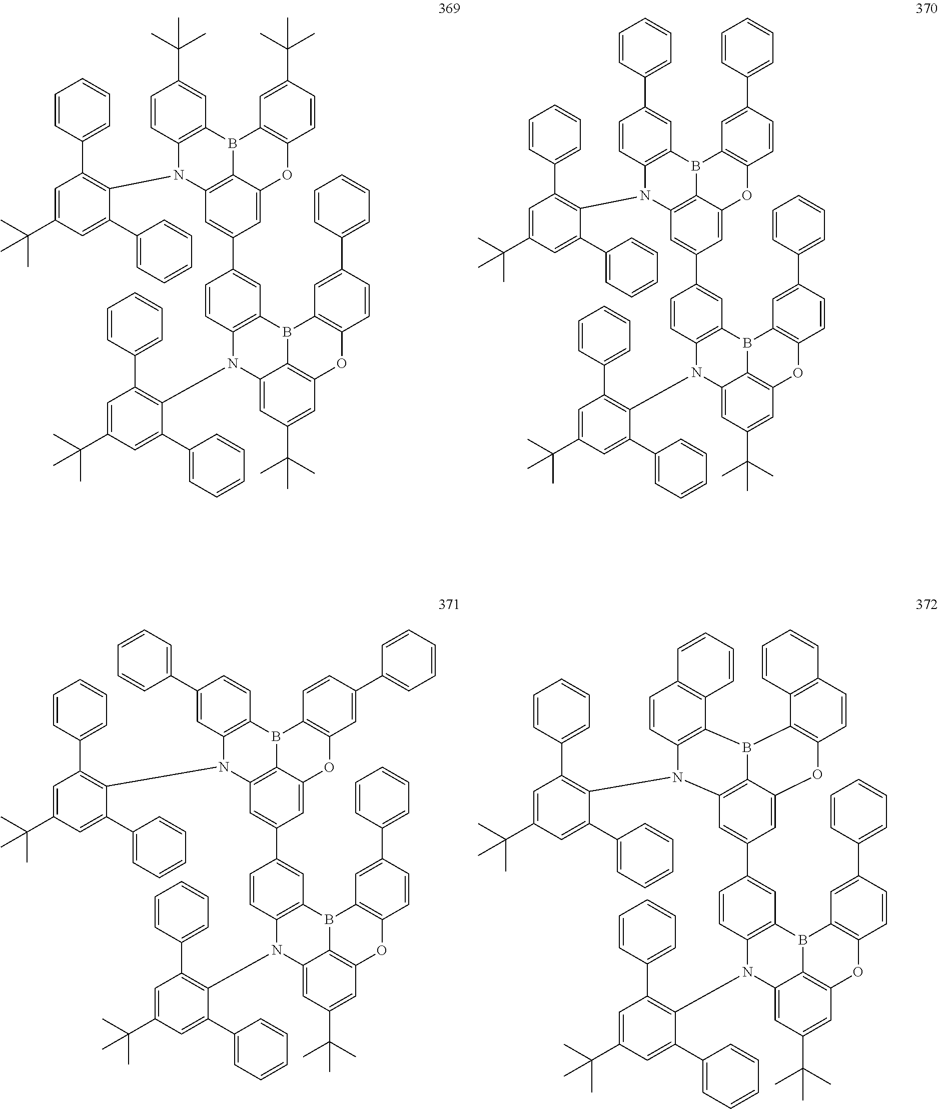

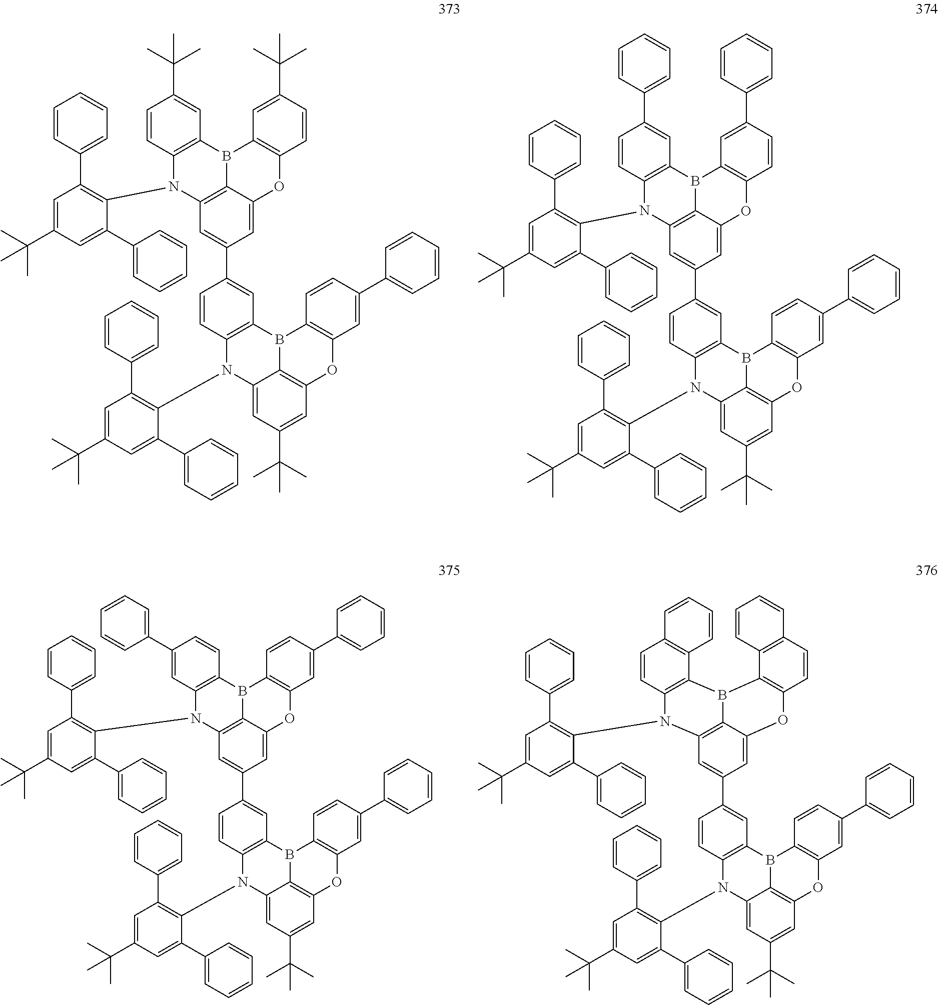

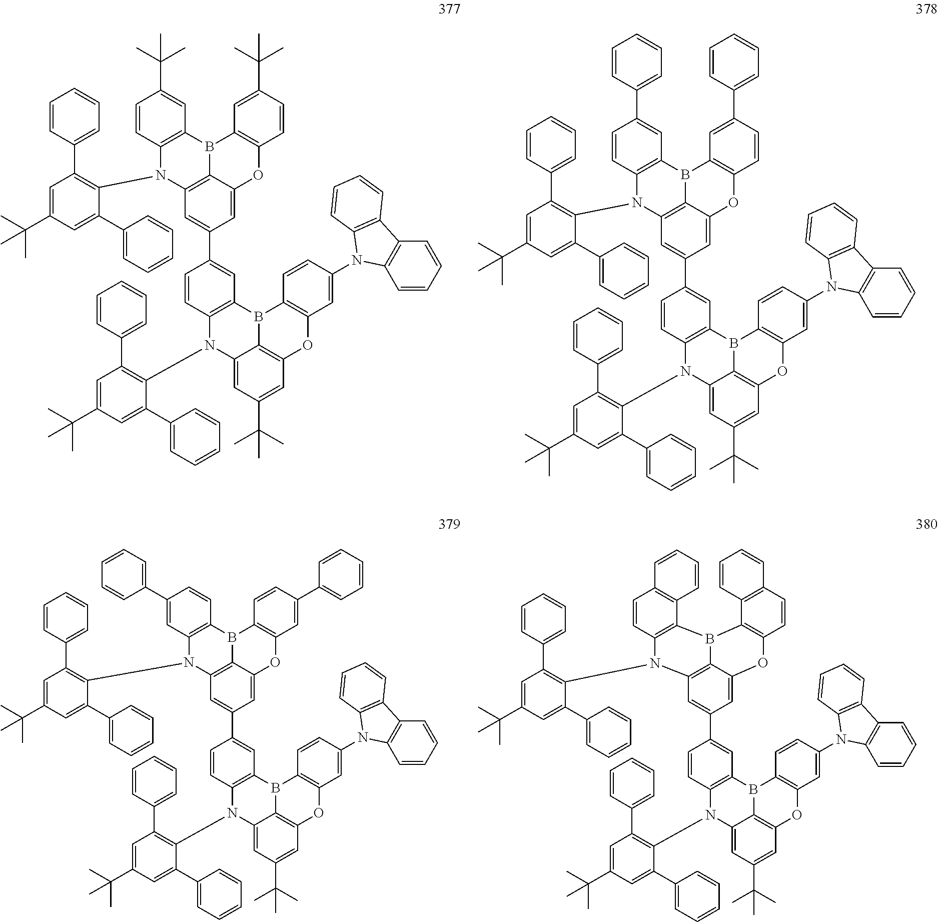

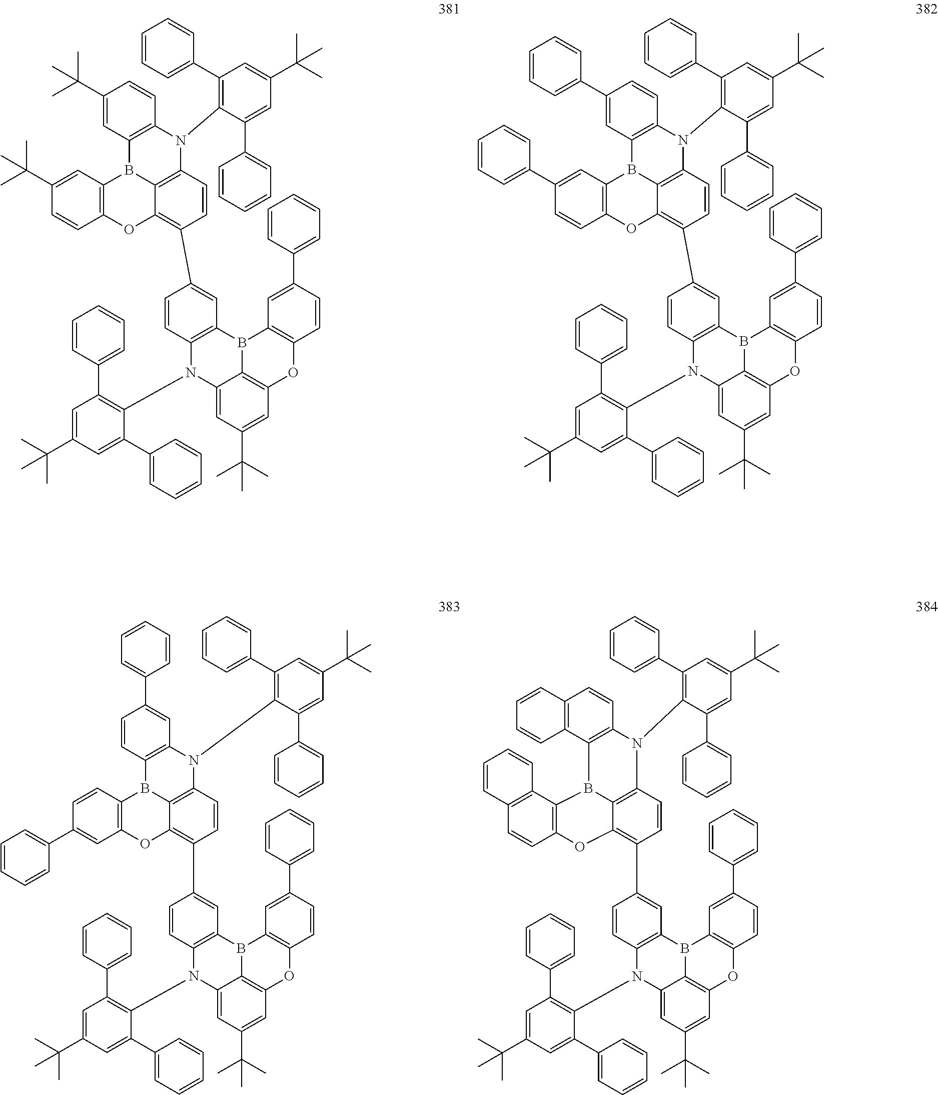

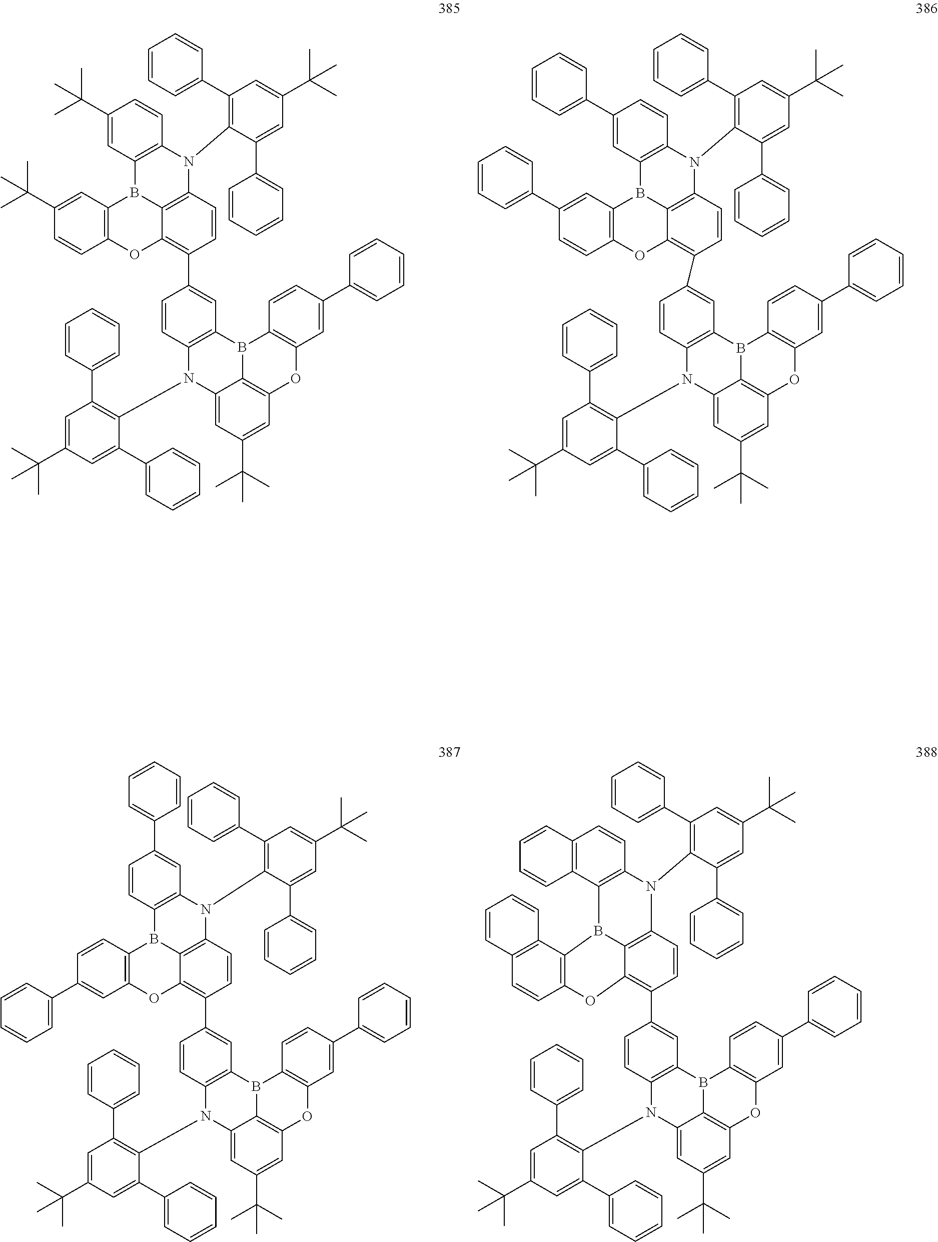

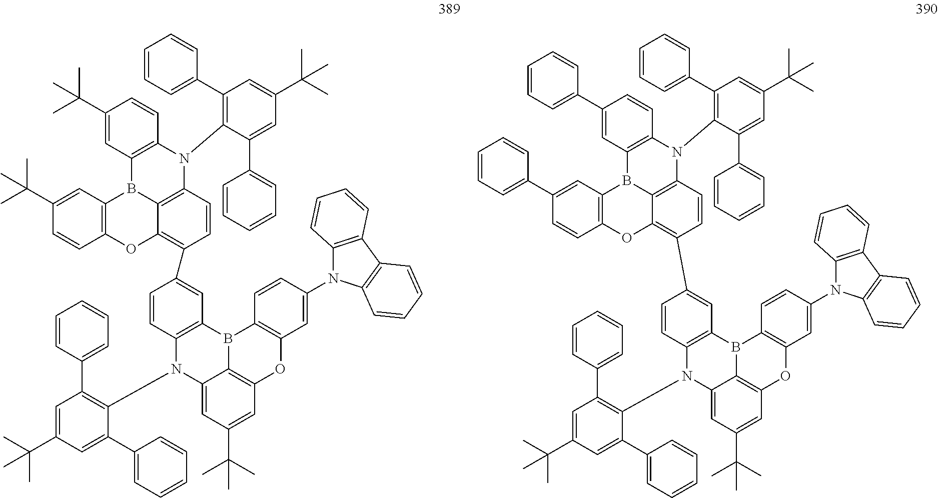 [SMILES: CC(C)(C)c1ccc2c(c1)B1c3cc(C(C)(C)C)ccc3N(c3c(-c4ccccc4)cc(C(C)(C)C)cc3-c3ccccc3)c3ccc(-c4ccc5c(c4)B4c6ccc(-n7c8ccccc8c8ccccc87)cc6Oc6cc(C(C)(C)C)cc(c64)N5c4c(-c5ccccc5)cc(C(C)(C)C)cc4-c4ccccc4)c(c31)O2 ; CC(C)(C)c1cc(-c2ccccc2)c(N2c3ccc(-c4ccc5c6c4Oc4ccc(-c7ccccc7)cc4B6c4cc(-c6ccccc6)ccc4N5c4c(-c5ccccc5)cc(C(C)(C)C)cc4-c4ccccc4)cc3B3c4ccc(-n5c6ccccc6c6ccccc65)cc4Oc4cc(C(C)(C)C)cc2c43)c(-c2ccccc2)c1]

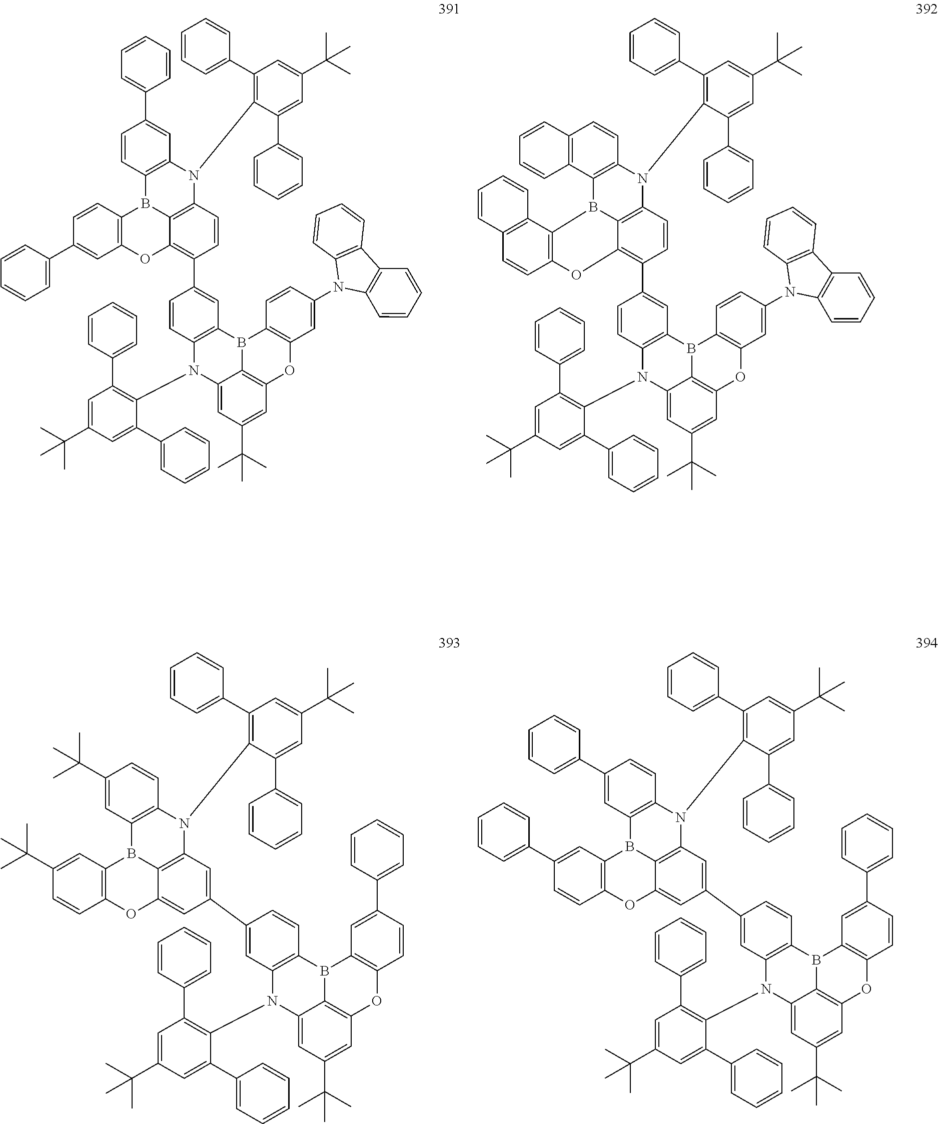

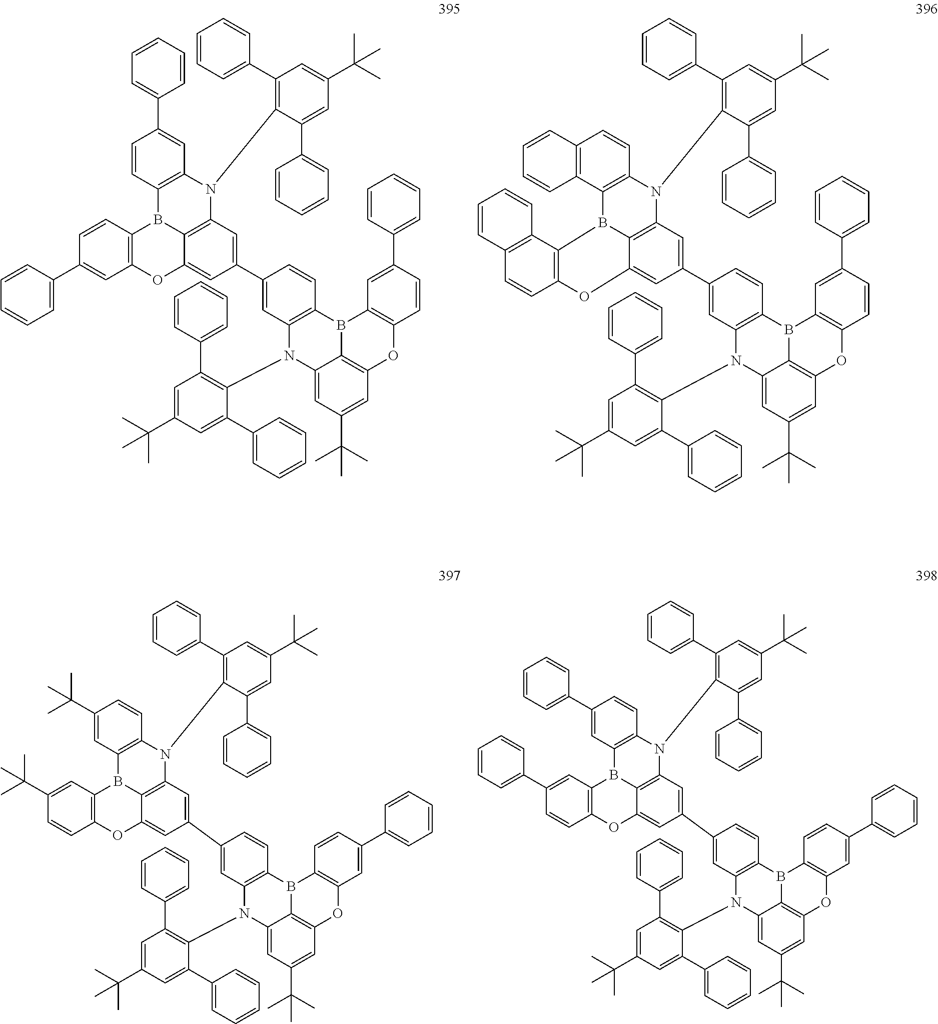

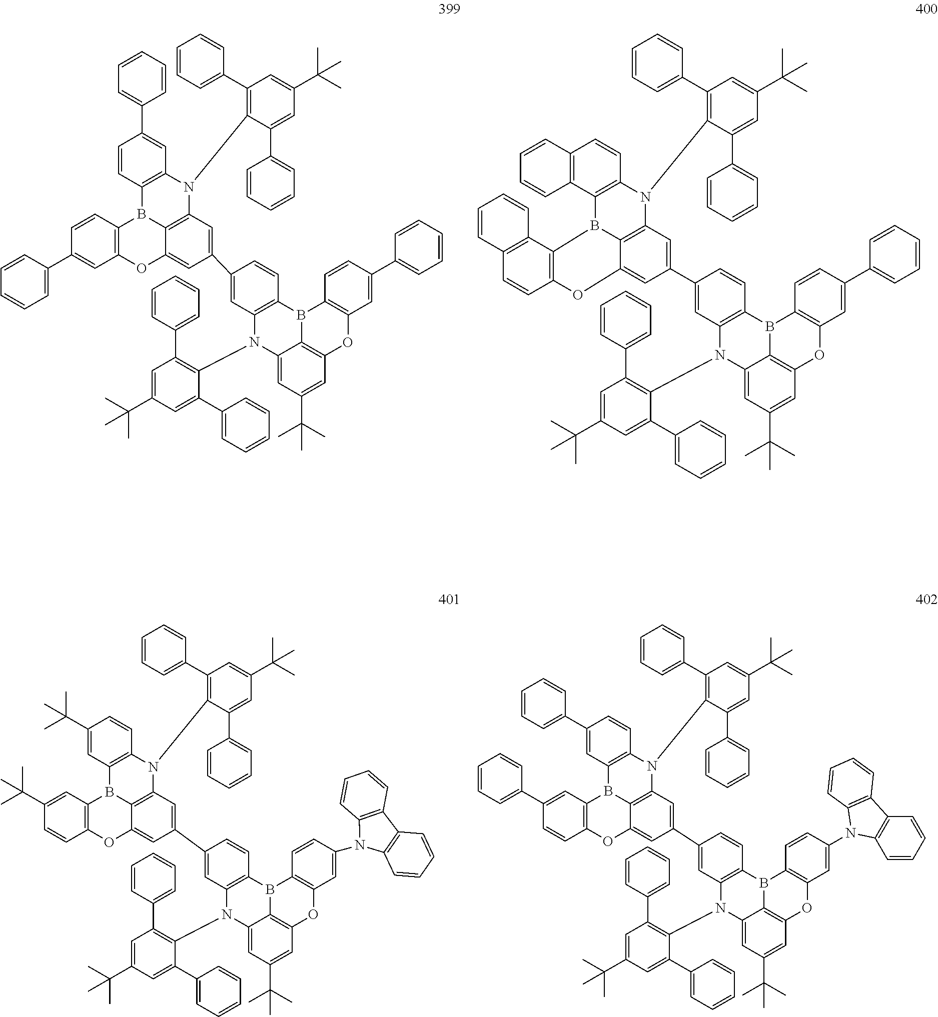

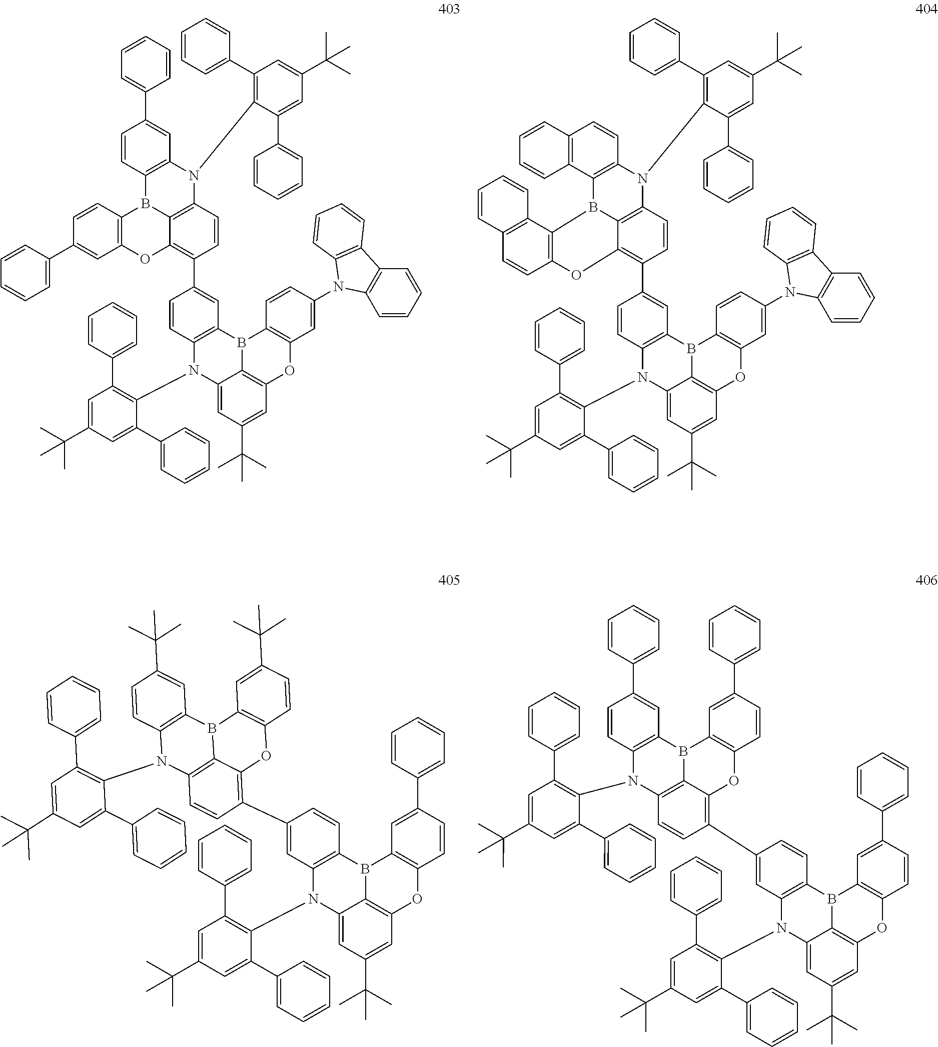

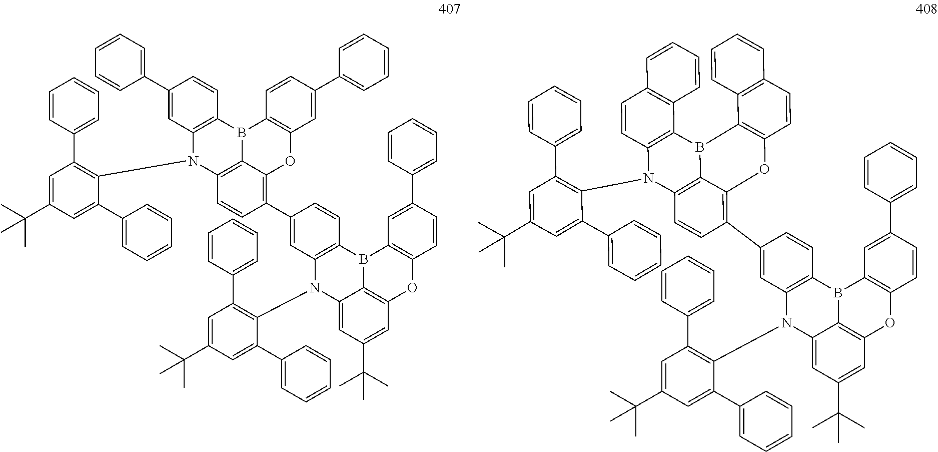 [SMILES: CC(C)(C)c1cc(-c2ccccc2)c(N2c3cc(-c4ccc5c6c4Oc4cc(-c7ccccc7)ccc4B6c4ccc(-c6ccccc6)cc4N5c4c(-c5ccccc5)cc(C(C)(C)C)cc4-c4ccccc4)ccc3B3c4cc(-c5ccccc5)ccc4Oc4cc(C(C)(C)C)cc2c43)c(-c2ccccc2)c1 ; CC(C)(C)c1cc(-c2ccccc2)c(N2c3cc(-c4ccc5c6c4Oc4ccc7ccccc7c4B6c4c(ccc6ccccc46)N5c4c(-c5ccccc5)cc(C(C)(C)C)cc4-c4ccccc4)ccc3B3c4cc(-c5ccccc5)ccc4Oc4cc(C(C)(C)C)cc2c43)c(-c2ccccc2)c1]

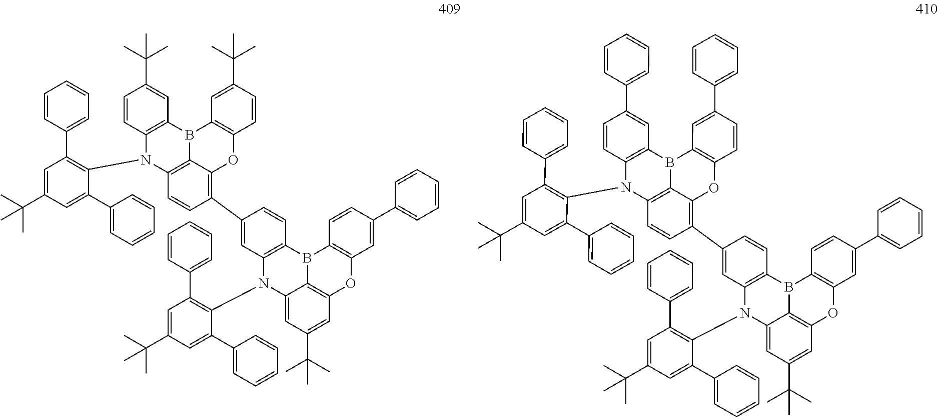 [SMILES: CC(C)(C)c1ccc2c(c1)B1c3cc(C(C)(C)C)ccc3N(c3c(-c4ccccc4)cc(C(C)(C)C)cc3-c3ccccc3)c3ccc(-c4ccc5c(c4)N(c4c(-c6ccccc6)cc(C(C)(C)C)cc4-c4ccccc4)c4cc(C(C)(C)C)cc6c4B5c4ccc(-c5ccccc5)cc4O6)c(c31)O2 ; CC(C)(C)c1cc(-c2ccccc2)c(N2c3cc(-c4ccc5c6c4Oc4ccc(-c7ccccc7)cc4B6c4cc(-c6ccccc6)ccc4N5c4c(-c5ccccc5)cc(C(C)(C)C)cc4-c4ccccc4)ccc3B3c4ccc(-c5ccccc5)cc4Oc4cc(C(C)(C)C)cc2c43)c(-c2ccccc2)c1]

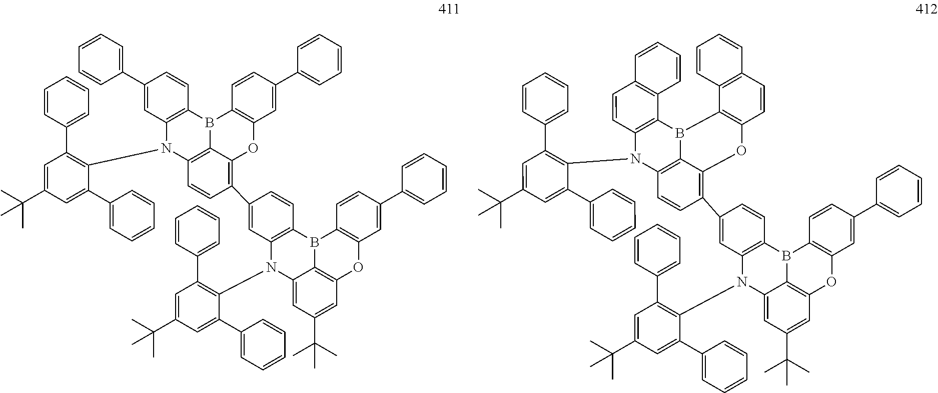

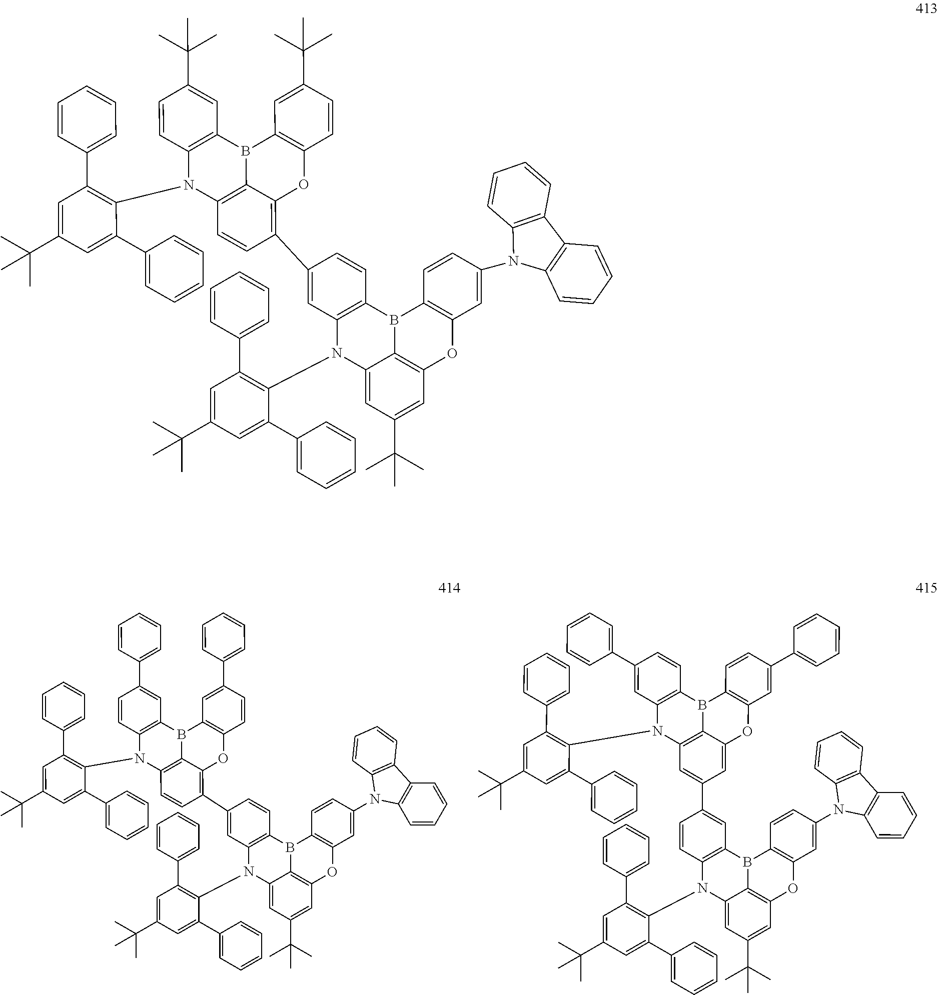

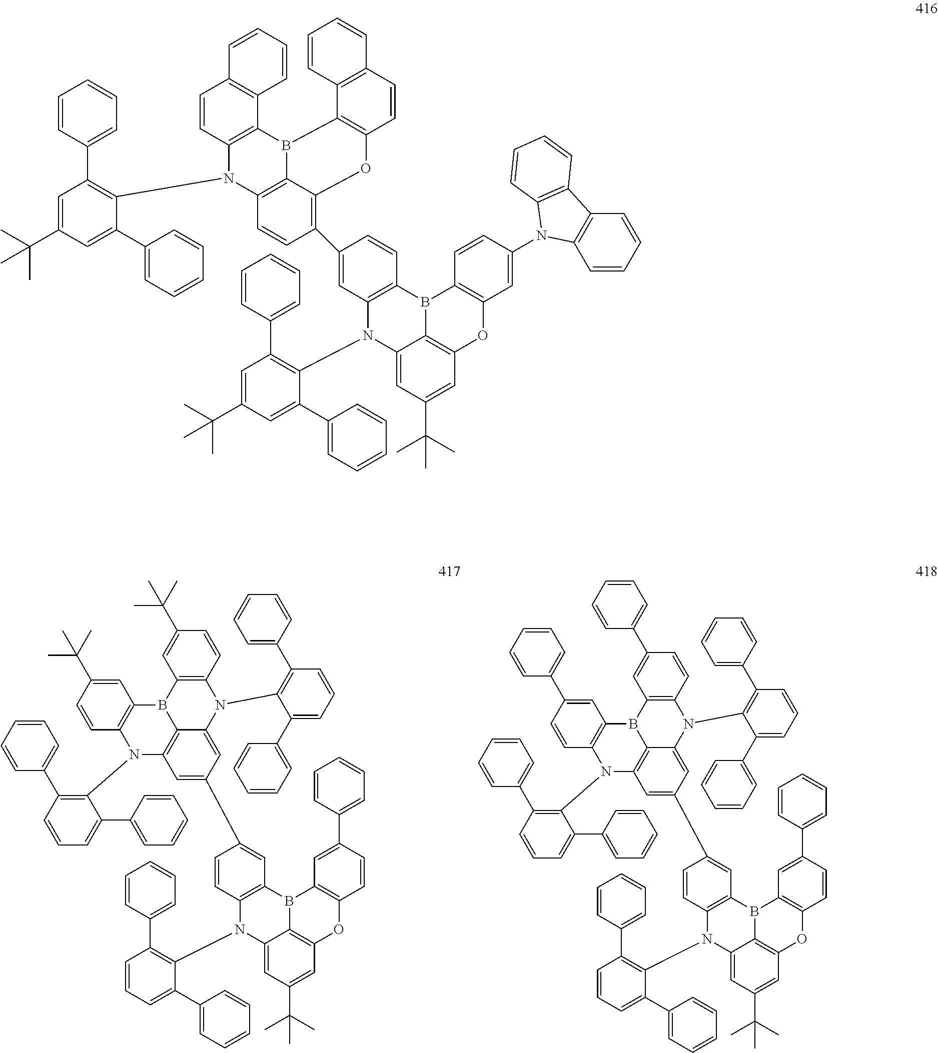

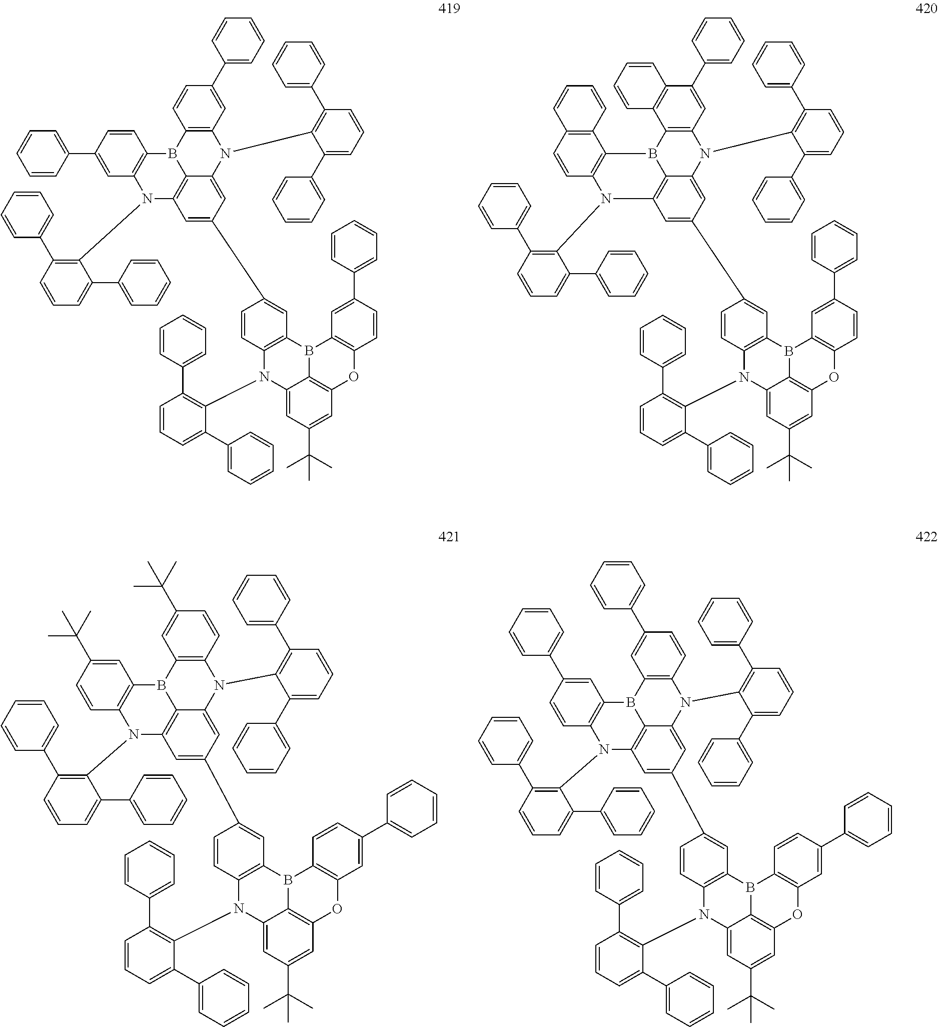

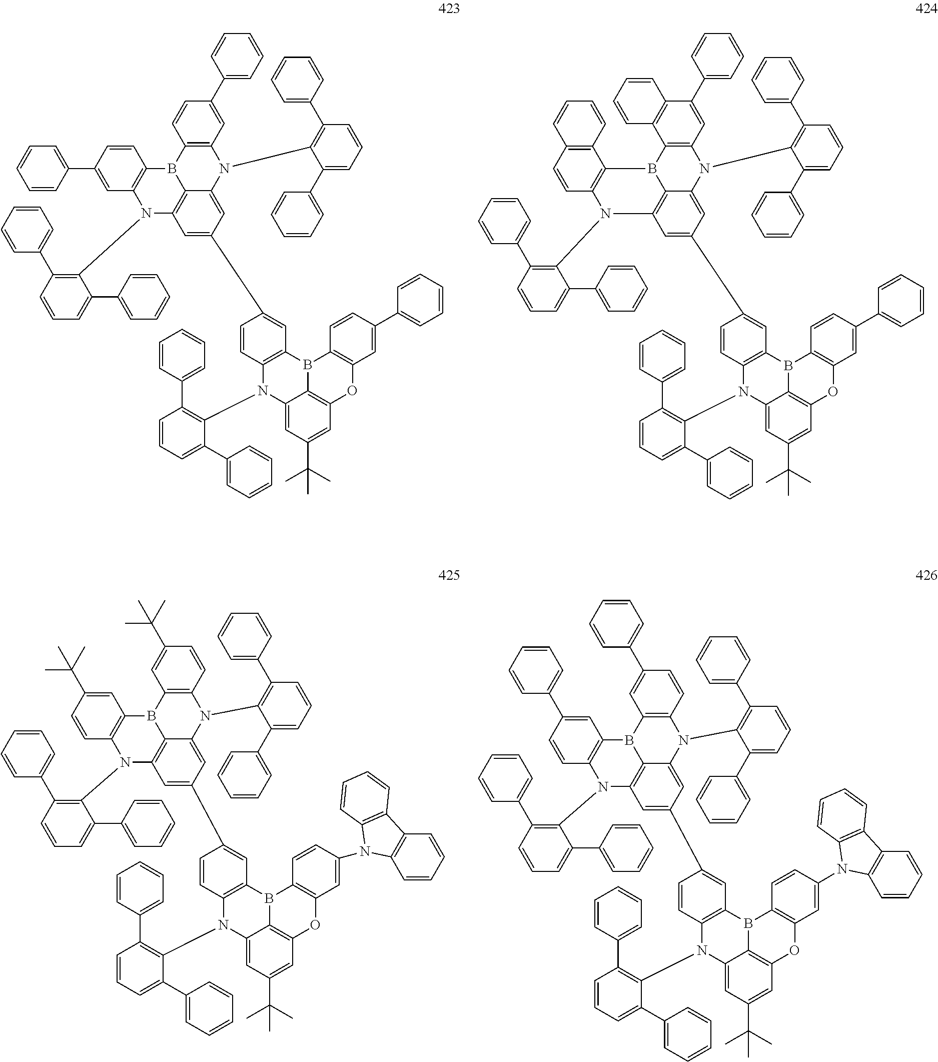

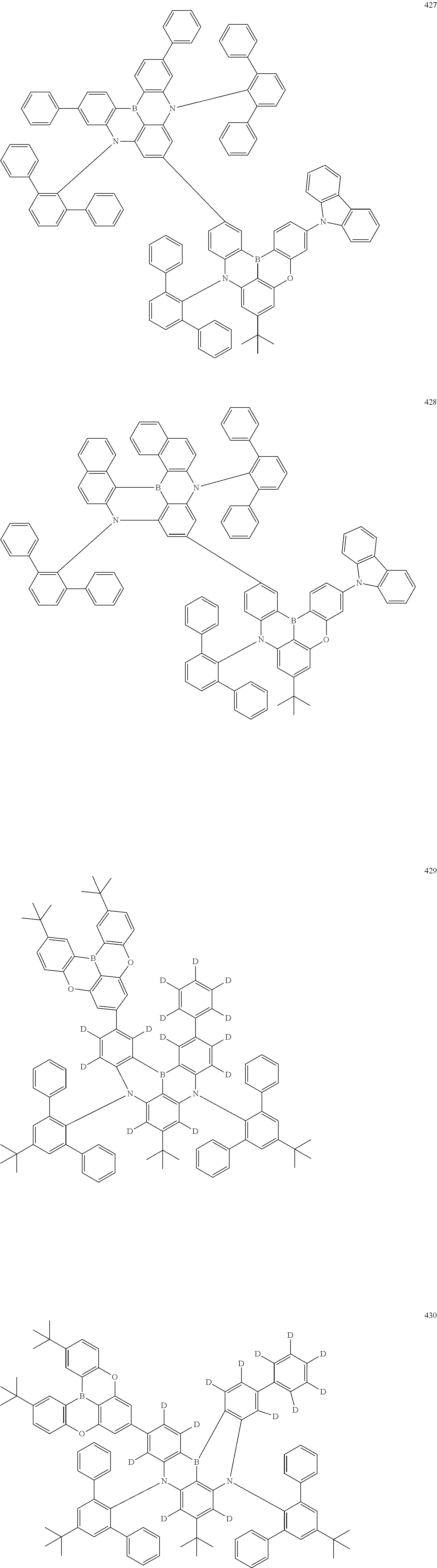

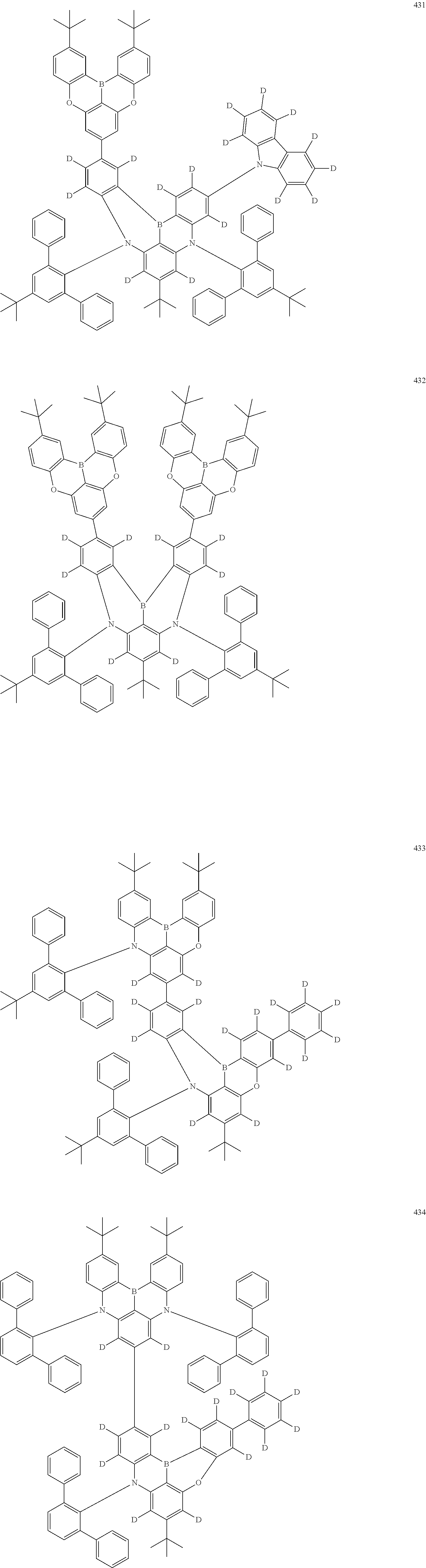

In the specific example compounds suggested in Compound Group 1, “D” refers to a deuterium atom.

The fused polycyclic compound according to one or more embodiments includes the at least two fused ring structures, and thus may achieve improvements in high efficiency and long lifespan.

The fused polycyclic compound according to one or more embodiments includes one first fused ring, and at least one second fused ring, wherein the second fused ring includes a structure to which the first fused ring is directly connected without an additional linker. At least one among the heteroatoms constituting the first fused ring is a nitrogen atom. The fused polycyclic compound according to one or more embodiments of the disclosure has an incomplete charge transfer (CT)-typed structure formed due to a specified structure and connection position of the first fused ring and the second fused ring, and thus has an excellent or suitable multi-resonance structure, which may contribute to improvements in high efficiency and long lifespan of the light-emitting element ED containing the fused polycyclic compound. If the incomplete charge transfer (CT)-typed structure is formed, due to an intramolecular charge transfer (CT) structure, an overlapping region occurs between a highest occupied molecular orbital (HOMO) and a lowest unoccupied molecular orbital (LUMO) of the compound, resulting in smoother HOMO-LUMO transitions. Therefore, material stability and luminescence characteristics of the fused polycyclic compound may be improved.

The fused polycyclic compound according to one or more embodiments includes one first fused ring, and at least one second fused ring. Any one among the first fused ring and the second fused ring has characteristics of an electron donor, and the other has characteristics of an electron acceptor. In one or more embodiments, a fused ring acting as the electron donor, among the first fused ring and the second fused ring, includes (e.g., contains) at least one nitrogen atom. The fused ring acting as the electron donor may include (e.g., contain) more nitrogen atoms than the fused ring acting as the electron acceptor. Because the fused polycyclic compound according to one or more embodiments includes (e.g., contains) the first fused ring and the second fused ring respectively acting as an electron donor and an electron acceptor in the molecular structure, and thus the intramolecular charge transfer (CT) structure is formed. Therefore, the fused polycyclic compound according to one or more embodiments may have a excellent or suitable multi-resonance structure. As a result, the fused polycyclic compound according to one or more embodiments may have improved material stability and luminous characteristics, and may contribute to improvements in high efficiency and long lifespan of the light-emitting element ED.

In one or more embodiments, in the fused polycyclic compound according to one or more embodiments, the second fused ring is connected to a (1-1)-th aromatic ring or a (2-1)-th aromatic ring of the first fused ring. Because the second fused ring is connected to a (1-1)-th aromatic ring or a (2-1)-th aromatic ring of the first fused ring, the intramolecular charge transfer (CT) structure is formed, and thus the fused polycyclic compound according to one or more embodiments may have an excellent or suitable multi-resonance structure.

The fused polycyclic compound according to one or more embodiments represented by Formula 1 exhibits an emission spectrum having a full width at half maximum of about 10 nanometer (nm) to about 50 nm, e.g., a full width at half maximum of about 20 nm to about 40 nm. Because the emission spectrum of the first dopant according to one or more embodiments has the full width at half maximum in the herein-described range, luminous efficiency may be improved if (e.g., when) the fused polycyclic compound according to one or more embodiments is applied to the element. In some embodiments, the fused polycyclic compound according to one or more embodiments is used as a blue emission material for a light-emitting element, the light-emitting element may have an improved element lifespan.

In one or more embodiments, the fused polycyclic compound according to one or more embodiments represented by Formula 1 may be a thermally activated delayed fluorescence emission material. In some embodiments, the fused polycyclic compound according to one or more embodiments represented by Formula 1 may be a thermally activated delayed fluorescence emission material, which has a difference (ΔE_{ST}) between a lowest triplet excited energy level (T1) and a lowest singlet excited energy level (S1) of at most about 0.6 electron volt (eV) (e.g., or less). The fused polycyclic compound according to one or more embodiments represented by Formula may be a thermally activated delayed fluorescence dopant, which has a difference (ΔE_{ST}) between a lowest triplet excited energy level (T1) and a lowest singlet excited energy level (S1) of at most about 0.2 eV (e.g., or less). However, one or more embodiments of the disclosure is not limited thereto.

In one or more embodiments, the fused polycyclic compound according to one or more embodiments represented by Formula 1 may include a first fused ring and a second fused ring within the compound. By adjusting a fused structure and substitution position of the first fused ring and the second fused ring, a singlet energy level and a triplet energy level of the compound may be appropriately or suitably adjusted overall. Through this, the fused polycyclic compound according to one or more embodiments of the disclosure may exhibit improved thermally activated delayed fluorescence characteristics.

The fused polycyclic compound according to one or more embodiments represented by Formula 1 may be an emission material with an emission peak wavelength in a region of about 430 nm to about 490 nm. For example, the fused polycyclic compound according to one or more embodiments represented by Formula may be a blue thermally activated delayed fluorescence (TADF) dopant. However, one or more embodiments of the disclosure is not limited thereto, and if (e.g., when) the fused polycyclic compound according to one or more embodiments is used as an emission material, a first dopant may be used as a dopant material that emits light in a one or more suitable wavelength region such as red emission dopant, and green emission dopant.

In the light-emitting element ED according to one or more embodiments, the emission layer EML may be to emit delayed fluorescence. For example, the emission layer EML may be to emit thermally activated delayed fluorescence (TADF).

In some embodiments, the emission layer EML may be to emit blue light. For example, the emission layer EML of the organic light-emitting element ED according to one or more embodiments may be to emit blue light in a wavelength region of at most about 490 nm (e.g., or less). However, one or more embodiments of the disclosure is not limited thereto, and the emission layer EML may be to emit green light or red light.

In one or more embodiments, the fused polycyclic compound according to one or more embodiments may be included (e.g., contained) in the emission layer EML. The fused polycyclic compound according to one or more embodiments may be included (e.g., contained) in the emission layer EML as a dopant material. The fused polycyclic compound according to one or more embodiments may be a thermally activated delayed fluorescence emission material. The fused polycyclic compound according to one or more embodiments may be used as a thermally activated delayed fluorescence dopant. For example, the emission layer EML in the light-emitting element ED according to one or more embodiments may include (e.g., contain) at least one among the fused polycyclic compounds present in Compound Group 1, described previously. However, the use of the fused polycyclic compound according to one or more embodiments is not limited thereto.

In one or more embodiments, the light emitting layer EML may include a plurality of compounds. The light emitting layer EML of one or more embodiments includes a condensed polycyclic compound represented by Chemical Formula 1, that is, a first compound, in addition, a second compound represented by Chemical Formula HT-1, a third compound represented by Chemical Formula ET-1, And it may include at least one of a fourth compound represented by Formula D-1.

In one or more embodiments, the emission layer EML may include the first compound represented by Formula 1, and may further include at least one of the first compound represented by Formula 1, the second compound represented by Formula HT-1, the third compound represented by Formula ET-1, or the fourth compound represented by Formula D-1.

In one or more embodiments, the second compound may be used as a hole transporting host material of the emission layer EML.

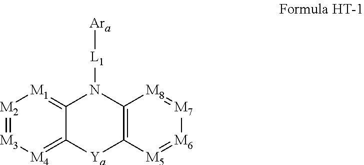

In Formula HT-1, M₁ to M₈ may each independently be N or CR₅₁. For example, all of M₁ to M₈ may be CR₅₁. In one or more embodiments, any one among M₁ to M₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, and/or the like, but one or more embodiments of the disclosure is not limited thereto.

In Formula HT-1, Yₐ may be a direct linkage, CR₅₂R₅₃, or SiR₅₄R₅₅. For example, it may refer to that the two benzene rings linked to the nitrogen atom in Formula HT-1 are linked via a direct linkage,

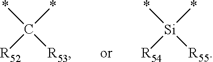

In Formula HT-1, if (e.g., when) Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but one or more embodiments of the disclosure is not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, each of R₅₁ to R₅₅ may be bonded to an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by any one among (e.g., selected from among) the compounds represented by Compound Group 2. The emission layer EML may include at least one among (e.g., selected from among) the compounds represented by Compound Group 2 as a hole transporting host material.

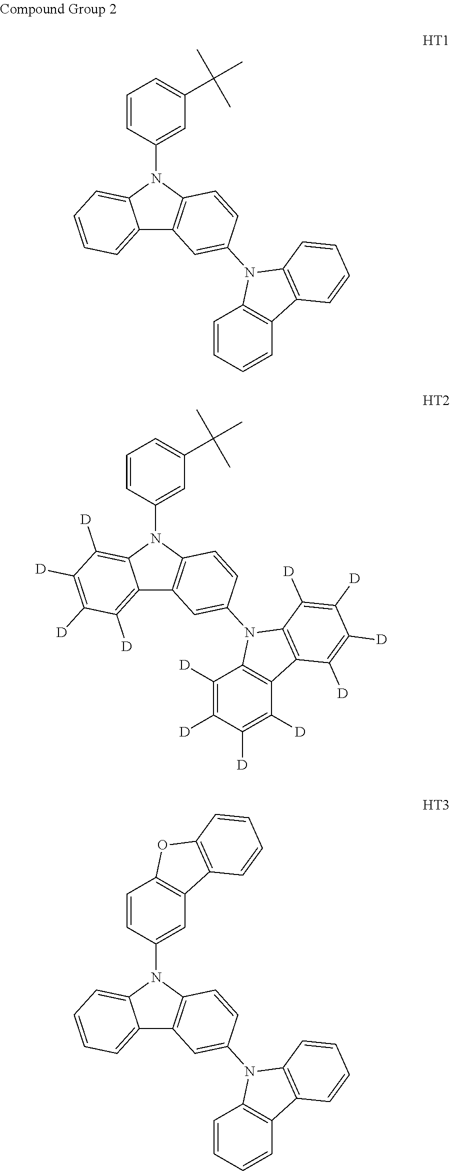 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

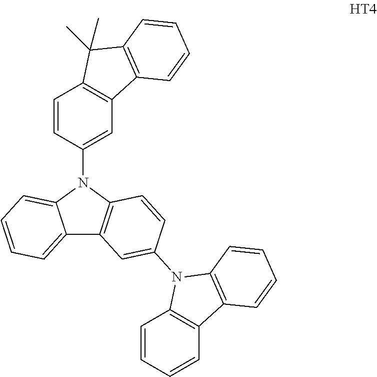 [SMILES: CC1(C)c2ccccc2-c2cc(-n3c4ccccc4c4cc(-n5c6ccccc6c6ccccc65)ccc43)ccc21]

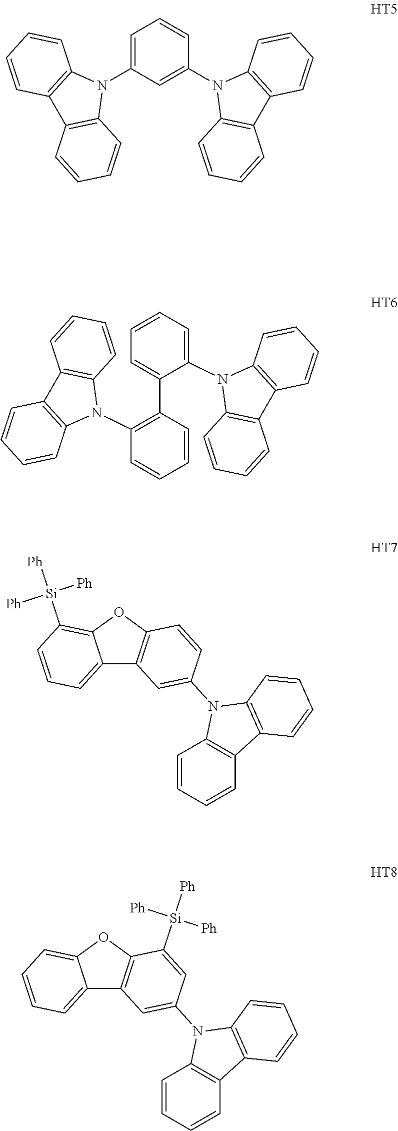 [SMILES: c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

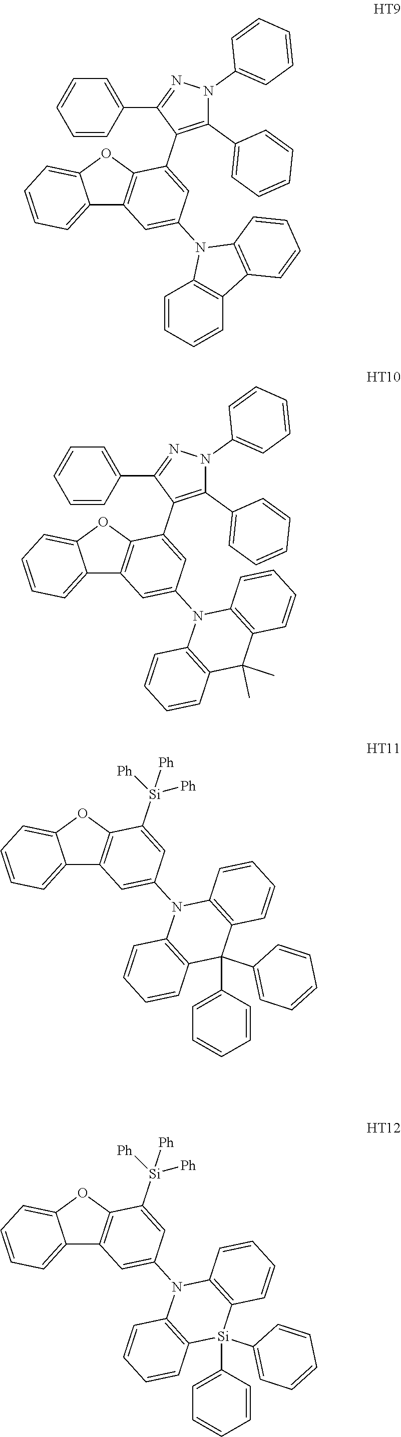 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

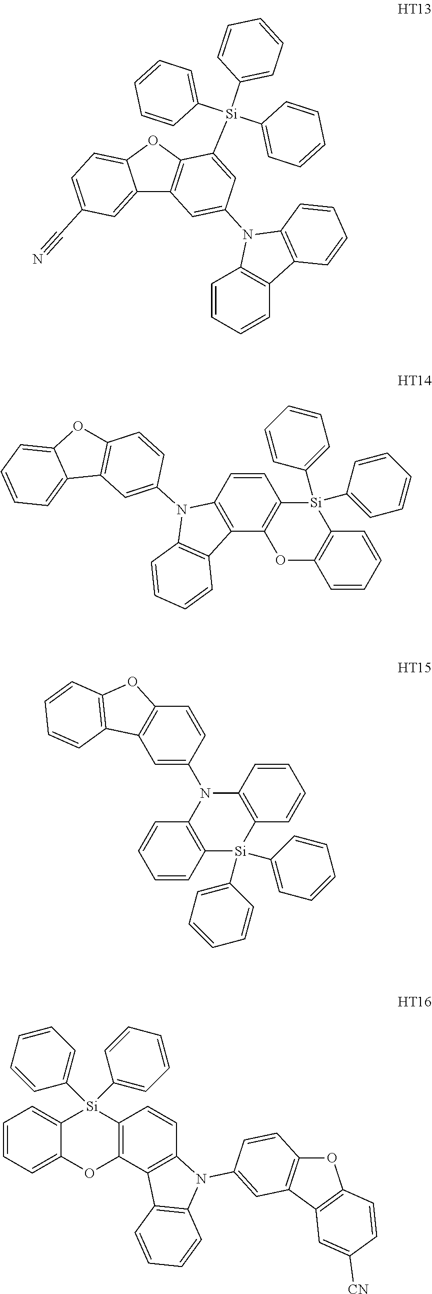 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

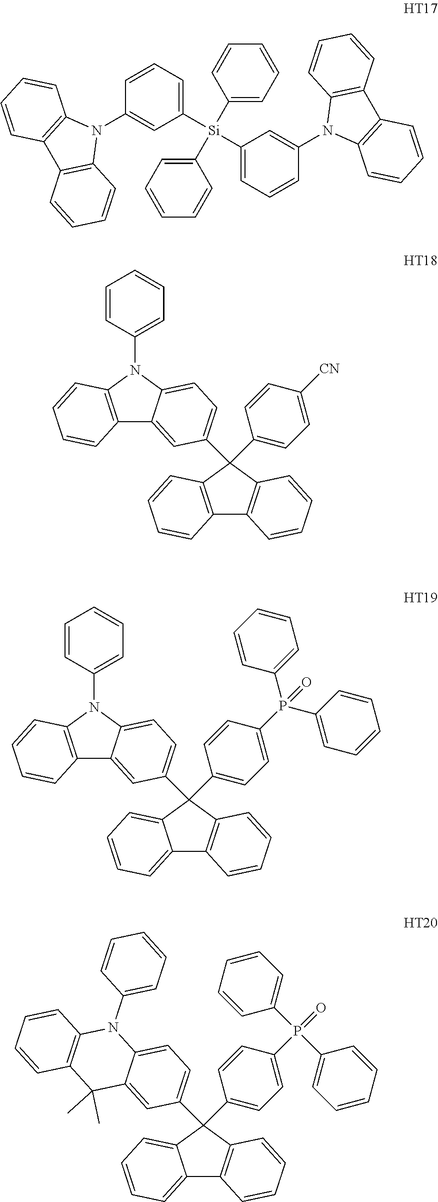 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

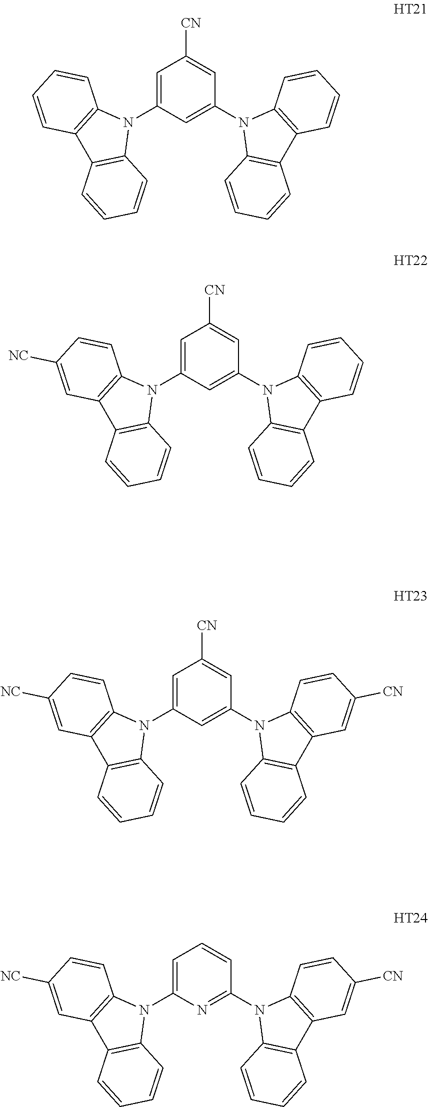 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

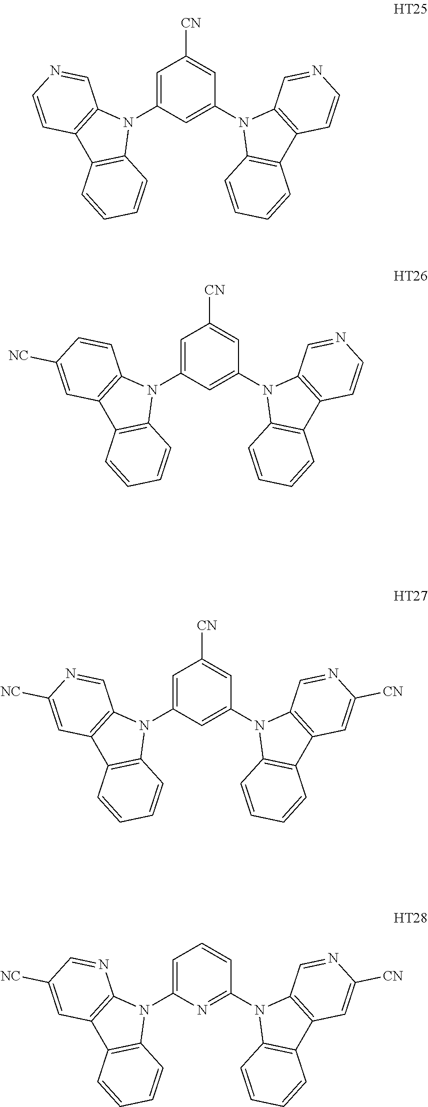 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cnc2c(c1)c1ccccc1n2-c1cccc(-n2c3ccccc3c3cc(C#N)ncc32)n1]

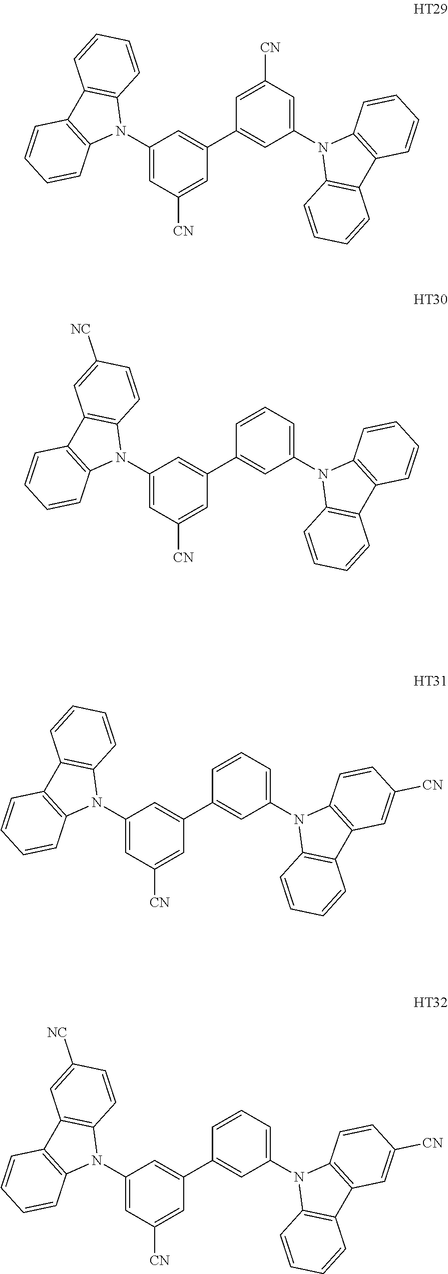 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

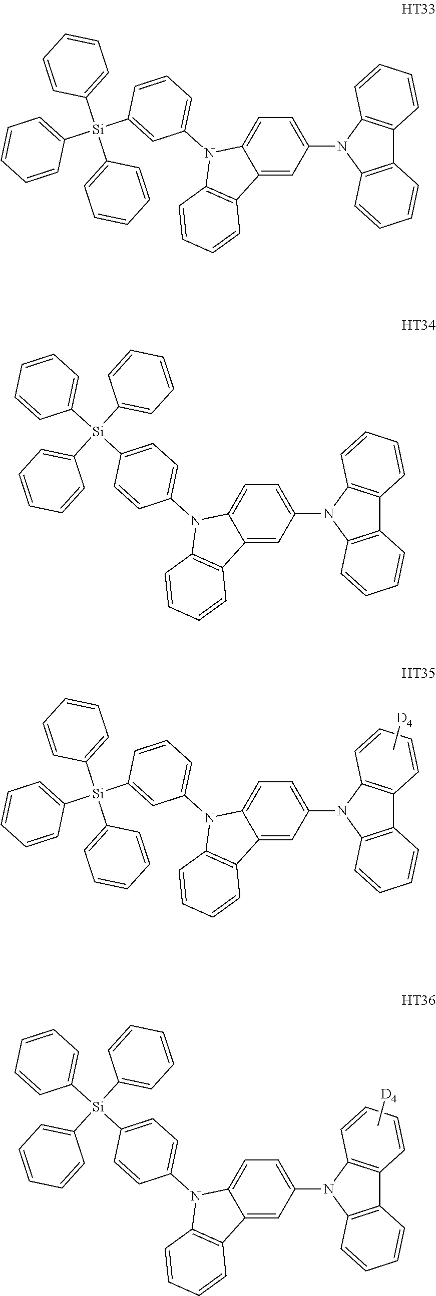

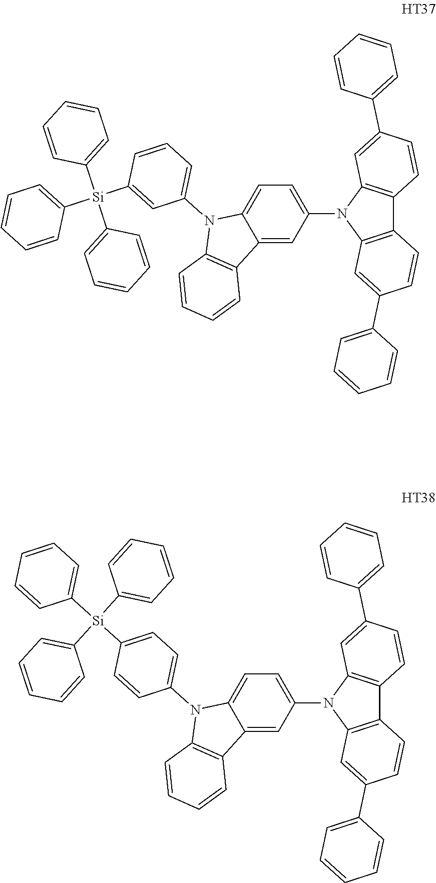 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

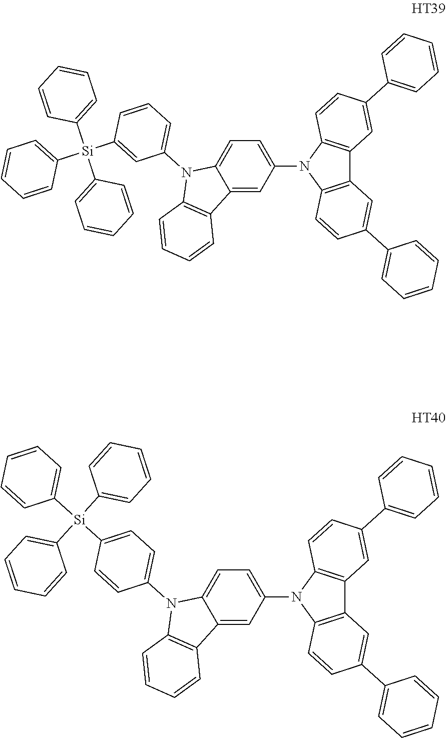 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

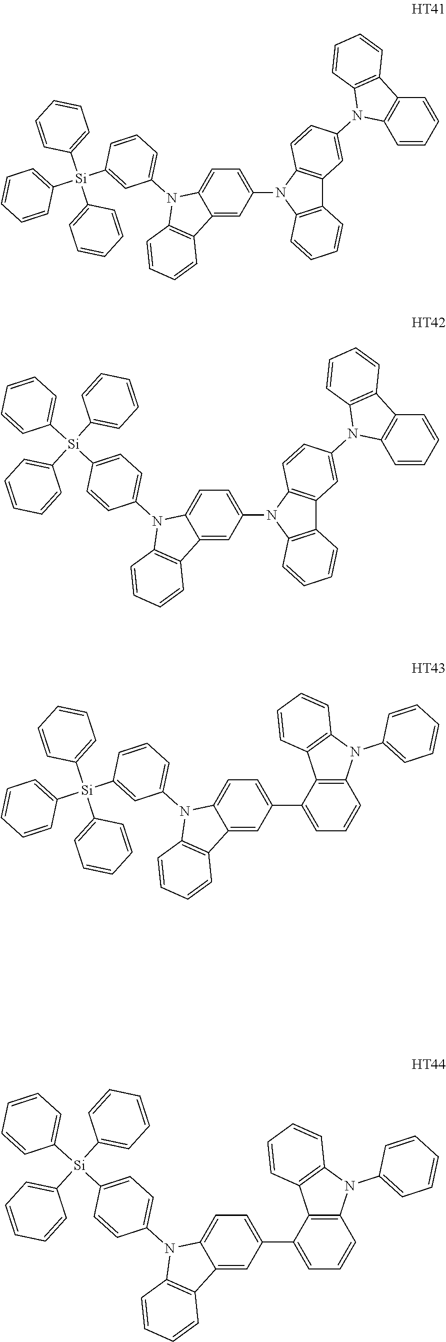 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

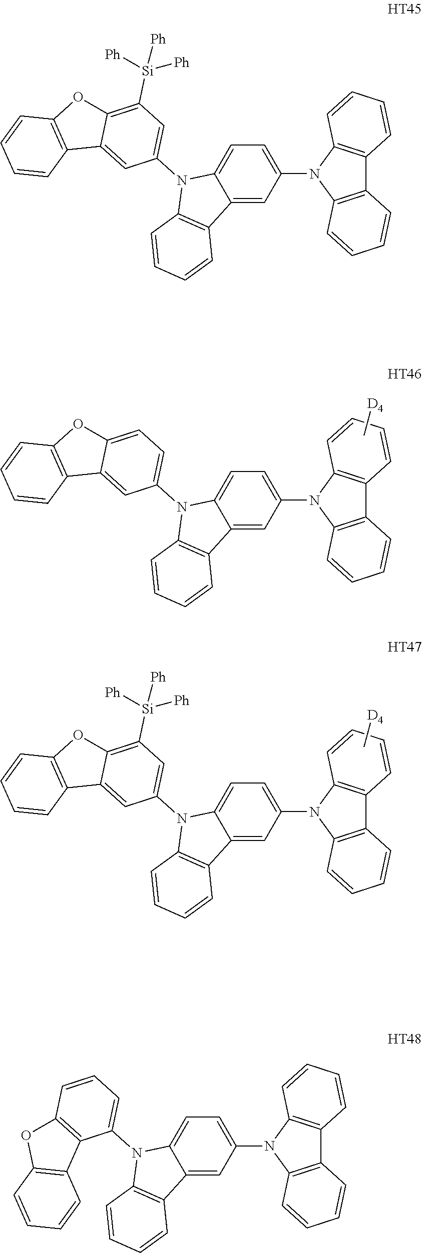

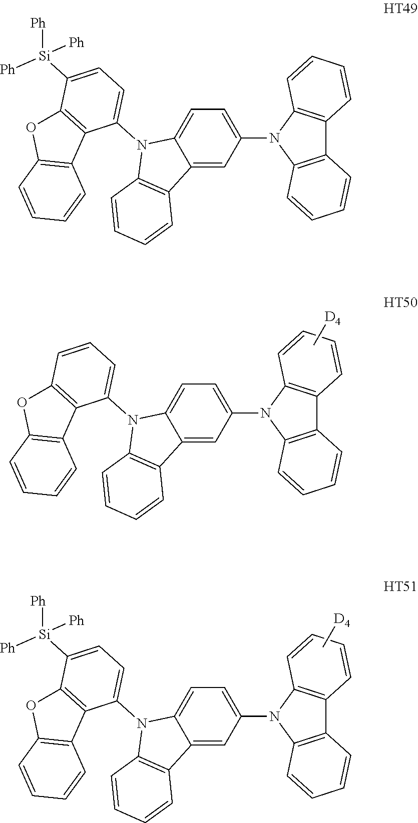

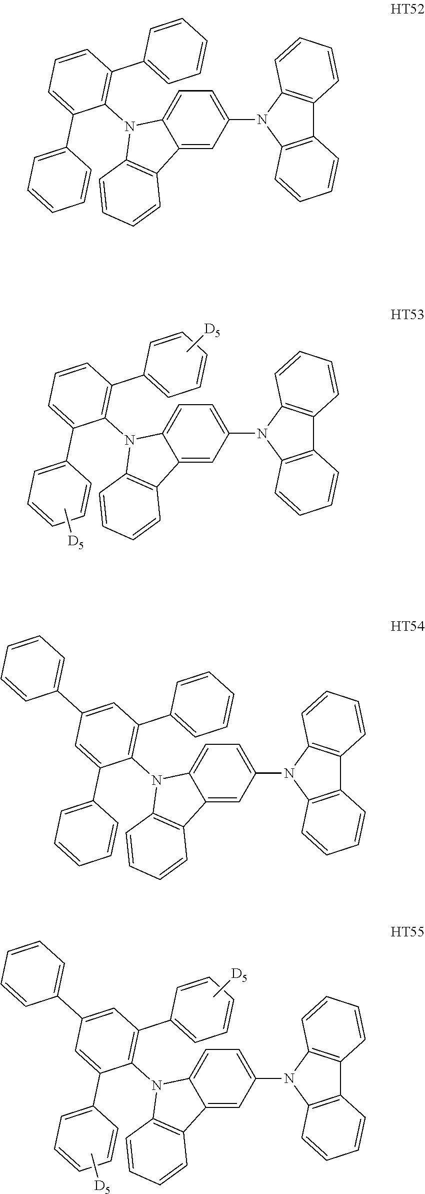

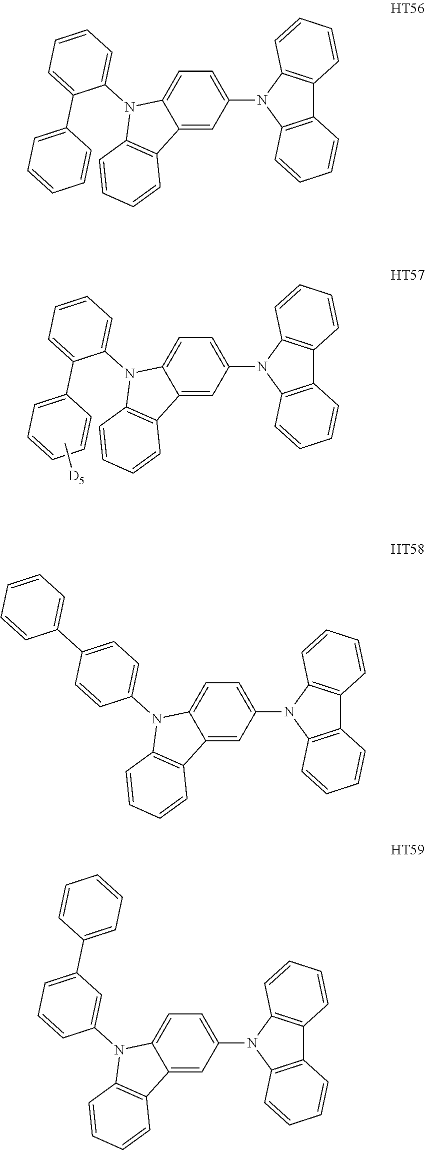

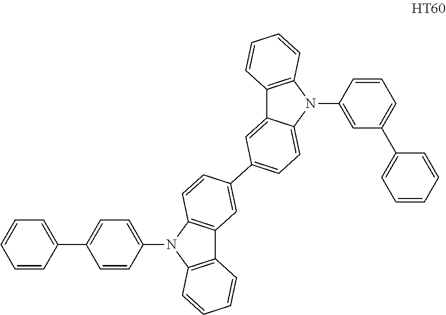 [SMILES: c1ccc(-c2ccc(-n3c4ccccc4c4cc(-c5ccc6c(c5)c5ccccc5n6-c5cccc(-c6ccccc6)c5)ccc43)cc2)cc1]

In embodiment compounds presented in Compound Group 2, “D” may refer to a deuterium atom, and “Ph” may refer to a substituted or unsubstituted phenyl group. For example, in embodiment compounds presented in Compound Group 2, “Ph” may refer to an unsubstituted phenyl group.

In one or more embodiments, the emission layer EML may include the third compound represented by Formula ET-1. For example, the third compound may be used as an electron transport host material for the emission layer EML.

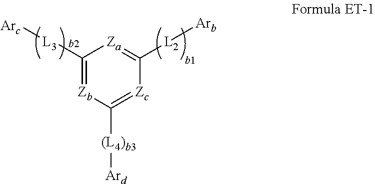

In Formula ET-1, at least one among Zₐ to Z_{c} is N, and the rest are CR₅₆. For example, any one among Zₐ to Z_{c} may be N, and the rest may each independently be CR₅₆. In this case, the third compound represented by Formula ET-1 may include a pyridine moiety. In one or more embodiments, two among Zₐ to Z_{c} may be N, and the rest may be CR₅₆. In this case, the third compound represented by Formula ET-1 may include a pyrimidine moiety. In one or more embodiments, Zₐ to Z_{c} may all be N. In this case, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar_{b} to Ar_{d} may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar_{b} to Ar_{d} may each independently be a substituted or unsubstituted phenyl group, or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) b1 to b3 are integers of 2 or greater, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In one or more embodiments, the third compound may be represented by any one among (e.g., selected from among) Compounds in Compound Group 3. The light emitting device ED of one or more embodiments may include any one among (e.g., selected from among) the compounds in Compound Group 3.

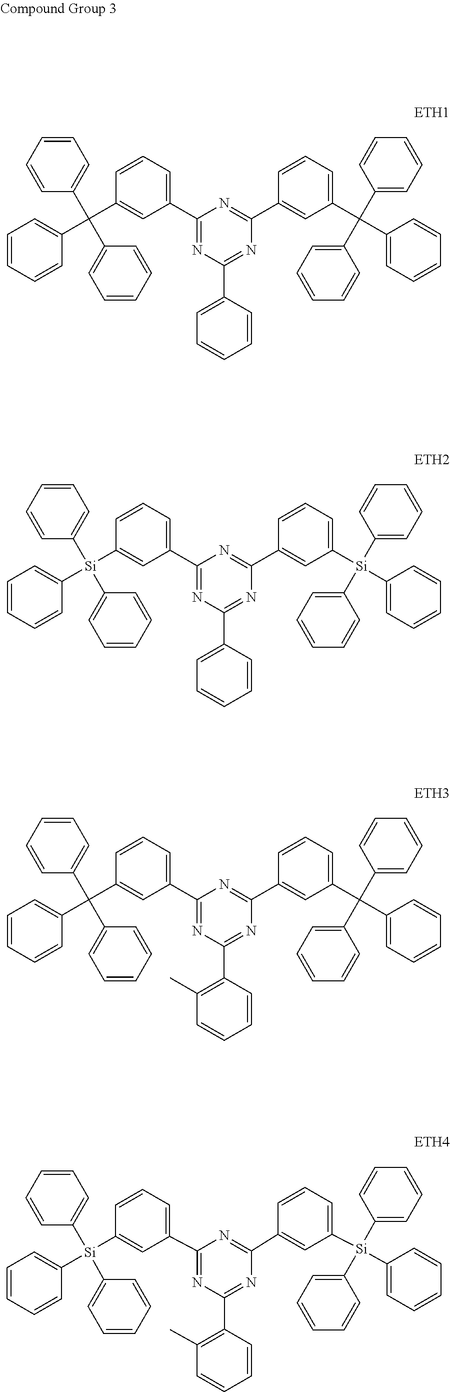 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

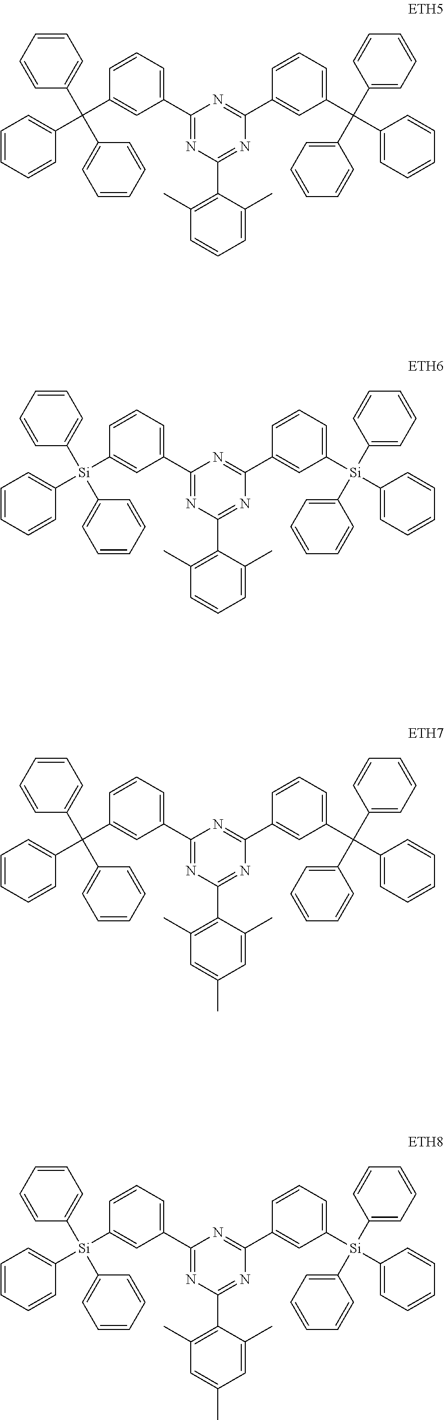 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

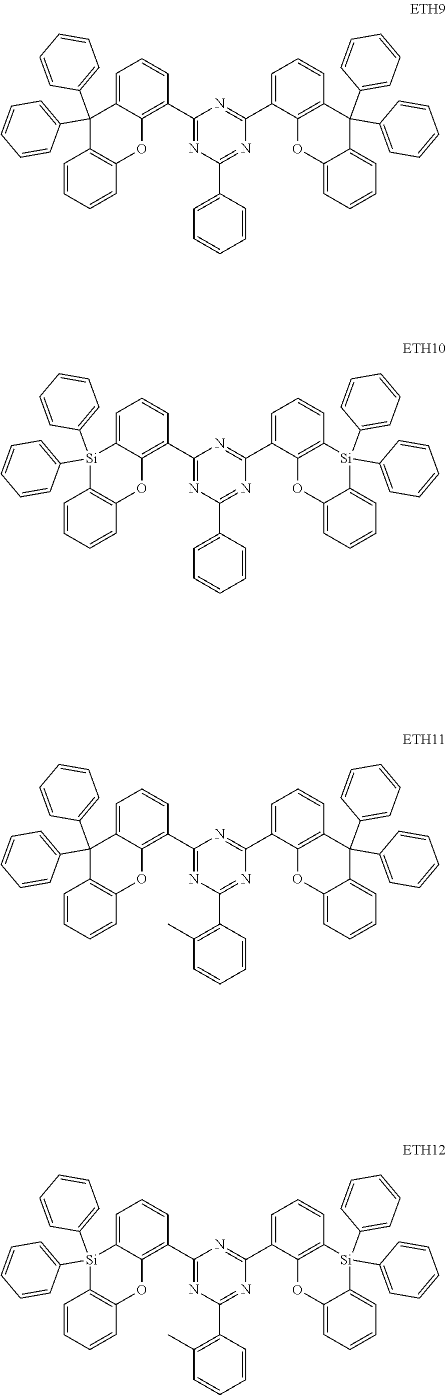 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

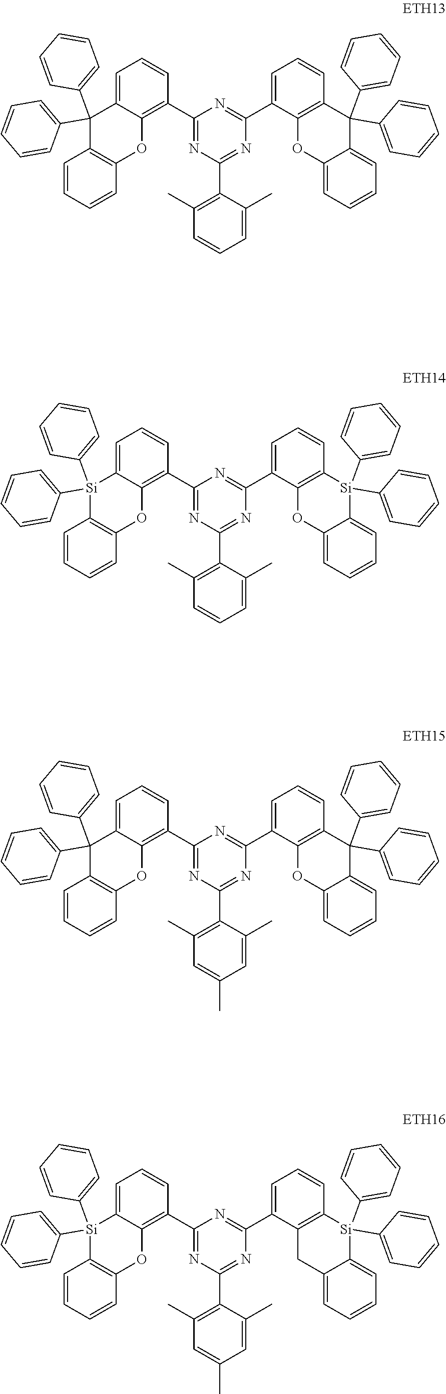 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Cc3ccccc3[Si]4(c3ccccc3)c3ccccc3)nc(-c3cccc4c3Oc3ccccc3[Si]4(c3ccccc3)c3ccccc3)n2)c(C)c1]

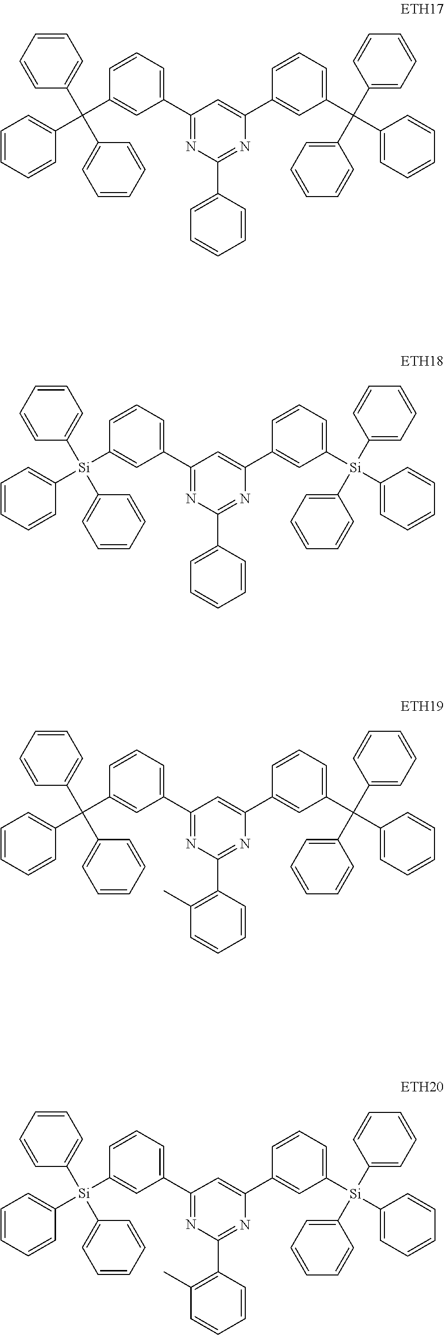 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

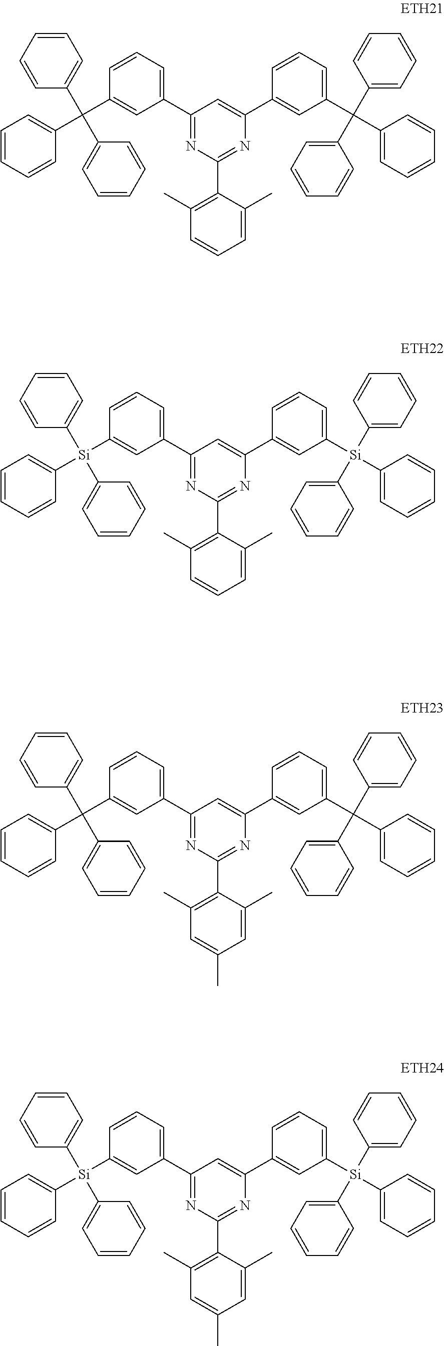 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

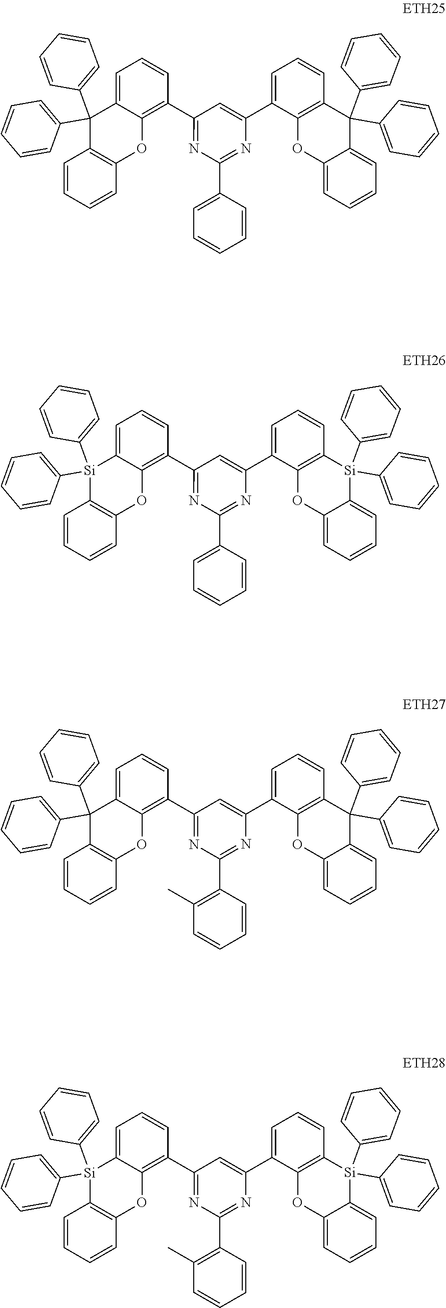 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

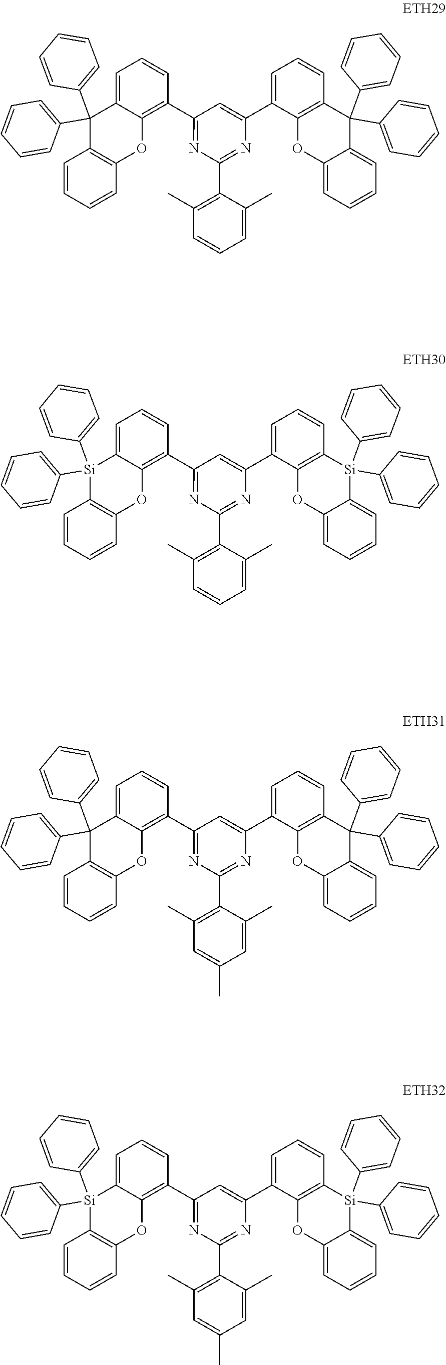 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

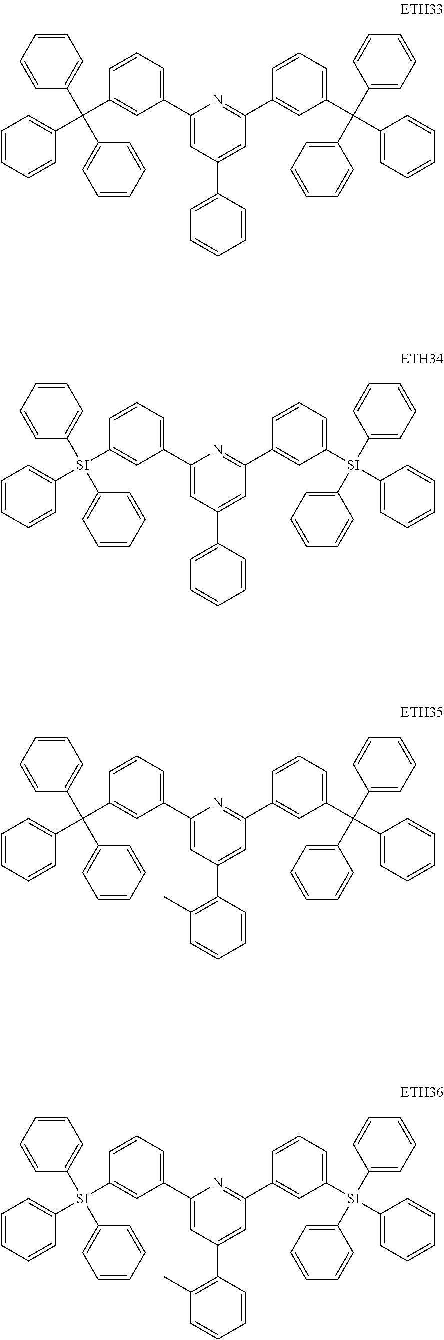

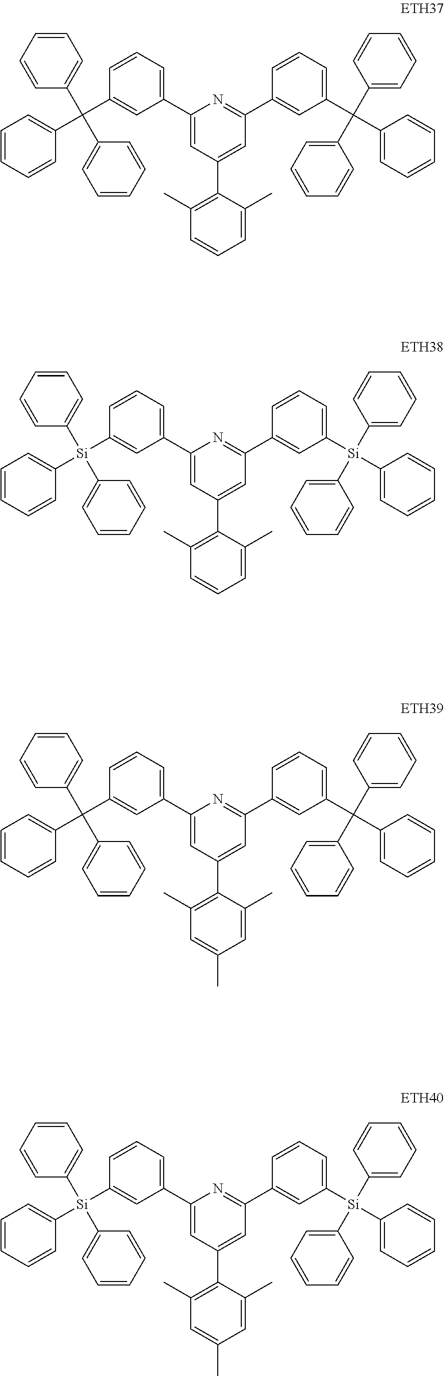 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

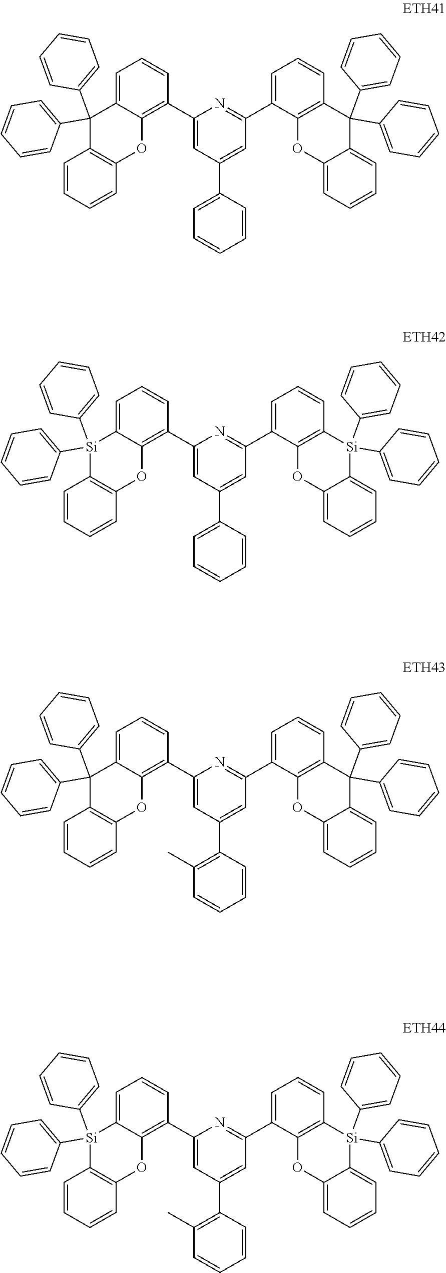 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

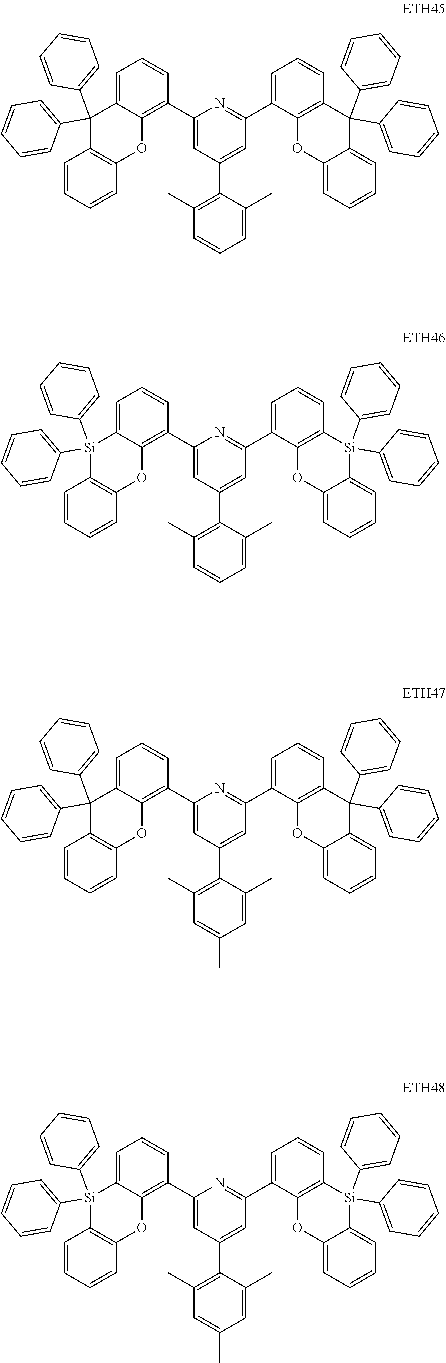 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

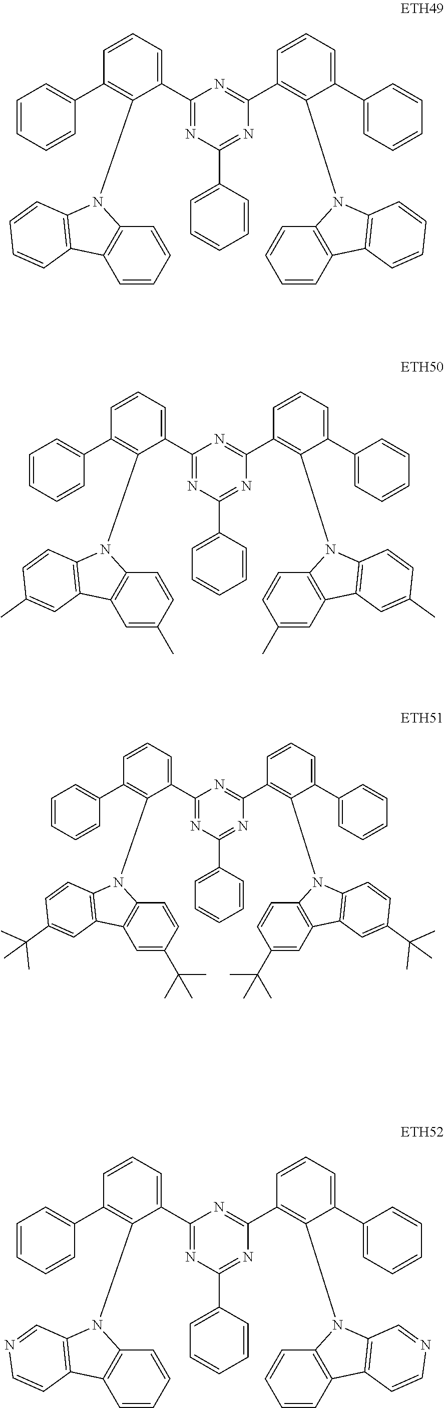

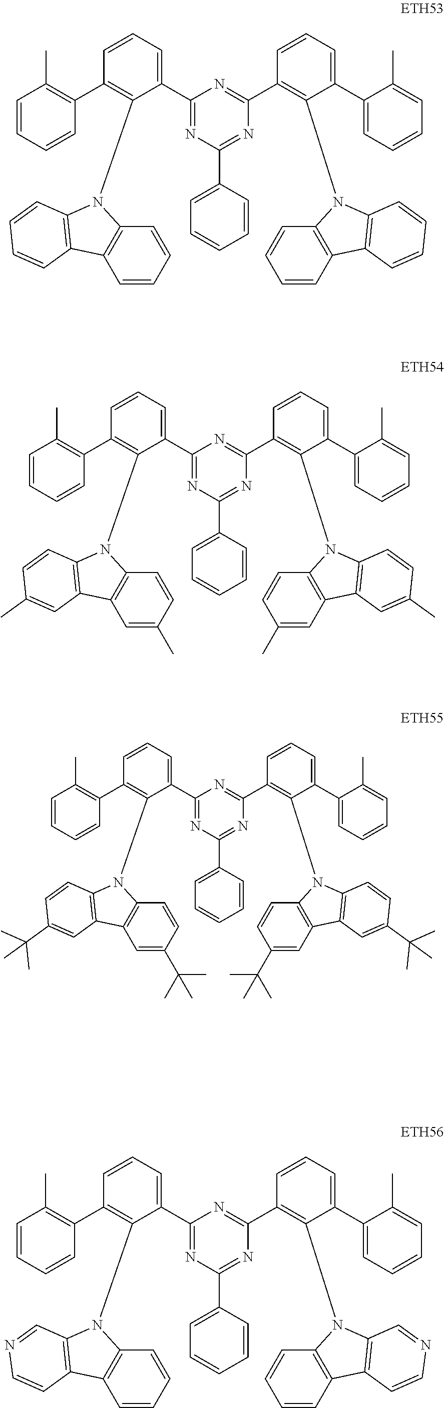

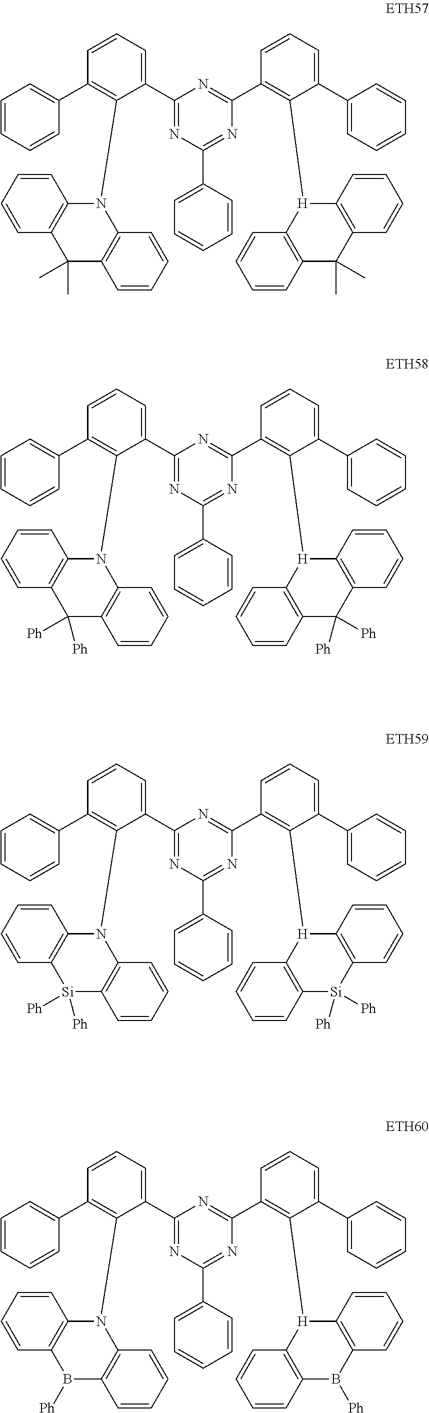

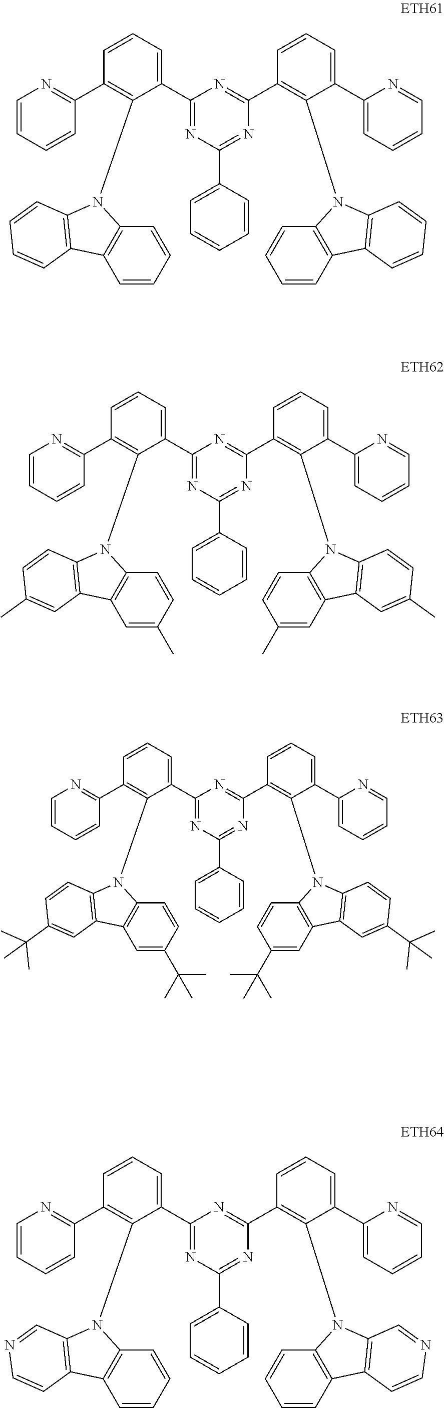

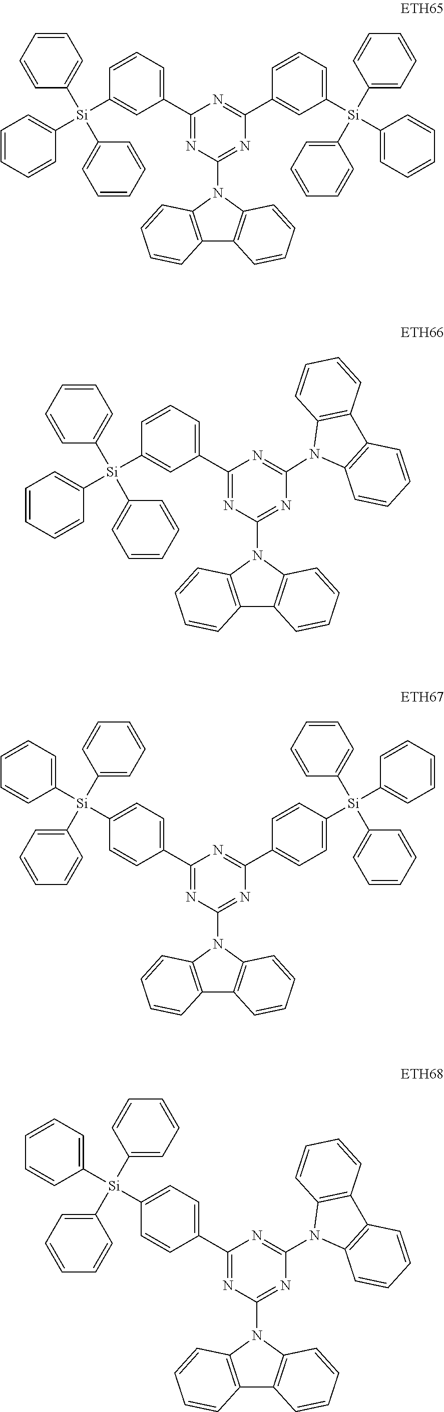 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

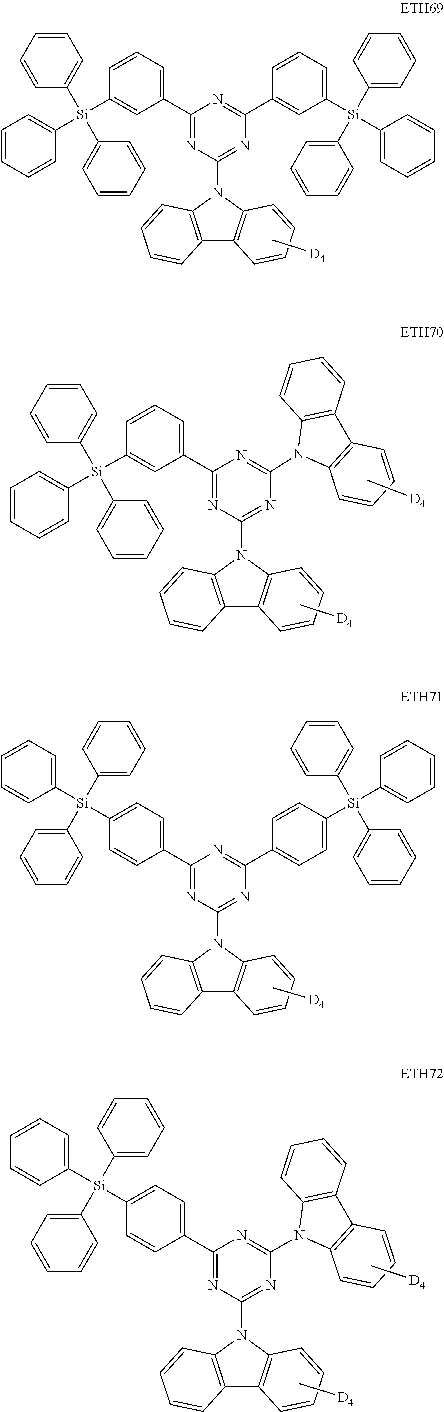

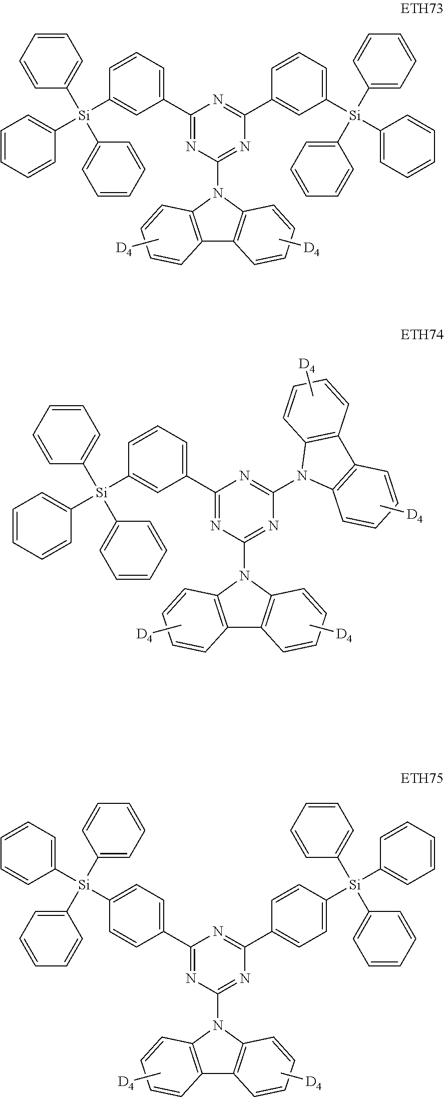

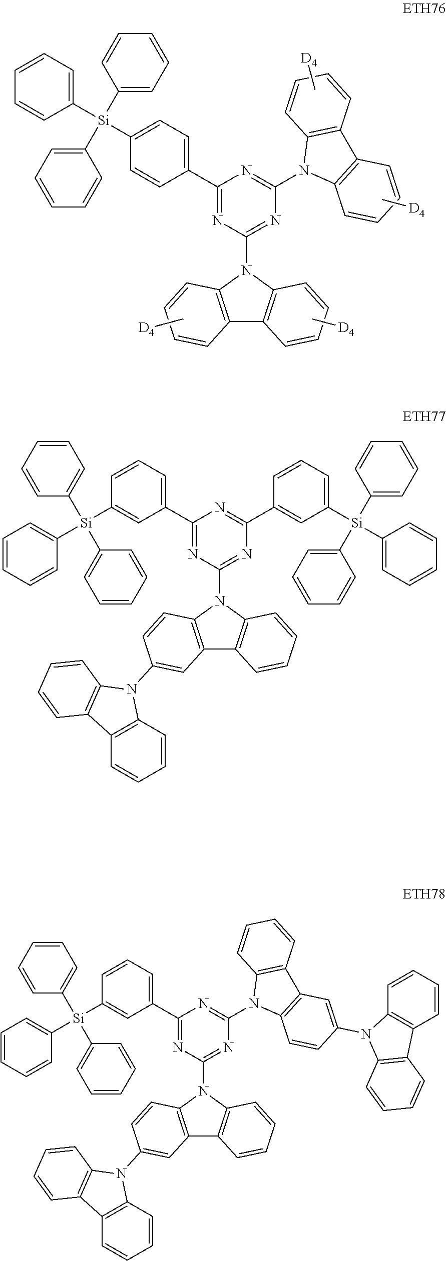

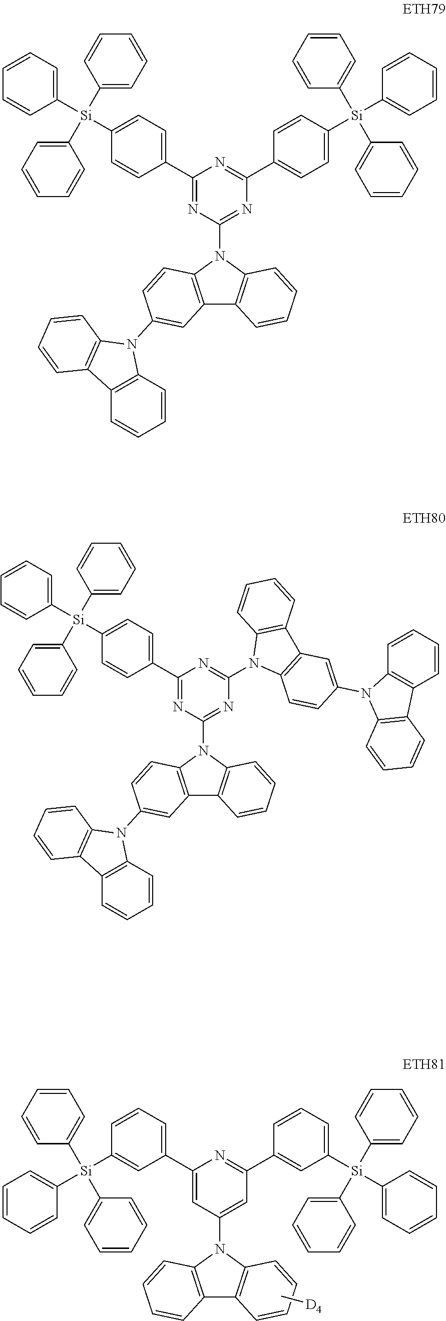

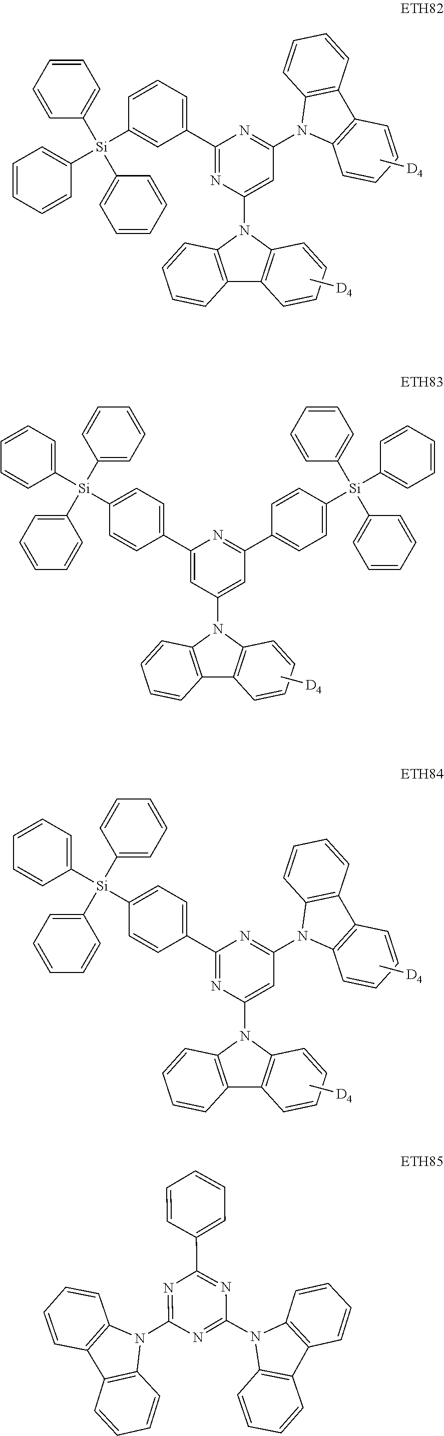

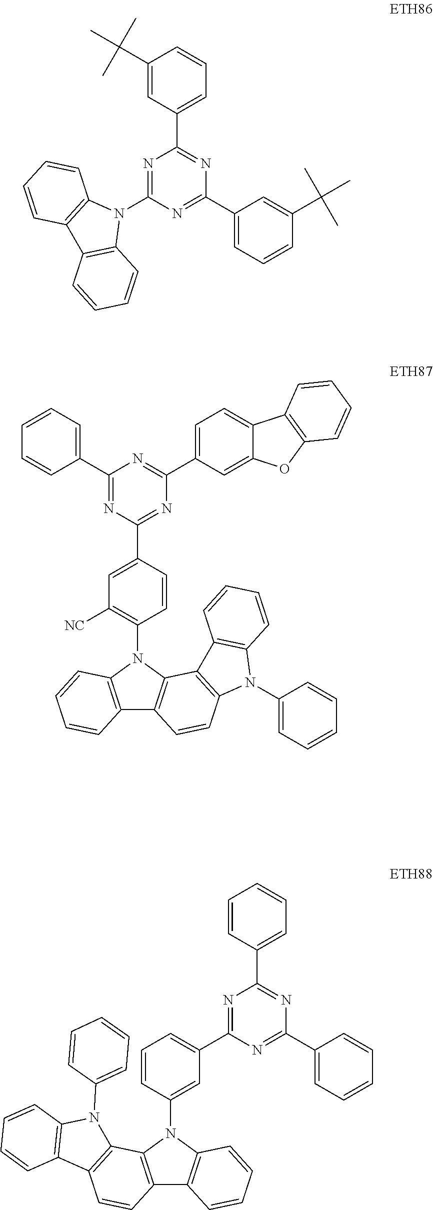 [SMILES: CC(C)(C)c1cccc(-c2nc(-c3cccc(C(C)(C)C)c3)nc(-n3c4ccccc4c4ccccc43)n2)c1 ; N#Cc1cc(-c2nc(-c3ccccc3)nc(-c3ccc4c(c3)oc3ccccc34)n2)ccc1-n1c2ccccc2c2ccc3c(c4ccccc4n3-c3ccccc3)c21 ; c1ccc(-c2nc(-c3ccccc3)nc(-c3cccc(-n4c5ccccc5c5ccc6c7ccccc7n(-c7ccccc7)c6c54)c3)n2)cc1]

In one or more embodiments compounds presented in Compound Group 3, “D” refers to a deuterium atom and “Ph” refers to an unsubstituted phenyl group.

The emission layer EML may include the second compound and the third compound, and the second compound and the third compound may form an exciplex. In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 eV to about 3.0 eV. In some embodiments, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound as described. The fourth compound may be used as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light emitting device ED of one or more embodiments may include, as the fourth compound, a compound represented by Formula D-1:

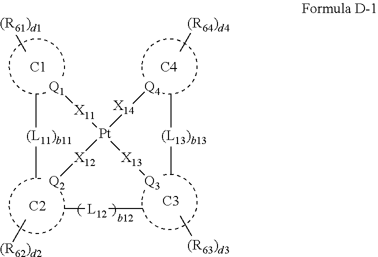

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

X₁₁ to X₁₄ may each independently be a direct bond or

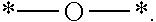

For example, any one of X₁₁ to X₁₄ may be

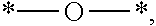

and the others may be direct bonds.

In Formula D-1, L₁₁ to L₁₃ may each independently be a direct linkage,

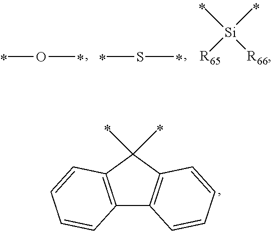

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃,

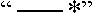

refers to a part linked to C1 to C4.

In Formula D-1, b11 to b13 may each independently be 0 or 1. If b11 is 0, C1 and C2 may not be linked to each other. If b12 is 0, C2 and C3 may not be linked to each other. If b13 is 0, C3 and C4 may not be linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, each of R₆₁ to R₆₆ may be bonded to an adjacent group to form a ring. R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, if each of d1 to d4 is 0, the fourth compound may not be substituted with each of R₆₁ to R₆₄. The case where each of d1 to d4 is 4 and R₆₁'s to R₆₄' are each hydrogen atoms may be the same as the case where each of d1 to d4 is 0. When each of d1 to d4 is an integer of 2 or more, a plurality of R₆₁'s to R₆₄'s may each be the same or at least one among the plurality of R₆₁'s to R₆₄'s may be different from the others.

In Formula D-1, C1 to C4 may each independently be a substituted or unsubstituted hydrocarbon ring or a substituted or unsubstituted heterocycle represented by any one among C-1 to C-5:

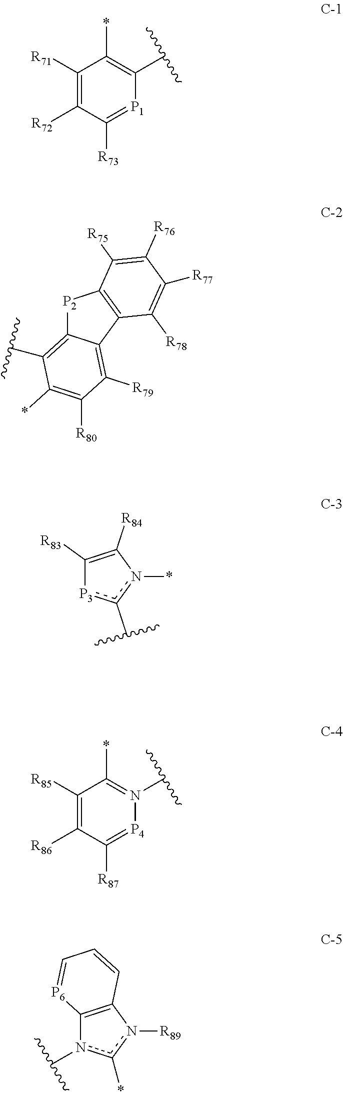

In C-1 to 0-4, P₁ may be

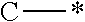 [SMILES: *C]

or CR₇₄, P₂ may be

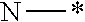 [SMILES: *N]

or NR₈₁, P₃ may be

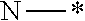 [SMILES: *N]

or NR₈₂, and P₄ may be

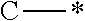 [SMILES: *C]

or CR₈₈, and P₅ may be

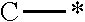 [SMILES: *C]

or CR₉₀. R₇₁ to R₉₀ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In some embodiments, in C-1 to C-5,

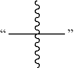

corresponds to a part linked to Pt that is a central metal atom, and

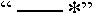

corresponds to a part linked to a neighboring cyclic group (C1 to C4) or a linker (L₁₁ to L₁₃).

The emission layer EML of one or more embodiments may include the first compound, which is a fused polycyclic compound, and at least one of (e.g., selected from among) the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In some embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light emitting device ED of one or more embodiments may serve as a sensitizer to deliver energy from the host to the first compound that is a light emitting dopant. For example, the fourth compound serving as an auxiliary dopant accelerates energy delivery to the first compound that is a light emitting dopant, thereby increasing the emission ratio of the first compound. Therefore, the emission layer EML of one or more embodiments may improve luminous efficiency. In some embodiments, if (e.g., when) the energy delivery to the first compound is increased, an exciton formed in the emission layer EML is not accumulated inside the emission layer EML and emits light rapidly, and thus deterioration of the device may be reduced. Therefore, the service life of the light emitting device ED of one or more embodiments may increase.

The light emitting device ED of one or more embodiments may include all of the first compound, the second compound, the third compound, and the fourth compound, and the emission layer EML may include the combination of two host materials and two dopant materials. In the light emitting device ED of one or more embodiments, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may represented at least one among (e.g., selected from among) the compounds represented by Compound Group 4. The emission layer EML may include at least one among (e.g., selected from among) the compounds represented by Compound Group 4 as a sensitizer material.

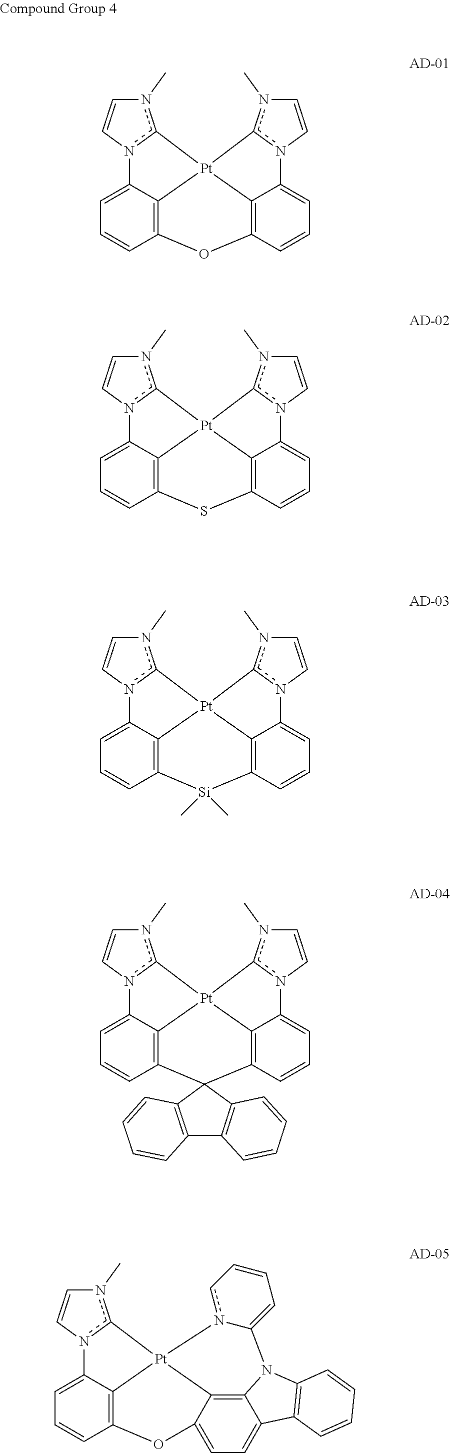

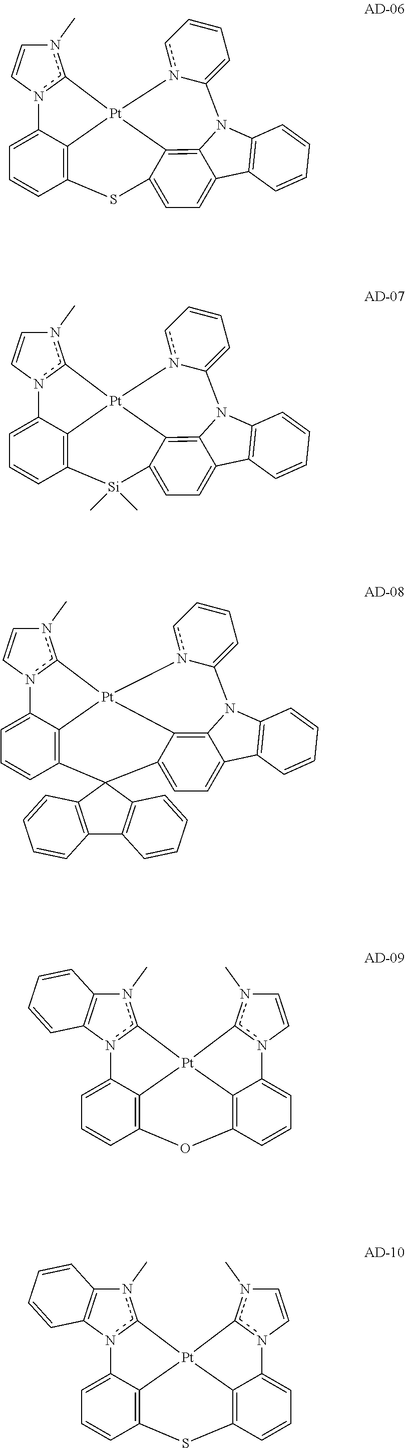

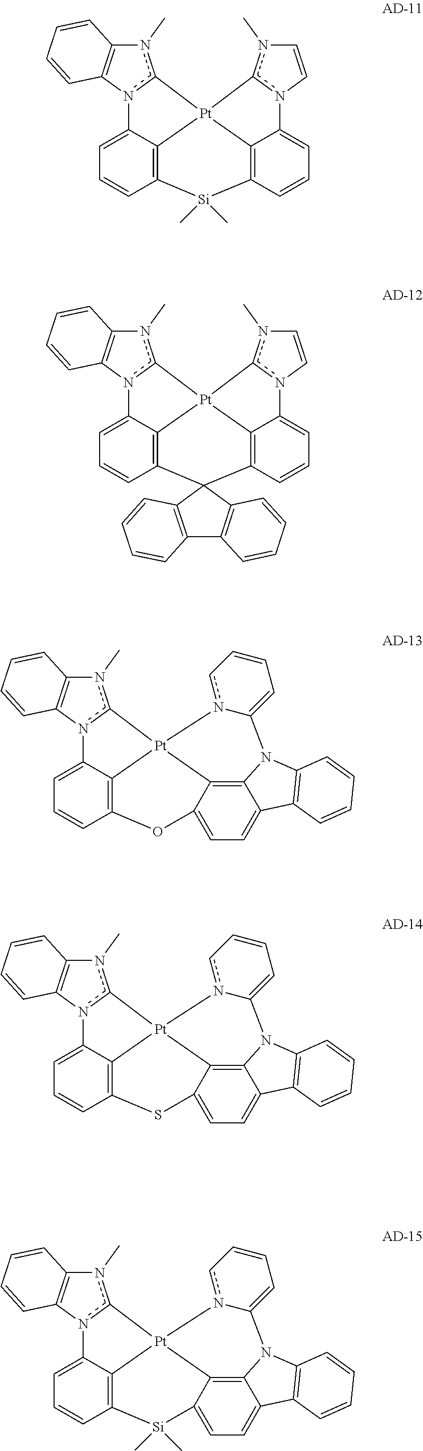

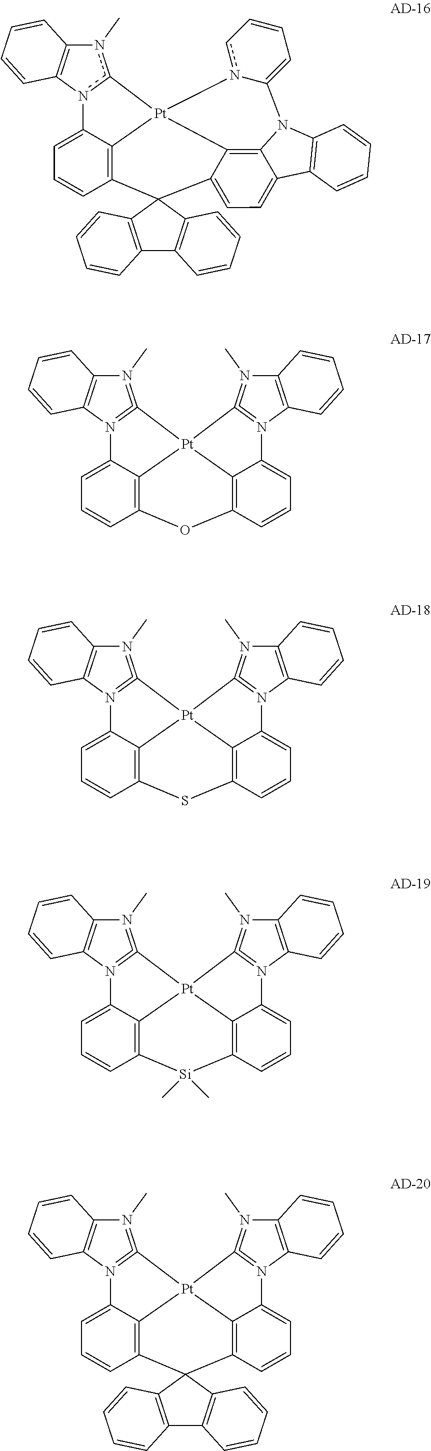

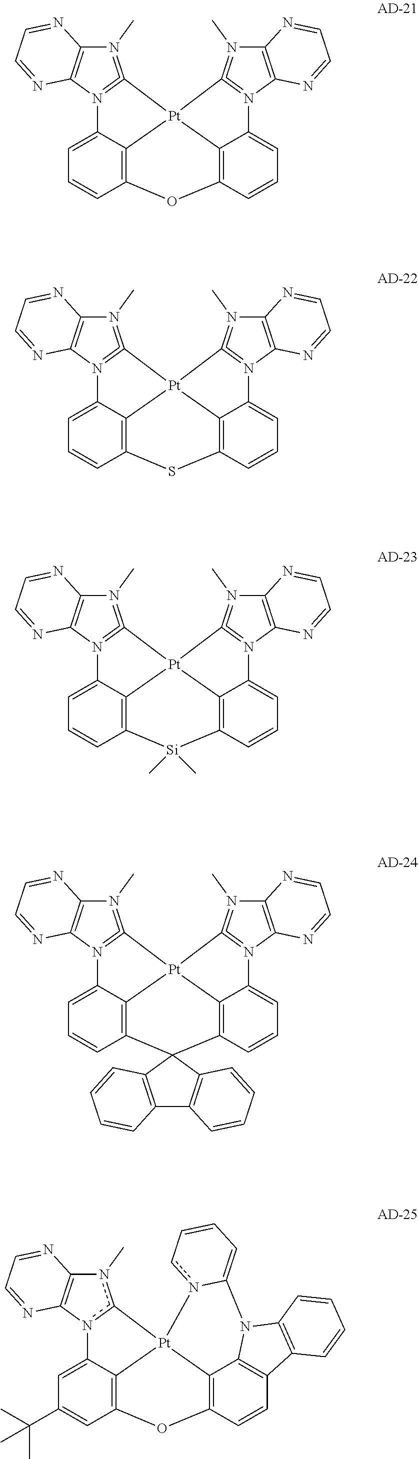

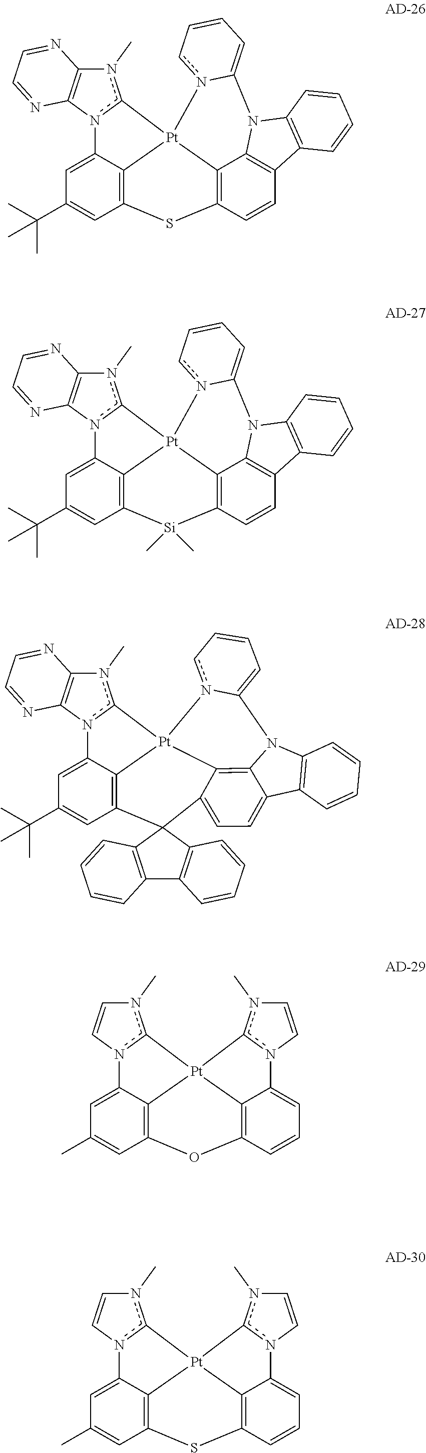

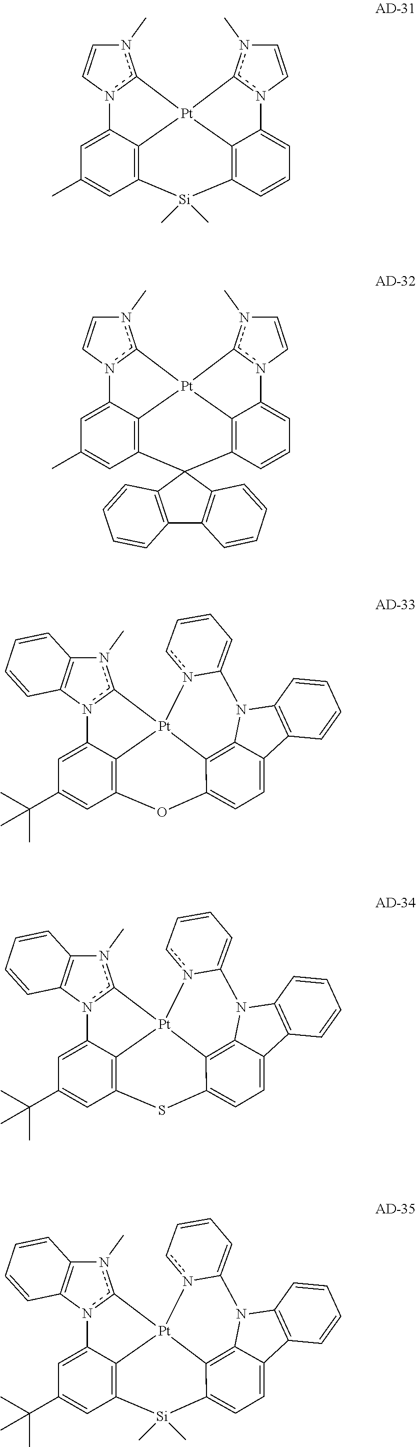

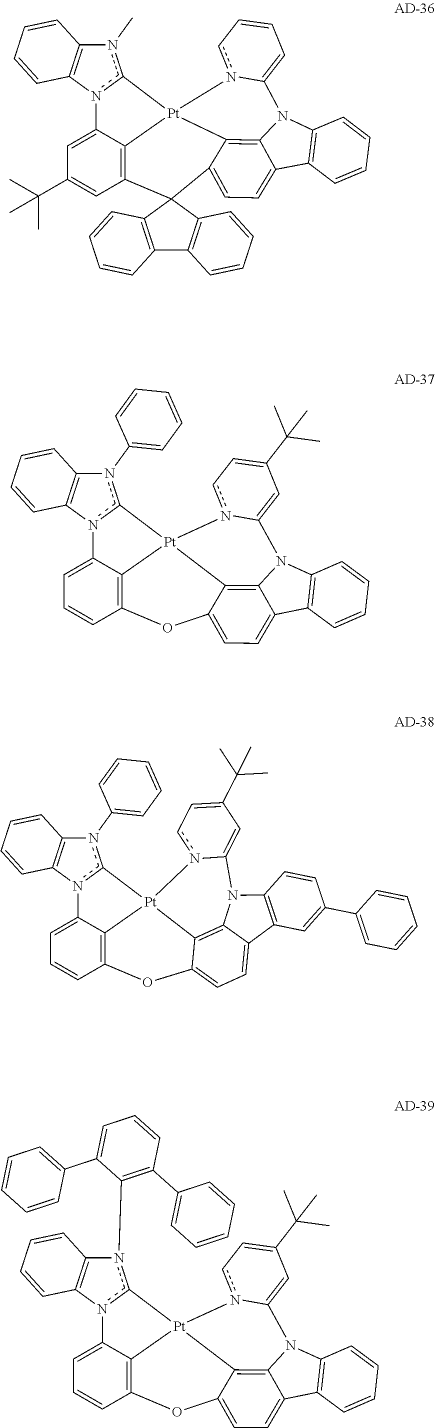

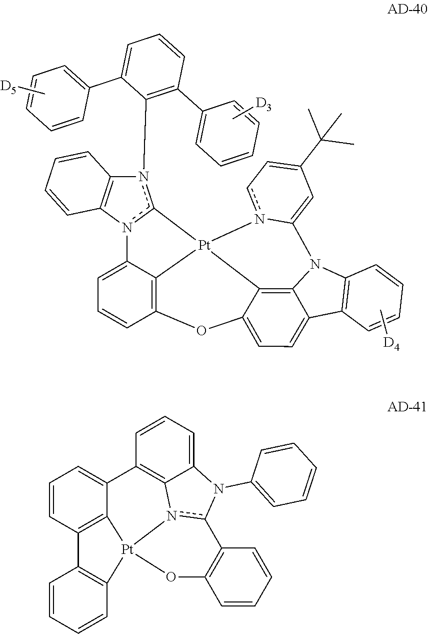

In one or more embodiments compounds presented in Compound Group 4, “D” refers to a deuterium atom.

When the emission layer EML in the light emitting device ED of one or more embodiments includes all of the first compound, the second compound, and the third compound, with respect to the total weight of the first compound, the second compound, and the third compound, the content (e.g., amount) of the first compound may be about 0.1 wt % to about 5 wt %. However, one or more embodiments of the disclosure is not limited thereto. When the content (e.g., amount) of the first compound satisfy the herein-described proportion, the energy transfer from the second compound and the third compound to the first compound may increase, and thus the luminous efficiency and device service life may increase.

The contents of the second compound and the third compound in the emission layer EML may be the rest excluding the weight of the first compound. For example, the contents of the second compound and the third compound in the emission layer EML may be about 65 wt % to about 95 wt % with respect to the total weight of the first compound, the second compound, and the third compound.

In the total weight of the second compound and the third compound, the weight ratio of the second compound and the third compound may be about 3:7 to about 7:3.

When the contents of the second compound and the third compound satisfy the herein-described ratio, a charge balance characteristic in the emission layer EML are improved, and thus the luminous efficiency and device service life may increase. When the contents of the second compound and the third compound deviate from the herein-described ratio range, a charge balance in the emission layer EML is broken, and thus the luminous efficiency may be reduced and the device may be easily deteriorated.

When the emission layer EML includes the fourth compound, the content (e.g., amount) of the fourth compound in the emission layer EML may be about 10 wt % to about 30 wt % with respect to the total weight of the first compound, the second compound, the third compound, and the fourth compound. However, one or more embodiments of the disclosure is not limited thereto. When the content (e.g., amount) of the fourth compound satisfies the herein-described content (e.g., amount), the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the herein-described content (e.g., amount) ratio range, excellent or suitable luminous efficiency and long service life may be achieved.

In the light emitting device ED of one or more embodiments, the emission layer EML may include an anthracene derivative, a pyrene derivative, a fluoranthene derivative, a chrysene derivative, a dihydrobenzanthracene derivative, or a triphenylene derivative. For example, the emission layer EML may include the anthracene derivative or the pyrene derivative.

In each light emitting device ED of embodiments illustrated in FIGS. 3 to 6, the emission layer EML may further include a suitable host and dopant besides the herein-described host and dopant, and for example the emission layer EML may include a compound represented by Formula E-1. The compound represented by Formula E-1 may be used as a fluorescent host material.

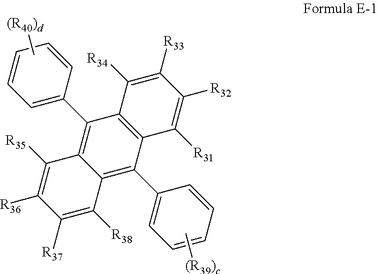

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In one or more embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

Formula E-1 may be represented by any one among (e.g., selected from among) Compound E1 to Compound E19:

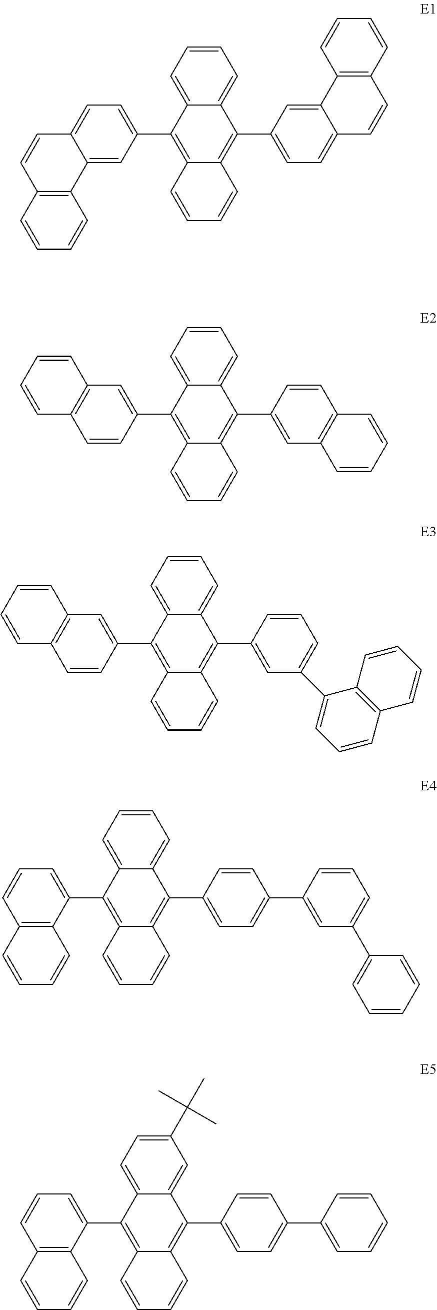

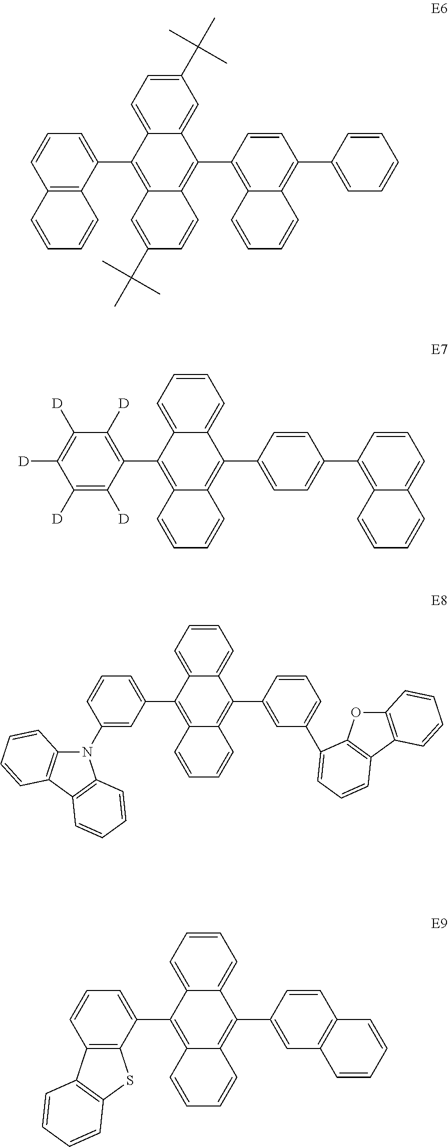

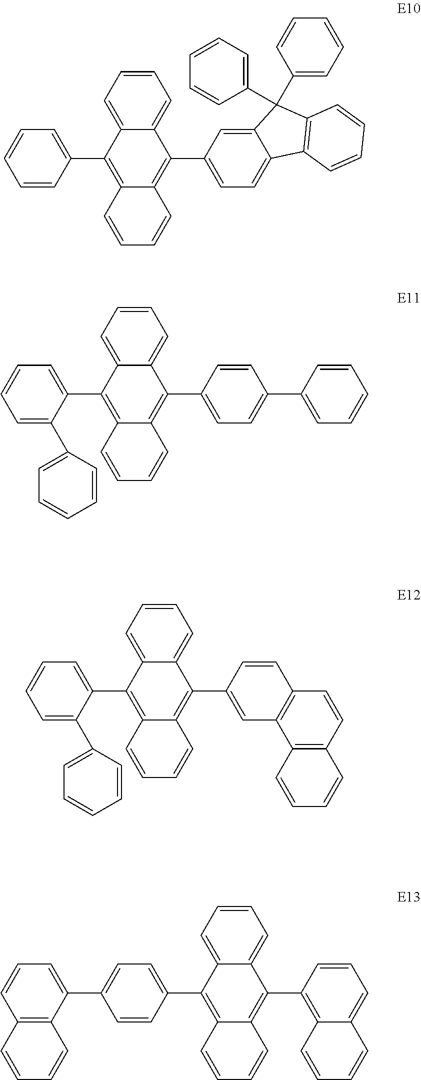

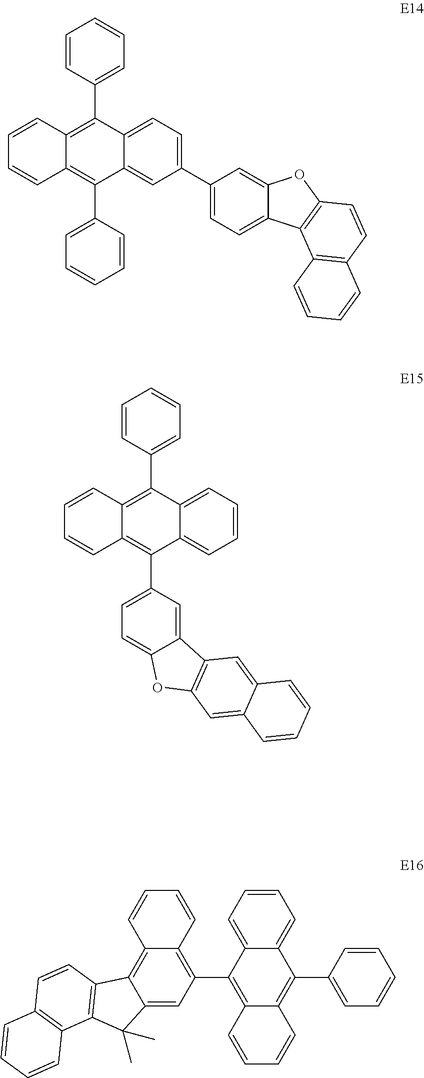

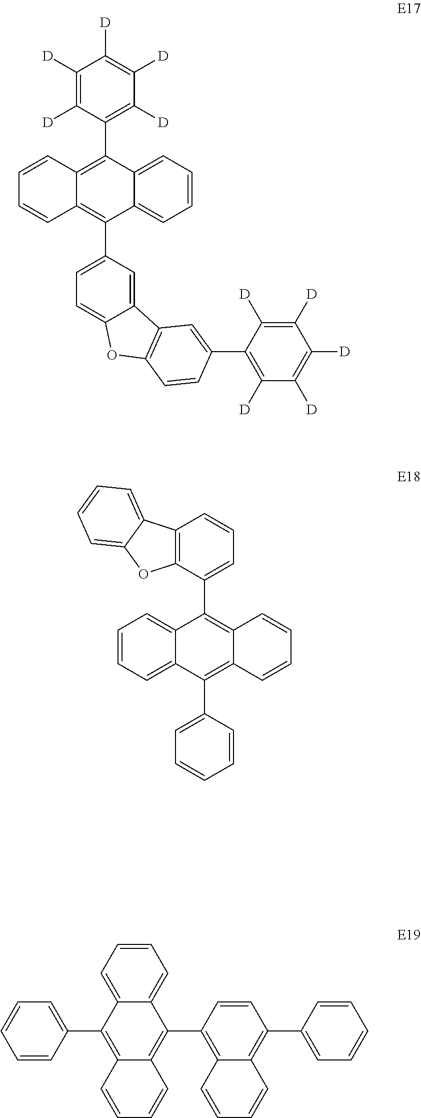

In one or more embodiments, the emission layer EML may include a compound represented by Formula E-2a or Formula E-2b. The compound represented by Formula E-2a or Formula E-2b may be used as a phosphorescent host material.

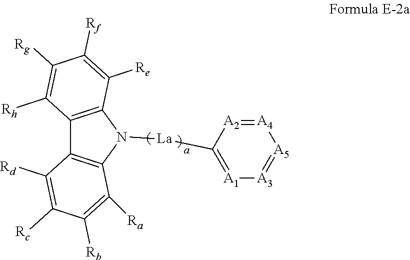

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a is an integer of 2 or greater, a plurality of La's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, and/or the like, as a ring-forming atom.

In one or more embodiments, in Formula E-2a, two or three selected from among A₁ to A₅ may be N, and the rest may be CRᵢ.

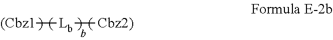

In Formula E-2b, Cbz1 and Cbz2 may each independently be an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, b is an integer of 0 to 10, and if (e.g., when) b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one among (e.g., selected from among) the compounds of Compound Group E-2. However, the compounds listed in Compound Group E-2 are example, and the compound represented by Formula E-2a or Formula E-2b is not limited to those represented in Compound Group E-2.

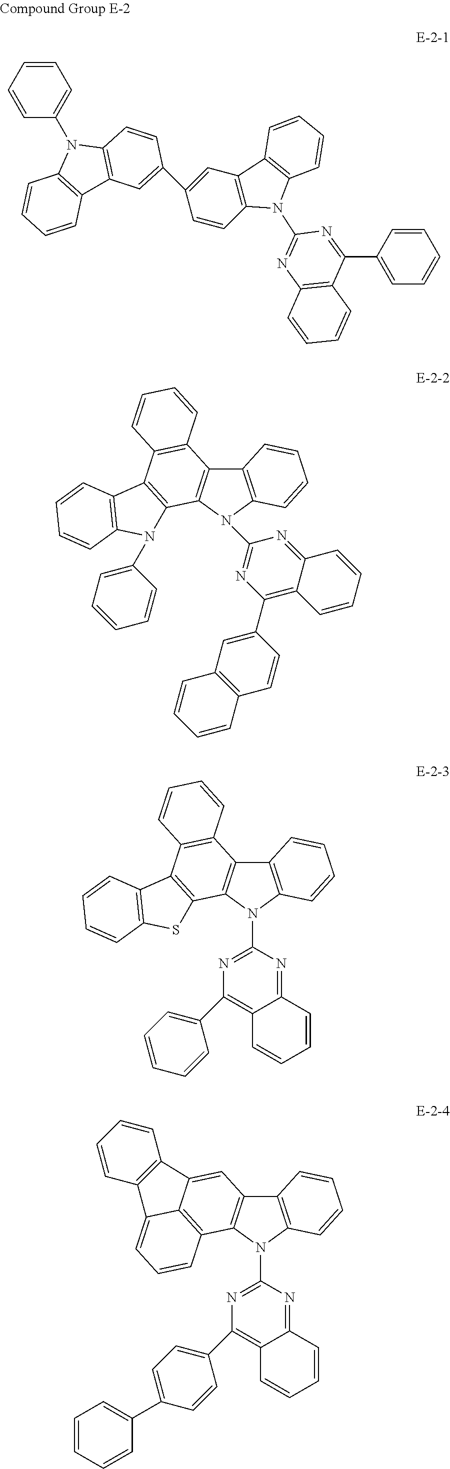

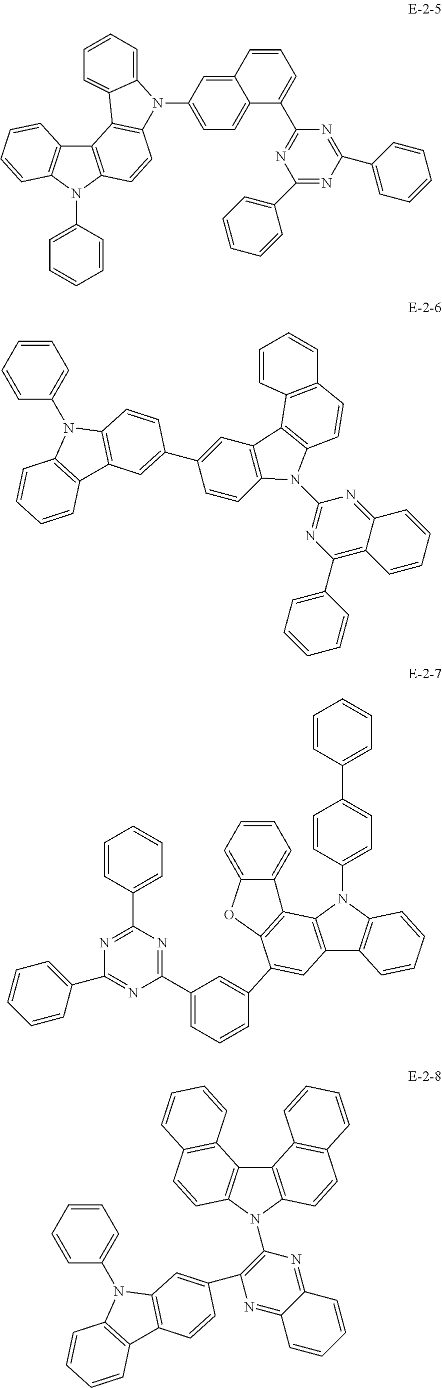

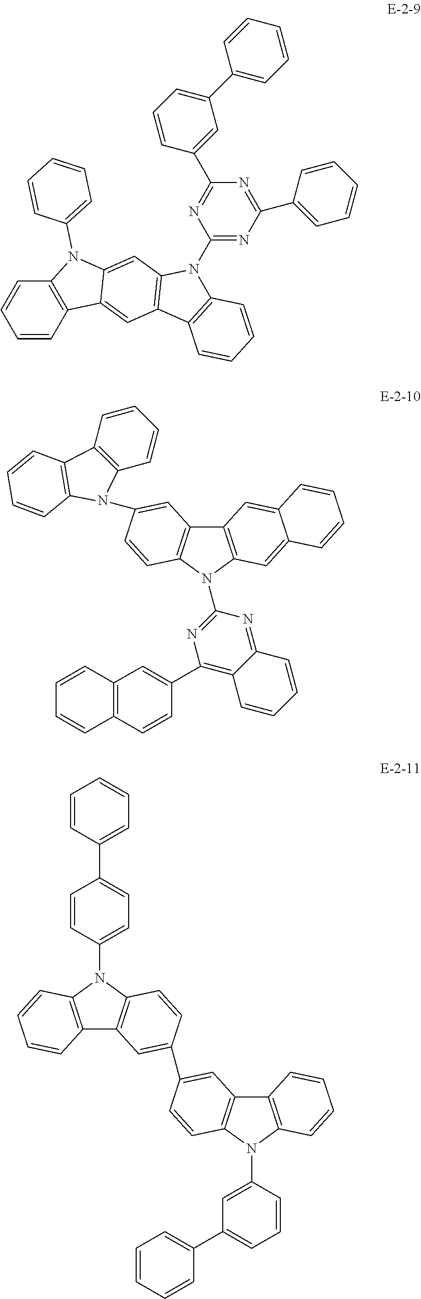 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

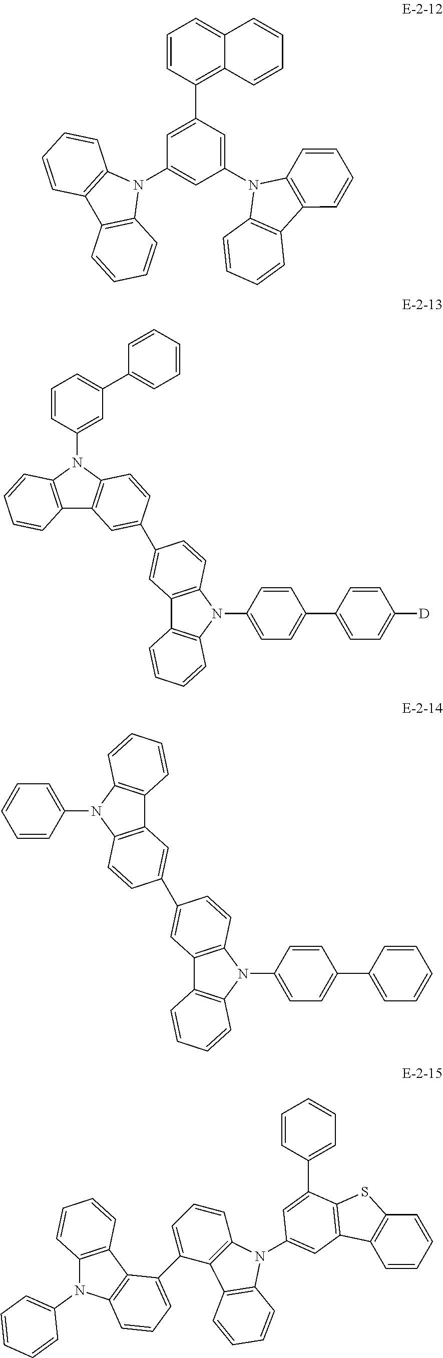 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

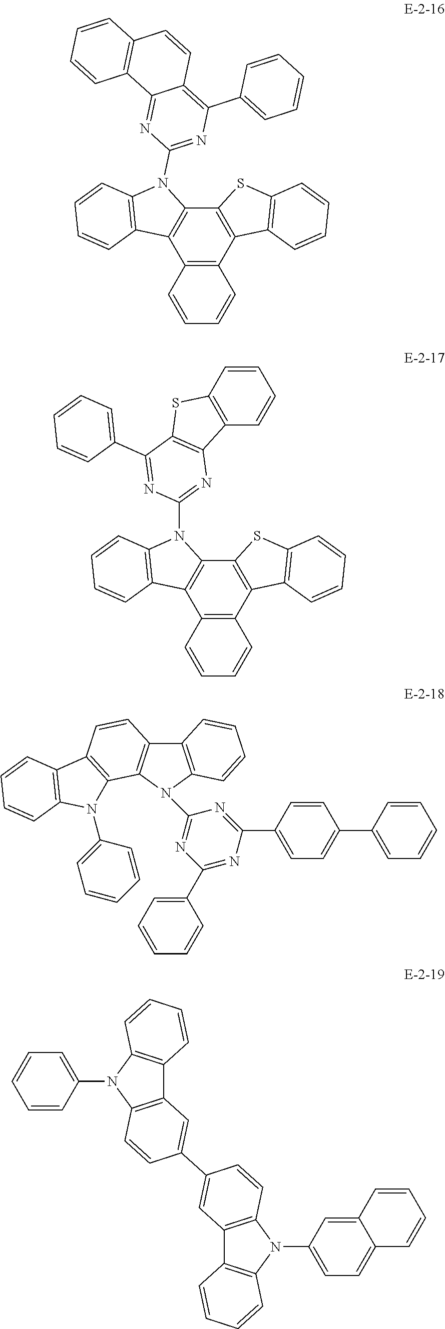

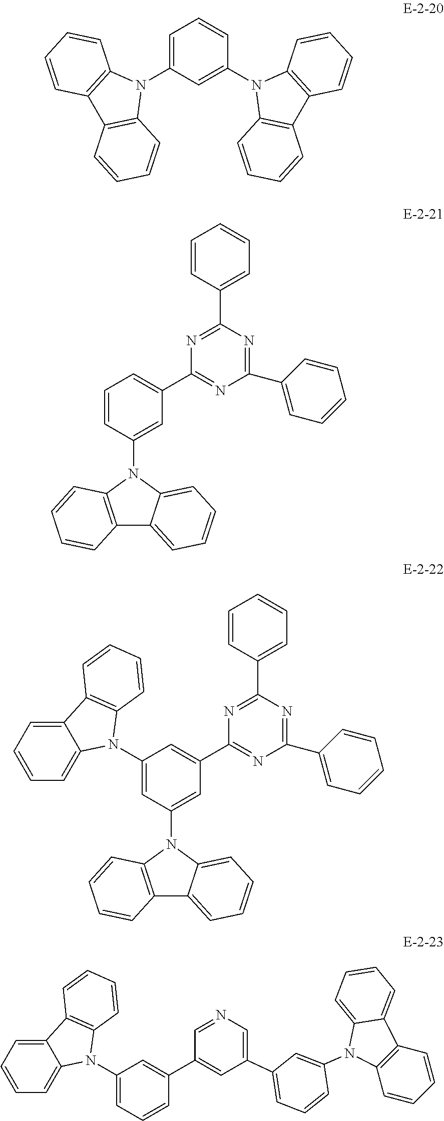 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

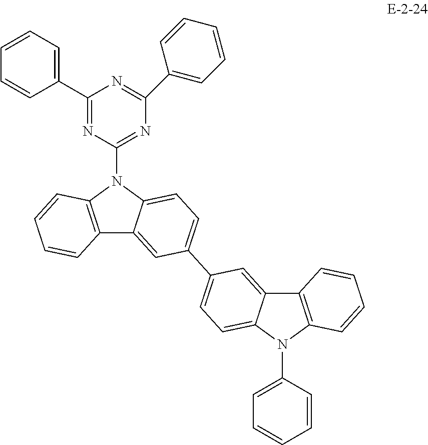 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and/or 1,3,5-tris(1-phenyl-1H-benzo[d]imidazole-2-yl)benzene (TPBi). However, one or more embodiments of the disclosure is not limited thereto, for example, tris(8-hydroxyquinolino)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and/or the like may be used as a host material.

The emission layer EML may include the compound represented by Formula M-a. The compound represented by Formula M-a may be used as a phosphorescent dopant material.

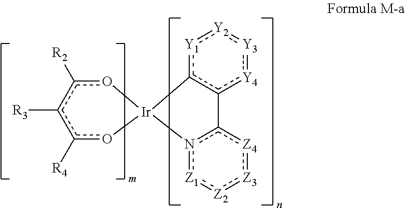

In Formula M-a, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m is 0 or 1, and n is 2 or 3. In Formula M-a, if (e.g., when) m is 0, n is 3, and if (e.g., when) m is 1, n is 2.

The compound represented by Formula M-a may be used as a phosphorescent dopant.

The compound represented by Formula M-a may be represented by any one among (e.g., selected from among) Compound M-a1 to Compound M-a25. However, Compounds M-a1 to M-a25 are examples, and the compound represented by Formula M-a is not limited to those represented by Compounds M-a1 to M-a25.

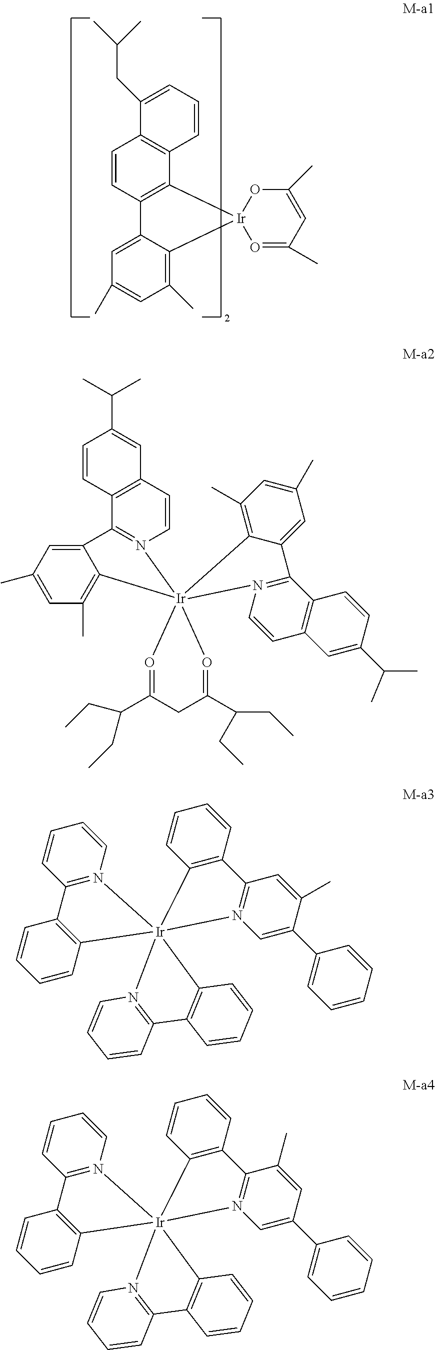

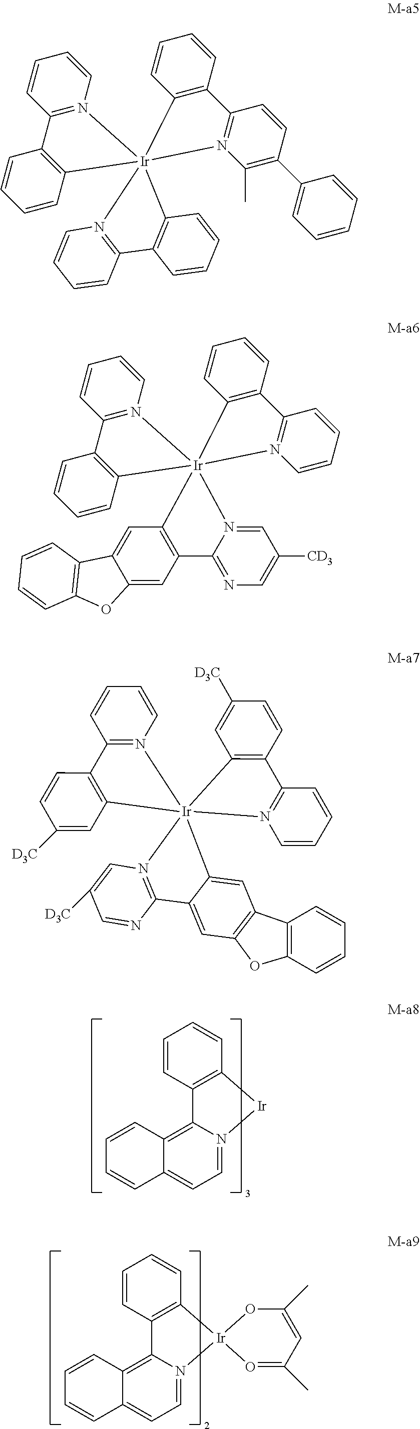

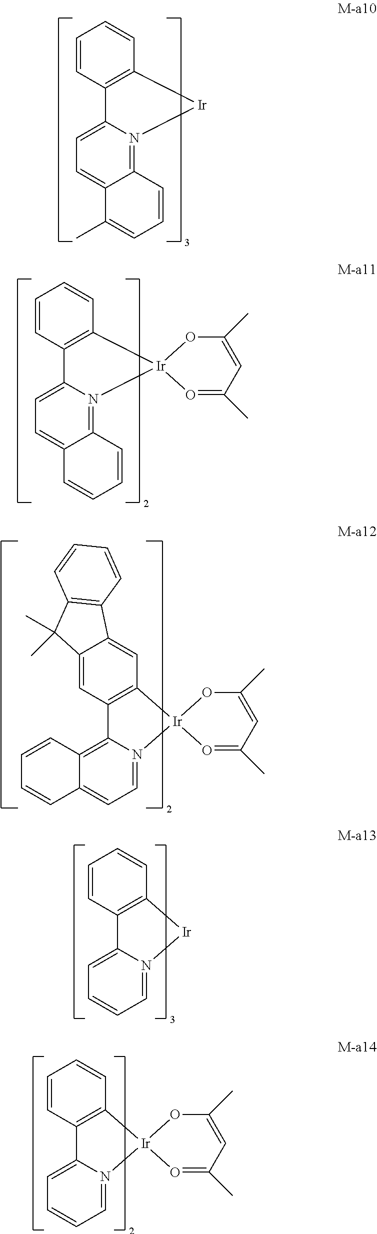

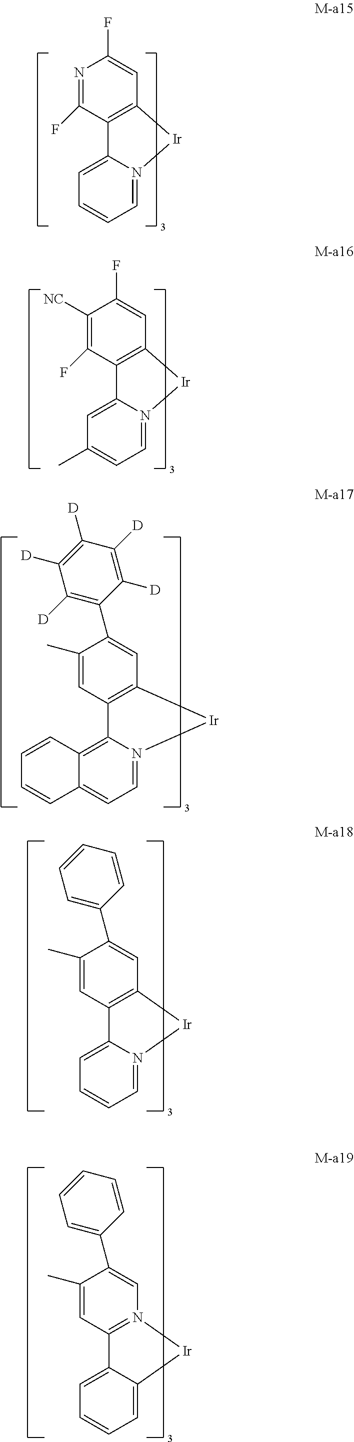

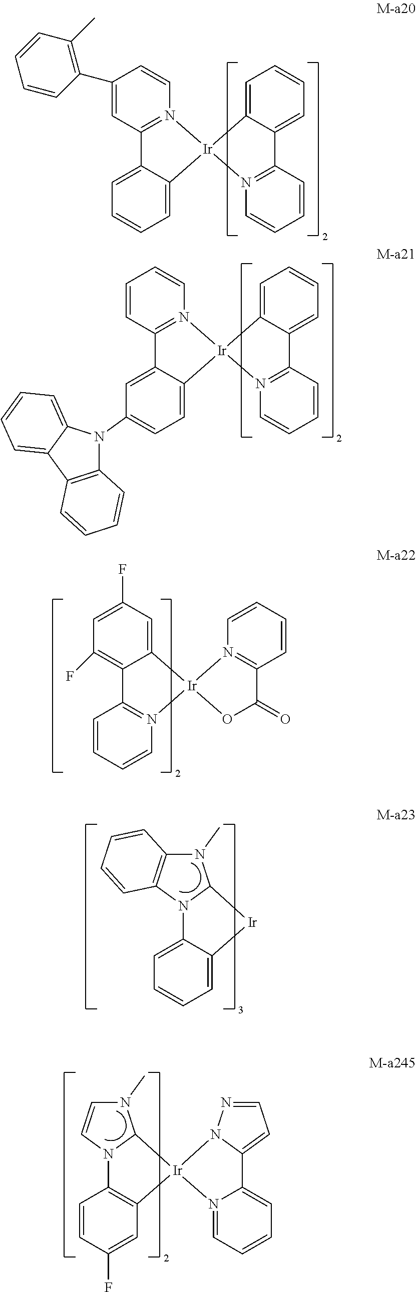

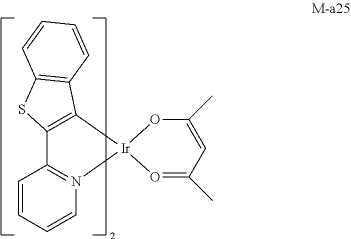

The emission layer EML may include a compound represented by any one among Formula F-a to Formula F-c. The compound represented by Formula F-a to Formula F-c may be used as a fluorescence dopant material.

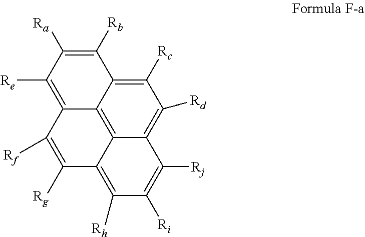

In Formula F-a, two selected from among Rₐ to Rⱼ may each independently be substituted with

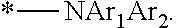

The others, which are not substituted with

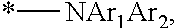

among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In

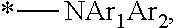

Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

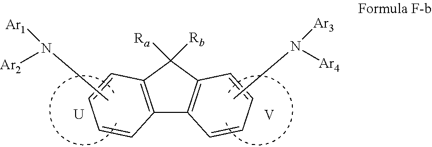

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one among Ar₁ to Ar₄ may be a heteroaryl group containing O or S as a ring-forming atom.

In Formula F-b, the number of rings represented by U and V may each independently be 0 or 1. For example, in Formula F-b, it refers to that if (e.g., when) the number of U or V is 1, one ring constitutes a fused ring at a portion indicated by U or V, and if (e.g., when) the number of U or V is 0, a ring indicated by U or V does not exist. For example, if (e.g., when) the number of U is 0 and the number of V is 1, or if (e.g., when) the number of U is 1 and the number of V is 0, the fused ring having a fluorene core in Formula F-b may be a cyclic compound having four rings. In some embodiments, if (e.g., when) each number of U and V is 0, the fused ring in Formula F-b may be a cyclic compound having three rings. In some embodiments, if (e.g., when) each number of U and V is 1, the fused ring having a fluorene core in Formula F-b may be a cyclic compound having five rings.

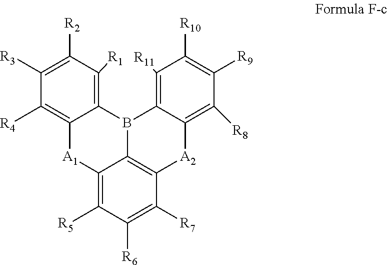

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to substituents of an adjacent ring to form a fused ring. For example, if (e.g., when) A₁ and A₂ may each independently be NRₘ, A₁ may be bonded to R₄ or R₅ to form a ring. In some embodiments, A₂ may be bonded to R₇ or R₈ to form a ring.

In one or more embodiments, the emission layer EML may further include, as a suitable dopant material, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), and/or the like.

The emission layer EML may further include a suitable phosphorescence dopant material. For example, a metal complex including (e.g., containing) iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2) (Flrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, one or more embodiments of the disclosure is not limited thereto.

The emission layer EML may include a quantum dot material. The core of the quantum dot may be selected from among a Group II-VI compound, a Group III-VI compound, a Group 1-III-IV compound, a Group III-V compound, a Group III-II-V compound, a Group IV-VI compound, a Group IV element, a Group IV compound, and/or a (e.g., any suitable) combination thereof.

The Group II-VI compound may be selected from among the group consisting of a binary compound selected from among the group consisting of CdSe, CdTe, CdS, ZnS, ZnSe, ZnTe, ZnO, HgS, HgSe, HgTe, MgSe, MgS, and/or a (e.g., any suitable) mixture thereof, a ternary compound selected from among the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or a (e.g., any suitable) mixture thereof, and a quaternary compound selected from among the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and/or a (e.g., any suitable) mixture thereof.

The Group III-VI compound may include a binary compound such as In₂S₃ or In₂Se₃, a ternary compound such as InGaS₃ or InGaSe₃, or any combination thereof.

The Group I-III-VI compound may be selected from among a ternary compound selected from among the group consisting of AgInS, AgInS₂, CuInS, CuInS₂, AgGaS₂, CuGaS₂ CuGaO₂, AgGaO₂, AgAlO₂, and/or a (e.g., any suitable) mixture thereof, or a quaternary compound such as AgInGaS₂ or CuInGaS₂.

The Group III-V compound may be selected from among the group consisting of a binary compound selected from among the group consisting of GaN, GaP, GaAs, GaSb, AlN, AlP, AlAs, AlSb, InN, InP, InAs, InSb, and/or a (e.g., any suitable) mixture thereof, a ternary compound selected from among the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and/or a (e.g., any suitable) mixture thereof, and a quaternary compound selected from among the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or a (e.g., any suitable) mixture thereof. In one or more embodiments, the Group III-V compound may further include a Group II metal. For example, InZnP, and/or the like, may be selected as a Group III-II-V compound.

The Group IV-VI compound may be selected from among the group consisting of a binary compound selected from among the group consisting of SnS, SnSe, SnTe, PbS, PbSe, PbTe, and/or a (e.g., any suitable) mixture thereof, a ternary compound selected from among the group consisting of SnSeS, SnSeTe, SnSTe, PbSeS, PbSeTe, PbSTe, SnPbS, SnPbSe, SnPbTe, and/or a (e.g., any suitable) mixture thereof, and a quaternary compound selected from among the group consisting of SnPbSSe, SnPbSeTe, SnPbSTe, and/or a (e.g., any suitable) mixture thereof. The Group IV element may be selected from among the group consisting of Si, Ge, and/or a (e.g., any suitable) mixture thereof. The Group IV compound may be a binary compound selected from among the group consisting of SiC, SiGe, and/or a (e.g., any suitable) mixture thereof.

Each element included in a polynary compound such as the binary compound, the ternary compound, or the quaternary compound may be present in a particle with a substantially uniform or non-substantially uniform concentration distribution. For example, the formulae refer to the types (kinds) of elements included in the compounds, and the elemental ratio in the compound may be different. For example, AgInGaS₂ may refer to AgInₓGa₁₋ₓS₂ (where x is a real number of 0 to 1).

In one or more embodiments, the quantum dot may have a single structure or a double structure of core-shell in which the concentration of each element included in the quantum dot is substantially uniform. For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or multiple layers. An interface between the core and the shell may have a concentration gradient in which the concentration of an element present in the shell becomes lower towards the center.

In one or more embodiments, the quantum dot may have the herein-described core/shell structure including a core containing nanocrystals and a shell around (e.g., surrounding) the core. An example of the shell of the quantum dots may include a metal or non-metal oxide, a semiconductor compound, and/or a (e.g., any suitable) combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but one or more embodiments of the disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but one or more embodiments of the disclosure is not limited thereto.

Each element included in a polynary compound such as the binary compound, or the ternary compound may be present in a particle with a substantially uniform or non-substantially uniform concentration distribution. For example, the formulae refer to the types (kinds) of elements included in the compounds, and the elemental ratio in the compound may be different.

The quantum dot may have a full width of half maximum (FWHM) of alight emitting wavelength spectrum of about 45 nm or less, about 40 nm or less, and more about 30 nm or less, and color purity or color reproducibility may be improved in the preceding range. In some embodiments, light emitted through such quantum dot is emitted in all directions so that a wide viewing angle may be improved.

In some embodiments, although the form of the quantum dot is not particularly limited as long as it is a form commonly used in the art, more specifically, the quantum dot in the form of spherical, pyramidal, multi-arm, or cubic nanoparticles, nanotubes, nanowires, nanofibers, nanoplate particles, and/or the like. may be used.

As the size of the quantum dot is adjusted or the elemental ratio in the quantum dot compound is adjusted, it is possible to control the energy band gap, and thus light in one or more suitable wavelength ranges may be obtained in the quantum dot emission layer. Therefore, the quantum dot as described (using different sizes of quantum dots or different elemental ratios in the quantum dot compound) is used, and thus the light emitting device, which emits light in one or more suitable wavelengths, may be implemented. For example, the adjustment of the size of the quantum dot or the elemental ratio in the quantum dot compound may be selected to emit red, green, and/or blue light. In some embodiments, the quantum dots may be configured to emit white light by combining one or more suitable colors of light.

In each of the light emitting devices ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but one or more embodiments of the disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but one or more embodiments of the disclosure is not limited thereto. The electron transport region ETR may have a thickness, for example, from about 1,000 Å to about 1,500 Å.

The electron transport region ETR may be formed using one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2:

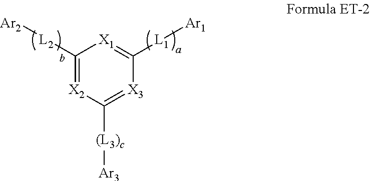

In Formula ET-2, at least one among X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a to c may each independently be an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, one or more embodiments of the disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), and/or a (e.g., any suitable) mixture thereof.

The electron transport region ETR may include at least one among (e.g., selected from among) Compound ET1 to Compound ET36:

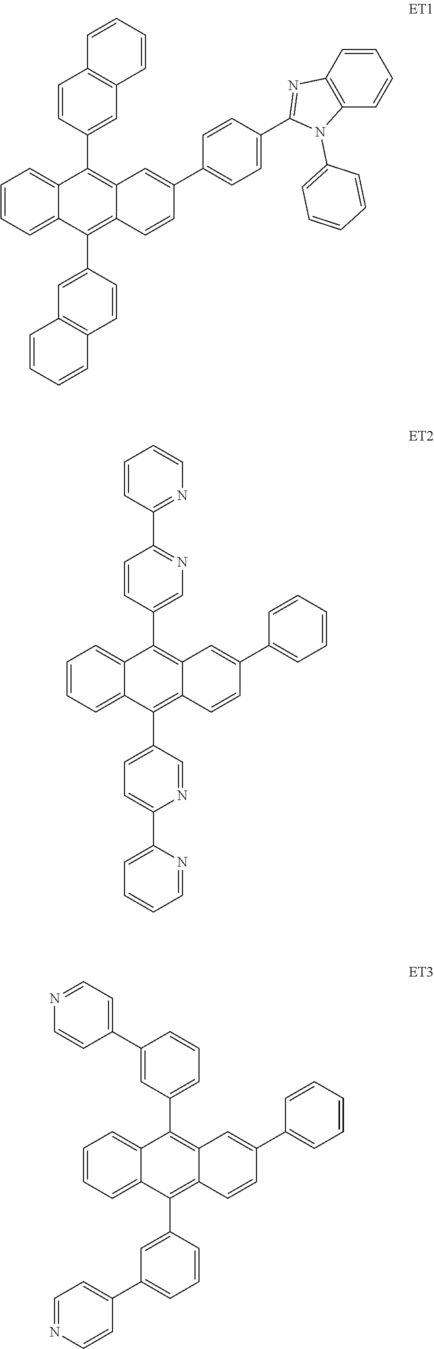 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

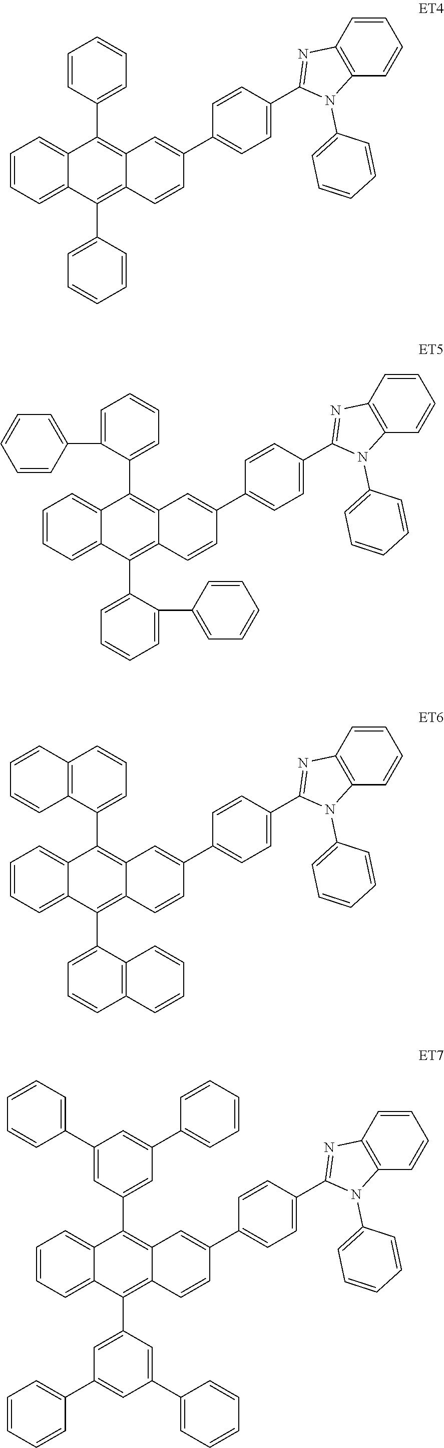 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

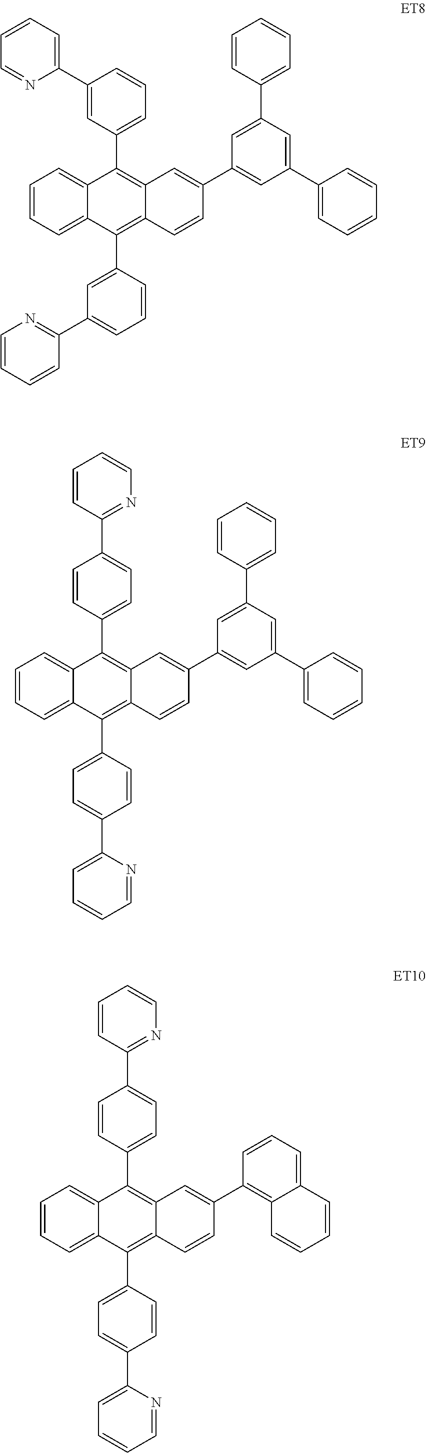 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

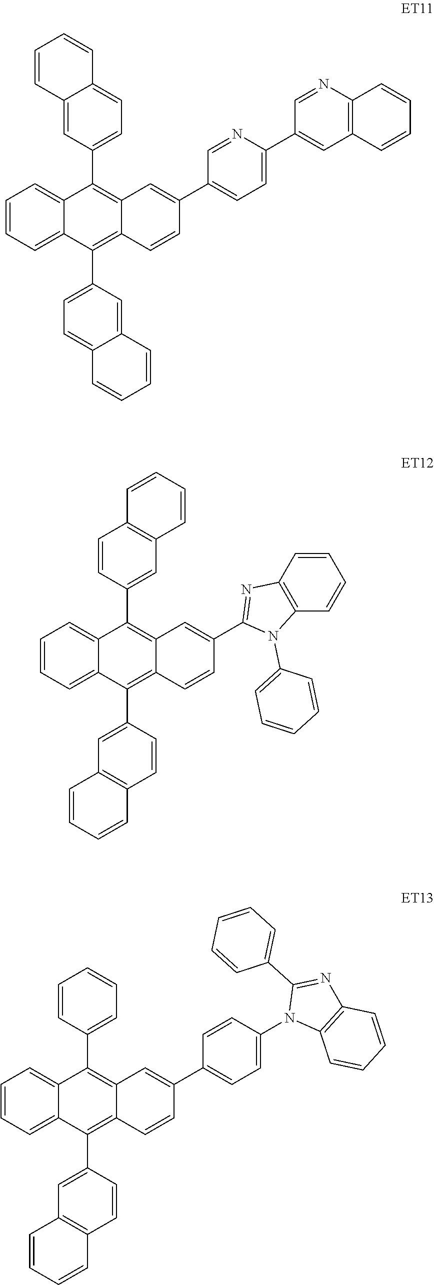 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

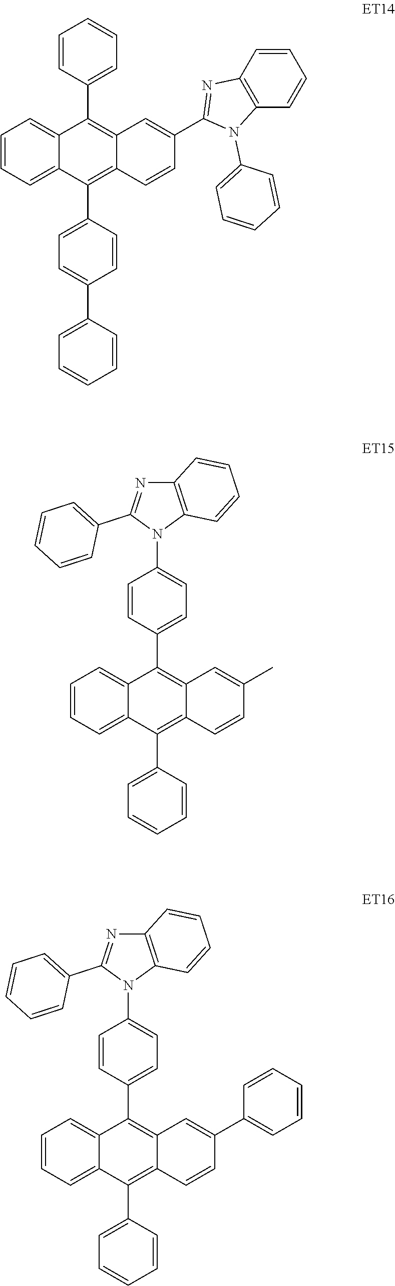 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

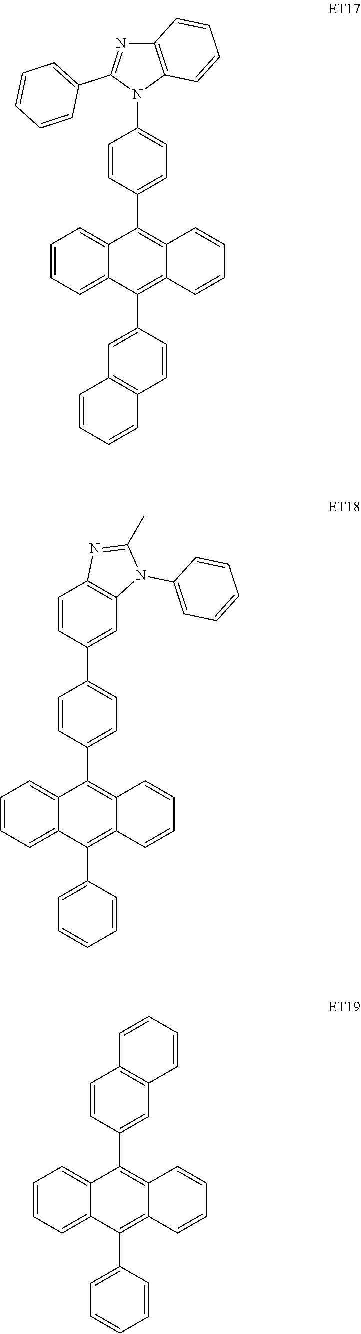

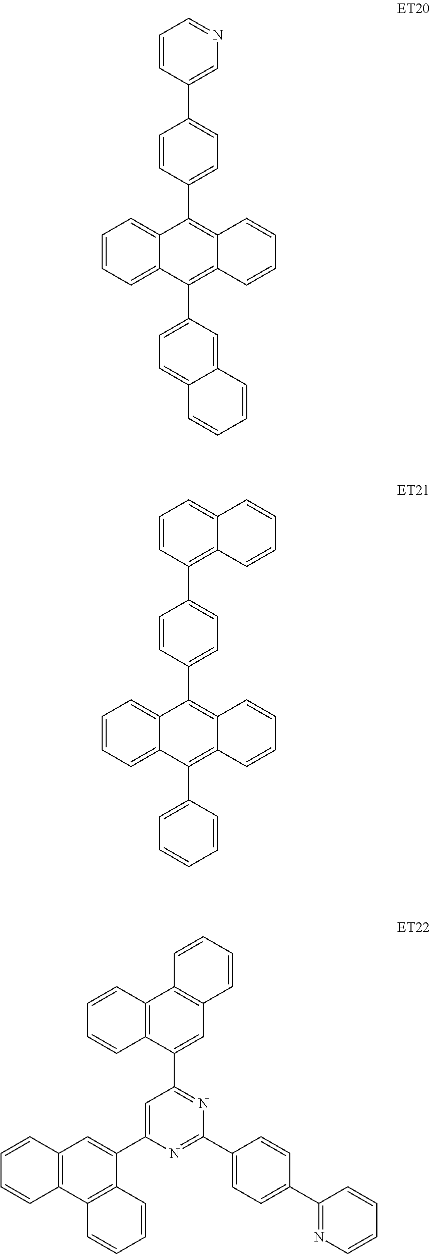

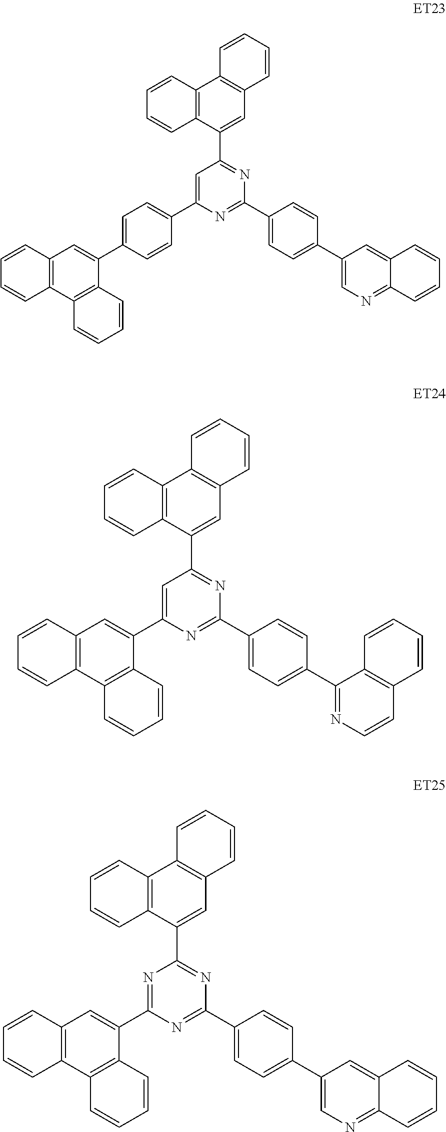 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

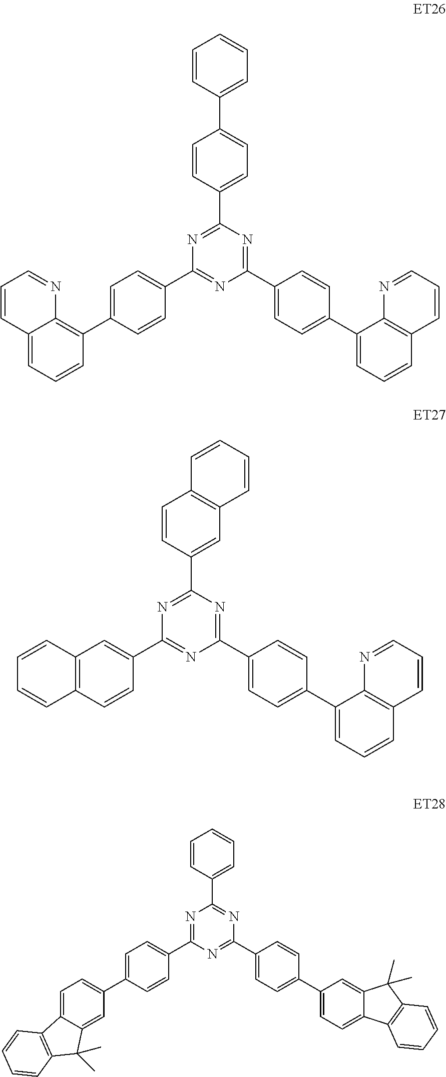 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

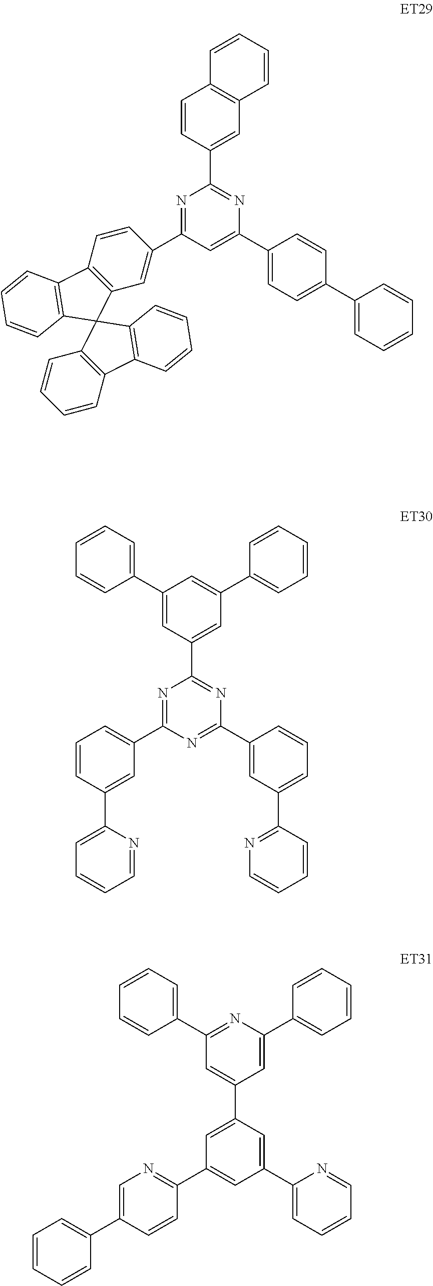 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

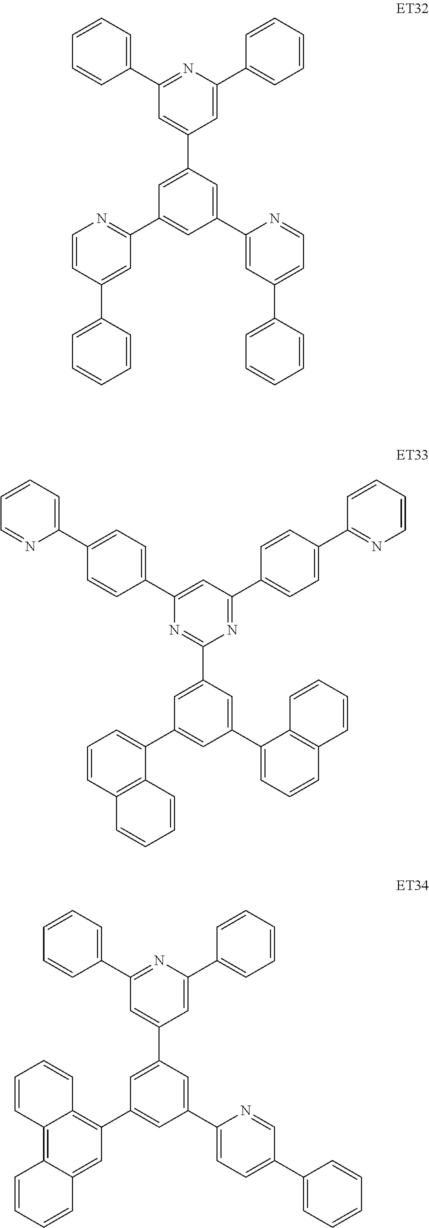 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

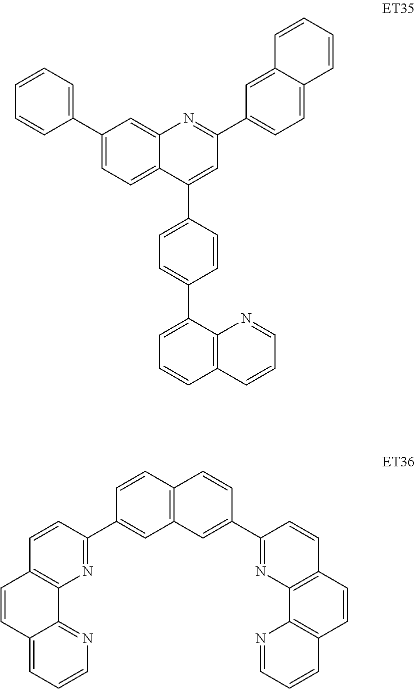 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI, and/or KI, a lanthanide metal such as Yb, and a co-deposited material of the metal halide and the lanthanide metal. For example, the electron transport region ETR may include KI:Yb, RbI:Yb, LiF:Yb, and/or the like, as a co-deposited material. In one or more embodiments, the electron transport region ETR may be formed using a metal oxide such as Li₂O and/or BaO, or 8-hydroxyl-lithium quinolate (Liq), and/or the like, but one or more embodiments of the disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the herein-described materials, but one or more embodiments of the disclosure is not limited thereto.

The electron transport region ETR may include the herein-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. If the thickness of the electron transport layer ETL satisfies the aforementioned range, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. If the thickness of the electron injection layer EIL satisfies the herein-described range, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but one or more embodiments of the disclosure is not limited thereto. For example, if (e.g., when) the first electrode EL1 is an anode, the second electrode EL2 may be a cathode, and if (e.g., when) the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, L₁, Ca, LiF/Ca, LiF/Al, Mo, Ti, Yb, W, and/or a compound and/or mixture thereof (e.g., AgMg, AgYb, and/or MgYb). In one or more embodiments, the second electrode EL2 may have a multilayer structure including a reflective film or a transflective film formed of the herein-described materials, and a transparent conductive film formed of ITO, IZO, ZnO, ITZO, and/or the like. For example, the second electrode EL2 may include the herein-described metal materials, combinations of at least two metal materials of the herein-described metal materials, oxides of the herein-described metal materials, and/or the like.

The second electrode EL2 may be connected with an auxiliary electrode. If the second electrode EL2 is connected with the auxiliary electrode, the resistance of the second electrode EL2 may be decreased.

In one or more embodiments, a capping layer CPL may further be arranged on the second electrode EL2 of the light emitting device ED of one or more embodiments. The capping layer CPL may include a multilayer or a single layer.

In one or more embodiments, the capping layer CPL may be an organic layer or an inorganic layer. For example, if (e.g., when) the capping layer CPL contains an inorganic material, the inorganic material may include an alkaline metal compound (e.g., LiF), an alkaline earth metal compound (e.g., MgF₂), SiON, SiNₓ, SiO_{y}, and/or the like.

For example, if (e.g., when) the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or an epoxy resin, or acrylate such as methacrylate. However, one or more embodiments of the disclosure is not limited thereto, and the capping layer CPL may include at least one among (e.g., selected from among) Compounds P1 to P5:

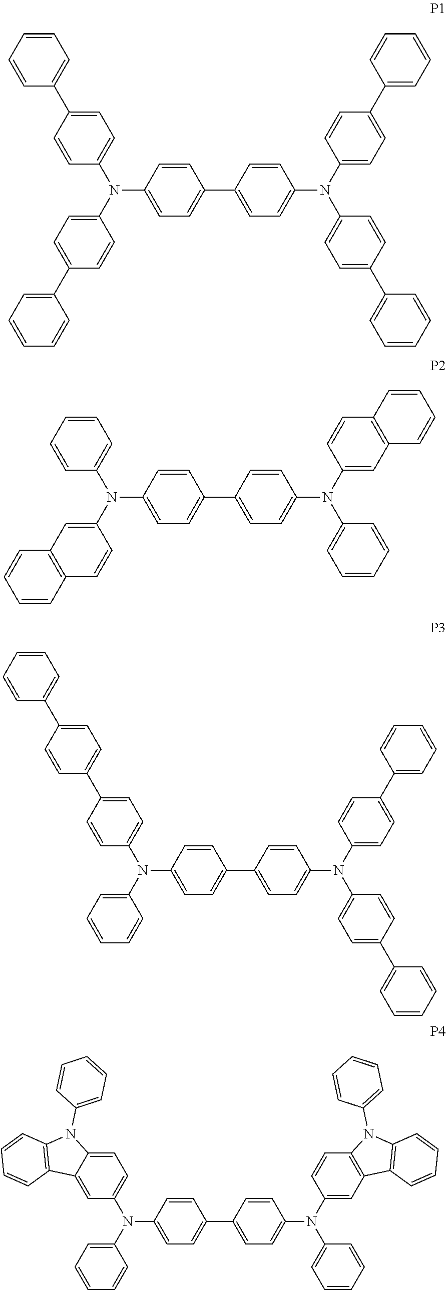 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

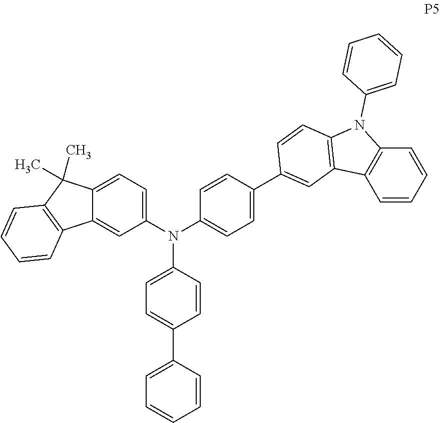 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be at least about 1.6 (e.g., or more). For example, the refractive index of the capping layer CPL may be at least about 1.6 (e.g., or more) with respect to light in a wavelength range of about 550 nm to about 660 nm.

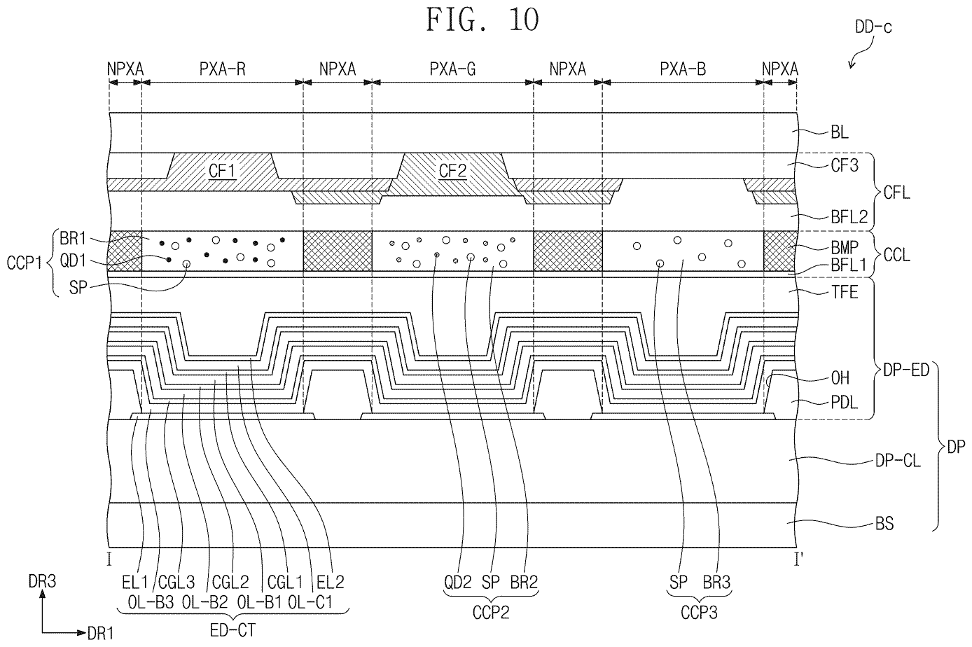

Each of FIGS. 7 to 10 is a cross-sectional view of a display apparatus according to one or more embodiments of the disclosure. Hereinafter, in describing the display apparatuses of embodiments with reference to FIGS. 7 to 10, the duplicated features which have been described in FIGS. 1 to 6 are not described again, but their differences will be mainly described.

Referring to FIG. 7, the display apparatus DD-a according to one or more embodiments may include a display panel DP including a display device layer DP-ED, a light control layer CCL arranged on the display panel DP, and a color filter layer CFL. In one or more embodiments illustrated in FIG. 7, the display panel DP may include a base layer BS, a circuit layer DP-CL provided on the base layer BS, and the display device layer DP-ED, and the display device layer DP-ED may include a light emitting device ED.

The light emitting device ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. In one or more embodiments, the structures of the light emitting devices of FIGS. 3 to 6 as described may be equally applied to the structure of the light emitting device ED illustrated in FIG. 7.

The emission layer EML of the light emitting element ED included in a display device DD-a according to one or more embodiments may include the fused polycyclic compound of one or more embodiments described herein.

Referring to FIG. 7, the emission layer EML may be arranged in an opening OH defined in a pixel defining film PDL. For example, the emission layer EML which is divided by the pixel defining film PDL and provided corresponding to each light emitting regions PXA-R, PXA-G, and PXA-B may be to emit light in substantially the same wavelength range. In the display apparatus DD-a of one or more embodiments, the emission layer EML may be to emit blue light. In one or more embodiments, unlike the configuration illustrated, in one or more embodiments, the emission layer EML may be provided as a common layer in the entire light emitting regions PXA-R, PXA-G, and PXA-B.

The light control layer CCL may be arranged on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced and/or apart (e.g., spaced apart or separated) from each other.

Referring to FIG. 7, divided patterns BMP may be arranged between the light control parts CCP1, CCP2 and CCP3 which are spaced and/or apart (e.g., spaced apart or separated) from each other, but one or more embodiments of the disclosure is not limited thereto. FIG. 7 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light emitting device ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The same as described herein may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, and/or the like. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block the light control parts CCP1, CCP2 and CCP3 from being exposed to moisture/oxygen. In one or more embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In one or more embodiments, the barrier layers BFL1 and BFL2 may further include an organic film. The barrier layers BFL1 and BFL2 may be formed of a single layer or a plurality of layers.

In the display apparatus DD-a of one or more embodiments, the color filter layer CFL may be arranged on the light control layer CCL. For example, the color filter layer CFL may be directly arranged on the light control layer CCL. In this case, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

In one or more embodiments, one or more embodiments of the disclosure is not limited thereto, and the third filter CF3 may not include (e.g., may exclude) a (e.g., any) pigment or dye. The third filter CF3 may include a polymeric photosensitive resin and may not include (e.g., may exclude) a pigment or dye. The third filter CF3 may be transparent. The third filter CF3 may be formed of a transparent photosensitive resin.

Furthermore, in one or more embodiments, the first filter CF1 and the second filter CF2 may be a yellow filter. The first filter CF1 and the second filter CF2 may not be separated but be provided as one filter.

Although not illustrated, the color filter layer CFL may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF1, CF2, and CF3.

The first to third filters CF1, CF2, and CF3 may be arranged corresponding to the red light emitting region PXA-R, the green light emitting region PXA-G, and the blue light emitting region PXA-B, respectively.

A base substrate BL may be arranged on the color filter layer CFL. The base substrate BL may be a member which provides a base surface in which the color filter layer CFL, the light control layer CCL, and/or the like are arranged. The base substrate BL may be a glass substrate, a metal substrate, a plastic substrate, and/or the like. However, one or more embodiments of the disclosure is not limited thereto, and the base substrate BL may be an inorganic layer, an organic layer, or a composite material layer. In some embodiments, unlike the configuration illustrated, in one or more embodiments, the base substrate BL may not be provided.

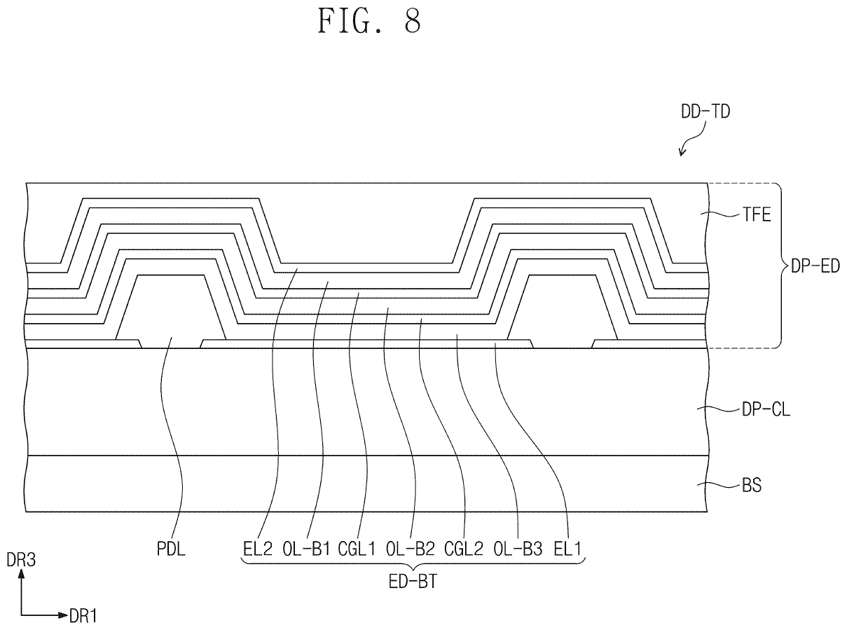

FIG. 8 is a cross-sectional view illustrating a portion of a display apparatus according to one or more embodiments. In the display apparatus DD-TD of one or more embodiments, the light emitting device ED-BT may include a plurality of light emitting structures OL-B1, OL-B2, and OL-B3. The light emitting device ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR arranged with the emission layer EML (FIG. 7) located therebetween.

For example, the light emitting device ED-BT included in the display apparatus DD-TD of one or more embodiments may be a light emitting device having a tandem structure and including a plurality of emission layers.

In one or more embodiments illustrated in FIG. 8, all light beams respectively emitted from the light emitting structures OL-B1, OL-B2, and OL-B3 may be blue light. However, one or more embodiments of the disclosure is not limited thereto, and the light beams respectively emitted from the light emitting structures OL-B1, OL-B2, and OL-B3 may have wavelength ranges different from each other. For example, the light emitting device ED-BT including the plurality of light emitting structures OL-B1, OL-B2, and OL-B3 which emit light beams having wavelength ranges different from each other may be to emit white light.

Charge generation layers CGL1 and CGL2 may be respectively arranged between two of the neighboring light emitting structures OL-B1, OL-B2, and OL-B3. The charge generation layers CGL1 and CGL2 may include a p-type (kind) charge generation layer and/or an n-type (kind) charge generation layer. At least one of the light emitting structures OL-B1, OL-B2, and OL-B3 included in the display device DD-TD of one or more embodiments may include the fused polycyclic compound of one or more embodiments described herein. For example, at least one of (e.g., selected from among) the plurality of emission layers included in the light emitting element ED-BT may include the fused polycyclic compound of one or more embodiments.

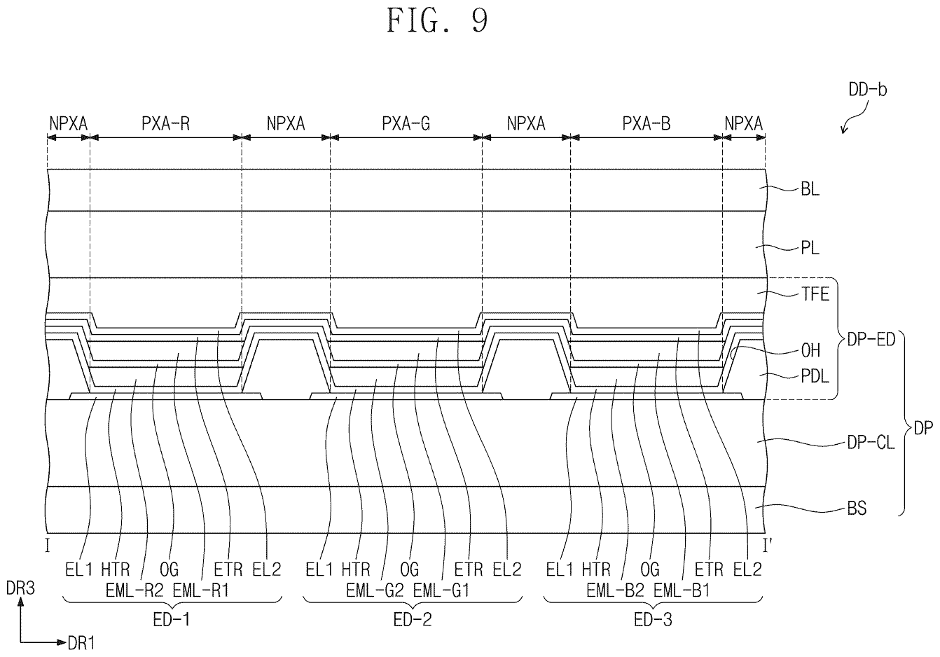

Referring to FIG. 9, the display apparatus DD-b according to one or more embodiments may include light emitting devices ED-1, ED-2, and ED-3 in which two emission layers are stacked. Compared with the display apparatus DD of one or more embodiments illustrated in FIG. 2, one or more embodiments illustrated in FIG. 9 has a difference in that the first to third light emitting devices ED-1, ED-2, and ED-3 each include two emission layers stacked in the thickness direction. In each of the first to third light emitting devices ED-1, ED-2, and ED-3, the two emission layers may be to emit light in substantially the same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In some embodiments, the third light emitting device ED-3 may include a first blue emission layer EML-B1 and a second blue emission layer EML-B2. An emission auxiliary part OG may be arranged between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light emitting devices ED-1, ED-2, and ED-3. However, one or more embodiments of the disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be arranged between the emission auxiliary part OG and the electron transport region ETR. The second red emission layer EML-R2, the second green emission layer EML-G2, and the second blue emission layer EML-B2 may be arranged between the hole transport region HTR and the emission auxiliary part OG.

For example, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In one or more embodiments, an optical auxiliary layer PL may be arranged on the display device layer DP-ED. The optical auxiliary layer PL may include a polarizing layer. The optical auxiliary layer PL may be arranged on the display panel DP and control reflected light in the display panel DP due to external light. Unlike the configuration illustrated, the optical auxiliary layer PL in the display apparatus according to one or more embodiments may not be provided.

At least one emission layer included in a display device DD-b of one or more embodiments shown in FIG. 9 may include the fused polycyclic compound of one or more embodiments described herein. For example, at least one of the first blue emission layer EML-B1 or the second blue emission layer EML-B2 may include the fused polycyclic compound of one or more embodiments.

Unlike FIGS. 8 and 9, FIG. 10 illustrates that a display apparatus DD-c includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. Charge generation layers CGL1, CGL2, and CGL3 may be arranged between the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, one or more embodiments of the disclosure is not limited thereto, and the first to fourth light emitting structures OL-B1, OL-B2, OL-B3, and OL-C1 may be to emit light beams in different wavelength regions.

The charge generation layers CGL1, CGL2, and CGL3 arranged between adjacent light emitting structures OL-B1, OL-B2, OL-B3, and OL-C1 may include a p-type (kind) charge generation layer and/or an n-type (kind) charge generation layer.

At least one of (e.g. selected from among) the light emitting structures OL-B1, OL-B2, OL-B3, and OL-C1 included in the display device DD-c according to one or more embodiments may include the fused polycyclic compound of one or more embodiments described herein. For example, in one or more embodiments, at least one of (e.g., selected from among) the first to third light emitting structures OL-B1, OL-B2, and OL-B3 may include the fused polycyclic compound of one or more embodiments described herein.

The light emitting element ED represented by Formula 1 described herein according to one or more embodiments of the disclosure includes the polycyclic compound of one or more embodiments in at least one functional layer arranged between the first electrode EL1 and the second electrode EL2, and may thus exhibit excellent or suitable light emitting efficiency and improved lifespan. For example, the polycyclic compound according to one or more embodiments may be included in the emission layer EML of the light emitting element ED of one or more embodiments, and the light emitting element of one or more embodiments may exhibit long lifespan.

In one or more embodiments, the electronic apparatus may include a display apparatus including a plurality of light emitting devices, and a control part which controls the display apparatus. The electronic apparatus of one or more embodiments may be a device that is activated according to an electrical signal. The electronic apparatus may include display apparatuses of one or more suitable embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display apparatus for a vehicle, a game console, a portable electronic device, or a camera.

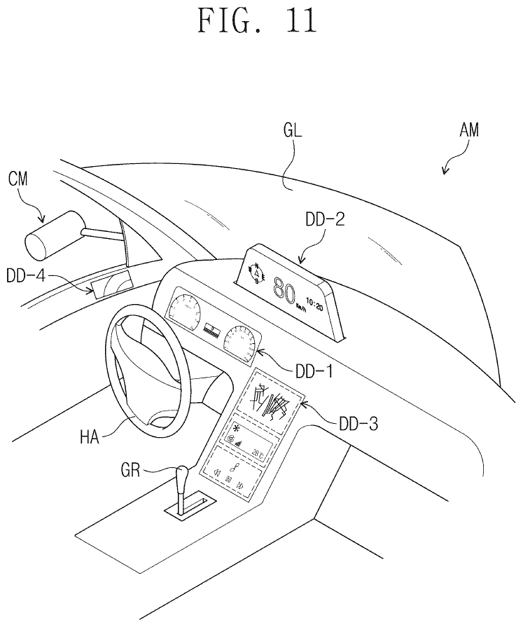

FIG. 11 is a view illustrating a vehicle AM in which first to fourth display apparatuses DD-1, DD-2, DD-3, and DD-4 are arranged. At least one among the first to fourth display apparatuses DD-1, DD-2, DD-3, and DD-4 may include the same configuration as the display apparatuses DD, DD-TD, DD-a, DD-b, and DD-c as described with reference to FIGS. 1, and 2, and 7 to 10.

FIG. 11 illustrates a vehicle AM, but this is an example, and the first to fourth display apparatuses DD-1, DD-2, DD-3, and DD-4 may be arranged in another transportation refers to such as bicycles, motorcycles, trains, ships, and airplanes. In some embodiments, at least one among the first to fourth display apparatuses DD-1, DD-2, DD-3, and DD-4 including the same configuration as the display apparatuses DD, DD-TD, DD-a, DD-b, and DD-c of one or more embodiments may be employed in a personal computer, a laptop computer, a personal digital terminal, a game console, a portable electronic device, a television, a monitor, an outdoor billboard, and/or the like. In some embodiments, these are merely provided as embodiments, and thus may be employed in other electronic apparatuses unless departing from the disclosure.

At least one of (e.g., selected from among) the first to fourth display devices DD-1, DD-2, DD-3, and DD-4 may include the light emitting element ED of one or more embodiments described with reference to FIGS. 3 to 6. The light emitting element ED of one or more embodiments may include the fused polycyclic compound of one or more embodiments. At least one of (e.g., selected from among) the first to fourth display devices DD-1, DD-2, DD-3, and DD-4 includes the light emitting element ED including the fused polycyclic compound of one or more embodiments, and may thus have increased display lifespan.

Referring to FIG. 11, the vehicle AM may include a steering wheel HA and a gear GR for driving the vehicle AM. In some embodiments, the vehicle AM may include a front window GL arranged so as to face the driver.

The first display apparatus DD-1 may be arranged in a first region overlapping the steering wheel HA. For example, the first display apparatus DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. A first scale and a second scale may be indicated as a digital image.

The second display apparatus DD-2 may be arranged in a second region opposite to (e.g., facing) the driver's seat and overlapping the front window GL. The driver's seat may be a seat in which the steering wheel HA is arranged. For example, the second display apparatus DD-2 may be a head up display (HUD) which displays second information of the vehicle AM. The second display apparatus DD-2 may be optically transparent. The second information may include digital numbers which indicate a driving speed, and may further include information such as the current time. Unlike the configuration illustrated, the second information of the second display apparatus DD-2 may be projected to the front window GL to be displayed.

The third display apparatus DD-3 may be arranged in a third region adjacent to the gear GR. For example, the third display apparatus DD-3 may be arranged between the driver's seat and the passenger seat and may be a center information display (CID) for a vehicle for displaying third information. The passenger seat may be a seat spaced and/or apart (e.g., spaced apart or separated) from the driver's seat with the gear GR arranged therebetween. The third information may include information about traffic (e.g., navigation information), playing music or radio or a video (or an image), temperatures inside the vehicle AM, and/or the like.

The fourth display apparatus DD-4 may be spaced and/or apart (e.g., spaced apart or separated) from the steering wheel HA and the gear GR, and may be arranged in a fourth region adjacent to the side of the vehicle AM. For example, the fourth display apparatus DD-4 may be a digital side-view mirror which displays fourth information. The fourth display apparatus DD-4 may display an image outside the vehicle AM taken by a camera module CM arranged outside the vehicle AM. The fourth information may include an image outside the vehicle AM.

The herein-described first to fourth information may be examples, and the first to fourth display apparatuses DD-1, DD-2, DD-3, and DD-4 may further display information about the inside and outside of the vehicle AM. The first to fourth information may include different information. However, one or more embodiments of the disclosure is not limited thereto, and a part of the first to fourth information may include the same information as one another.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

Hereinafter, with reference to examples and comparative examples, a fused polycyclic compound according to one or more embodiments of the disclosure and a light-emitting element according to one or more embodiments will be described in more detail. In some embodiments, examples to be described in more detail are provided to aid in understanding the disclosure and are merely illustrative, and one or more embodiments of the disclosure is not limited to thereto.

### EXAMPLES

### 1. Synthesis of Fused Polycyclic Compound

First, synthetic methods of the fused polycyclic compound according to one or more embodiments of the disclosure will be described in more detail by exemplifying the synthetic methods of Compounds 1, 26, 85, 145, 373, and 421. In some embodiments, the synthetic method of the fused polycyclic compound to be explained hereinafter is one or more embodiments, and the synthetic method of the fused polycyclic compound is not limited to one or more embodiments.

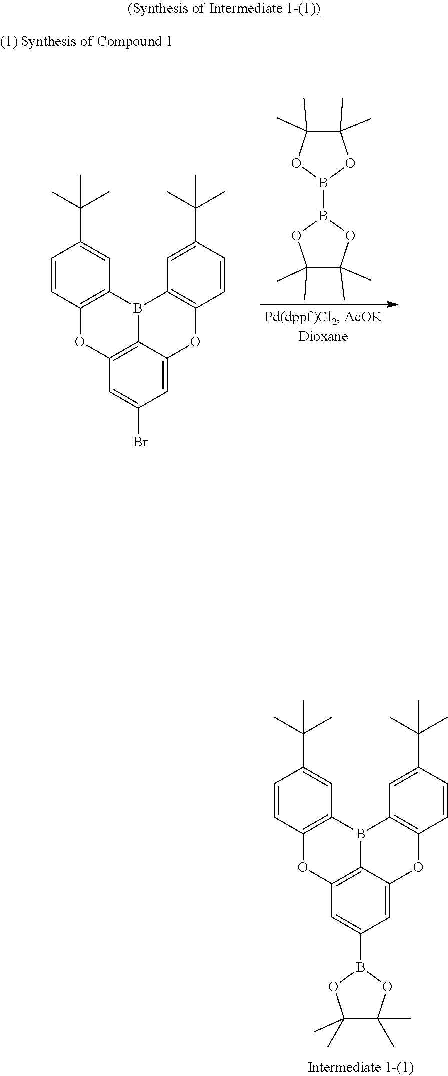

In an argon (Ar) atmosphere, 7-bromo-2,12-di-tert-butyl-5,9-dioxa-13b-boranaphtho[3,2,1-de]anthracene (5 gram (g), 10.84 millimole (mmol)), bis(pinacolato)diboron (5.51 g, 21.68 mmol), Pd(dppf)Cl₂ (0.89 g, 1.08 mmol), and AcOK (2.45 g, 24.93 mmol), were added to 108 mL of dioxane, and the mixture was heated under stirring at about 100° C. for about 8 hours. CH₂Cl₂ and water were added, the mixture was filtered through Celite and separated, and an organic layer was concentrated. The resultant was purified by silica gel column chromatography to obtain Intermediate 1-(1) (8.83 g, yield of 83%). The molecular mass of Intermediate 1-(1) of 981 was obtained by fast-atom bombardment (FAB MS) measurement.

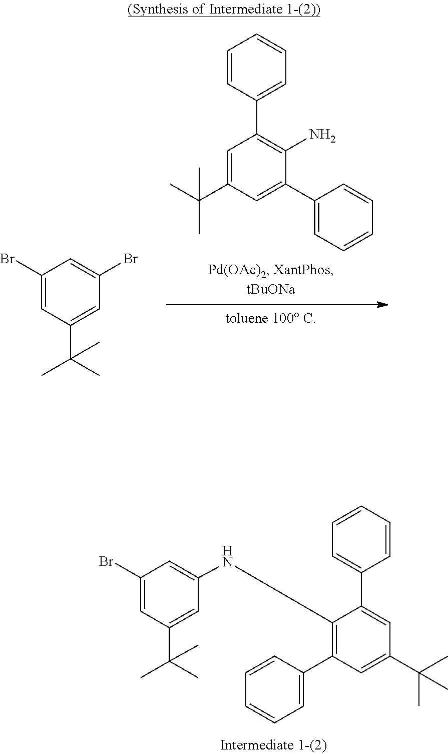 [SMILES: CC(C)(C)c1cc(-c2ccccc2)c(N)c(-c2ccccc2)c1 ; CC(C)(C)c1cc(Br)cc(Br)c1 ; CC(C)(C)c1cc(Br)cc(Nc2c(-c3ccccc3)cc(C(C)(C)C)cc2-c2ccccc2)c1]

In an Ar atmosphere, 1,3-dibromo-5-(tert-butyl)benzene (10.00 g, 34.25 mmol), 5′-(tert-butyl)-[1,1′:3′,1″-terphenyl]-2′-amine (11.35 g, 37.67 mmol), Pd(OAc)₂ (0.23 g, 1.03 mmol), XantPhos (1.19 g, 2.05 mmol), and tBuONa (3.95 g, 41.09 mmol) were added to 171 mL of toluene, and the mixture was heated under stirring at about 100° C. for about 8 hours. Water was added, the mixture was filtered through Celite and separated, and an organic layer was concentrated. The resultant was purified by silica gel column chromatography to obtain Intermediate 1-(2) (15.27 g, yield of 87%). The molecular mass of Intermediate 1-(2) of 513 was obtained by FAB MS measurement.

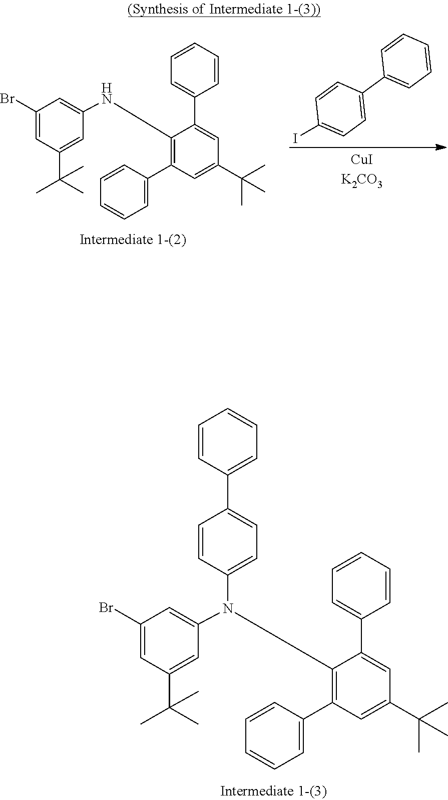

A small amount of toluene, about 10 mL, was added to Intermediate 1-(2) (14.55 g, 28.39 mmol), 4-iodo-1,1′-biphenyl (39.76 g, 141.94 mmol), CuI (11.35 g, 59.61 mmol), and K₂CO₃ (39.24 g, 283.88 mmol) and the mixture was heated for about 24 hours while maintaining an external temperature of about 215° C. The mixture was diluted with CH₂Cl₂, water was added, the mixture was filtered through Celite, and separated, and an organic layer was concentrated. The resultant was purified by silica gel column chromatography to obtain Intermediate 1-(3) (16.04 g, yield of 85%). The molecular mass of Intermediate 1-(3) of 665 was obtained by FAB MS measurement.

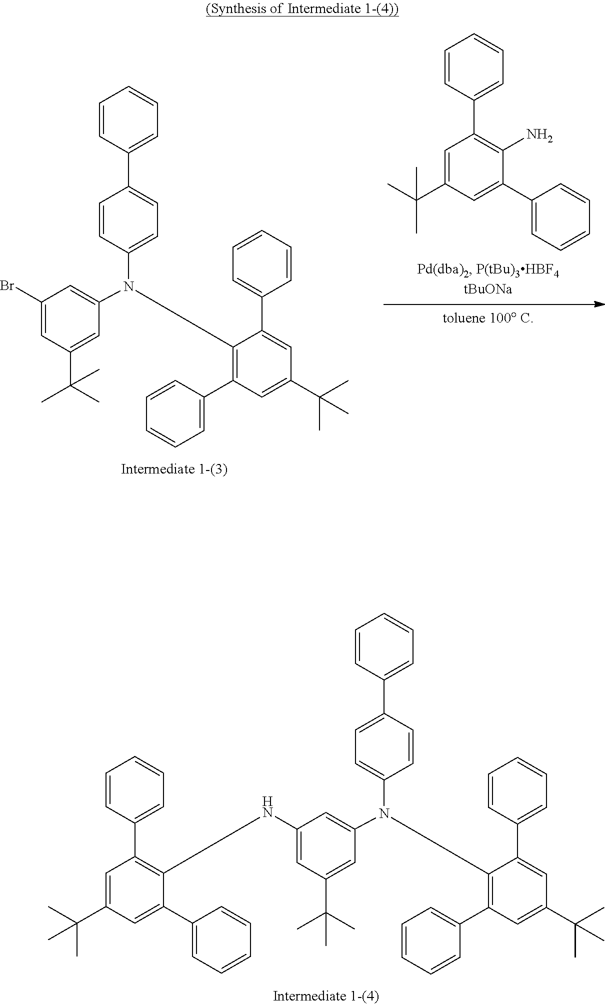 [SMILES: CC(C)(C)c1cc(Br)cc(N(c2ccc(-c3ccccc3)cc2)c2c(-c3ccccc3)cc(C(C)(C)C)cc2-c2ccccc2)c1 ; CC(C)(C)c1cc(-c2ccccc2)c(N)c(-c2ccccc2)c1 ; CC(C)(C)c1cc(Nc2c(-c3ccccc3)cc(C(C)(C)C)cc2-c2ccccc2)cc(N(c2ccc(-c3ccccc3)cc2)c2c(-c3ccccc3)cc(C(C)(C)C)cc2-c2ccccc2)c1]

In an Ar atmosphere, Intermediate 1-(3) (15.56 g, 23.41 mmol), 5′-(tert-butyl)-[1,1′:3′,1″-terphenyl]-2′-amine (14.11 g, 46.82 mmol), Pd(dba)₂ (1.35 g, 2.34 mmol), P(tBu)₃·HBF₄ (1.36 g, 4.68 mmol), and tBuONa (5.17 g, 53.84 mmol) were added to 117 mL of toluene, and the mixture was heated under stirring at about 100° C. for about 8 hours. Water was added, the mixture was filtered through Celite and separated, and an organic layer was concentrated. The resultant was purified by silica gel column chromatography to obtain Intermediate 1-(4) (17.20 g, yield of 83%). The molecular mass of Intermediate 1-(4) of 885 was obtained by FAB MS measurement.

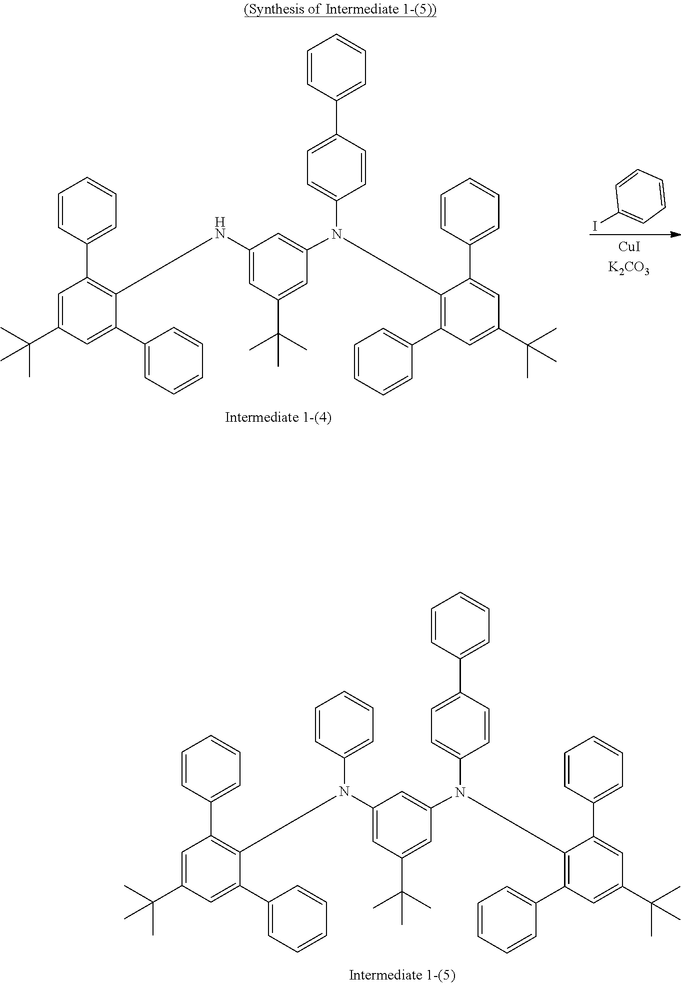

A small amount of toluene, about 10 mL, was added to Intermediate 1-(4) (16.03 g, 18.11 mmol), iodobenzene (18.47 g, 90.54 mmol), CuI (7.24 g, 38.03 mmol), K₂CO₃ (25.03 g, 181.08 mmol) and the mixture was heated for about 24 hours while maintaining an external temperature of about 215° C. The mixture was diluted with CH₂Cl₂, water was added, the mixture was filtered through Celite, and separated, and an organic layer was concentrated. The resultant was purified by silica gel column chromatography to obtain Intermediate 1-(5) (14.45 g, yield of 83%). The molecular mass of Intermediate 1-(5) of 961 was obtained by FAB MS measurement.

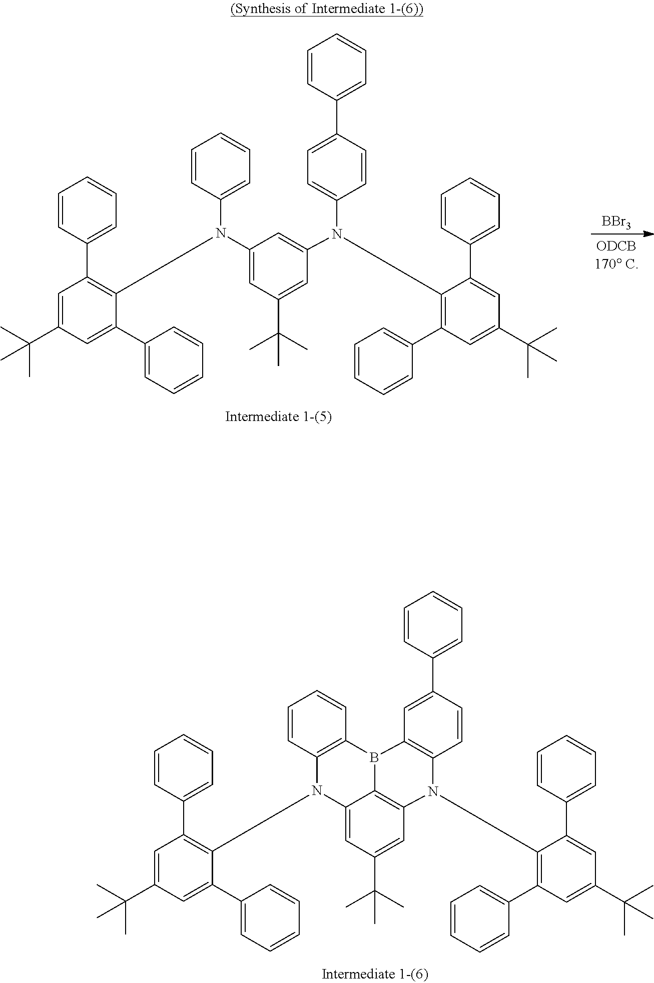

In an Ar atmosphere, Intermediate 1-(5) (5.01 g, 5.21 mmol) was dissolved in ODCB (52 mL), BBr₃ (2.61 g, 10.42 mmol) was added, and the mixture was heated under stirring at about 170° C. for about 10 hours. Cooled to a room temperature, DIPEA (8.07 g, 62.54 mmol) was added, water was added, the mixture was filtered through Celite, then separated, and an organic layer was concentrated. The resultant was purified by silica gel column chromatography to obtain Intermediate 1-(6) (1.82 g, yield of 36%). The molecular mass of Intermediate 1-(6) of 969 was obtained by FAB MS measurement.

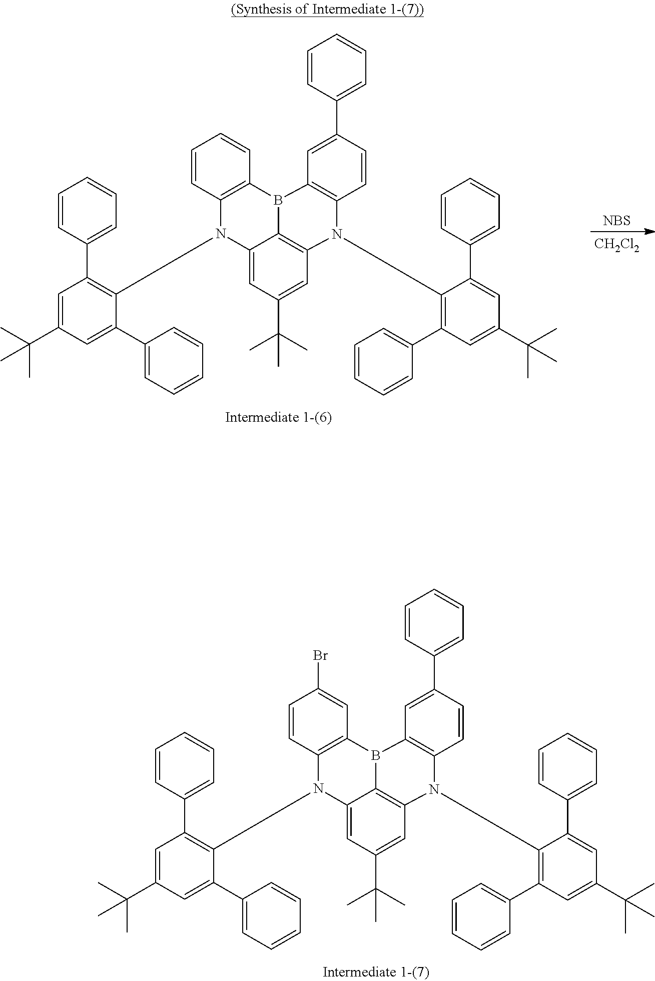

In an Ar atmosphere, Intermediate 1-(6) (1.57 g, 1.62 mmol) was dissolved in CH₂Cl₂ (16 mL), N-bromosuccinimide (0.29 g, 1.62 mmol) was added, and the mixture was stirred at room temperature for about 24 hours. Water was added, the mixture was filtered through Celite, then separated, and an organic layer was concentrated. The resultant was purified by silica gel column chromatography to obtain Intermediate 1-(7) (1.49 g, yield of 88%). The molecular mass of Intermediate 1-(7) of 1048 was obtained by FAB MS measurement.

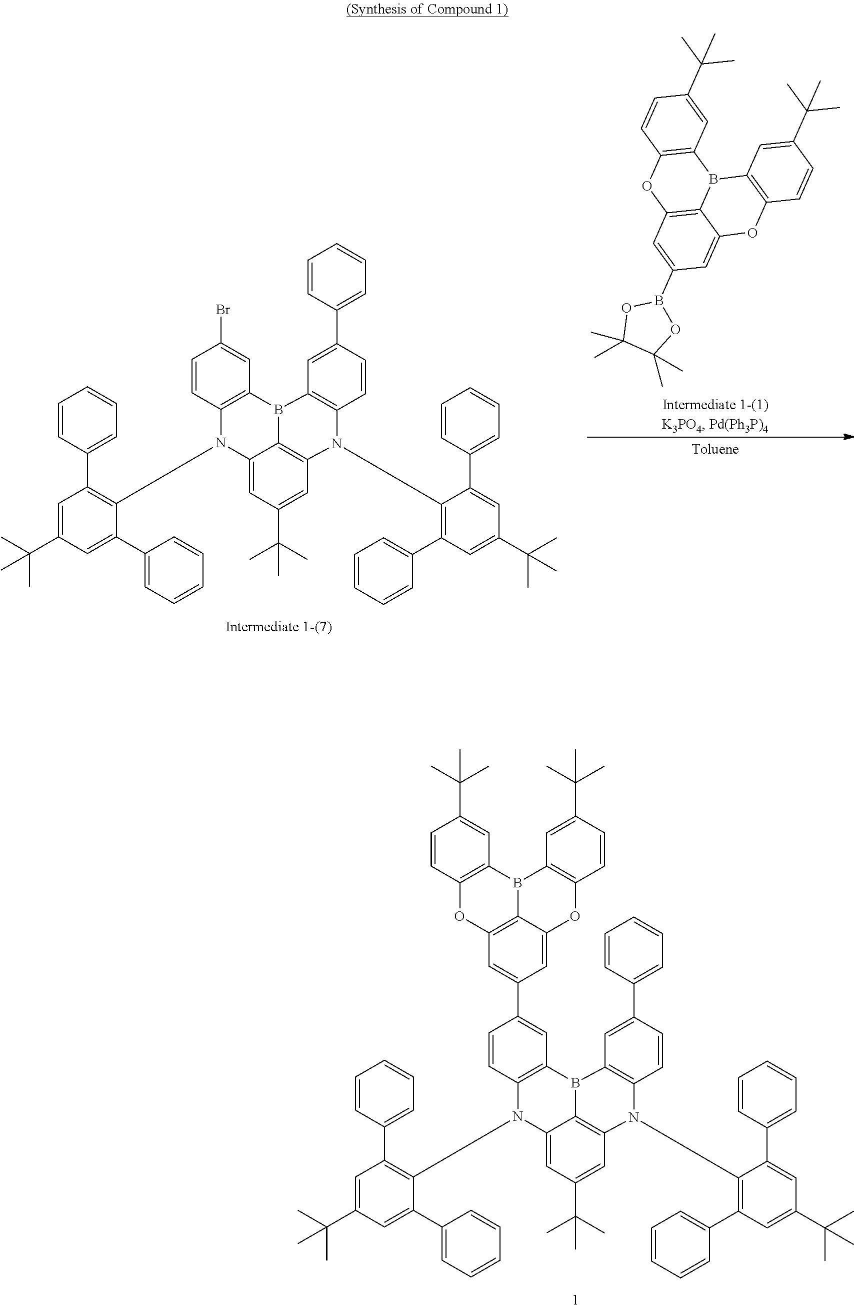

In an Ar atmosphere, toluene 10.64 mL, and a mixture of EtOH and water in a ratio of 1:1 of 5.32 mL were added to Intermediate 1-(7) (1.33 g, 1.8 mmol), Intermediate 1-(1) (1.10 g, 2.16 mmol), K₃PO₄ (0.76 g, 3.59 mmol), and Pd(Ph₃P)₄ (0.21 g, 0.18 mmol), and the mixture was heated for about 24 hours while maintaining an external temperature of about 80° C. The mixture was filtered through Celite, and separated, and an organic layer was concentrated. The resultant was purified by silica gel column chromatography to obtain Compound 1 (1.79 g, yield of 74%). The molecular mass of Compound 1 of 1349 was obtained by FAB MS measurement.

Compound 1 was purified by sublimation (350° C., 2.1×10⁻³ pascal (Pa)) and then evaluated for device performance.

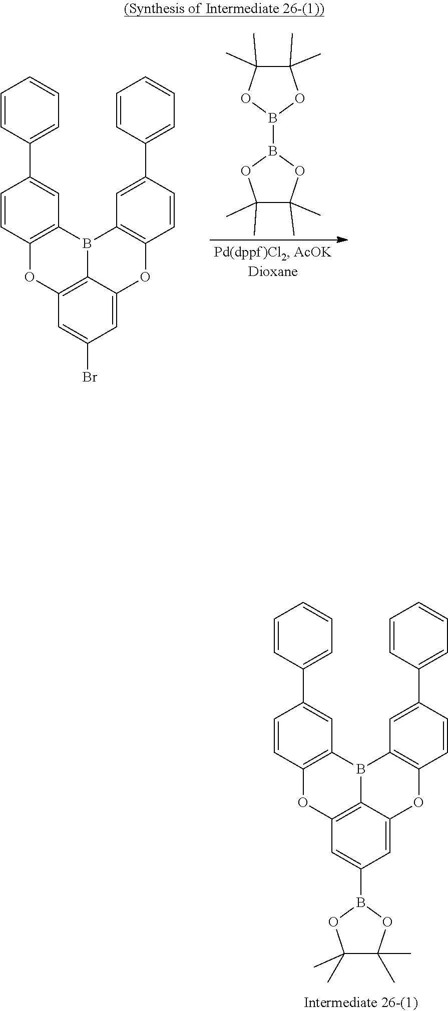

In an Ar atmosphere, 7-bromo-2,12-diphenyl-5,9-dioxa-13b-boranaphtho[3,2,1-de]anthracene (15.02 g, 29.97 mmol), bis(pinacolato)diboron (15.22 g, 59.94 mmol), Pd(dppf)Cl₂ (2.45 g, 3 mmol), and AcOK (6.76 g, 68.93 mmol) were added to dioxane 299 mL, and the mixture was heated for about 8 hours at about 100° C. under stirring. CH₂Cl₂ and water were added, the mixture was filtered through Celite, and separated, and an organic layer was concentrated. The resultant was purified by silica gel column chromatography to obtain Intermediate 26-(1) (13.97 g, yield of 85%). The molecular mass of Intermediate 26-(1) of 548 was obtained by FAB MS measurement.

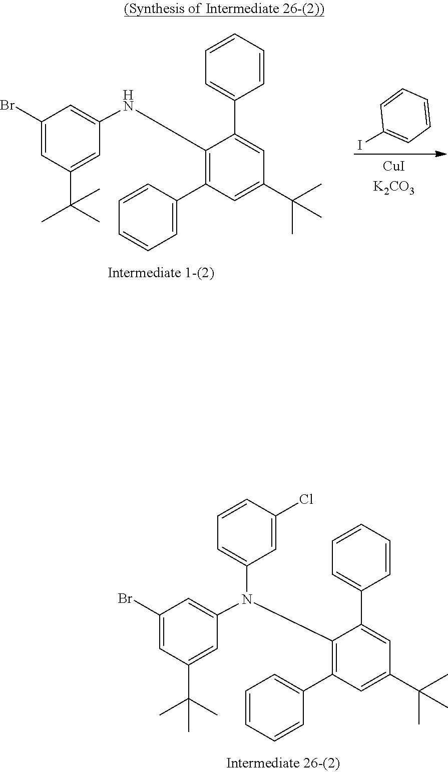 [SMILES: CC(C)(C)c1cc(Br)cc(Nc2c(-c3ccccc3)cc(C(C)(C)C)cc2-c2ccccc2)c1 ; Ic1ccccc1 ; CC(C)(C)c1cc(Br)cc(N(c2cccc(Cl)c2)c2c(-c3ccccc3)cc(C(C)(C)C)cc2-c2ccccc2)c1]

A small amount of toluene, about 10 mL, was added to Intermediate 1-(2) (16.03 g, 31.28 mmol), 1-chloro-3-iodobenzene (37.29 g, 156.38 mmol), CuI (12.51 g, 65.68 mmol), and K₂CO₃ (43.23 g, 312.76 mmol) and the mixture was heated for about 24 hours while maintaining an external temperature of about 215° C. The mixture was diluted with CH₂Cl₂, water was added, the mixture was filtered through Celite, and separated, and an organic layer was concentrated. The resultant was purified by silica gel column chromatography to obtain Intermediate 26-(2) (15.2 g, yield of 78%). The molecular mass of Intermediate 26-(2) of 623 was obtained by FAB MS measurement.

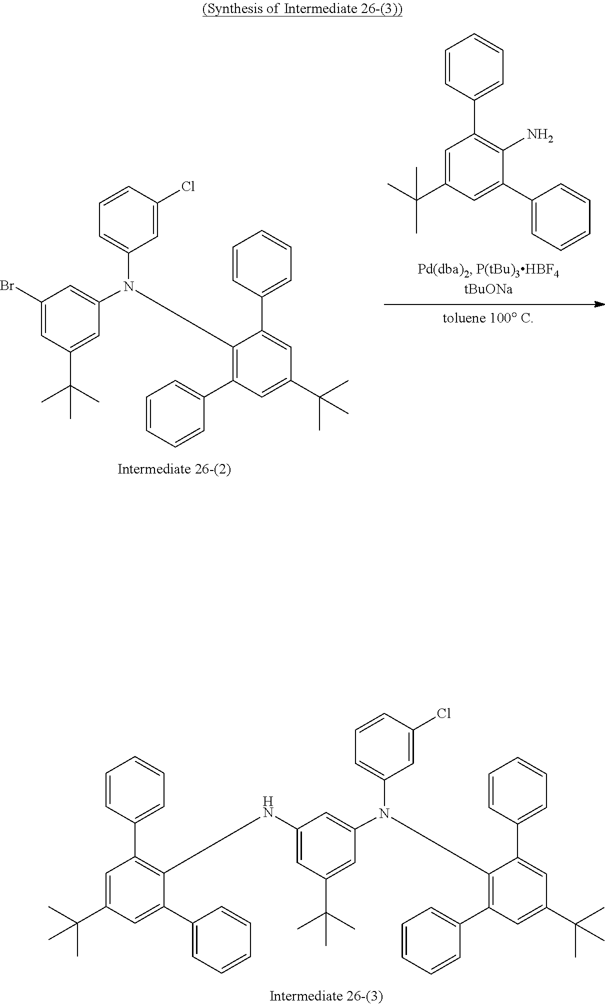 [SMILES: CC(C)(C)c1cc(Br)cc(N(c2cccc(Cl)c2)c2c(-c3ccccc3)cc(C(C)(C)C)cc2-c2ccccc2)c1 ; CC(C)(C)c1cc(-c2ccccc2)c(N)c(-c2ccccc2)c1 ; CC(C)(C)c1cc(Nc2c(-c3ccccc3)cc(C(C)(C)C)cc2-c2ccccc2)cc(N(c2cccc(Cl)c2)c2c(-c3ccccc3)cc(C(C)(C)C)cc2-c2ccccc2)c1]

In an Ar atmosphere, toluene of about 105 mL was added to Intermediate 26-(2) (13.11 g, 21.04 mmol), 5′-(tert-butyl)-[1,1′:3′,1″-terphenyl]-2′-amine (7.61 g, 25.25 mmol), Pd(dba)₂ (1.21 g, 2.1 mmol), P(tBu)₃·HBF₄ (1.22 g, 4.21 mmol), and tBuONa (4.65 g, 48.39 mmol) and the mixture was heated under stirring for about 8 hours at about 100° C. Water was added, and the mixture was filtered through Celite, and separated, and an organic layer was concentrated. The resultant was purified by silica gel column chromatography to obtain Intermediate 26-(3) (14.55 g, yield of 82%). The molecular mass of Intermediate 26-(3) (14.55 g, yield of 82%) of 844 was obtained by FAB MS measurement.

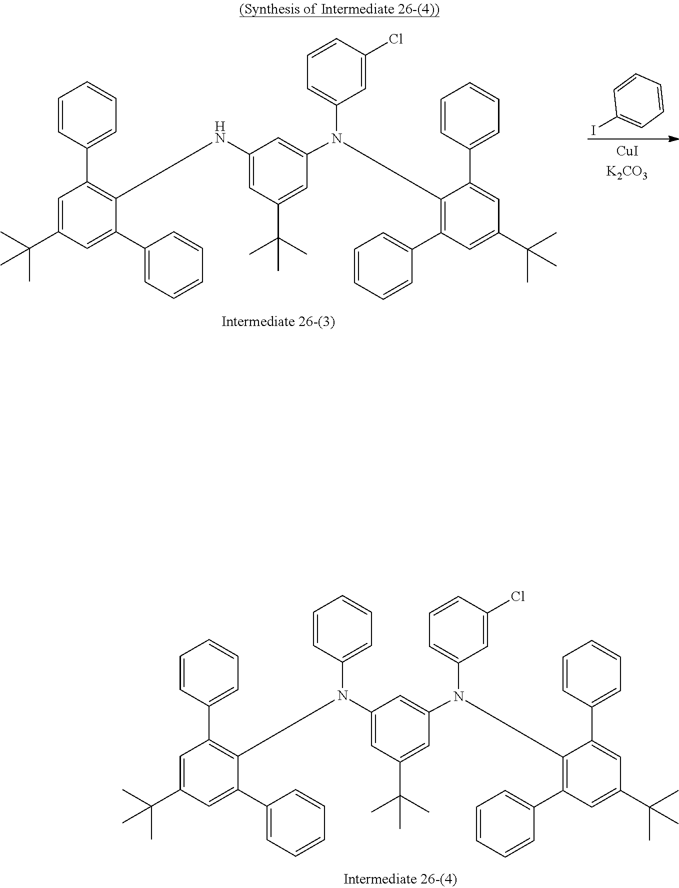

A small amount of toluene, about 10 mL, was added to Intermediate 26-(3) (13.86 g, 16.43 mmol), iodobenzene (16.76 g, 82.15 mmol), CuI (6.57 g, 34.5 mmol), and K₂CO₃ (22.71 g, 164.3 mmol) and the mixture was heated for about 24 hours while maintaining an external temperature of about 215° C. The mixture was diluted with CH₂Cl₂, water was added, and the mixture was filtered through Celite, and separated, and an organic layer was concentrated. The resultant was purified by silica gel column chromatography to obtain Intermediate 26-(4) (12.69 g, yield of 84%). The molecular mass of Intermediate 26-(4) of 920 was obtained by FAB MS measurement.

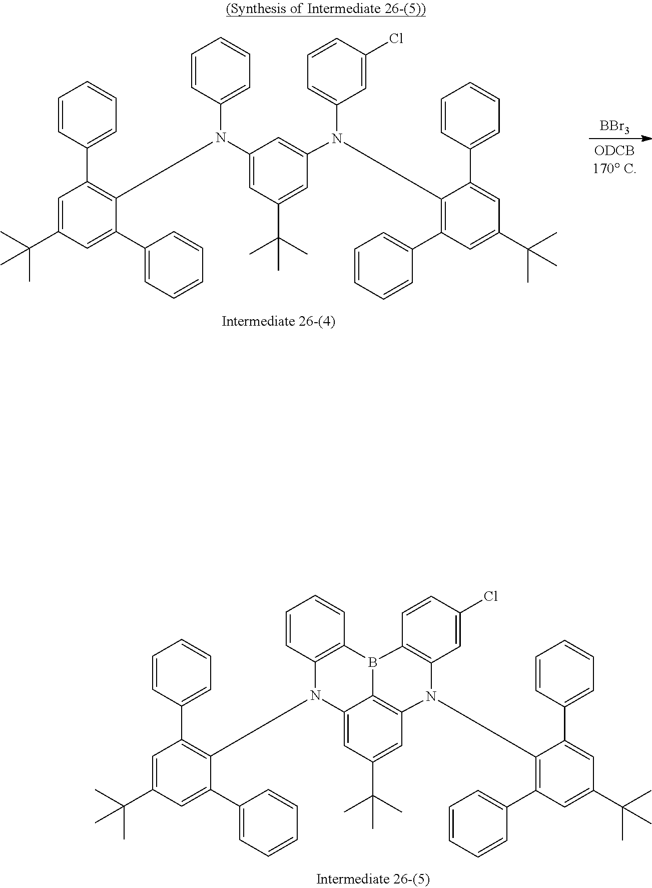

In an Ar atmosphere, Intermediate 26-(4) (12.33 g, 13.41 mmol) was dissolved in ODCB (134 mL), BBr₃ (6.72 g, 26.81 mmol) was added, and the mixture was heated under stirring at about 170° C. for about 10 hours. Cooled to a room temperature, DIPEA (20.75 g, 160.88 mmol) was added, water was added, the mixture was filtered through Celite, then separated, and an organic layer was concentrated. The resultant was purified by silica gel column chromatography to obtain Intermediate 26-(5) (3.98 g, yield of 32%). The molecular mass of Intermediate 26-(5) of 927 was obtained by FAB MS measurement.

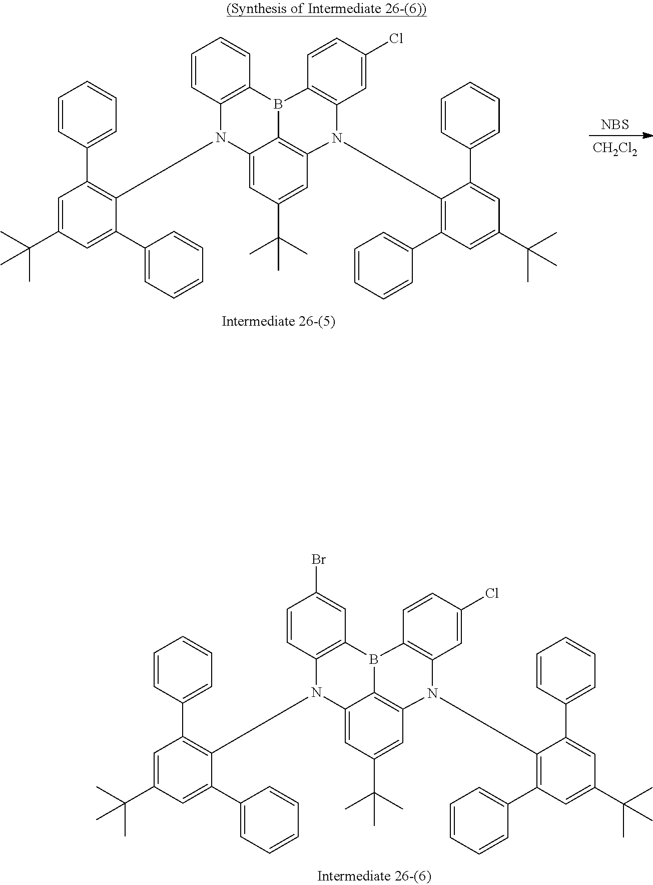

In an Ar atmosphere, Intermediate 26-(5) (3.66 g, 3.95 mmol) was dissolved in CH₂Cl₂ (39 mL), N-bromosuccinimide (0.7 g, 3.95 mmol) was added, and the mixture was stirred at room temperature for about 24 hours. Water was added, the mixture was filtered through Celite, then separated, and an organic layer was concentrated. The resultant was purified by silica gel column chromatography to obtain Intermediate 26-(6) (2.86 g, yield of 72%). The molecular mass of Intermediate 26-(6) of 1006 was obtained by FAB MS measurement.

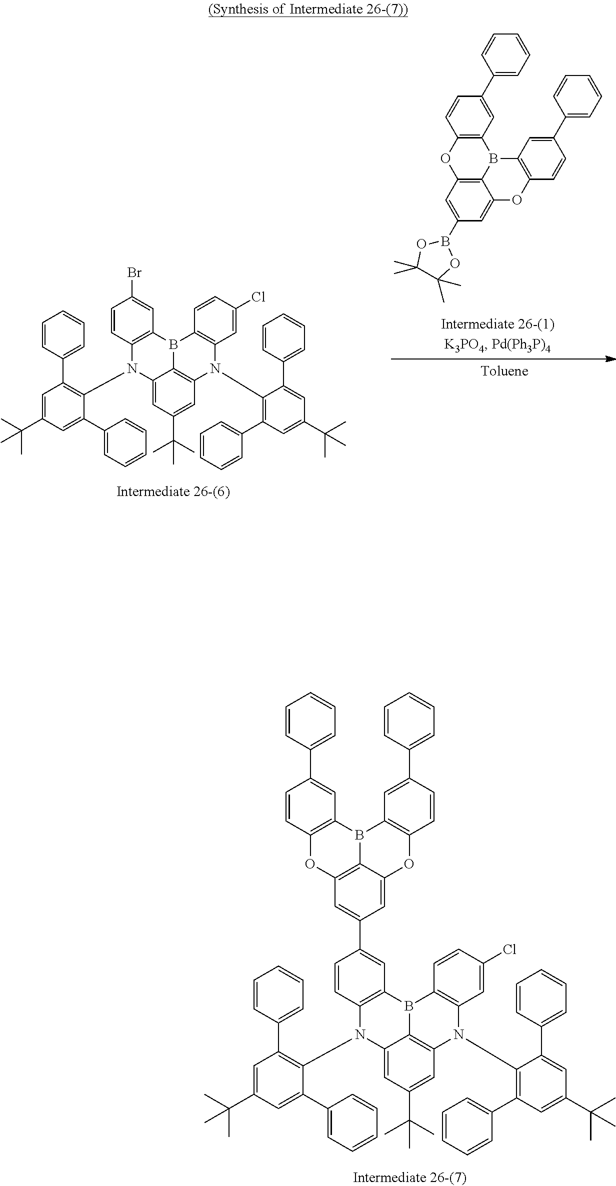 [SMILES: CC(C)(C)c1cc(-c2ccccc2)c(N2c3ccc(Br)cc3B3c4ccc(Cl)cc4N(c4c(-c5ccccc5)cc(C(C)(C)C)cc4-c4ccccc4)c4cc(C(C)(C)C)cc2c43)c(-c2ccccc2)c1 ; CC1(C)OB(c2cc3c4c(c2)Oc2ccc(-c5ccccc5)cc2B4c2cc(-c4ccccc4)ccc2O3)OC1(C)C ; CC(C)(C)c1cc(-c2ccccc2)c(N2c3ccc(-c4cc5c6c(c4)Oc4ccc(-c7ccccc7)cc4B6c4cc(-c6ccccc6)ccc4O5)cc3B3c4ccc(Cl)cc4N(c4c(-c5ccccc5)cc(C(C)(C)C)cc4-c4ccccc4)c4cc(C(C)(C)C)cc2c43)c(-c2ccccc2)c1]

In an Ar atmosphere, toluene of 20.08 mL, and a mixture of EtOH and water in a ratio of 1:1 of 10.04 mL were added to, Intermediate 26-(6) (2.51 g, 2.49 mmol), Intermediate 26-(1) (1.64 g, 2.99 mmol), K₃PO₄ (1.06 g, 4.99 mmol), and Pd(Ph₃P)₄ (0.29 g, 0.25 mmol), and the mixture was heated for about 24 hours while maintaining an external temperature of about 80° C. The resultant was filtered through Celite, then separated, and an organic layer was concentrated. The resulting product was purified by silica gel column chromatography to obtain Intermediate 26-(7) (2.82 g, yield of 84%). The molecular mass of Intermediate 26-(7) of 1348 was obtained by FAB MS measurement.

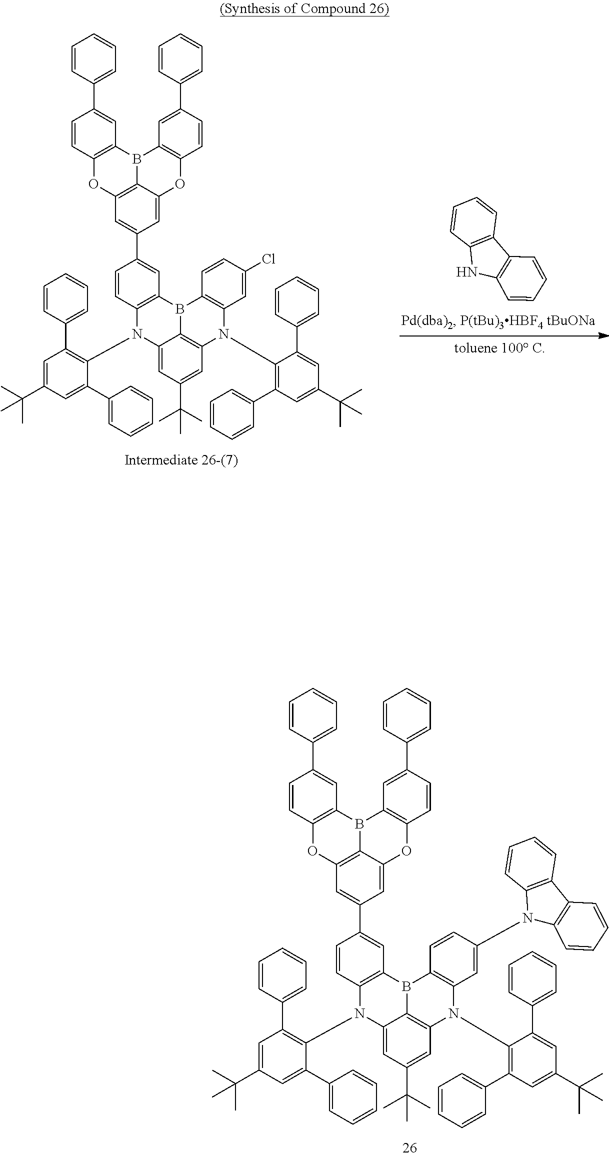 [SMILES: CC(C)(C)c1cc(-c2ccccc2)c(N2c3ccc(-c4cc5c6c(c4)Oc4ccc(-c7ccccc7)cc4B6c4cc(-c6ccccc6)ccc4O5)cc3B3c4ccc(Cl)cc4N(c4c(-c5ccccc5)cc(C(C)(C)C)cc4-c4ccccc4)c4cc(C(C)(C)C)cc2c43)c(-c2ccccc2)c1 ; c1ccc2c(c1)[nH]c1ccccc12 ; CC(C)(C)c1cc(-c2ccccc2)c(N2c3ccc(-c4cc5c6c(c4)Oc4ccc(-c7ccccc7)cc4B6c4cc(-c6ccccc6)ccc4O5)cc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1]

In an Ar atmosphere, Intermediate 26-(7) (2.51 g, 1.86 mmol), 9H-carbazole (0.37 g, 2.23 mmol), Pd(dba)₂ (0.11 g, 0.19 mmol), P(tBu)₃·HBF₄ (0.11 g, 0.37 mmol), and tBuONa (0.41 g, 4.28 mmol) were added to toluene of 9 mL, and the mixture was heated under stirring for about 8 hours at about 100° C. Water was added, the mixture was filtered through Celite, then separated, and an organic layer was concentrated. The resultant was purified by silica gel column chromatography to obtain Compound 26 (2.51 g, yield of 91%). The molecular mass of Compound 26 of 1479 was obtained by FAB MS measurement.

Compound 26 was purified by sublimation (370° C., 2.8×10⁻³ Pa) and then evaluated for device performance.

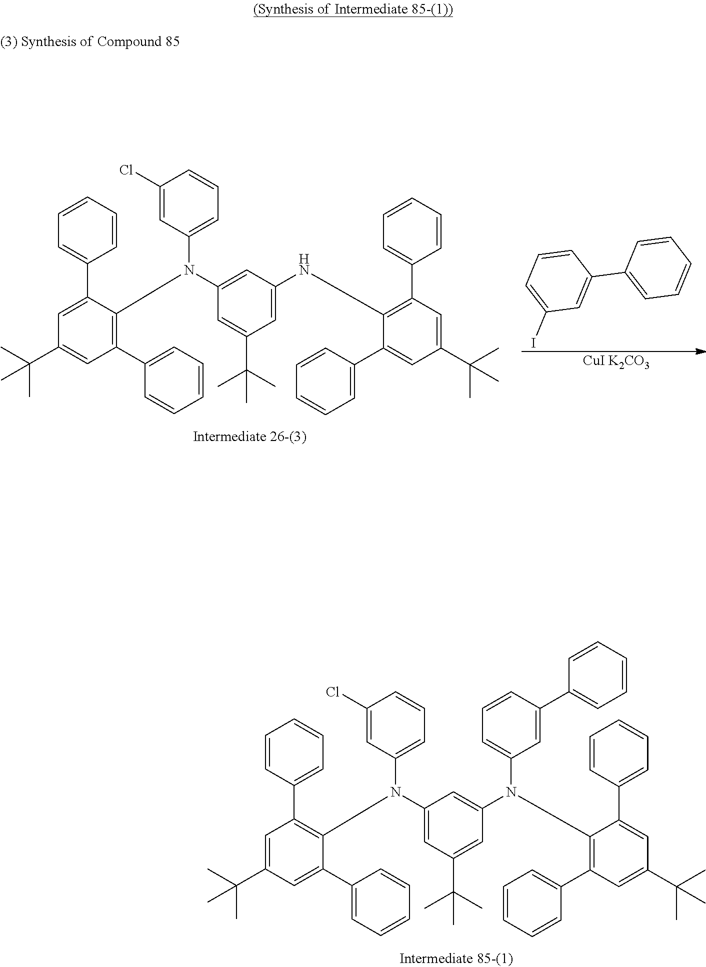

A small amount of toluene, about 10 mL, was added to Intermediate 26-(3) (5.63 g, 6.67 mmol), 3-iodo-1,1′-biphenyl (9.35 g, 33.37 mmol), CuI (2.67 g, 14.01 mmol), and K₂CO₃ (9.22 g, 66.74 mmol) and the mixture was heated for about 24 hours while maintaining an external temperature of about 215° C. The mixture was diluted with CH₂Cl₂, water was added, the mixture was filtered through Celite, and separated, and an organic layer was concentrated. The resultant was purified by silica gel column chromatography to obtain Intermediate 85-(1) (5.72 g, yield of 86%). The molecular mass of Intermediate 85-(1) of 996 was obtained by FAB MS measurement.

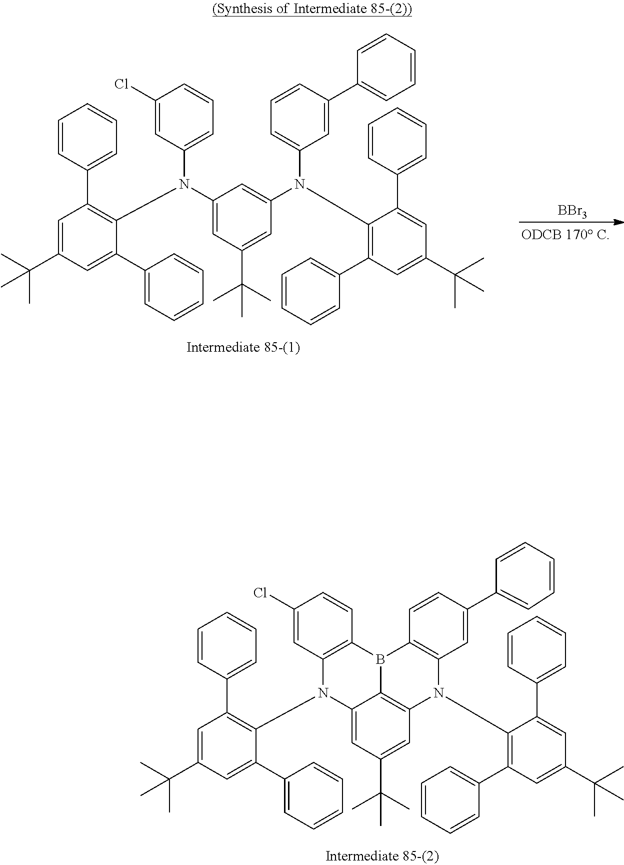

In an Ar atmosphere, Intermediate 85-(1) (5.22 g, 5.24 mmol) was dissolved in ODCB (52 mL), BBr₃ ((2.63 g, 10.48 mmol) was added, and the mixture was heated under stirring at about 170° C. for about 10 hours. Cooled to a room temperature, DIPEA (8.11 g, 62.9 mmol) was added, water was added, the mixture was filtered through Celite, then separated, and an organic layer was concentrated. The resultant was purified by silica gel column chromatography to obtain Intermediate 85-(2) (2.37 g, yield of 45%). The molecular mass of Intermediate 85-(2) of 1004 was obtained by FAB MS measurement.

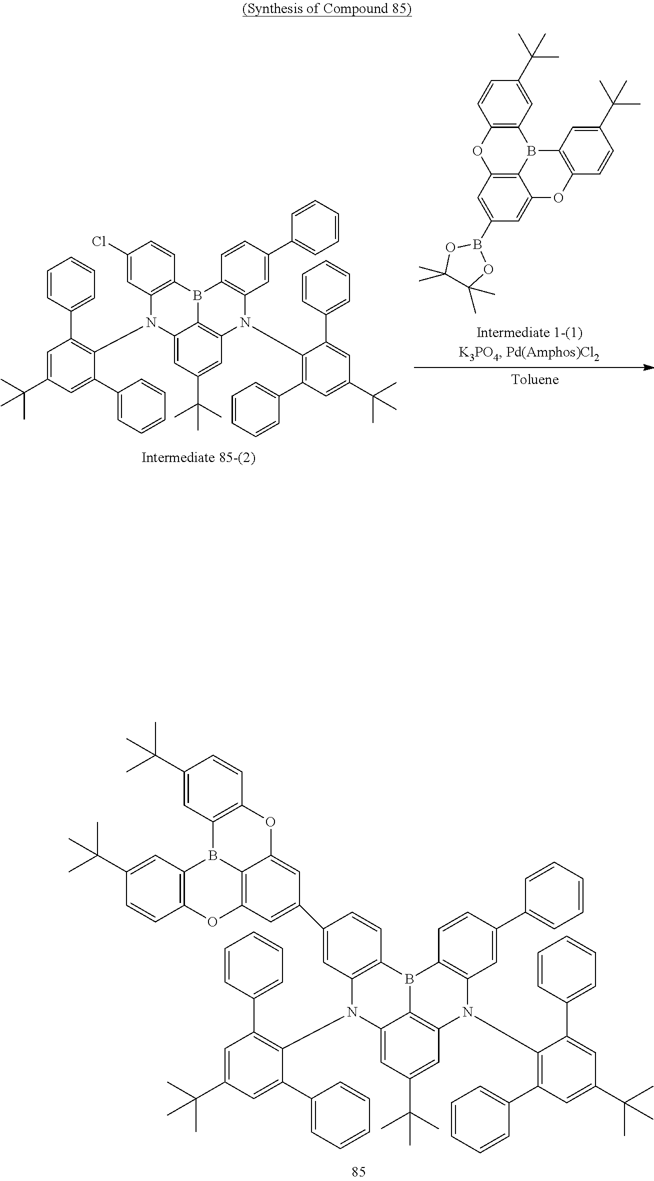

In an Ar atmosphere, toluene of 17.2 mL, and a mixture of EtOH and water in a ratio of 1:1 of 8.6 mL were added to Intermediate 85-(2) (2.15 g, 2.14 mmol), Intermediate 1-(1) (4.36 g, 8.57 mmol), K₃PO₄ (0.91 g, 4.28 mmol), and Pd(Amphos)Cl₂ (0.15 g, 0.21 mmol), and the mixture was heated for about 24 hours while maintaining an external temperature of about 40° C. The mixture was filtered through Celite, then separated, and an organic layer was concentrated. The resultant was purified by silica gel column chromatography to obtain Compound 85 (2.34 g, yield of 81%). The molecular mass of Compound 85 of 1349 was obtained by FAB MS measurement.

Compound 26 was purified by sublimation (350° C., 2.1×10⁻³ Pa) and then evaluated for device performance.

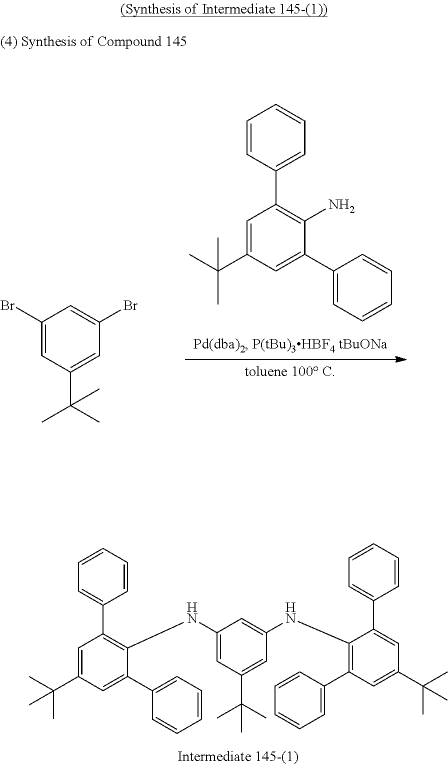 [SMILES: CC(C)(C)c1cc(Br)cc(Br)c1 ; CC(C)(C)c1cc(-c2ccccc2)c(N)c(-c2ccccc2)c1 ; CC(C)(C)c1cc(Nc2c(-c3ccccc3)cc(C(C)(C)C)cc2-c2ccccc2)cc(Nc2c(-c3ccccc3)cc(C(C)(C)C)cc2-c2ccccc2)c1]

In an Ar atmosphere, 1,3-dibromo-5-(tert-butyl)benzene (8.88 g, 30.41 mmol), 5′-(tert-butyl)-[1,1′:3′,1″-terphenyl]-2′-amine (22.92 g, 76.02 mmol), Pd(dba)₂ (1.75 g, 3.04 mmol), P(tBu)₃·HBF₄ (1.76 g, 6.08 mmol), and tBuONa (6.72 g, 69.94 mmol), were added to 152 mL of toluene, and the mixture was heated under stirring at about 100° C. for about 8 hours. Water was added, the mixture was filtered through Celite and separated, and an organic layer was concentrated. The resultant was purified by silica gel column chromatography to obtain Intermediate 145-(1) (19.84 g, yield of 89%). The molecular mass of Intermediate 145-(1) of 733 was obtained by FAB MS measurement.

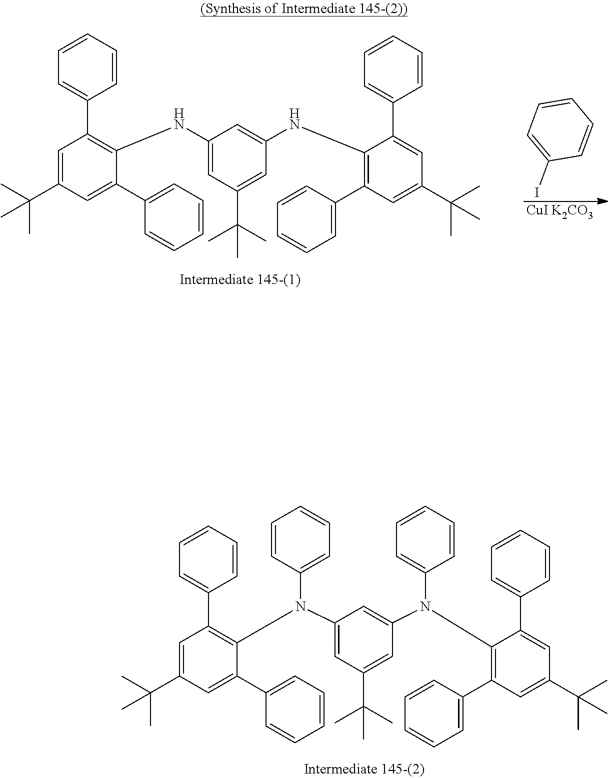

A small amount of toluene, about 10 mL, was added to Intermediate 145-(1) (5.63 g, 7.68 mmol), iodobenzene (7.83 g, 38.4 mmol), CuI (3.07 g, 16.13 mmol), and K₂CO₃ (10.61 g, 76.8 mmol) and the mixture was heated for about 24 hours while maintaining an external temperature of about 215° C. The mixture was diluted with CH₂Cl₂, water was added, the mixture was filtered through Celite, and separated, and an organic layer was concentrated. The resultant was purified by silica gel column chromatography to obtain Intermediate 145-(2) (5.85 g, yield of 86%). The molecular mass of Intermediate 145-(2) of 885 was obtained by FAB MS measurement.

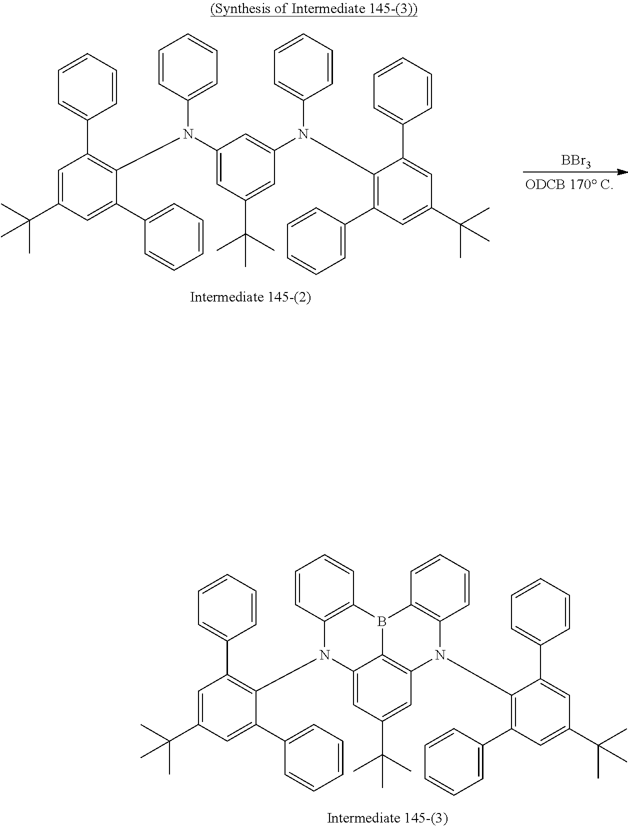

In an Ar atmosphere, Intermediate 145-(2) (5.74 g, 6.48 mmol) was dissolved in ODCB (65 ml), BBr₃ (3.25 g, 12.97 mmol) was added, and the mixture was heated under stirring at about 170° C. for about 10 hours. Cooled to a room temperature, DIPEA (10.04 g, 77.81 mmol) was added, water was added, the mixture was filtered through Celite, then separated, and an organic layer was concentrated. The resultant was purified by silica gel column chromatography to obtain Intermediate 145-(3) (2.37 g, yield of 41%). The molecular mass of Intermediate 145-(3) of 893 was obtained by FAB MS measurement.

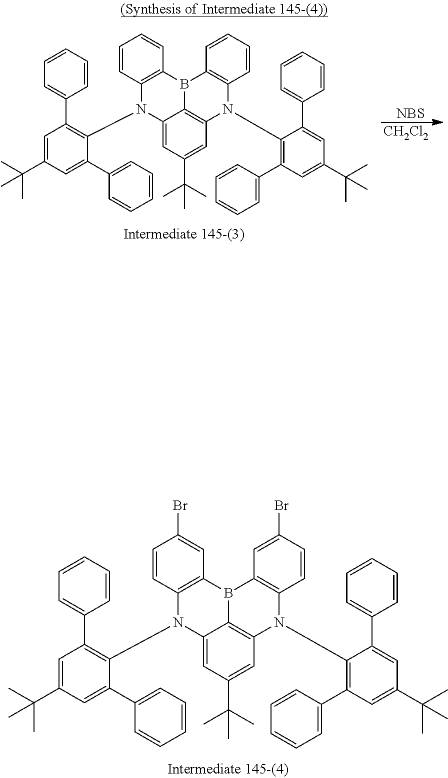

In an Ar atmosphere, Intermediate 145-(3) (2.04 g, 2.28 mmol) was dissolved in CH₂Cl₂ (23 mL), N-bromosuccinimide (0.81 g, 4.57 mmol) was added, and the mixture was stirred at room temperature for about 24 hours. Water was added, the mixture was filtered through Celite, then separated, and an organic layer was concentrated. The resultant was purified by silica gel column chromatography to obtain Intermediate 145-(4) (2.16 g, yield of 90%). The molecular mass of Intermediate 145-(4) of 1051 was obtained by FAB MS measurement.

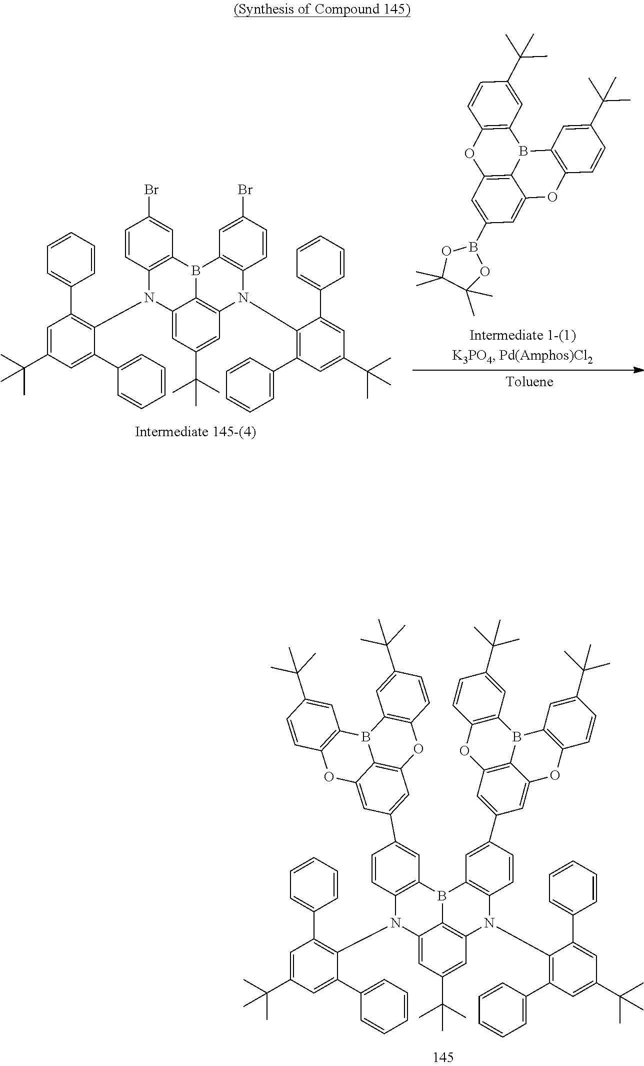

In an Ar atmosphere, toluene of 15.04 mL, and a mixture of EtOH and water in a ratio of 1:1 of 7.52 mL were added to Intermediate 145-(4) (1.88 g, 1.79 mmol), Intermediate 1-(1) (1.91 g, 3.76 mmol), K₃PO₄ (0.76 g, 3.58 mmol), and Pd(Amphos)Cl₂ (0.13 g, 0.18 mmol), and the mixture was heated for about 24 hours while maintaining an external temperature of about 40° C. The mixture was filtered through Celite, and separated, and an organic layer was concentrated. The resultant was purified by silica gel column chromatography to obtain Compound 145 (2.4 g, yield of 81%). The molecular mass of Compound 145 of 1654 was obtained by FAB MS measurement.

Compound 145 was purified by sublimation (380° C., 2.4×10⁻³ Pa) and then evaluated for device performance.

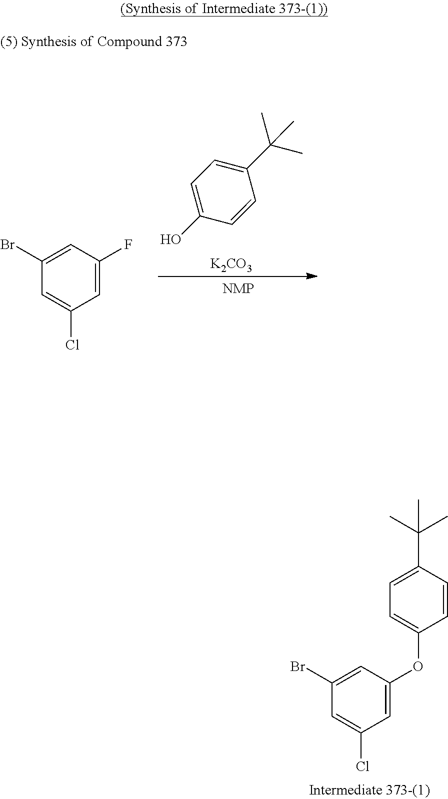

In an Ar atmosphere, 1-bromo-3-chloro-5-fluorobenzene (10.04 g, 47.94 mmol), 4-(tert-butyl)phenol (7.95 g, 57.52 mmol), and K₂CO₃ (29.81 g, 215.72 mmol) were added to NMP of 100 mL, and the mixture was heated for about 24 hours while maintaining an external temperature of about 140° C. The mixture was diluted with CH₂Cl₂, water was added, the mixture was filtered through Celite, and separated, and an organic layer was concentrated. The resultant was purified by silica gel column chromatography to obtain Intermediate 373-(1) (14.49 g, yield of 89%). The molecular mass of Intermediate 373-(1) of 340 was obtained by FAB MS measurement.

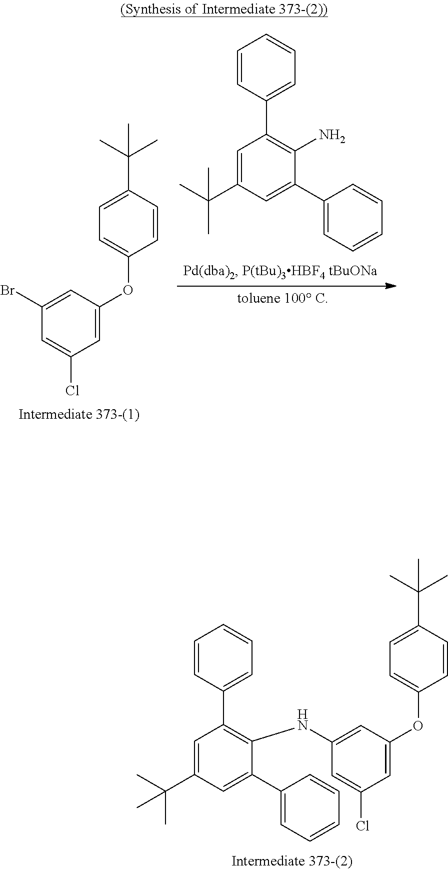

In an Ar atmosphere, Intermediate 373-(1) (13.56 g, 39.92 mmol), 5′-(tert-butyl)-[1,1′:3′,1″-terphenyl]-2′-amine (12.64 g, 41.92 mmol), Pd(dba)₂ (2.3 g, 3.99 mmol), P(tBu)₃·HBF₄ (2.32 g, 7.98 mmol), and tBuONa (8.82 g, 91.82 mmol) were added to 199 mL of toluene, and the mixture was heated under stirring at about 100° C. for about 8 hours. Water was added, the mixture was filtered through Celite and separated, and an organic layer was concentrated. The resultant was purified by silica gel column chromatography to obtain Intermediate 373-(2) (16.77 g, yield of 75%). The molecular mass of Intermediate 373-(2) of 560 was obtained by FAB MS measurement.

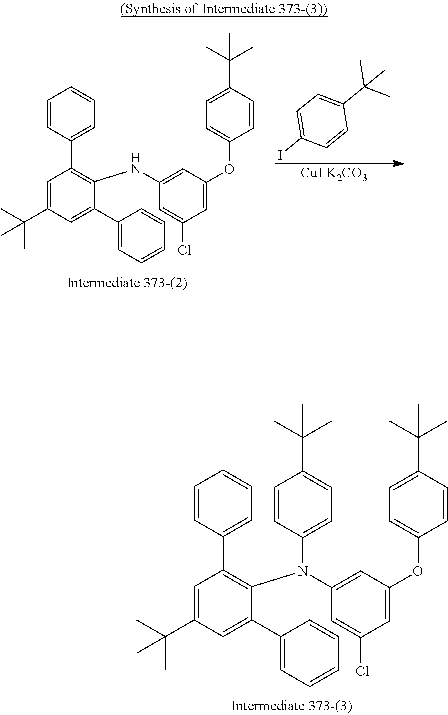

A small amount of toluene, about 10 mL, was added to Intermediate 373-(2) (15.23 g, 27.19 mmol), 1-(tert-butyl)-4-iodobenzene (35.36 g, 135.94 mmol), CuI (10.87 g, 57.09 mmol), and K₂CO₃ (37.58 g, 271.88 mmol) and the mixture was heated for about 24 hours while maintaining an external temperature of about 215° C. The mixture was diluted with CH₂Cl₂, water was added, the mixture was filtered through Celite, and separated, and an organic layer was concentrated. The resultant was purified by silica gel column chromatography to obtain Intermediate 373-(3) (15.81 g, yield of 84%). The molecular mass of Intermediate 373-(3) of 692 was obtained by FAB MS measurement.

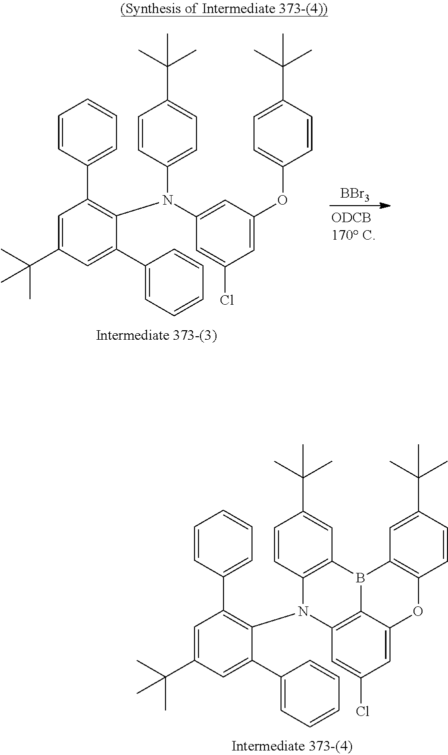

In an Ar atmosphere, Intermediate 373-(3) (12.19 g, 17.61 mmol) was dissolved in ODCB (176 ml), BBr₃ (8.82 g, 35.21 mmol) was added, and the mixture was heated under stirring at about 170° C. for about 10 hours. Cooled to a room temperature, DIPEA (27.25 g, 211.27 mmol) was added, water was added, the mixture was filtered through Celite, and separated, and an organic layer was concentrated. The resultant was purified by silica gel column chromatography to obtain Intermediate 373-(4) (4.68 g, yield of 38%). The molecular mass of Intermediate 373-(4) of 700 was obtained by FAB MS measurement.

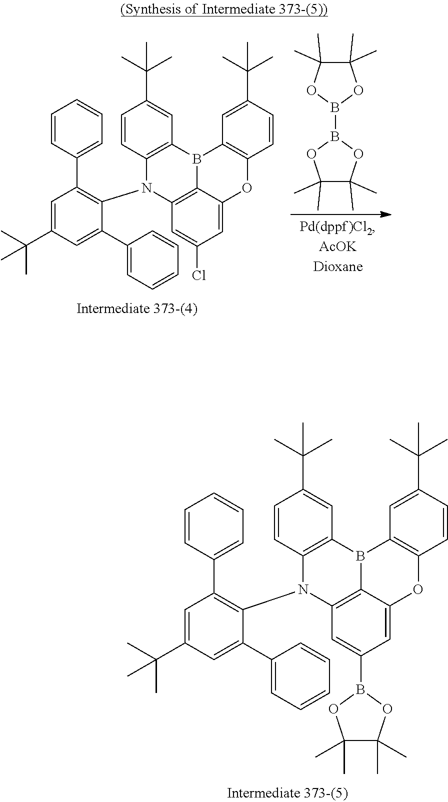

In an Ar atmosphere, 7 Intermediate 373-(4) (4.15 g, 5.93 mmol), bis(pinacolato)diboron (3.01 g, 11.85 mmol), Pd(dppf)Cl₂ (0.48 g, 0.59 mmol), and AcOK (1.34 g, 13.63 mmol) were added to 59 mL of dioxane and the mixture was heated under stirring at about 100° C. for about 8 hours. CH₂Cl₂ and water were added, the mixture was filtered through Celite and separated, and an organic layer was concentrated. The resultant was purified by silica gel column chromatography to obtain Intermediate 373-(5) (3.99 g, yield of 85%). The molecular mass of 373-(5) of 792 was obtained by FAB MS measurement.

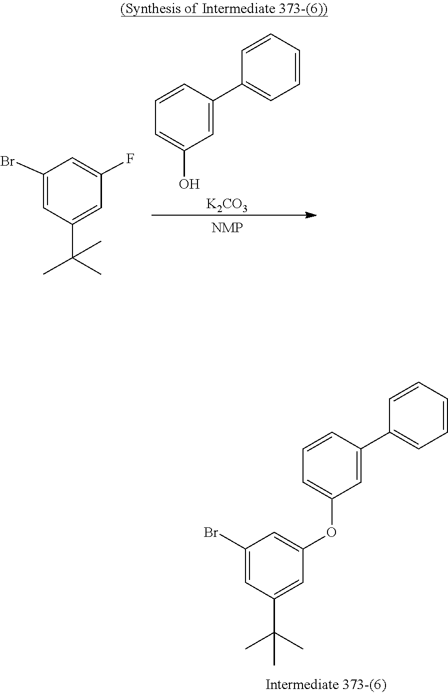

In an Ar atmosphere, 1-bromo-3-(tert-butyl)-5-fluorobenzene (10.55 g, 45.65 mmol), [1,1′-biphenyl]-3-ol (9.32 g, 54.78 mmol), and K₂CO₃ (28.39 g, 205.42 mmol) were added to NMP of 105 mL, and the mixture was heated for about 24 hours while maintaining an external temperature of about 140° C. The mixture was diluted with CH₂Cl₂, water was added, the mixture was filtered through Celite, and separated, and an organic layer was concentrated. The resultant was purified by silica gel column chromatography to obtain Intermediate 373-(6) (14.62 g, yield of 84%). The molecular mass of Intermediate 373-(6) of 381 was obtained by FAB MS measurement.

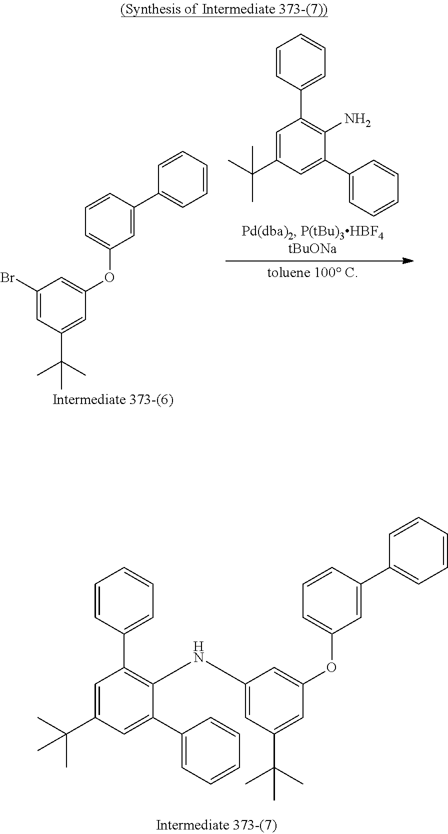

In an Ar atmosphere, Intermediate 373-(6) (14.33 g, 37.58 mmol), 5′-(tert-butyl)-[1,1′:3′,1″-terphenyl]-2′-amine (11.89 g, 39.46 mmol), Pd(dba)₂ (2.16 g, 3.76 mmol), P(tBu)₃·HBF₄ (2.18 g, 7.52 mmol), and tBuONa (8.31 g, 86.44 mmol), were added to 187 mL of toluene, and the mixture was heated under stirring at about 100° C. for about 8 hours. Water was added, the mixture was filtered through Celite and separated, and an organic layer was concentrated. The resultant was purified by silica gel column chromatography to obtain Intermediate 373-(7) (17.42 g, yield of 77%). The molecular mass of Intermediate 373-(7) of 602 was obtained by FAB MS measurement.

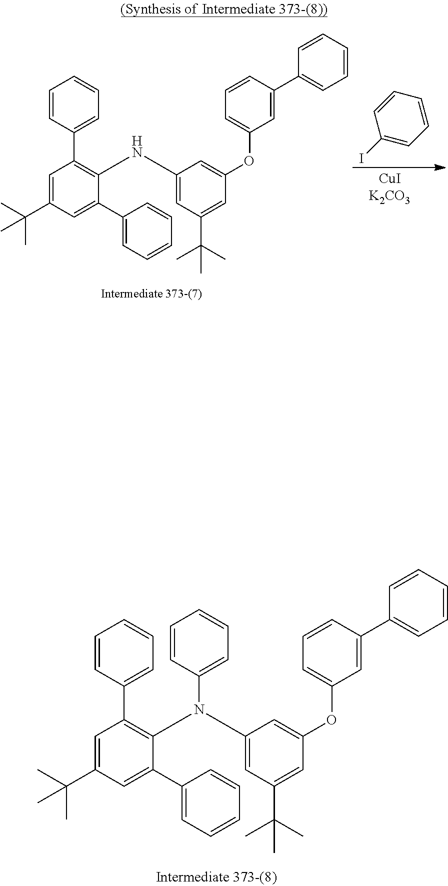

A small amount of toluene, about 10 mL, was added to Intermediate 373-(7) (15.55 g, 25.84 mmol), iodobenzene (26.36 g, 129.19 mmol), CuI (10.33 g, 54.26 mmol), and K₂CO₃ (35.71 g, 258.38 mmol) and heated for about 24 hours while maintaining an external temperature of about 215° C. The mixture was diluted with CH₂Cl₂, water was added, the mixture was filtered through Celite, and separated, and an organic layer was concentrated. The resultant was purified by silica gel column chromatography to obtain Intermediate 373-(8) (14.71 g, yield of 84%). The molecular mass of Intermediate 373-(8) of 678 was obtained by FAB MS measurement.

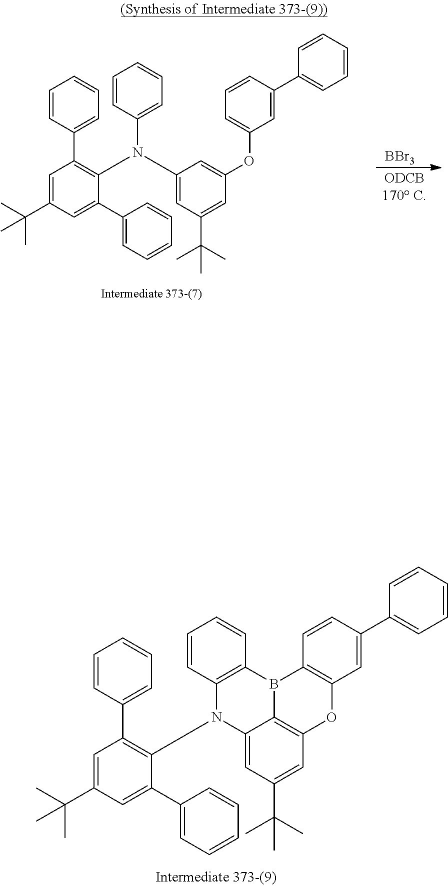 [SMILES: CC(C)(C)c1cc(Oc2cccc(-c3ccccc3)c2)cc(N(c2ccccc2)c2c(-c3ccccc3)cc(C(C)(C)C)cc2-c2ccccc2)c1 ; "BBr3" ; CC(C)(C)c1cc(-c2ccccc2)c(N2c3ccccc3B3c4ccc(-c5ccccc5)cc4Oc4cc(C(C)(C)C)cc2c43)c(-c2ccccc2)c1]

In an Ar atmosphere, Intermediate 373-(8) (13.15 g, 19.4 mmol) was dissolved in ODCB (194 mL), BBr₃ (9.72 g, 38.79 mmol) was added, and the mixture was heated under stirring at about 170° C. for about 10 hours. Cooled to a room temperature, DIPEA (30.03 g, 232.77 mmol) was added, water was added, the mixture was filtered through Celite, and separated, and an organic layer was concentrated. The resultant was purified by silica gel column chromatography to obtain Intermediate 373-(9) (4.12 g, yield of 31%). The molecular mass of Intermediate 373-(9) of 686 was obtained by FAB MS measurement.

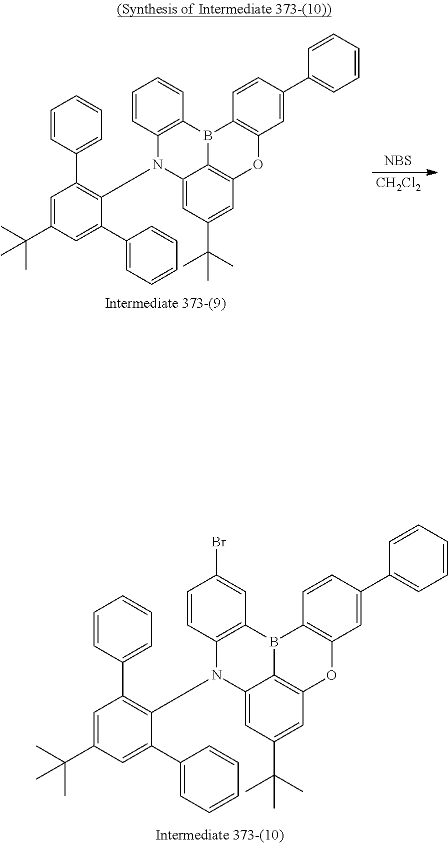 [SMILES: CC(C)(C)c1cc(-c2ccccc2)c(N2c3ccccc3B3c4ccc(-c5ccccc5)cc4Oc4cc(C(C)(C)C)cc2c43)c(-c2ccccc2)c1 ; "NBS" ; "CH2Cl2" ; CC(C)(C)c1cc(-c2ccccc2)c(N2c3ccc(Br)cc3B3c4ccc(-c5ccccc5)cc4Oc4cc(C(C)(C)C)cc2c43)c(-c2ccccc2)c1]

In an Ar atmosphere, Intermediate 373-(9) (3.88 g, 5.66 mmol) was dissolved in CH₂Cl₂ (57 mL), N-bromosuccinimide (2.01 g, 11.32 mmol) was added, and the mixture was stirred at room temperature for about 24 hours. Water was added, the mixture was filtered through Celite, then separated, and an organic layer was concentrated. The resultant was purified by silica gel column chromatography to obtain Intermediate 373-(10) (3.98 g, yield of 92%). The molecular mass of Intermediate 373-(10) of 765 was obtained by FAB MS measurement.

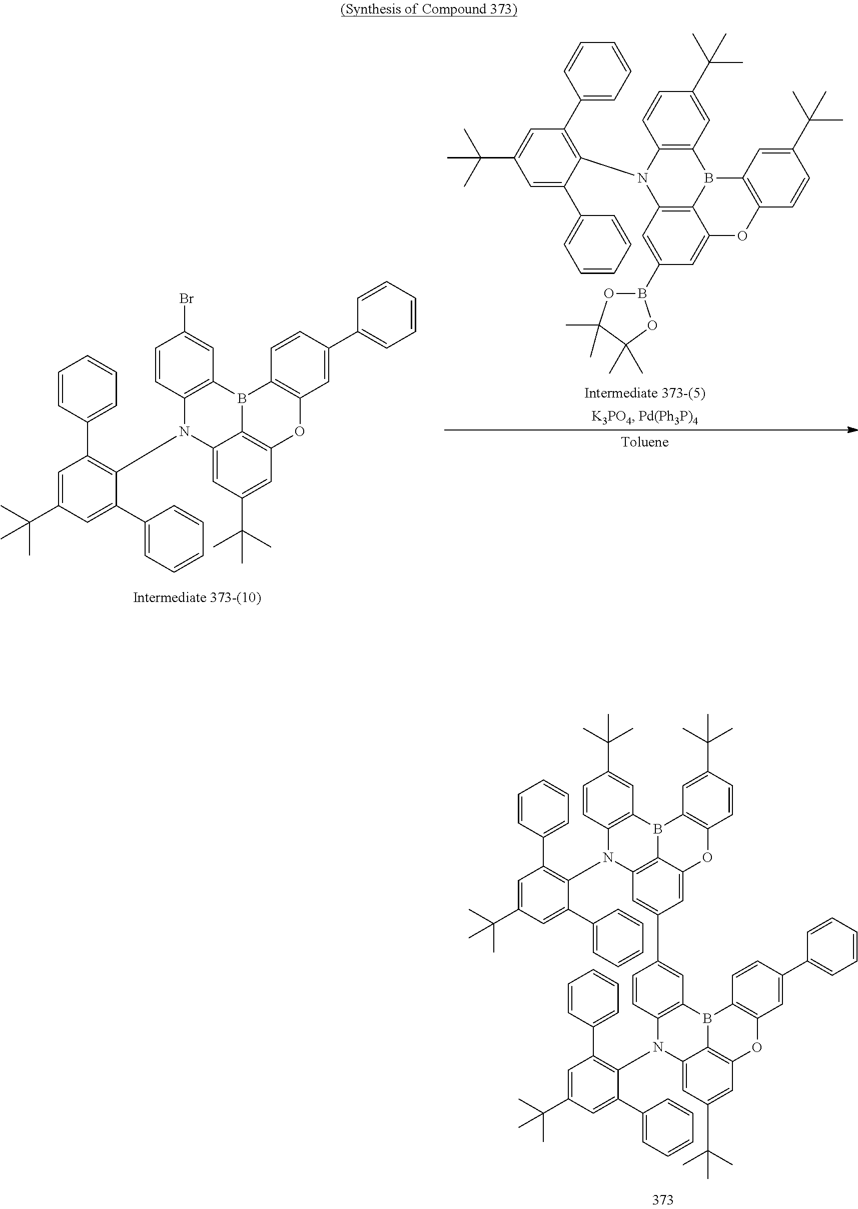

In an Ar atmosphere, toluene 20.08 mL, and a mixture of EtOH and water in a ratio of 1:1 of 10.04 mL were added Intermediate 373-(10) (2.51 g, 3.28 mmol), Intermediate 373-(5) (3.12 g, 3.94 mmol), K₃PO₄ (1.39 g, 6.57 mmol), and Pd(Ph₃P)₄ (0.38 g, 0.33 mmol), and the mixture was heated for about 24 hours while maintaining an external temperature of about 80° C. The mixture was filtered through Celite, and separated, and an organic layer was concentrated. The resultant was purified by silica gel column chromatography to obtain Compound 373 (3.28 g, yield of 74%)). The molecular mass of Compound 373 of 1349 was obtained by FAB MS measurement.

Compound 373 was purified by sublimation (380° C., 2.5×10⁻³ Pa) and then evaluated for device performance.

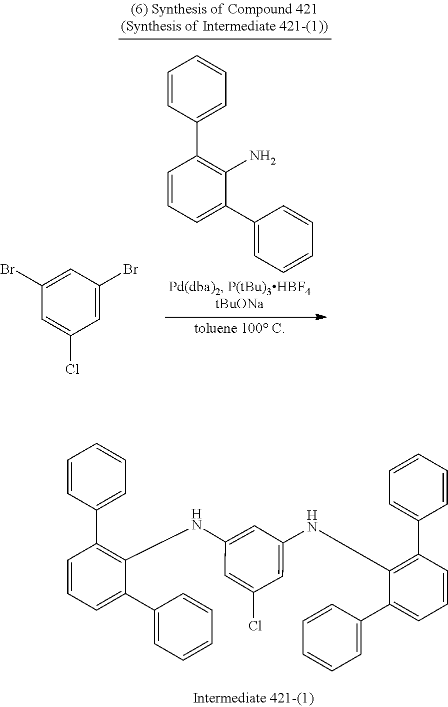 [SMILES: Clc1cc(Br)cc(Br)c1 ; Nc1c(-c2ccccc2)cccc1-c1ccccc1 ; Clc1cc(Nc2c(-c3ccccc3)cccc2-c2ccccc2)cc(Nc2c(-c3ccccc3)cccc2-c2ccccc2)c1]

In an Ar atmosphere, 1,3-dibromo-5-chlorobenzene (10.22 g, 37.8 mmol), [1,1′:3′,1″-terphenyl]-2′-amine (19.48 g, 79.39 mmol), Pd(dba)₂ (2.17 g, 3.78 mmol), P(tBu)₃·HBF₄ (2.19 g, 7.56 mmol), and tBuONa (8.36 g, 86.95 mmol) were added to toluene of 189 mL, and the mixture was heated for about 8 at about 100° C. under stirring. Water was added, the mixture was filtered through Celite, and separated, and an organic layer was concentrated. The resultant was purified by silica gel column chromatography to obtain Intermediate 421-(1) (20.39 g, yield of 90%). The molecular mass of Intermediate 421-(1) of 599 was obtained by FAB MS measurement.

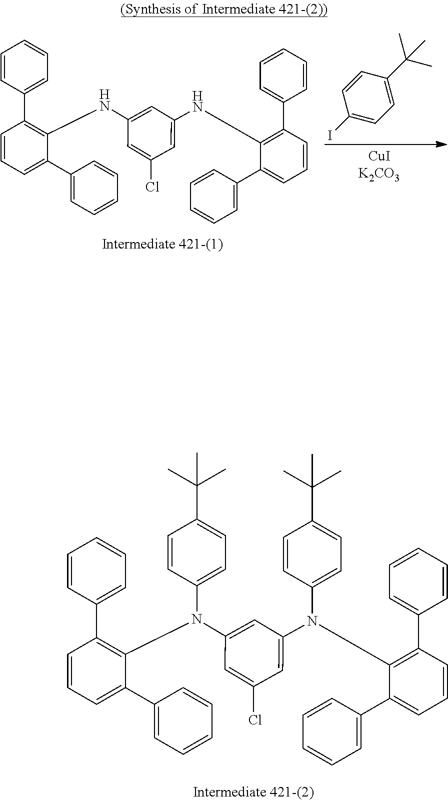

A small amount of toluene, about 10 mL, was added to Intermediate 421-(1) (18.52 g, 30.91 mmol), 1-(tert-butyl)-4-iodobenzene (80.4 g, 309.09 mmol), CuI (14.72 g, 77.27 mmol), and K₂CO₃ (64.08 g, 463.64 mmol) and the mixture was heated for about 24 hours while maintaining an external temperature of about 215° C. The mixture was diluted with CH₂Cl₂, water was added, the mixture was filtered through Celite, and separated, and an organic layer was concentrated. The resultant was purified by silica gel column chromatography to obtain Intermediate 421-(2) (23.49 g, yield of 88%). The molecular mass of Intermediate 421-(2) of 864 was obtained by FAB MS measurement.

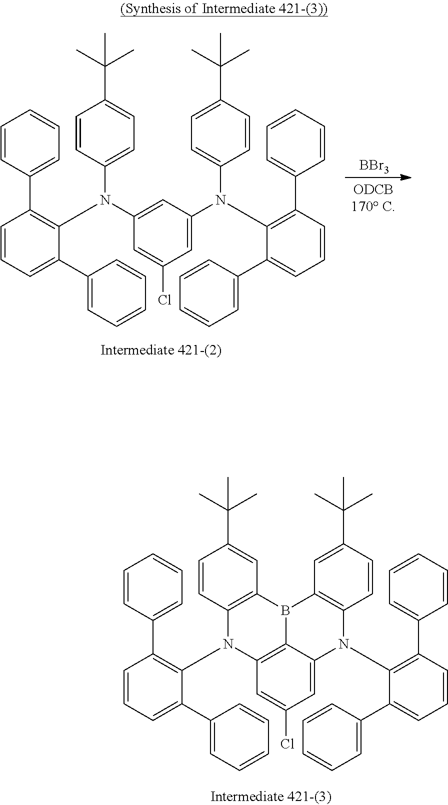

In an Ar atmosphere, Intermediate 421-(2) (20.11 g, 23.29 mmol) was dissolved in ODCB (233 mL), BBr₃ (11.67 g, 46.57 mmol) was added, and the mixture was heated under stirring at about 170° C. for about 10 hours. Cooled to a room temperature, DIPEA (36.05 g, 279.44 mmol) was added, water was added, the mixture was filtered through Celite, and separated, and an organic layer was concentrated. The resultant was purified by silica gel column chromatography to obtain Intermediate 421-(3) (8.93 g, yield of 44%). The molecular mass of Intermediate 421-(3) of 871 was obtained by FAB MS measurement.

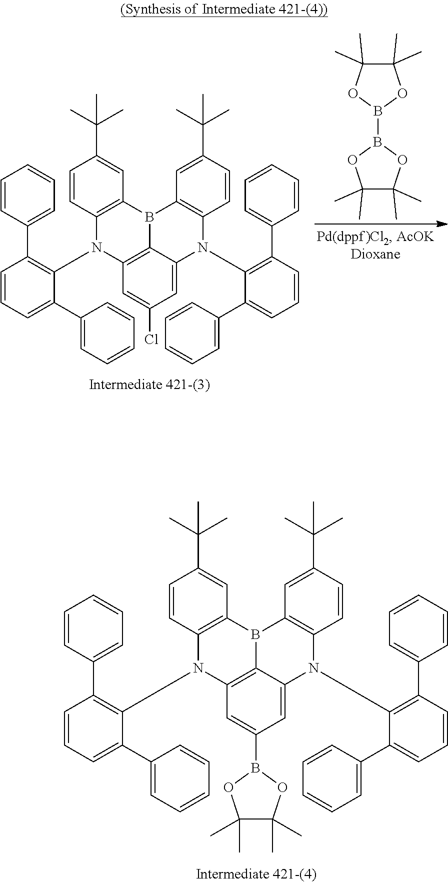

In an Ar atmosphere, Intermediate 421-(3) (23.05 g, 26.45 mmol), Bis(pinacolato)diboron (13.43 g, 52.91 mmol), Pd(dppf)Cl₂ (2.16 g, 2.65 mmol), and AcOK (5.97 g, 60.84 mmol) were added to 264 mL of dioxane and the mixture was heated under stirring at about 100° C. for about 8 hours. CH₂Cl₂ and water were added, the mixture was filtered through Celite and separated, and an organic layer was concentrated. The resultant was purified by silica gel column chromatography to obtain Intermediate 421-(4) (20.38 g, yield 80%). The molecular mass of Intermediate 421-(4) of 963 was obtained by FAB MS measurement.

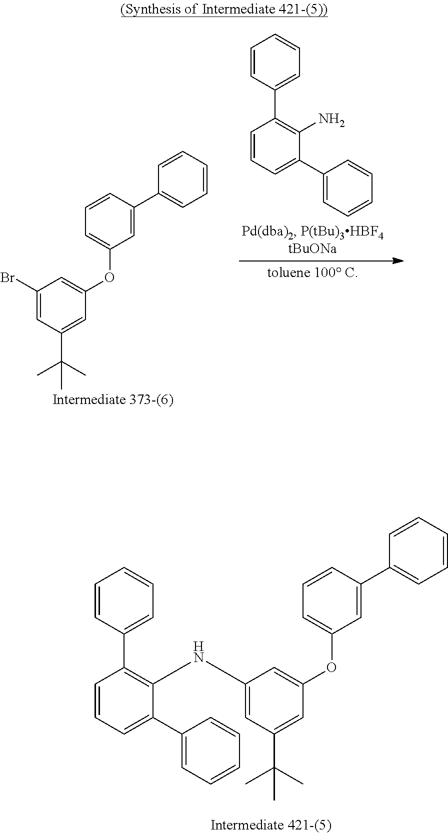 [SMILES: CC(C)(C)c1cc(Br)cc(Oc2cccc(-c3ccccc3)c2)c1 ; Nc1c(-c2ccccc2)cccc1-c1ccccc1 ; CC(C)(C)c1cc(Nc2c(-c3ccccc3)cccc2-c2ccccc2)cc(Oc2cccc(-c3ccccc3)c2)c1]

In an Ar atmosphere, Intermediate 373-(6) (10.24 g, 26.85 mmol), [1,1′:3′,1″-terphenyl]-2′-amine (6.92 g, 28.2 mmol), Pd(dba)₂ (1.54 g, 2.69 mmol), P(tBu)₃·HBF₄ (1.56 g, 5.37 mmol), and tBuONa (5.94 g, 61.77 mmol) were added to 134 mL of toluene, and the mixture was heated under stirring at about 100° C. for about 8 hours. Water was added, the mixture was filtered through Celite and separated, and an organic layer was concentrated. The resultant was purified by silica gel column chromatography to obtain Intermediate 421-(5) (11.14 g, yield 76%). The molecular mass of Intermediate 421-(5) of 546 was obtained by FAB MS measurement.

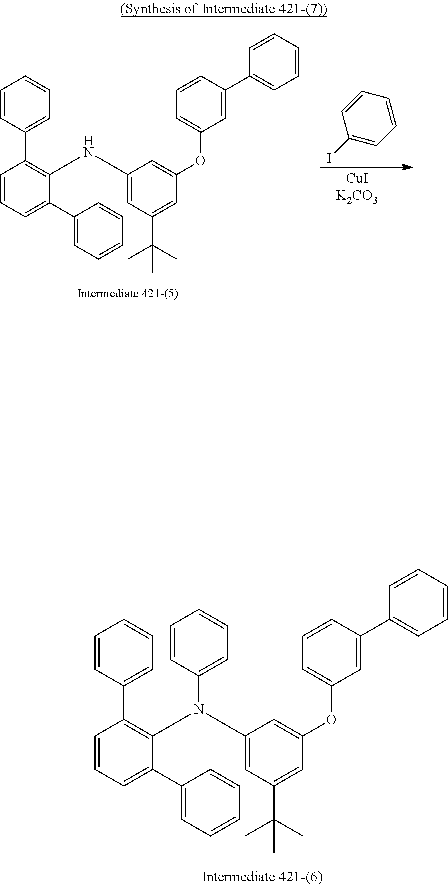 [SMILES: CC(C)(C)c1cc(Nc2c(-c3ccccc3)cccc2-c2ccccc2)cc(Oc2cccc(-c3ccccc3)c2)c1 ; Ic1ccccc1 ; CC(C)(C)c1cc(Oc2cccc(-c3ccccc3)c2)cc(N(c2ccccc2)c2c(-c3ccccc3)cccc2-c2ccccc2)c1]

A small amount of toluene, about 10 mL, was added to Intermediate 421-(5) (10.33 g, 18.93 mmol), iodobenzene (38.62 g, 189.29 mmol), CuI (9.01 g, 47.32 mmol), and K₂CO₃ (39.24 g, 283.93 mmol) and the mixture was heated for about 24 hours while maintaining an external temperature of about 215° C. The mixture was diluted with CH₂Cl₂, water was added, the mixture was filtered through Celite, and separated, and an organic layer was concentrated. The resultant was purified by silica gel column chromatography to obtain Intermediate 421-(6) (9.89 g, yield of 84%). The molecular mass of Intermediate 421-(6) of 622 was obtained by FAB MS measurement.

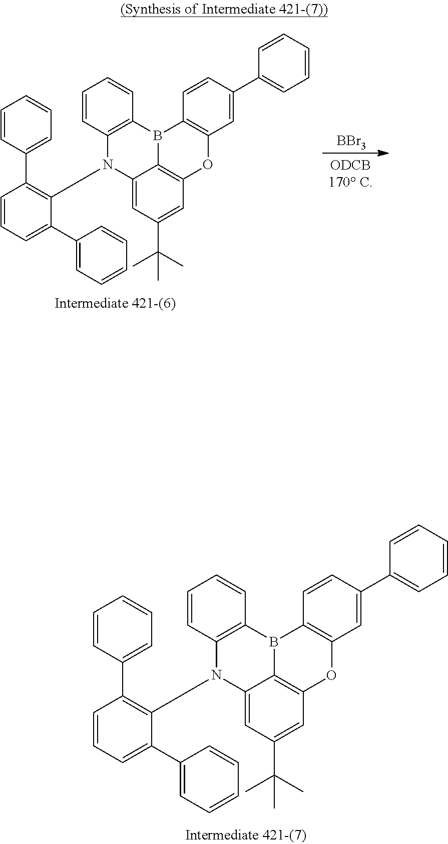

In an Ar atmosphere, Intermediate 421-(6) (9.77 g, 15.71 mmol) was dissolved in ODCB (157 mL), BBr₃ (7.87 g, 31.42 mmol) was added, and the mixture was heated under stirring at about 170° C. for about 10 hours. Cooled to a room temperature, DIPEA (24.32 g, 188.54 mmol) was added, water was added, the mixture was filtered through Celite, and separated, and an organic layer was concentrated. The resultant was purified by silica gel column chromatography to obtain Intermediate 421-(7) (3.56 g, yield of 36%). The molecular mass of Intermediate 421-(7) of 630 was obtained by FAB MS measurement.

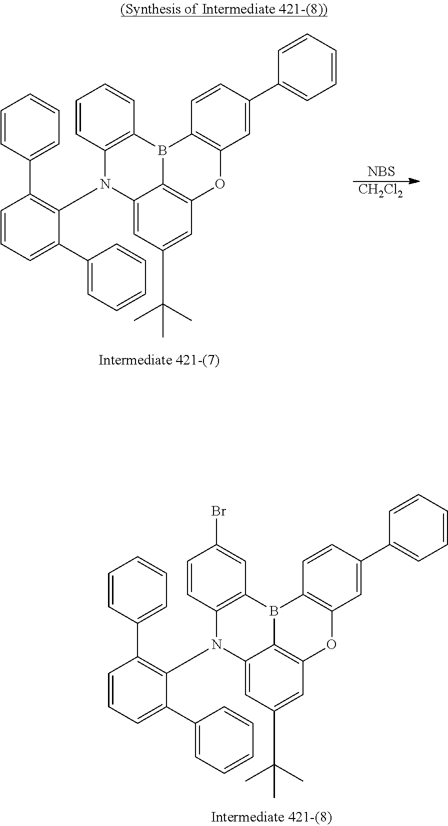 [SMILES: CC(C)(C)c1cc2c3c(c1)N(c1c(-c4ccccc4)cccc1-c1ccccc1)c1ccccc1B3c1ccc(-c3ccccc3)cc1O2 ; "CH2Cl2" ; "NBS" ; CC(C)(C)c1cc2c3c(c1)N(c1c(-c4ccccc4)cccc1-c1ccccc1)c1ccc(Br)cc1B3c1ccc(-c3ccccc3)cc1O2]

In an Ar atmosphere, Intermediate 421-(7) (3.25 g, 4.74 mmol) was dissolved in CH₂Cl₂ (47 mL), N-bromosuccinimide (1.69 g, 9.48 mmol) was added, and the mixture was heated under stirring at room temperature for about 24 hours. Water was added, the mixture was filtered through Celite, then separated, and an organic layer was concentrated. The resultant was purified by silica gel column chromatography to obtain Intermediate 421-(8) (3.06 g, yield of 91%). The molecular mass of Intermediate 421-(8) of 709 was obtained by FAB MS measurement.

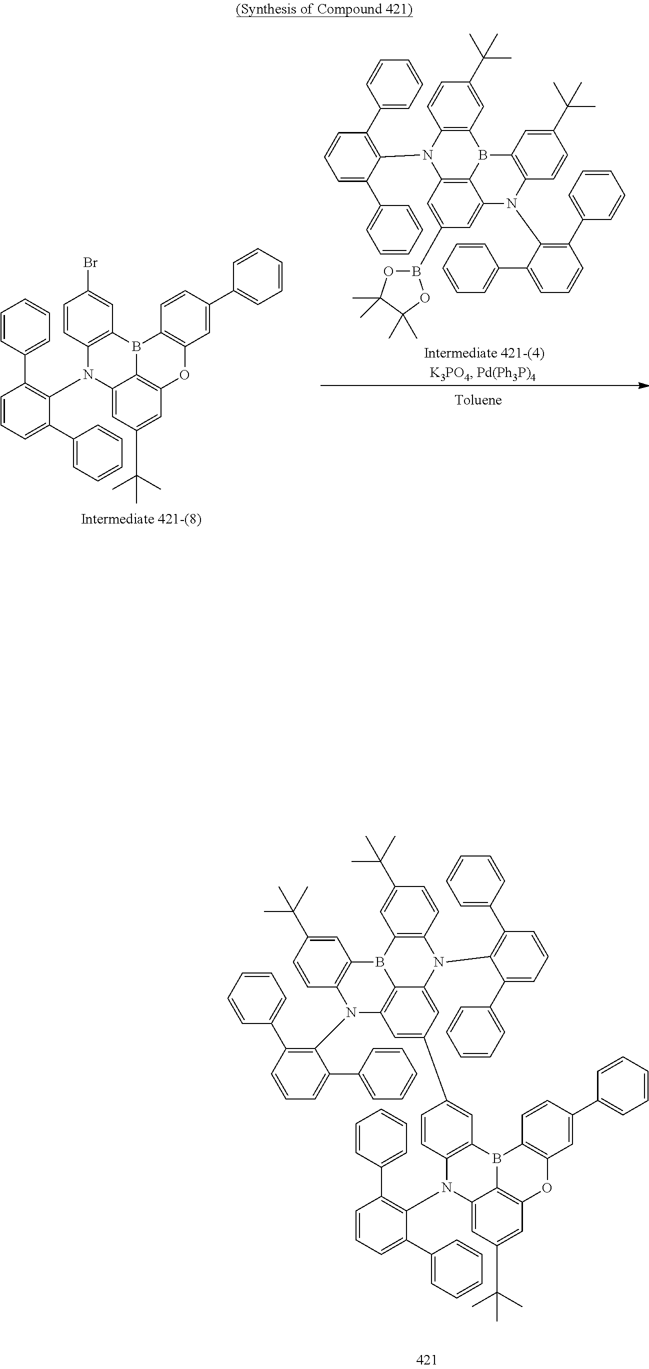

In an Ar atmosphere, toluene 22.8 mL, and a mixture of EtOH and water in a ratio of 1:1 of 11.4 mL were added Intermediate 421-(8) (2.85 g, 4.02 mmol) Intermediate 421-(4) (4.65 g, 4.83 mmol), K₃PO₄ (1.71 g, 8.05 mmol), and Pd(Ph₃P)₄ (0.46 g, 0.4 mmol), and heated for about 24 hours while maintaining an external temperature of about 80° C. The mixture was filtered through Celite, and separated, and an organic layer was concentrated. The resultant was purified by silica gel column chromatography to obtain Compound 421 (4.18 g, yield of 71%)). The molecular mass of Compound 421 of 1465 was obtained by FAB MS measurement.

Compound 421 was purified by sublimation (370° C., 2.3×10⁻³ Pa) and then evaluated for device performance.

### 2. Manufacturer and Evaluation of Light-Emitting Element

A light-emitting element according to one or more embodiments, containing a fused polycyclic compound according to one or more embodiments in an emission layer was manufactured by a following method. The light-emitting elements according to Example 1 to Example 6 were manufactured using, as a dopant material in the emission layer, the fused polycyclic compounds of Compounds 1, 26, 85, 145, 373, and 421, which were example compounds synthesized by the herein-described synthetic methods. The light-emitting elements according to Example 7 to Example 12 were manufactured using the fused polycyclic compounds of Example Compounds 61, 97, 111, and 9 to 10, synthesized through similar synthetic methods, as a dopant material in the emission layer. The light-emitting elements according to Comparative Example 1 to Comparative Example 8 correspond to the light-emitting elements using Comparative Example Compound X1 to Comparative Example Compound X8 as a dopant material in the emission layer.

### Example Compounds

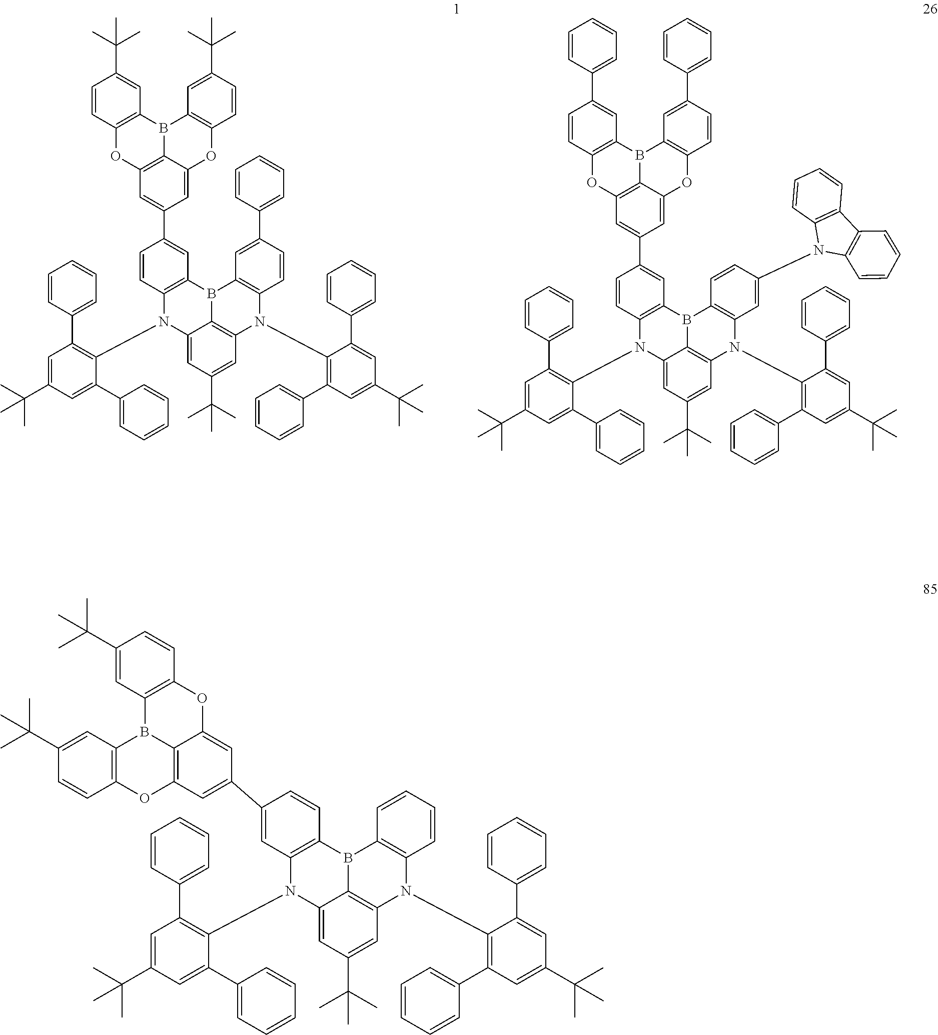

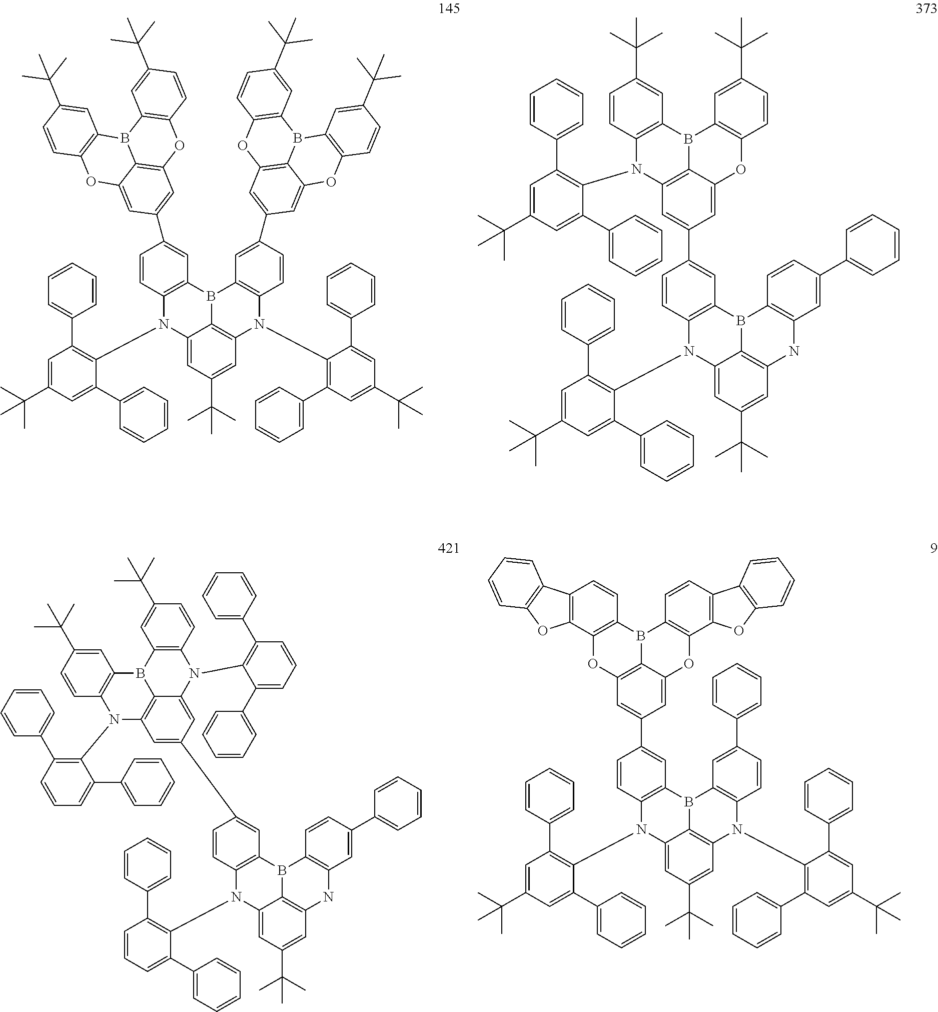

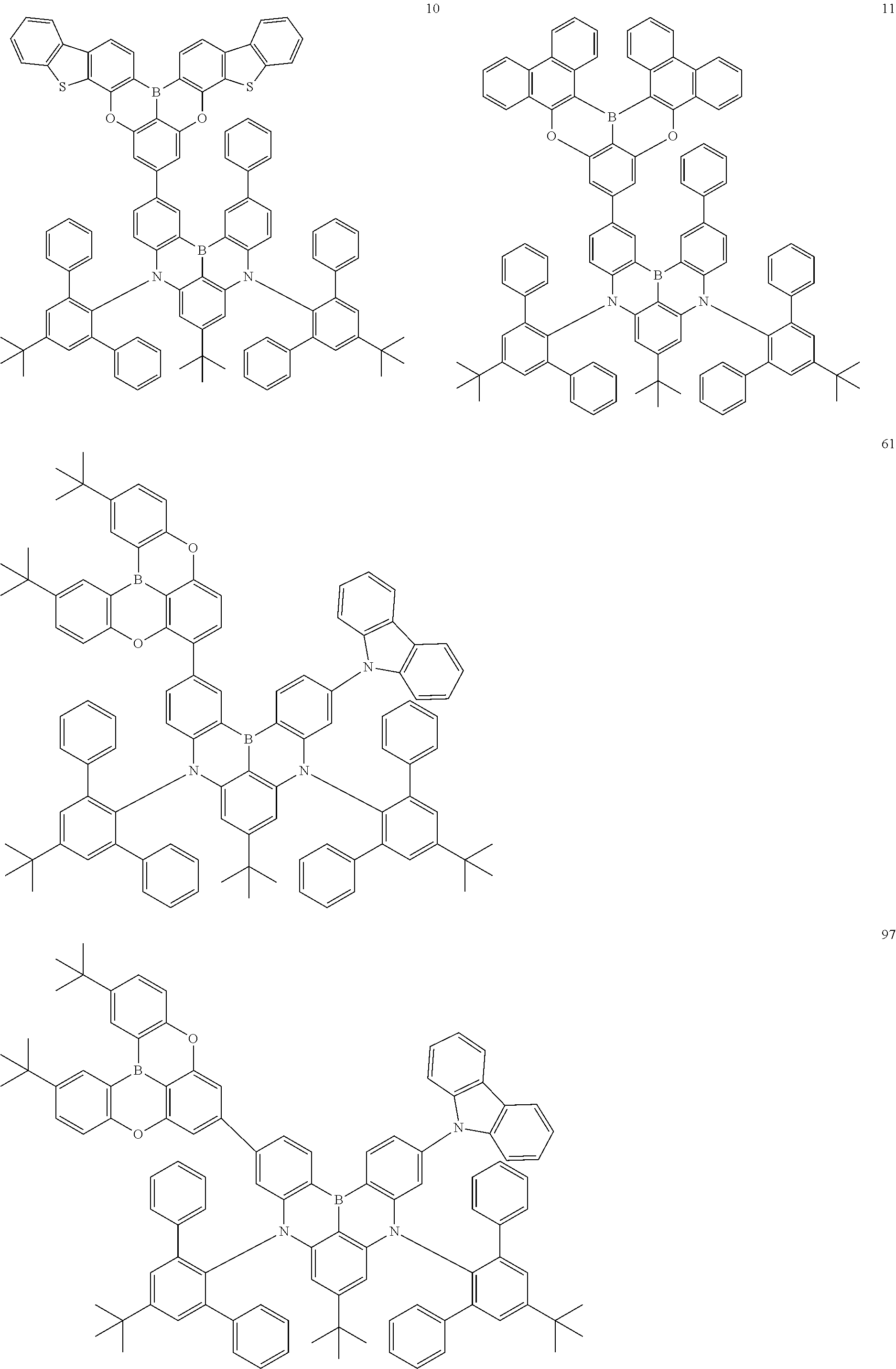

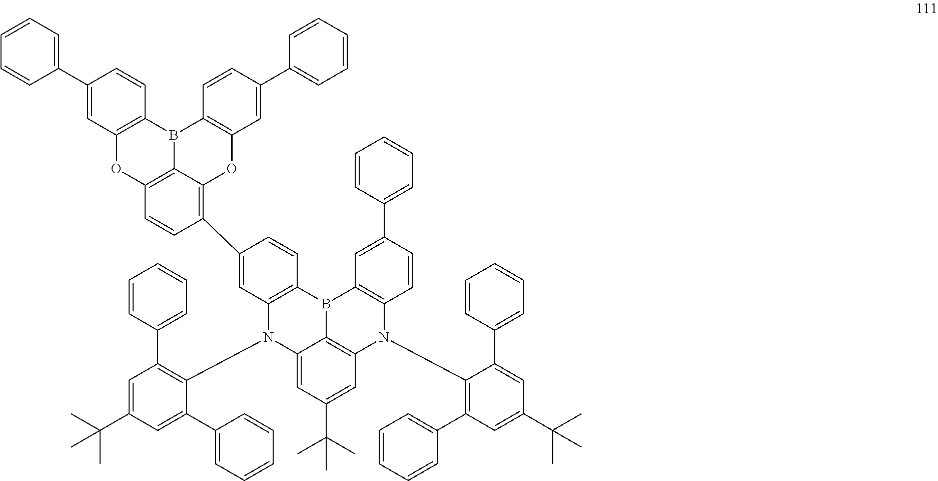 [SMILES: CC(C)(C)c1cc(-c2ccccc2)c(N2c3ccc(-c4ccccc4)cc3B3c4ccc(-c5ccc6c7c5Oc5cc(-c8ccccc8)ccc5B7c5ccc(-c7ccccc7)cc5O6)cc4N(c4c(-c5ccccc5)cc(C(C)(C)C)cc4-c4ccccc4)c4cc(C(C)(C)C)cc2c43)c(-c2ccccc2)c1]

### Comparative Example Compounds

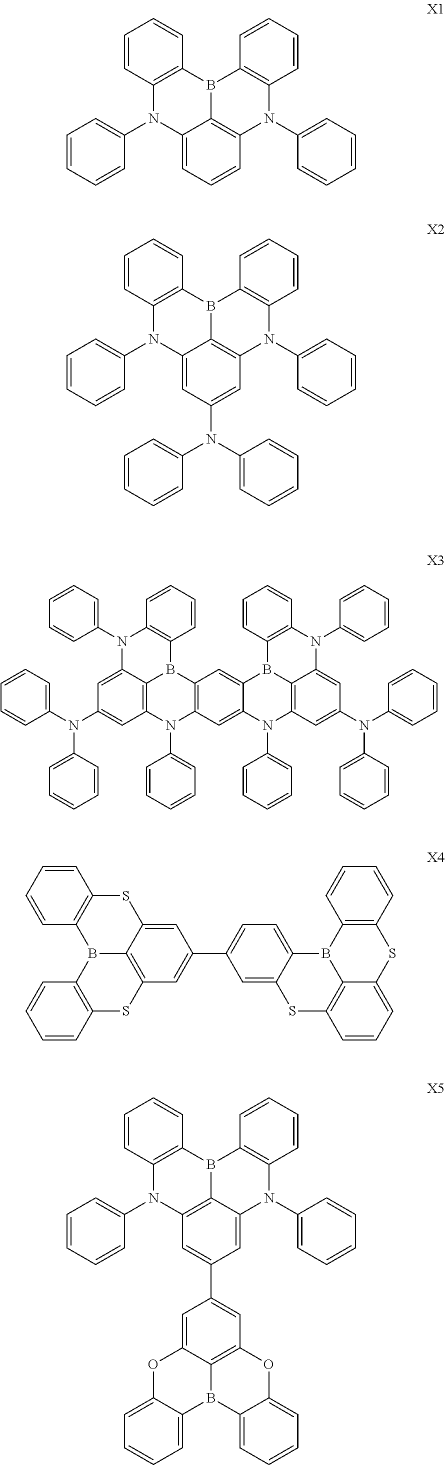 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1 ; c1ccc2c(c1)Sc1cccc3c1B2c1ccc(-c2cc4c5c(c2)Sc2ccccc2B5c2ccccc2S4)cc1S3 ; c1ccc(N2c3ccccc3B3c4ccccc4N(c4ccccc4)c4cc(-c5cc6c7c(c5)Oc5ccccc5B7c5ccccc5O6)cc2c43)cc1]

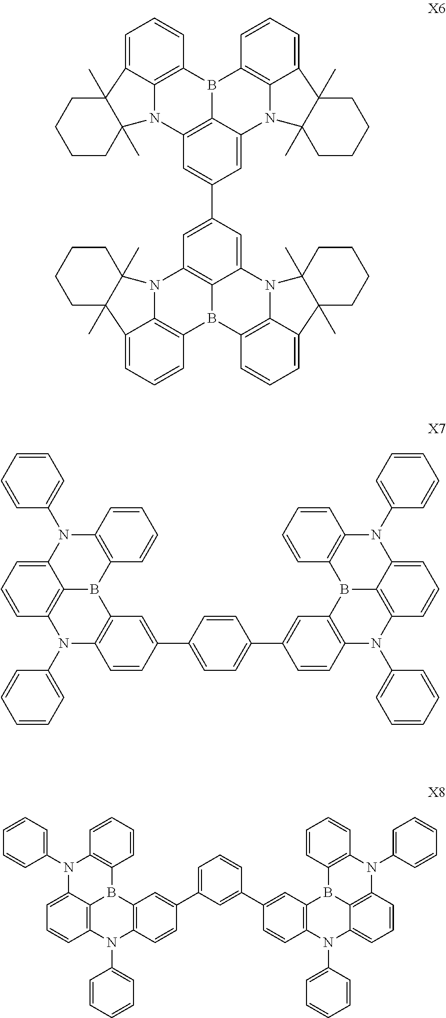 [SMILES: CC12CCCCC1(C)N1c3cc(-c4cc5c6c(c4)N4c7c(cccc7C7(C)CCCCC47C)B6c4cccc6c4N5C4(C)CCCCC64C)cc4c3B(c3cccc2c31)c1cccc2c1N4C1(C)CCCCC21C ; c1ccc(N2c3ccccc3B3c4cc(-c5ccc(-c6ccc7c(c6)B6c8ccccc8N(c8ccccc8)c8cccc(c86)N7c6ccccc6)cc5)ccc4N(c4ccccc4)c4cccc2c43)cc1 ; c1ccc(N2c3ccccc3B3c4cc(-c5cccc(-c6ccc7c(c6)B6c8ccccc8N(c8ccccc8)c8cccc(c86)N7c6ccccc6)c5)ccc4N(c4ccccc4)c4cccc2c43)cc1]

### (Manufacture of Light-Emitting Element)

A first electrode having about a thickness of about 150 nanometer (nm) was formed with indium tin oxide (ITO), a hole injection layer having a thickness of about 10 nm was formed on the first electrode with dipyrazino[2,3-f: 2′,3′-h]quinoxaline-2,3,6,7,10,11-hexacarbonitrile (HAT-ON), a hole transport layer having a thickness of about 80 nm was formed on the hole injection layer with N,N′-Di(1-naphthyl)-N,N′-diphenyl-(1,1′-biphenyl)-4,4′-diamine (NPD), an emission auxiliary layer having a thickness of about 5 nm was formed on the hole transport layer with 1,3-Bis(N-carbazolyl)benzene (mOP), an emission layer having a thickness of about 20 nm was formed on the emission auxiliary layer with 3,3′-di(9H-carbazol-9-yl)-1,1′-biphenyl) (mCBP) doped with about 1% of the example compound or comparative example compound, an electron transport layer having a thickness of 30 nm was formed on the emission layer with 2,2′,2″-(1,3,5-benzinetriyl)-tris(1-phenyl-1-H-benzimidazole) (TPBi), an electron injection layer having a thickness of about 0.5 nm was formed on the electron transport layer with LiF, and a second electrode having a thickness of about 100 nm was formed on the electron injection layer with Al. Each layer was formed by a deposition method under a vacuum atmosphere.

The compounds used in the manufacture of the light-emitting elements according to examples and comparative examples are disclosed herein. The following materials are suitable substances, and commercially available products were purified by sublimation to be used in the manufacture of an element.

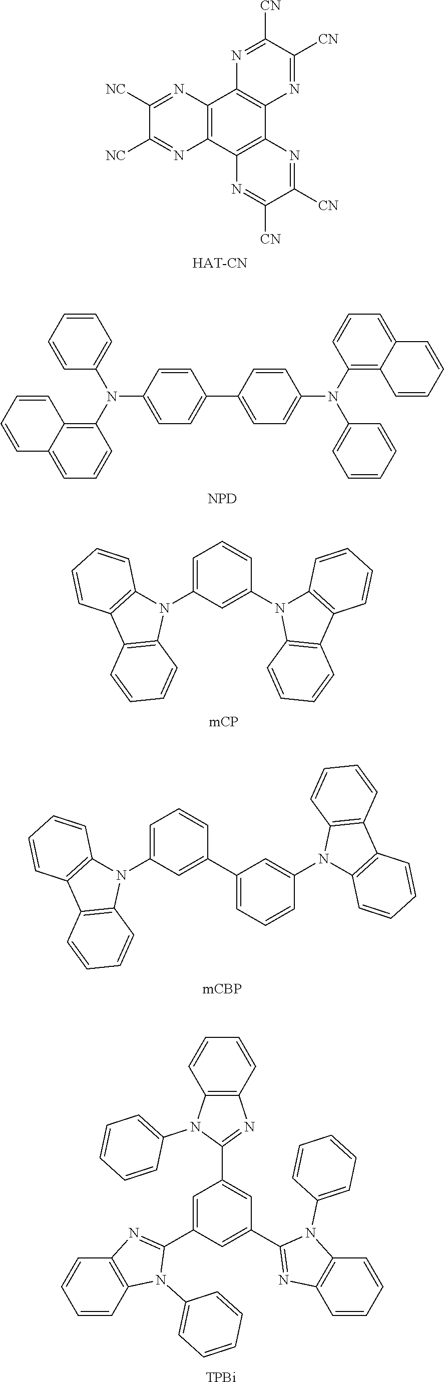

### (Characteristic Evaluation of Light-Emitting Element)

Light-emitting elements according to Example 1 to Example 6, and Comparative Example 1 to Comparative Example 6 were evaluated and the results were listed in Table 1. Maximum emission wavelength (λₘₐₓ), a roll-off value (%), and a relative lifespan (LT50) of each manufactured light-emitting elements were compared and shown in Table 1.

In the characteristic evaluation results of the light-emitting elements according to examples and comparative examples, shown in Table 1, the maximum emission wavelength (λₘₐₓ), the roll-off value (%), and the relative lifetime (LT50) were measured using the external quantum efficiency measurement device C9920-12 made by Hamamatsu Photonics. The maximum emission wavelength (λₘₐₓ) represents a wavelength showing the highest value in the emission spectrum. The roll-off value represents a rate of efficiency degradation at high luminance, evaluated based on luminance levels at about 1 candela per square meter (cd/m²) and about 1000 cd/m². Additionally, a time taken for luminance to decrease to half of the initial value of about 800 cd/m² was measured for evaluating the relative lifespan (LT50). The time of each light-emitting element is relatively expressed with respect to the result of Comparative Example 3, which is a standard value.

TABLE 1

| Element | | | | |
|---|---|---|---|---|
| manufacture | | λₘₐₓ | Roll-off | LT50 |
| examples | Dopant | (nm) | (%) | (h) |
| Example 1 | Compound 1 | 461 | 12.5 | 3.8 |
| Example 2 | Compound 26 | 458 | 11.6 | 3.9 |
| Example 3 | Compound 84 | 462 | 14.8 | 2.8 |
| Example 4 | Compound 145 | 458 | 11.1 | 4.0 |
| Example 5 | Compound 373 | 460 | 10.3 | 4.3 |
| Example 6 | Compound 421 | 458 | 13.0 | 3.7 |
| Example 7 | Compound 61 | 457 | 14.0 | 3.3 |
| Example 8 | Compound 97 | 463 | 13.3 | 3.6 |
| Example 9 | Compound 111 | 461 | 14.2 | 3.1 |
| Example 10 | Compound 9 | 462 | 14.5 | 3.0 |
| Example 11 | Compound 10 | 465 | 12.0 | 3.9 |
| Example 12 | Compound 11 | 462 | 12.8 | 3.7 |
| Comparative | Comparative Example | 457 | 33.2 | 0.3 |
| Example 1 | Compound X1 | | | |
| Comparative | Comparative Example | 446 | 30.5 | 0.2 |
| Example 2 | Compound X2 | | | |
| Comparative | Comparative Example | 467 | 13.5 | 1.0 |
| Example 3 | Compound X3 | | | |
| Comparative | Comparative Example | 427 | 52.5 | 0.05 |
| Example 4 | Compound X4 | | | |
| Comparative | Comparative Example | 457 | 41.2 | 0.23 |
| Example 5 | Compound X5 | | | |
| Comparative | Comparative Example | 465 | 65.5 | 0.13 |
| Example 6 | Compound X6 | | | |
| Comparative | Comparative Example | 468 | 21.3 | 0.90 |
| Example 7 | Compound X7 | | | |
| Comparative | Comparative Example | 466 | 25.4 | 0.85 |
| Example 8 | Compound X8 | | | |

Referring to Table 1, it can be confirmed that in the light-emitting element using, as an emission material, the fused polycyclic compound according to one or more embodiments of the present disclosure, the roll-off value shows prevented or reduced efficiency degradation even at high luminance, and lifespan characteristics are improved compared to the light-emitting elements according to Comparative Examples.

Each of Example Compounds includes (e.g., contains) a first fused ring, and at least one second fused ring, at least any one among the first fused ring and the second fused ring has characteristics of an electron donor and the other has characteristics of an electron acceptor, thereby capable of achieving improvements in high efficiency and long lifespan due to an excellent or suitable multi-resonance structure. Example Compounds may exhibit excellent or suitable molecular stability due to a specified structure and a connection position of the first fused ring and the at least one second fused ring, and thus may contribute to improvements in high efficiency and long lifespan.

The light-emitting element according to one or more embodiments includes (e.g., contains) the fused polycyclic compound according to one or more embodiments as a light-emitting dopant of the thermally activated delayed fluorescence (TADF) light-emitting element, and thus high element efficiency and improved lifespan characteristics may be achieved in a blue light wavelength region.

Compared to the light-emitting elements according to Comparative Example to Comparative Example 8, the light-emitting elements according to Example 1 to Example 12 achieved long lifespan of the elements, and a decrease in efficiency thereof was prevented or reduced even at high luminance. Example Compounds included (e.g., contained) in the molecular structure of the light-emitting elements according to Example 1 to Example 8 have characteristics in that any one selected from among the first fused ring and the second fused ring has characteristics of an electron donor, and the other has characteristics of an electron acceptor. Because, through these characteristics, an incomplete charge transfer (CT)-typed structure is formed within the molecule to thereby have excellent or suitable multi-resonance characteristics, thus it is thought that, a decrease in efficiency may be prevented or reduced and long lifespan characteristics may be achieved.

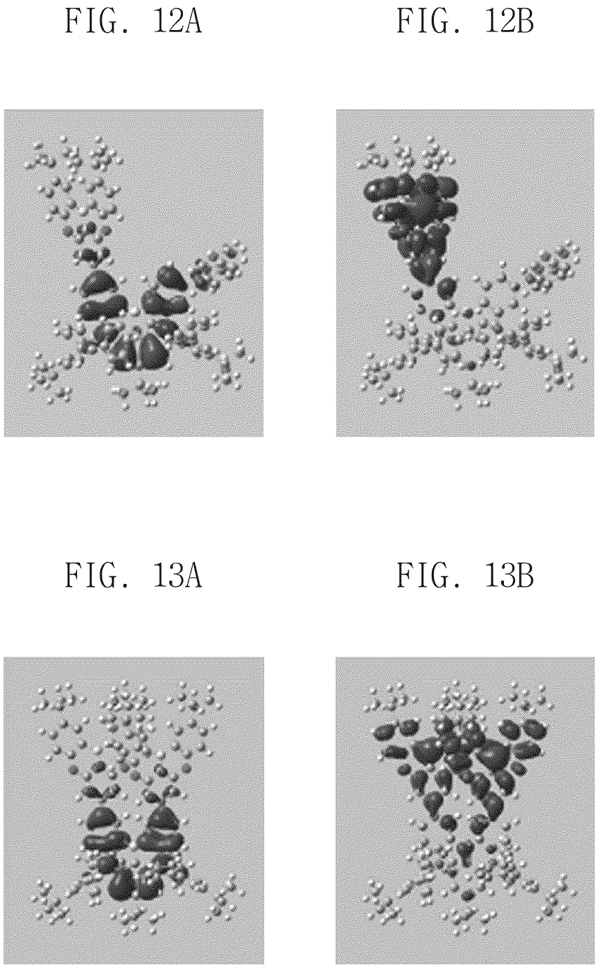

FIG. 12A, FIG. 12B, FIG. 13A and FIG. 13B are each a view showing a three-dimensional molecular model of the compound according to one or more embodiments. FIG. 12A is a view showing a HOMO level distribution of Example Compound 26, and FIG. 12B is a view showing a LUMO level distribution of Example Compound 26. FIG. 13A is a view showing a HOMO level distribution of Example Compound 145, and FIG. 13B is a view showing a LUMO level distribution of Example Compound 145. Referring to FIG. 12A and FIG. 12B, in the schematic view of molecular model of Example Compound 26, an electron density of the HOMO level of the compound is mainly distributed at the bottom in the first fused ring containing a nitrogen atom arranged therein. In contrast, the electron density of the LUMO level is mainly distributed at the top in the second fused ring arranged therein. Therefore, it can be confirmed that the incomplete charge transfer (CT)-type (kind) structure is formed within the molecule, which may lead to an excellent or suitable multi-resonance structure. Referring to FIG. 13A and FIG. 13B, in the schematic view of molecular model of Example Compound 145, an electron density of the HOMO level of the compound is mainly distributed at the bottom in the first fused ring containing a nitrogen atom arranged therein. In contrast, the electron density of the LUMO level is mainly distributed at the top in the two second fused rings arranged therein. Therefore, it can be confirmed that the incomplete charge transfer (CT)-type (kind) structure is formed within the molecule, which may lead to an excellent or suitable multi-resonance structure.

The light-emitting elements according to Comparative Example 1 to Comparative Example 3 have decreases in both (e.g., simultaneously) roll-off characteristics and a lifespan, compared to the light-emitting elements according to examples. Because Comparative Example Compounds X1 to X3 contained in the light-emitting elements according to Comparative Example 1 to Comparative Example 3, compared to the example compounds, do not include a first fused ring and at least one second fused ring and include one fused skeleton, an incomplete charge transfer-type (kind) structure is not formed therein, and thus material stability may be reduced, compared to the example compounds that include two or more fused rings. Therefore, the light-emitting elements according to Comparative Example 1 to Comparative Example 3 may have a reduced element lifespan and deteriorated roll-off characteristics.

Each of Comparative Example Compounds X4 and X6 contained in the light-emitting elements according to Comparative Example 4 and Comparative Example 6 includes a connected structure of two fused structures as Example Compounds, but, in a case of Comparative Example Compounds X4, a nitrogen atom is not contained in both (e.g., simultaneously) two fused rings, and in a case of Comparative Example Compounds X6, both (e.g., simultaneously) two fused rings contains only a nitrogen atom as a skeleton-forming heteroatom. Therefore, unlike Example Compounds according to one or more embodiments of the disclosure, in which any one among the fused rings has characteristics of an electron donor, and the other has characteristics of an electron acceptor, Comparative Example Compounds X4 and X6 does not have an incomplete charge transfer-type (kind) structure, and thus material stability thereof may be reduced. Therefore, compared to the light-emitting elements according to examples, the light-emitting elements according to Comparative Example 4 and Comparative Example 6 may have a reduced element lifespan, and deteriorated roll-off characteristics.

Comparative Example Compound X5 contained in the light-emitting element according to Comparative Example 5 includes a connected structure of two fused ring structures as those of the example compounds, one fused ring contains two nitrogen atoms to thereby have characteristics of an electron donor, and the other contains no nitrogen atom to thereby have characteristics of an electron acceptor. However, as illustrated herein, in a case of Comparative Example Compound X5, which has a bottom-bottom connection structure between two fused rings, the incomplete charge transfer-type (kind) structure is not formed, thereby having reduced material stability, unlike the example compounds having a bottom-top connection structure or a top-top connection structure between two fused rings. Therefore, compared to the light-emitting elements according to examples, the light-emitting element according to Comparative Example 5 may have reduced element lifespan and deteriorated roll-off characteristics.

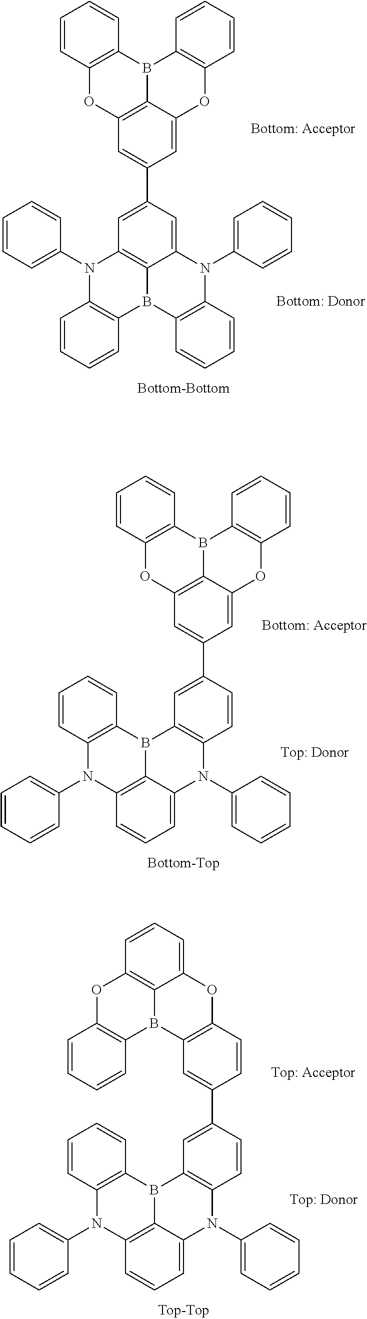 [SMILES: c1ccc(N2c3ccccc3B3c4ccccc4N(c4ccccc4)c4cc(-c5cc6c7c(c5)Oc5ccccc5B7c5ccccc5O6)cc2c43)cc1 ; c1ccc(N2c3ccccc3B3c4cc(-c5cc6c7c(c5)Oc5ccccc5B7c5ccccc5O6)ccc4N(c4ccccc4)c4cccc2c43)cc1 ; c1ccc(N2c3ccccc3B3c4cc(-c5ccc6c(c5)B5c7ccccc7Oc7cccc(c75)O6)ccc4N(c4ccccc4)c4cccc2c43)cc1]

Comparative Example Compounds X7 and X8, contained in the light-emitting elements according to Comparative Example 7 and Comparative Example 8, include a connected structure of two fused rings like example compounds. However, because both (e.g., simultaneously) two fused rings contain nitrogen, there is no distinction between the electron donor and the electron acceptor, an electron donor and an electron acceptor, and as described previously, Comparative Example Compounds X7 and X8 have a bottom-bottom connection structure. In some embodiments, a phenylene linker and/or the like is introduced between two fused rings, the degree of overlap between the HOMO and LUMO within the molecule decreases. Therefore, the incomplete charge transfer-type (kind) structure may be not formed, and material stability may decrease. Accordingly, the light-emitting elements according to Comparative Example 7 and Comparative Example 8 may have a reduced element lifespan and deteriorated roll-off characteristics, compared to the light-emitting elements according to examples.

The light-emitting element according to one or more embodiments may exhibit improved element characteristics of high efficiency and long lifespan.

The fused polycyclic compound according to one or more embodiments may be contained in the emission layer of the light-emitting element, and thus may contribute to improvements in high efficiency and long lifespan of the light-emitting element.

The display device according to one or more embodiments may exhibit excellent or suitable display quality.

In other words, the light-emitting element, according to one or more embodiments, may exhibit significantly improved characteristics of high efficiency and long lifespan. This is achieved by incorporating the fused polycyclic compound described in these embodiments into the emission layer of the light-emitting element. The unique structure of this compound, which includes a first fused ring and at least one second fused ring with distinct electron donor and acceptor characteristics, contributes to an excellent multi-resonance structure. This structure enhances molecular stability and prevents efficiency degradation even at high luminance, thereby extending the lifespan of the light-emitting element. Consequently, display devices utilizing these light-emitting elements may demonstrate superior display quality, combining high efficiency with long-lasting performance.

The display apparatus, display device, electronic device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display and/or electronic apparatus and/or device may be formed on one integrated circuit (IC) chip or on separate IC chips. Further, the one or more suitable components of display and/or electronic apparatus and/or device may be implemented on a flexible printed circuit film, a tape carrier package (TCP), a printed circuit board (PCB), or formed on one substrate. Further, the one or more suitable components of the display and/or electronic apparatus and/or device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

Hitherto, although one or more embodiments of disclosure have been described with reference to preferable embodiments, it is understood that disclosure should not be limited to these embodiments, but one or more suitable changes and modifications can be made by one ordinary skilled in the art within the spirit and scope of disclosure as hereinafter claimed.

Therefore, the technical scope of the disclosure is not intended to be limited to the contents set forth in the detailed description of the specification, but is intended to be defined by the appended claims and equivalents thereof.

What is claimed is:

1. A light-emitting element comprising:
a first electrode;
a second electrode on the first electrode; and
an emission layer between the first electrode and the second electrode and comprising a first compound represented by Formula 1: 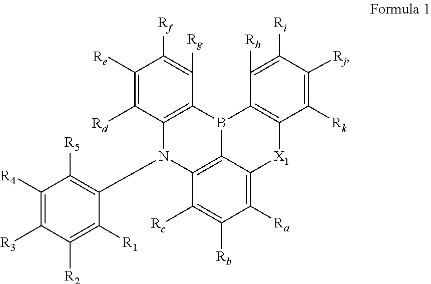
wherein, in Formula 1,
X₁ is O, S, or NR₆
R₁ to R₆, and Rₐ to Rₖ are each independently a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring, and
at least one selected from among R_{d} to Rₖ is a substituent represented by Formula 2: 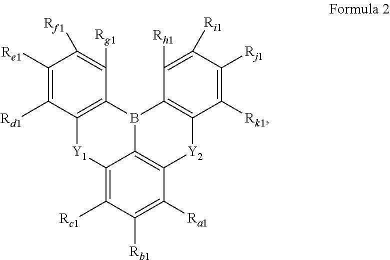
wherein, in Formula 2,
Y₁ and Y₂ are each independently O, S, or NR₇,
R₇, and Rₐ₁ to Rₖ₁ are each independently a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring, and
any one selected from among Rₐ₁ to Rₖ₁ is a portion to which Formula 1 is connected.

2. The light-emitting element of claim 1, wherein the first compound is represented by Formula 1-1 or Formula 1-2: 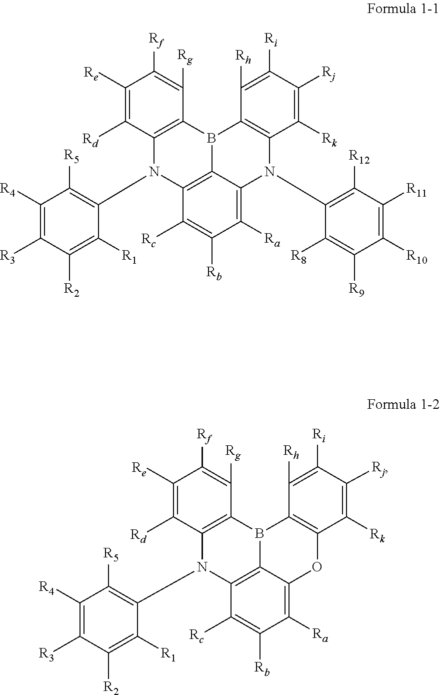
wherein, in Formula 1-1 and Formula 1-2,
R₈ to R₁₂ are each independently a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring, and
R₁ to R₅, and Rₐ to Rₖ are as defined in Formula 1.

3. The light-emitting element of claim 1, wherein at least one selected from among R_{d} to Rₖ is represented by any one selected from among Formula 2-1 to Formula 2-3: 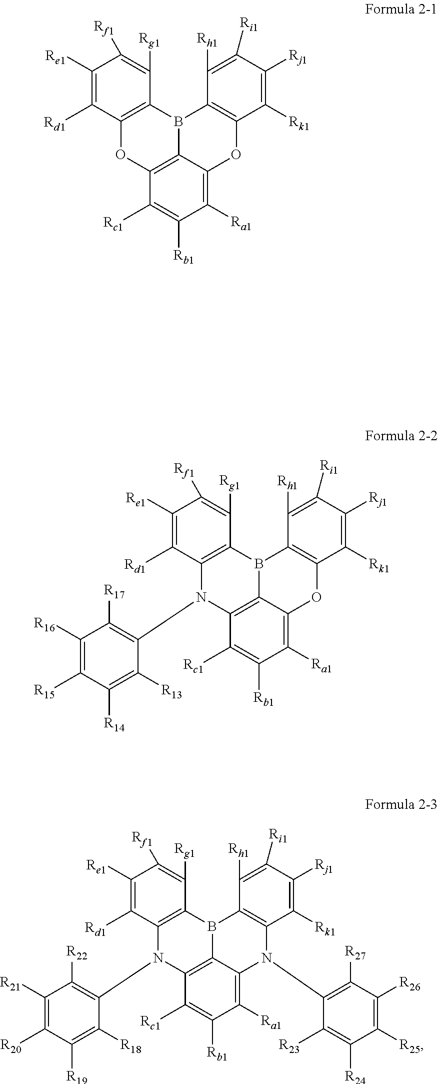
wherein, in Formula 2-1 to Formula 2-3,
R₁₃ to R₂₇ are each independently a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring, and
Rₐ₁ to Rₖ₁ are as defined in Formula 2.

4. The light-emitting element of claim 1, wherein the first compound is represented by any one selected from among Formula 3-1 to Formula 3-3: 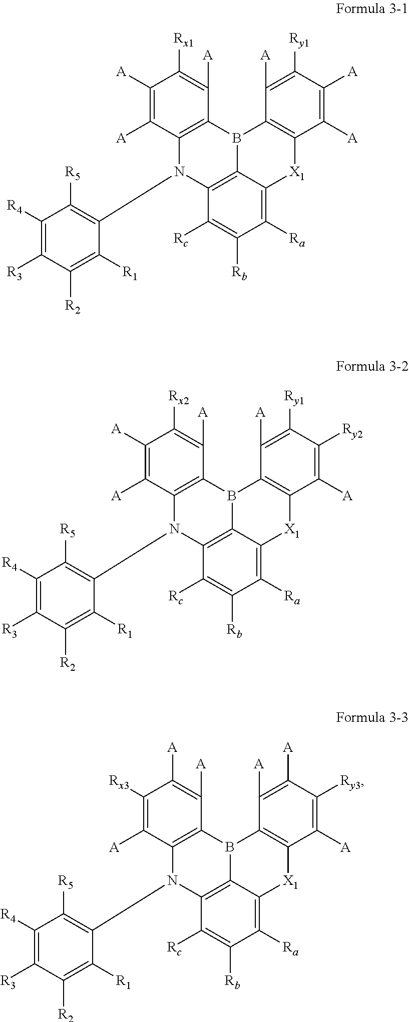
wherein, in Formula 3-1 to Formula 3-3,
A is a hydrogen atom or a deuterium atom,
Rₓ₁, Rₓ₂, Rₓ₃, R_{y1}, R_{y2}, and R_{y3} are each independently a substituted or unsubstituted amine group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and
X₁, R₁ to R₅, and Rₐ to R_{c} are as defined in Formula 1,
in Formula 3-1, at least one selected from among Rₓ₁ and R_{y1} is a substituent represented by Formula 2,
in Formula 3-2, at least one selected from among Rₓ₂ and R_{y2} is a substituent represented by Formula 2, and
in Formula 3-3, at least one selected from among Rₓ₃ and R_{y3} is a substituent represented by Formula 2.

5. The light-emitting element of claim 1, wherein at least one selected from among R_{d} to Rₖ is represented by any one selected from among Formula 4-1 to Formula 4-3: 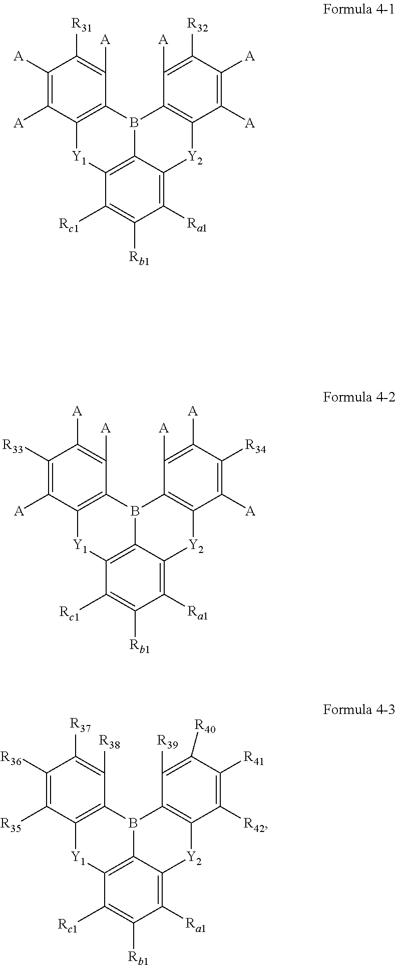
wherein, in Formula 4-1 to Formula 4-3,
A is a hydrogen atom or a deuterium atom,
R₃₁ to R₄₂ are each independently a hydrogen atom, a deuterium atom, a halogen atom, a substituted or unsubstituted amine group, a substituted or unsubstituted oxy group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring,
at least one adjacent pair selected from among R₃₅ to R₄₂ are bonded to each other to form a ring, and
Y₁, Y₂, and Rₐ₁ to R_{c1} are as defined in Formula 2.

6. The light-emitting element of claim 1, wherein the first compound is represented by Formula 5: 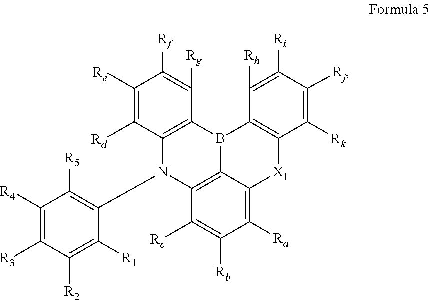
wherein, in Formula 5,
A is a hydrogen atom or a deuterium atom,
R_{z} is a substituted or unsubstituted amine group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and
X₁, R₁ to R₅, and R_{d} to Rₖ are as defined in Formula 1.

7. The light-emitting element of claim 1, wherein at least one selected from among R_{d} to Rₖ is represented by Formula 6-1, or Formula 6-2: 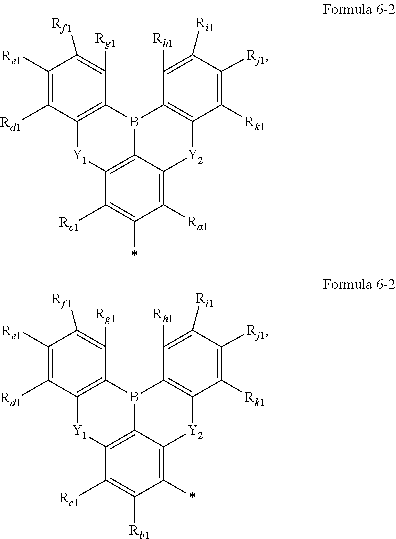
wherein, in Formula 6-1 and Formula 6-2, 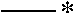 [SMILES: *C]
is a portion to which Formula 1 is connected, and
Y₁, Y₂, and Rₐ₁ to Rₖ₁ are as defined in Formula 2.

8. The light-emitting element of claim 1, wherein the first compound is represented by Formula 7: 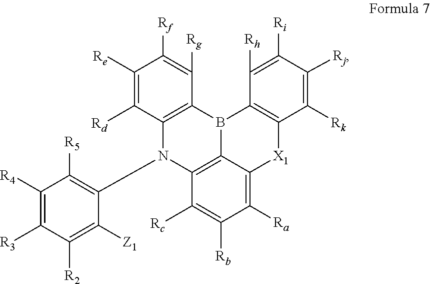
wherein, in Formula 7,
A is a hydrogen atom or a deuterium atom,
Z₁ to Z₃ are each independently a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and
X₁ and Rₐ to Rₖ are as defined in Formula 1.

9. The light-emitting element of claim 1,
wherein, in Formula 1:
one or two selected from among R_{d} to Rₖ are each independently a substituent represented by Formula 2, and
any remaining selected from among R_{d} to Rₖ are each independently a hydrogen atom, a deuterium atom, a substituted or unsubstituted t-butyl group, a substituted or unsubstituted phenyl group, or a substituted or unsubstituted carbazole group.

10. The light-emitting element of claim 1,
wherein, in Formula 2:
any one selected from among Rₐ₁ to R_{c1} is a portion to which Formula 1 is connected, and two selected from among Rₐ₁ to R_{c1} are each independently a hydrogen atom or a deuterium atom; and
R_{d1} to Rₖ₁ are each independently
a hydrogen atom, a deuterium atom, a substituted or unsubstituted t-butyl group, a substituted or unsubstituted phenyl group, or a substituted or unsubstituted carbazole group, and/or
bonded to an adjacent group to form an aromatic hydrocarbon ring or an aromatic hetero ring.

11. The light-emitting element of claim 1, wherein the emission layer further comprises at least one selected from among a second compound represented by Formula HT-1, a third compound represented by Formula ET-1, and a fourth compound represented by Formula D-1: 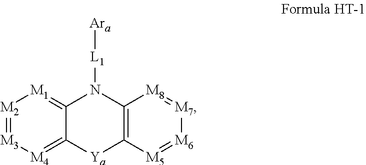
wherein, in Formula HT-1,
M₁ to M₈ are each independently N or CR₅₁,
L₁ is a direct linkage, a substituted or unsubstituted arylene group having 6 to 30 ring-forming carbons, or a substituted or unsubstituted heteroarylene group having 2 to 30 ring-forming carbons,
Yₐ is a direct linkage, CR₅₂R₅₃, or SiR₅₄R₅₅,
Arₐ is a substituted or unsubstituted aryl group having 6 to 30 ring-forming carbons, a substituted or unsubstituted heteroaryl group having 2 to 30 ring-forming carbons, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, and/or are each bonded to an adjacent group to form a ring: 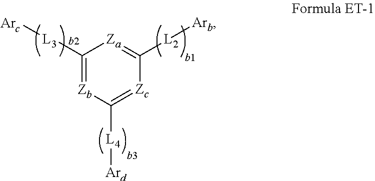
wherein, in Formula ET-1,
at least one selected from among Zₐ to Z_{c} is N, and any remaining Zₐ to Z_{c} are CR₅₆,
R₅₆ is a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons,
b1 to b3 are each independently an integer of 0 to 10,
Ar_{b} to Ar_{d} are each independently a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 carbons, and
L₂ to L₄ are each independently a direct linkage, a substituted or unsubstituted arylene group having 6 to 30 ring-forming carbons, or a substituted or unsubstituted heteroarylene group having 2 to 30 ring-forming carbons: 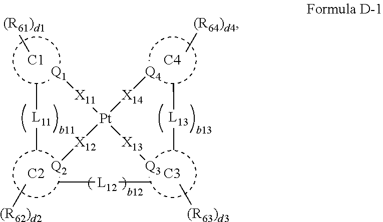
wherein, in Formula D-1,
Q₁ to Q₄ are each independently C or N,
C1 to C4 are each independently a substituted or unsubstituted hydro carbon ring having 5 to 30 ring-forming carbons, a substituted or unsubstituted aryl group having 6 to 30 ring-forming carbons, or a substituted or unsubstituted heteroaryl group having 2 to 30 ring-forming carbons,
X₁₁ to X₁₄ are each independently a direct linkage, or 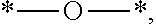
L₁₁ to L₁₃ are each independently a direct linkage, 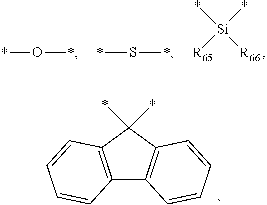
a substituted or unsubstituted divalent alkyl group having 1 to 20 carbons, a substituted or unsubstituted arylene group having 6 to 30 ring-forming carbons, or a substituted or unsubstituted heteroarylene group having 2 to 30 ring-forming carbons,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, and
d1 to d4 are each independently an integer of 0 to 4.

12. An electronic device comprising:
a base layer;
a circuit layer on the base layer; and
a display element layer on the circuit layer and comprising a light-emitting element,
wherein the light-emitting element comprises a first electrode, a second electrode on the first electrode, and an emission layer between the first electrode and the second electrode and comprising a first compound represented by Formula 1: 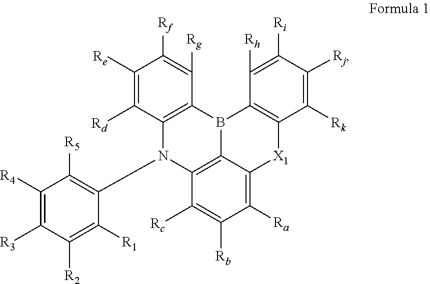
wherein, in Formula 1,
X₁ O, S, or NR₆,
R₁ to R₆, and Rₐ to Rₖ are each independently a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring, and
any one selected from among R_{d} to Rₖ is a substituent represented by Formula 2: 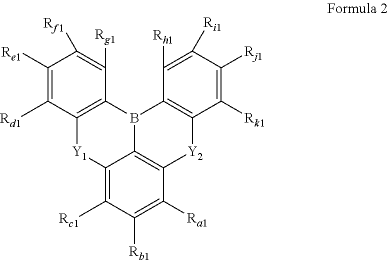
wherein, in Formula 2,
Y₁ and Y₂ are each independently O, S, or NR₇,
R₇, and Rₐ₁ to Rₖ₁ are each independently a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring, and
any one selected from among Rₐ₁ to Rₖ₁ is a portion to which Formula 1 is connected.

13. The electronic device of claim 12,
wherein,
the light-emitting element further comprises a capping layer on the second electrode, and
a refractive index of the capping layer is at least about 1.6 for light in a wavelength range of about 550 nanometer (nm) to about 660 nm.

14. The electronic device of claim 12, further comprising a light control layer on the display element layer and comprising a quantum dot,
wherein the light-emitting element is configured to emit a first color light, and
wherein the light control layer comprises:
a first light control part comprising a first quantum dot configured to convert the first color light into a second color light, the second color light having a wavelength region that is longer than a wavelength region of the first color light;
a second light control part comprising a second quantum dot configured to convert the first color light into a third color light, the third color light having a wavelength region that is longer than a wavelength region of the first color light and a wavelength region of the second color light; and
a third light control part configured to transmit the first color light.

15. The electronic device of claim 12, wherein the electronic device is at least one selected from among:
large-sized display devices selected from among televisions, monitors, and outdoor billboards; and
medium- or small-sized display devices selected from among personal computers, laptop computers, personal digital assistants, display devices for vehicles, game consoles, mobile electronic devices, or cameras.

16. A fused polycyclic compound represented by Formula 1: 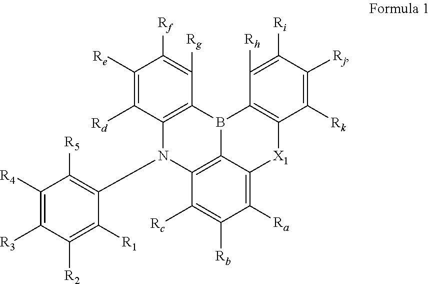
wherein, in Formula 1,
X₁ is O, S, or NR₆,
R₁ to R₆, and Rₐ to Rₖ are each independently a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring, and
at least one selected from among R_{d} to Rₖ is a substituent represented by Formula 2: 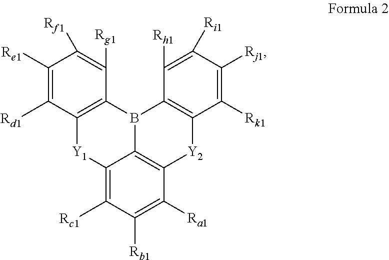
wherein, in Formula 2,
Y₁ and Y₂ are each independently O, S, or NR₇,
R₇, and Rₐ₁ to Rₖ₁ are each independently a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring, and
any one selected from among Rₐ₁ to Rₖ₁ is a portion to which Formula 1 is connected.

17. The fused polycyclic compound of claim 16, wherein the fused polycyclic compound is represented by Formula 1-1 or Formula 1-2: 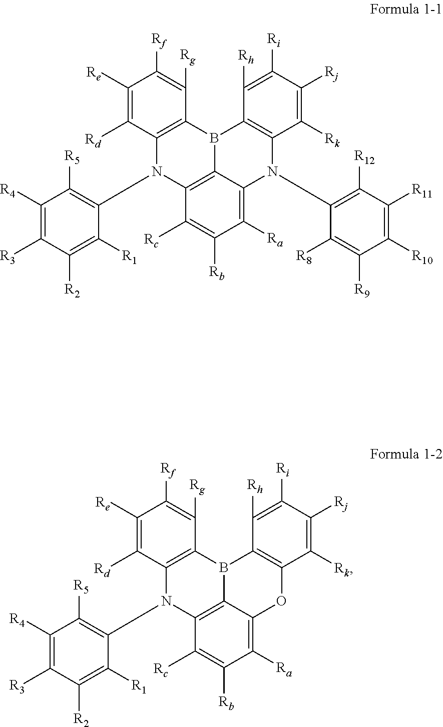
wherein, in Formula 1-1 and Formula 1-2,
R₈ to R₁₂ are each independently a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring, and
R₁ to R₅, and Rₐ to Rₖ are as defined in Formula 1.

18. The fused polycyclic compound of claim 16, wherein at least one selected from among R_{d} to Rₖ is represented by any one selected from among Formula 2-1 to Formula 2-3: 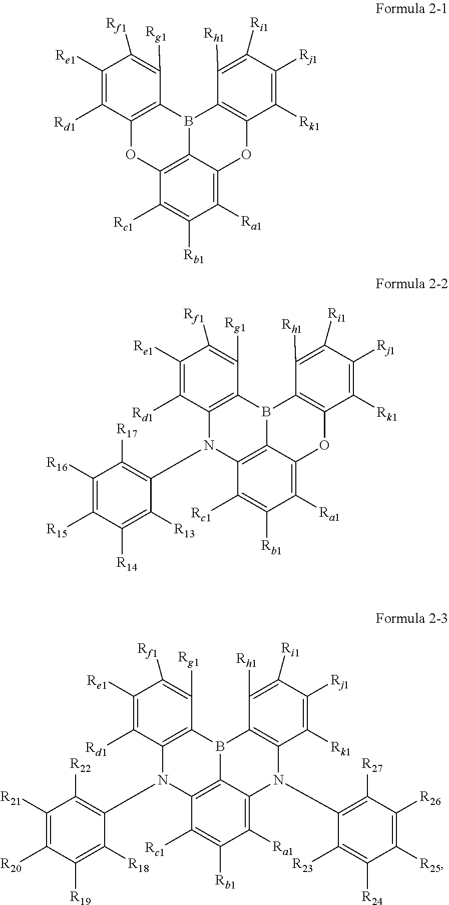
wherein, in Formula 2-1 to Formula 2-3,
R₁₃ to R₂₇ are each independently a hydrogen atom, a deuterium atom, a halogen atom, a substituted or unsubstituted amine group, a substituted or unsubstituted oxy group, a substituted or unsubstituted thio group, a substituted or unsubstituted alkyl group having 1 to 20 carbons, a substituted or unsubstituted alkenyl group having 2 to 20 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring, and
Rₐ₁ to Rₖ₁ are as defined in Formula 2.

19. The fused polycyclic compound of claim 16, wherein the fused polycyclic compound is represented by any one selected from among Formula 3-1 to Formula 3-3: 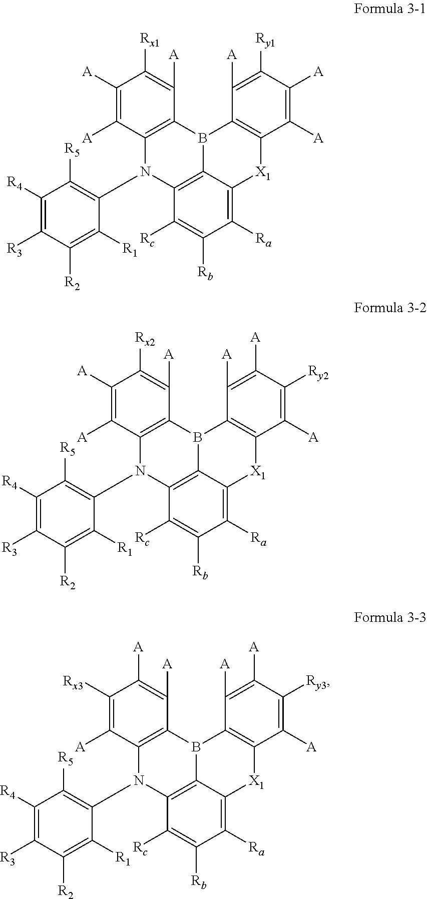
wherein, in Formula 3-1 to Formula 3-3,
A is a hydrogen atom, or a deuterium atom,
Rₓ₁, Rₓ₂, Rₓ₃, R_{y1}, R_{y2}, and R_{y3} are each independently a substituted or unsubstituted amine group, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons,
X₁, R₁ to R₅, and Rₐ to R_{c} are as defined in Formula 1,
in Formula 3-1, at least one selected from among Rₓ₁ and R_{y1} is a substituent represented by Formula 2,
in Formula 3-2, at least one selected from among Rₓ₂ and R_{y2} is a substituent represented by Formula 2, and
in Formula 3-3, at least one selected from among Rₓ₃ and R_{y3} is a substituent represented by Formula 2.

20. The fused polycyclic compound of claim 16, wherein the fused polycyclic compound comprises at least one selected from among Compound Group 1: 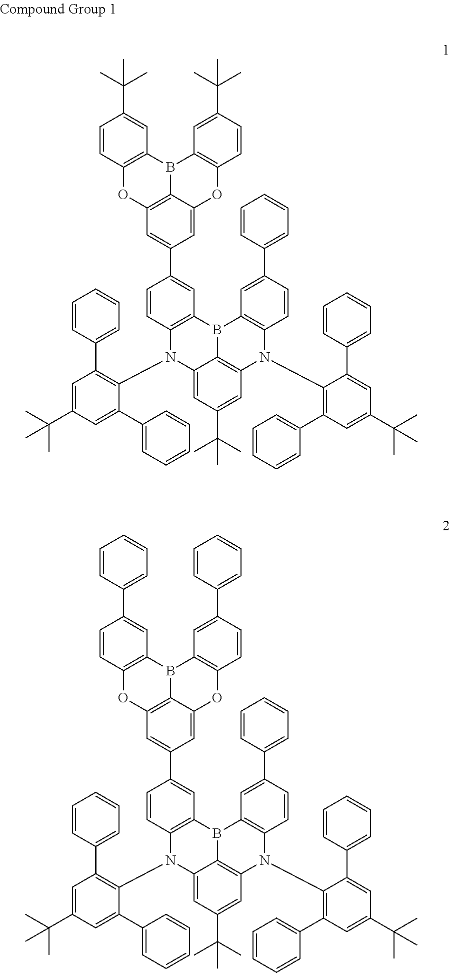 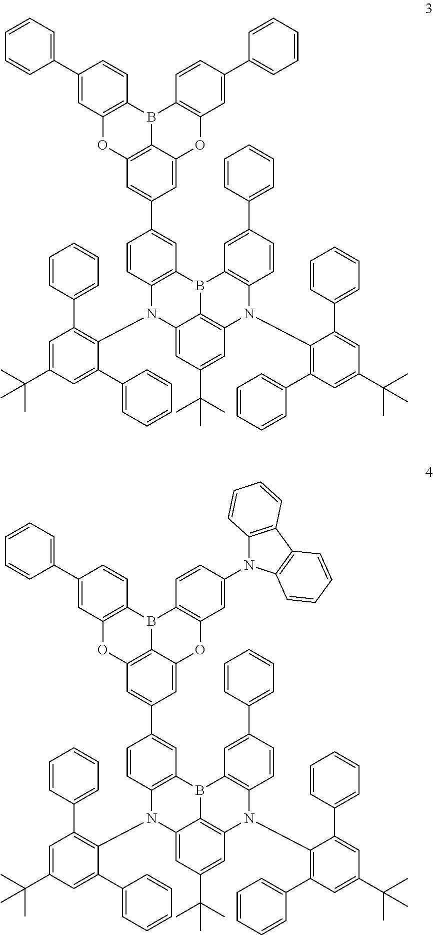 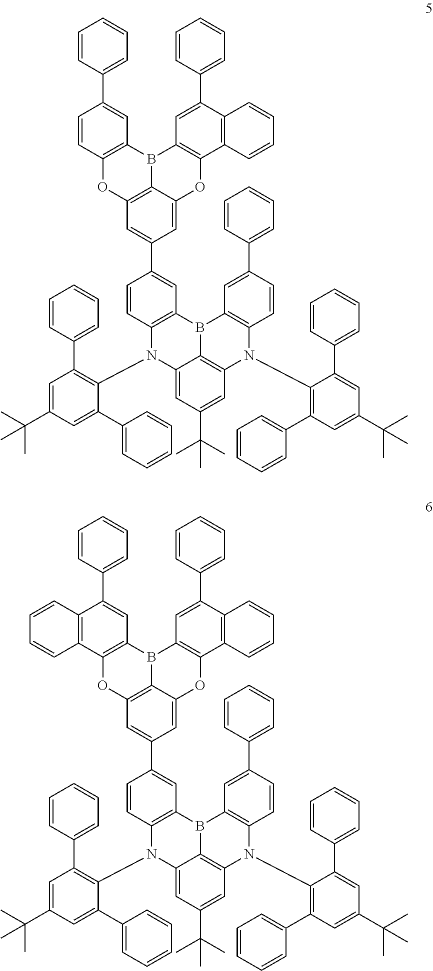 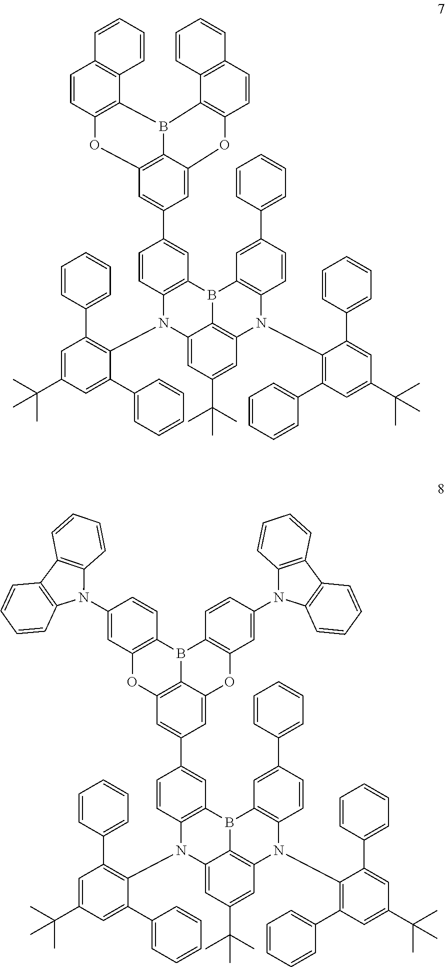 [SMILES: CC(C)(C)c1cc(-c2ccccc2)c(N2c3ccc(-c4ccccc4)cc3B3c4cc(-c5cc6c7c(c5)Oc5ccc8ccccc8c5B7c5c(ccc7ccccc57)O6)ccc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4ccccc4)cc3B3c4cc(-c5cc6c7c(c5)Oc5cc(-n8c9ccccc9c9ccccc98)ccc5B7c5ccc(-n7c8ccccc8c8ccccc87)cc5O6)ccc4N(c4c(-c5ccccc5)cc(C(C)(C)C)cc4-c4ccccc4)c4cc(C(C)(C)C)cc2c43)c(-c2ccccc2)c1] 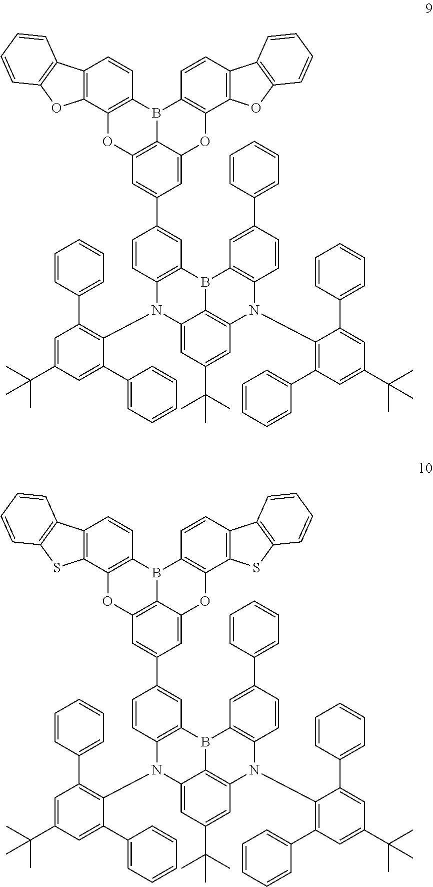 [SMILES: CC(C)(C)c1cc(-c2ccccc2)c(N2c3ccc(-c4ccccc4)cc3B3c4cc(-c5cc6c7c(c5)Oc5c(ccc8c5oc5ccccc58)B7c5ccc7c(oc8ccccc87)c5O6)ccc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4ccccc4)cc3B3c4cc(-c5cc6c7c(c5)Oc5c(ccc8c5sc5ccccc58)B7c5ccc7c(sc8ccccc87)c5O6)ccc4N(c4c(-c5ccccc5)cc(C(C)(C)C)cc4-c4ccccc4)c4cc(C(C)(C)C)cc2c43)c(-c2ccccc2)c1] 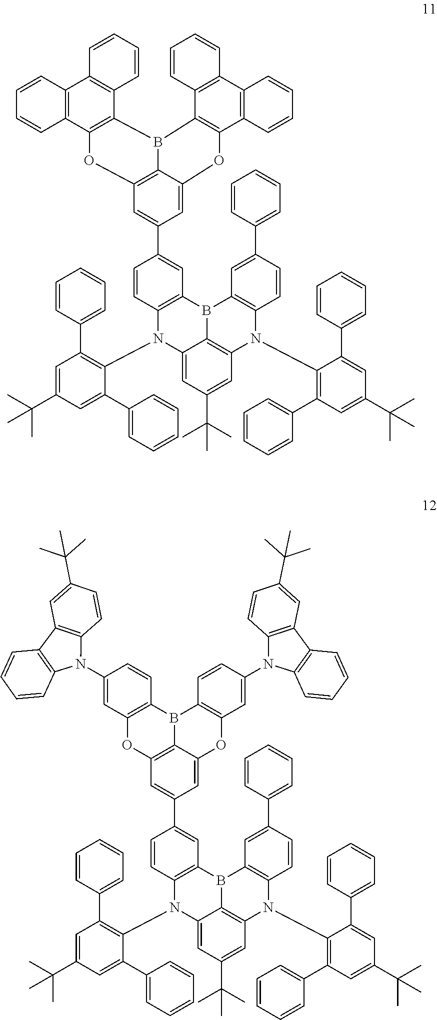 [SMILES: CC(C)(C)c1cc(-c2ccccc2)c(N2c3ccc(-c4ccccc4)cc3B3c4cc(-c5cc6c7c(c5)Oc5c(c8ccccc8c8ccccc58)B7c5c(c7ccccc7c7ccccc57)O6)ccc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4ccccc4)cc3B3c4cc(-c5cc6c7c(c5)Oc5cc(-n8c9ccccc9c9cc(C(C)(C)C)ccc98)ccc5B7c5ccc(-n7c8ccccc8c8cc(C(C)(C)C)ccc87)cc5O6)ccc4N(c4c(-c5ccccc5)cc(C(C)(C)C)cc4-c4ccccc4)c4cc(C(C)(C)C)cc2c43)c(-c2ccccc2)c1] 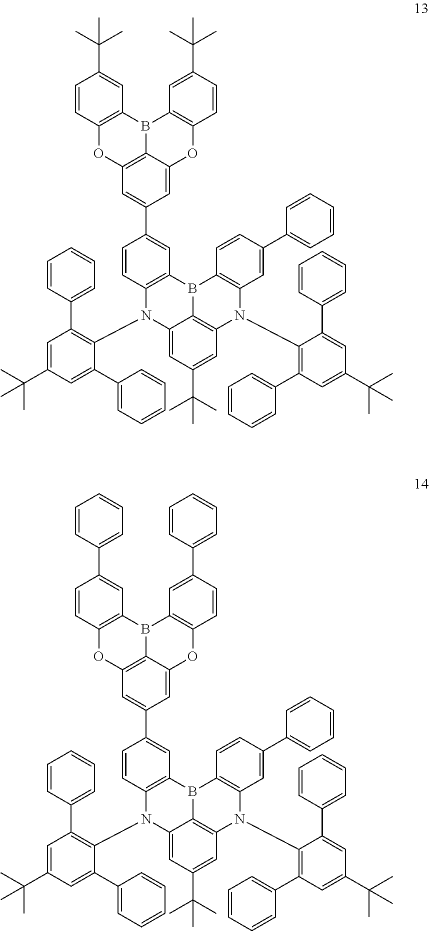 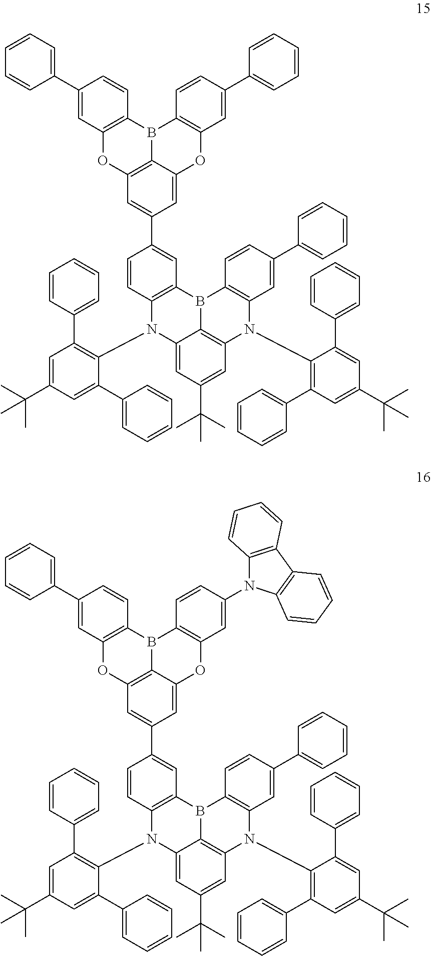 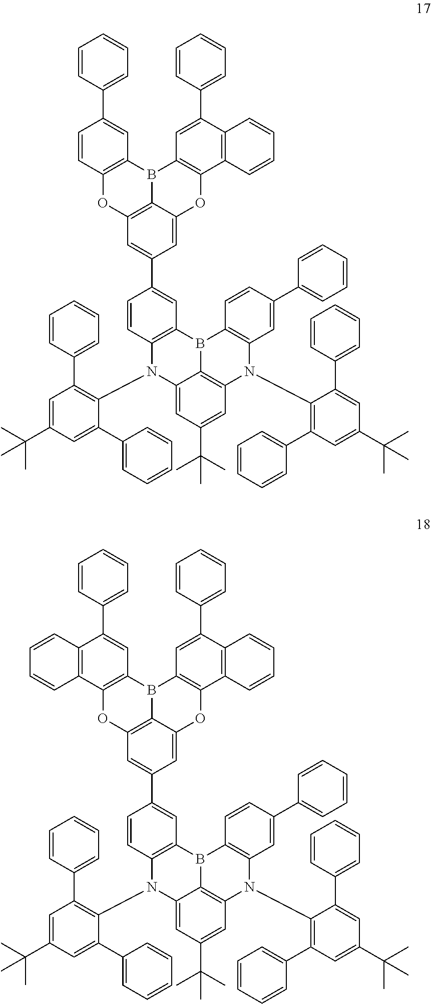 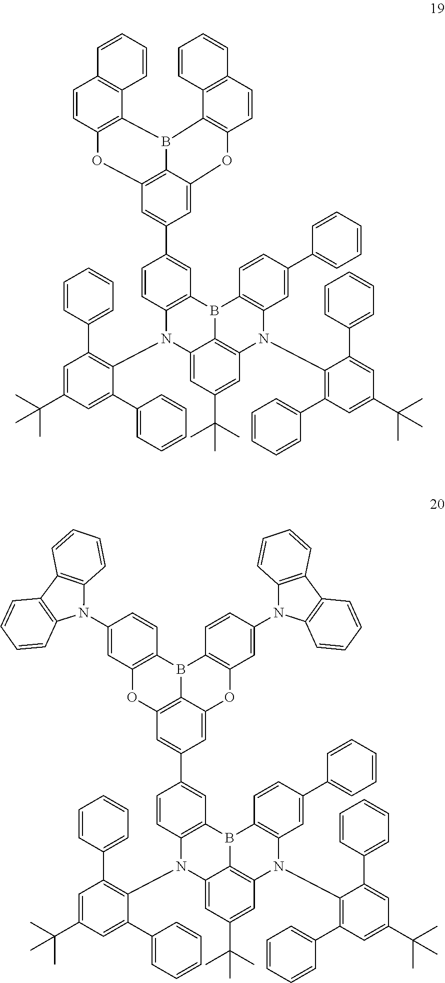 [SMILES: CC(C)(C)c1cc(-c2ccccc2)c(N2c3ccc(-c4cc5c6c(c4)Oc4ccc7ccccc7c4B6c4c(ccc6ccccc46)O5)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-n6c7ccccc7c7ccccc76)cc4O5)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1] 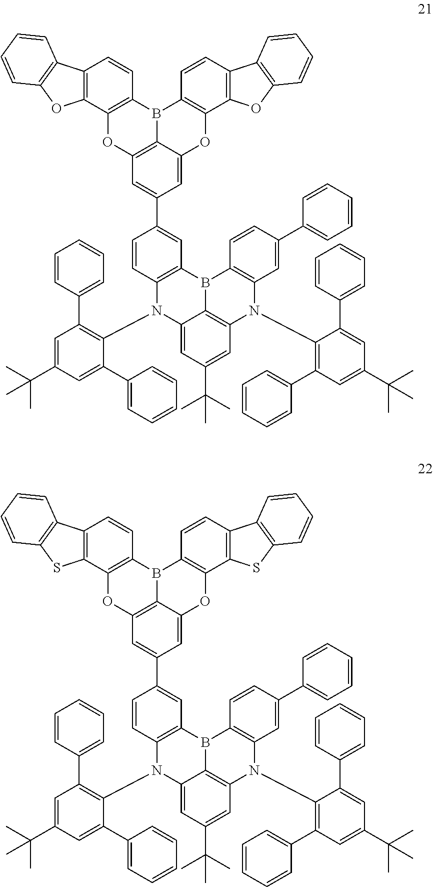 [SMILES: CC(C)(C)c1cc(-c2ccccc2)c(N2c3ccc(-c4cc5c6c(c4)Oc4c(ccc7c4oc4ccccc47)B6c4ccc6c(oc7ccccc76)c4O5)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4cc5c6c(c4)Oc4c(ccc7c4sc4ccccc47)B6c4ccc6c(sc7ccccc76)c4O5)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1] 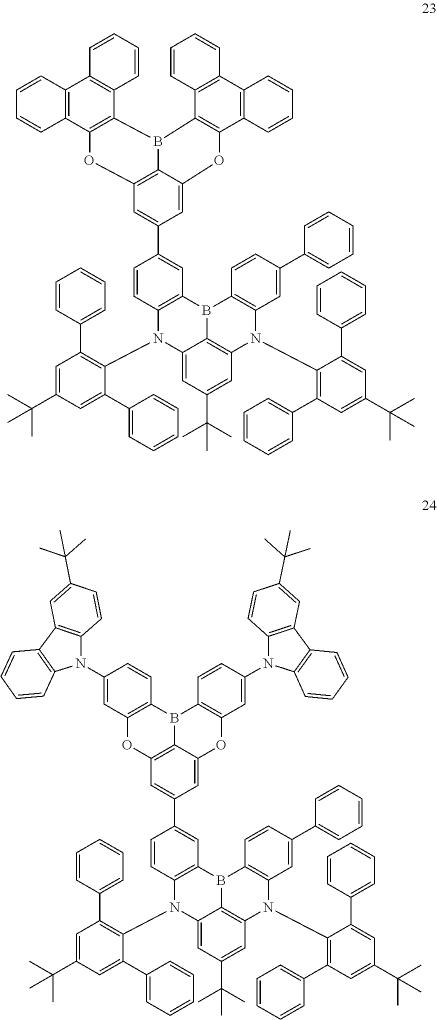 [SMILES: CC(C)(C)c1cc(-c2ccccc2)c(N2c3ccc(-c4cc5c6c(c4)Oc4c(c7ccccc7c7ccccc47)B6c4c(c6ccccc6c6ccccc46)O5)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8cc(C(C)(C)C)ccc87)ccc4B6c4ccc(-n6c7ccccc7c7cc(C(C)(C)C)ccc76)cc4O5)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1] 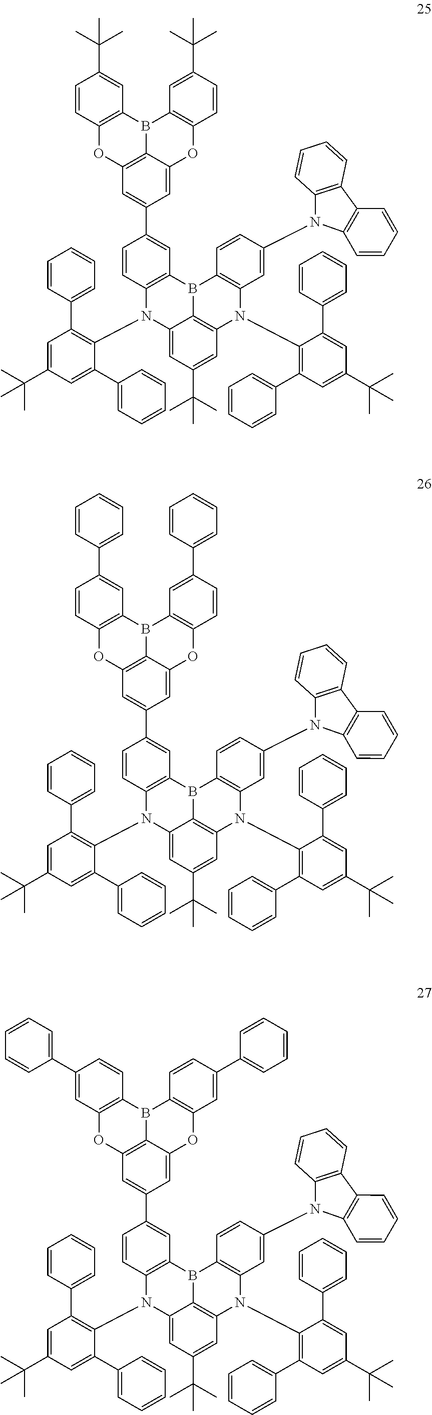 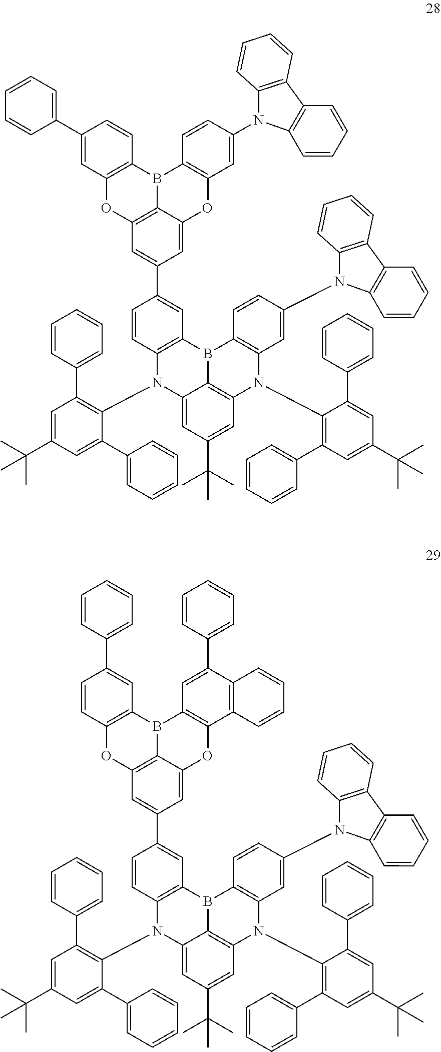 [SMILES: CC(C)(C)c1cc(-c2ccccc2)c(N2c3ccc(-c4cc5c6c(c4)Oc4cc(-n7c8ccccc8c8ccccc87)ccc4B6c4ccc(-c6ccccc6)cc4O5)cc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4cc5c6c(c4)Oc4c(cc(-c7ccccc7)c7ccccc47)B6c4cc(-c6ccccc6)ccc4O5)cc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1] 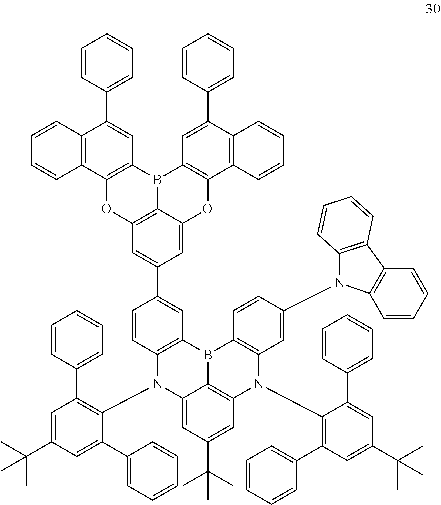 [SMILES: CC(C)(C)c1cc(-c2ccccc2)c(N2c3ccc(-c4cc5c6c(c4)Oc4c(cc(-c7ccccc7)c7ccccc47)B6c4cc(-c6ccccc6)c6ccccc6c4O5)cc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1] 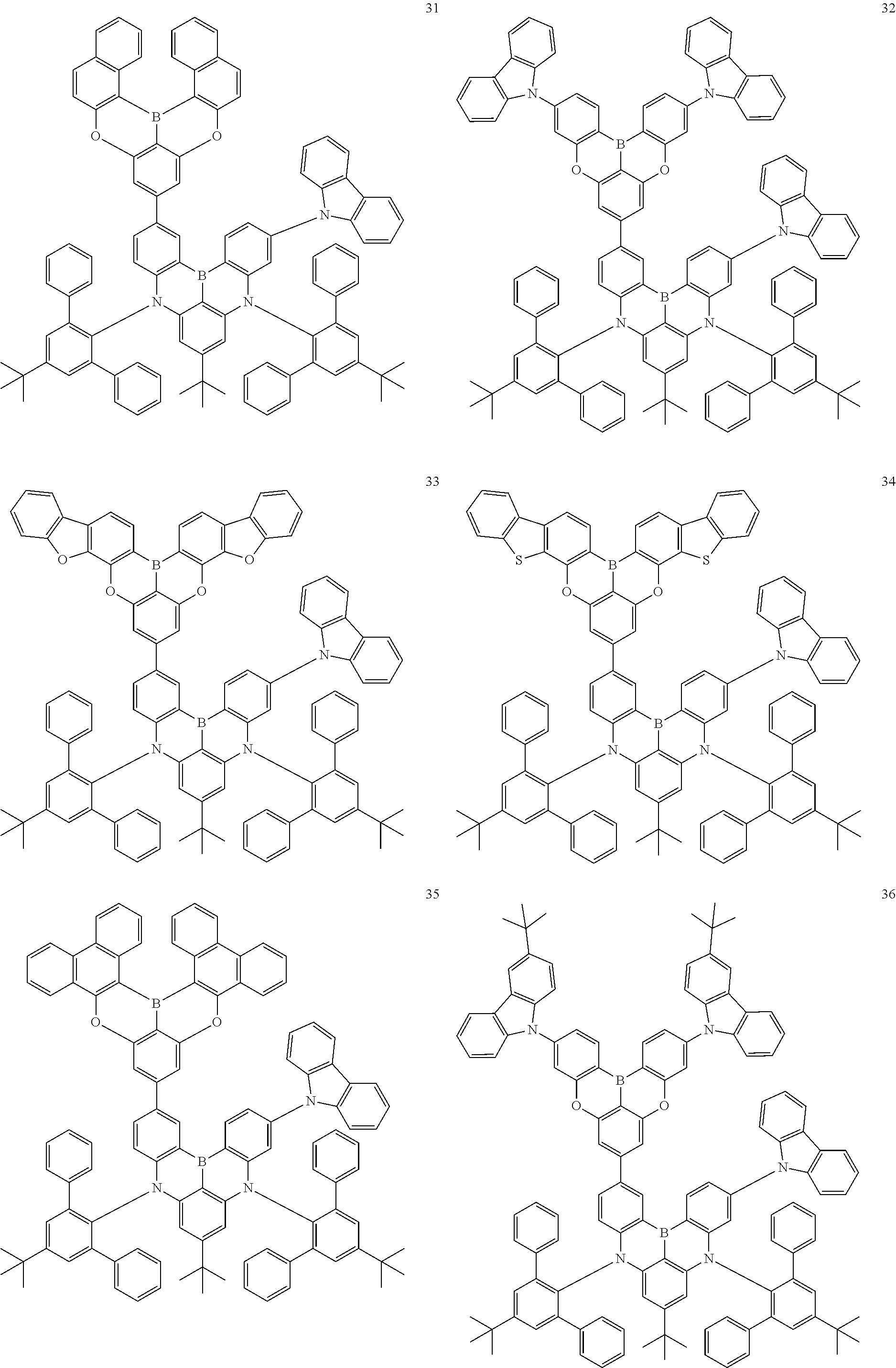 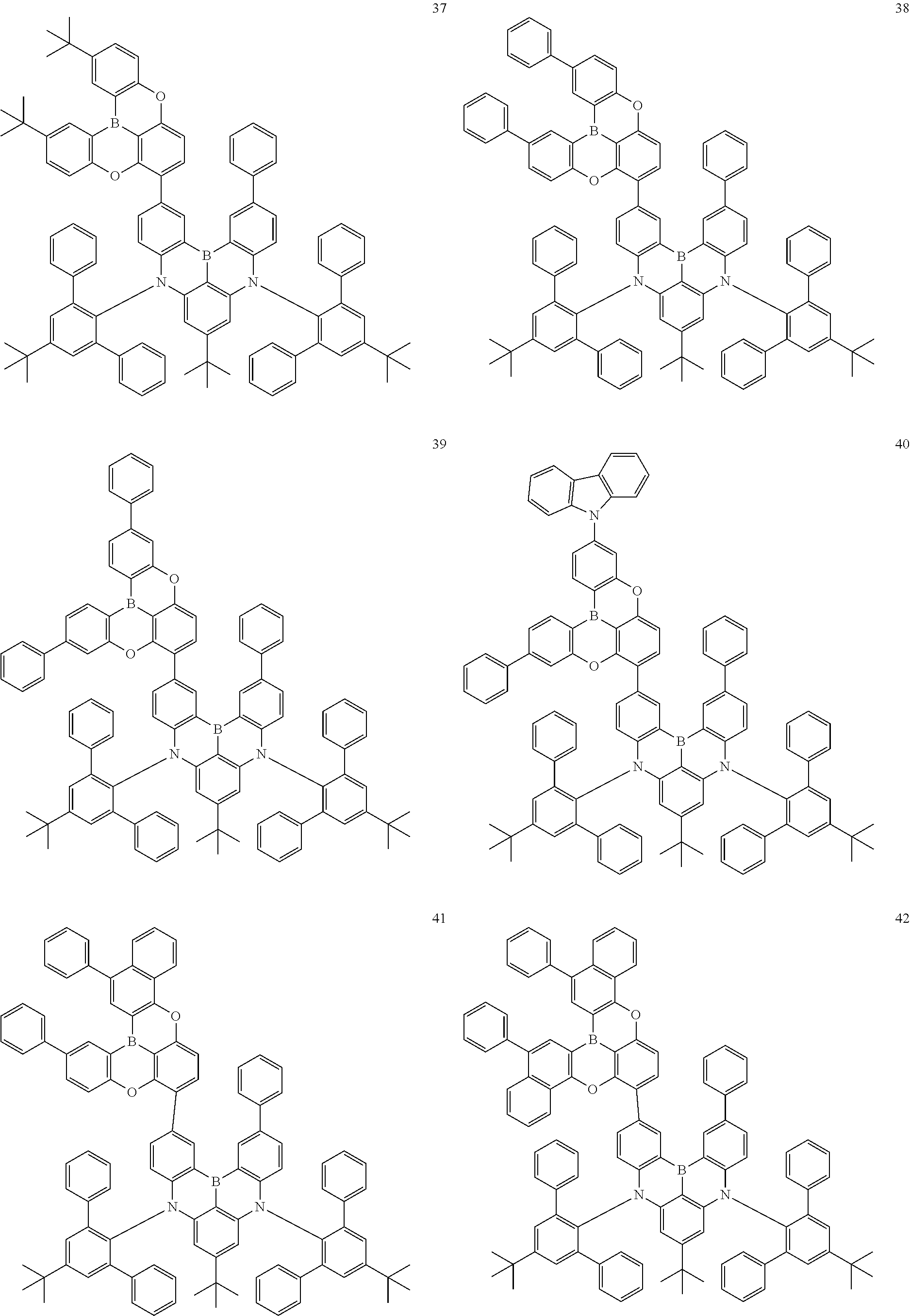 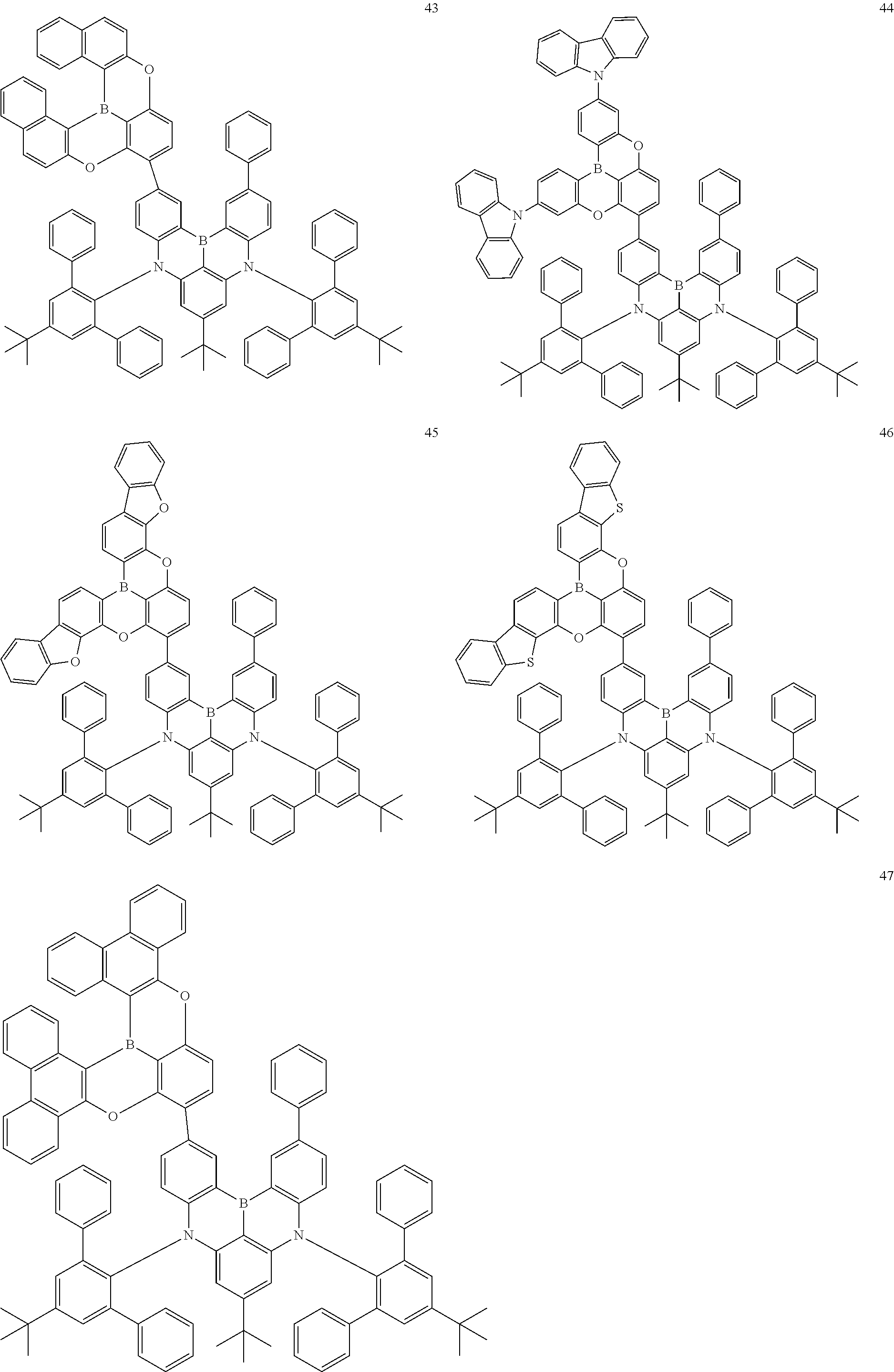 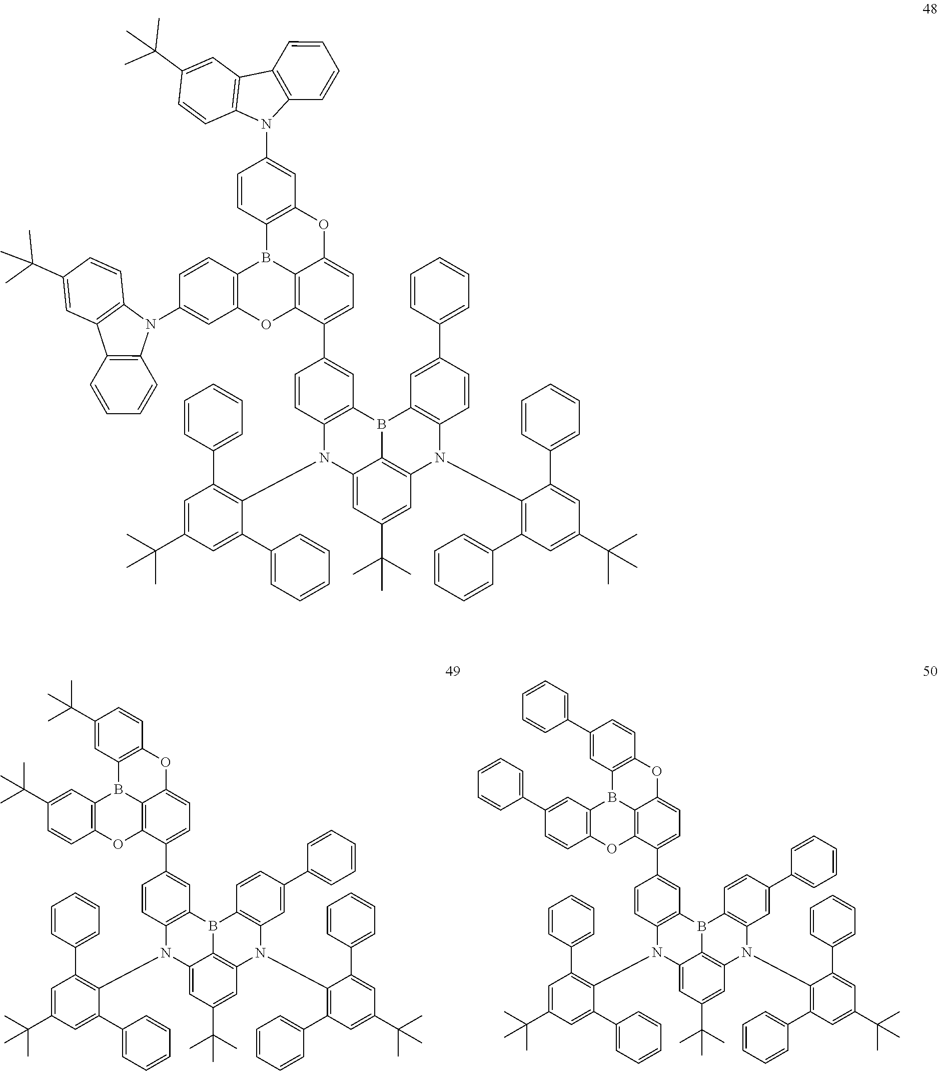 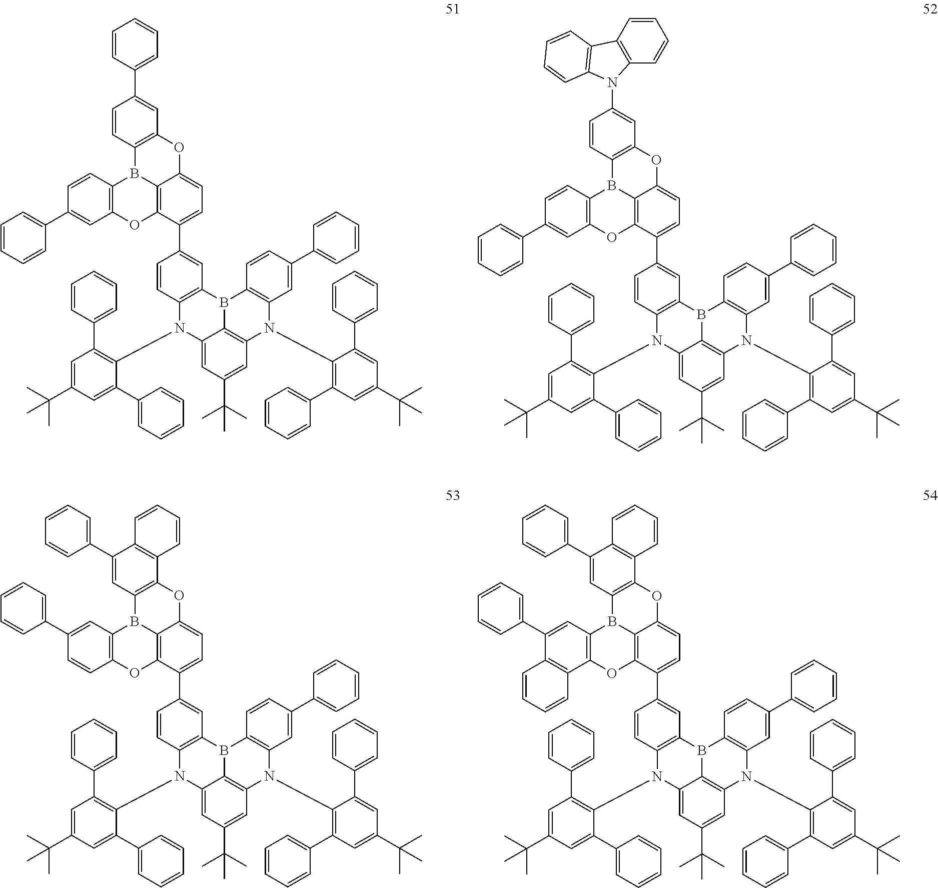 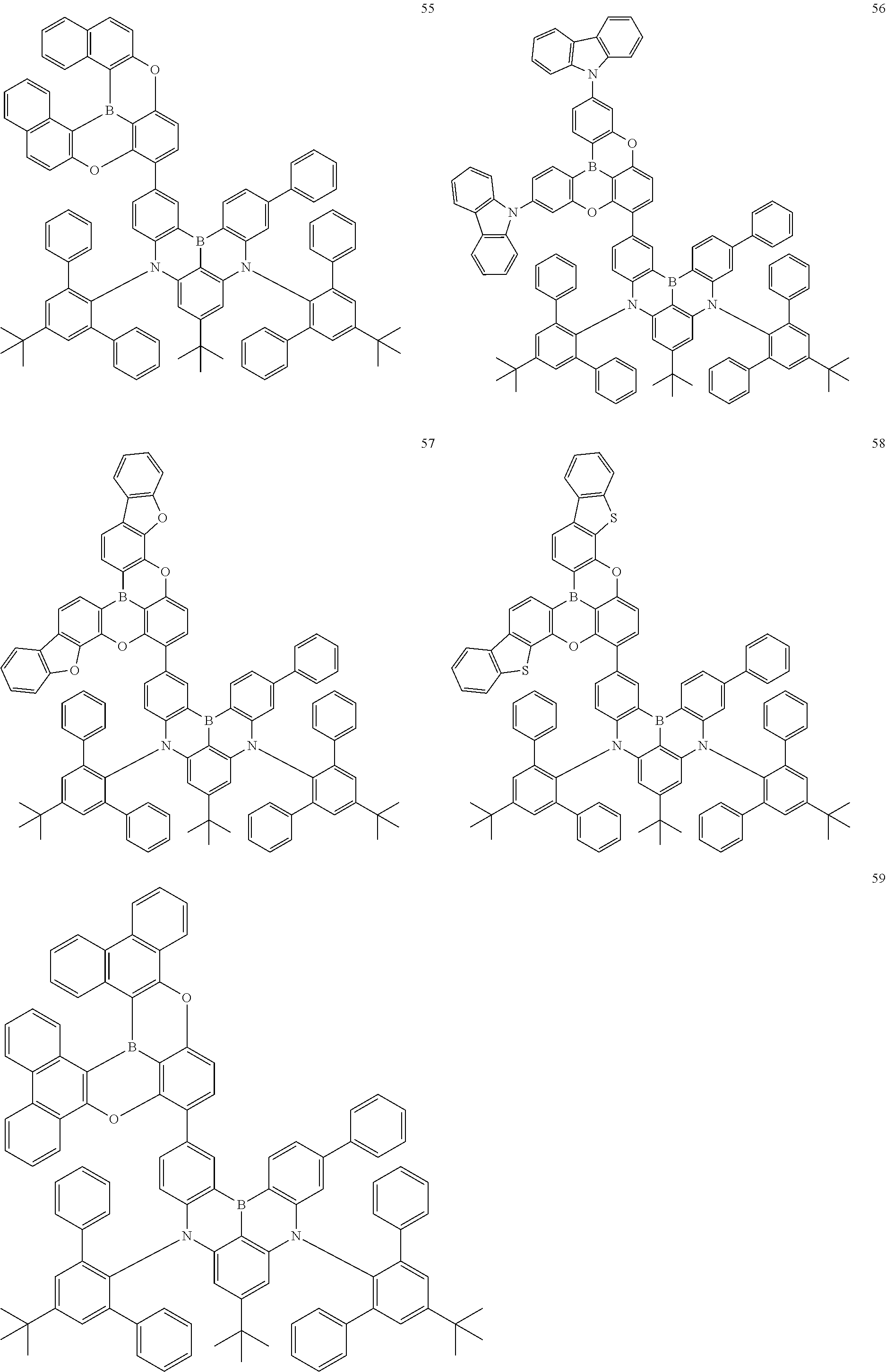 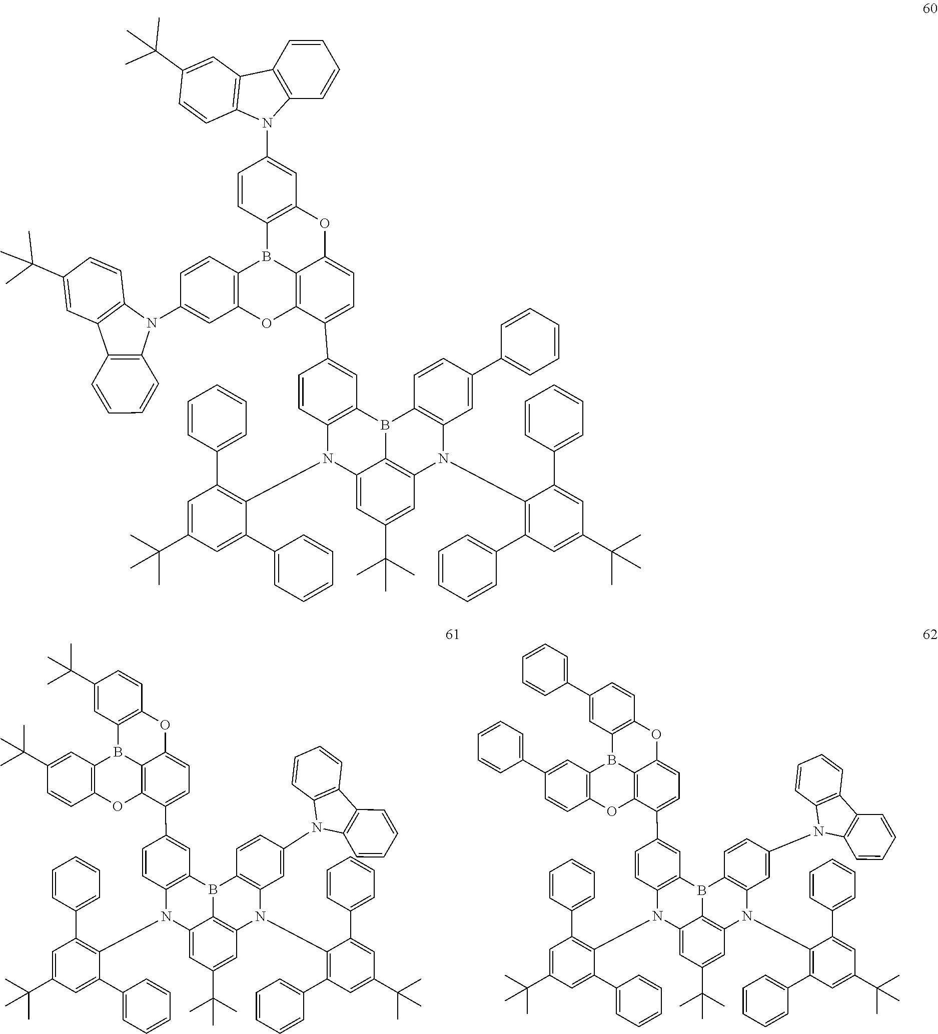 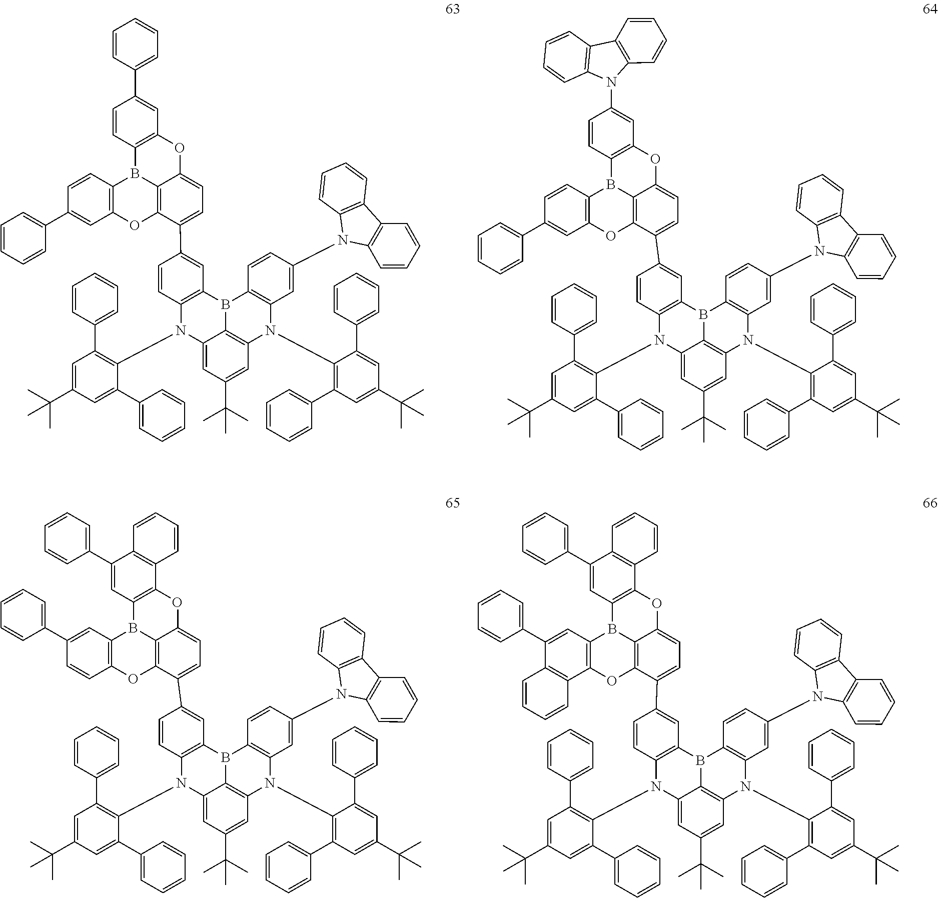 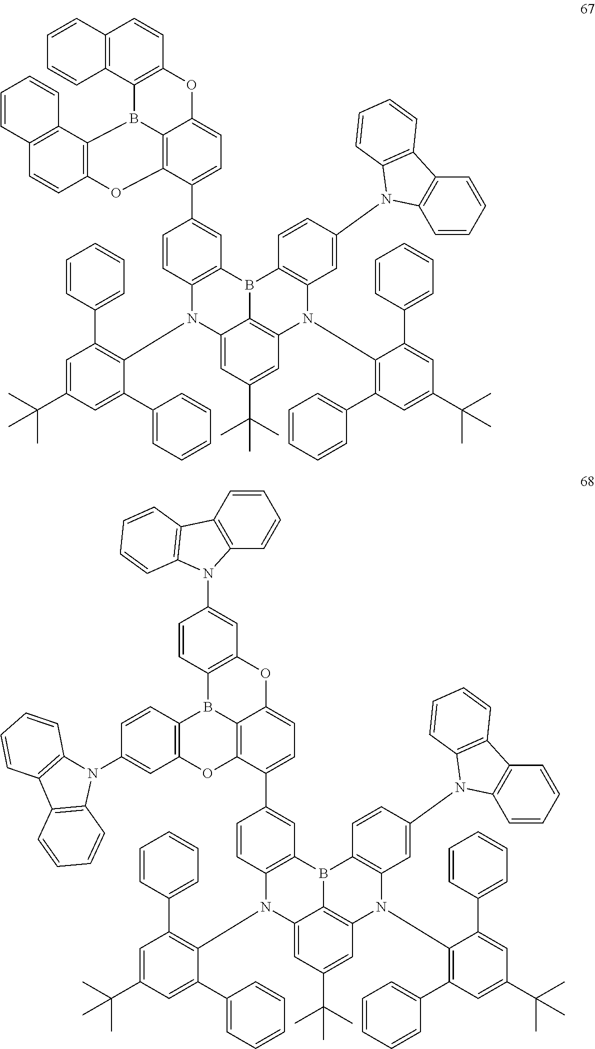 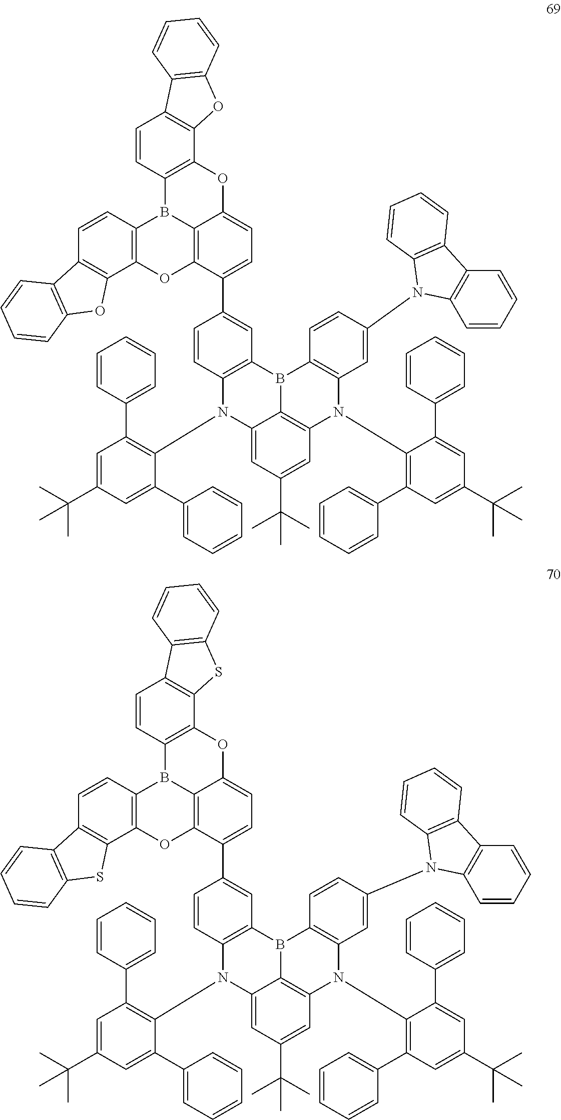 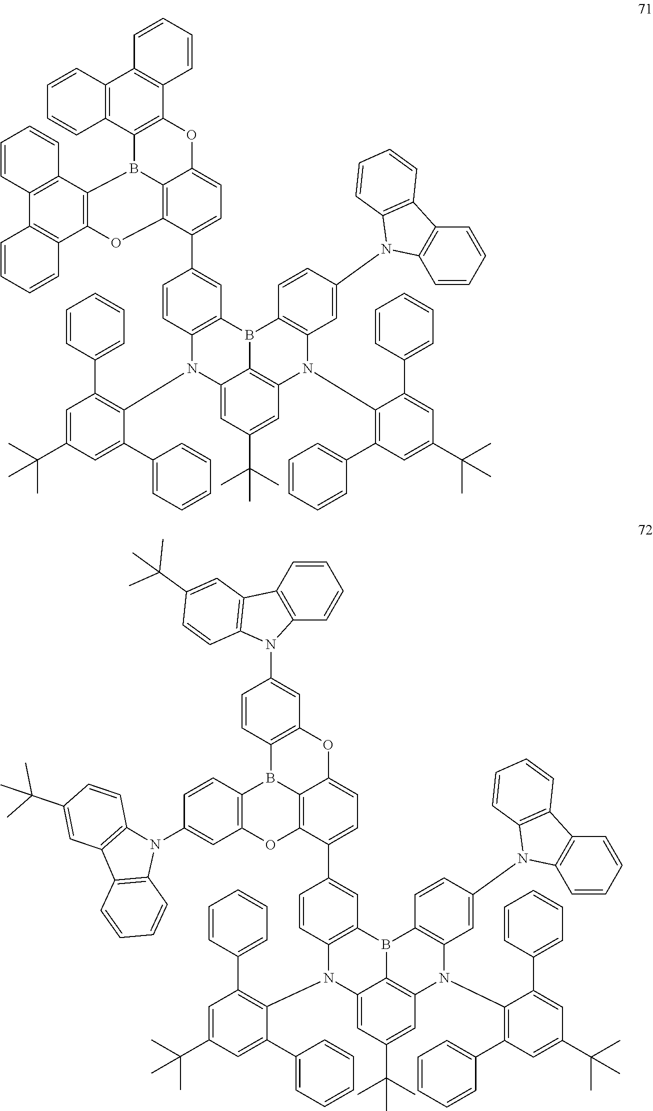 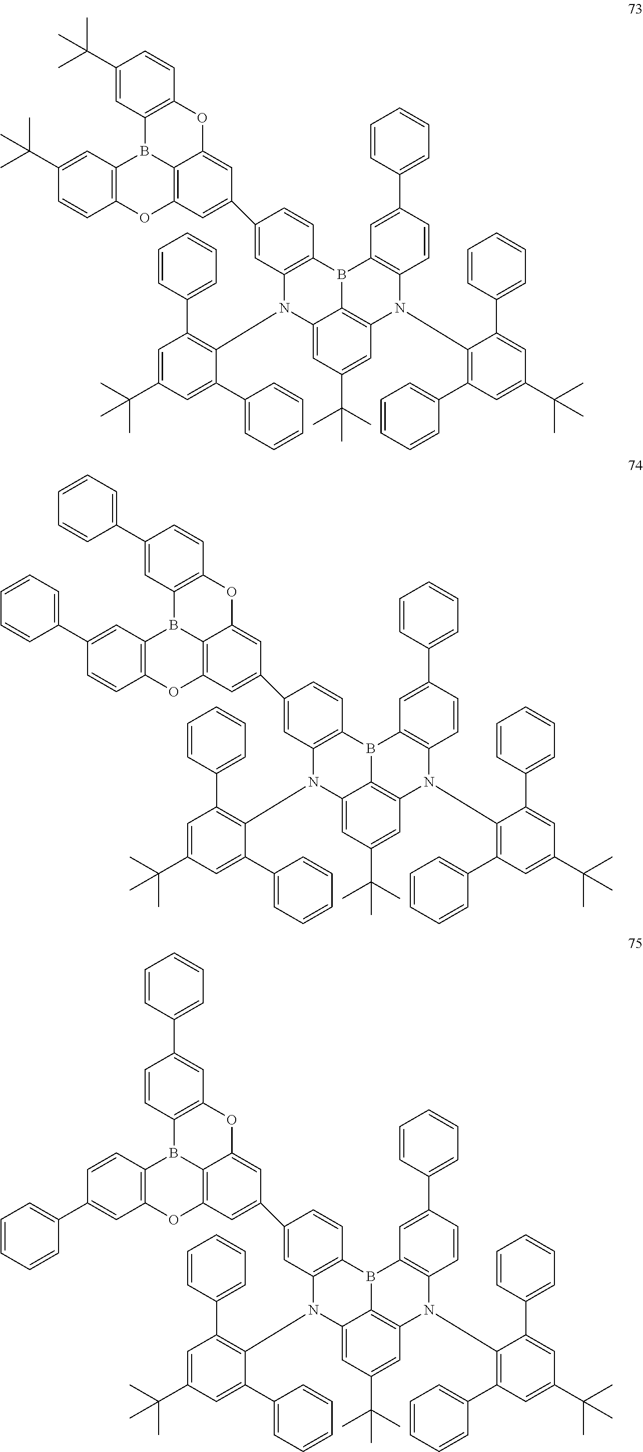 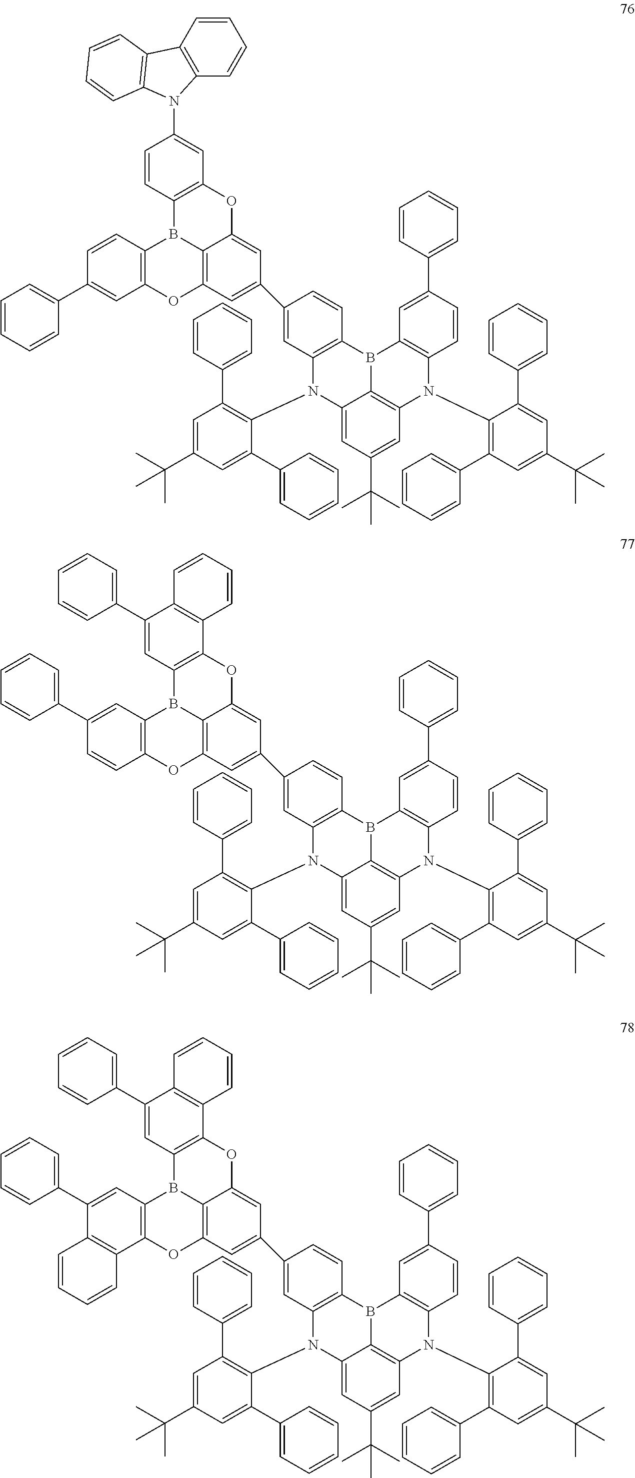 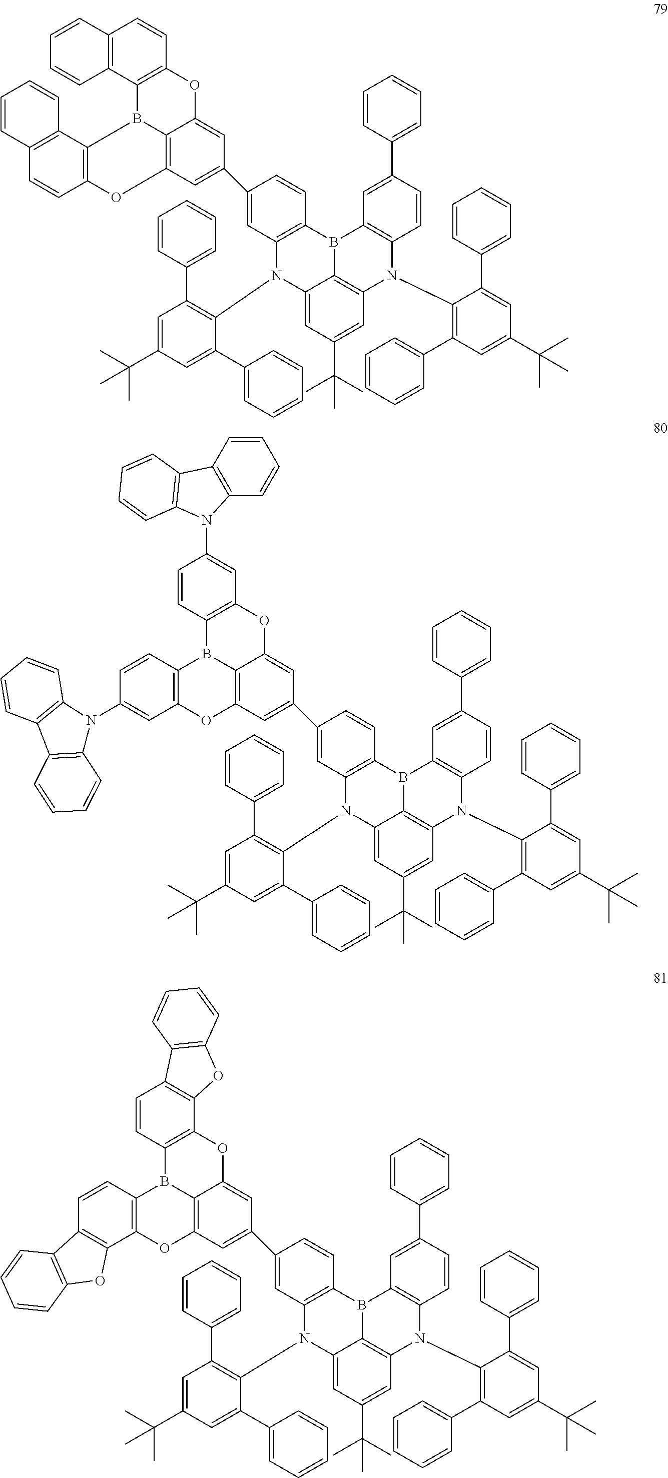 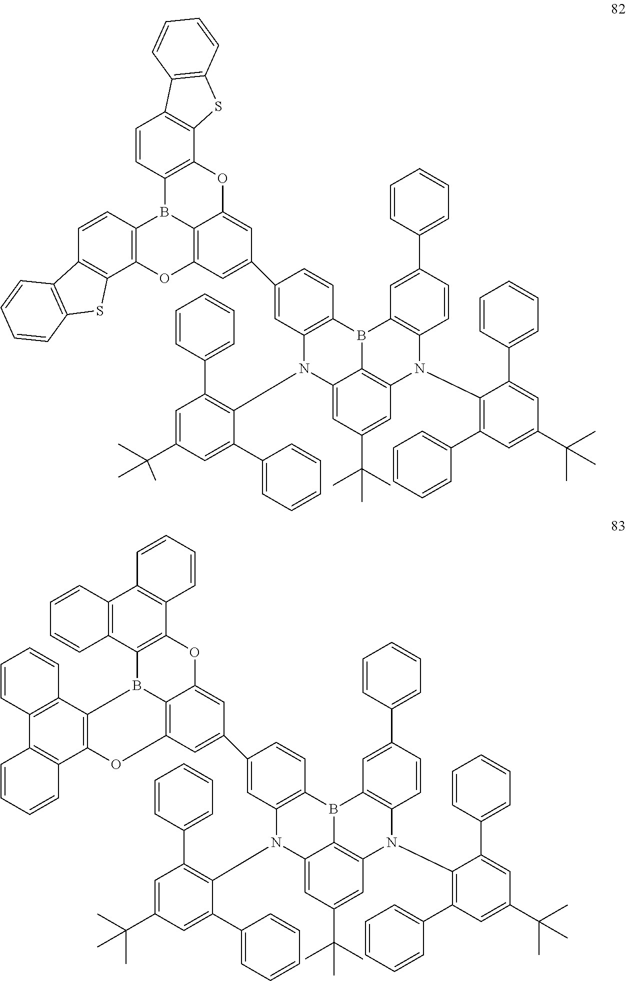 [SMILES: CC(C)(C)c1cc(-c2ccccc2)c(N2c3ccc(-c4ccccc4)cc3B3c4ccc(-c5cc6c7c(c5)Oc5c(ccc8c5sc5ccccc58)B7c5ccc7c(sc8ccccc87)c5O6)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4ccccc4)cc3B3c4ccc(-c5cc6c7c(c5)Oc5c(c8ccccc8c8ccccc58)B7c5c(c7ccccc7c7ccccc57)O6)cc4N(c4c(-c5ccccc5)cc(C(C)(C)C)cc4-c4ccccc4)c4cc(C(C)(C)C)cc2c43)c(-c2ccccc2)c1] 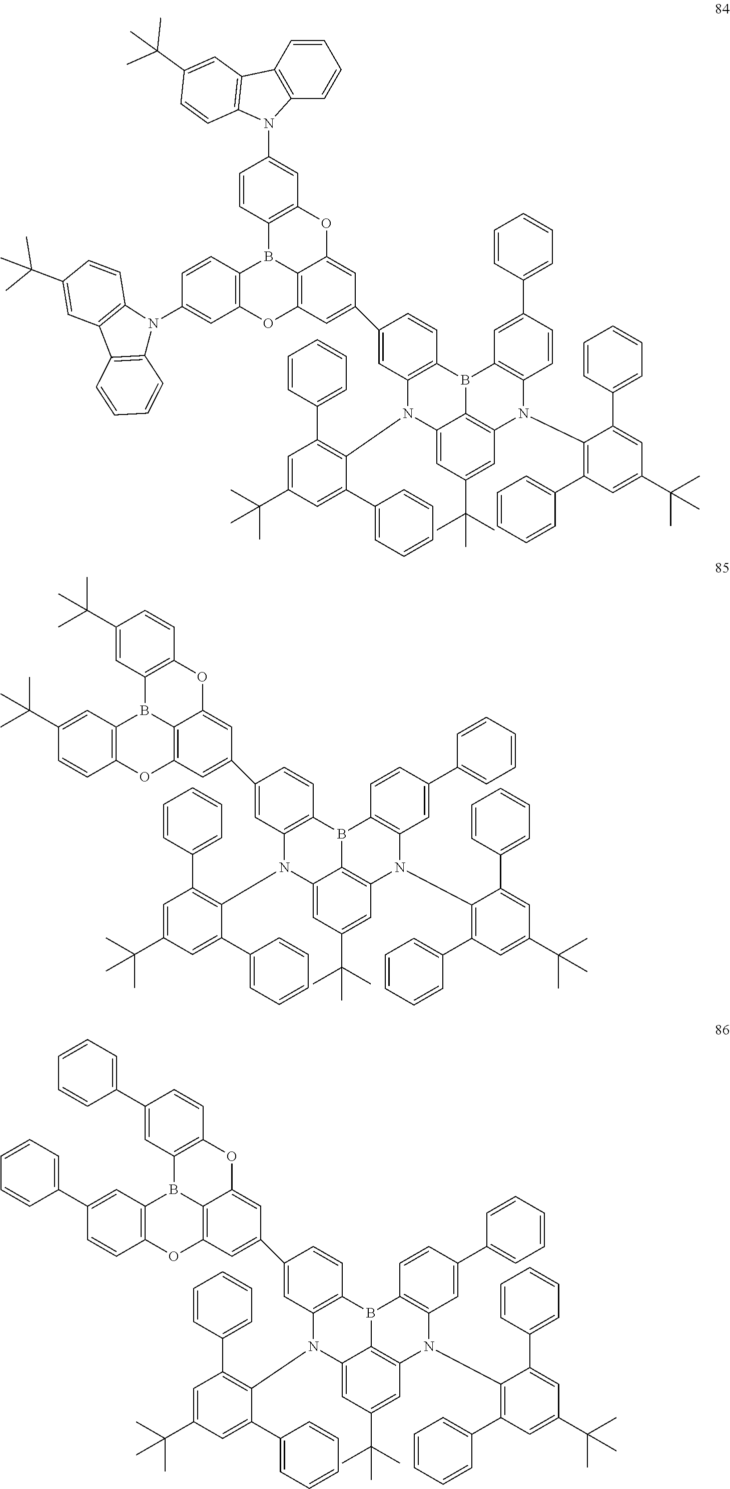 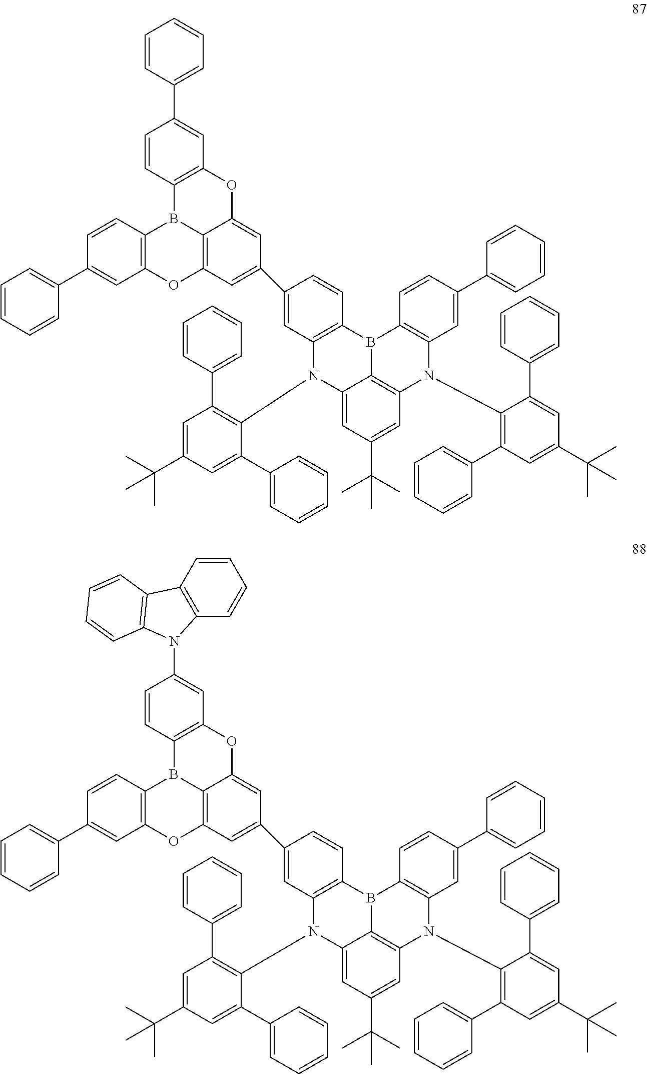 [SMILES: CC(C)(C)c1cc(-c2ccccc2)c(N2c3cc(-c4ccccc4)ccc3B3c4ccc(-c5cc6c7c(c5)Oc5cc(-c8ccccc8)ccc5B7c5ccc(-c7ccccc7)cc5O6)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4ccccc4)ccc3B3c4ccc(-c5cc6c7c(c5)Oc5cc(-n8c9ccccc9c9ccccc98)ccc5B7c5ccc(-c7ccccc7)cc5O6)cc4N(c4c(-c5ccccc5)cc(C(C)(C)C)cc4-c4ccccc4)c4cc(C(C)(C)C)cc2c43)c(-c2ccccc2)c1] 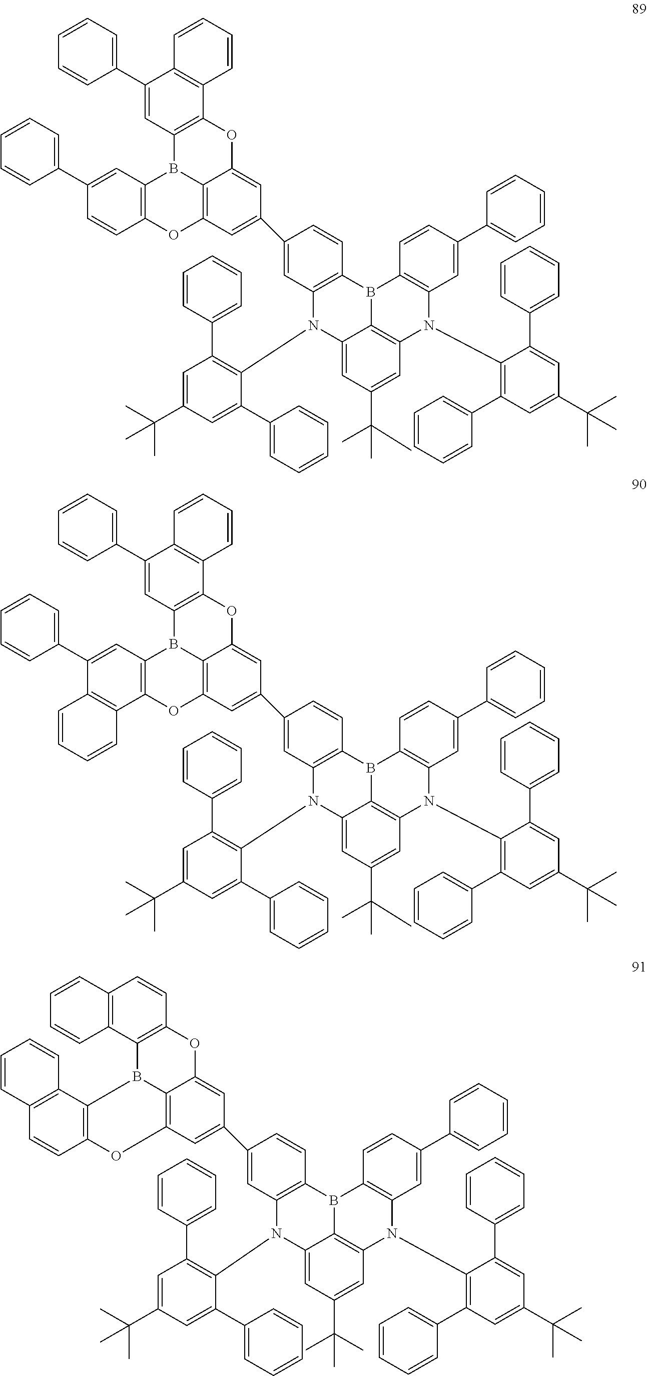 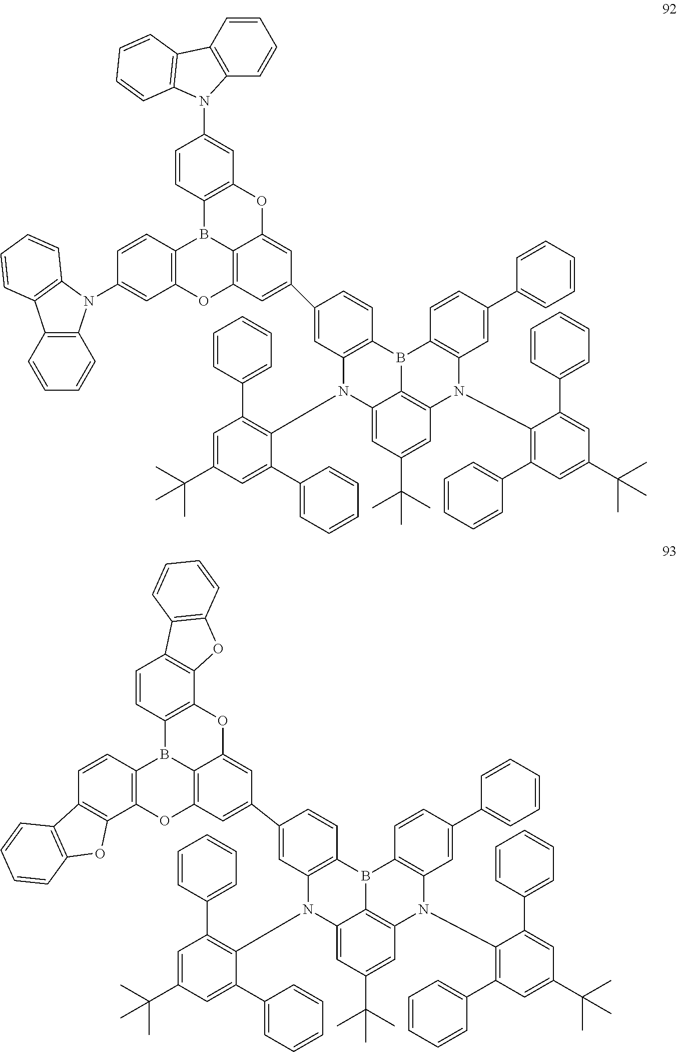 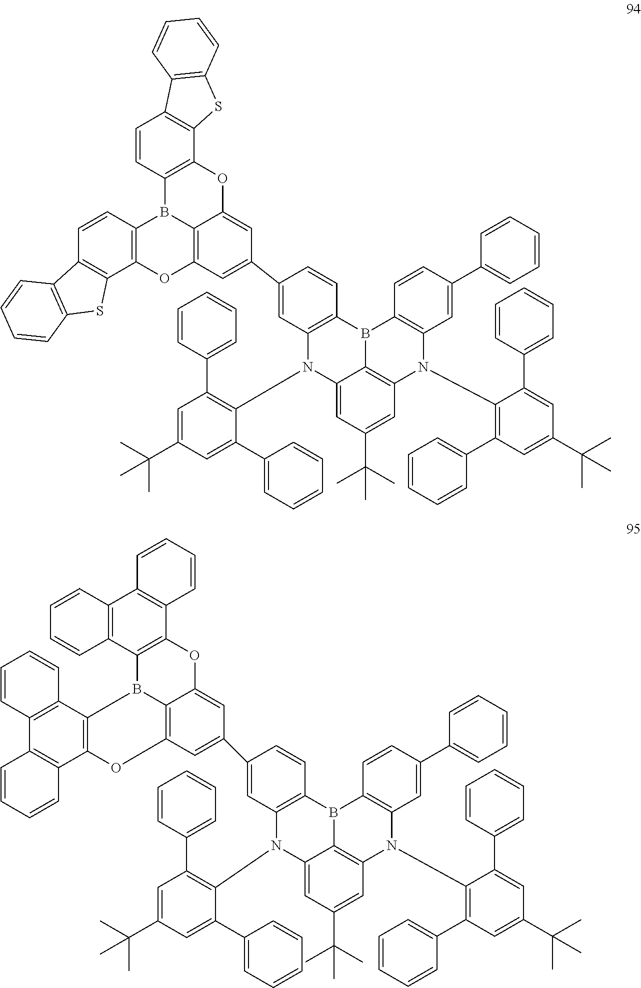 [SMILES: CC(C)(C)c1cc(-c2ccccc2)c(N2c3cc(-c4ccccc4)ccc3B3c4ccc(-c5cc6c7c(c5)Oc5c(ccc8c5sc5ccccc58)B7c5ccc7c(sc8ccccc87)c5O6)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4ccccc4)ccc3B3c4ccc(-c5cc6c7c(c5)Oc5c(c8ccccc8c8ccccc58)B7c5c(c7ccccc7c7ccccc57)O6)cc4N(c4c(-c5ccccc5)cc(C(C)(C)C)cc4-c4ccccc4)c4cc(C(C)(C)C)cc2c43)c(-c2ccccc2)c1] 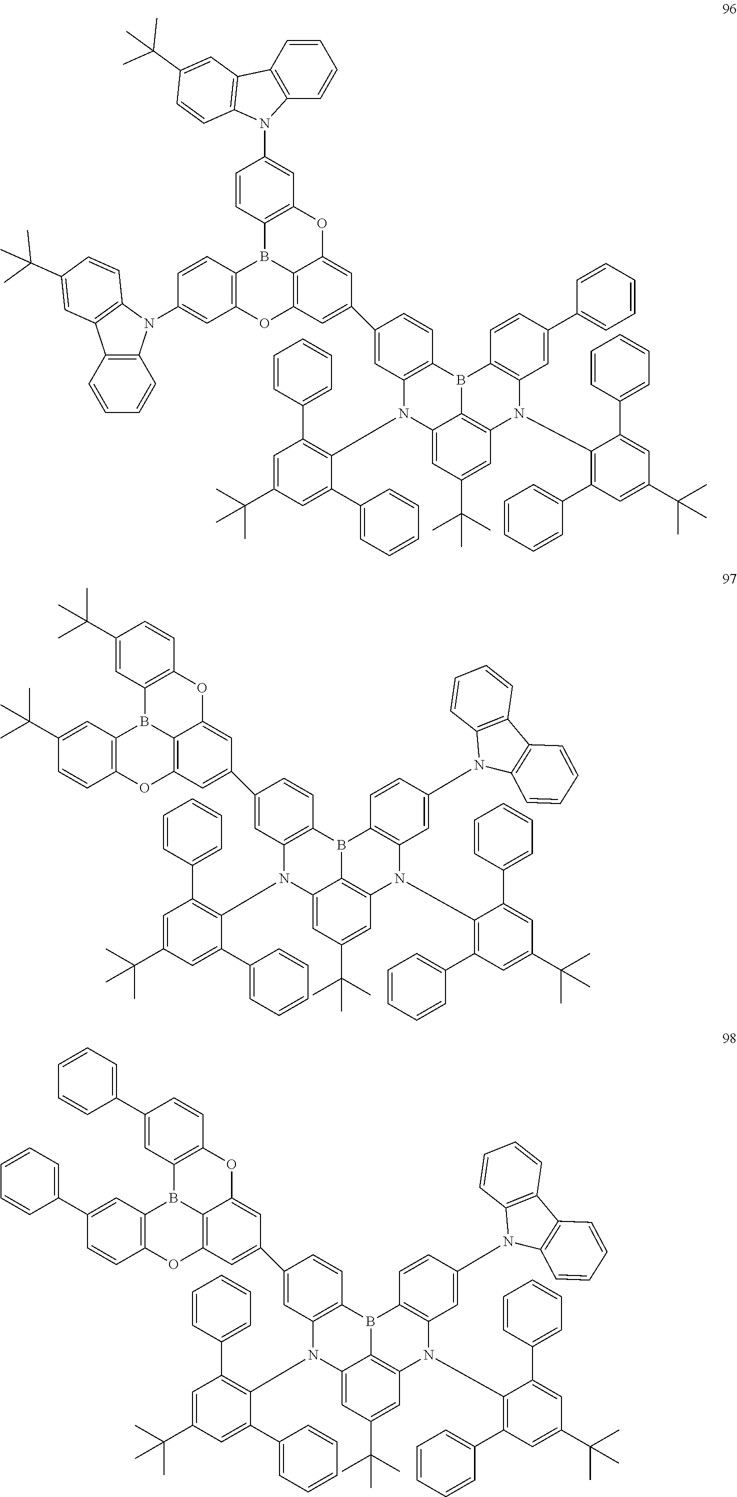 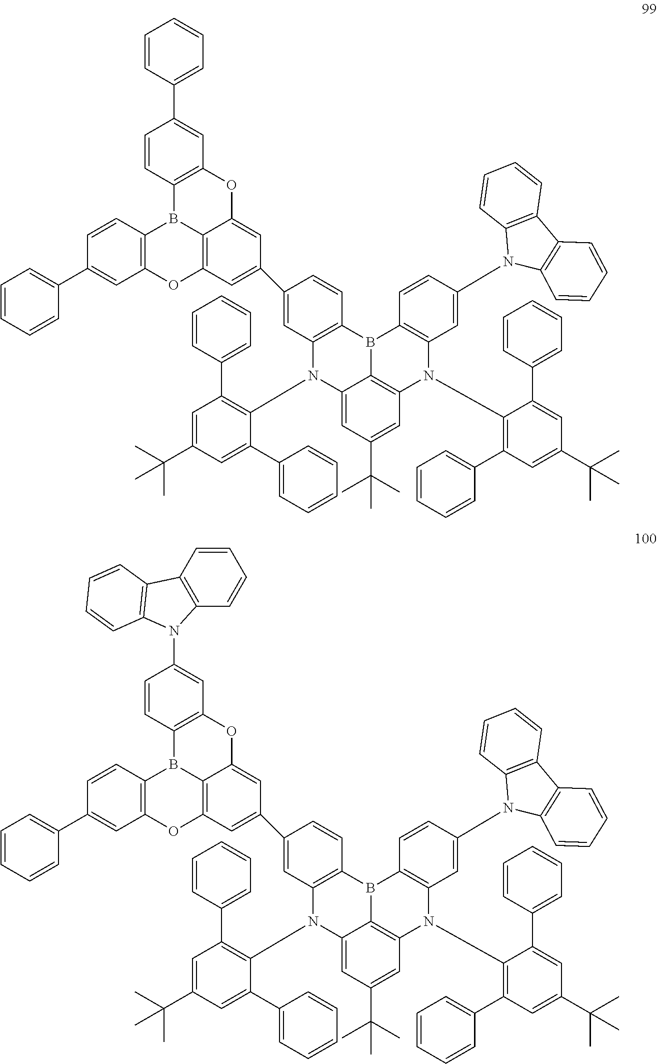 [SMILES: CC(C)(C)c1cc(-c2ccccc2)c(N2c3cc(-c4cc5c6c(c4)Oc4cc(-c7ccccc7)ccc4B6c4ccc(-c6ccccc6)cc4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8ccccc87)ccc4B6c4ccc(-c6ccccc6)cc4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1] 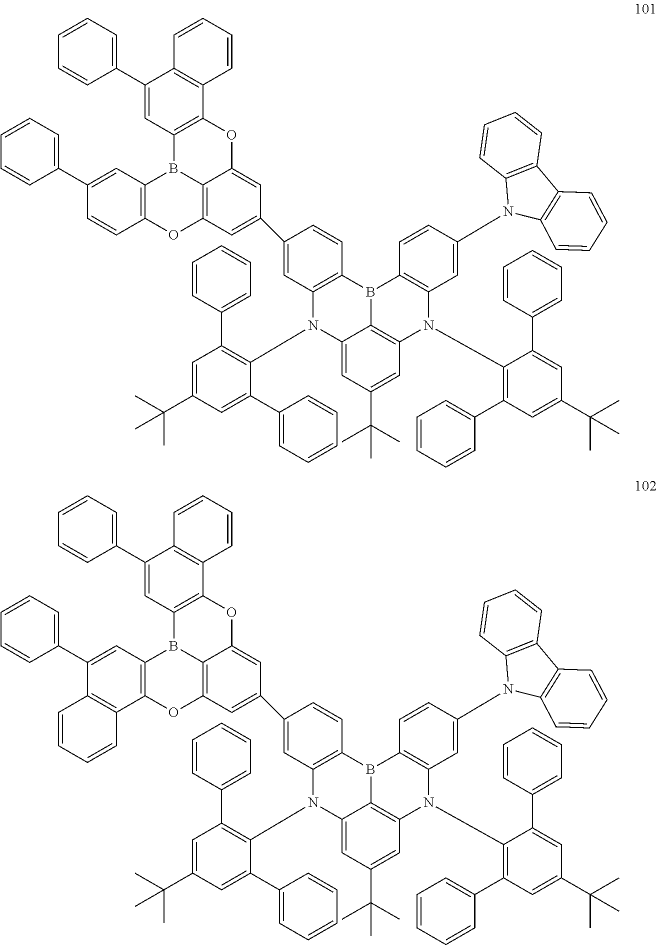 [SMILES: CC(C)(C)c1cc(-c2ccccc2)c(N2c3cc(-c4cc5c6c(c4)Oc4c(cc(-c7ccccc7)c7ccccc47)B6c4cc(-c6ccccc6)ccc4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4cc5c6c(c4)Oc4c(cc(-c7ccccc7)c7ccccc47)B6c4cc(-c6ccccc6)c6ccccc6c4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1] 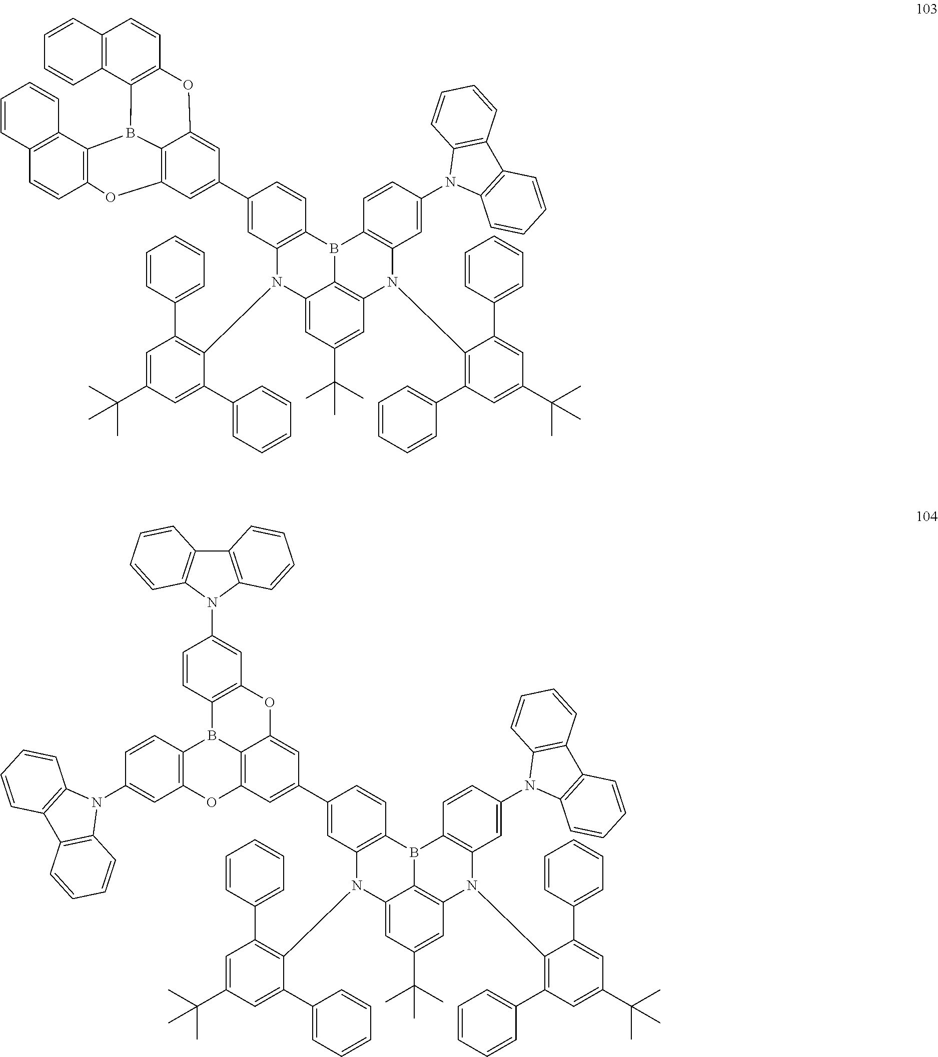 [SMILES: CC(C)(C)c1cc(-c2ccccc2)c(N2c3cc(-c4cc5c6c(c4)Oc4ccc7ccccc7c4B6c4c(ccc6ccccc46)O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8ccccc87)ccc4B6c4ccc(-n6c7ccccc7c7ccccc76)cc4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1] 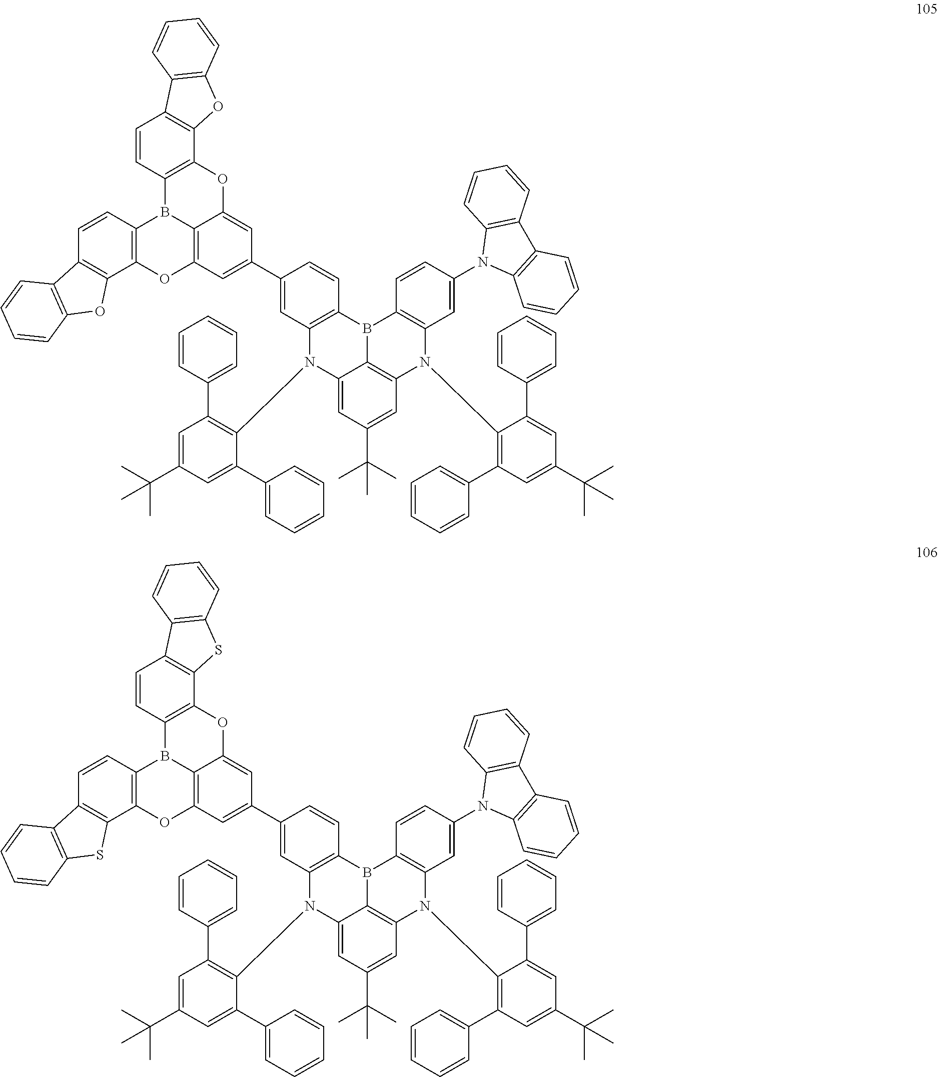 [SMILES: CC(C)(C)c1cc(-c2ccccc2)c(N2c3cc(-c4cc5c6c(c4)Oc4c(ccc7c4oc4ccccc47)B6c4ccc6c(oc7ccccc76)c4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4cc5c6c(c4)Oc4c(ccc7c4sc4ccccc47)B6c4ccc6c(sc7ccccc76)c4O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1] 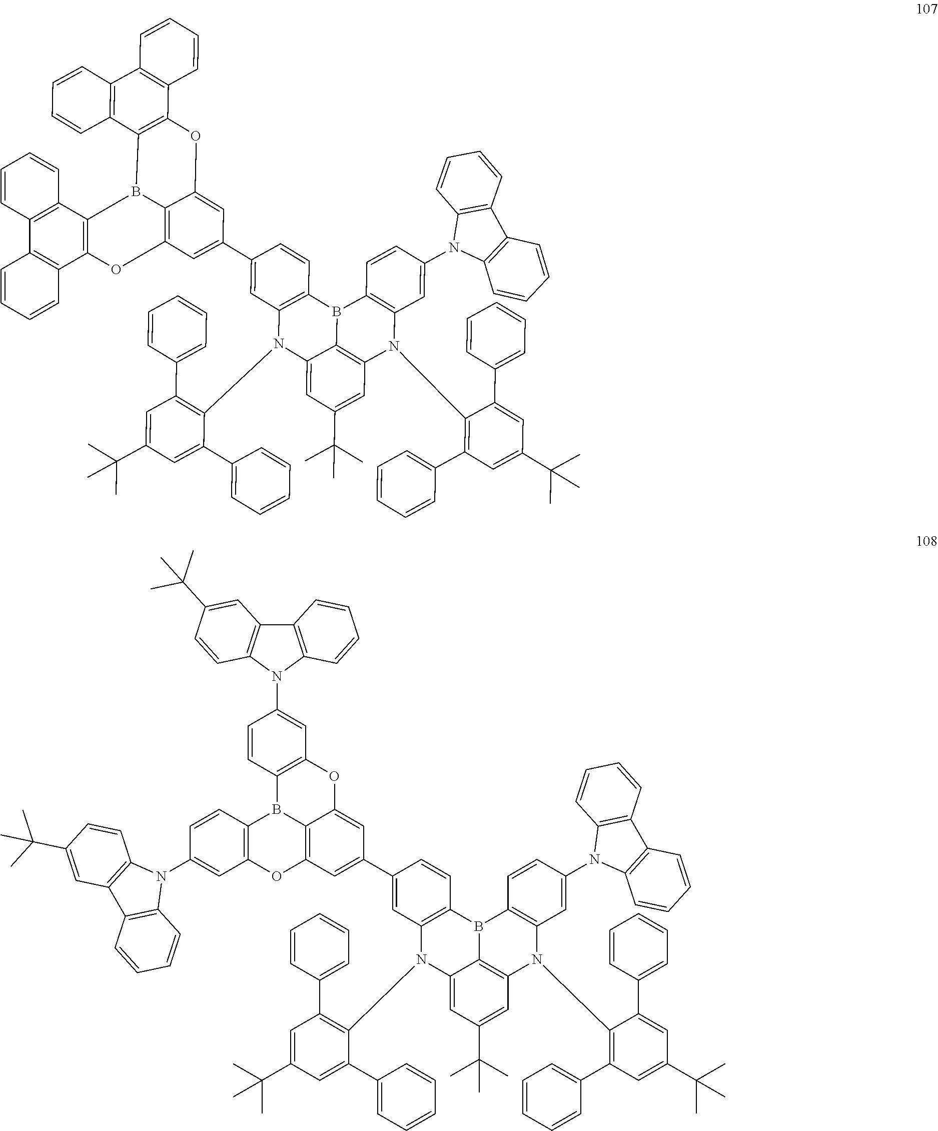 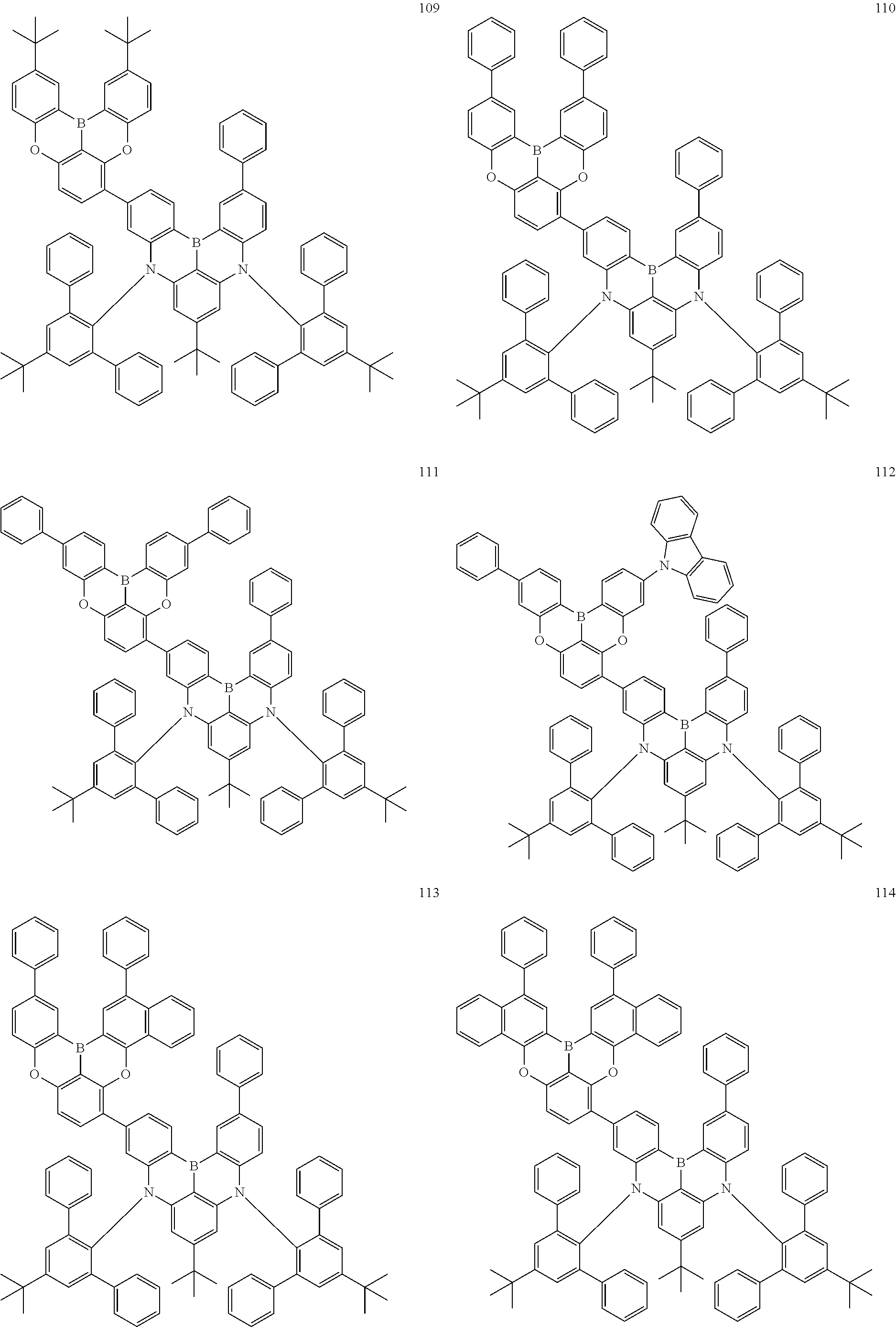 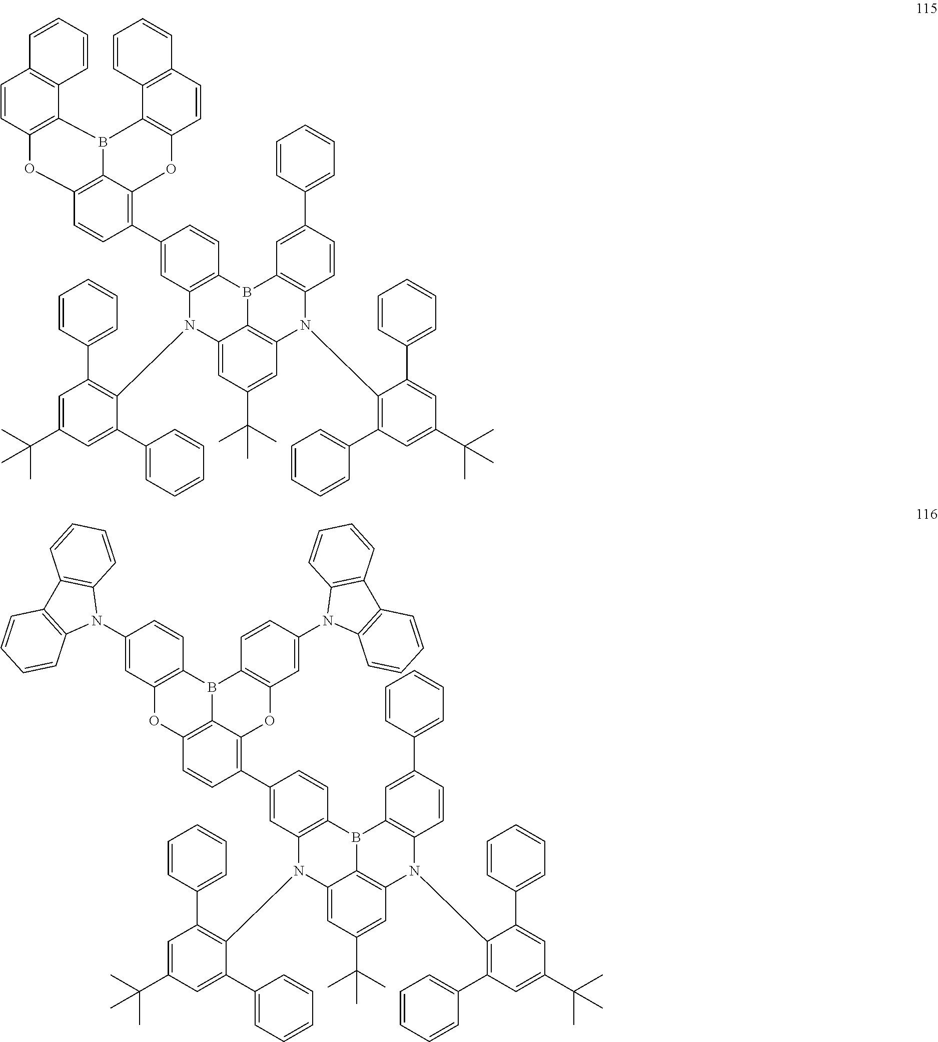 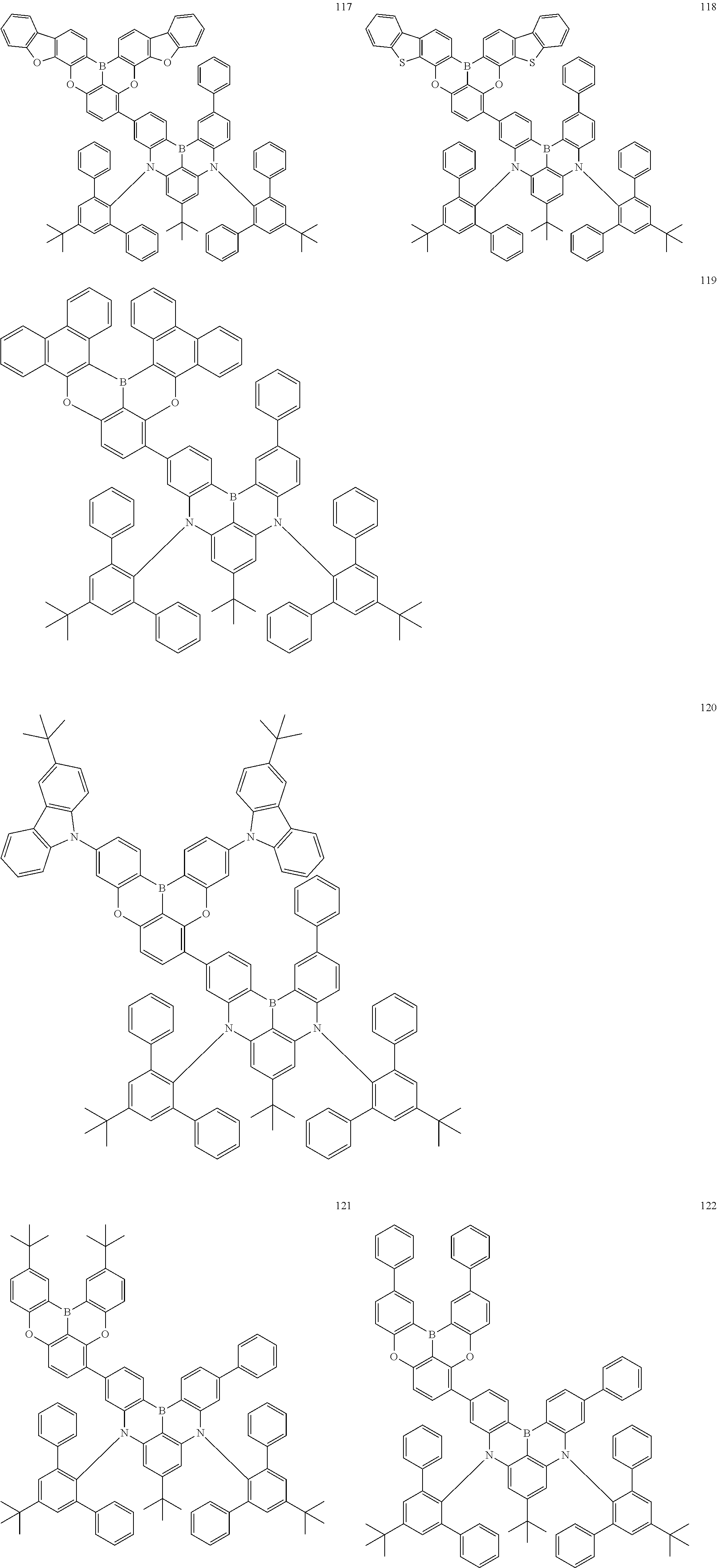 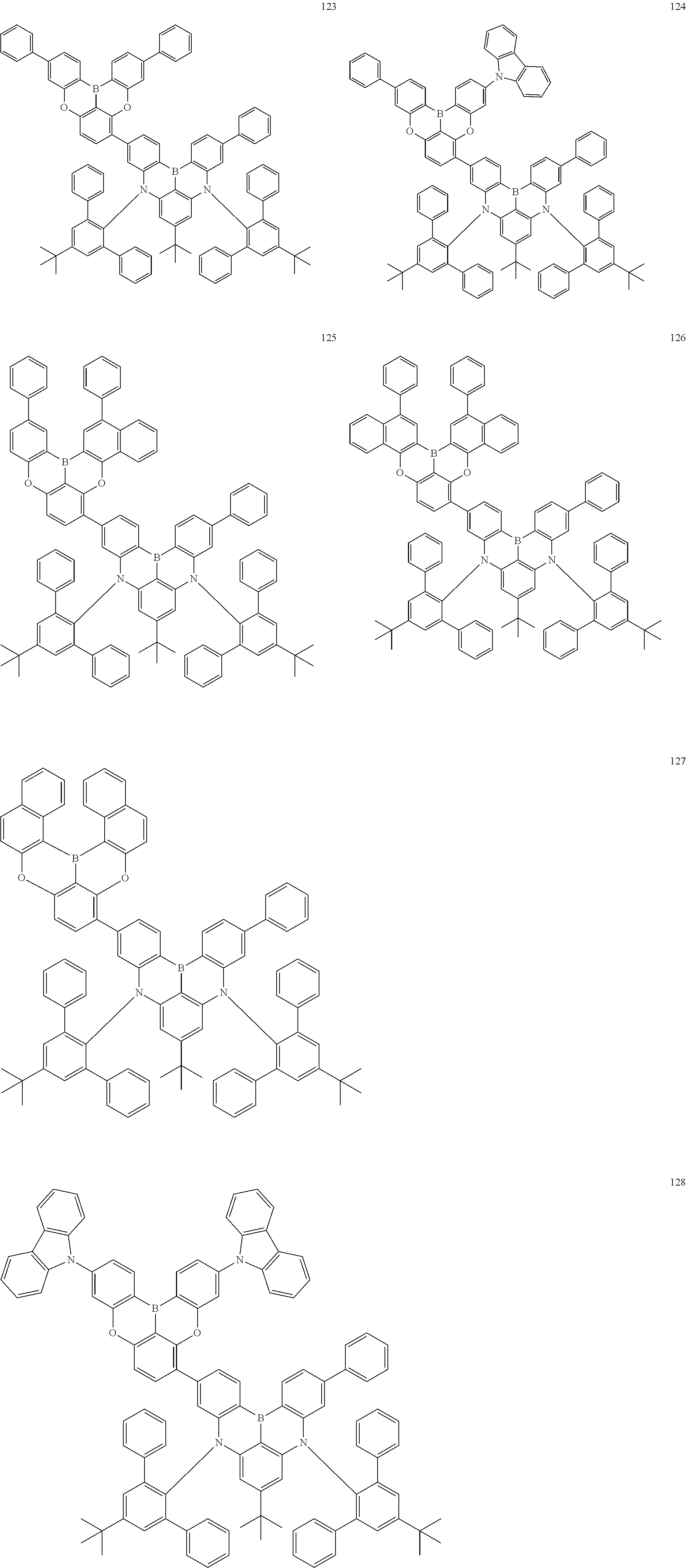 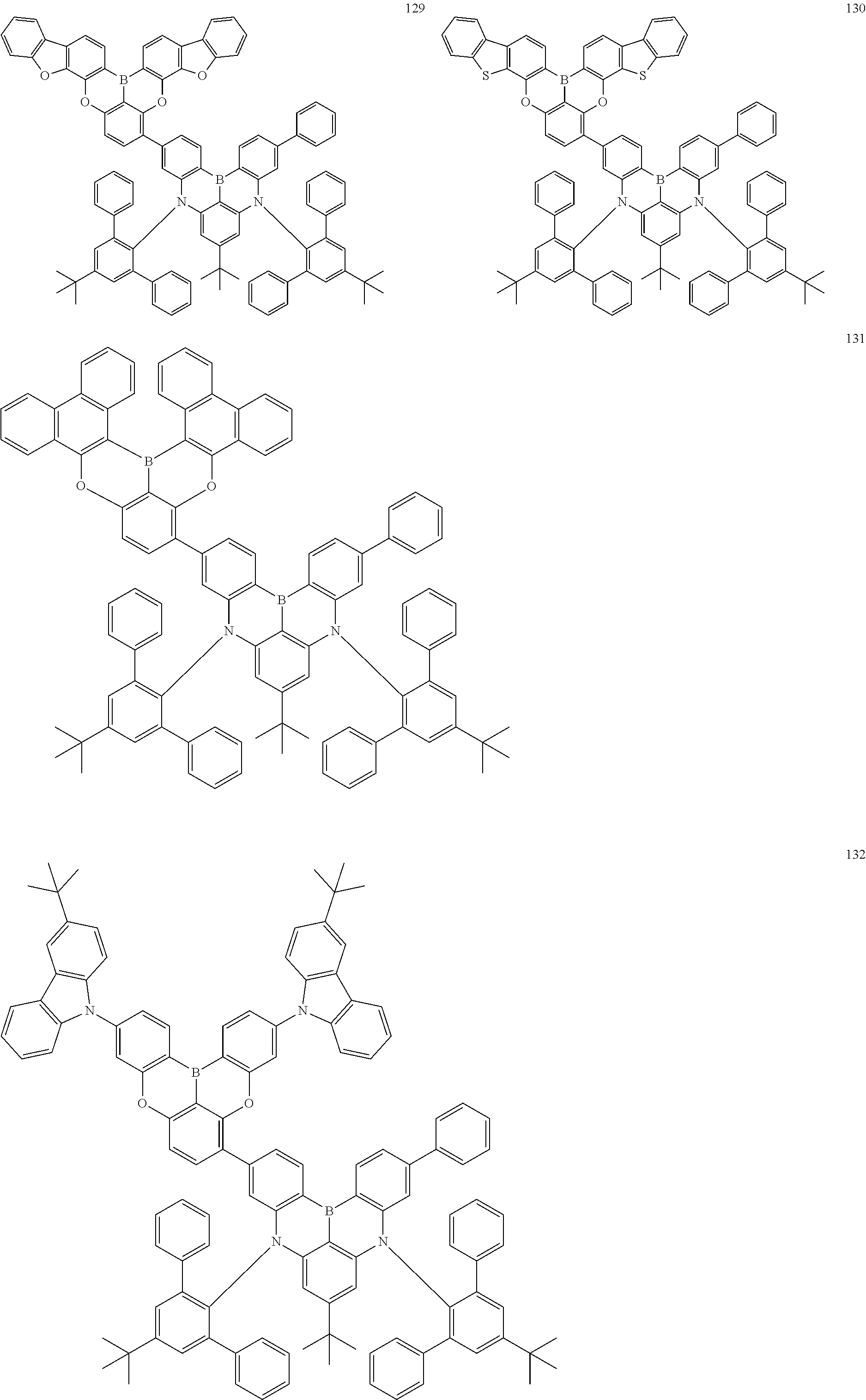 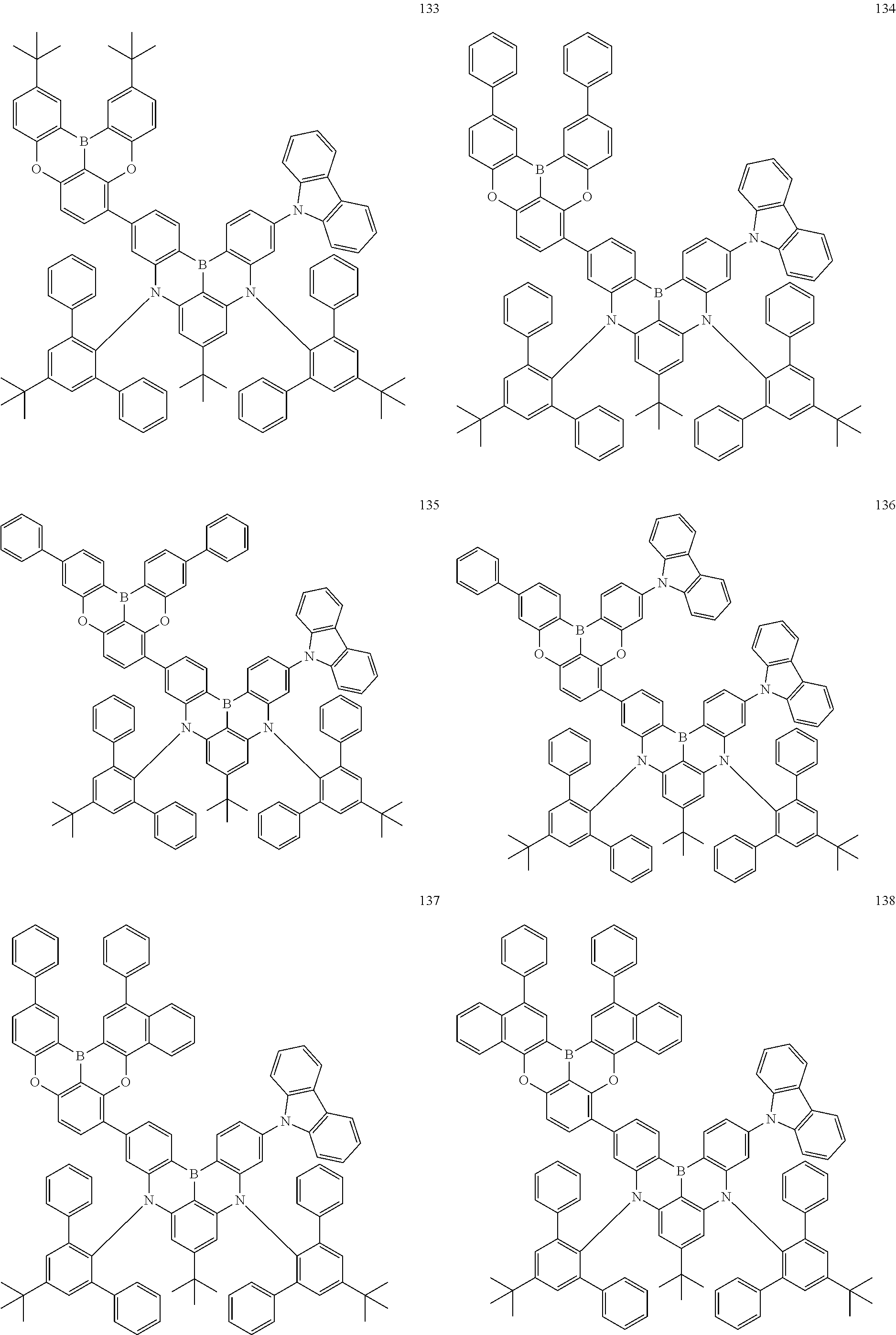 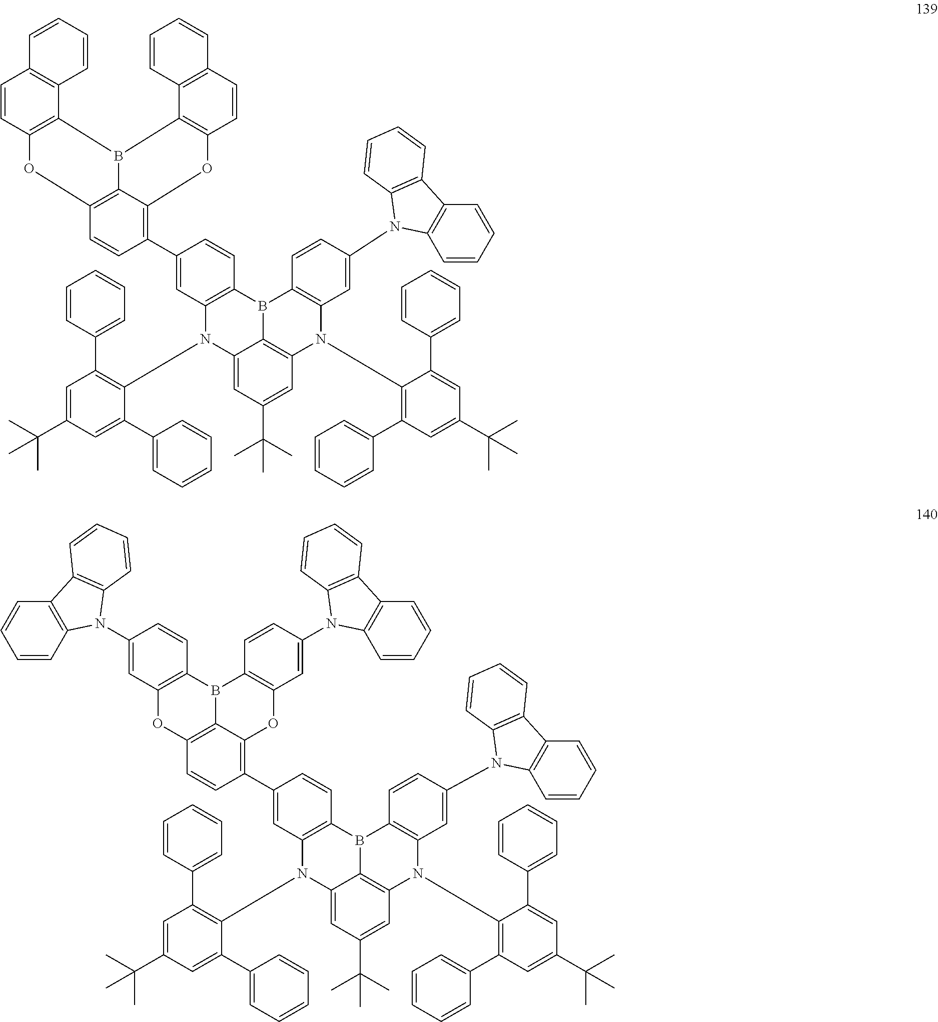 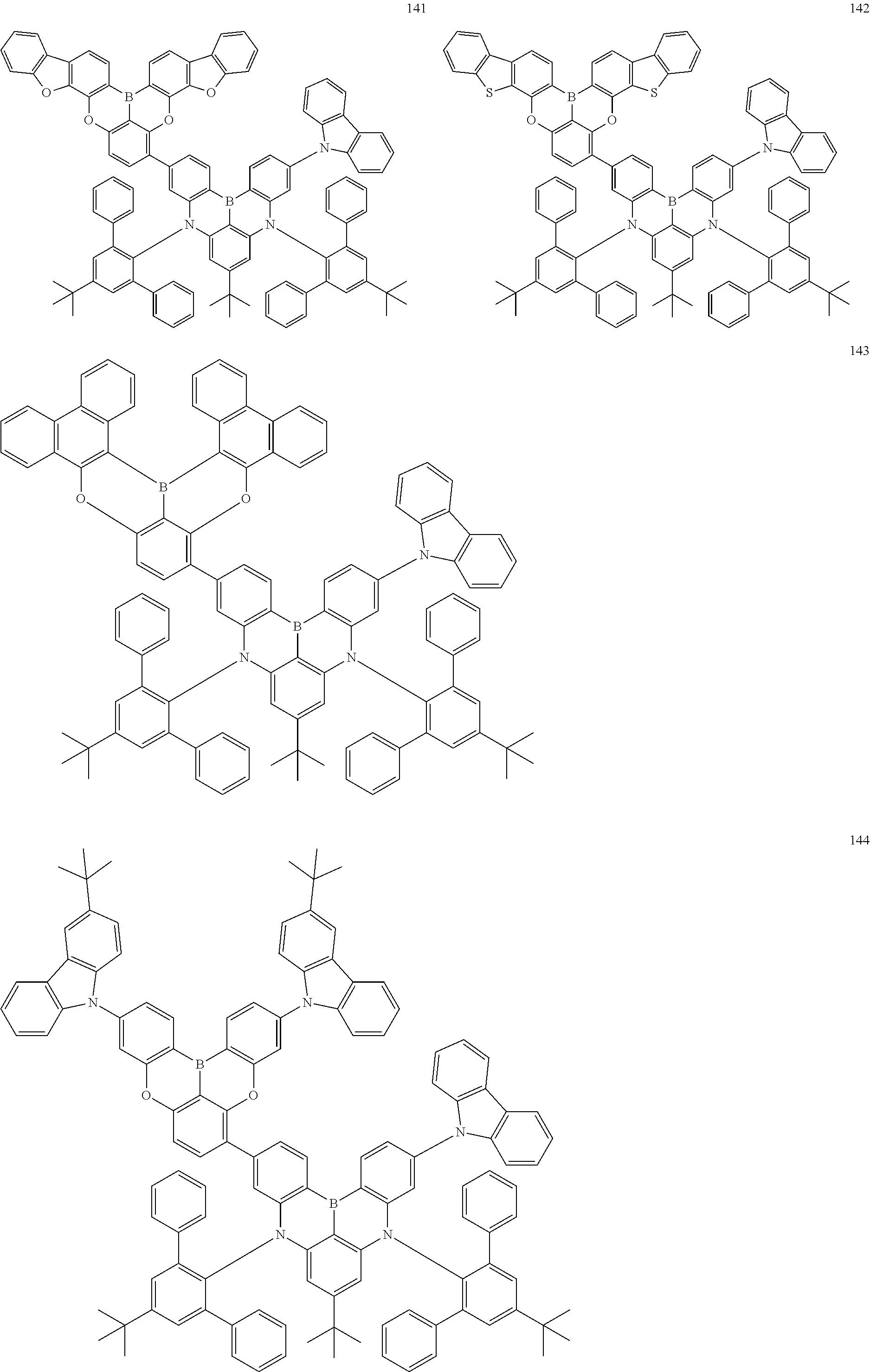 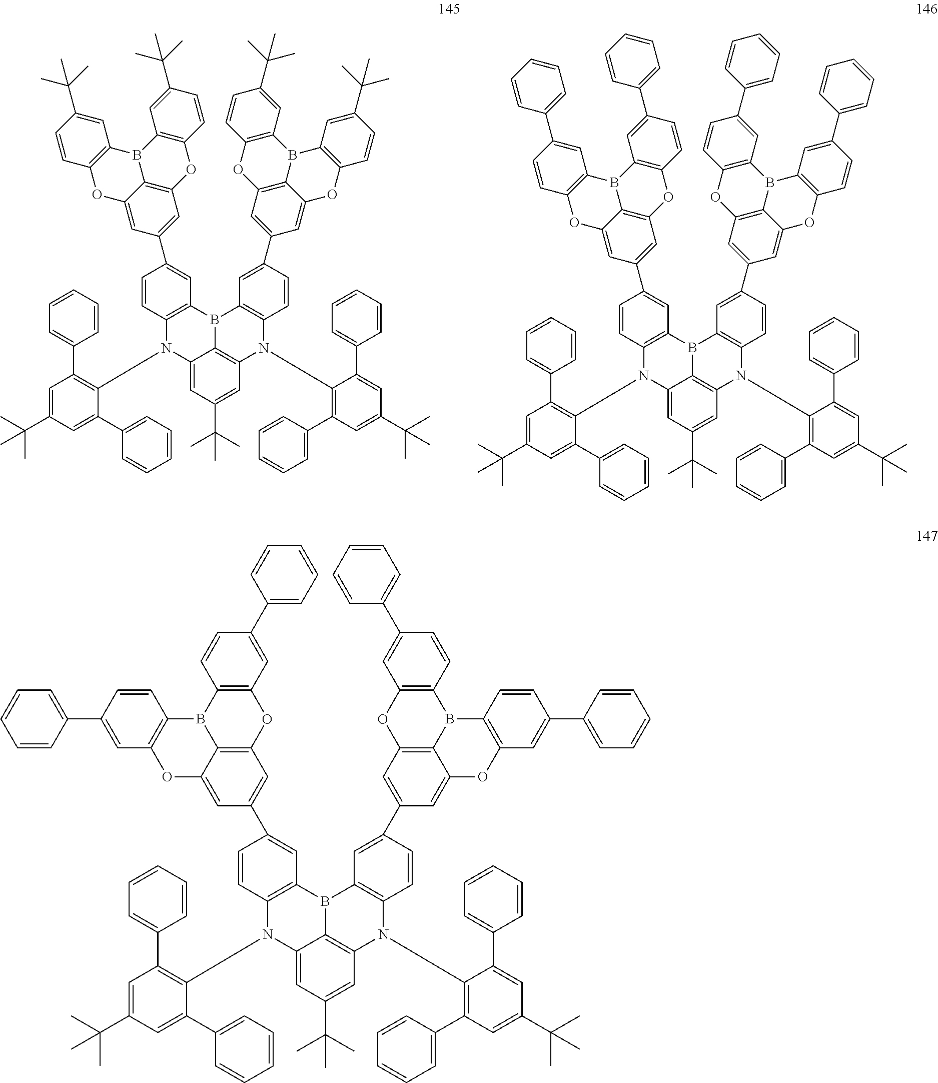 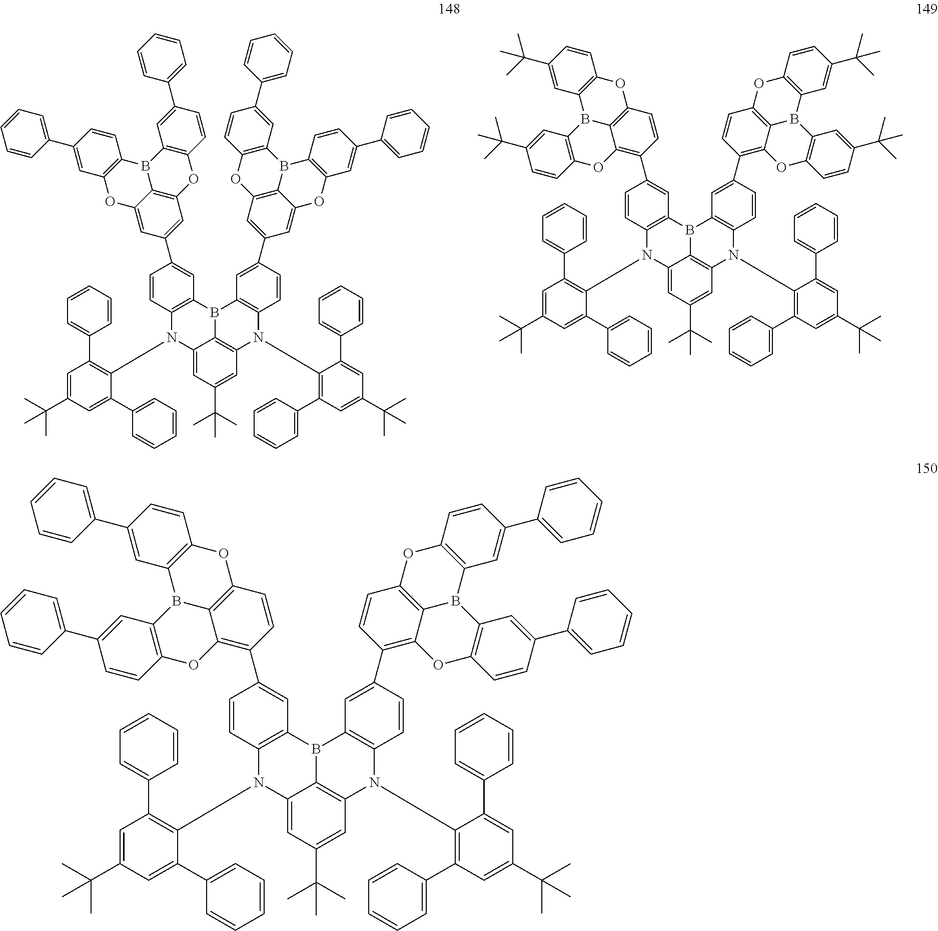 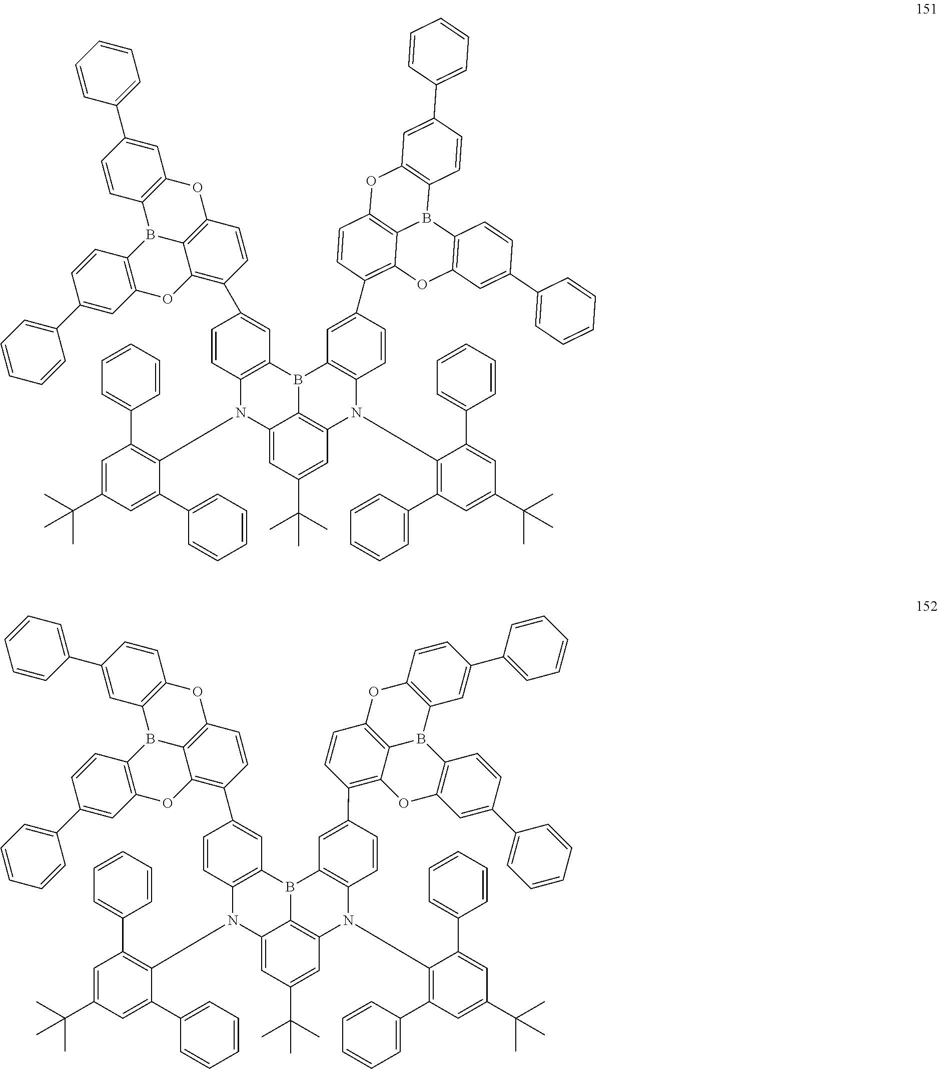 [SMILES: CC(C)(C)c1cc(-c2ccccc2)c(N2c3ccc(-c4ccc5c6c4Oc4cc(-c7ccccc7)ccc4B6c4ccc(-c6ccccc6)cc4O5)cc3B3c4cc(-c5ccc6c7c5Oc5cc(-c8ccccc8)ccc5B7c5ccc(-c7ccccc7)cc5O6)ccc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4ccc5c6c4Oc4cc(-c7ccccc7)ccc4B6c4cc(-c6ccccc6)ccc4O5)cc3B3c4cc(-c5ccc6c7c5Oc5cc(-c8ccccc8)ccc5B7c5cc(-c7ccccc7)ccc5O6)ccc4N(c4c(-c5ccccc5)cc(C(C)(C)C)cc4-c4ccccc4)c4cc(C(C)(C)C)cc2c43)c(-c2ccccc2)c1] 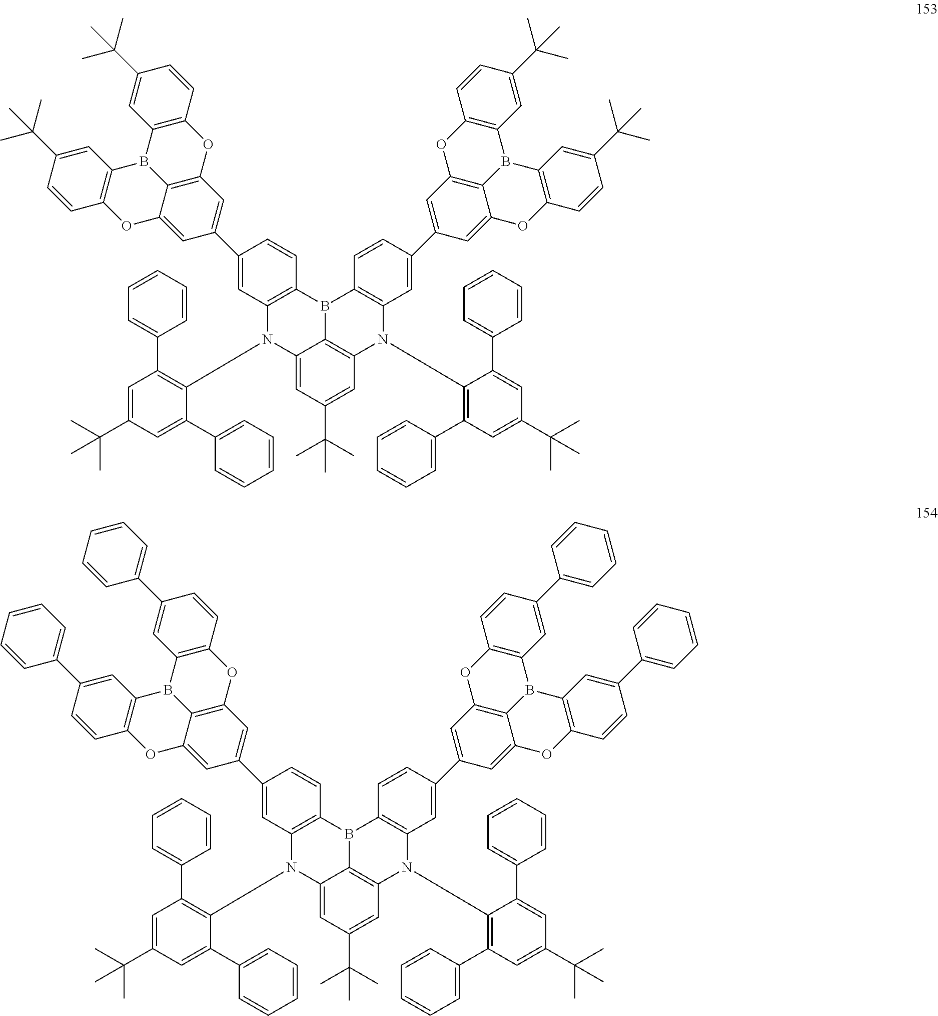 [SMILES: CC(C)(C)c1ccc2c(c1)B1c3cc(C(C)(C)C)ccc3Oc3cc(-c4ccc5c(c4)N(c4c(-c6ccccc6)cc(C(C)(C)C)cc4-c4ccccc4)c4cc(C(C)(C)C)cc6c4B5c4ccc(-c5cc7c8c(c5)Oc5ccc(C(C)(C)C)cc5B8c5cc(C(C)(C)C)ccc5O7)cc4N6c4c(-c5ccccc5)cc(C(C)(C)C)cc4-c4ccccc4)cc(c31)O2 ; CC(C)(C)c1cc(-c2ccccc2)c(N2c3cc(-c4cc5c6c(c4)Oc4ccc(-c7ccccc7)cc4B6c4cc(-c6ccccc6)ccc4O5)ccc3B3c4ccc(-c5cc6c7c(c5)Oc5ccc(-c8ccccc8)cc5B7c5cc(-c7ccccc7)ccc5O6)cc4N(c4c(-c5ccccc5)cc(C(C)(C)C)cc4-c4ccccc4)c4cc(C(C)(C)C)cc2c43)c(-c2ccccc2)c1] 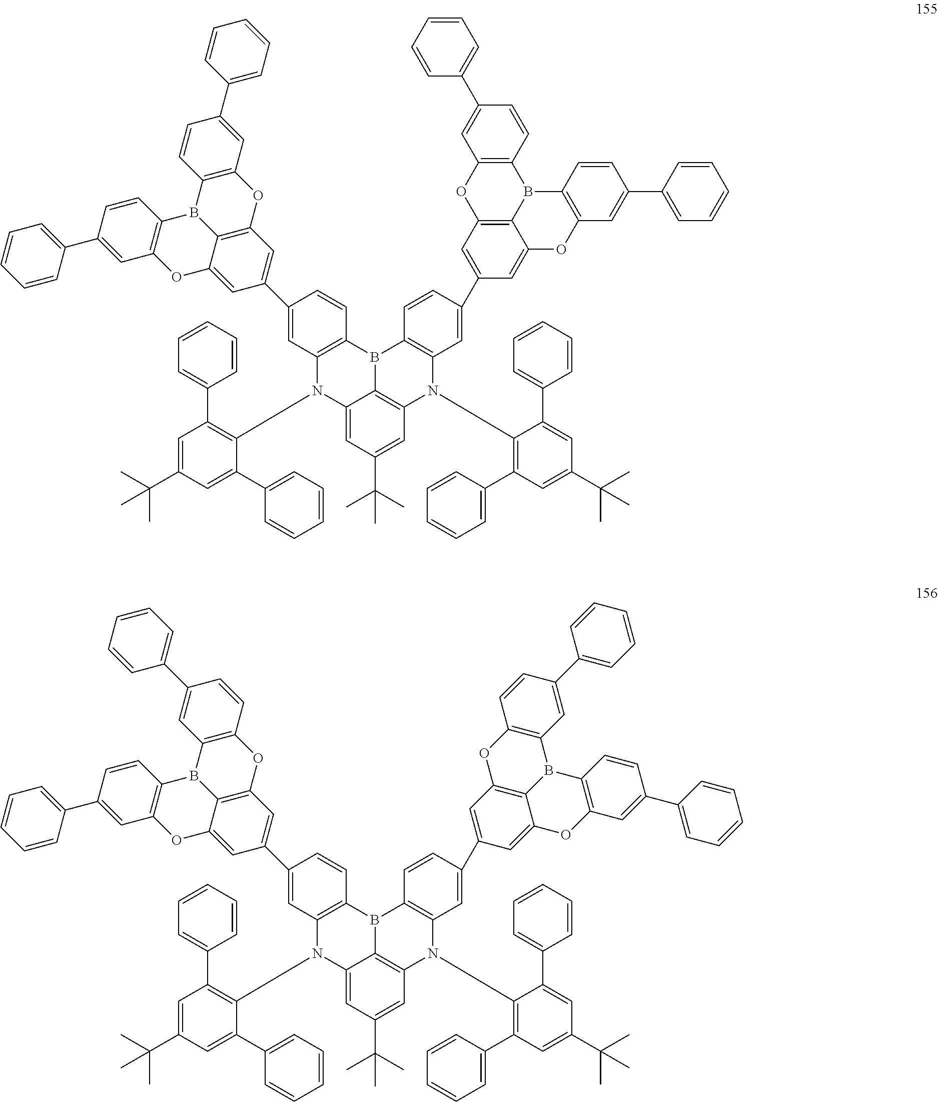 [SMILES: CC(C)(C)c1cc(-c2ccccc2)c(N2c3cc(-c4cc5c6c(c4)Oc4cc(-c7ccccc7)ccc4B6c4ccc(-c6ccccc6)cc4O5)ccc3B3c4ccc(-c5cc6c7c(c5)Oc5cc(-c8ccccc8)ccc5B7c5ccc(-c7ccccc7)cc5O6)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3cc(-c4cc5c6c(c4)Oc4ccc(-c7ccccc7)cc4B6c4ccc(-c6ccccc6)cc4O5)ccc3B3c4ccc(-c5cc6c7c(c5)Oc5ccc(-c8ccccc8)cc5B7c5ccc(-c7ccccc7)cc5O6)cc4N(c4c(-c5ccccc5)cc(C(C)(C)C)cc4-c4ccccc4)c4cc(C(C)(C)C)cc2c43)c(-c2ccccc2)c1] 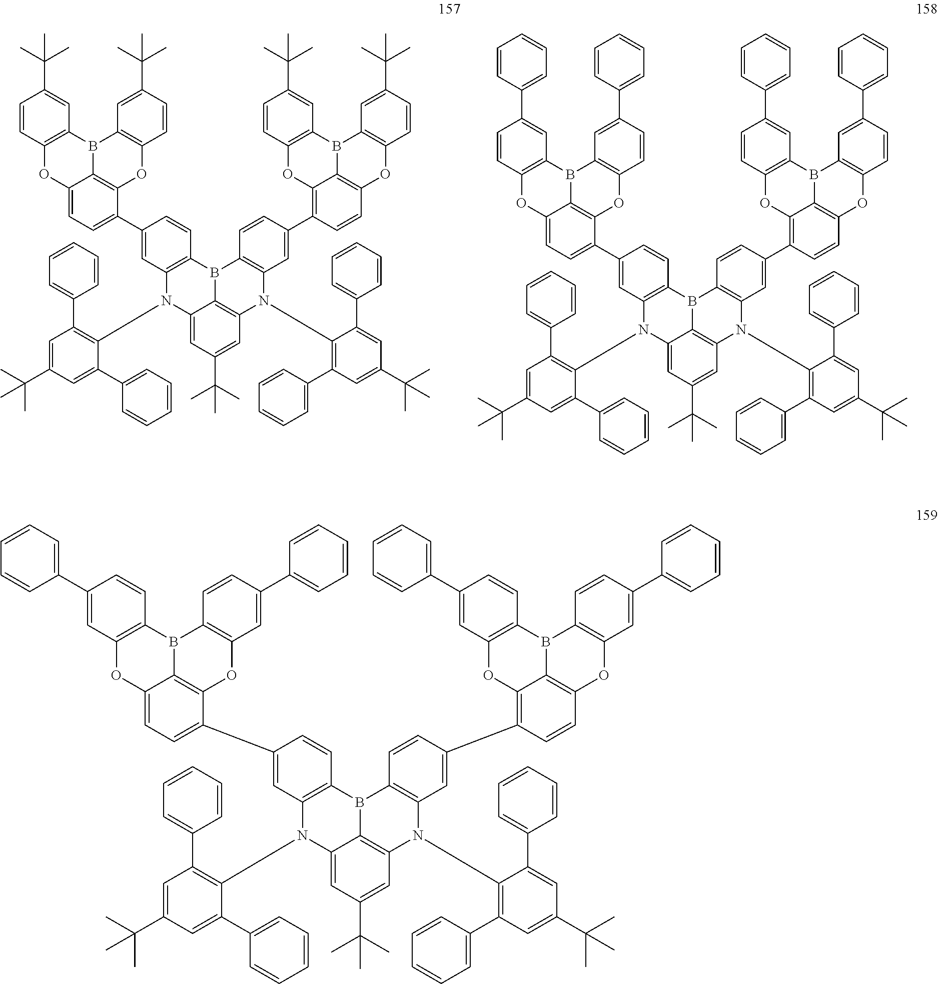 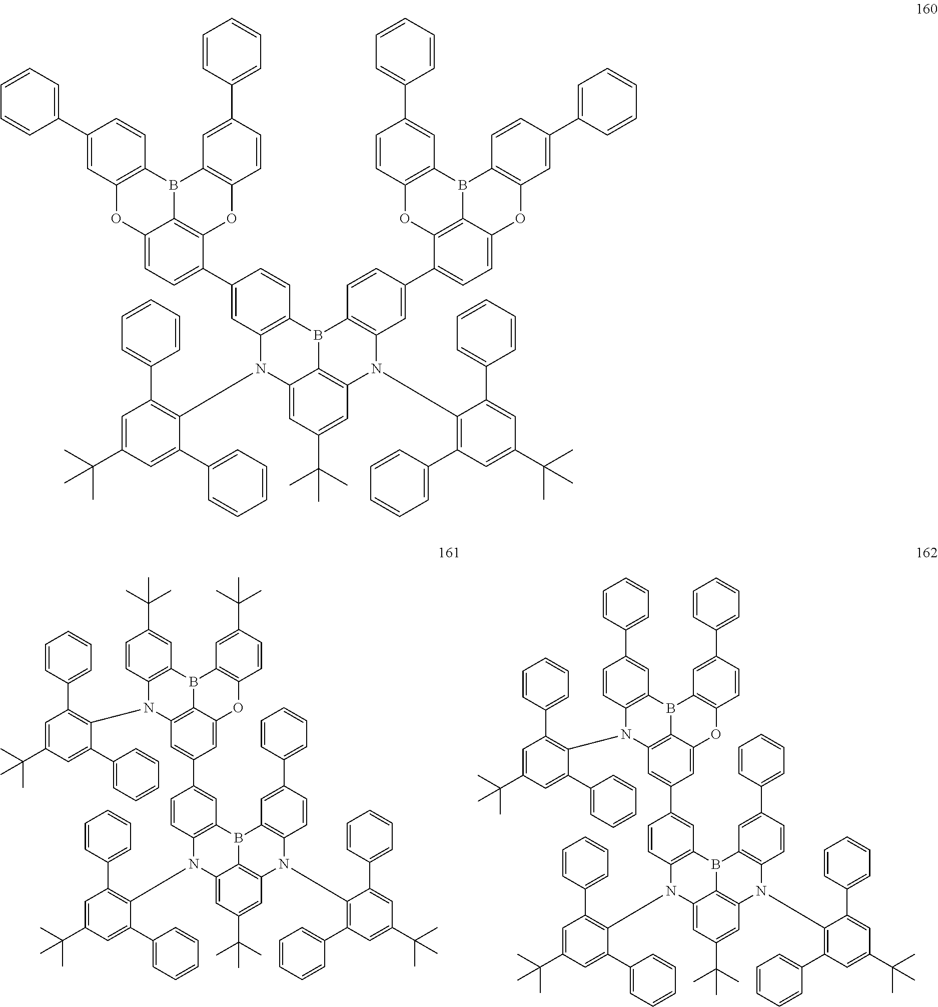 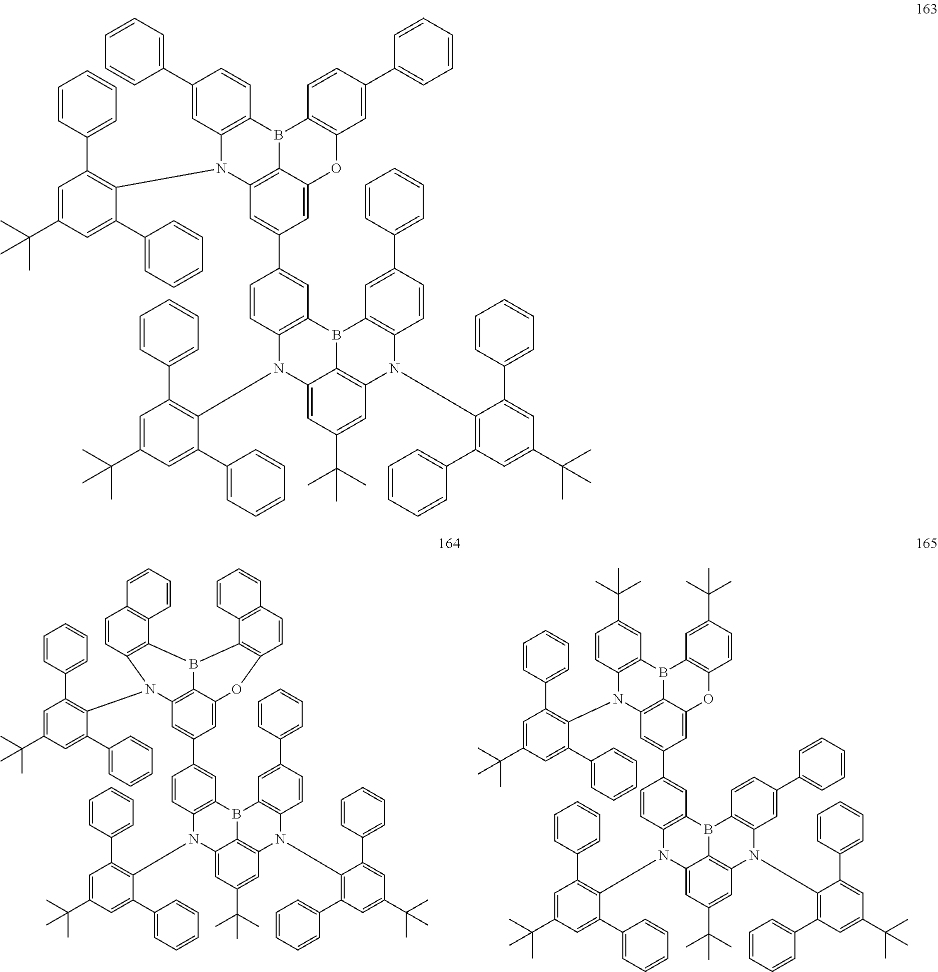 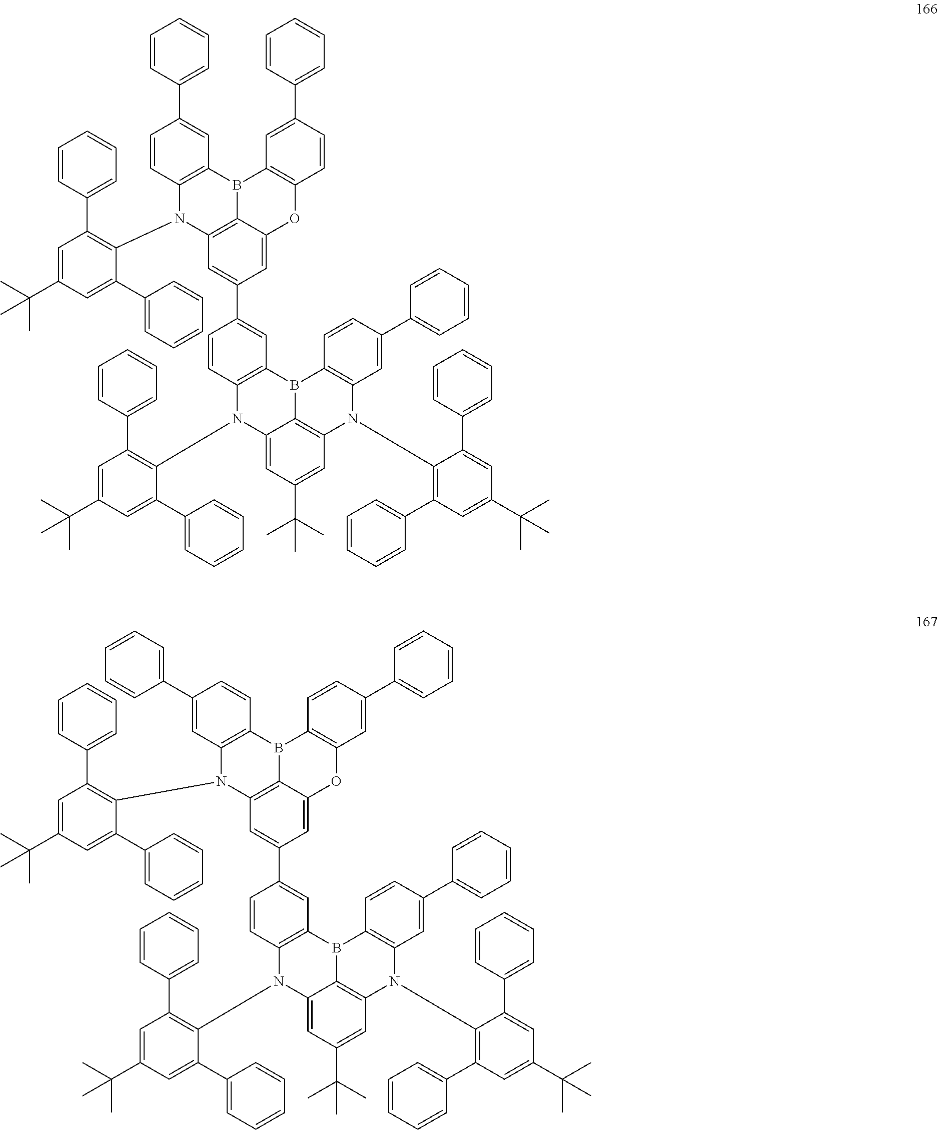 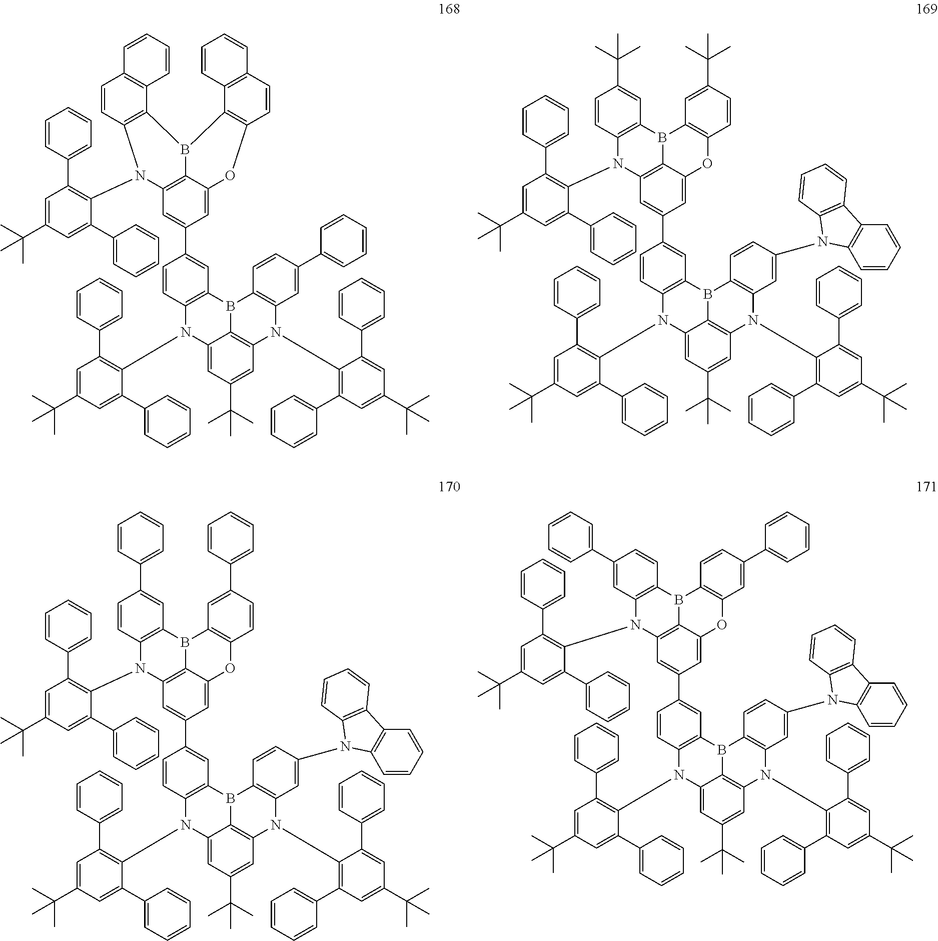 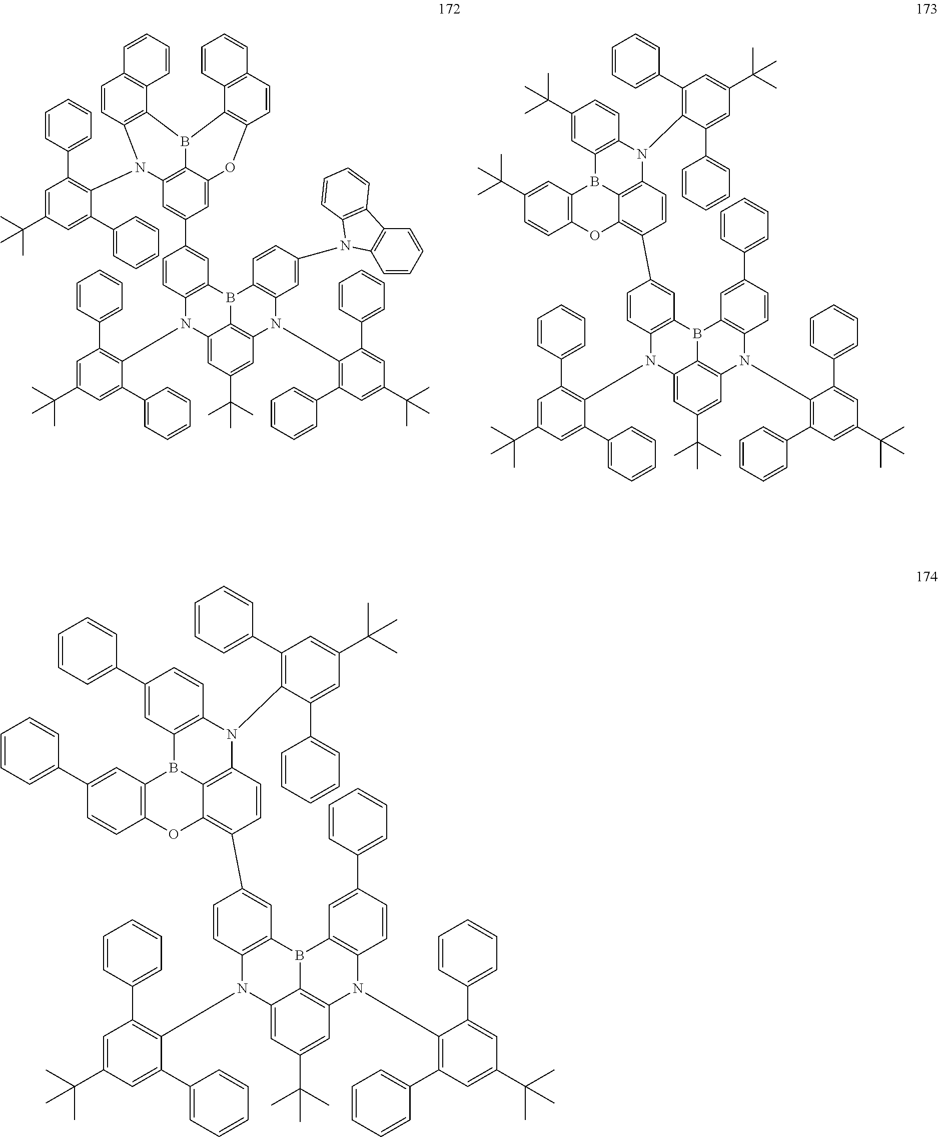 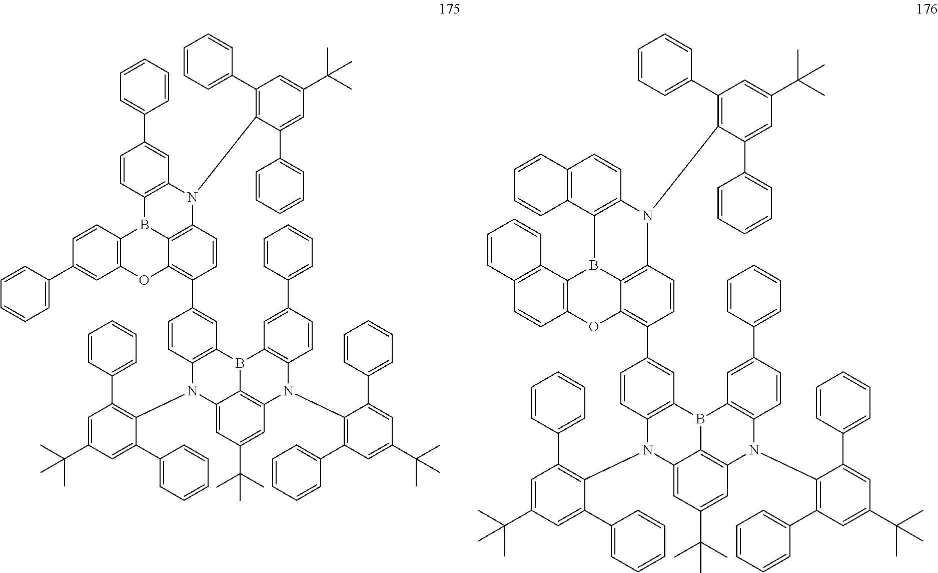 [SMILES: CC(C)(C)c1cc(-c2ccccc2)c(N2c3ccc(-c4ccccc4)cc3B3c4cc(-c5ccc6c7c5Oc5cc(-c8ccccc8)ccc5B7c5ccc(-c7ccccc7)cc5N6c5c(-c6ccccc6)cc(C(C)(C)C)cc5-c5ccccc5)ccc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4ccccc4)cc3B3c4cc(-c5ccc6c7c5Oc5ccc8ccccc8c5B7c5c(ccc7ccccc57)N6c5c(-c6ccccc6)cc(C(C)(C)C)cc5-c5ccccc5)ccc4N(c4c(-c5ccccc5)cc(C(C)(C)C)cc4-c4ccccc4)c4cc(C(C)(C)C)cc2c43)c(-c2ccccc2)c1] 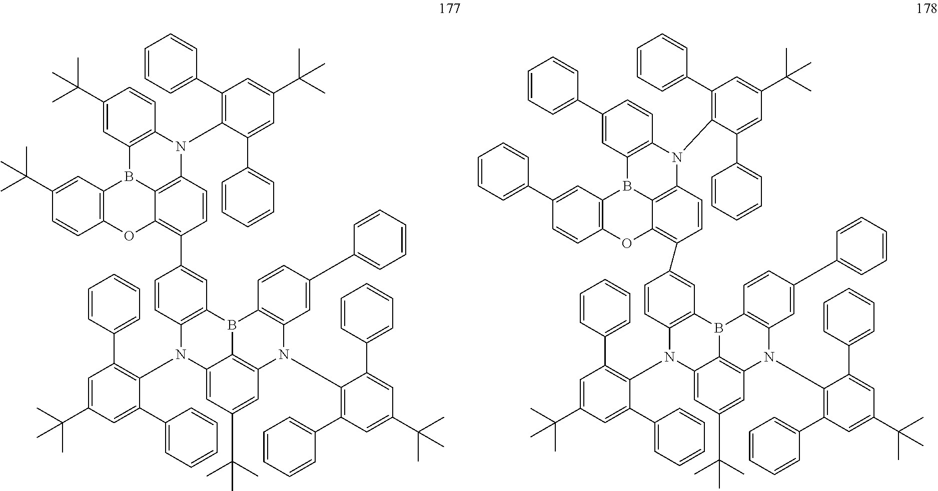 [SMILES: CC(C)(C)c1ccc2c(c1)B1c3cc(C(C)(C)C)ccc3N(c3c(-c4ccccc4)cc(C(C)(C)C)cc3-c3ccccc3)c3ccc(-c4ccc5c(c4)B4c6ccc(-c7ccccc7)cc6N(c6c(-c7ccccc7)cc(C(C)(C)C)cc6-c6ccccc6)c6cc(C(C)(C)C)cc(c64)N5c4c(-c5ccccc5)cc(C(C)(C)C)cc4-c4ccccc4)c(c31)O2 ; CC(C)(C)c1cc(-c2ccccc2)c(N2c3ccc(-c4ccc5c6c4Oc4ccc(-c7ccccc7)cc4B6c4cc(-c6ccccc6)ccc4N5c4c(-c5ccccc5)cc(C(C)(C)C)cc4-c4ccccc4)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1] 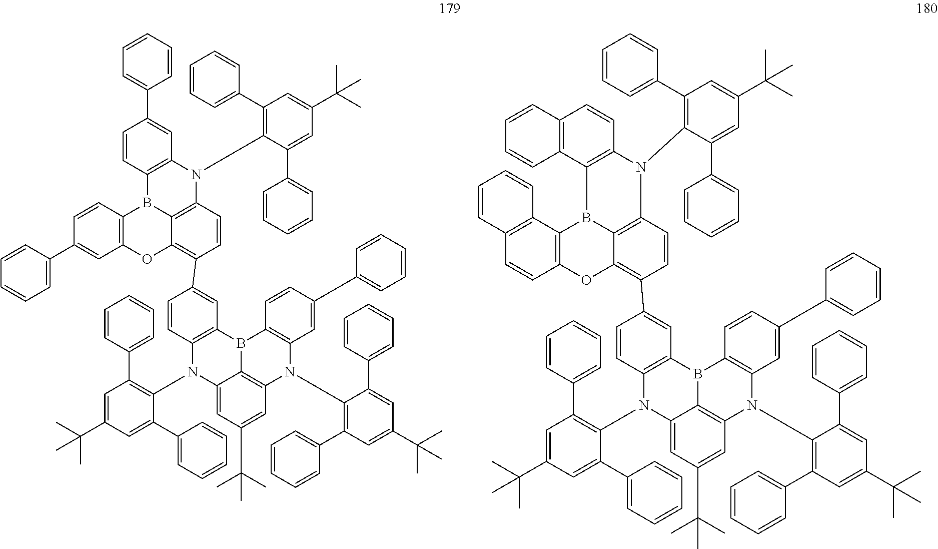 [SMILES: CC(C)(C)c1cc(-c2ccccc2)c(N2c3ccc(-c4ccc5c6c4Oc4cc(-c7ccccc7)ccc4B6c4ccc(-c6ccccc6)cc4N5c4c(-c5ccccc5)cc(C(C)(C)C)cc4-c4ccccc4)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4ccc5c6c4Oc4ccc7ccccc7c4B6c4c(ccc6ccccc46)N5c4c(-c5ccccc5)cc(C(C)(C)C)cc4-c4ccccc4)cc3B3c4ccc(-c5ccccc5)cc4N(c4c(-c5ccccc5)cc(C(C)(C)C)cc4-c4ccccc4)c4cc(C(C)(C)C)cc2c43)c(-c2ccccc2)c1] 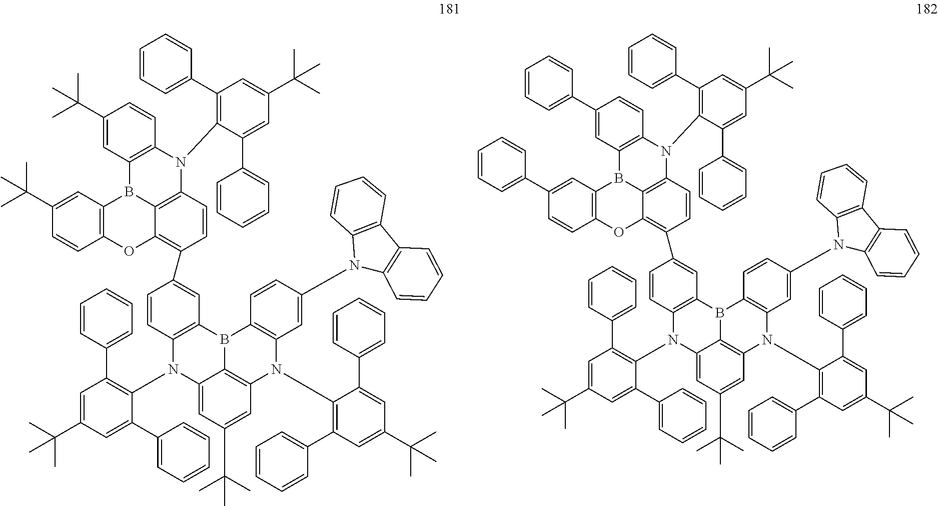 [SMILES: CC(C)(C)c1ccc2c(c1)B1c3cc(C(C)(C)C)ccc3N(c3c(-c4ccccc4)cc(C(C)(C)C)cc3-c3ccccc3)c3ccc(-c4ccc5c(c4)B4c6ccc(-n7c8ccccc8c8ccccc87)cc6N(c6c(-c7ccccc7)cc(C(C)(C)C)cc6-c6ccccc6)c6cc(C(C)(C)C)cc(c64)N5c4c(-c5ccccc5)cc(C(C)(C)C)cc4-c4ccccc4)c(c31)O2 ; CC(C)(C)c1cc(-c2ccccc2)c(N2c3ccc(-c4ccc5c6c4Oc4ccc(-c7ccccc7)cc4B6c4cc(-c6ccccc6)ccc4N5c4c(-c5ccccc5)cc(C(C)(C)C)cc4-c4ccccc4)cc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1] 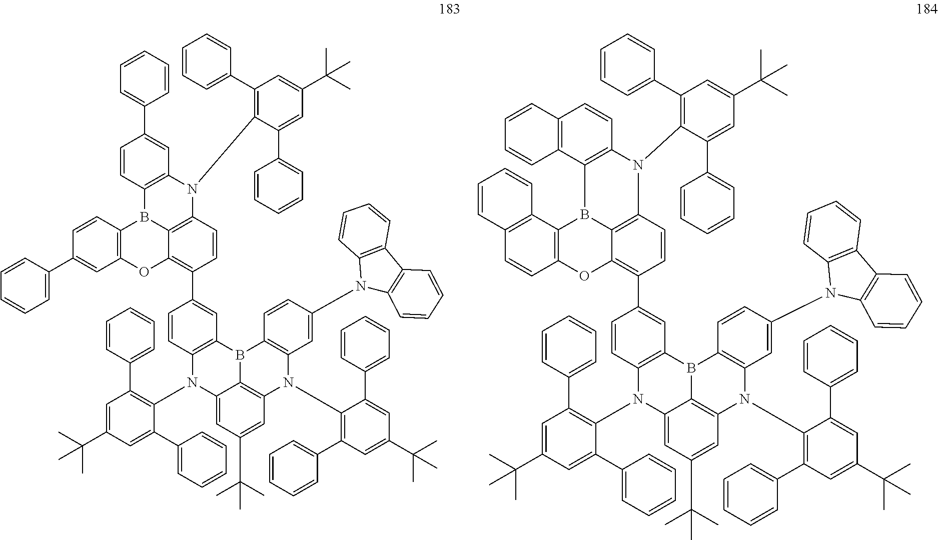 [SMILES: CC(C)(C)c1cc(-c2ccccc2)c(N2c3ccc(-c4ccc5c6c4Oc4cc(-c7ccccc7)ccc4B6c4ccc(-c6ccccc6)cc4N5c4c(-c5ccccc5)cc(C(C)(C)C)cc4-c4ccccc4)cc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc(-c2ccccc2)c(N2c3ccc(-c4ccc5c6c4Oc4ccc7ccccc7c4B6c4c(ccc6ccccc46)N5c4c(-c5ccccc5)cc(C(C)(C)C)cc4-c4ccccc4)cc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1] 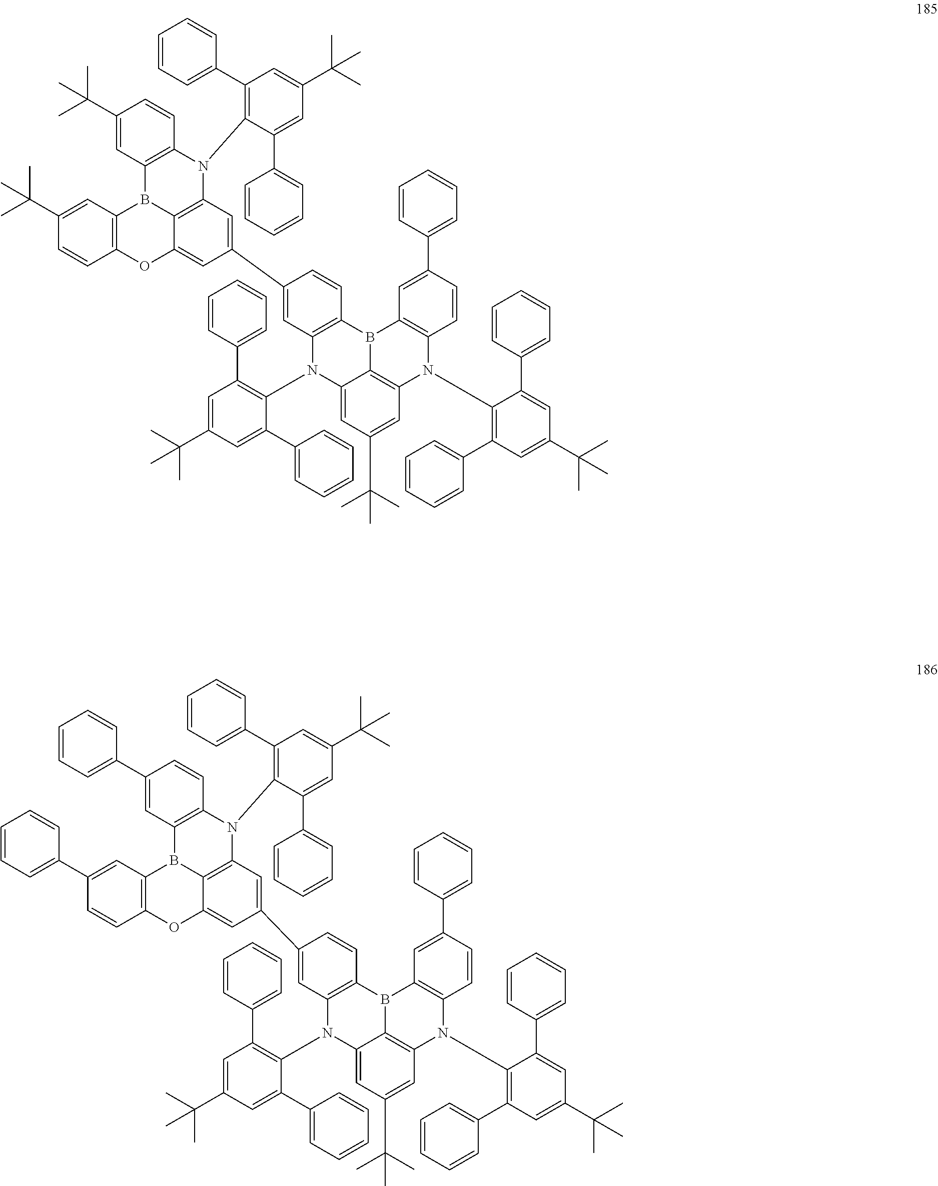 [SMILES: CC(C)(C)c1ccc2c(c1)B1c3cc(C(C)(C)C)ccc3N(c3c(-c4ccccc4)cc(C(C)(C)C)cc3-c3ccccc3)c3cc(-c4ccc5c(c4)N(c4c(-c6ccccc6)cc(C(C)(C)C)cc4-c4ccccc4)c4cc(C(C)(C)C)cc6c4B5c4cc(-c5ccccc5)ccc4N6c4c(-c5ccccc5)cc(C(C)(C)C)cc4-c4ccccc4)cc(c31)O2 ; CC(C)(C)c1cc(-c2ccccc2)c(N2c3ccc(-c4ccccc4)cc3B3c4cc(-c5ccccc5)ccc4Oc4cc(-c5ccc6c(c5)N(c5c(-c7ccccc7)cc(C(C)(C)C)cc5-c5ccccc5)c5cc(C(C)(C)C)cc7c5B6c5cc(-c6ccccc6)ccc5N7c5c(-c6ccccc6)cc(C(C)(C)C)cc5-c5ccccc5)cc2c43)c(-c2ccccc2)c1] 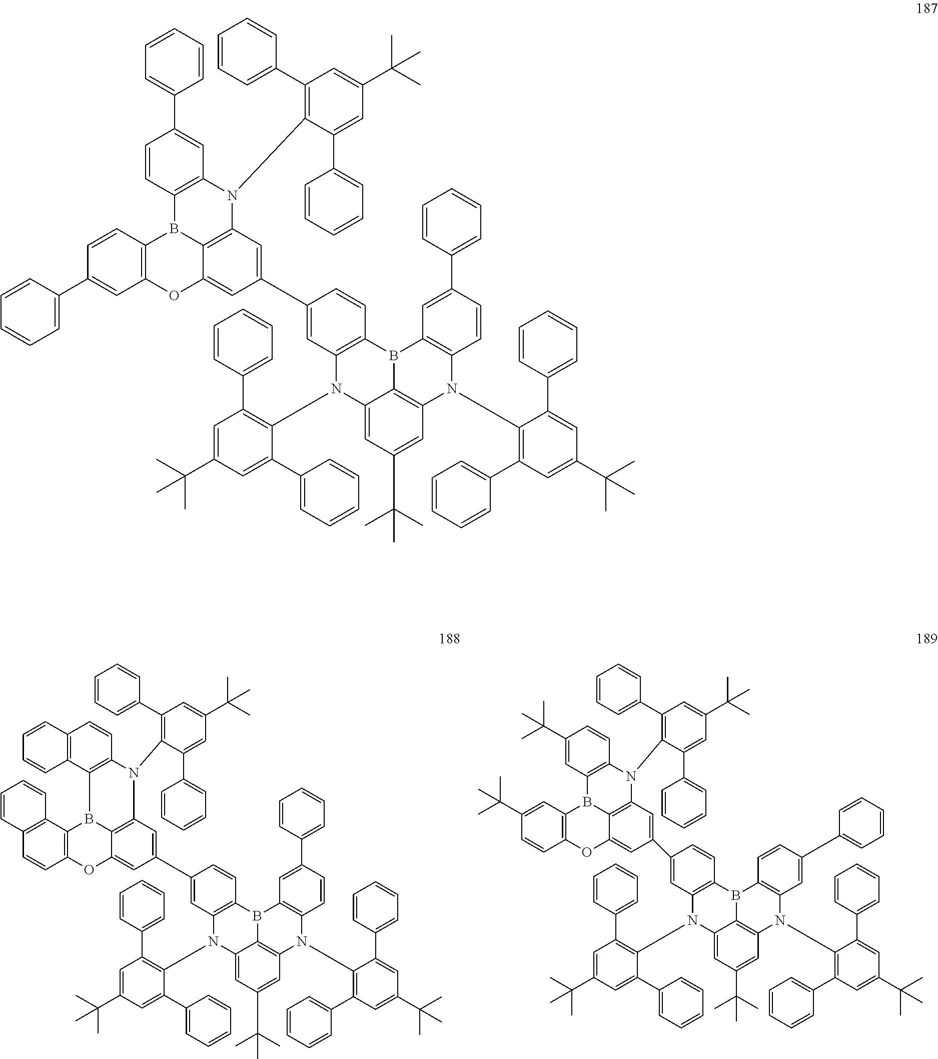 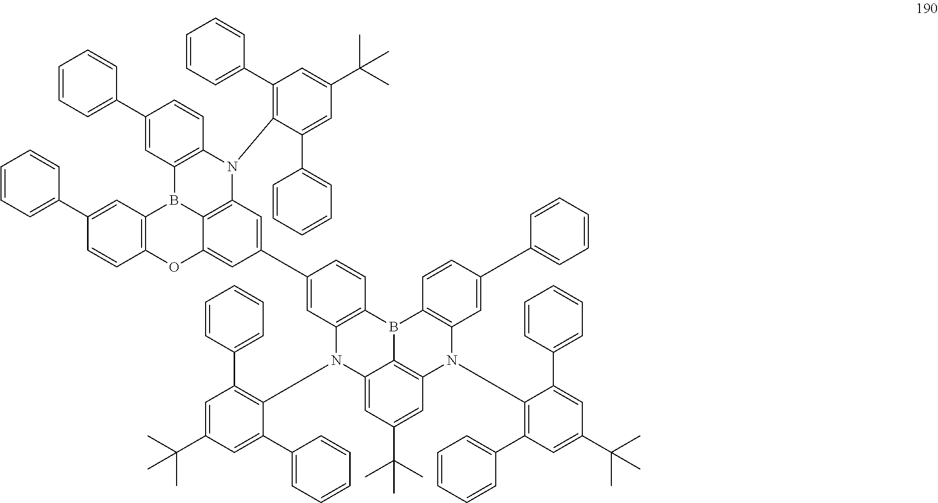 [SMILES: CC(C)(C)c1cc(-c2ccccc2)c(N2c3ccc(-c4ccccc4)cc3B3c4cc(-c5ccccc5)ccc4Oc4cc(-c5ccc6c(c5)N(c5c(-c7ccccc7)cc(C(C)(C)C)cc5-c5ccccc5)c5cc(C(C)(C)C)cc7c5B6c5ccc(-c6ccccc6)cc5N7c5c(-c6ccccc6)cc(C(C)(C)C)cc5-c5ccccc5)cc2c43)c(-c2ccccc2)c1] 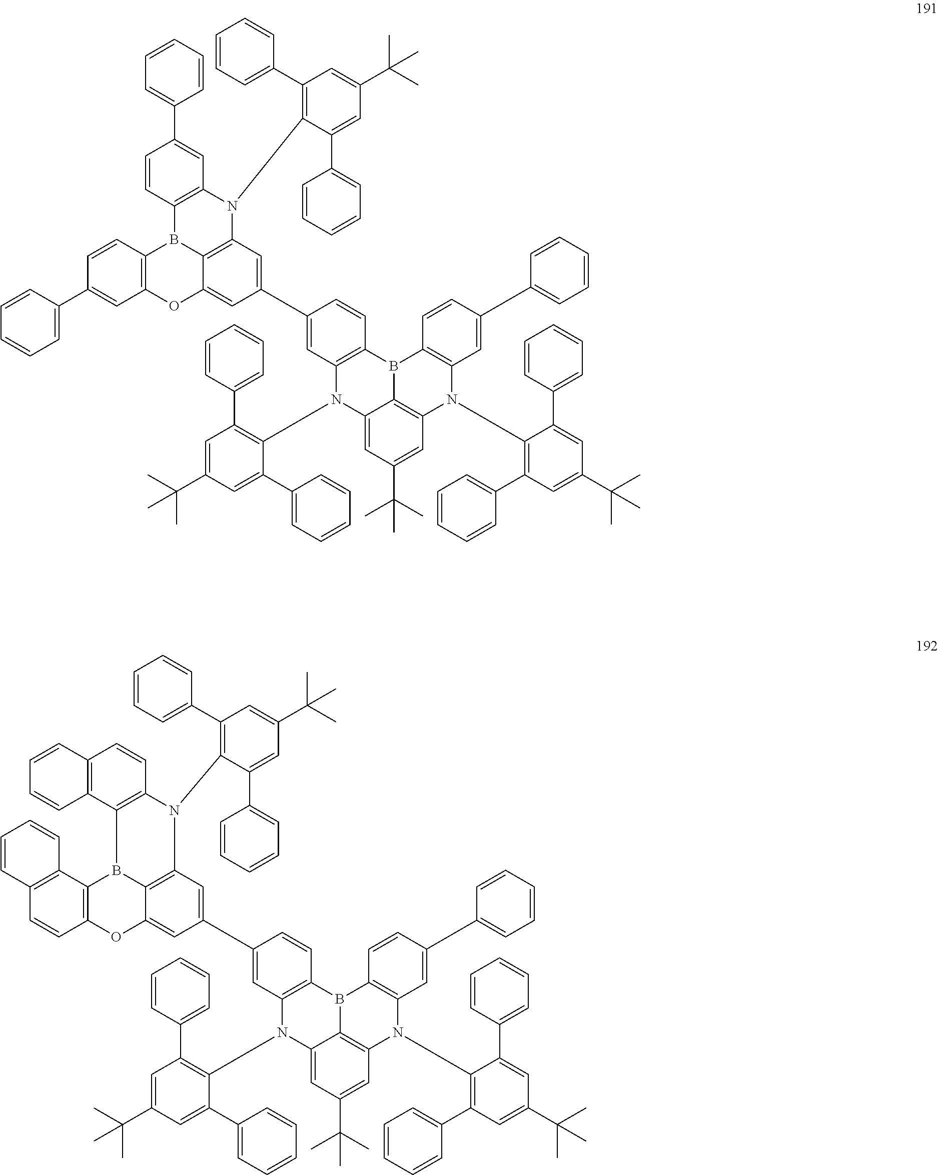 [SMILES: CC(C)(C)c1cc(-c2ccccc2)c(N2c3cc(-c4ccccc4)ccc3B3c4ccc(-c5ccccc5)cc4Oc4cc(-c5ccc6c(c5)N(c5c(-c7ccccc7)cc(C(C)(C)C)cc5-c5ccccc5)c5cc(C(C)(C)C)cc7c5B6c5ccc(-c6ccccc6)cc5N7c5c(-c6ccccc6)cc(C(C)(C)C)cc5-c5ccccc5)cc2c43)c(-c2ccccc2)c1 ; CC(C)(C)c1cc(-c2ccccc2)c(N2c3cc(-c4ccccc4)ccc3B3c4ccc(-c5cc6c7c(c5)N(c5c(-c8ccccc8)cc(C(C)(C)C)cc5-c5ccccc5)c5ccc8ccccc8c5B7c5c(ccc7ccccc57)O6)cc4N(c4c(-c5ccccc5)cc(C(C)(C)C)cc4-c4ccccc4)c4cc(C(C)(C)C)cc2c43)c(-c2ccccc2)c1] 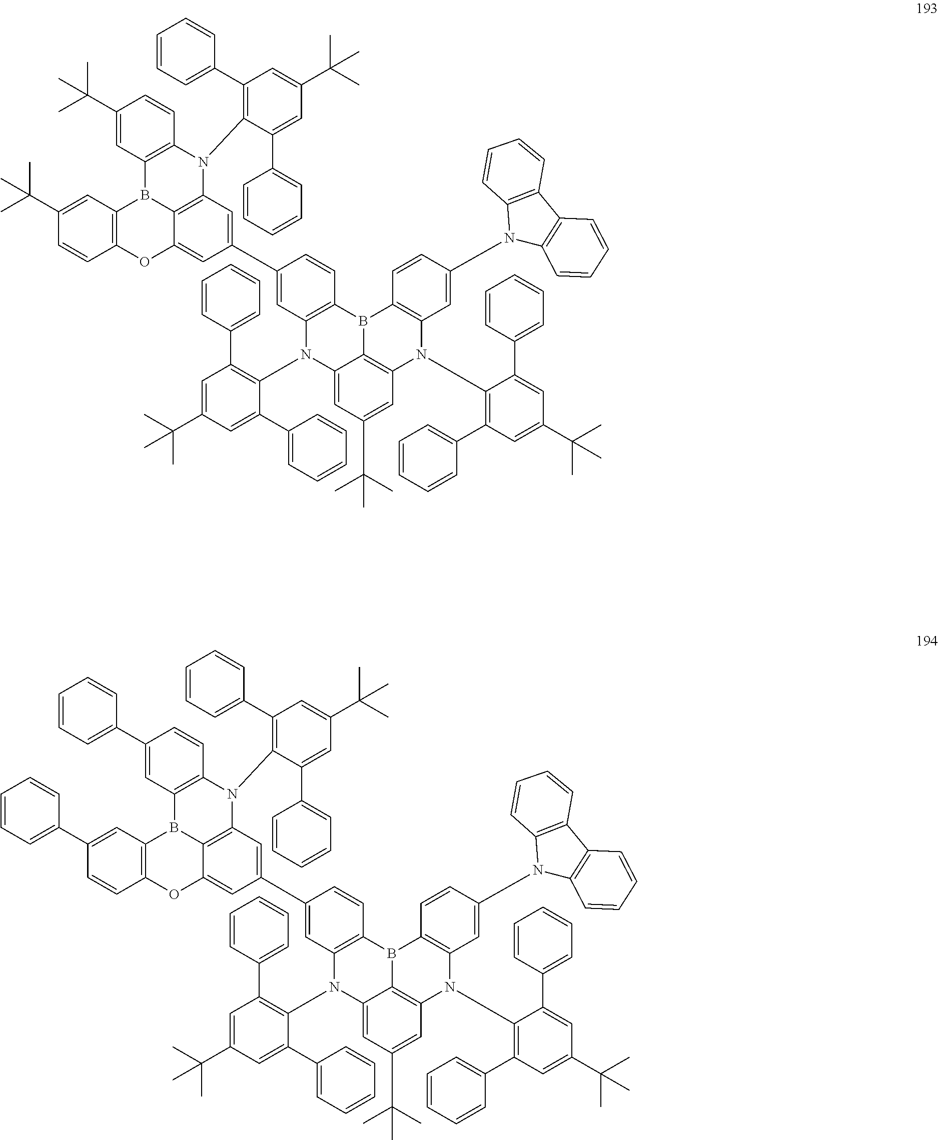 [SMILES: CC(C)(C)c1ccc2c(c1)B1c3cc(C(C)(C)C)ccc3N(c3c(-c4ccccc4)cc(C(C)(C)C)cc3-c3ccccc3)c3cc(-c4ccc5c(c4)N(c4c(-c6ccccc6)cc(C(C)(C)C)cc4-c4ccccc4)c4cc(C(C)(C)C)cc6c4B5c4ccc(-n5c7ccccc7c7ccccc75)cc4N6c4c(-c5ccccc5)cc(C(C)(C)C)cc4-c4ccccc4)cc(c31)O2 ; CC(C)(C)c1cc(-c2ccccc2)c(N2c3ccc(-c4ccccc4)cc3B3c4cc(-c5ccccc5)ccc4Oc4cc(-c5ccc6c(c5)N(c5c(-c7ccccc7)cc(C(C)(C)C)cc5-c5ccccc5)c5cc(C(C)(C)C)cc7c5B6c5ccc(-n6c8ccccc8c8ccccc86)cc5N7c5c(-c6ccccc6)cc(C(C)(C)C)cc5-c5ccccc5)cc2c43)c(-c2ccccc2)c1] 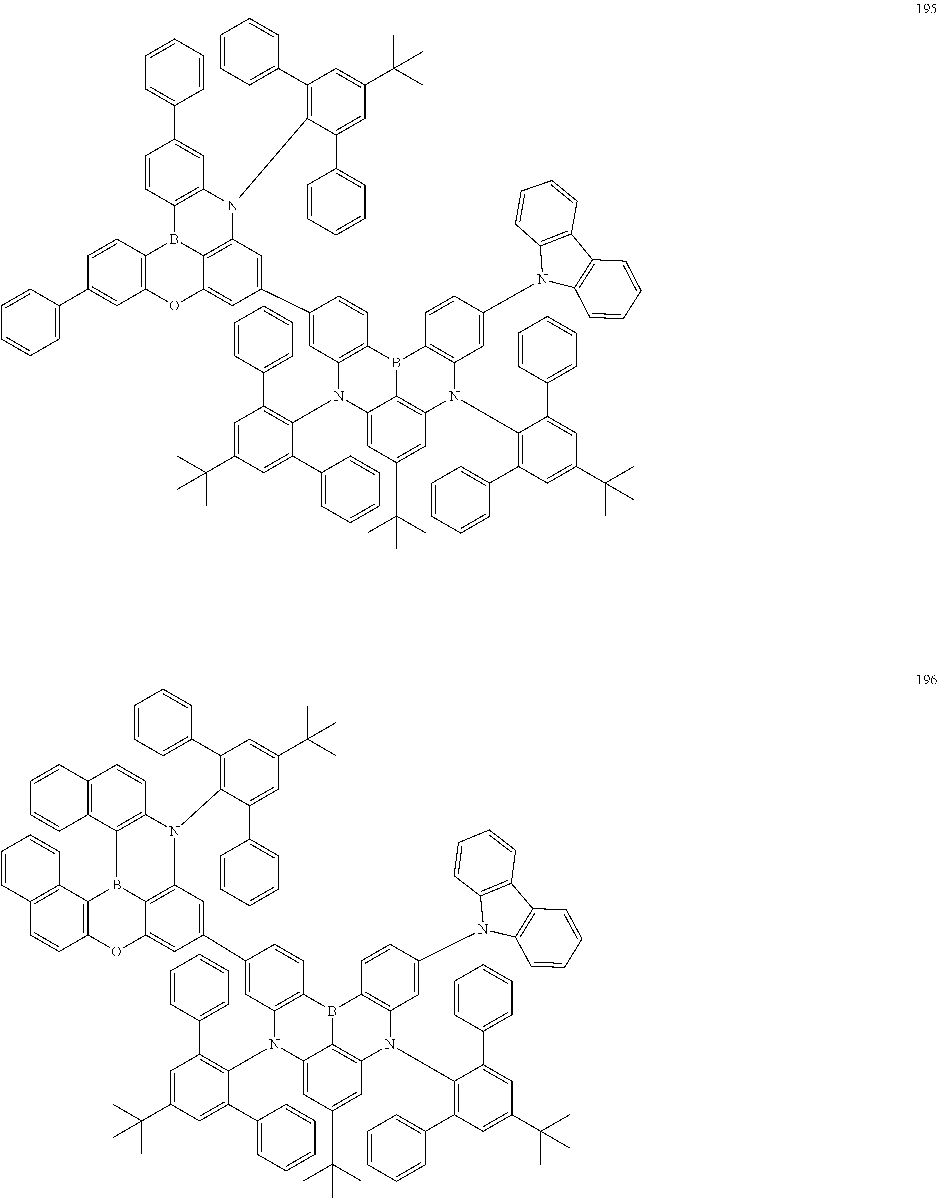 [SMILES: CC(C)(C)c1cc(-c2ccccc2)c(N2c3cc(-c4ccccc4)ccc3B3c4ccc(-c5ccccc5)cc4Oc4cc(-c5ccc6c(c5)N(c5c(-c7ccccc7)cc(C(C)(C)C)cc5-c5ccccc5)c5cc(C(C)(C)C)cc7c5B6c5ccc(-n6c8ccccc8c8ccccc86)cc5N7c5c(-c6ccccc6)cc(C(C)(C)C)cc5-c5ccccc5)cc2c43)c(-c2ccccc2)c1 ; CC(C)(C)c1cc(-c2ccccc2)c(N2c3cc(-c4cc5c6c(c4)N(c4c(-c7ccccc7)cc(C(C)(C)C)cc4-c4ccccc4)c4ccc7ccccc7c4B6c4c(ccc6ccccc46)O5)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1] 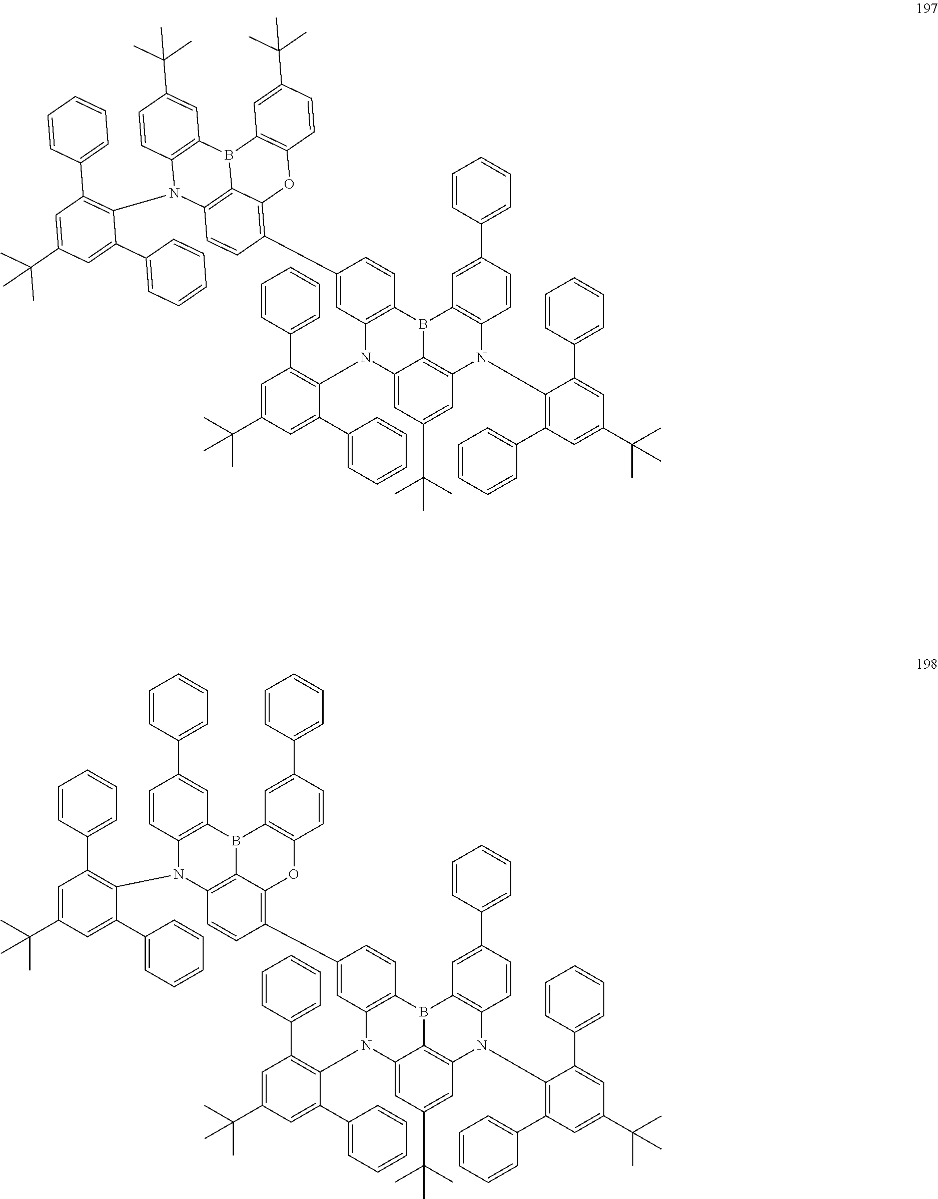 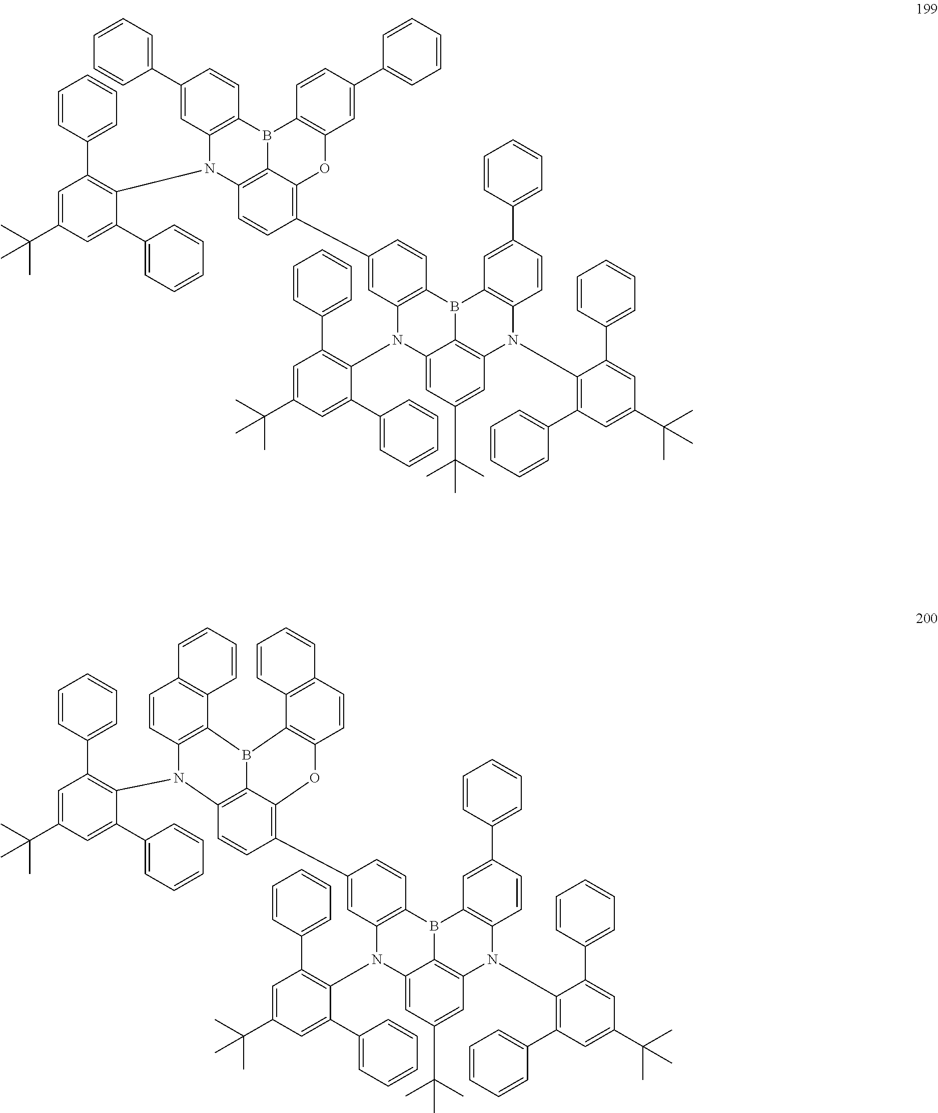 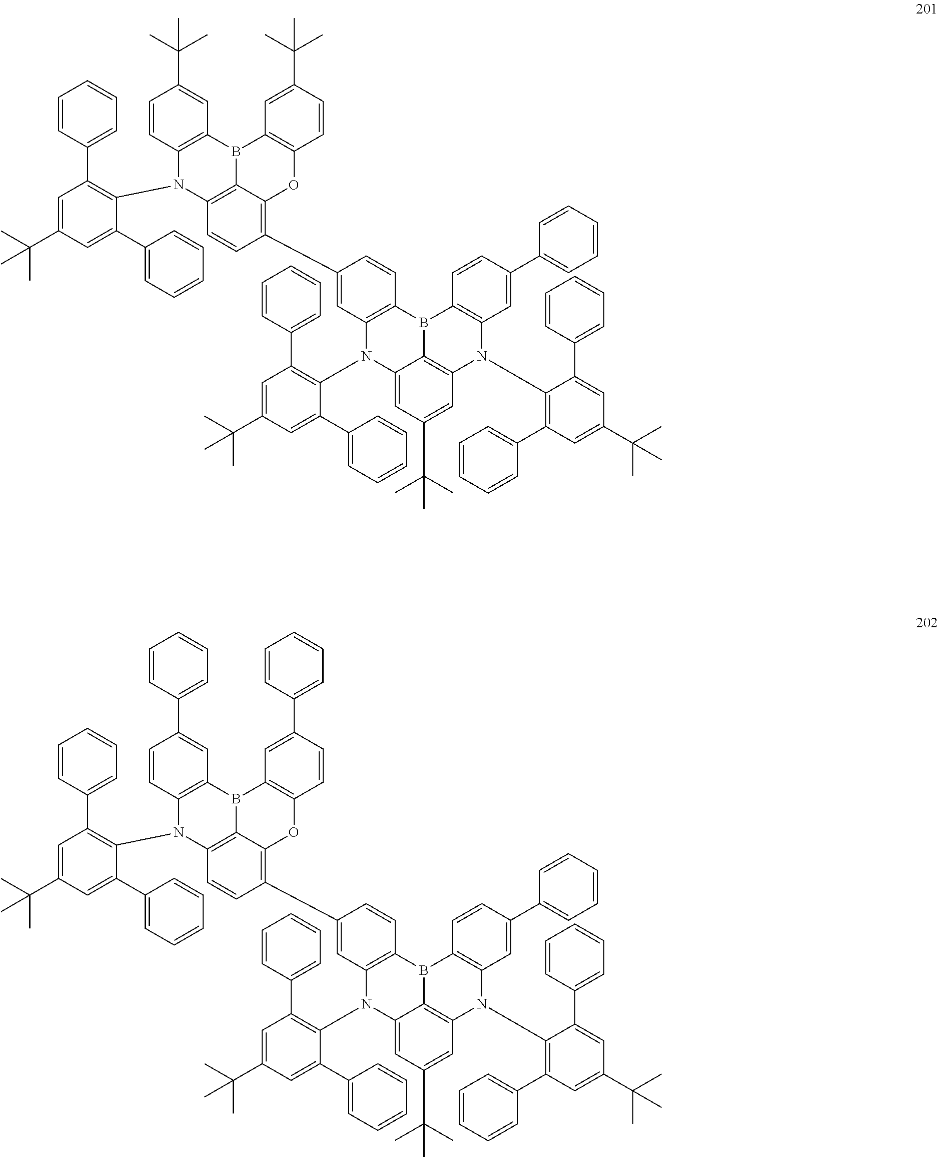 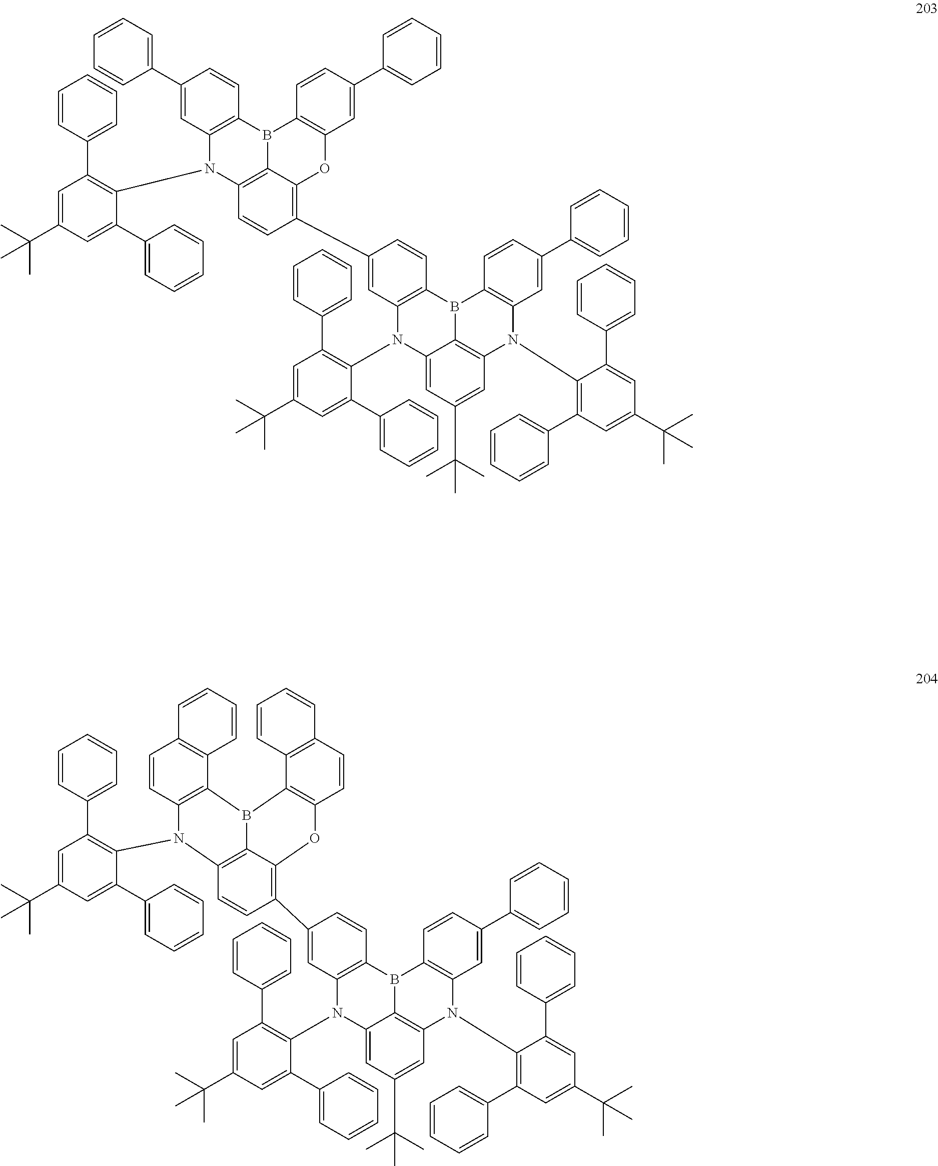 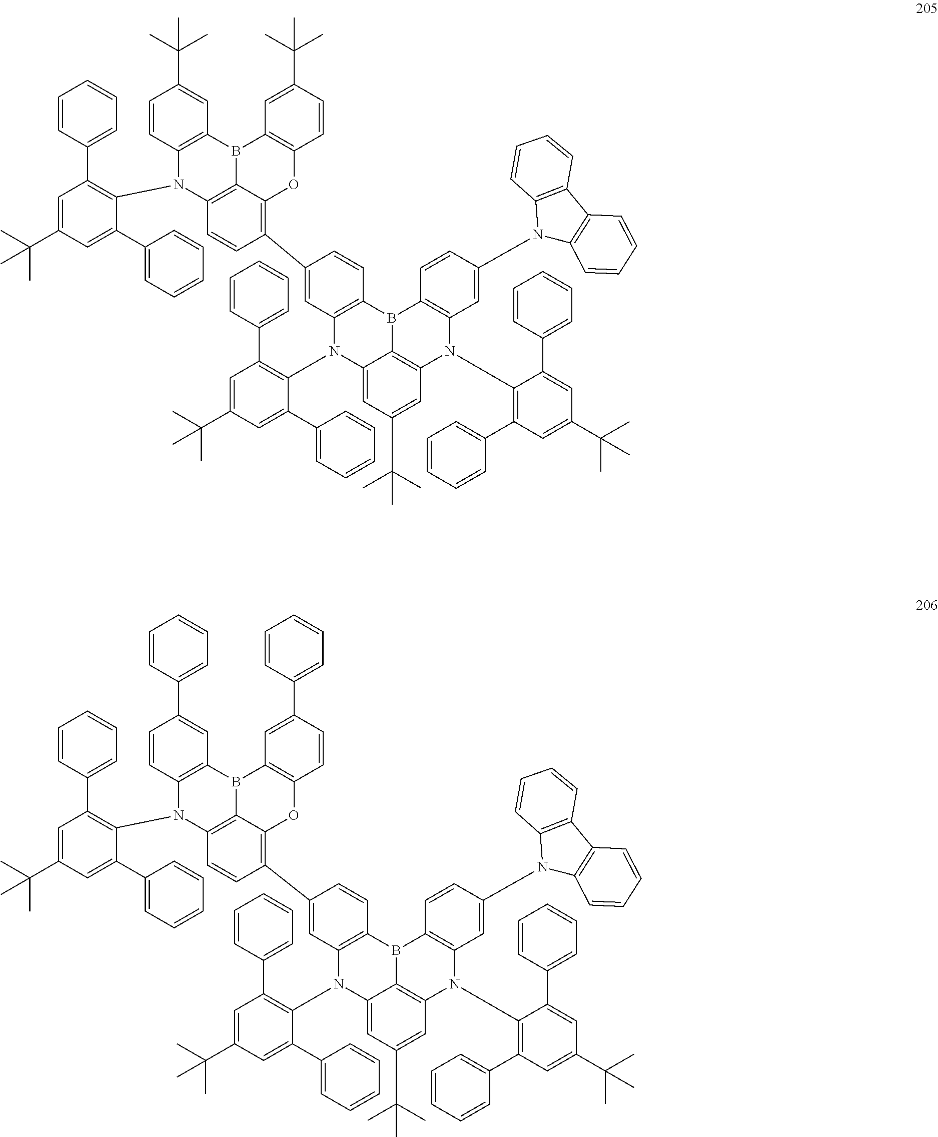 [SMILES: CC(C)(C)c1ccc2c(c1)B1c3cc(C(C)(C)C)ccc3N(c3c(-c4ccccc4)cc(C(C)(C)C)cc3-c3ccccc3)c3ccc(-c4ccc5c(c4)N(c4c(-c6ccccc6)cc(C(C)(C)C)cc4-c4ccccc4)c4cc(C(C)(C)C)cc6c4B5c4ccc(-n5c7ccccc7c7ccccc75)cc4N6c4c(-c5ccccc5)cc(C(C)(C)C)cc4-c4ccccc4)c(c31)O2 ; CC(C)(C)c1cc(-c2ccccc2)c(N2c3cc(-c4ccc5c6c4Oc4ccc(-c7ccccc7)cc4B6c4cc(-c6ccccc6)ccc4N5c4c(-c5ccccc5)cc(C(C)(C)C)cc4-c4ccccc4)ccc3B3c4ccc(-n5c6ccccc6c6ccccc65)cc4N(c4c(-c5ccccc5)cc(C(C)(C)C)cc4-c4ccccc4)c4cc(C(C)(C)C)cc2c43)c(-c2ccccc2)c1] 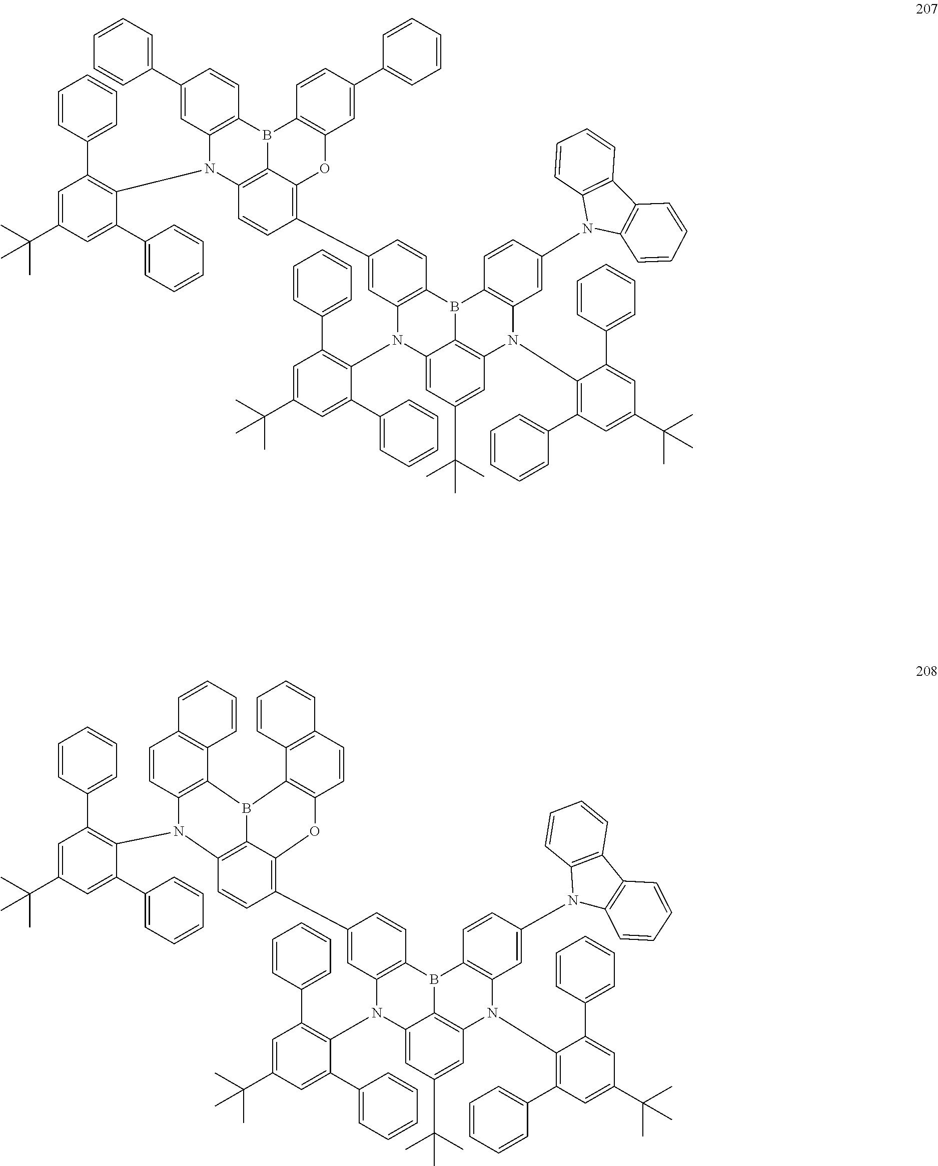 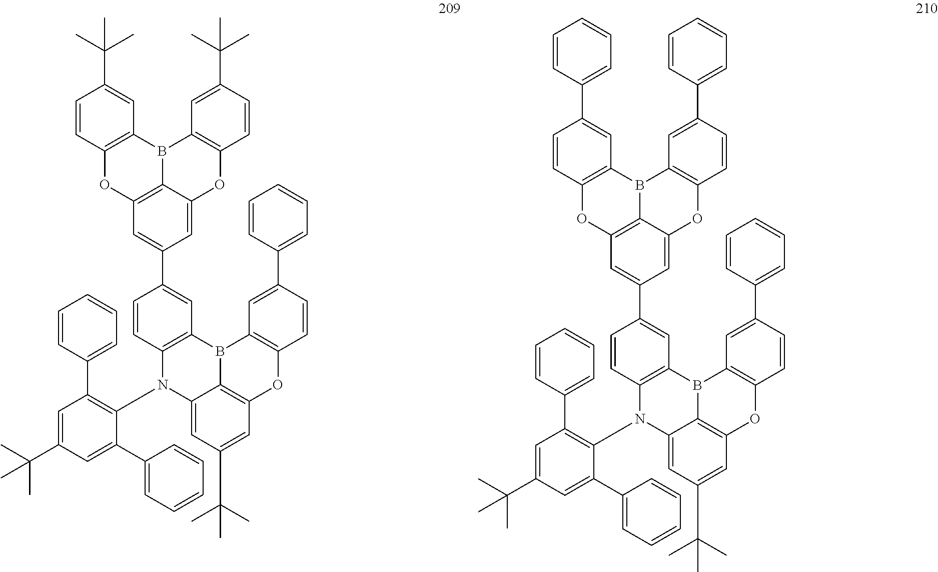 [SMILES: CC(C)(C)c1ccc2c(c1)B1c3cc(C(C)(C)C)ccc3Oc3cc(-c4ccc5c(c4)B4c6cc(-c7ccccc7)ccc6Oc6cc(C(C)(C)C)cc(c64)N5c4c(-c5ccccc5)cc(C(C)(C)C)cc4-c4ccccc4)cc(c31)O2 ; CC(C)(C)c1cc(-c2ccccc2)c(N2c3ccc(-c4cc5c6c(c4)Oc4ccc(-c7ccccc7)cc4B6c4cc(-c6ccccc6)ccc4O5)cc3B3c4cc(-c5ccccc5)ccc4Oc4cc(C(C)(C)C)cc2c43)c(-c2ccccc2)c1] 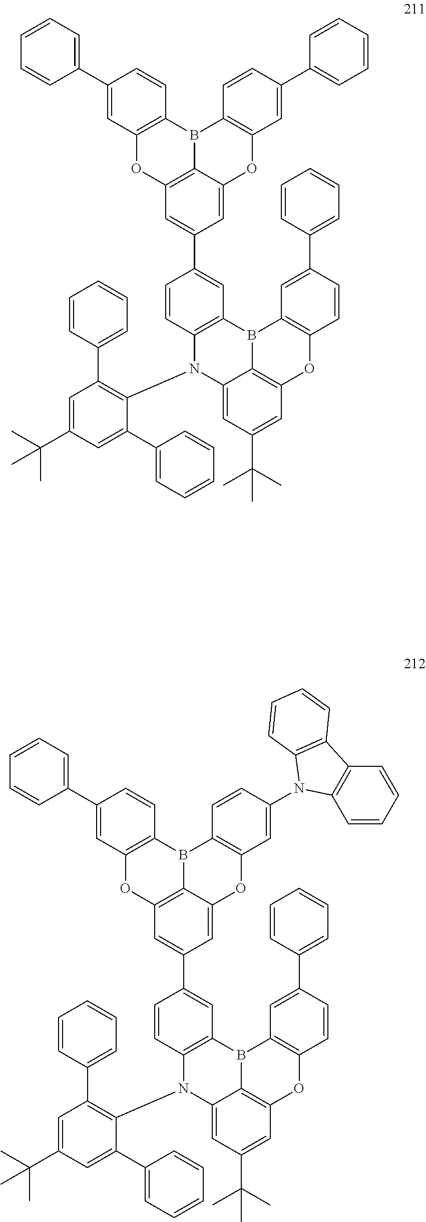 [SMILES: CC(C)(C)c1cc(-c2ccccc2)c(N2c3ccc(-c4cc5c6c(c4)Oc4cc(-c7ccccc7)ccc4B6c4ccc(-c6ccccc6)cc4O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-c6ccccc6)cc4O5)cc3B3c4cc(-c5ccccc5)ccc4Oc4cc(C(C)(C)C)cc2c43)c(-c2ccccc2)c1] 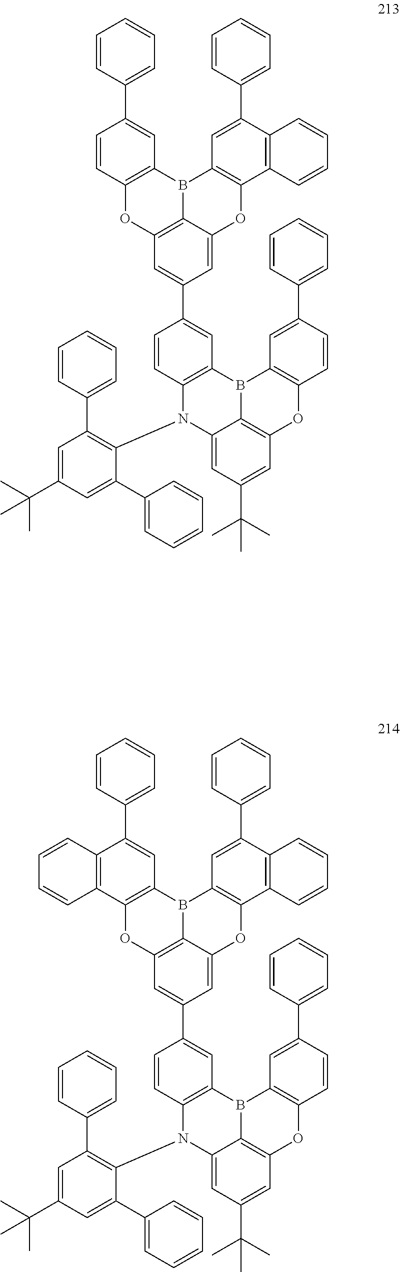 [SMILES: CC(C)(C)c1cc(-c2ccccc2)c(N2c3ccc(-c4cc5c6c(c4)Oc4c(cc(-c7ccccc7)c7ccccc47)B6c4cc(-c6ccccc6)ccc4O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4cc5c6c(c4)Oc4c(cc(-c7ccccc7)c7ccccc47)B6c4cc(-c6ccccc6)c6ccccc6c4O5)cc3B3c4cc(-c5ccccc5)ccc4Oc4cc(C(C)(C)C)cc2c43)c(-c2ccccc2)c1] 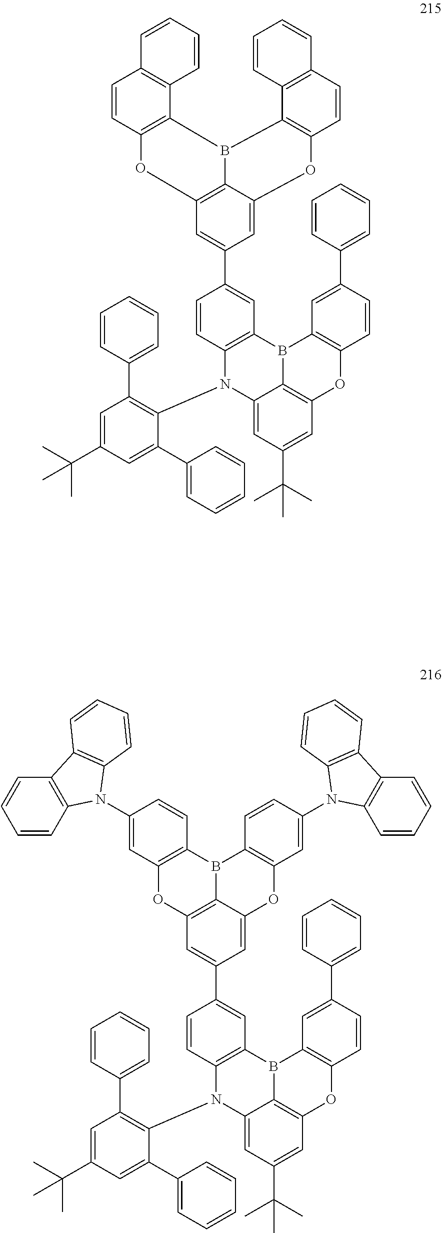 [SMILES: CC(C)(C)c1cc(-c2ccccc2)c(N2c3ccc(-c4cc5c6c(c4)Oc4ccc7ccccc7c4B6c4c(ccc6ccccc46)O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-n6c7ccccc7c7ccccc76)cc4O5)cc3B3c4cc(-c5ccccc5)ccc4Oc4cc(C(C)(C)C)cc2c43)c(-c2ccccc2)c1] 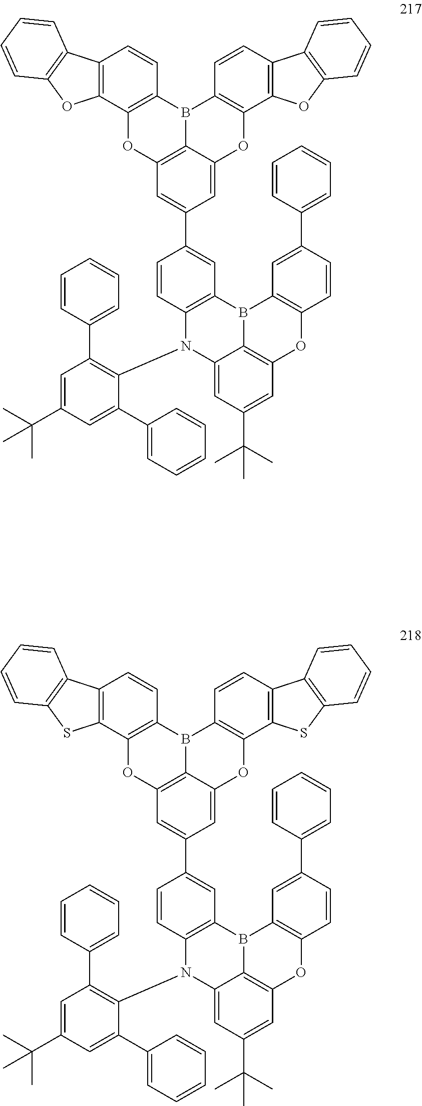 [SMILES: CC(C)(C)c1cc(-c2ccccc2)c(N2c3ccc(-c4cc5c6c(c4)Oc4c(ccc7c4oc4ccccc47)B6c4ccc6c(oc7ccccc76)c4O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4cc5c6c(c4)Oc4c(ccc7c4sc4ccccc47)B6c4ccc6c(sc7ccccc76)c4O5)cc3B3c4cc(-c5ccccc5)ccc4Oc4cc(C(C)(C)C)cc2c43)c(-c2ccccc2)c1] 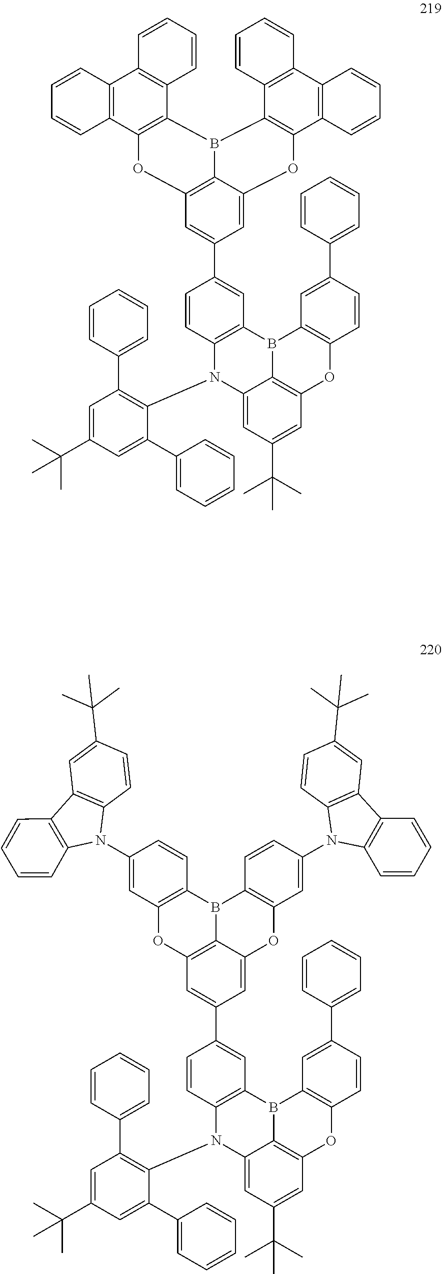 [SMILES: CC(C)(C)c1cc(-c2ccccc2)c(N2c3ccc(-c4cc5c6c(c4)Oc4c(c7ccccc7c7ccccc47)B6c4c(c6ccccc6c6ccccc46)O5)cc3B3c4cc(-c5ccccc5)ccc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8cc(C(C)(C)C)ccc87)ccc4B6c4ccc(-n6c7ccccc7c7cc(C(C)(C)C)ccc76)cc4O5)cc3B3c4cc(-c5ccccc5)ccc4Oc4cc(C(C)(C)C)cc2c43)c(-c2ccccc2)c1] 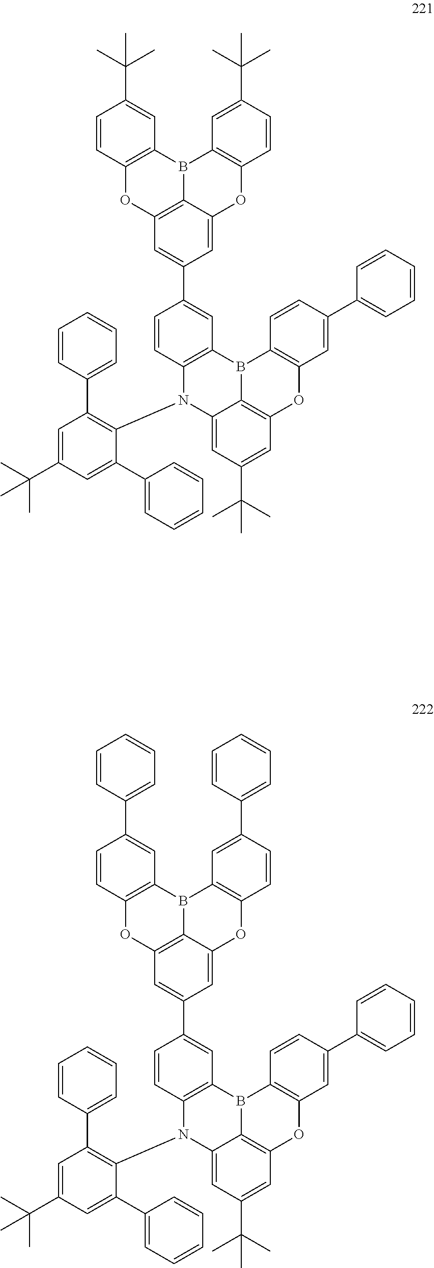 [SMILES: CC(C)(C)c1ccc2c(c1)B1c3cc(C(C)(C)C)ccc3Oc3cc(-c4ccc5c(c4)B4c6ccc(-c7ccccc7)cc6Oc6cc(C(C)(C)C)cc(c64)N5c4c(-c5ccccc5)cc(C(C)(C)C)cc4-c4ccccc4)cc(c31)O2 ; CC(C)(C)c1cc(-c2ccccc2)c(N2c3ccc(-c4cc5c6c(c4)Oc4ccc(-c7ccccc7)cc4B6c4cc(-c6ccccc6)ccc4O5)cc3B3c4ccc(-c5ccccc5)cc4Oc4cc(C(C)(C)C)cc2c43)c(-c2ccccc2)c1] 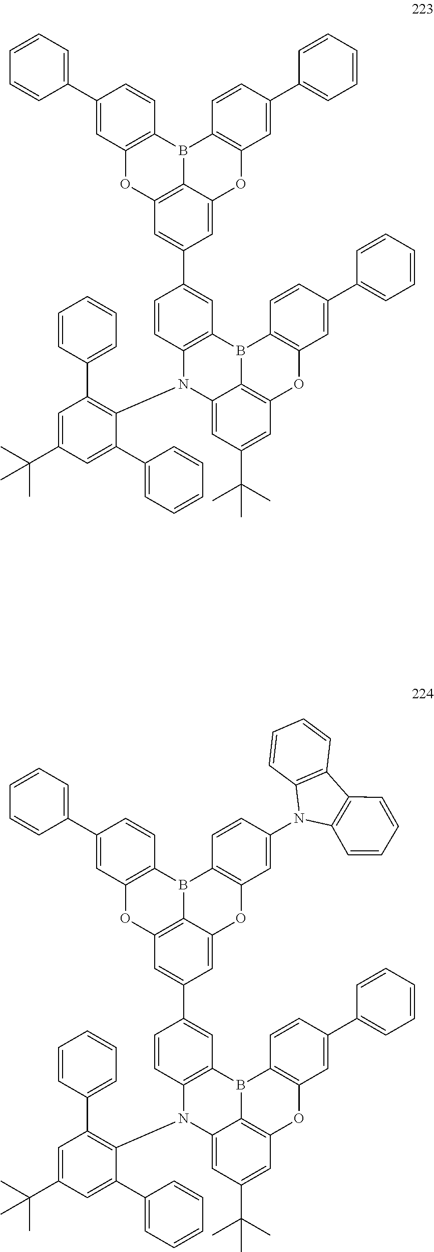 [SMILES: CC(C)(C)c1cc(-c2ccccc2)c(N2c3ccc(-c4cc5c6c(c4)Oc4cc(-c7ccccc7)ccc4B6c4ccc(-c6ccccc6)cc4O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-c6ccccc6)cc4O5)cc3B3c4ccc(-c5ccccc5)cc4Oc4cc(C(C)(C)C)cc2c43)c(-c2ccccc2)c1] 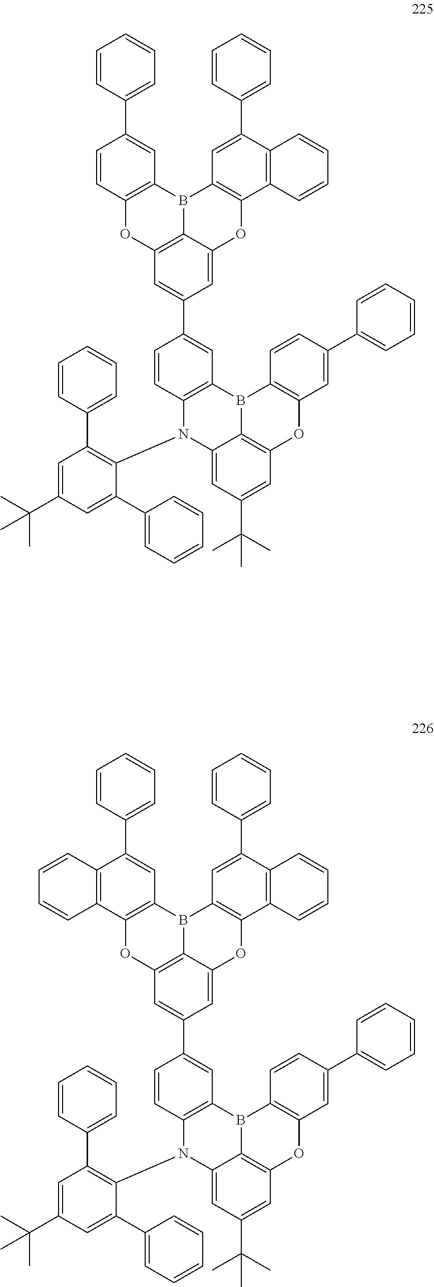 [SMILES: CC(C)(C)c1cc(-c2ccccc2)c(N2c3ccc(-c4cc5c6c(c4)Oc4c(cc(-c7ccccc7)c7ccccc47)B6c4cc(-c6ccccc6)ccc4O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4c(cc(-c7ccccc7)c7ccccc47)B6c4cc(-c6ccccc6)c6ccccc6c4O5)cc3B3c4ccc(-c5ccccc5)cc4Oc4cc(C(C)(C)C)cc2c43)c(-c2ccccc2)c1] 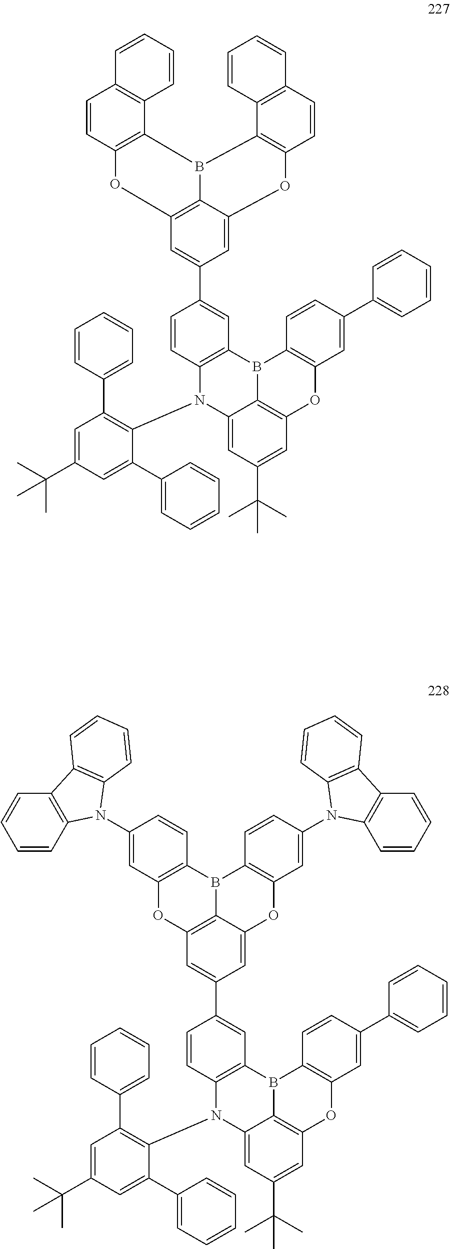 [SMILES: CC(C)(C)c1cc(-c2ccccc2)c(N2c3ccc(-c4cc5c6c(c4)Oc4ccc7ccccc7c4B6c4c(ccc6ccccc46)O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-n6c7ccccc7c7ccccc76)cc4O5)cc3B3c4ccc(-c5ccccc5)cc4Oc4cc(C(C)(C)C)cc2c43)c(-c2ccccc2)c1] 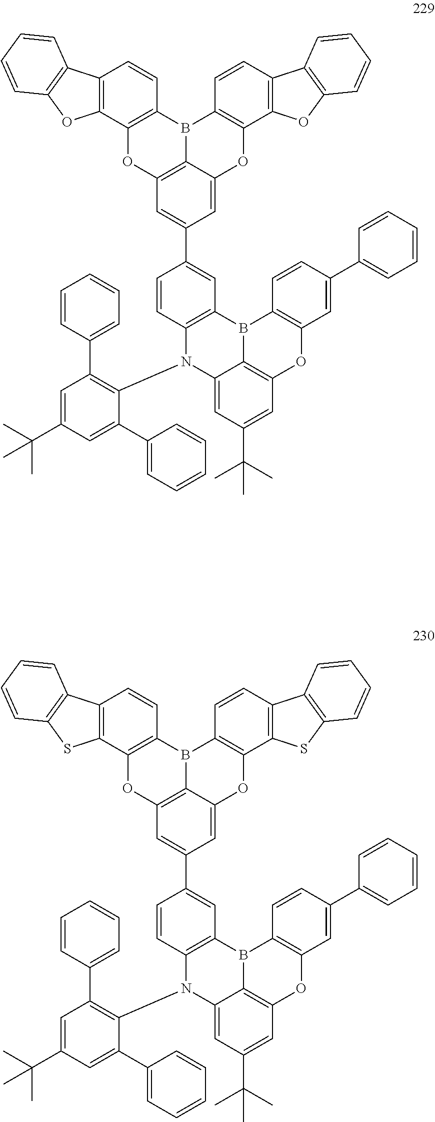 [SMILES: CC(C)(C)c1cc(-c2ccccc2)c(N2c3ccc(-c4cc5c6c(c4)Oc4c(ccc7c4oc4ccccc47)B6c4ccc6c(oc7ccccc76)c4O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4c(ccc7c4sc4ccccc47)B6c4ccc6c(sc7ccccc76)c4O5)cc3B3c4ccc(-c5ccccc5)cc4Oc4cc(C(C)(C)C)cc2c43)c(-c2ccccc2)c1] 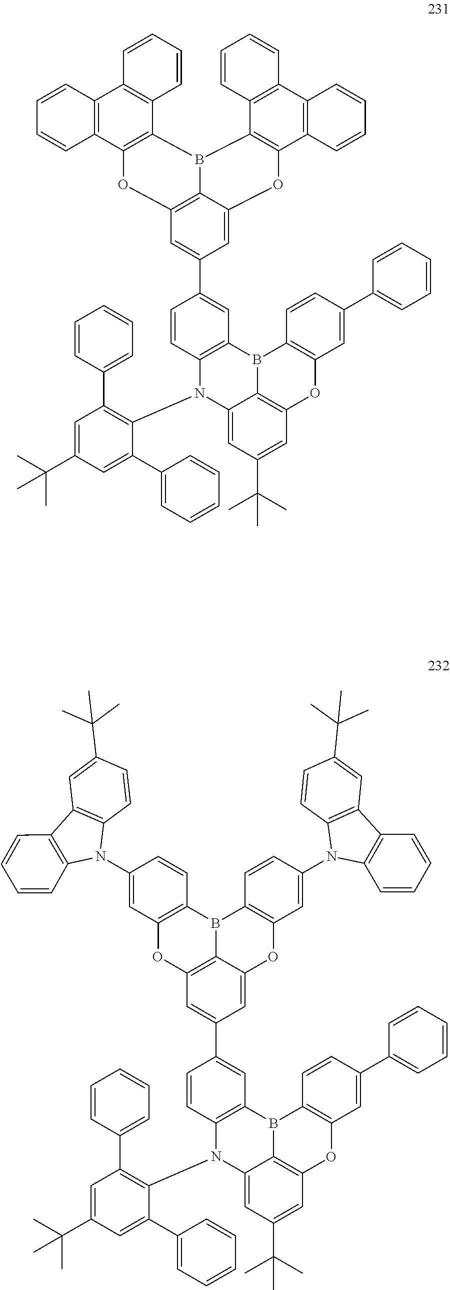 [SMILES: CC(C)(C)c1cc(-c2ccccc2)c(N2c3ccc(-c4cc5c6c(c4)Oc4c(c7ccccc7c7ccccc47)B6c4c(c6ccccc6c6ccccc46)O5)cc3B3c4ccc(-c5ccccc5)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8cc(C(C)(C)C)ccc87)ccc4B6c4ccc(-n6c7ccccc7c7cc(C(C)(C)C)ccc76)cc4O5)cc3B3c4ccc(-c5ccccc5)cc4Oc4cc(C(C)(C)C)cc2c43)c(-c2ccccc2)c1] 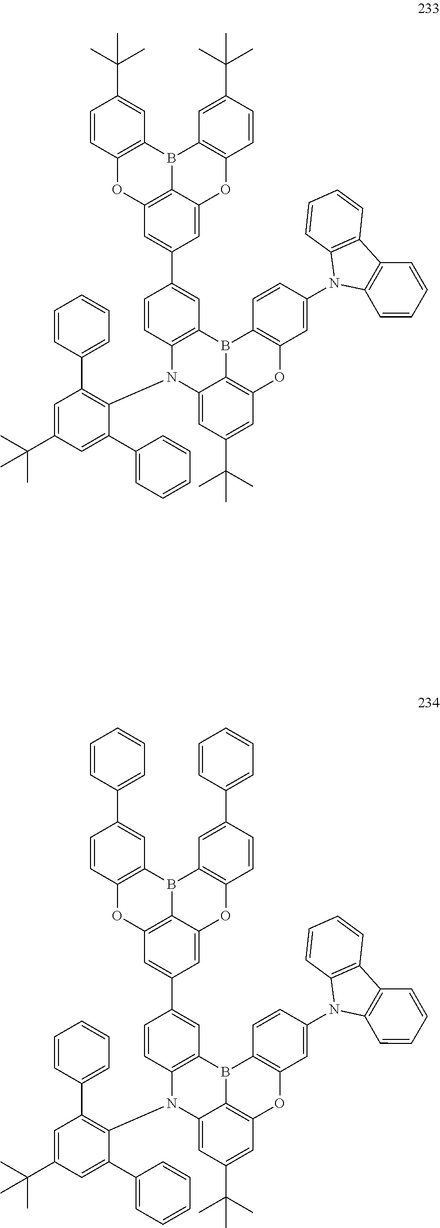 [SMILES: CC(C)(C)c1ccc2c(c1)B1c3cc(C(C)(C)C)ccc3Oc3cc(-c4ccc5c(c4)B4c6ccc(-n7c8ccccc8c8ccccc87)cc6Oc6cc(C(C)(C)C)cc(c64)N5c4c(-c5ccccc5)cc(C(C)(C)C)cc4-c4ccccc4)cc(c31)O2 ; CC(C)(C)c1cc(-c2ccccc2)c(N2c3ccc(-c4cc5c6c(c4)Oc4ccc(-c7ccccc7)cc4B6c4cc(-c6ccccc6)ccc4O5)cc3B3c4ccc(-n5c6ccccc6c6ccccc65)cc4Oc4cc(C(C)(C)C)cc2c43)c(-c2ccccc2)c1] 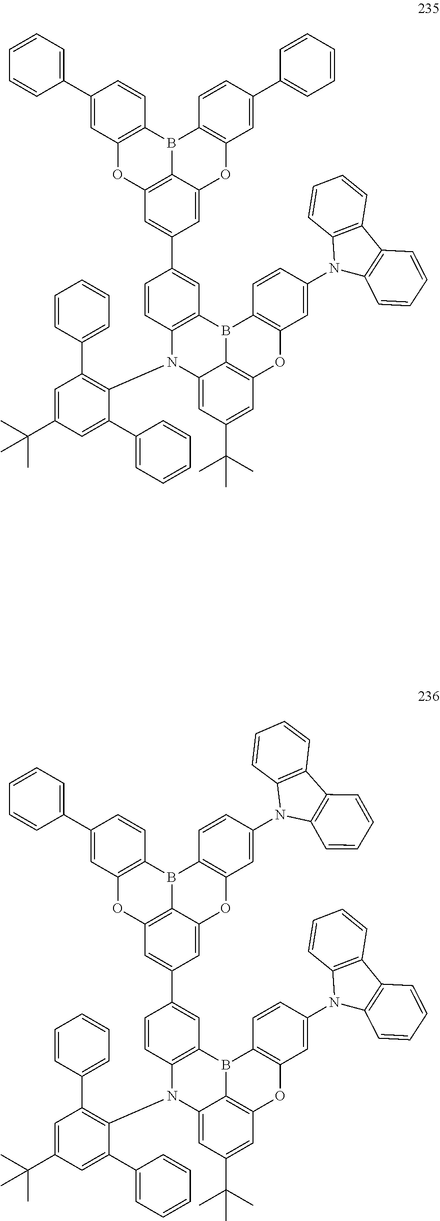 [SMILES: CC(C)(C)c1cc(-c2ccccc2)c(N2c3ccc(-c4cc5c6c(c4)Oc4cc(-c7ccccc7)ccc4B6c4ccc(-c6ccccc6)cc4O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-c6ccccc6)cc4O5)cc3B3c4ccc(-n5c6ccccc6c6ccccc65)cc4Oc4cc(C(C)(C)C)cc2c43)c(-c2ccccc2)c1] 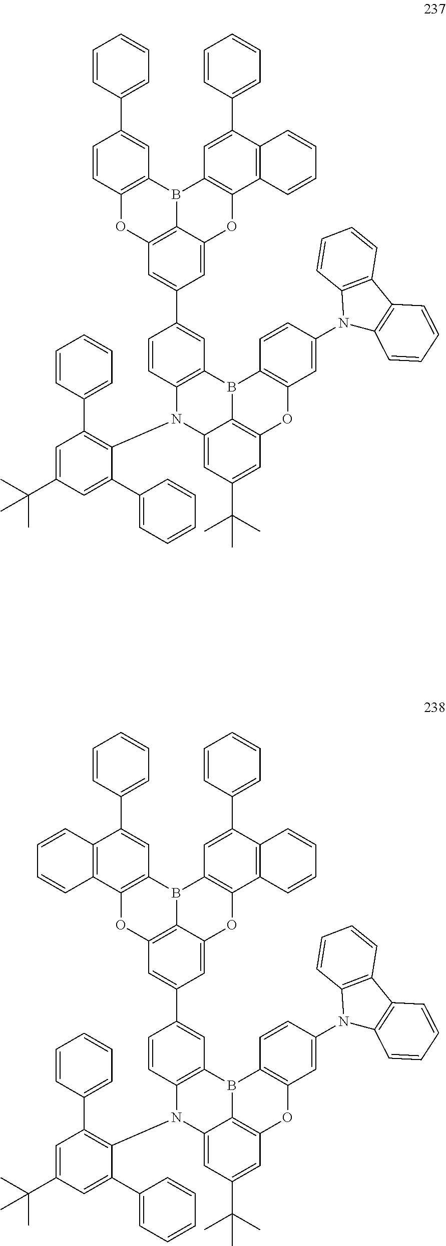 [SMILES: CC(C)(C)c1cc(-c2ccccc2)c(N2c3ccc(-c4cc5c6c(c4)Oc4c(cc(-c7ccccc7)c7ccccc47)B6c4cc(-c6ccccc6)ccc4O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4c(cc(-c7ccccc7)c7ccccc47)B6c4cc(-c6ccccc6)c6ccccc6c4O5)cc3B3c4ccc(-n5c6ccccc6c6ccccc65)cc4Oc4cc(C(C)(C)C)cc2c43)c(-c2ccccc2)c1] 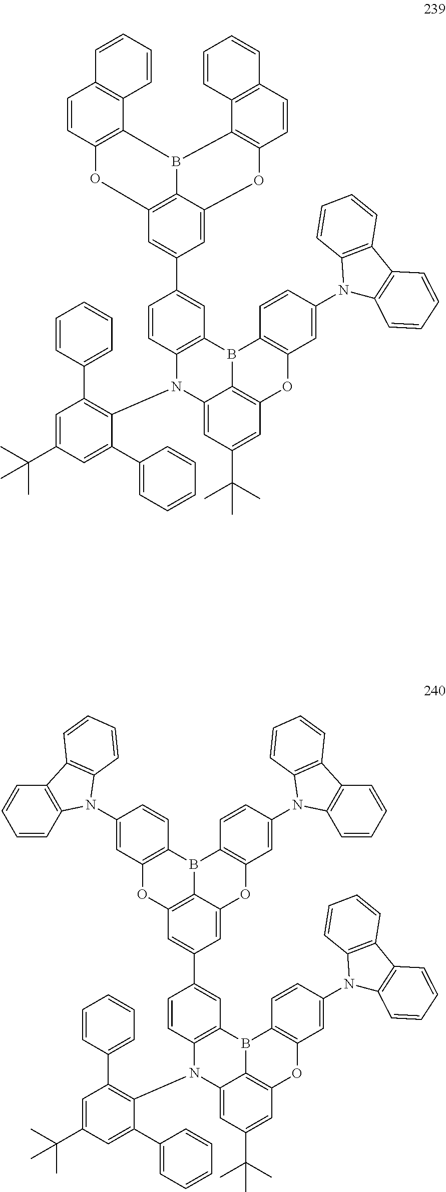 [SMILES: CC(C)(C)c1cc(-c2ccccc2)c(N2c3ccc(-c4cc5c6c(c4)Oc4ccc7ccccc7c4B6c4c(ccc6ccccc46)O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8ccccc87)ccc4B6c4ccc(-n6c7ccccc7c7ccccc76)cc4O5)cc3B3c4ccc(-n5c6ccccc6c6ccccc65)cc4Oc4cc(C(C)(C)C)cc2c43)c(-c2ccccc2)c1] 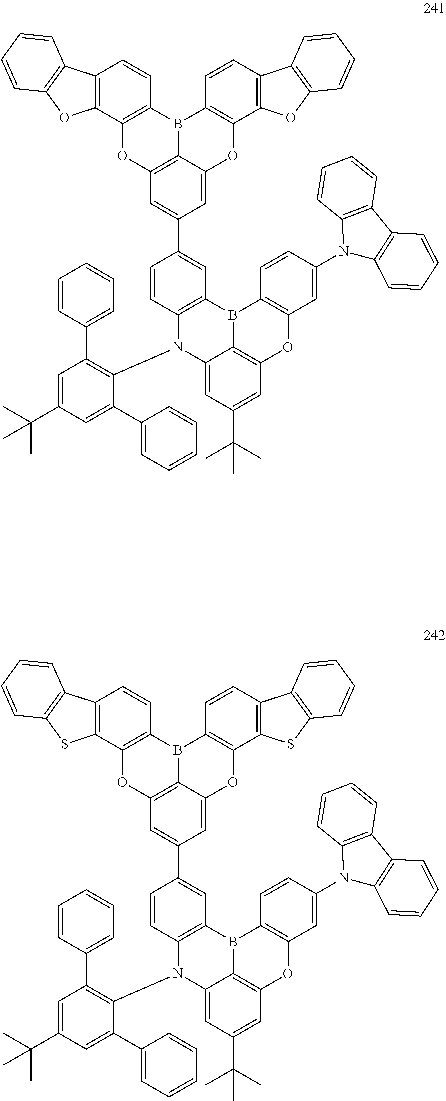 [SMILES: CC(C)(C)c1cc(-c2ccccc2)c(N2c3ccc(-c4cc5c6c(c4)Oc4c(ccc7c4oc4ccccc47)B6c4ccc6c(oc7ccccc76)c4O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4c(ccc7c4sc4ccccc47)B6c4ccc6c(sc7ccccc76)c4O5)cc3B3c4ccc(-n5c6ccccc6c6ccccc65)cc4Oc4cc(C(C)(C)C)cc2c43)c(-c2ccccc2)c1] 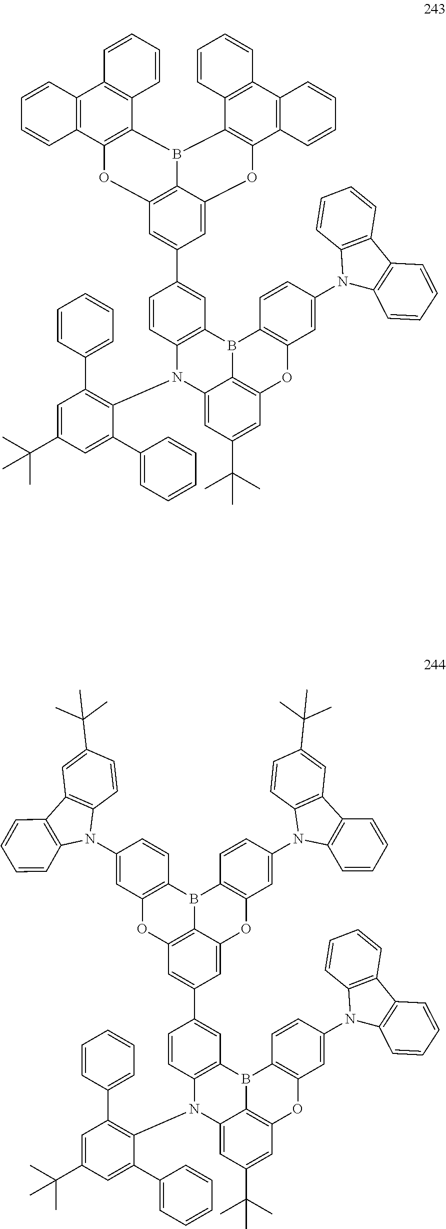 [SMILES: CC(C)(C)c1cc(-c2ccccc2)c(N2c3ccc(-c4cc5c6c(c4)Oc4c(c7ccccc7c7ccccc47)B6c4c(c6ccccc6c6ccccc46)O5)cc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3ccc(-c4cc5c6c(c4)Oc4cc(-n7c8ccccc8c8cc(C(C)(C)C)ccc87)ccc4B6c4ccc(-n6c7ccccc7c7cc(C(C)(C)C)ccc76)cc4O5)cc3B3c4ccc(-n5c6ccccc6c6ccccc65)cc4Oc4cc(C(C)(C)C)cc2c43)c(-c2ccccc2)c1] 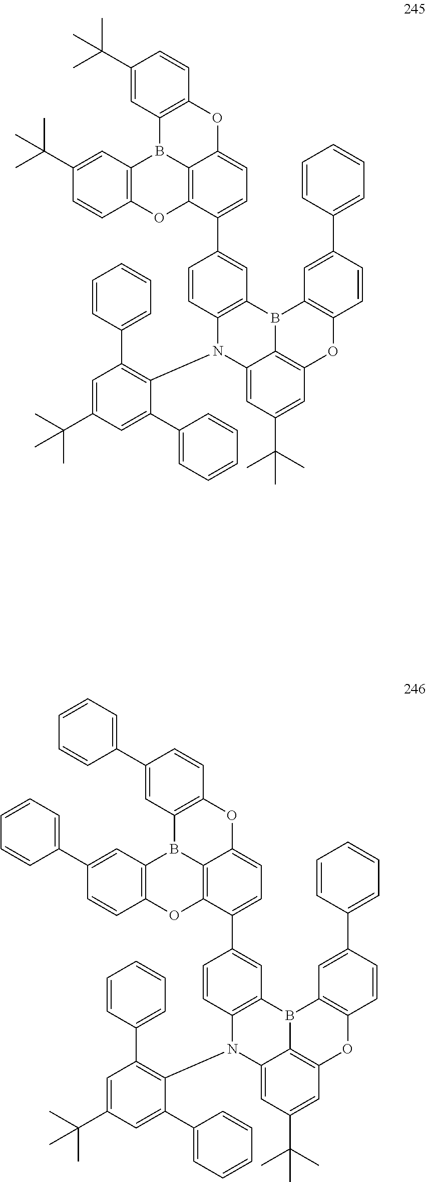 [SMILES: CC(C)(C)c1ccc2c(c1)B1c3cc(C(C)(C)C)ccc3Oc3c(-c4ccc5c(c4)B4c6cc(-c7ccccc7)ccc6Oc6cc(C(C)(C)C)cc(c64)N5c4c(-c5ccccc5)cc(C(C)(C)C)cc4-c4ccccc4)ccc(c31)O2 ; CC(C)(C)c1cc(-c2ccccc2)c(N2c3ccc(-c4ccc5c6c4Oc4ccc(-c7ccccc7)cc4B6c4cc(-c6ccccc6)ccc4O5)cc3B3c4cc(-c5ccccc5)ccc4Oc4cc(C(C)(C)C)cc2c43)c(-c2ccccc2)c1] 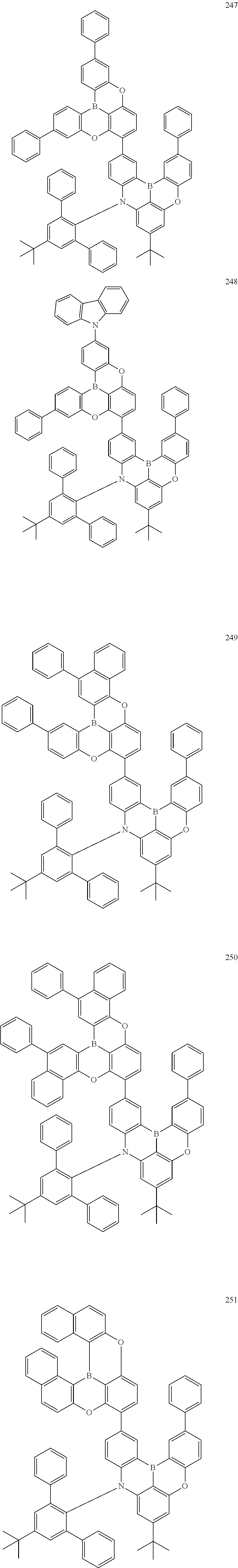 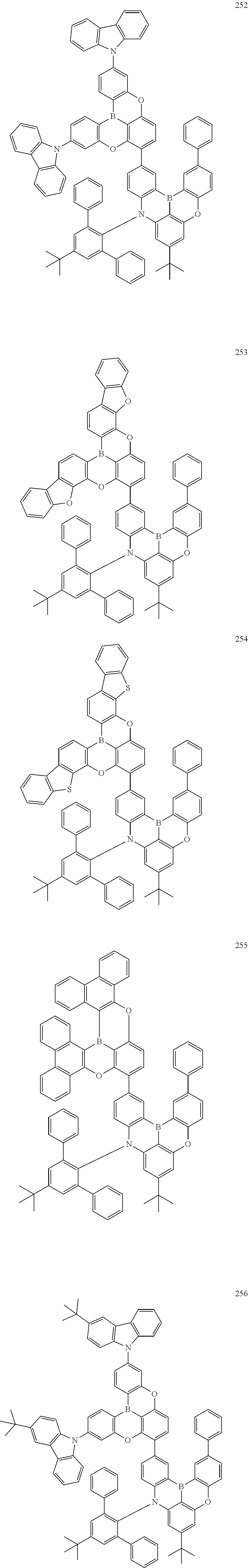 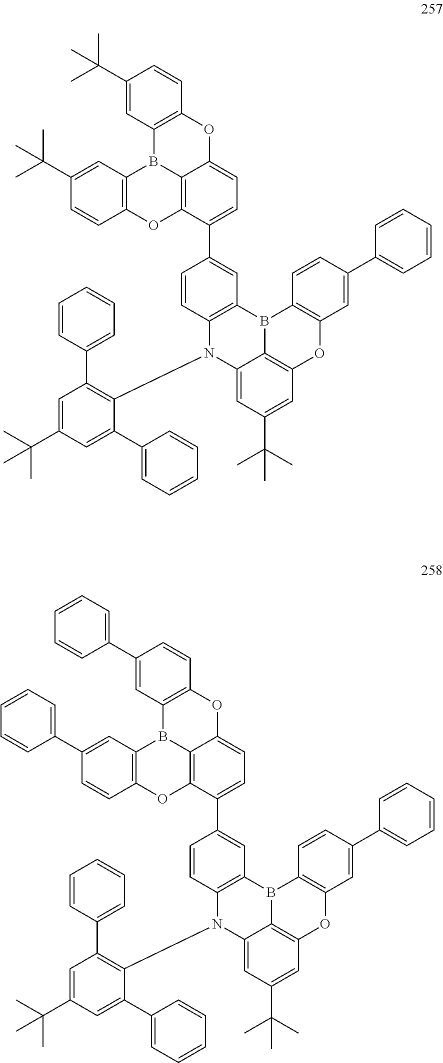 [SMILES: CC(C)(C)c1ccc2c(c1)B1c3cc(C(C)(C)C)ccc3Oc3c(-c4ccc5c(c4)B4c6ccc(-c7ccccc7)cc6Oc6cc(C(C)(C)C)cc(c64)N5c4c(-c5ccccc5)cc(C(C)(C)C)cc4-c4ccccc4)ccc(c31)O2 ; CC(C)(C)c1cc(-c2ccccc2)c(N2c3ccc(-c4ccc5c6c4Oc4ccc(-c7ccccc7)cc4B6c4cc(-c6ccccc6)ccc4O5)cc3B3c4ccc(-c5ccccc5)cc4Oc4cc(C(C)(C)C)cc2c43)c(-c2ccccc2)c1] 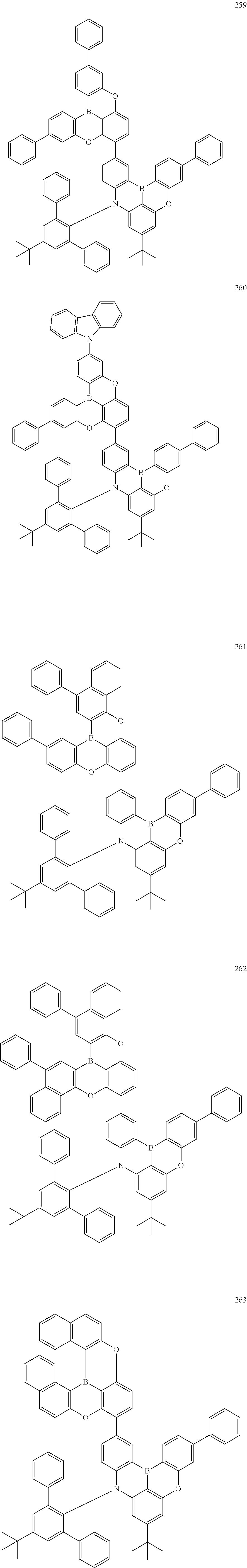 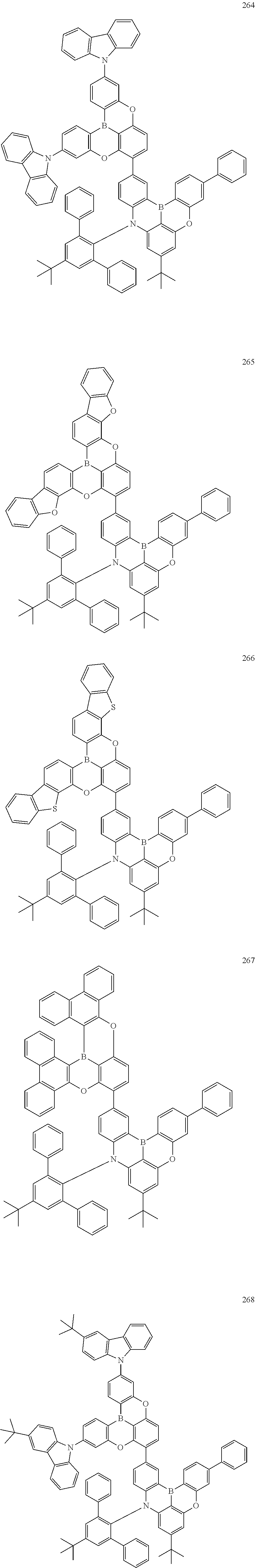 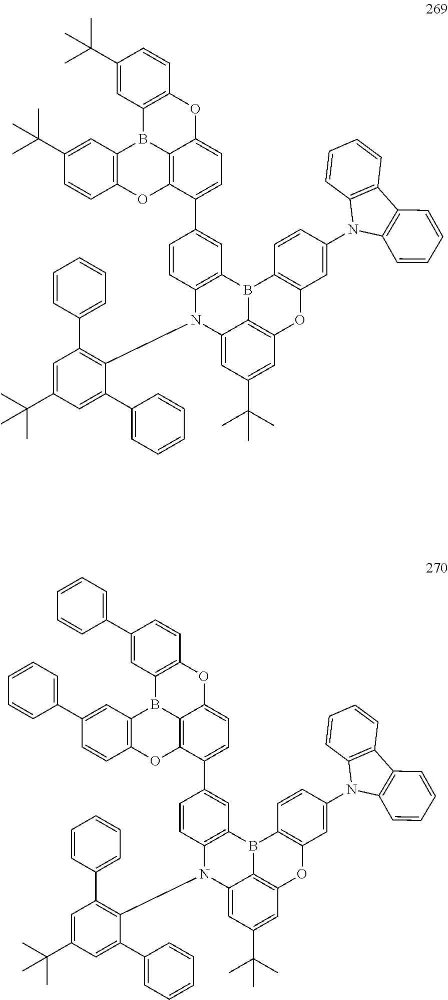 [SMILES: CC(C)(C)c1ccc2c(c1)B1c3cc(C(C)(C)C)ccc3Oc3c(-c4ccc5c(c4)B4c6ccc(-n7c8ccccc8c8ccccc87)cc6Oc6cc(C(C)(C)C)cc(c64)N5c4c(-c5ccccc5)cc(C(C)(C)C)cc4-c4ccccc4)ccc(c31)O2 ; CC(C)(C)c1cc(-c2ccccc2)c(N2c3ccc(-c4ccc5c6c4Oc4ccc(-c7ccccc7)cc4B6c4cc(-c6ccccc6)ccc4O5)cc3B3c4ccc(-n5c6ccccc6c6ccccc65)cc4Oc4cc(C(C)(C)C)cc2c43)c(-c2ccccc2)c1] 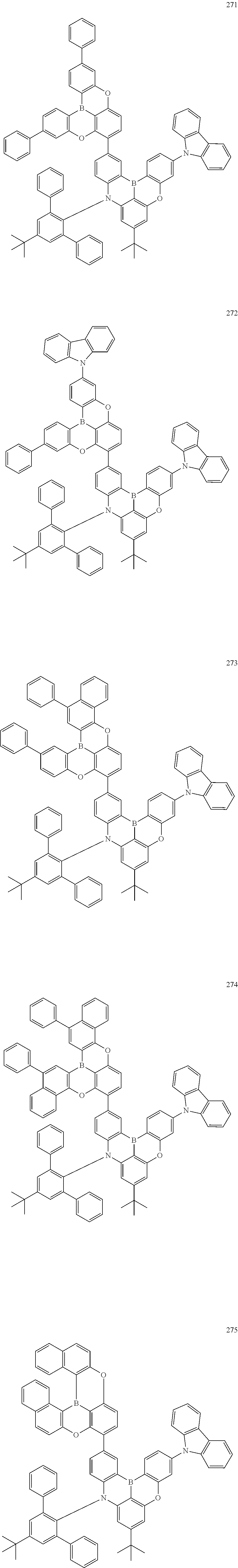 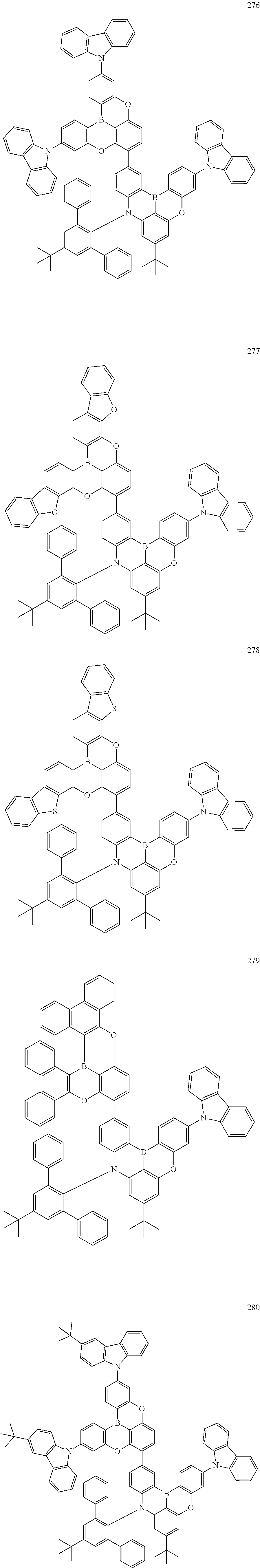 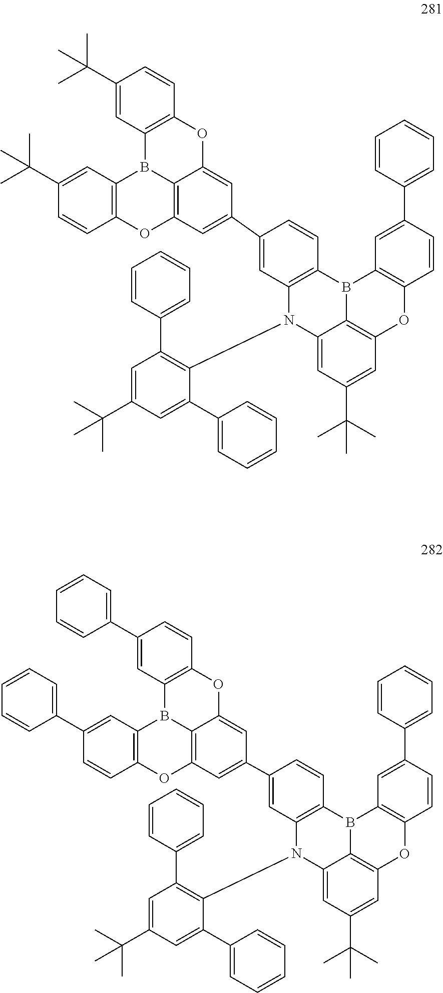 [SMILES: CC(C)(C)c1ccc2c(c1)B1c3cc(C(C)(C)C)ccc3Oc3cc(-c4ccc5c(c4)N(c4c(-c6ccccc6)cc(C(C)(C)C)cc4-c4ccccc4)c4cc(C(C)(C)C)cc6c4B5c4cc(-c5ccccc5)ccc4O6)cc(c31)O2 ; CC(C)(C)c1cc(-c2ccccc2)c(N2c3cc(-c4cc5c6c(c4)Oc4ccc(-c7ccccc7)cc4B6c4cc(-c6ccccc6)ccc4O5)ccc3B3c4cc(-c5ccccc5)ccc4Oc4cc(C(C)(C)C)cc2c43)c(-c2ccccc2)c1] 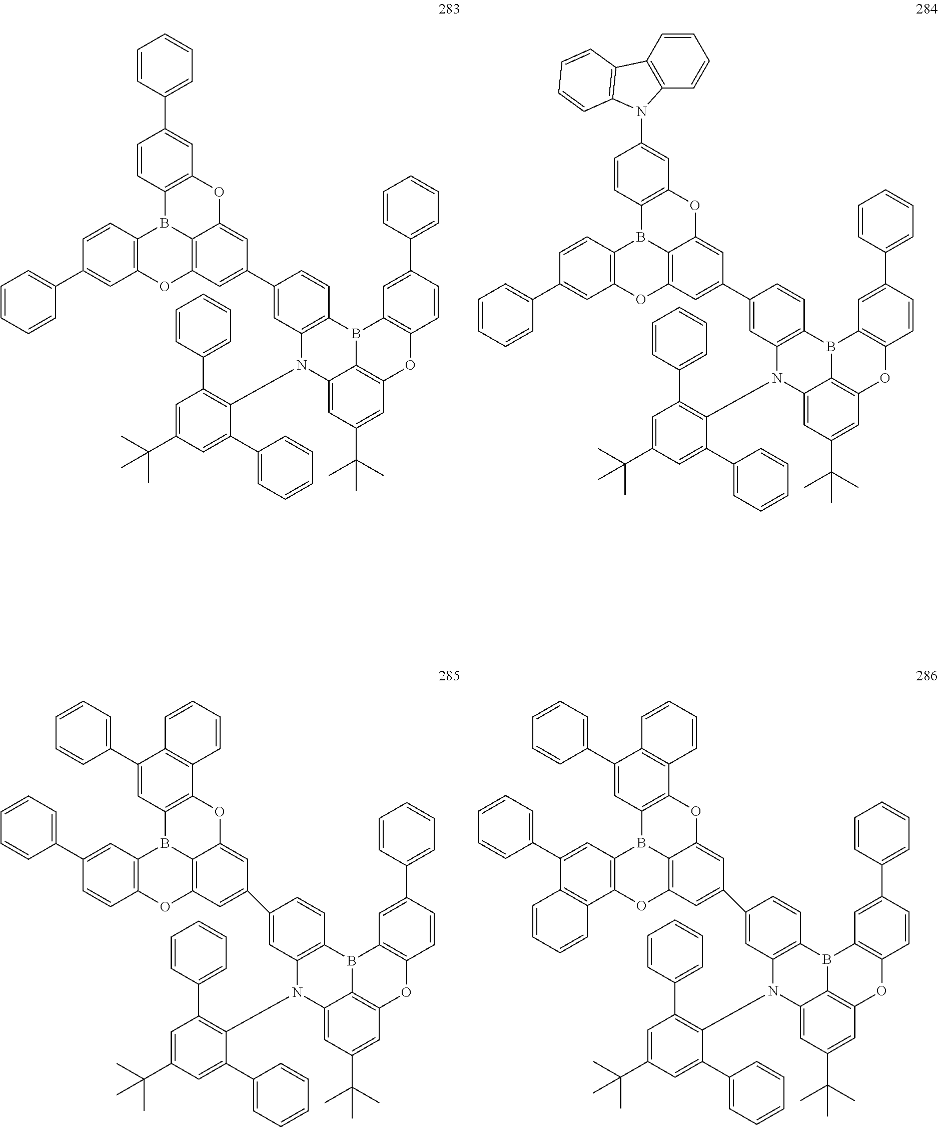 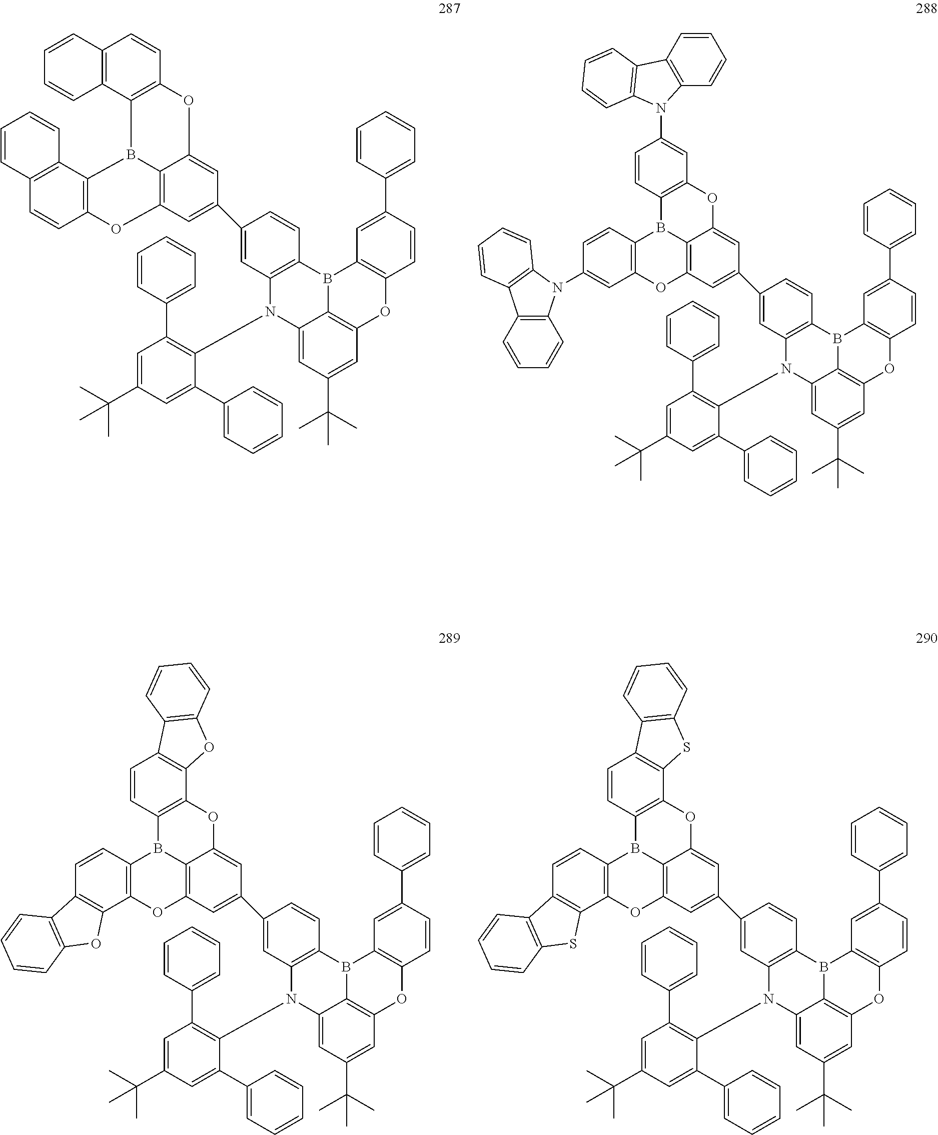 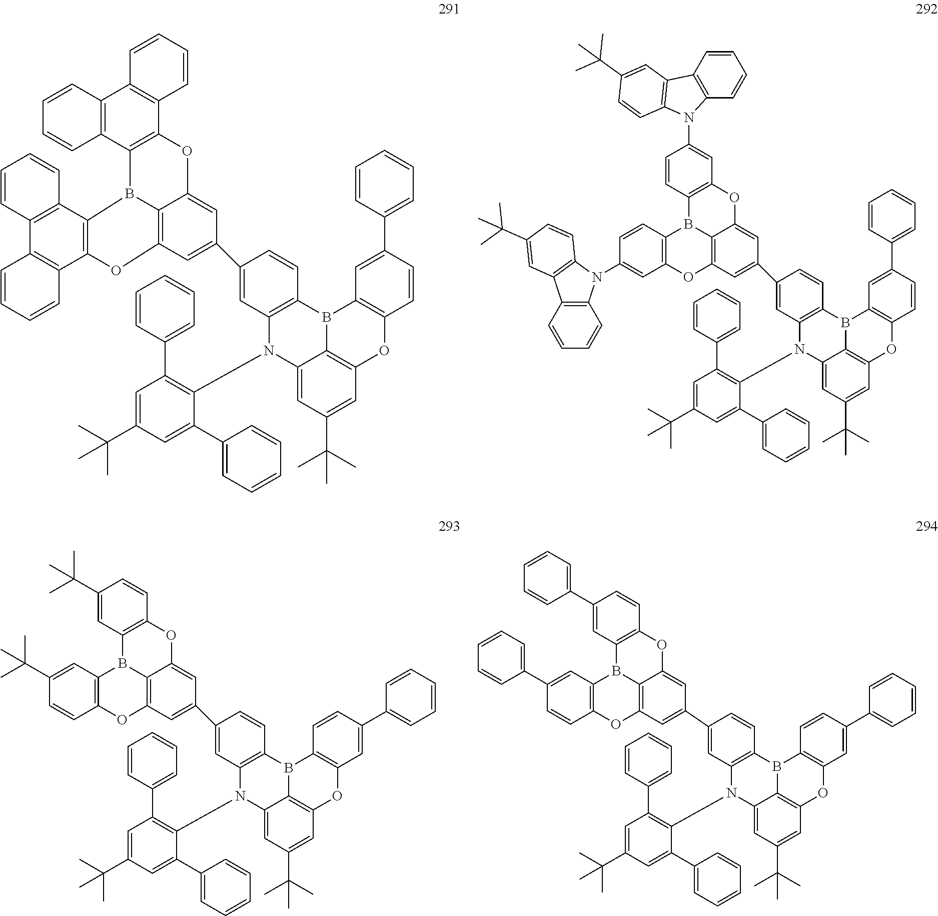 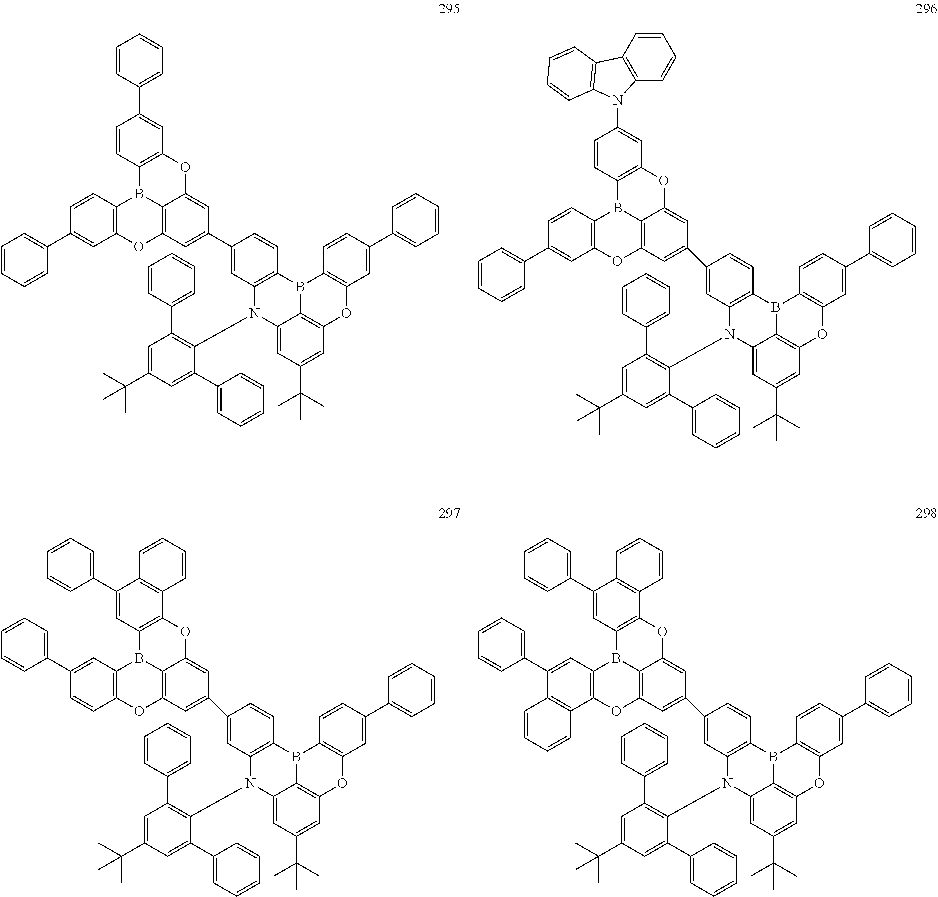 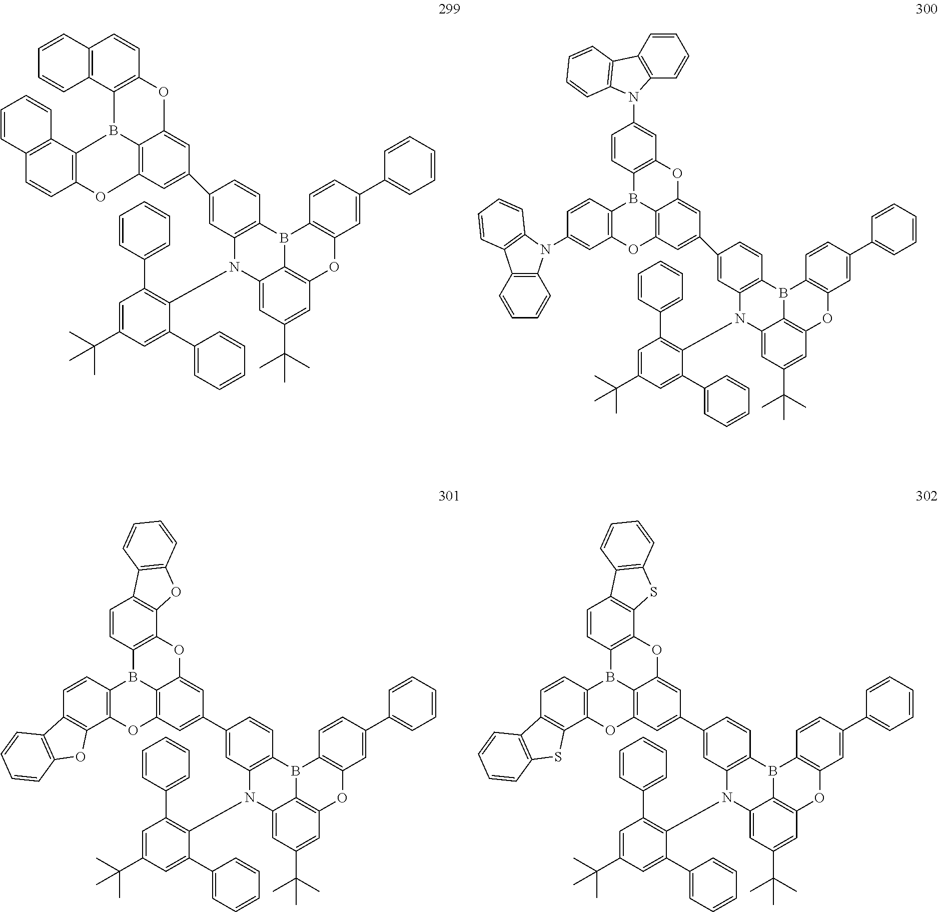 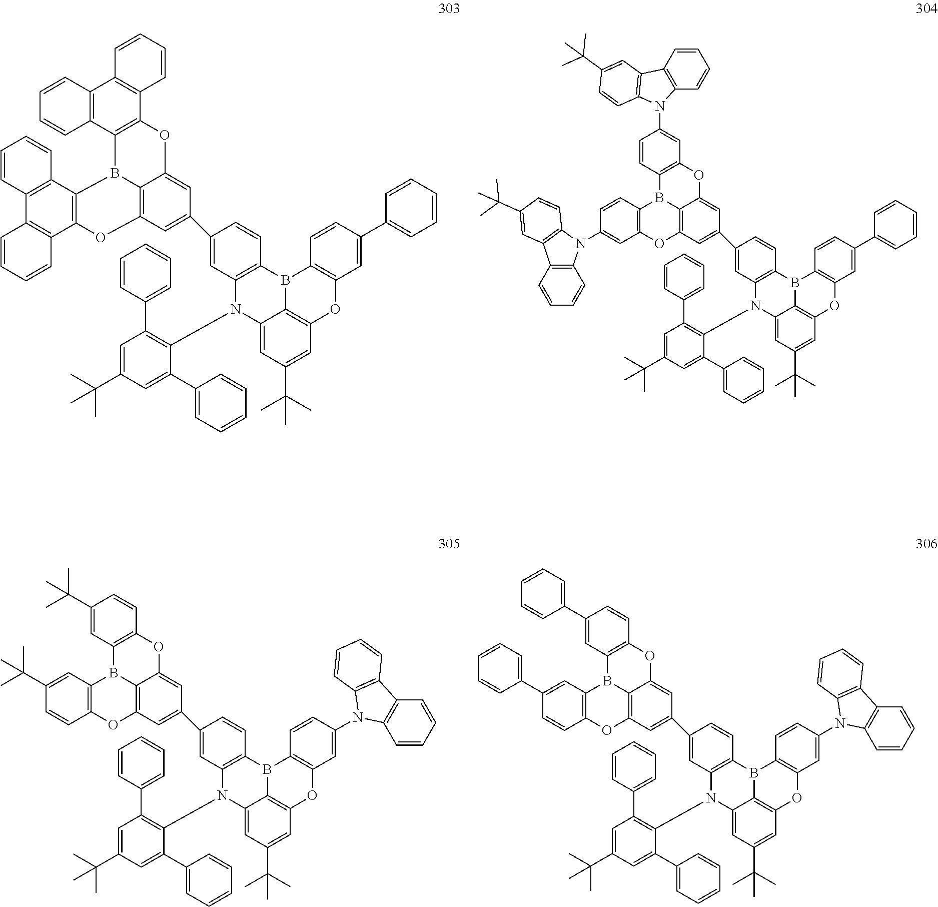 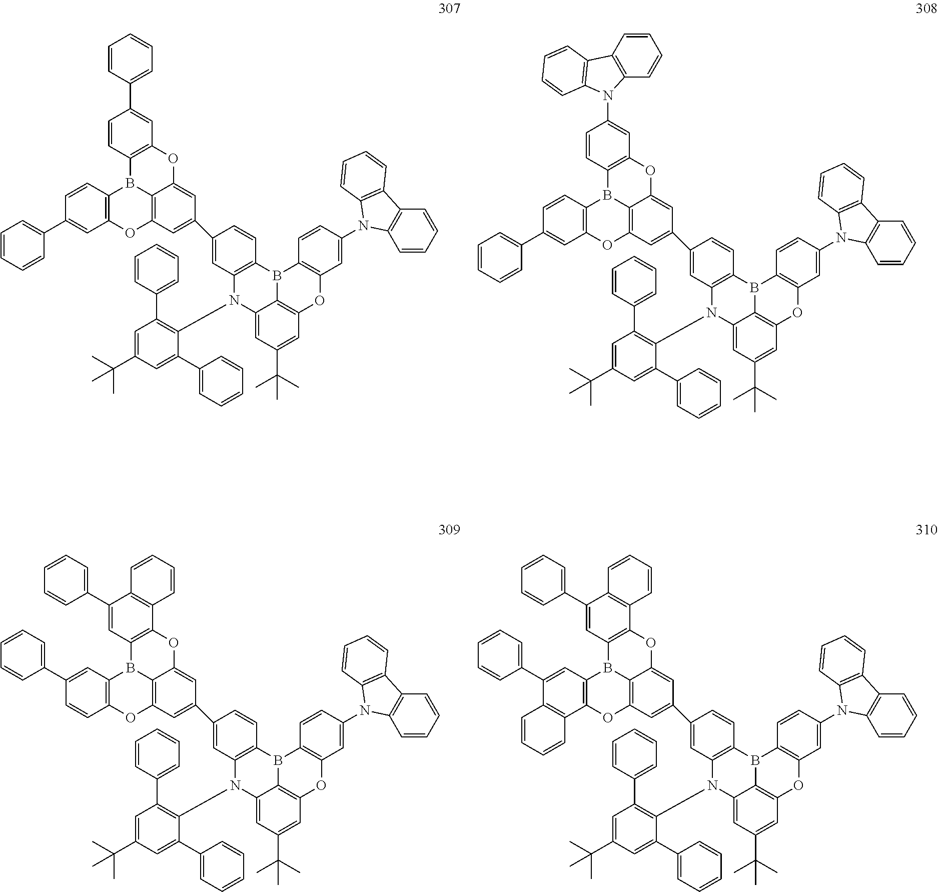 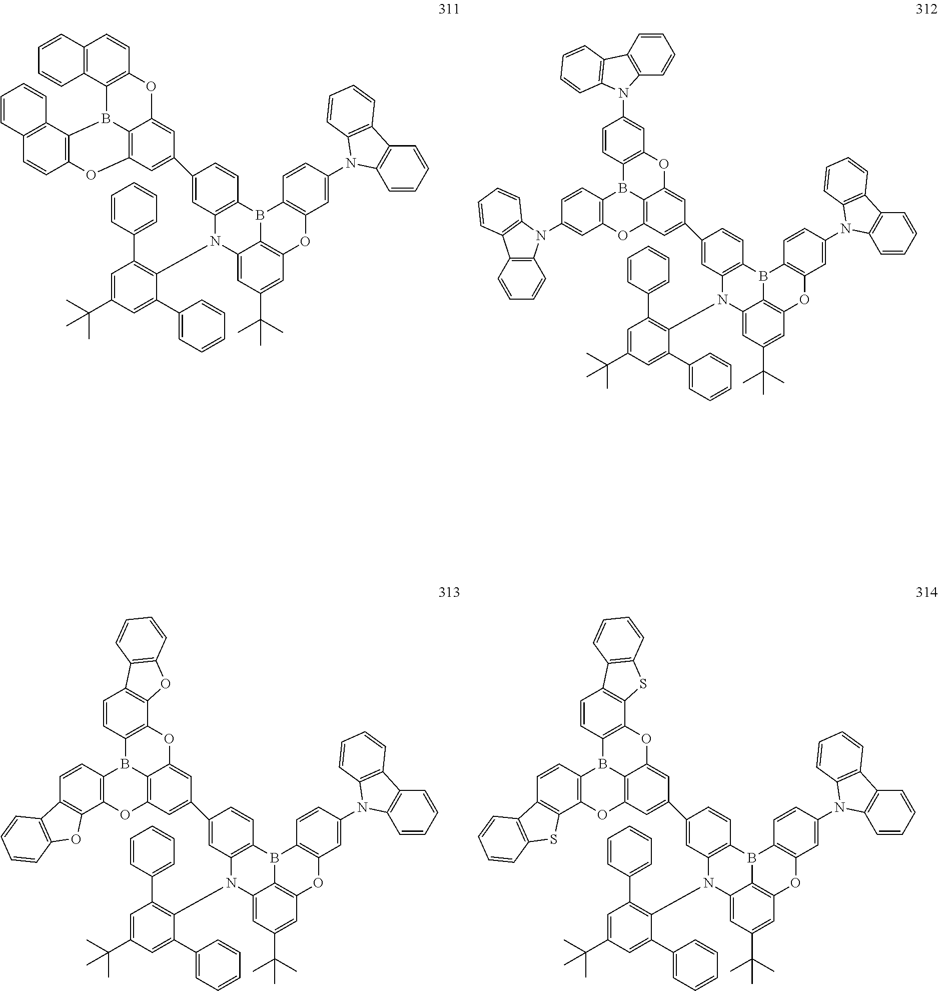 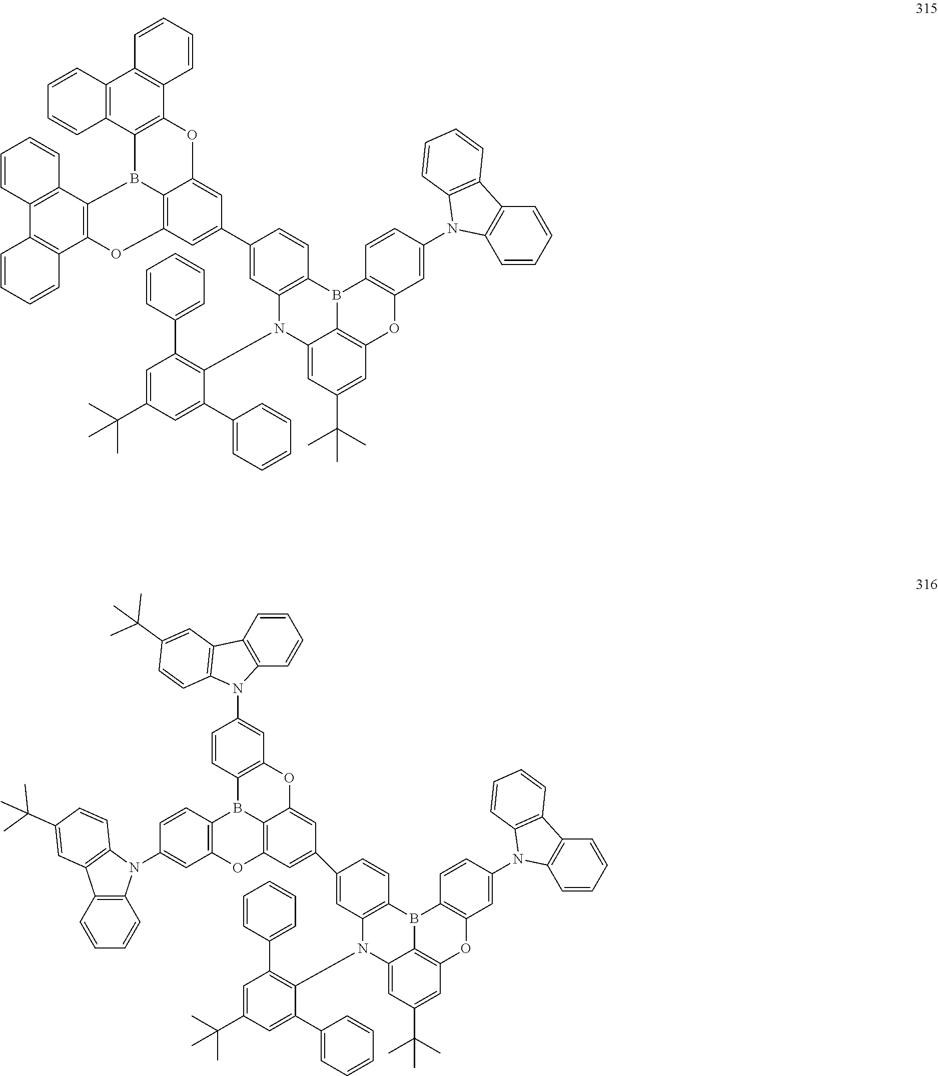 [SMILES: CC(C)(C)c1cc(-c2ccccc2)c(N2c3cc(-c4cc5c6c(c4)Oc4c(c7ccccc7c7ccccc47)B6c4c(c6ccccc6c6ccccc46)O5)ccc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4cc(-n7c8ccccc8c8cc(C(C)(C)C)ccc87)ccc4B6c4ccc(-n6c7ccccc7c7cc(C(C)(C)C)ccc76)cc4O5)ccc3B3c4ccc(-n5c6ccccc6c6ccccc65)cc4Oc4cc(C(C)(C)C)cc2c43)c(-c2ccccc2)c1] 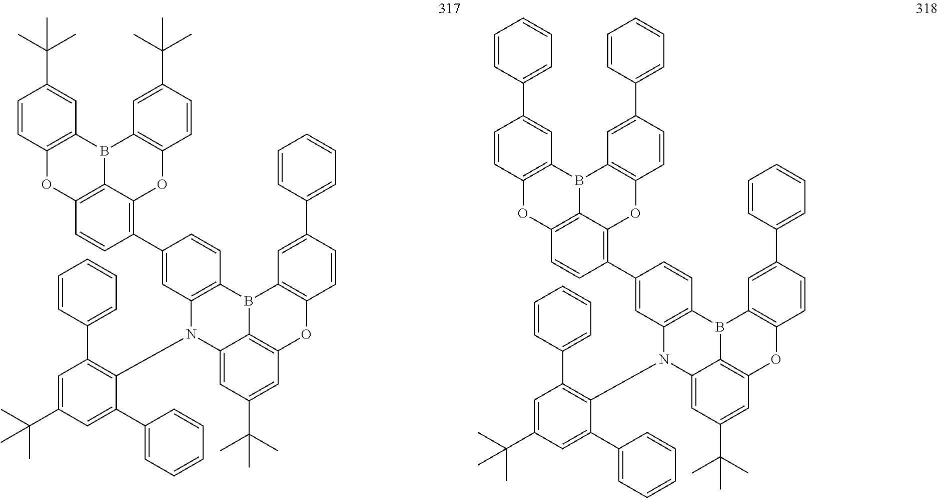 [SMILES: CC(C)(C)c1ccc2c(c1)B1c3cc(C(C)(C)C)ccc3Oc3c(-c4ccc5c(c4)N(c4c(-c6ccccc6)cc(C(C)(C)C)cc4-c4ccccc4)c4cc(C(C)(C)C)cc6c4B5c4cc(-c5ccccc5)ccc4O6)ccc(c31)O2 ; CC(C)(C)c1cc(-c2ccccc2)c(N2c3cc(-c4ccc5c6c4Oc4ccc(-c7ccccc7)cc4B6c4cc(-c6ccccc6)ccc4O5)ccc3B3c4cc(-c5ccccc5)ccc4Oc4cc(C(C)(C)C)cc2c43)c(-c2ccccc2)c1] 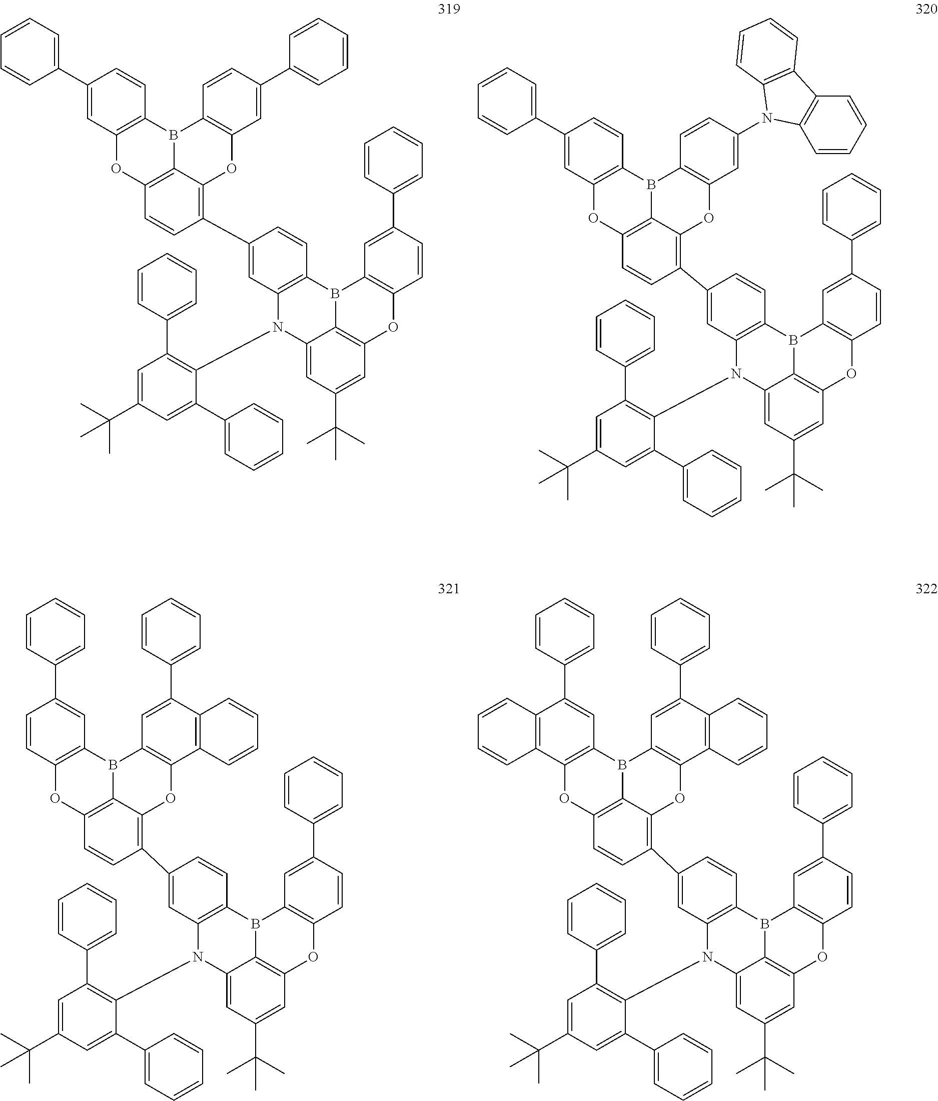 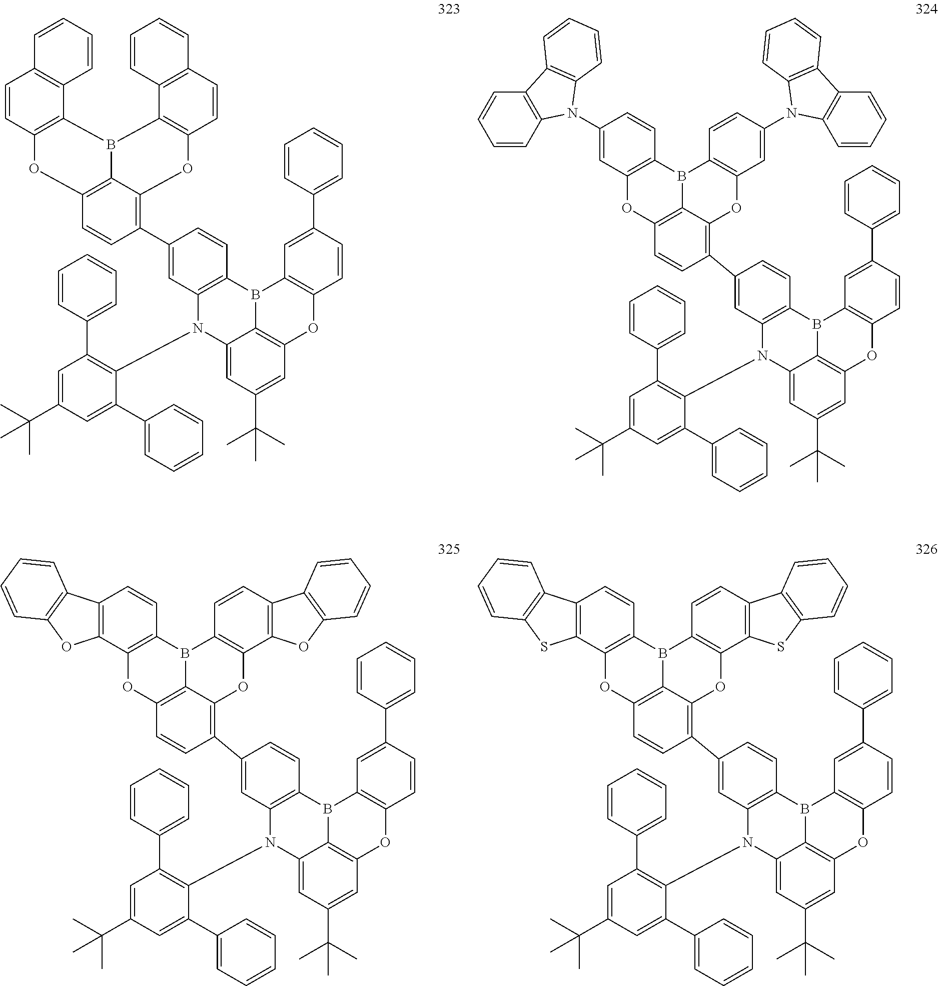 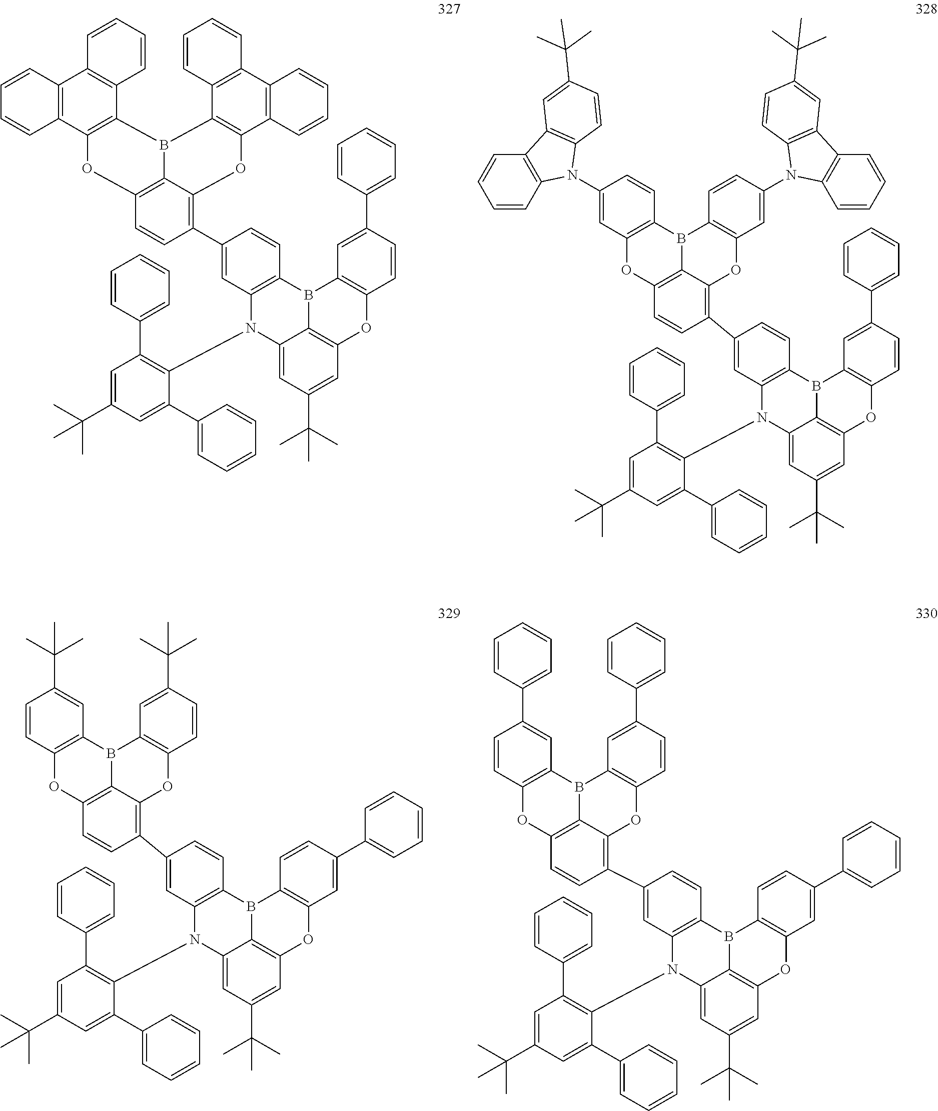 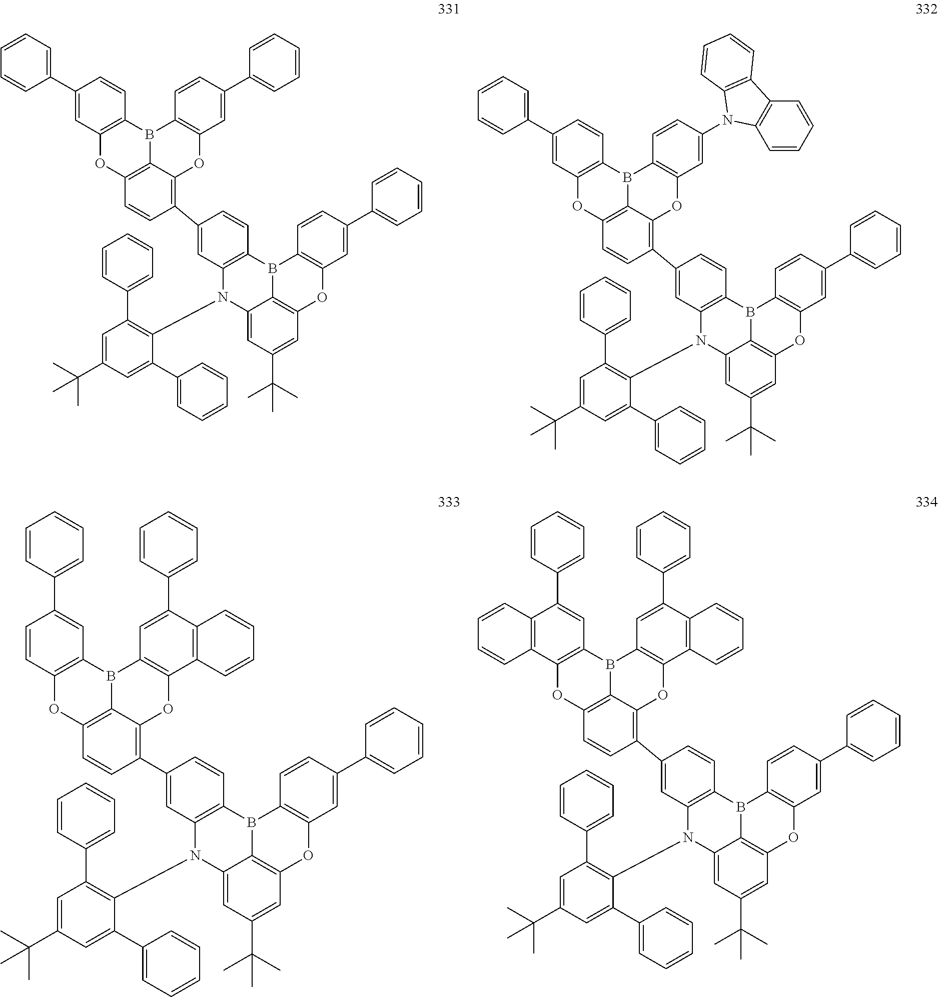 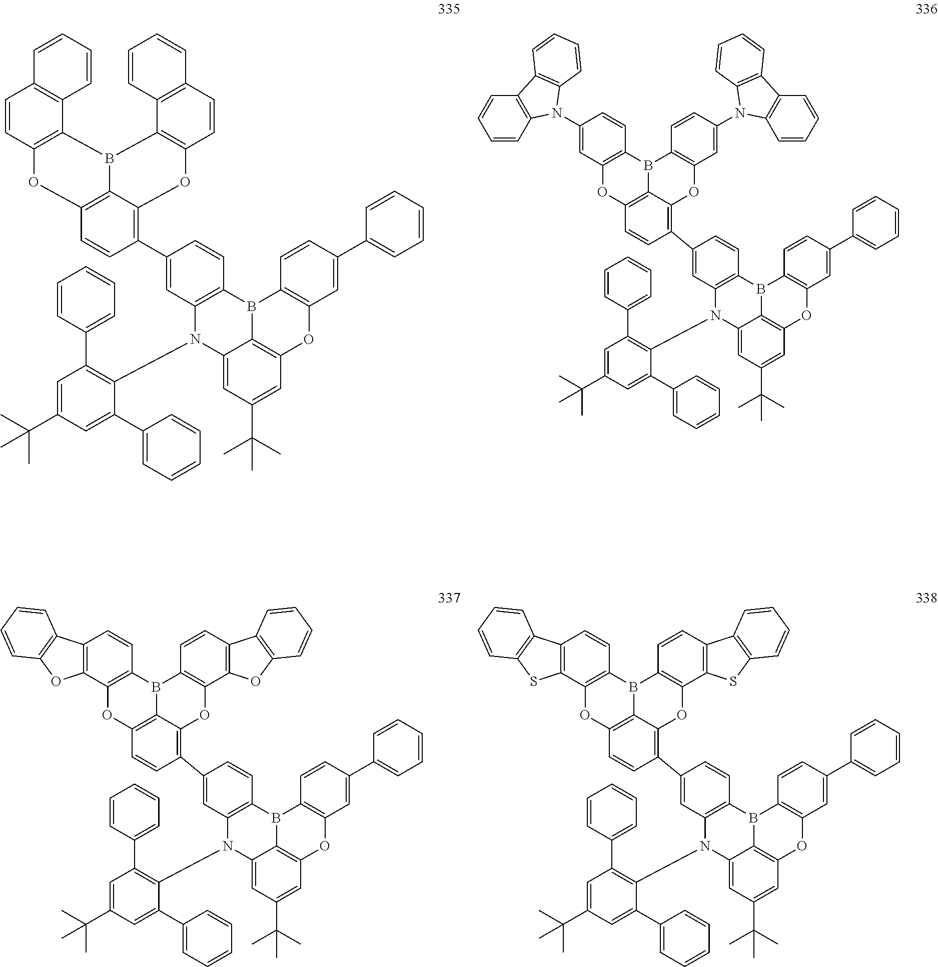 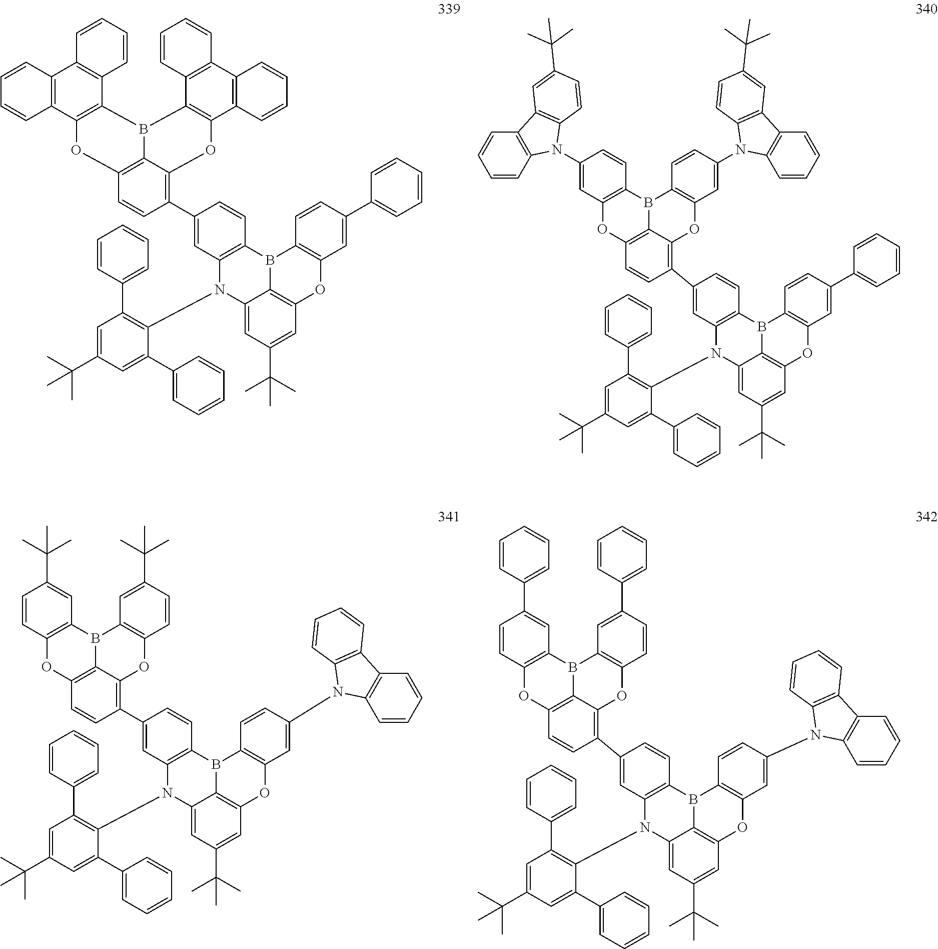 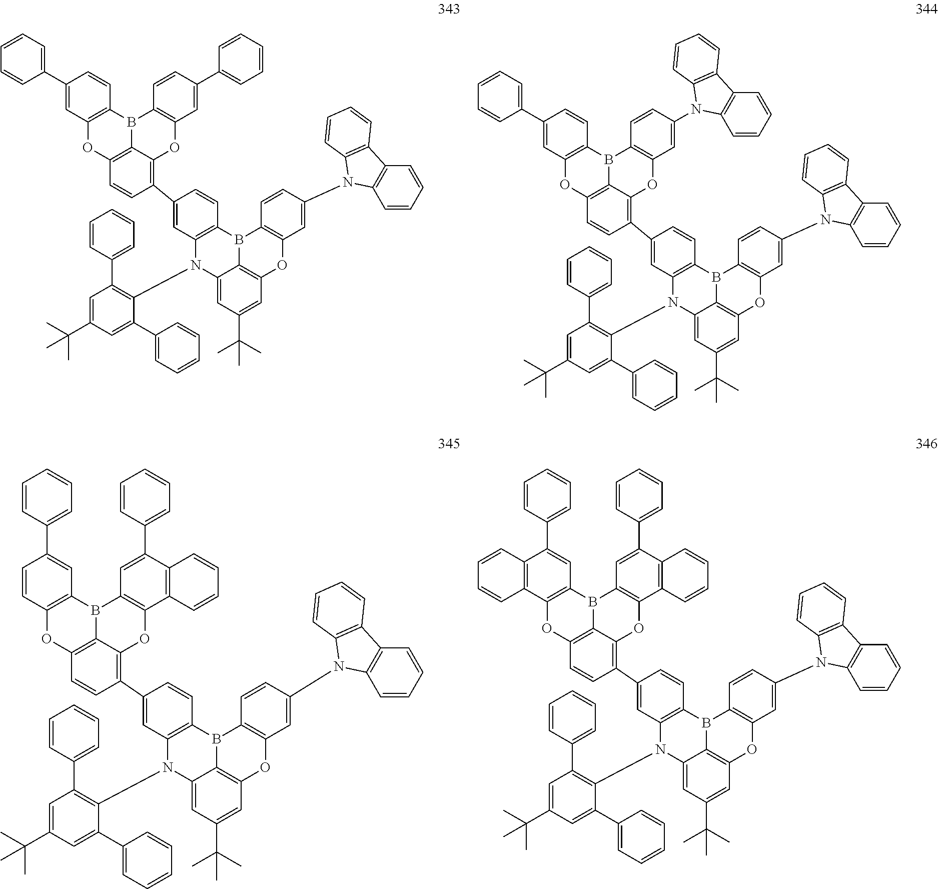 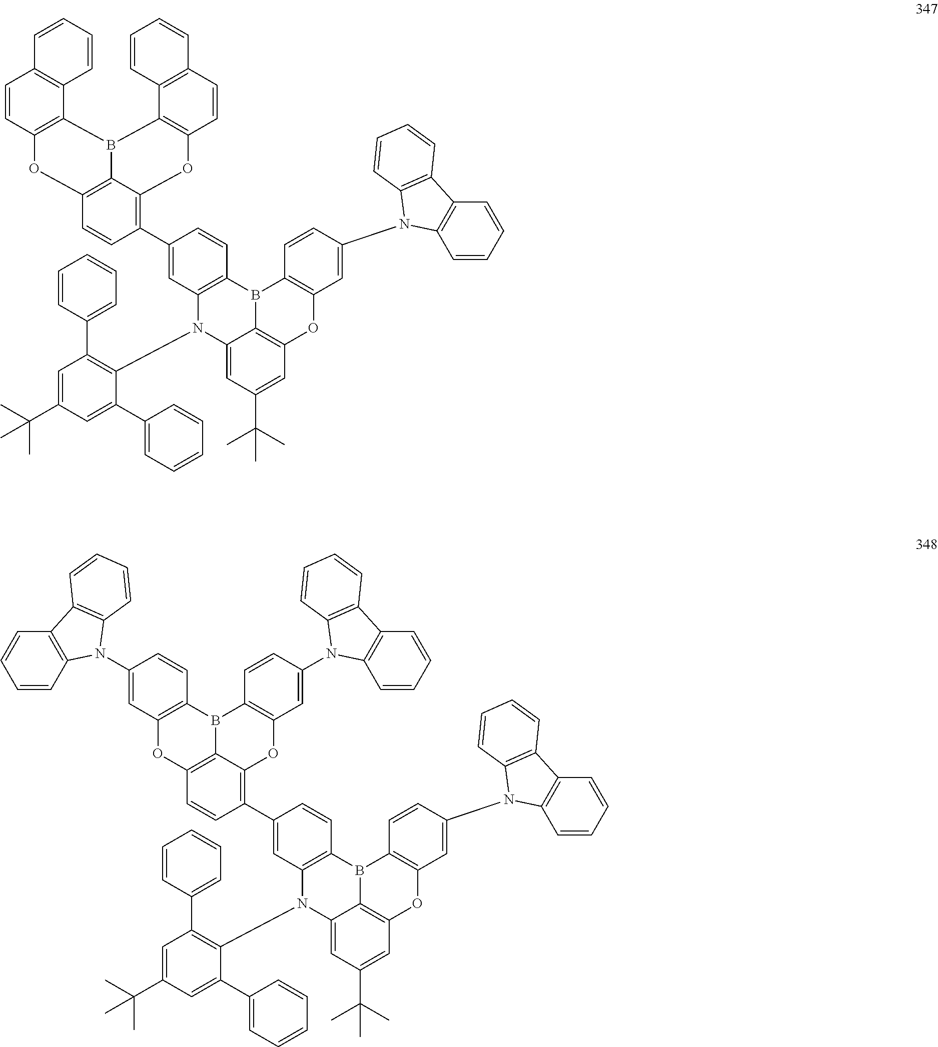 [SMILES: CC(C)(C)c1cc(-c2ccccc2)c(N2c3cc(-c4ccc5c6c4Oc4ccc7ccccc7c4B6c4c(ccc6ccccc46)O5)ccc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3cc(-c4ccc5c6c4Oc4cc(-n7c8ccccc8c8ccccc87)ccc4B6c4ccc(-n6c7ccccc7c7ccccc76)cc4O5)ccc3B3c4ccc(-n5c6ccccc6c6ccccc65)cc4Oc4cc(C(C)(C)C)cc2c43)c(-c2ccccc2)c1] 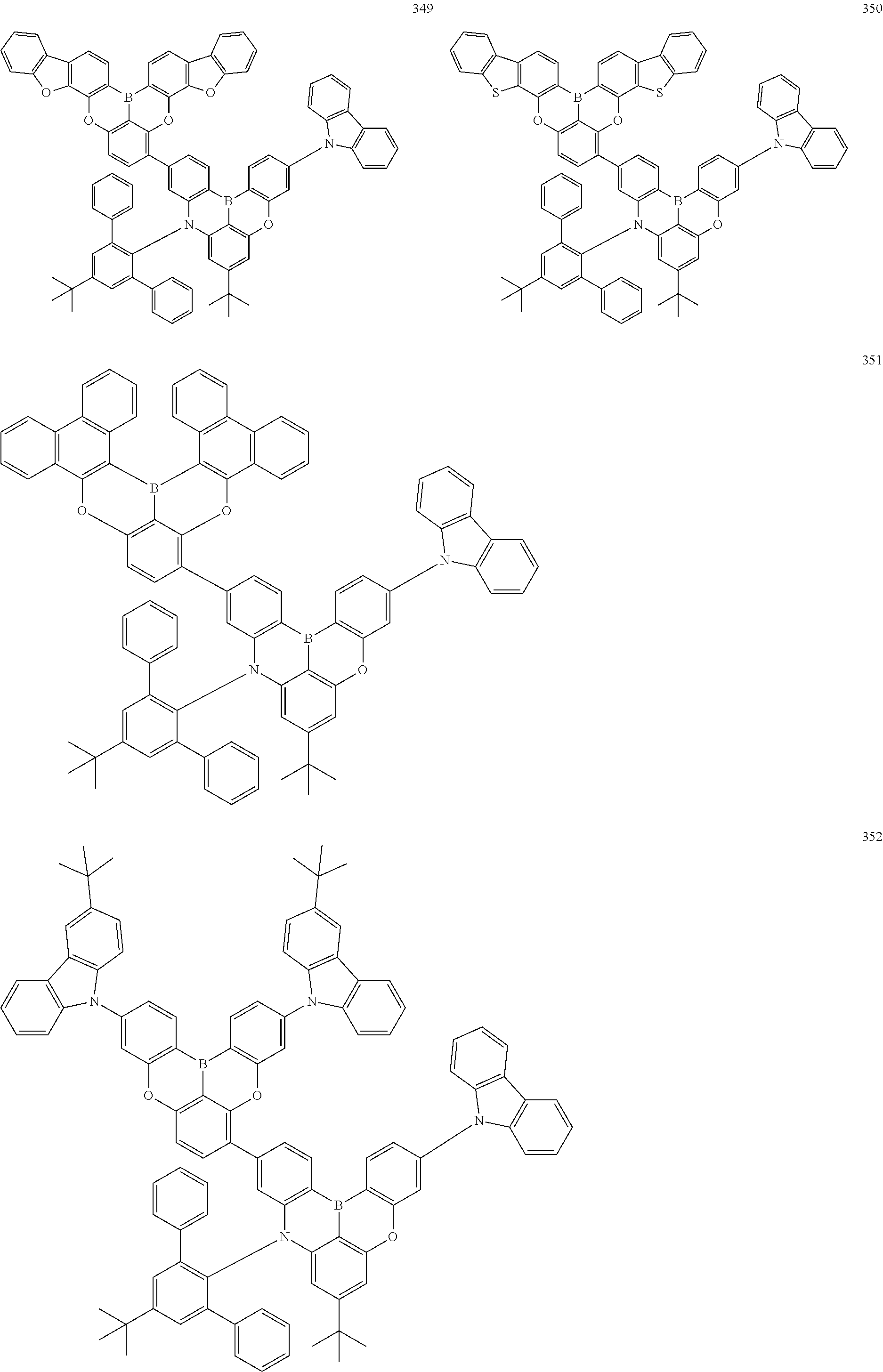 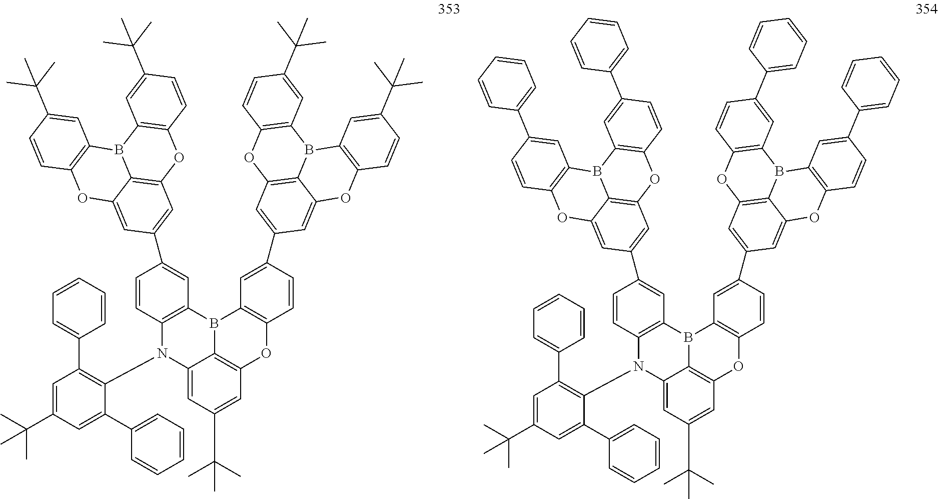 [SMILES: CC(C)(C)c1ccc2c(c1)B1c3cc(C(C)(C)C)ccc3Oc3cc(-c4ccc5c(c4)B4c6cc(-c7cc8c9c(c7)Oc7ccc(C(C)(C)C)cc7B9c7cc(C(C)(C)C)ccc7O8)ccc6N(c6c(-c7ccccc7)cc(C(C)(C)C)cc6-c6ccccc6)c6cc(C(C)(C)C)cc(c64)O5)cc(c31)O2 ; CC(C)(C)c1cc(-c2ccccc2)c(N2c3ccc(-c4cc5c6c(c4)Oc4ccc(-c7ccccc7)cc4B6c4cc(-c6ccccc6)ccc4O5)cc3B3c4cc(-c5cc6c7c(c5)Oc5ccc(-c8ccccc8)cc5B7c5cc(-c7ccccc7)ccc5O6)ccc4Oc4cc(C(C)(C)C)cc2c43)c(-c2ccccc2)c1] 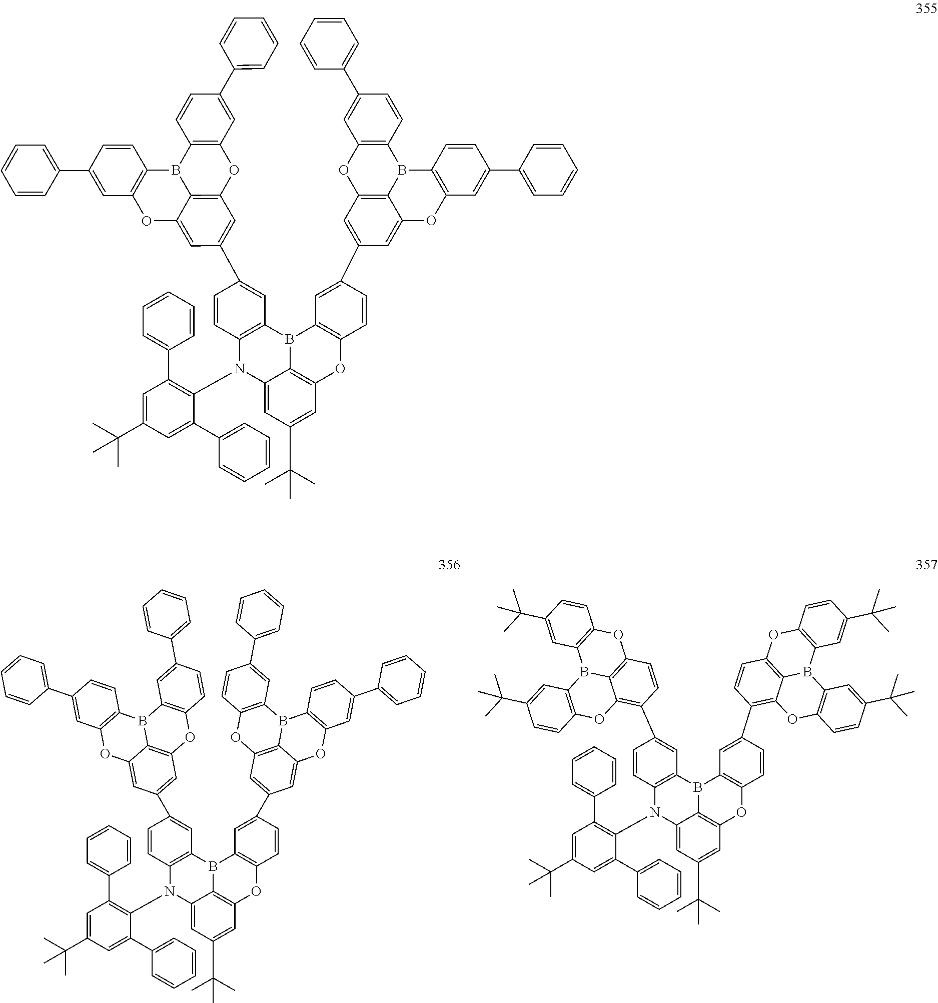 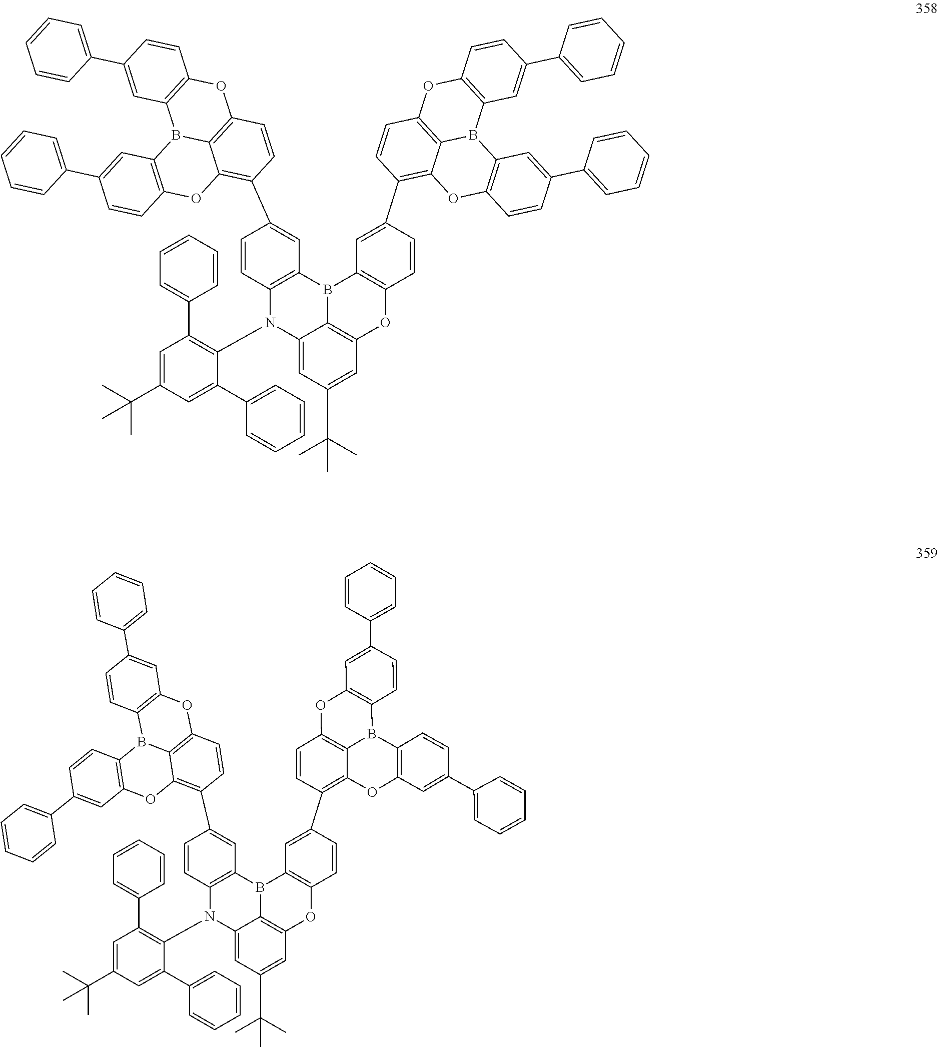 [SMILES: CC(C)(C)c1cc(-c2ccccc2)c(N2c3ccc(-c4ccc5c6c4Oc4ccc(-c7ccccc7)cc4B6c4cc(-c6ccccc6)ccc4O5)cc3B3c4cc(-c5ccc6c7c5Oc5ccc(-c8ccccc8)cc5B7c5cc(-c7ccccc7)ccc5O6)ccc4Oc4cc(C(C)(C)C)cc2c43)c(-c2ccccc2)c1 ; CC(C)(C)c1cc(-c2ccccc2)c(N2c3ccc(-c4ccc5c6c4Oc4cc(-c7ccccc7)ccc4B6c4ccc(-c6ccccc6)cc4O5)cc3B3c4cc(-c5ccc6c7c5Oc5cc(-c8ccccc8)ccc5B7c5ccc(-c7ccccc7)cc5O6)ccc4Oc4cc(C(C)(C)C)cc2c43)c(-c2ccccc2)c1] 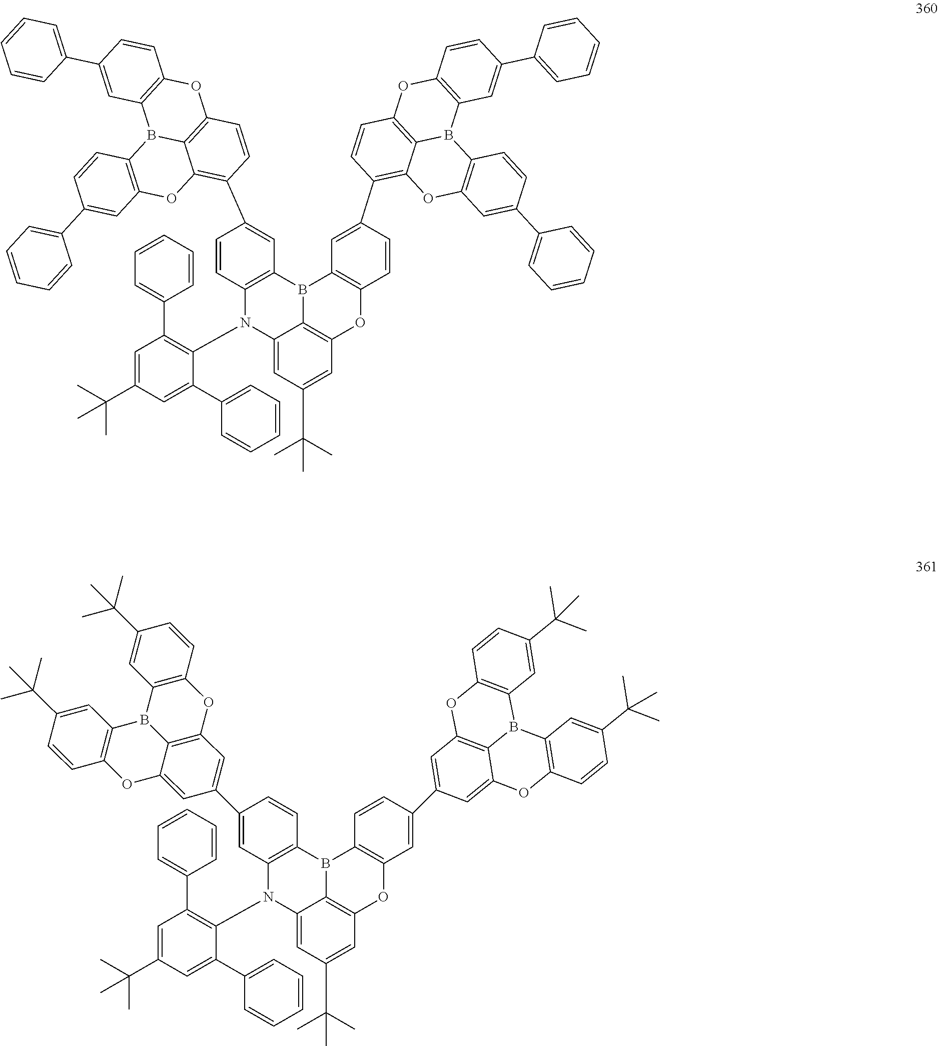 [SMILES: CC(C)(C)c1cc(-c2ccccc2)c(N2c3ccc(-c4ccc5c6c4Oc4cc(-c7ccccc7)ccc4B6c4cc(-c6ccccc6)ccc4O5)cc3B3c4cc(-c5ccc6c7c5Oc5cc(-c8ccccc8)ccc5B7c5cc(-c7ccccc7)ccc5O6)ccc4Oc4cc(C(C)(C)C)cc2c43)c(-c2ccccc2)c1 ; CC(C)(C)c1ccc2c(c1)B1c3cc(C(C)(C)C)ccc3Oc3cc(-c4ccc5c(c4)Oc4cc(C(C)(C)C)cc6c4B5c4ccc(-c5cc7c8c(c5)Oc5ccc(C(C)(C)C)cc5B8c5cc(C(C)(C)C)ccc5O7)cc4N6c4c(-c5ccccc5)cc(C(C)(C)C)cc4-c4ccccc4)cc(c31)O2] 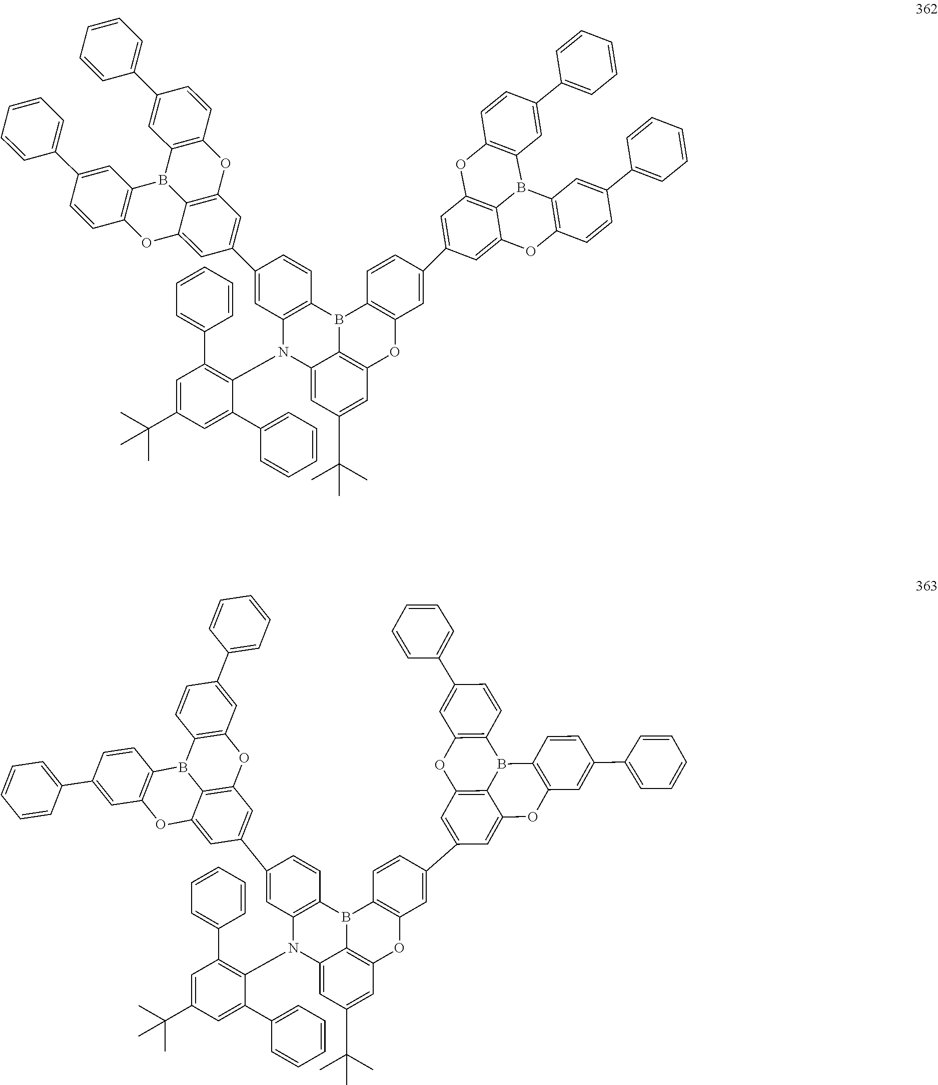 [SMILES: CC(C)(C)c1cc(-c2ccccc2)c(N2c3cc(-c4cc5c6c(c4)Oc4ccc(-c7ccccc7)cc4B6c4cc(-c6ccccc6)ccc4O5)ccc3B3c4ccc(-c5cc6c7c(c5)Oc5ccc(-c8ccccc8)cc5B7c5cc(-c7ccccc7)ccc5O6)cc4Oc4cc(C(C)(C)C)cc2c43)c(-c2ccccc2)c1 ; CC(C)(C)c1cc(-c2ccccc2)c(N2c3cc(-c4cc5c6c(c4)Oc4cc(-c7ccccc7)ccc4B6c4ccc(-c6ccccc6)cc4O5)ccc3B3c4ccc(-c5cc6c7c(c5)Oc5cc(-c8ccccc8)ccc5B7c5ccc(-c7ccccc7)cc5O6)cc4Oc4cc(C(C)(C)C)cc2c43)c(-c2ccccc2)c1] 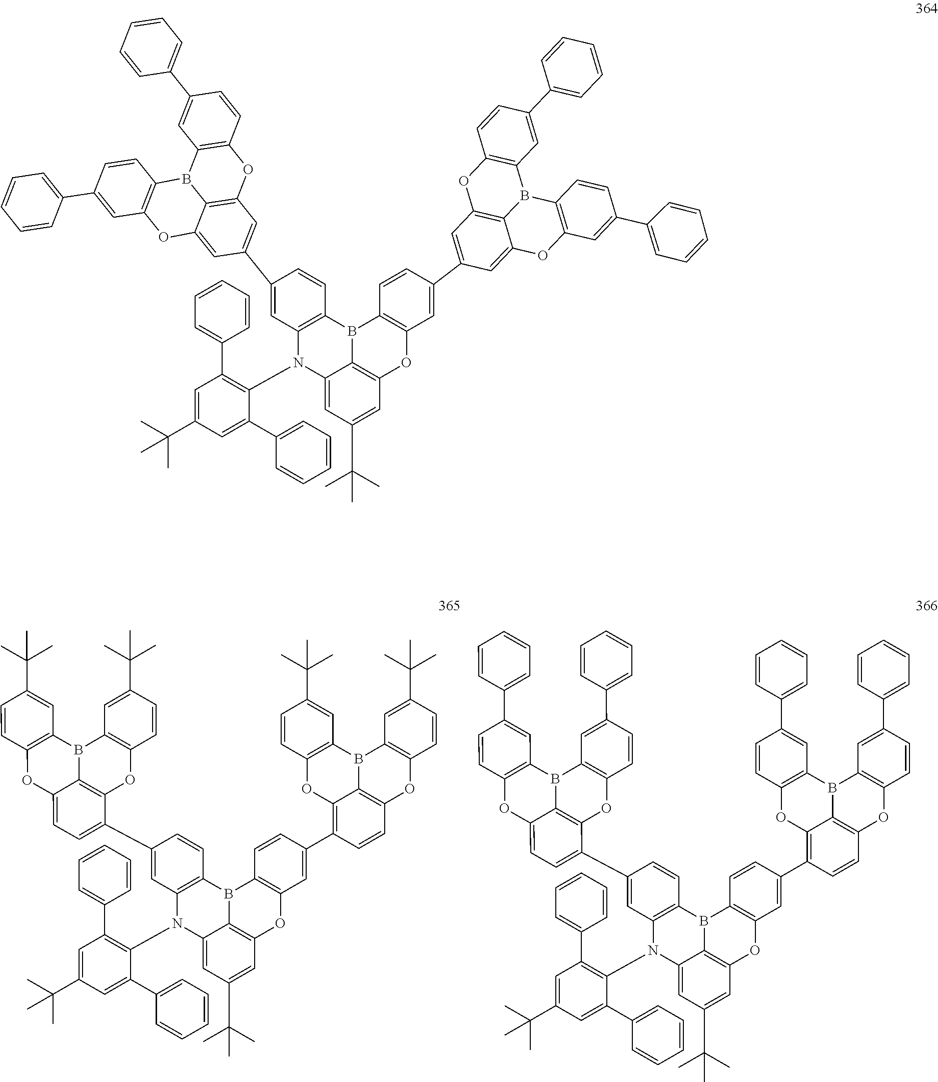 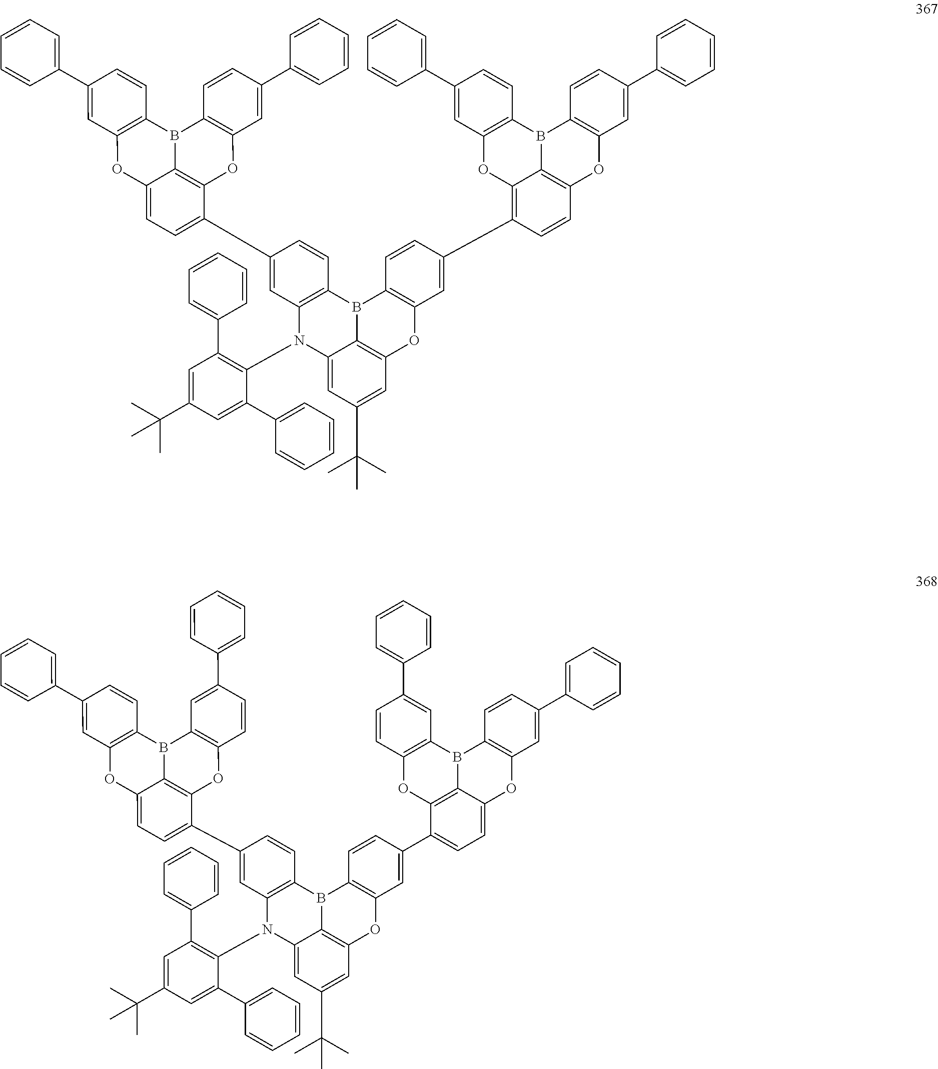 [SMILES: CC(C)(C)c1cc(-c2ccccc2)c(N2c3cc(-c4ccc5c6c4Oc4cc(-c7ccccc7)ccc4B6c4ccc(-c6ccccc6)cc4O5)ccc3B3c4ccc(-c5ccc6c7c5Oc5cc(-c8ccccc8)ccc5B7c5ccc(-c7ccccc7)cc5O6)cc4Oc4cc(C(C)(C)C)cc2c43)c(-c2ccccc2)c1 ; CC(C)(C)c1cc(-c2ccccc2)c(N2c3cc(-c4ccc5c6c4Oc4ccc(-c7ccccc7)cc4B6c4ccc(-c6ccccc6)cc4O5)ccc3B3c4ccc(-c5ccc6c7c5Oc5ccc(-c8ccccc8)cc5B7c5ccc(-c7ccccc7)cc5O6)cc4Oc4cc(C(C)(C)C)cc2c43)c(-c2ccccc2)c1] 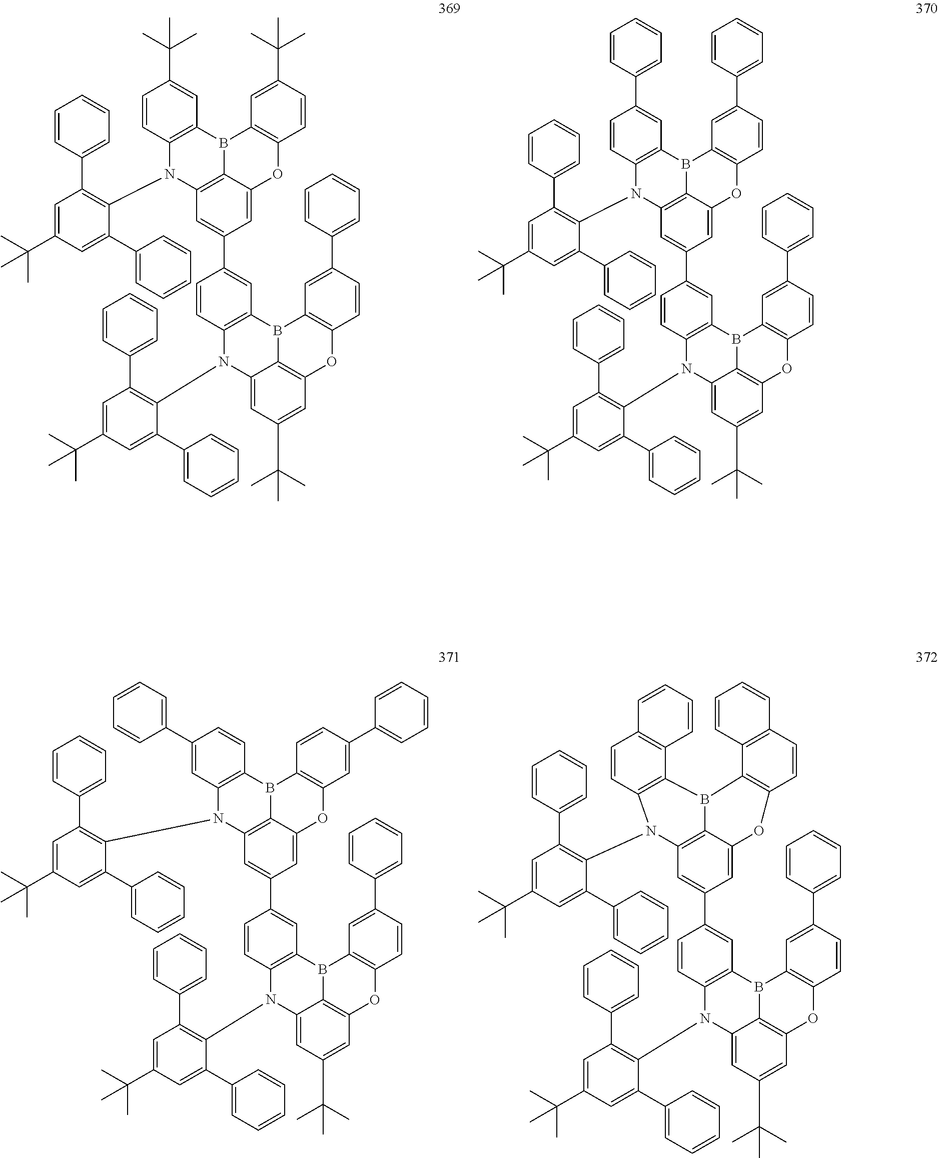 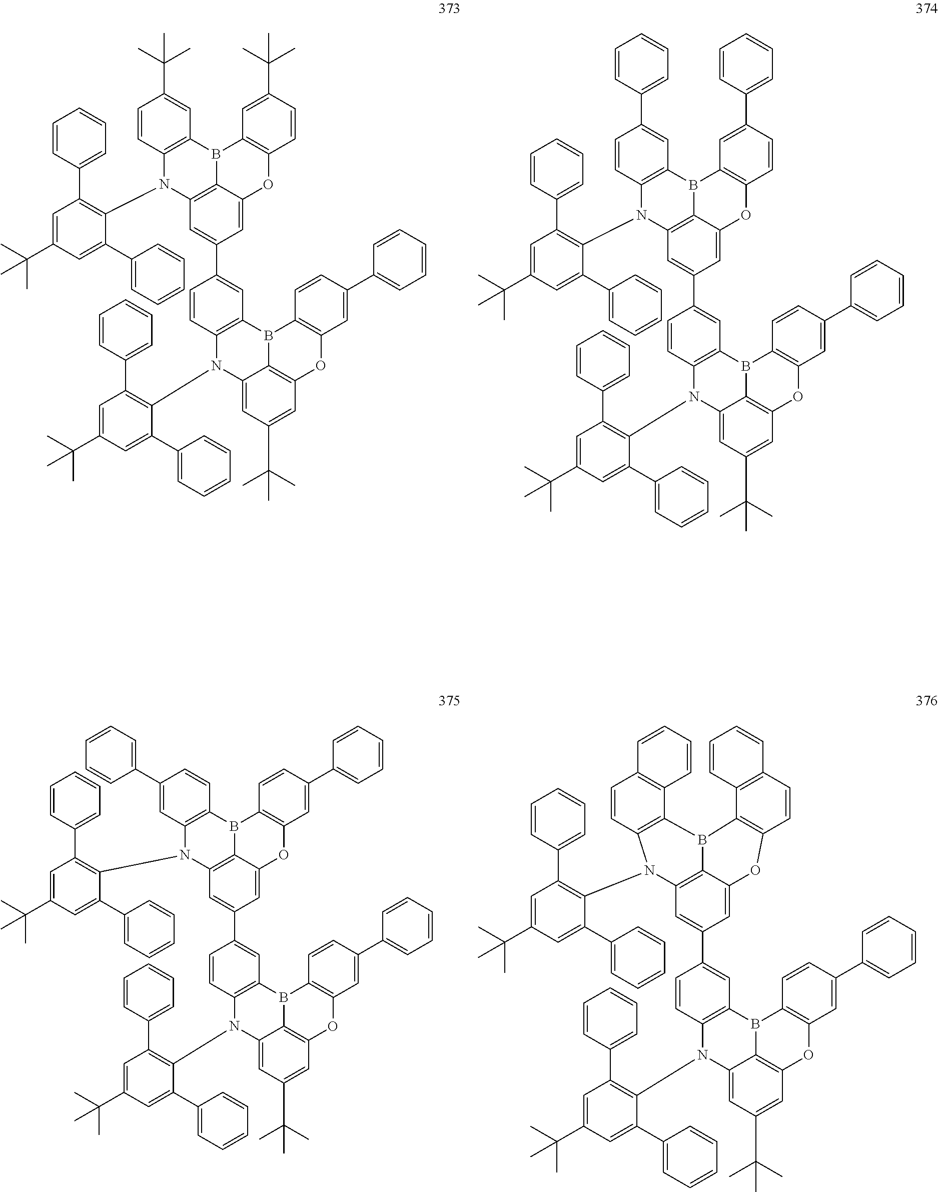 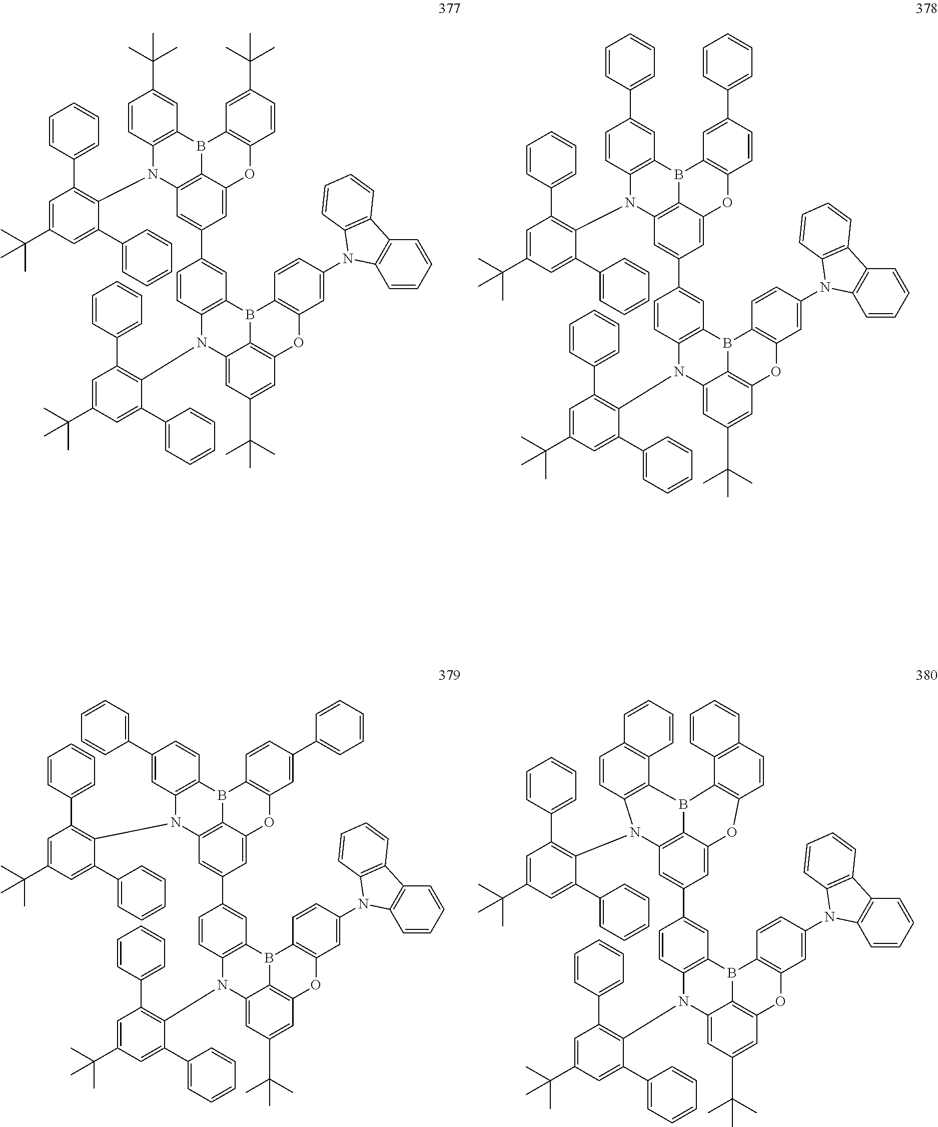 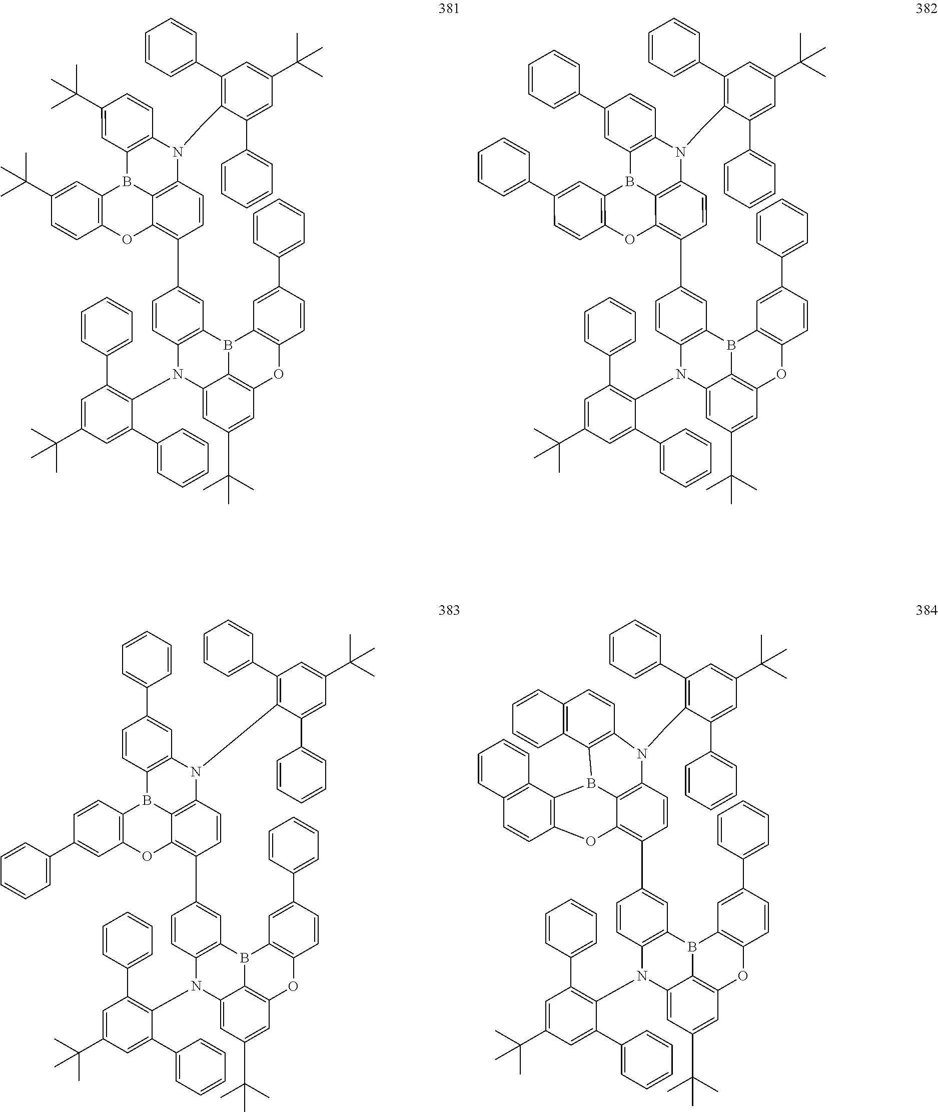 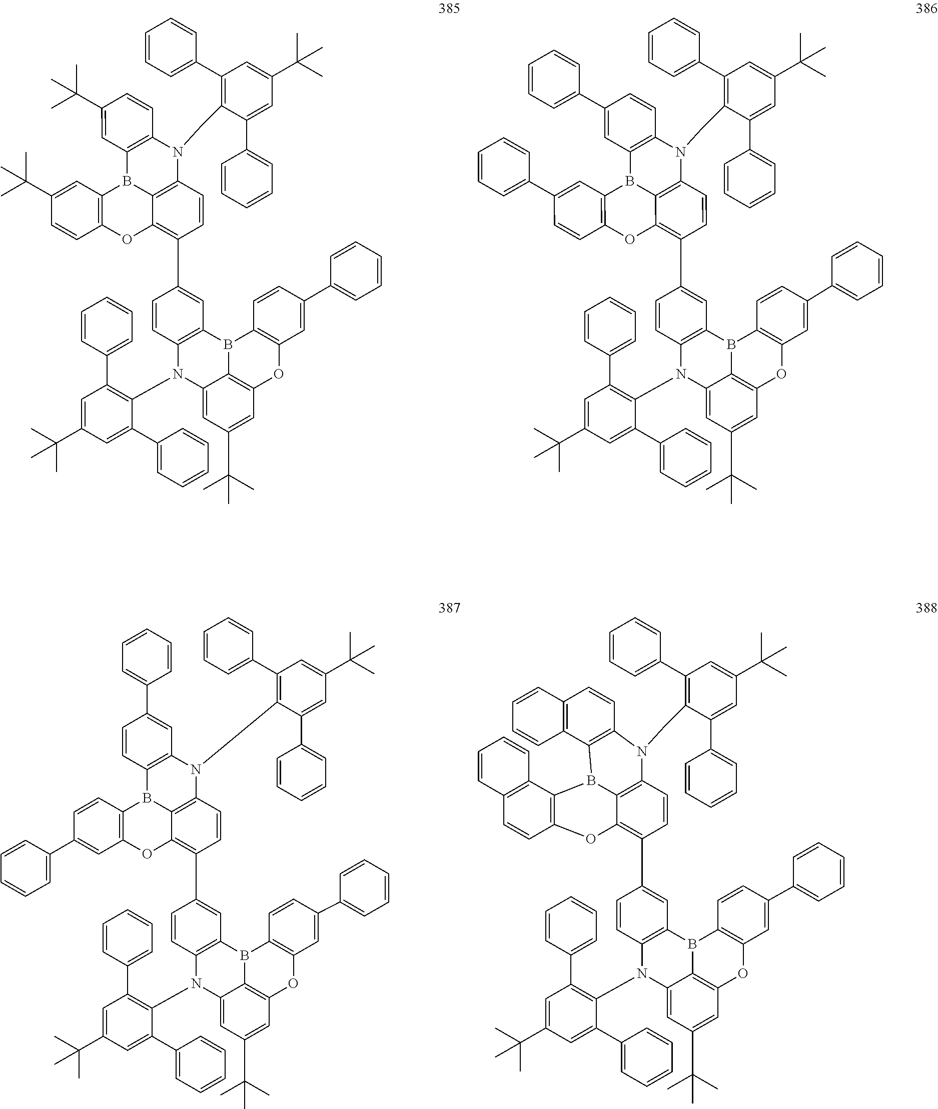 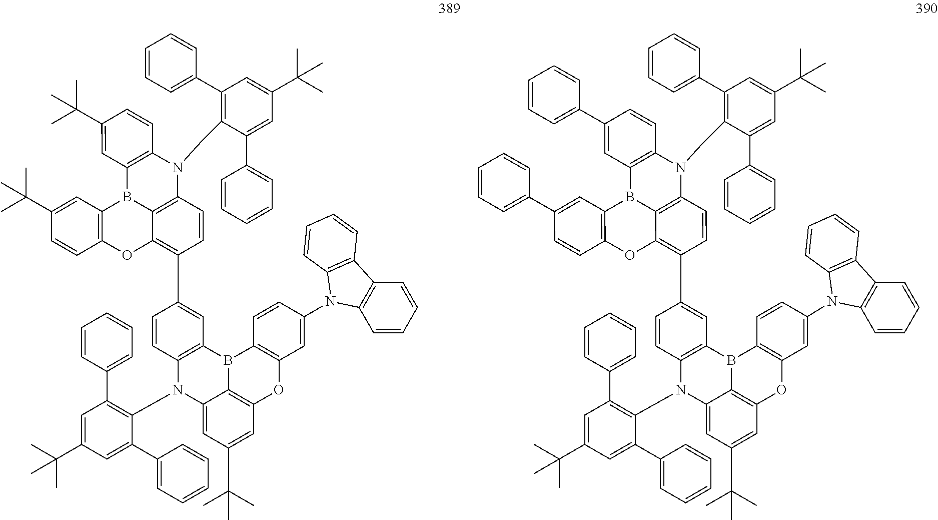 [SMILES: CC(C)(C)c1ccc2c(c1)B1c3cc(C(C)(C)C)ccc3N(Cc3c(-c4ccccc4)cc(C(C)(C)C)cc3-c3ccccc3)c3ccc(-c4ccc5c(c4)B4c6ccc(-n7c8ccccc8c8ccccc87)cc6Oc6cc(C(C)(C)C)cc(c64)N5c4c(-c5ccccc5)cc(C(C)(C)C)cc4-c4ccccc4)c(c31)O2 ; CC(C)(C)c1cc(-c2ccccc2)c(CN2c3ccc(-c4ccccc4)cc3B3c4cc(-c5ccccc5)ccc4Oc4c(-c5ccc6c(c5)B5c7ccc(-n8c9ccccc9c9ccccc98)cc7Oc7cc(C(C)(C)C)cc(c75)N6c5c(-c6ccccc6)cc(C(C)(C)C)cc5-c5ccccc5)ccc2c43)c(-c2ccccc2)c1] 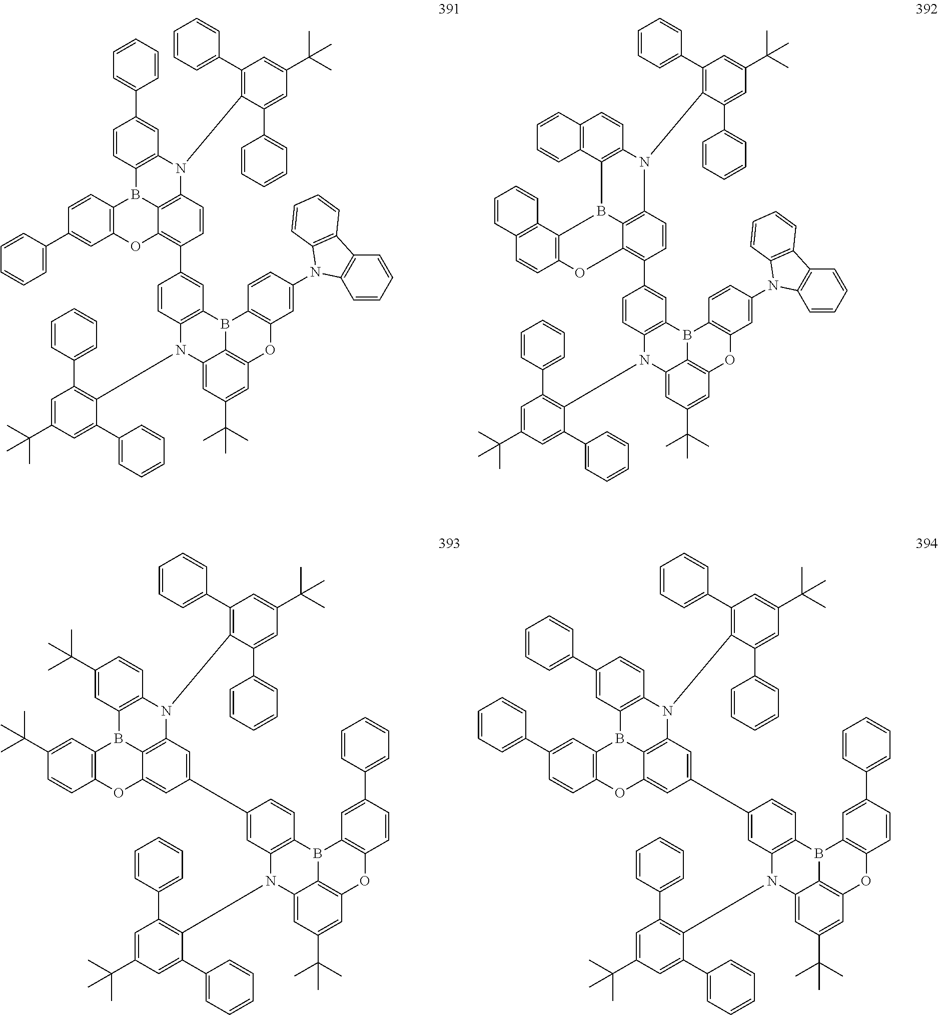 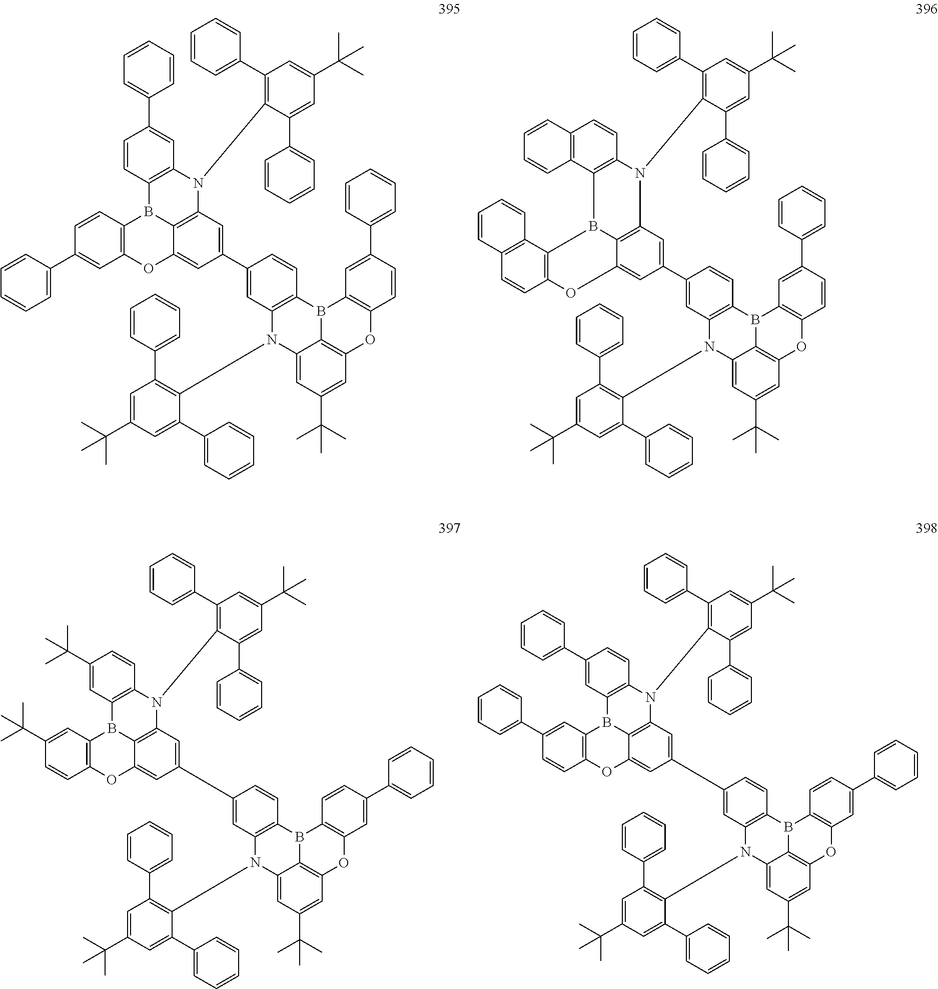 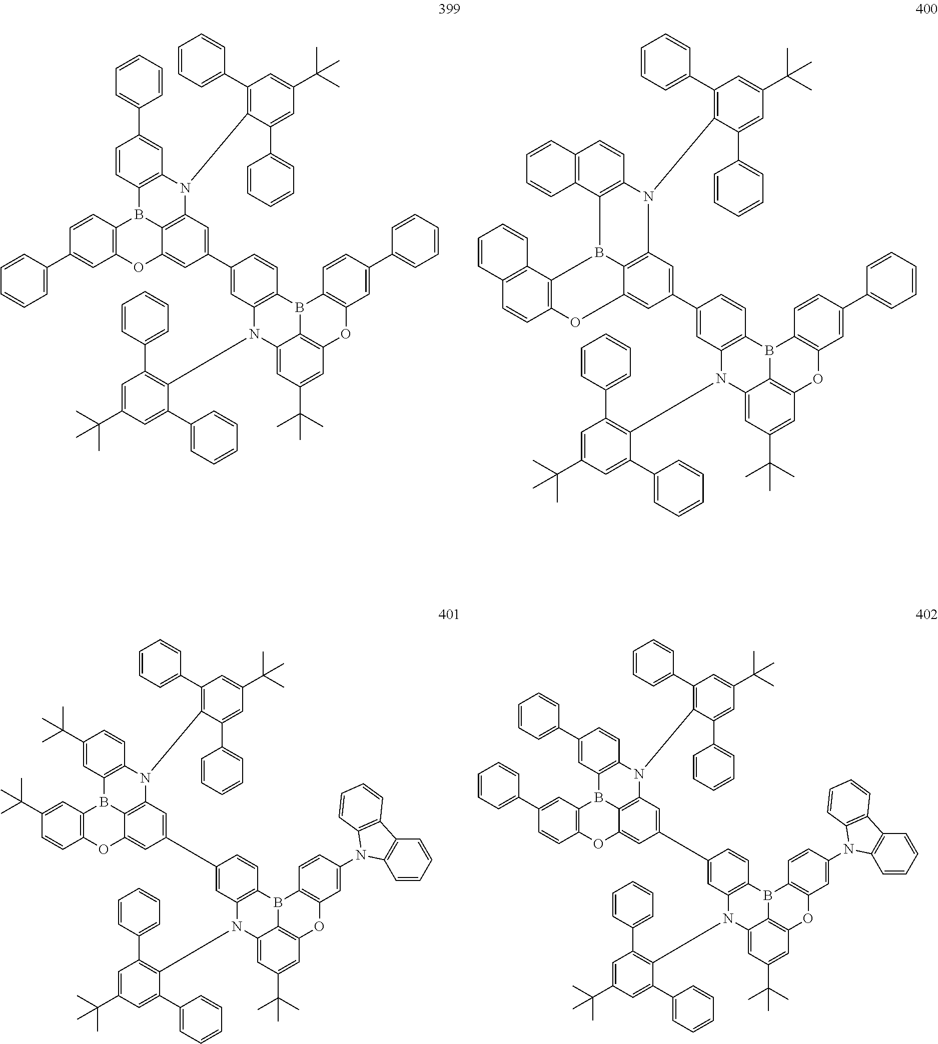 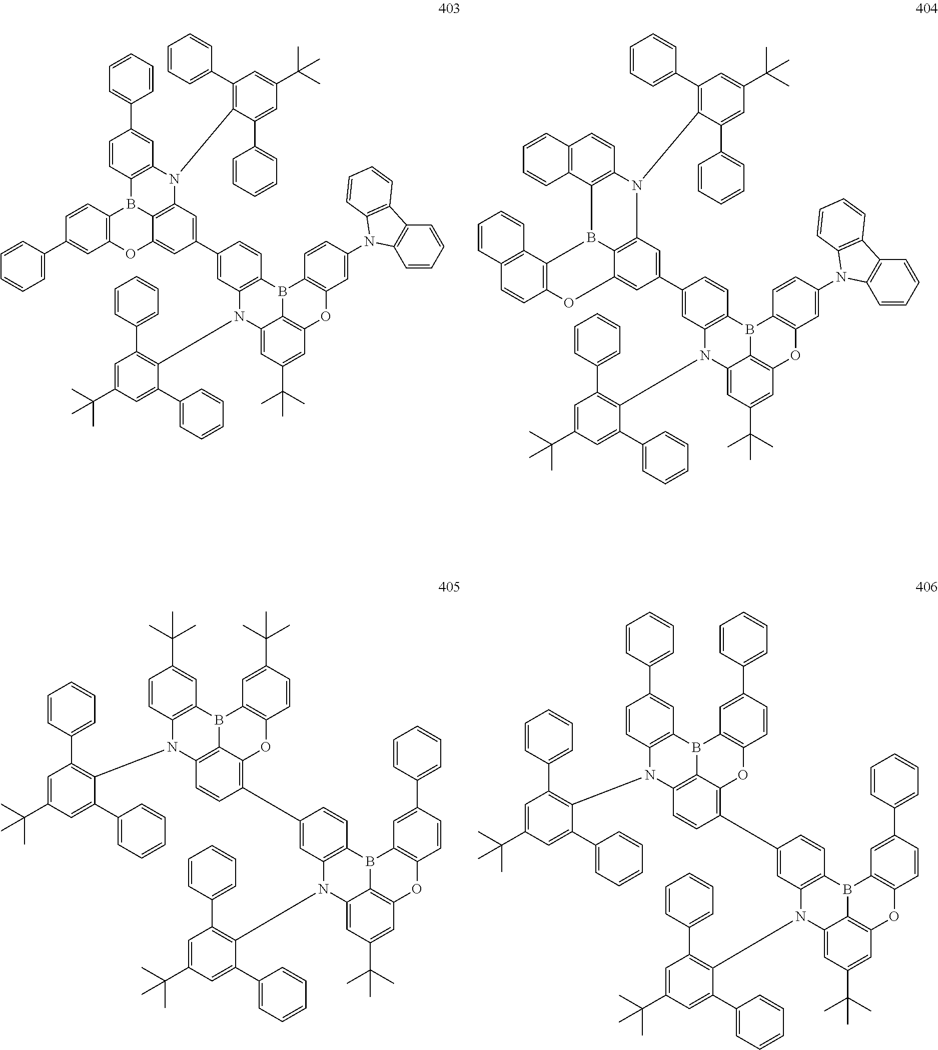 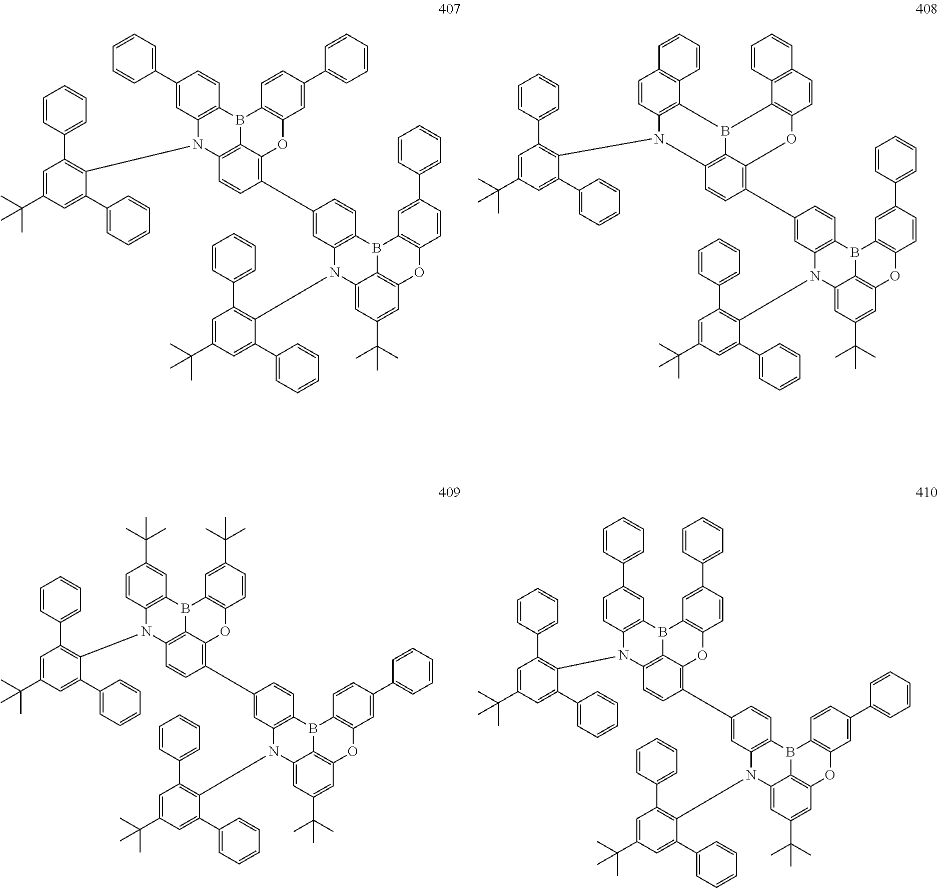 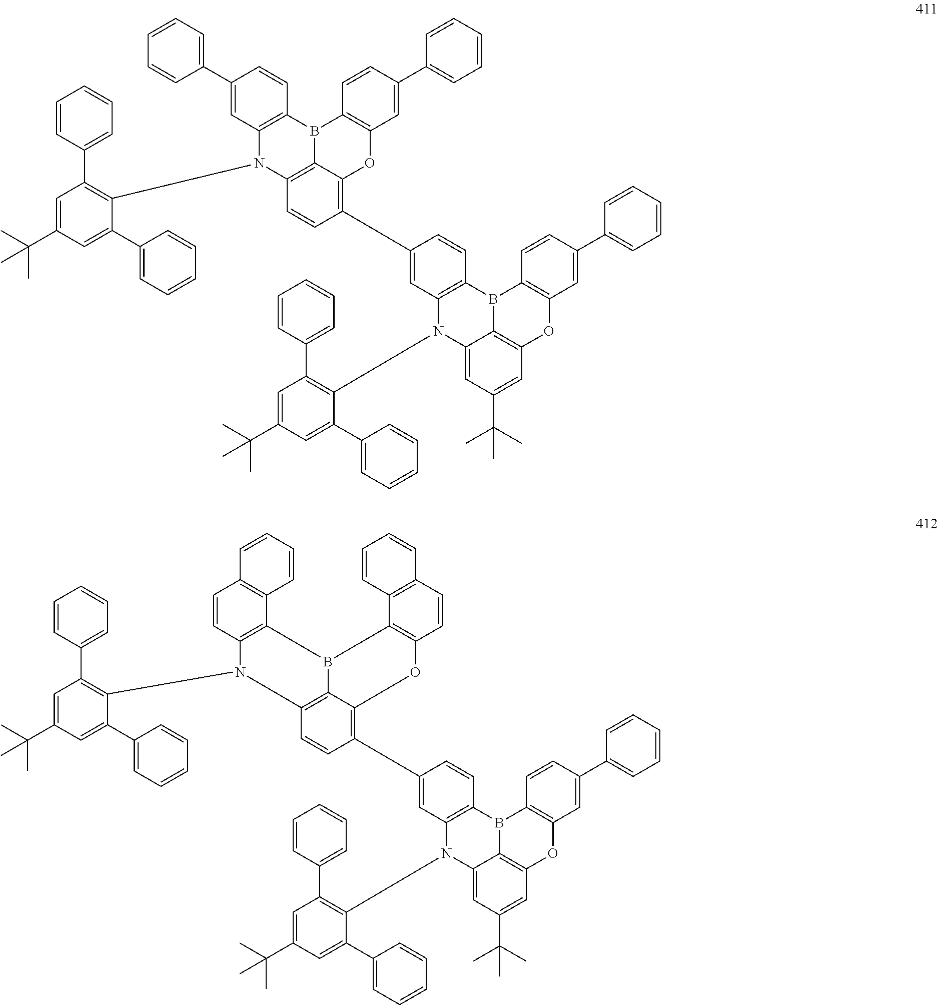 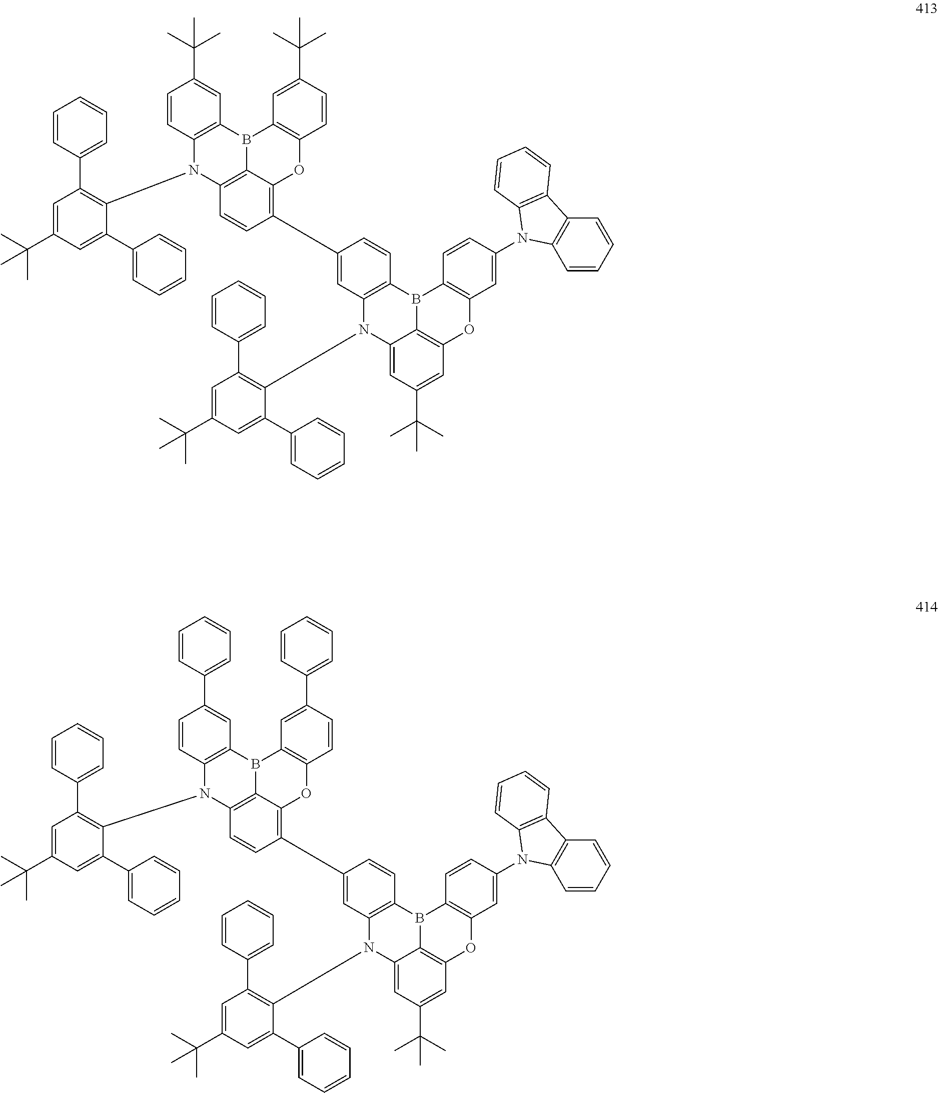 [SMILES: CC(C)(C)c1ccc2c(c1)B1c3cc(C(C)(C)C)ccc3N(c3c(-c4ccccc4)cc(C(C)(C)C)cc3-c3ccccc3)c3ccc(-c4ccc5c(c4)N(c4c(-c6ccccc6)cc(C(C)(C)C)cc4-c4ccccc4)c4cc(C(C)(C)C)cc6c4B5c4ccc(-n5c7ccccc7c7ccccc75)cc4O6)c(c31)O2 ; CC(C)(C)c1cc(-c2ccccc2)c(N2c3cc(-c4ccc5c6c4Oc4ccc(-c7ccccc7)cc4B6c4cc(-c6ccccc6)ccc4N5c4c(-c5ccccc5)cc(C(C)(C)C)cc4-c4ccccc4)ccc3B3c4ccc(-n5c6ccccc6c6ccccc65)cc4Oc4cc(C(C)(C)C)cc2c43)c(-c2ccccc2)c1] 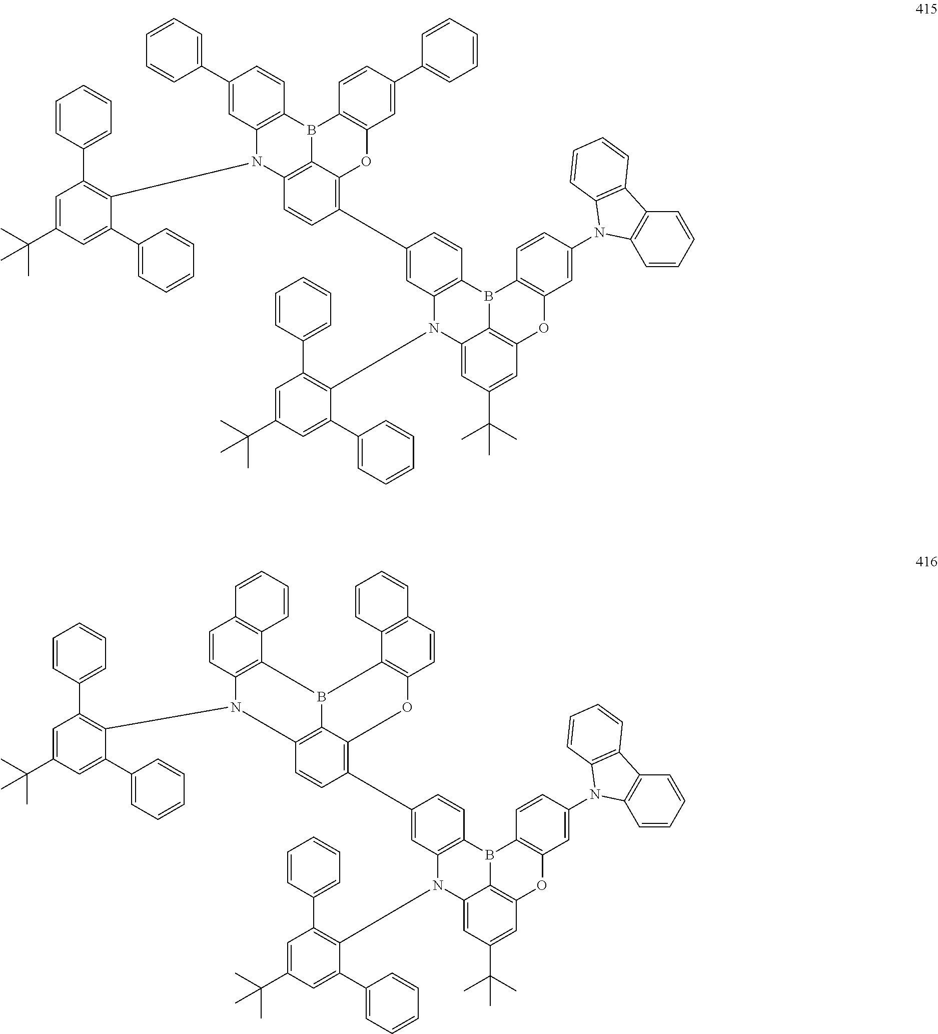 [SMILES: CC(C)(C)c1cc(-c2ccccc2)c(N2c3cc(-c4ccc5c6c4Oc4cc(-c7ccccc7)ccc4B6c4ccc(-c6ccccc6)cc4N5c4c(-c5ccccc5)cc(C(C)(C)C)cc4-c4ccccc4)ccc3B3c4ccc(-n5c6ccccc6c6ccccc65)cc4Oc4cc(C(C)(C)C)cc2c43)c(-c2ccccc2)c1 ; CC(C)(C)c1cc(-c2ccccc2)c(N2c3cc(-c4ccc5c6c4Oc4ccc7ccccc7c4B6c4c(ccc6ccccc46)N5c4c(-c5ccccc5)cc(C(C)(C)C)cc4-c4ccccc4)ccc3B3c4ccc(-n5c6ccccc6c6ccccc65)cc4Oc4cc(C(C)(C)C)cc2c43)c(-c2ccccc2)c1] 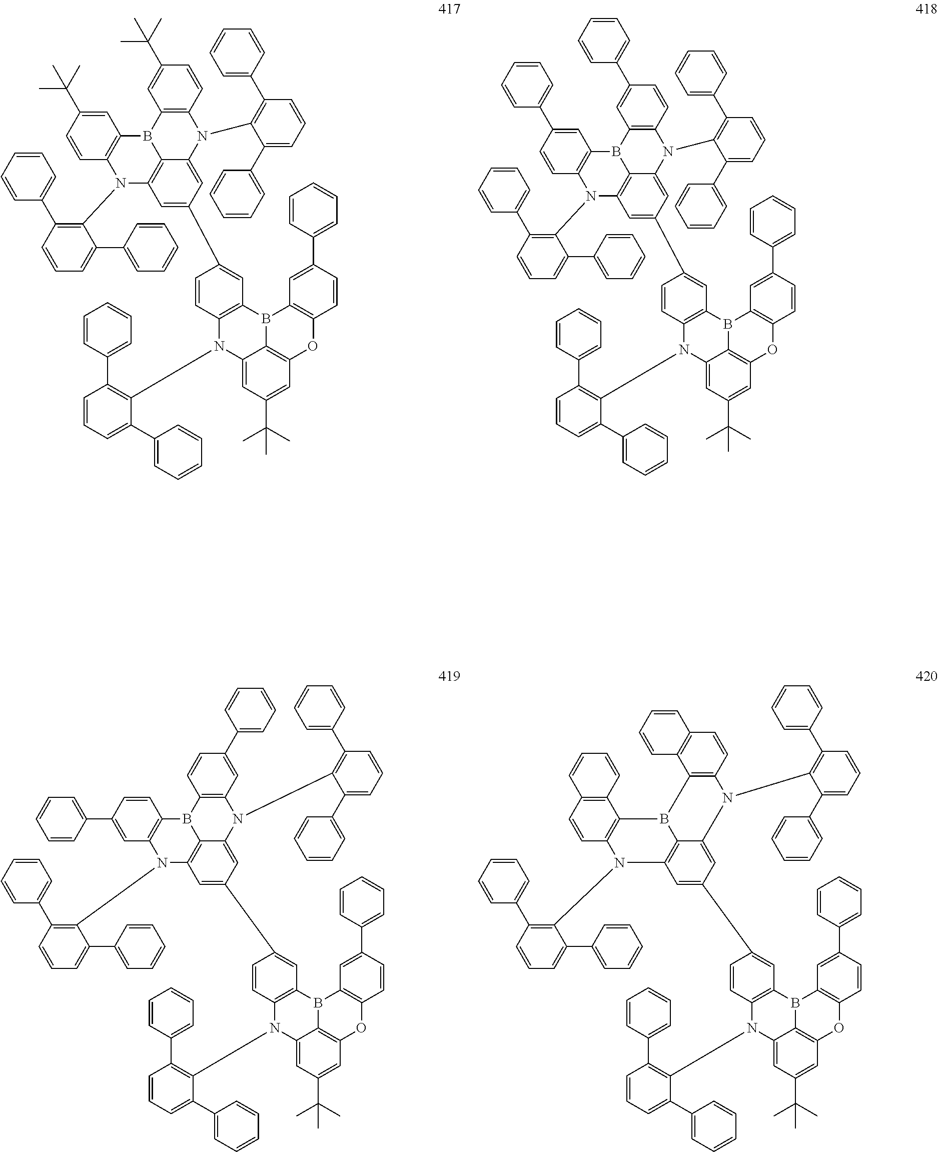 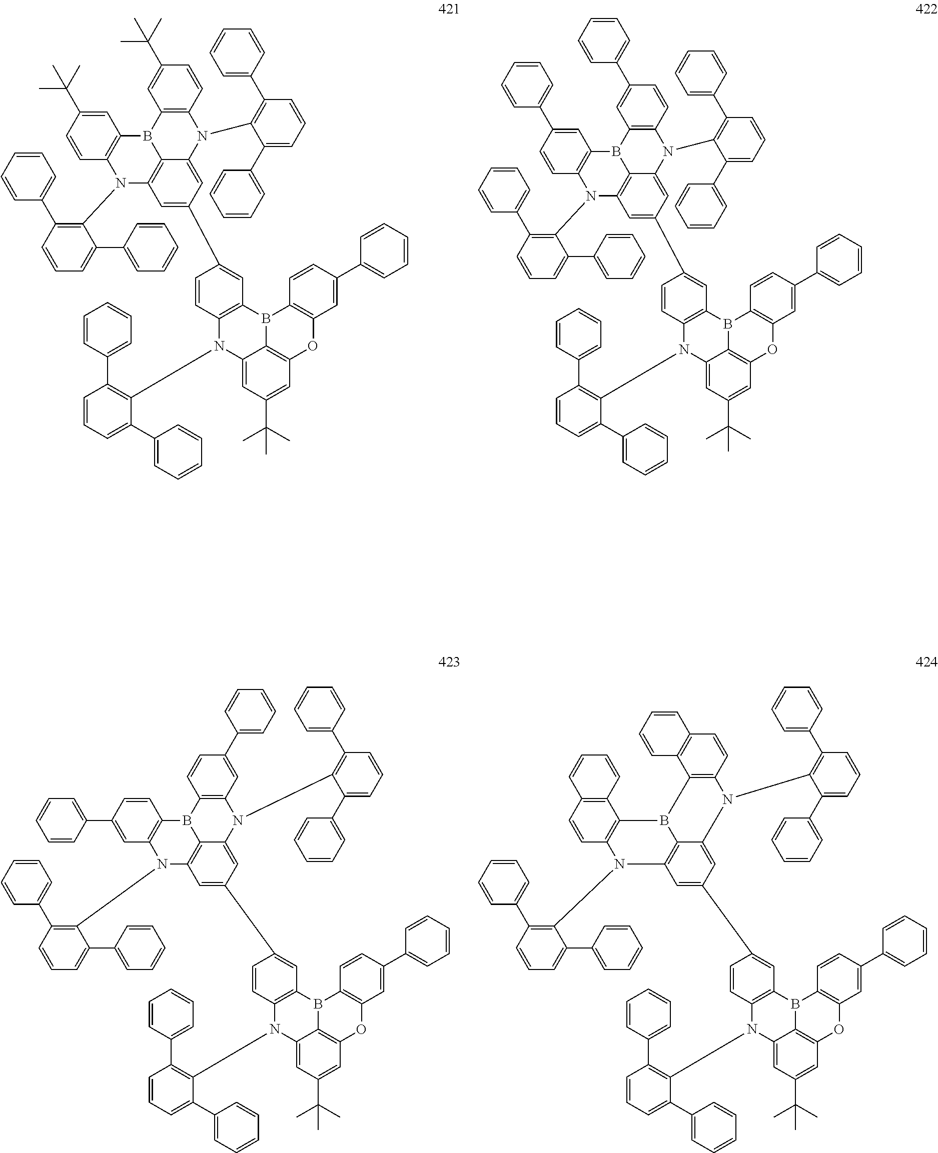 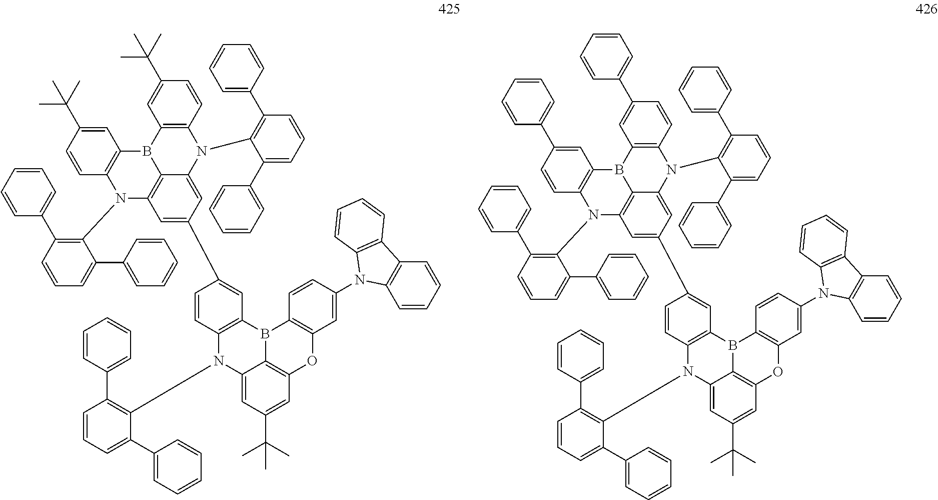 [SMILES: CC(C)(C)c1ccc2c(c1)B1c3cc(C(C)(C)C)ccc3N(c3c(-c4ccccc4)cccc3-c3ccccc3)c3cc(-c4ccc5c(c4)B4c6ccc(-n7c8ccccc8c8ccccc87)cc6Oc6cc(C(C)(C)C)cc(c64)N5c4c(-c5ccccc5)cccc4-c4ccccc4)cc(c31)N2c1c(-c2ccccc2)cccc1-c1ccccc1 ; CC(C)(C)c1cc2c3c(c1)N(c1c(-c4ccccc4)cccc1-c1ccccc1)c1ccc(-c4cc5c6c(c4)N(c4c(-c7ccccc7)cccc4-c4ccccc4)c4ccc(-c7ccccc7)cc4B6c4cc(-c6ccccc6)ccc4N5c4c(-c5ccccc5)cccc4-c4ccccc4)cc1B3c1ccc(-n3c4ccccc4c4ccccc43)cc1O2] 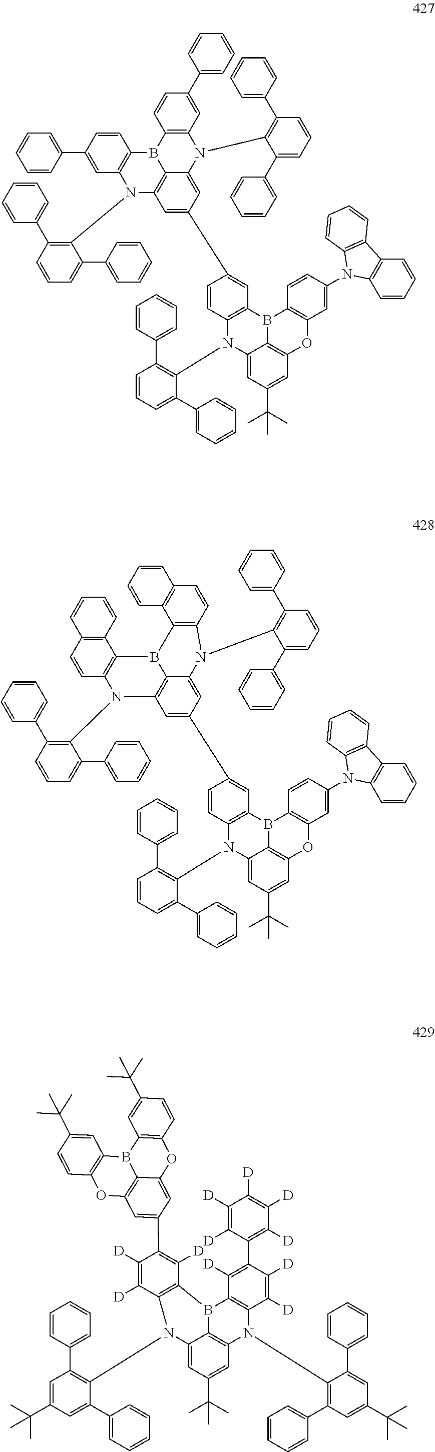 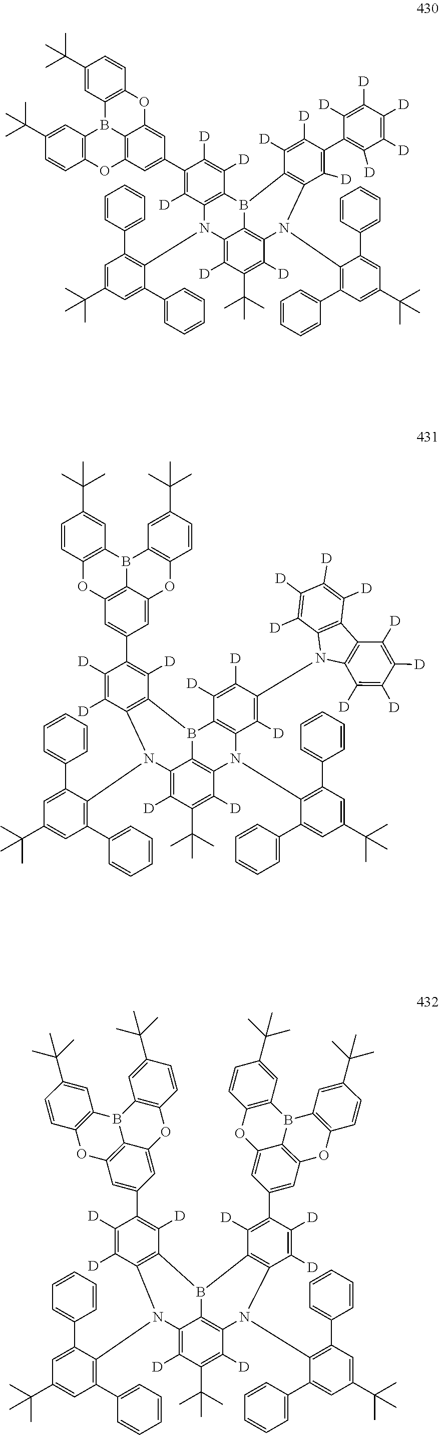 [chemical structure]
